(19) United States
(12) Patent Application Publication
(10) Pub. No.: US 2018/0208836 A1
(43) Pub. Date: Jul. 26, 2018

(54) ORGANIC ELECTROLUMINESCENCE ELEMENT AND ELECTRONIC DEVICE

(71) Applicant: IDEMITSU KOSAN CO., LTD., Tokyo (JP)

(72) Inventors: Hitoshi KUMA, Sodegaura-shi, Chiba (JP); Yukitoshi JINDE, Sodegaura-shi, Chiba (JP)

(73) Assignee: IDEMITSU KOSAN CO., LTD., Tokyo (JP)

(21) Appl. No.: 15/743,961

(22) PCT Filed: Jul. 12, 2016
(86) PCT No.: PCT/JP2016/070610

§ 371 Date: Jan. 11, 2018

(30) Foreign Application Priority Data
Jul. 14, 2015 (JP) 2015-140828

(51) Int. Cl. C09K 11/06; H01L 51/50; H01L 51/00

(52) U.S. Cl. CPC C09K 11/06; H01L 51/504; C09K 2211/1018; H01L 51/0059; H01L 51/0056

(57) ABSTRACT

An organic electroluminescence device includes a cathode, an anode, a charge generating layer provided between the cathode and the anode, a first emitting unit provided between the charge generating layer and the cathode, and a second emitting unit provided between the charge generating layer and the anode. The first emitting unit includes a blue emitting layer containing a first compound represented by a formula and a second compound emitting a blue light, in which Z¹ is represented by a formula and a cyclic structure represented by a formula or is fused to Z¹, and X¹ and X² are each an oxygen atom or a sulfur atom.

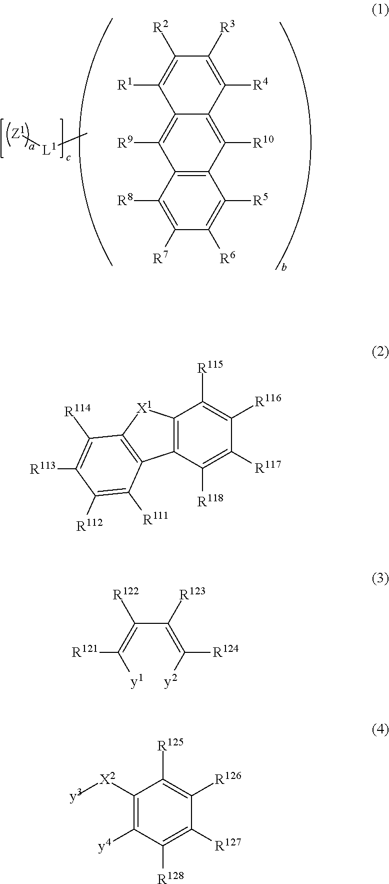

### TECHNICAL FIELD

The present invention relates to an organic electroluminescence device and an electronic device.

### BACKGROUND ART

An organic electroluminescence device (hereinafter, occasionally abbreviated as organic EL device) using an organic substance is highly expected to be used as an inexpensive solid-emitting full-color display device having a large area and has been variously developed. A typical organic EL device includes an emitting layer and a pair of opposing electrodes (i.e., anode and cathode) between which the emitting layer is interposed. When an electric field is applied on both of the electrodes, electrons are injected from the cathode while holes are injected from the anode. The injected holes and electrons are recombined in the emitting layer to generate excitons. When the excitons are returned to a ground state, energy is emitted as light.

The organic EL device is exemplified by an organic EL device including an anode, a cathode and a single emitting unit between the anode and the cathode (hereinafter, occasionally referred to as a mono-unit organic EL device).

Moreover, the organic EL device is also exemplified by an organic EL device including a plurality of emitting units connected in series with each other via a charge generating layer interposed between the emitting units. Such an organic EL device is occasionally referred to as a tandem organic EL device, multi-unit organic EL device, or stacked organic EL device. Herein, the organic EL device is referred to as a tandem organic EL device.

The tandem organic EL device has been conventionally studied in various ways (see, for instance, Patent Literatures 1 to 3).

It has been studied to make an organic EL device emit a white light by appropriately designing emission colors of an emitting unit interposed between the anode and the charge generating layer and an emitting unit interposed between the cathode and the charge generating layer. For instance, Patent Literatures 1 and 2 disclose an organic EL device including: an emitting unit including a red emitting layer and a green emitting layer and interposed between the anode and the charge generating layer; and an emitting unit including a blue emitting layer and interposed between the cathode and the charge generating layer.

### CITATION LIST

### Patent Literatures

Patent Literature 1: JP2006-324016A

Patent Literature 2: JP2005-267990A

Patent Literature 3: JP2008-518400A

### SUMMARY OF THE INVENTION

### Problems to be Solved by the Invention

An object of the invention is to provide an organic electroluminescence device drivable at a low voltage with a long lifetime while keeping a high luminous efficiency, and an electronic device including the organic electroluminescence device.

### Means for Solving the Problems

According to an aspect of the invention, an organic electroluminescence device includes a cathode, an anode, a charge generating layer provided between the cathode and the anode, a first emitting unit provided between the charge generating layer and the cathode, and a second emitting unit provided between the charge generating layer and the anode, in which the first emitting unit includes a blue emitting layer containing a first compound represented by a formula and a second compound emitting a blue light.

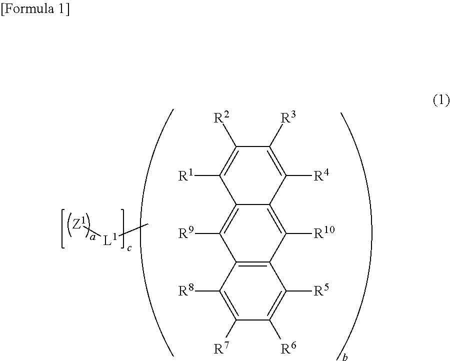

In the formula (1), any one of R¹ to R¹⁰ is a single bond to be bonded to L¹ and the rest of R¹ to R¹⁰, which are not bonded to L¹, are each independently a hydrogen atom or a substituent, R¹ to R¹⁰ each in a form of the substituent are each independently selected from the group consisting of a halogen atom, a hydroxyl group, a cyano group, a substituted or unsubstituted amino group, a substituted or unsubstituted alkyl group having 1 to 30 carbon atoms, a substituted or unsubstituted alkoxy group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted aromatic hydrocarbon group having 6 to 30 ring carbon atoms, and a substituted or unsubstituted heterocyclic group having 5 to 30 ring atoms; L¹ is a single bond or a linking group, and L¹ in a form of the linking group is a substituted or unsubstituted aromatic hydrocarbon group having 6 to 30 ring carbon atoms, or a substituted or unsubstituted heterocyclic group having 5 to 30 ring atoms; Z¹ is represented by a formula (2) below; a, b and c are each independently an integer of 1 to 4; a plurality of Z¹ are optionally the same or different; a plurality of structures each represented by [(Z¹)ₐ-L¹-] are optionally the same or different; and a plurality of cyclic structures in parentheses with a suffix b are optionally the same or different.

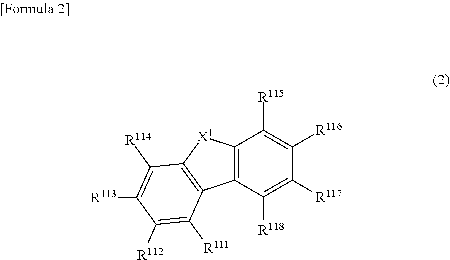

In the formula (2), X¹ is an oxygen atom or a sulfur atom; R¹¹¹ to R¹¹⁸ are each independently a hydrogen atom, a substituent, or a single bond bonded to L¹, and R¹¹¹ to R¹¹⁸ each in a form of the substituent are each independently selected from the examples of the substituent usable as R¹ to R¹⁰; and at least one combination of a combination of R¹¹¹ and R¹¹², a combination of R¹¹² and R¹¹³, a combination of R¹¹³ and R¹¹⁴, a combination of R¹¹⁵ and R¹¹⁶, a combination of R¹¹⁶ and R¹¹⁷, or a combination of R¹¹⁷ and R¹¹⁸ is the substituents that are bonded to each other to form a ring represented by a formula (3) or (4) below.

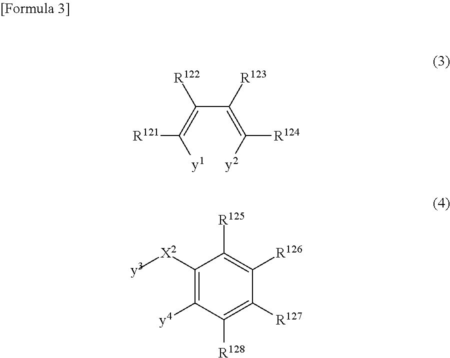

In the formula (3), y¹ and y² represent bonding positions with Z¹ that is the cyclic structure represented by the formula (2). In the formula (4), y³ and y⁴ represent bonding positions with Z¹ that is the cyclic structure represented by the formula (2), and X² is an oxygen atom or a sulfur atom. In the formulae (3) and (4), R¹²¹ to R¹²⁴ and R¹²⁵ to R¹²⁸ are each independently a hydrogen atom, a substituent, or a single bond bonded to L¹, and R¹²¹ to R¹²⁸ each in a form of the substituent are each independently selected from the examples of the substituent usable as R¹ to R¹⁰, when the ring represented by the formula (3) is formed, any one of R¹¹¹ to R¹¹⁸ and R¹²¹ to R¹²⁴ not bonded to form a ring is a single bond bonded to L¹, and when the ring represented by the formula (4) is formed, any one of R¹¹¹ to R¹¹⁸ and R¹²⁵ to R¹²⁸ not bonded to form a ring is a single bond bonded to L¹.

According to another aspect of the invention, an electronic device including the organic electroluminescence device according to the above aspect of the invention is provided.

According the above aspects of the invention, an organic electroluminescence device drivable at a low voltage with a long lifetime while keeping a high luminous efficiency can be provided, and an electronic device including the organic electroluminescence device can be provided.

### BRIEF DESCRIPTION OF DRAWINGS

FIG. 1 schematically shows an exemplary arrangement of an organic EL device according to a first exemplary embodiment.

FIG. 2 schematically shows an exemplary arrangement of an organic EL device according to a second exemplary embodiment.

FIG. 3 is a graph showing a time-dependent change in stimulus value of a blue component in organic EL devices according to Example and Comparative.

### DESCRIPTION OF EMBODIMENT(S)

### First Exemplary Embodiment

### Organic EL Device

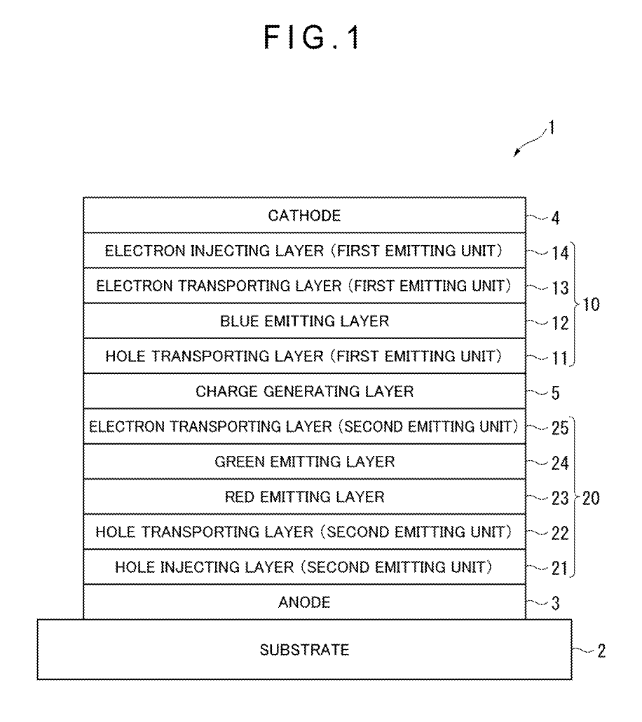

FIG. 1 schematically shows an arrangement of a tandem organic EL device 1 according to a first exemplary embodiment.

The organic EL device 1 includes a cathode 4, an anode 3, a charge generating layer 5 interposed between the cathode 4 and the anode 3, a first emitting unit 10 interposed between the charge generating layer 5 and the cathode 4, and a second emitting unit 20 interposed between the charge generating layer 5 and the anode 3. The first emitting unit 10 is connected in series with the second emitting unit 20 via the charge generating layer 5.

The first emitting unit 10 includes a hole transporting layer 11, a blue emitting layer 12, an electron transporting layer 13, and an electron injecting layer 14. The blue emitting layer 12 includes a first compound represented by a formula (1) below and a second compound emitting a blue light.

The second emitting unit 20 includes a hole injecting layer 21, a hole transporting layer 22, a red emitting layer 23, a green emitting layer 24, and an electron transporting layer 25.

Since the organic EL device 1 includes red, green and blue emitting layers, the organic EL device 1 can emit a white light.

### First Emitting Unit

In the first emitting unit 10, the hole transporting layer 11, the blue emitting layer 12, the electron transporting layer 13, and the electron injecting layer 14 are sequentially laminated on the charge generating layer 5.

### Blue Emitting Layer

The blue emitting layer 12 is interposed between the hole transporting layer 11 and the electron transporting layer 13 while being interposed between the charge generating layer 5 and the cathode 4.

The blue emitting layer 12 includes the first compound represented by a formula (1) below and the second compound emitting a blue light.

### First Compound

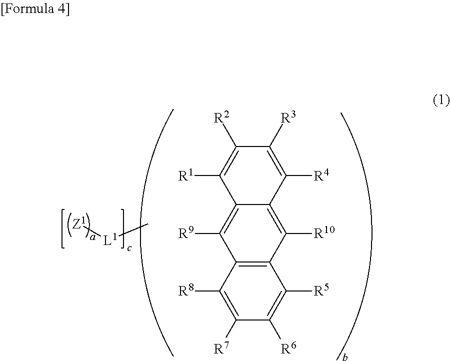

In the formula (1), any one of R¹ to R¹⁰ is a single bond bonded to L¹.

R¹ to R¹⁰ not bonded to L¹ are each independently a hydrogen atom or a substituent.

R¹ to R¹⁰ each in a form of the substituent are each independently selected from the group consisting of a halogen atom, hydroxyl group, cyano group, substituted or unsubstituted amino group, substituted or unsubstituted alkyl group having 1 to 30 carbon atoms, substituted or unsubstituted alkoxy group having 1 to 30 carbon atoms, substituted or unsubstituted aryloxy group having 6 to 30 ring carbon atoms, substituted or unsubstituted arylthio group having 6 to 30 ring carbon atoms, substituted or unsubstituted aromatic hydrocarbon group having 6 to 30 ring carbon atoms, and substituted or unsubstituted heterocyclic group having 5 to 30 ring atoms.

L¹ is a single bond or a linking group. L¹ as the linking group is a substituted or unsubstituted aromatic hydrocarbon group having 6 to 30 ring carbon atoms or a substituted or unsubstituted heterocyclic group having 5 to 30 ring atoms.

Z¹ is represented by a formula (2) below.

a, b and c are each independently an integer of 1 to 4.

A plurality of Z¹ may be mutually the same or different.

A plurality of structures each represented by [(Z¹)ₐ-L¹-] may be mutually the same or different.

A plurality of cyclic structures in parentheses with a suffix b may be mutually the same or different.

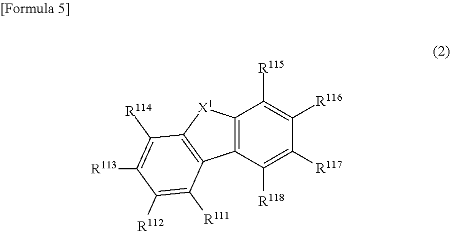

In the formula (2), X¹ is an oxygen atom or a sulfur atom.

R¹¹¹ to R¹¹⁸ are each independently a hydrogen atom, a substituent, or a single bond bonded to L¹. R¹¹¹ to R¹¹⁸ each in a form of the substituent are each independently selected from the above examples of the substituent usable as R¹ to R¹⁰. At least one combination of a combination of R¹¹¹ and R¹¹², a combination of R¹¹² and R¹¹³, a combination of R¹¹³ and R¹¹⁴, a combination of R¹¹⁵ and R¹¹⁶, a combination of R¹¹⁶ and R¹¹⁷, or a combination of R¹¹⁷ and R¹¹⁸ is the substituents that are bonded to each other to form a ring represented by a formula (3) or (4) below.

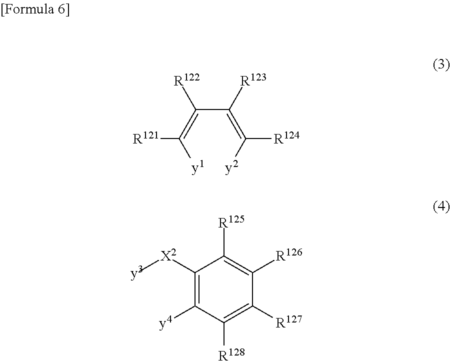

In the formula (3), y¹ and y² represent bonding positions with Z¹ that is the cyclic structure represented by the formula (2).

In the formula (4), y³ and y⁴ represent bonding positions with Z¹ that is the cyclic structure represented by the formula (2). X² is an oxygen atom or a sulfur atom.

In the formulae (3) and (4), R¹²¹ to R¹²⁴ and R¹²⁵ to R¹²⁸ are each independently a hydrogen atom, a substituent, or a single bond bonded to L¹. R¹²¹ to R¹²⁸ each in a form of the substituent are each independently selected from the above examples of the substituent usable as R¹ to R¹⁰.

In the first compound in which the ring represented by the formula (3) is formed, one of R¹¹¹ to R¹¹⁸ and R¹²¹ to R¹²⁴ not bonded to form a ring is a single bond bonded to L¹.

In the first compound in which the ring represented by the formula (3) is formed, X¹ is preferably an oxygen atom.

Z¹ is preferably a group selected from the group consisting of groups represented by formulae (8) to (10) below. Z¹ is more preferably a group represented by a formula (9) below.

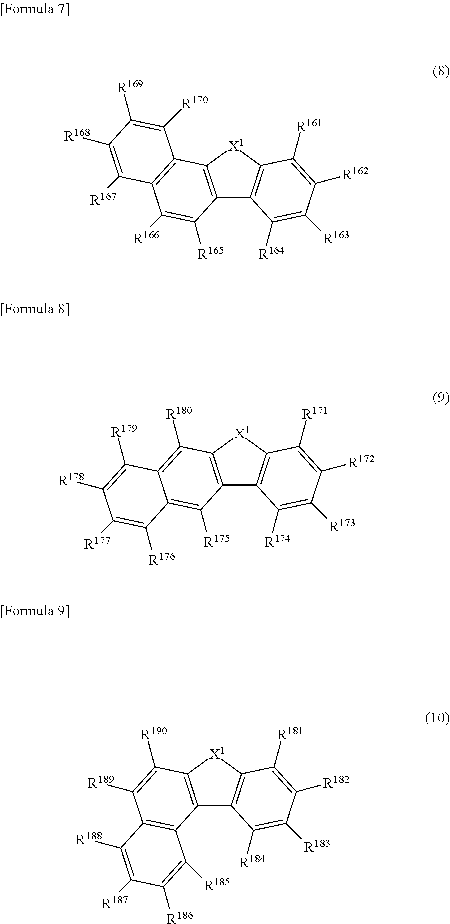

In the formula (8), R¹⁶¹ to R¹⁷⁰ each independently represent the same as R¹ to R¹⁰ not bonded to L¹ in the formula (1). However, one of R¹⁶¹ to R¹⁷⁰ is a single bond bonded to L¹.

In the formula (9), R¹⁷¹ to R¹⁸⁰ each independently represent the same as R¹ to R¹⁰ not bonded to L¹ in the formula (1). However, one of R¹⁷¹ to R¹⁸⁰ is a single bond bonded to L¹.

In the formula (10), R¹⁸¹ to R¹⁹⁰ each independently represent the same as R¹ to R¹⁰ not bonded to L¹ in the formula (1). However, one of R¹⁸¹ to R¹⁹⁰ is a single bond bonded to L¹.

In the formulae (8) to (10), X¹ represents the same as X¹ in the formula (2) and is preferably an oxygen atom.

In the first compound in which the ring represented by the formula (4) is formed, any one of R¹¹¹ to R¹¹⁸ and R¹²⁵ to R¹²⁸ not bonded to form a ring is a single bond bonded to L¹.

In the first compound in which the ring represented by the formula (4) is formed, X¹ and X² are preferably oxygen atoms.

Z¹ is also preferably a group selected from the group consisting of groups represented by formulae (5) to (7) below.

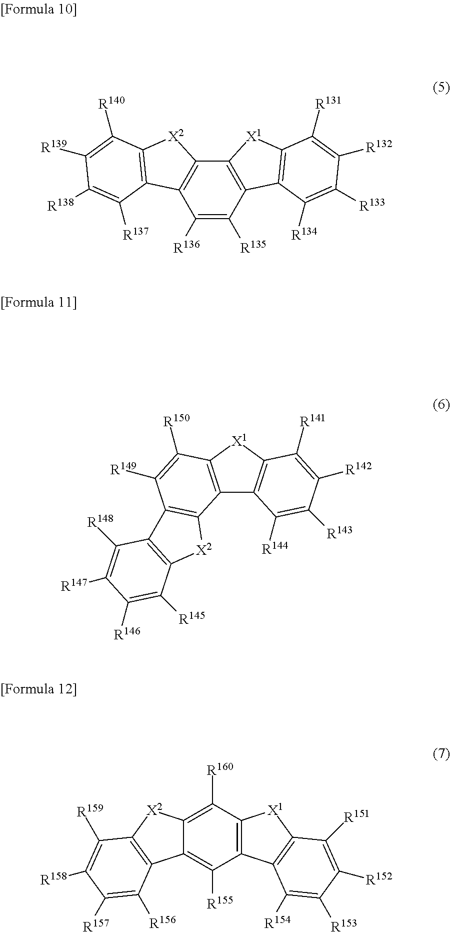

In the formula (5), R¹³¹ to R¹⁴⁰ each represent the same as R¹ to R¹⁰ not bonded to L¹ in the formula (1). However, any one of R¹³¹ to R¹⁴⁰ is a group (i.e., a single bond) bonded to L¹.

In the formula (6), R¹⁴¹ to R¹⁵⁰ each represent the same as R¹ to R¹⁰ not bonded to L¹ in the formula (1). However, any one of R¹⁴¹ to R¹⁵⁰ is a group (i.e., a single bond) bonded to L¹.

In the formula (7), R¹⁵¹ to R¹⁶⁰ each represent the same as R¹ to R¹⁰ not bonded to L¹ in the formula (1). However, any one of R¹⁵¹ to R¹⁶⁰ is a group (i.e., a single bond) bonded to L¹.

In the formulae (5) to (7), X¹ represents the same as X¹ in the formula (2) and X² represents the same as X² in the formula (4). X¹ and X² are the same or different.

In the formula (1), b is preferably 1.

In the formula (1), a is preferably 1 or 2.

In the formula (1), c is preferably 1.

At least one of R⁹ or R¹⁰ in the formula (1) is preferably a single bond bonded to L¹.

For instance, when b is 1 and R⁹ is a single bond bonded to L¹, the first compound is represented by a formula (11) below.

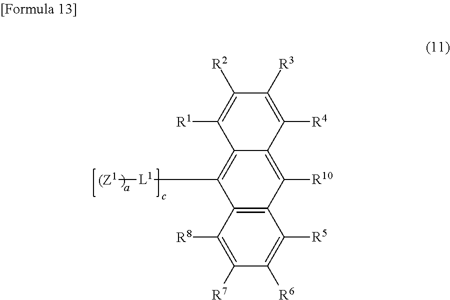

In the formula (11), R¹ to R⁸, R¹⁰, Z¹, L¹, a and c respectively represent the same as R¹ to R⁸, R¹⁰, Z¹, L¹, a and c of the formula (1).

R¹⁰ is preferably a group selected from the group consisting of a substituted or unsubstituted aromatic hydrocarbon group having 6 to 30 ring carbon atoms, and a substituted or unsubstituted heterocyclic group having 5 to 30 ring atoms.

The first compound is also preferably represented by a formula (12) below.

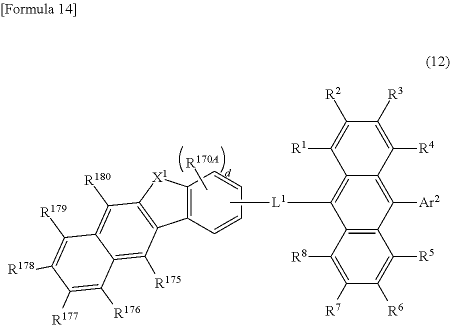

In the formula (12), R¹ to R⁸ are each independently a hydrogen atom or a substituent. R¹ to R⁸ each in a form of the substituent are each independently selected from the above examples of the substituent usable as R¹ to R⁸ in the formula (1).

L₁ is a single bond or a linking group. L¹ as the linking group is a substituted or unsubstituted aromatic hydrocarbon group having 6 to 30 ring carbon atoms or a substituted or unsubstituted heterocyclic group having 5 to 30 ring atoms.

Ar² is a substituted or unsubstituted aromatic hydrocarbon group having 6 to 30 ring carbon atoms or a substituted or unsubstituted heterocyclic group having 5 to 30 ring atoms.

R^{170A} is a hydrogen atom, a substituent, or a single bond bonded to L¹. R^{170A} in a form of the substituent is selected from the above examples of the substituent usable as R¹ to R⁸. d is 4. A plurality of R^{170A} may be mutually the same or different.

X¹ is an oxygen atom or a sulfur atom.

R¹⁷⁵ to R¹⁸⁰ are each independently a hydrogen atom or a substituent. R¹⁷⁵ to R¹⁸⁰ each in a form of the substituent are each independently selected from the above examples of the substituent usable as R¹ to R⁸.

The first compound is preferably represented by a formula (13) or (14) below.

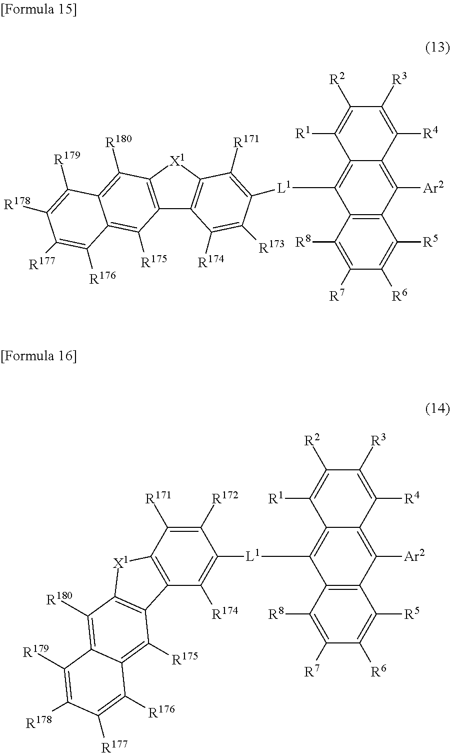

In the formulae (13) and (14), R¹ to R⁸, L¹ and X¹ respectively represent the same as R¹ to R⁸, L¹ and X¹ in the formula (1) or (2).

Ar² is a substituted or unsubstituted aromatic hydrocarbon group having 6 to 30 ring carbon atoms or a substituted or unsubstituted heterocyclic group having 5 to 30 ring atoms.

In the formula (13), R¹⁷¹ and R¹⁷³ to R¹⁸⁰ are each independently a hydrogen atom or a substituent. R¹⁷¹ and R¹⁷³ to R¹⁸⁰ each in a form of the substituent are each independently selected from the examples of the substituent usable as R¹ to R⁸.

In the formula (14), R¹⁷¹, R¹⁷², R¹⁷⁴ to R¹⁸⁰ are each independently a hydrogen atom or a substituent. R¹⁷¹, R¹⁷², and R¹⁷⁴ to R¹⁸⁰ each in a form of the substituent are each independently selected from the examples of the substituent usable as R¹ to R⁸.

The first compound is also preferably represented by a formula (17) below.

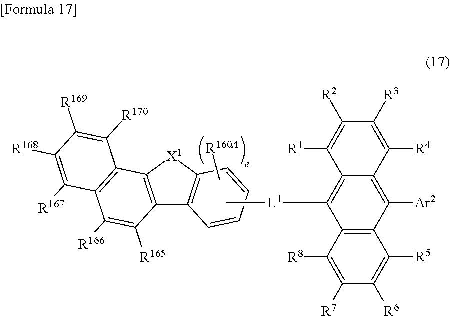

In the formula (17), R¹ to R⁸ are each independently a hydrogen atom or a substituent. R¹ to R⁸ each in a form of the substituent are each independently selected from the above examples of the substituent usable as R¹ to R⁸ in the formula (1).

L₁ is a single bond or a linking group. L¹ as the linking group is a substituted or unsubstituted aromatic hydrocarbon group having 6 to 30 ring carbon atoms or a substituted or unsubstituted heterocyclic group having 5 to 30 ring atoms.

Ar² is a substituted or unsubstituted aromatic hydrocarbon group having 6 to 30 ring carbon atoms or a substituted or unsubstituted heterocyclic group having 5 to 30 ring atoms.

R^{160A} is a hydrogen atom, a substituent, or a single bond bonded to L¹. R^{160A} in a form of the substituent is selected from the above examples of the substituent usable as R¹ to R⁸. e is 4. A plurality of R^{160A} may be mutually the same or different.

X¹ is an oxygen atom or a sulfur atom.

R¹⁶⁵ to R¹⁷⁰ are each independently a hydrogen atom or a substituent. R¹⁶⁵ to R¹⁷⁰ each in a form of the substituent are each independently selected from the above examples of the substituent usable as R¹ to R⁸.

The first compound is also preferably represented by a formula (18) or (19) below.

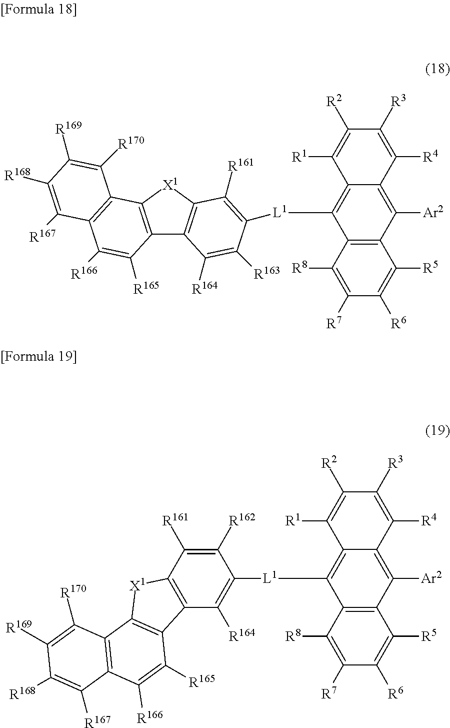

In the formulae (18) and (19), R¹ to R⁸, L¹ and X¹ respectively represent the same as R¹ to R⁸, L¹ and X¹ in the formula (1) or (2).

Ar² is a substituted or unsubstituted aromatic hydrocarbon group having 6 to 30 ring carbon atoms or a substituted or unsubstituted heterocyclic group having 5 to 30 ring atoms.

In the formula (18), R¹⁶¹ and R¹⁶³ to R¹⁷⁰ are each independently a hydrogen atom or a substituent. R¹⁶¹ and R¹⁶³ to R¹⁷⁰ each in a form of the substituent are each independently selected from the examples of the substituent usable as R¹ to R⁸.

In the formula (19), R¹⁶¹, R¹⁶², and R¹⁶⁴ to R¹⁷⁰ are each independently a hydrogen atom or a substituent. R¹⁶¹, R¹⁶², and R¹⁶⁴ to R¹⁷⁰ each in a form of the substituent are each independently selected from the examples of the substituent usable as R¹ to R⁸.

The first compound is also preferably represented by a formula (22) below.

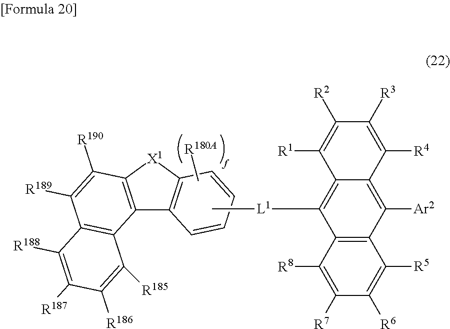

In the formula (22), R¹ to R⁸ are each independently a hydrogen atom or a substituent. R¹ to R⁸ each in a form of the substituent are each independently selected from the above examples of the substituent usable as R¹ to R⁸ in the formula (1).

L₁ is a single bond or a linking group. L¹ as the linking group is a substituted or unsubstituted aromatic hydrocarbon group having 6 to 30 ring carbon atoms or a substituted or unsubstituted heterocyclic group having 5 to 30 ring atoms.

Ar² is a substituted or unsubstituted aromatic hydrocarbon group having 6 to 30 ring carbon atoms or a substituted or unsubstituted heterocyclic group having 5 to 30 ring atoms.

R^{180A} is a hydrogen atom, a substituent, or a single bond bonded to L¹. R^{180A} being a substituent is selected from the above examples of the substituent usable as R¹ to R⁸. f is 4. A plurality of R^{180A} may be mutually the same or different.

X¹ is an oxygen atom or a sulfur atom.

R¹⁸⁵ to R¹⁹⁰ are each independently a hydrogen atom or a substituent. R¹⁸⁵ to R¹⁹⁰ each in a form of the substituent are each independently selected from the above examples of the substituent usable as R¹ to R⁸.

The first compound is also preferably represented by a formula (23) or (24) below.

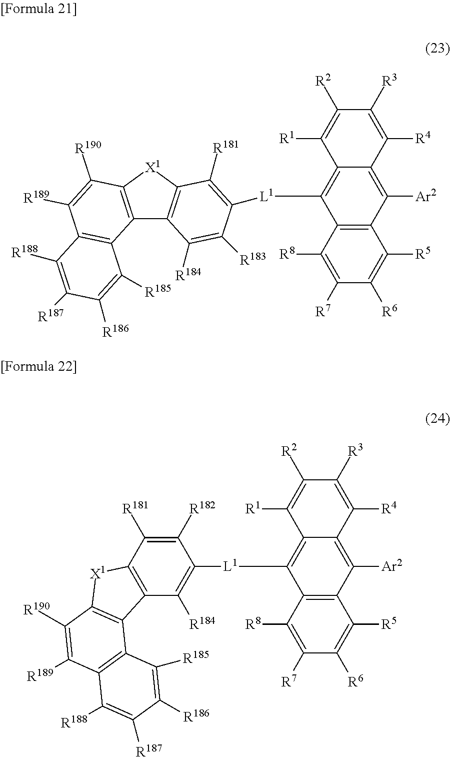

In the formulae (23) and (24), R¹ to R⁸, L¹ and X¹ respectively represent the same as R¹ to R⁸, L¹ and X¹ in the formula (1) or (2).

Ar² is a substituted or unsubstituted aromatic hydrocarbon group having 6 to 30 ring carbon atoms or a substituted or unsubstituted heterocyclic group having 5 to 30 ring atoms.

In the formula (23), R¹⁸¹ and R¹⁸³ to R¹⁹⁰ are each independently a hydrogen atom or a substituent. R¹⁸¹ and R¹⁸³ to R¹⁹⁰ each in a form of the substituent are each independently selected from the examples of the substituent usable as R¹ to R⁸.

In the formula (24), R¹⁸¹, R¹⁸², and R¹⁸⁴ to R¹⁹⁰ are each independently a hydrogen atom or a substituent. R¹⁸¹, R¹⁸², and R¹⁸⁴ to R¹⁹⁰ each in a form of the substituent are each independently selected from the examples of the substituent usable as R¹ to R⁸.

L¹ is also preferably a single bond.

The first compound is also preferably represented by a formula (15) or (16) below.

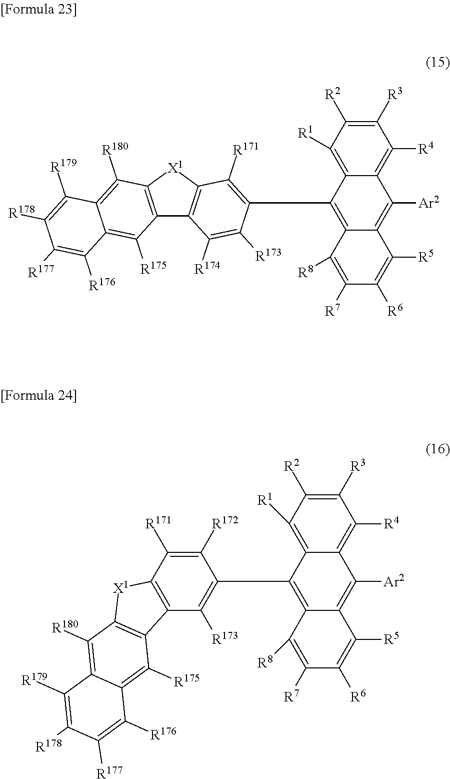

In the formulae (15) and (16), R¹ to R⁸ and X¹ respectively represent the same as R¹ to R⁸ and X¹ in the formula (1) or (2).

Ar² is a substituted or unsubstituted aromatic hydrocarbon group having 6 to 30 ring carbon atoms or a substituted or unsubstituted heterocyclic group having 5 to 30 ring atoms.

In the formula (15), R¹⁷¹ and R¹⁷³ to R¹⁸⁰ are each independently a hydrogen atom or a substituent. R¹⁷¹ and R¹⁷³ to R¹⁸⁰ each in a form of the substituent are each independently selected from the examples of the substituent usable as R¹ to R⁸.

In the formula (16), R¹⁷¹, R¹⁷², and R¹⁷⁴ to R¹⁸⁰ are each independently a hydrogen atom or a substituent. R¹⁷¹, R¹⁷², and R¹⁷⁴ to R¹⁸⁰ each in a form of the substituent are each independently selected from the examples of the substituent usable as R¹ to R⁸.

The first compound is also preferably represented by a formula (20) or (21) below.

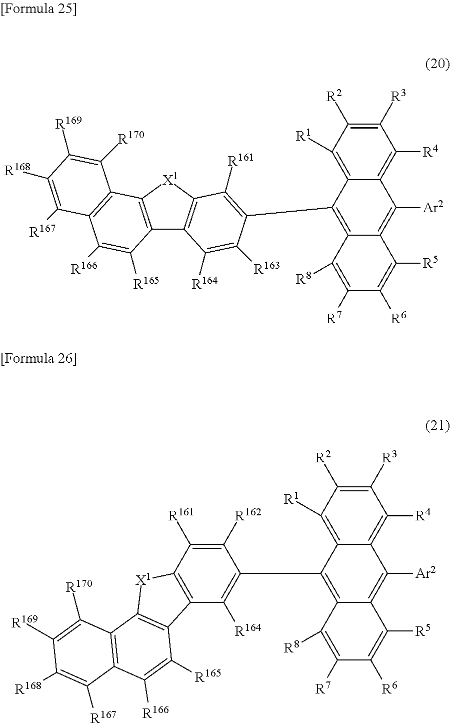

In the formulae (20) and (21), R¹ to R⁸ and X¹ respectively represent the same as R¹ to R⁸ and X¹ in the formula (1) or (2).

Ar² is a substituted or unsubstituted aromatic hydrocarbon group having 6 to 30 ring carbon atoms or a substituted or unsubstituted heterocyclic group having 5 to 30 ring atoms.

In the formula (20), R¹⁶¹ and R¹⁶³ to R¹⁷⁰ are each independently a hydrogen atom or a substituent. R¹⁶¹ and R¹⁶³ to R¹⁷⁰ each in a form of the substituent are each independently selected from the examples of the substituent usable as R¹ to R⁸.

In the formula (21), R¹⁶¹, R¹⁶² and R¹⁶⁴ to R¹⁷⁰ are each independently a hydrogen atom or a substituent. R¹⁶¹, R¹⁶², and R¹⁶⁴ to R¹⁷⁰ each in a form of the substituent are each independently selected from the examples of the substituent usable as R¹ to R⁸.

The first compound is also preferably represented by a formula (25) or (26) below.

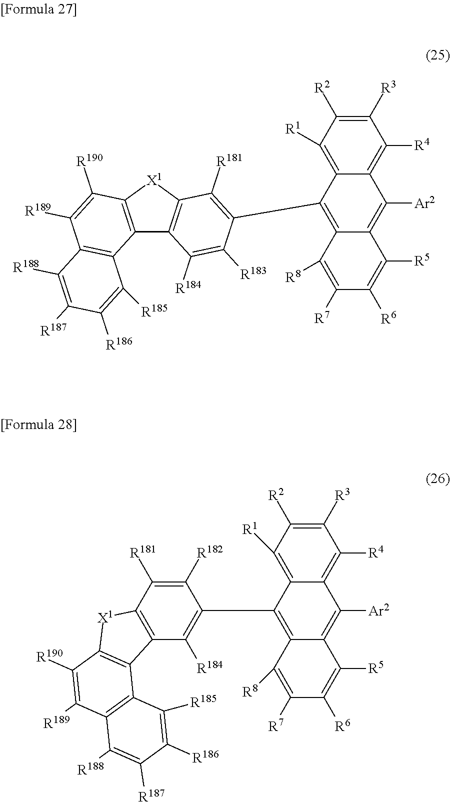

In the formulae (25) and (26), R¹ to R⁸ and X¹ respectively represent the same as R¹ to R⁸ and X¹ in the formula (1) or (2).

Ar² is a substituted or unsubstituted aromatic hydrocarbon group having 6 to 30 ring carbon atoms or a substituted or unsubstituted heterocyclic group having 5 to 30 ring atoms.

In the formula (25), R¹⁸¹ and R¹⁸³ to R¹⁹⁰ are each independently a hydrogen atom or a substituent. R¹⁸¹ and R¹⁸³ to R¹⁹⁰ each in a form of the substituent are each independently selected from the examples of the substituent usable as R¹ to R⁸.

In the formula (26), R¹⁸¹, R¹⁸², and R¹⁸⁴ to R¹⁹⁰ are each independently a hydrogen atom or a substituent. R¹⁸¹, R¹⁸², and R¹⁸⁴ to R¹⁹⁰ each in a form of the substituent are each independently selected from the examples of the substituent usable as R¹ to R⁸.

Ar² is preferably a substituted or unsubstituted aromatic hydrocarbon group having 6 to 20 ring carbon atoms, more preferably a substituted or unsubstituted aromatic hydrocarbon group having 6 to 14 ring carbon atoms, further preferably a substituted or unsubstituted aromatic hydrocarbon group having 6 to 12 ring carbon atoms.

Ar² is also preferably a substituent selected from the group consisting of a substituted or unsubstituted phenyl group, substituted or unsubstituted naphthyl group, substituted or unsubstituted phenanthryl group, substituted or unsubstituted benzanthryl group, substituted or unsubstituted 9,9-dimethylfluorenyl group, and substituted or unsubstituted dibenzofuranyl group.

A substituent as a “substituted or unsubstituted” group usable as Ar² is preferably a group selected from the group consisting of an aromatic hydrocarbon group, alkyl group, halogen atom, alkylsilyl group, arylsilyl group, and cyano group, more preferably a group selected from the group consisting of an aromatic hydrocarbon group and an alkyl group. Ar² is also preferably unsubstituted.

R¹⁰ and Ar² each are also preferably a group selected from the group consisting of groups represented by formulae (11a) to (11k), (11m), (11n) and (11p) below, more preferably a group represented by the formula (11f) below. In the formulae (11a) to (11k), (11m), (11n) and (11p), * represents a bonding position at a position 9 or a position 10 of an anthracene ring.

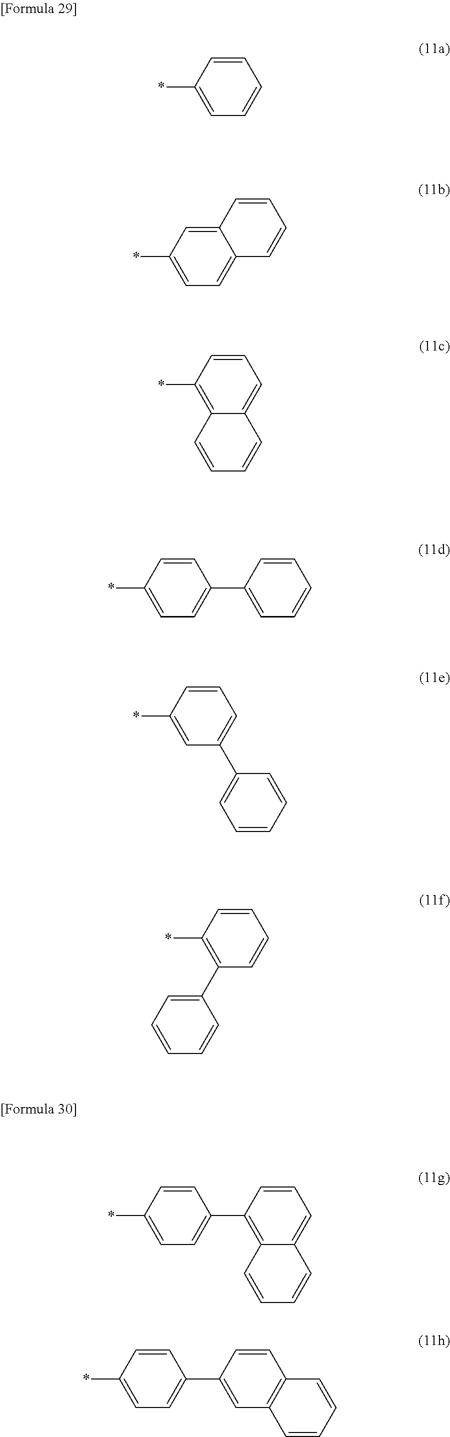

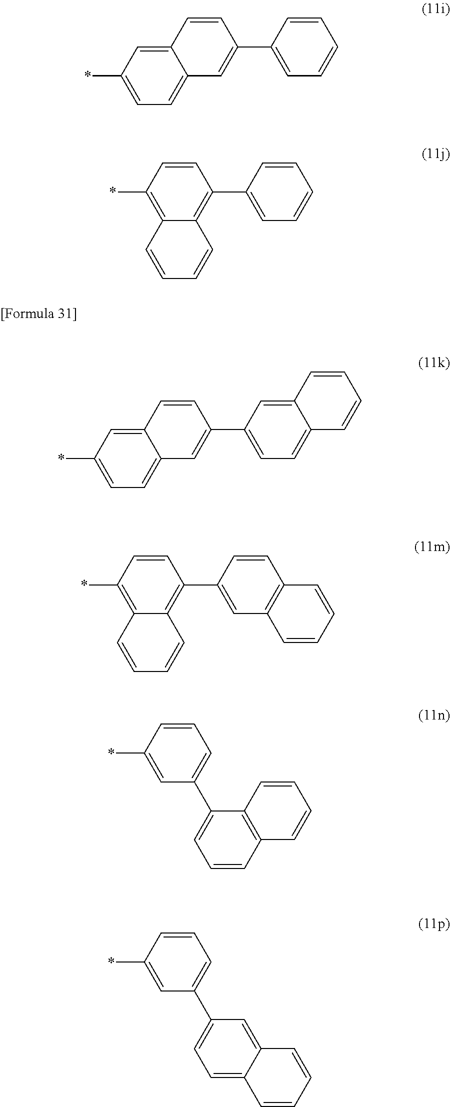 [SMILES: *c1ccc2cc(-c3ccccc3)ccc2c1 ; *c1ccc(-c2ccccc2)c2ccccc12 ; *c1ccc2cc(-c3ccc4ccccc4c3)ccc2c1 ; *c1ccc(-c2ccc3ccccc3c2)c2ccccc12 ; *c1cccc(-c2cccc3ccccc23)c1 ; *c1cccc(-c2ccc3ccccc3c2)c1]

R¹ to R⁸ are each preferably a hydrogen atom or an alkyl group having 1 to 30 carbon atoms, more preferably a hydrogen atom.

R¹⁷¹ to R¹⁸⁰, except for one being a single bond bonded to L¹, are each preferably a hydrogen atom or an alkyl group having 1 to 30 carbon atoms, more preferably a hydrogen atom.

R¹⁶¹ to R¹⁷⁰, except for one being a single bond bonded to L¹, are each preferably a hydrogen atom or an alkyl group having 1 to 30 carbon atoms, more preferably a hydrogen atom.

R¹⁸¹ to R¹⁹⁰, except for one being a single bond bonded to L¹, are each preferably a hydrogen atom or an alkyl group having 1 to 30 carbon atoms, more preferably a hydrogen atom.

In the first compound in which X¹ is an oxygen atom or a sulfur atom, it is believed that, since a naphthobenzofuran or a naphthobenzothiophene skeleton is bonded at a predetermined position (i.e., position 9 or position 10) of an anthracene skeleton, molecules are planarly expanded as compared with an anthracene substituted by an aryl group at this position (i.e., position 9 or position 10), so that intermolecular packing is improved to improve an injecting performance and a transporting performance of electrons and holes, particularly the transporting performance of the holes. Accordingly, it is expected that the organic EL device with the first compound requires a low drive voltage. Moreover, it is expected that, since the first compound allows the transporting performance of the holes to be improved as described above to avoid a state where excessive electrons are present in the emitting layer, the electrons and the holes in the emitting layer become well-balanced to improve the luminous efficiency.

In the formulae (12) to (26), X¹ is preferably an oxygen atom.

Examples of the first compound are given below. It should be noted that the first compound of the invention is not limited to the examples.

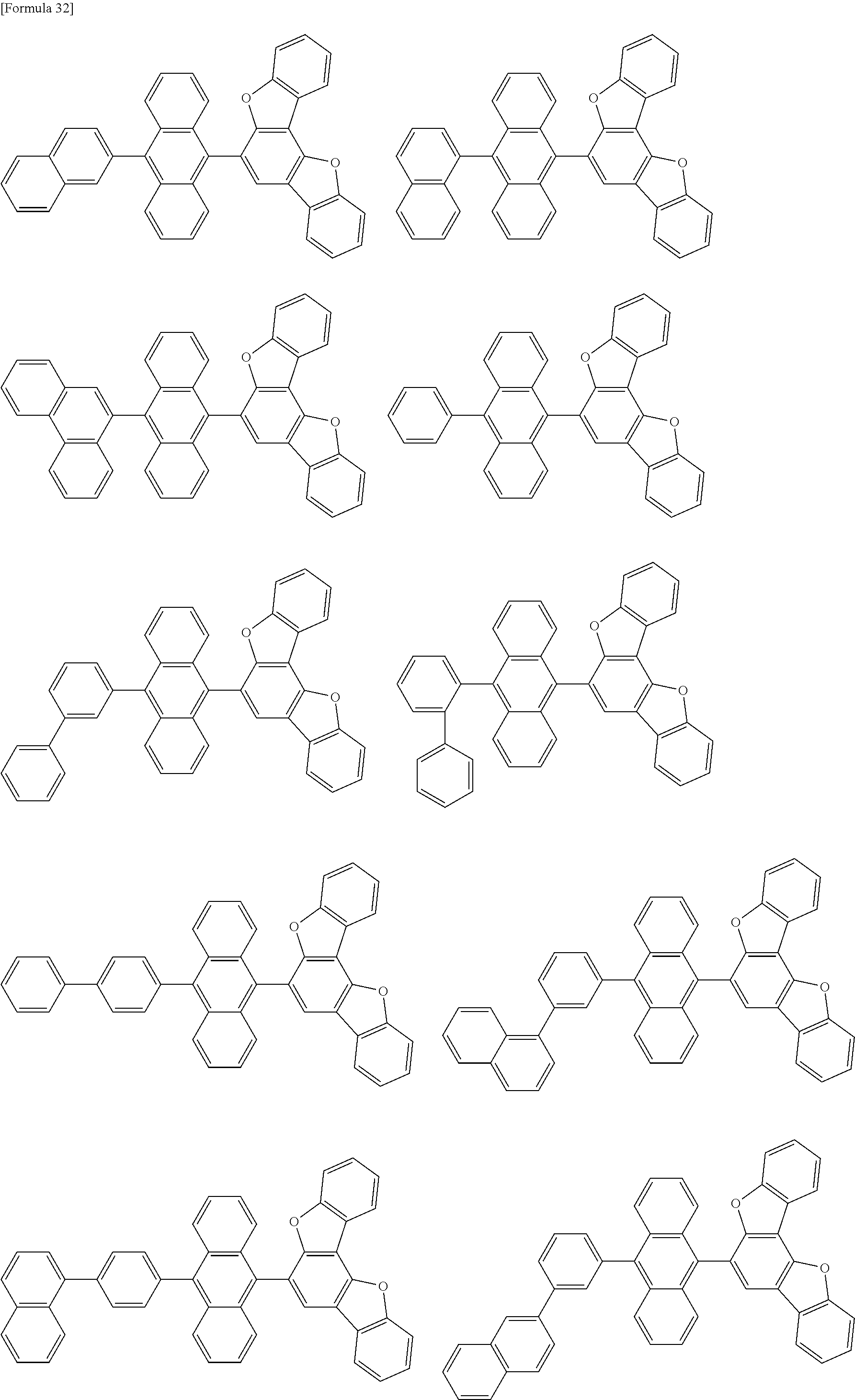

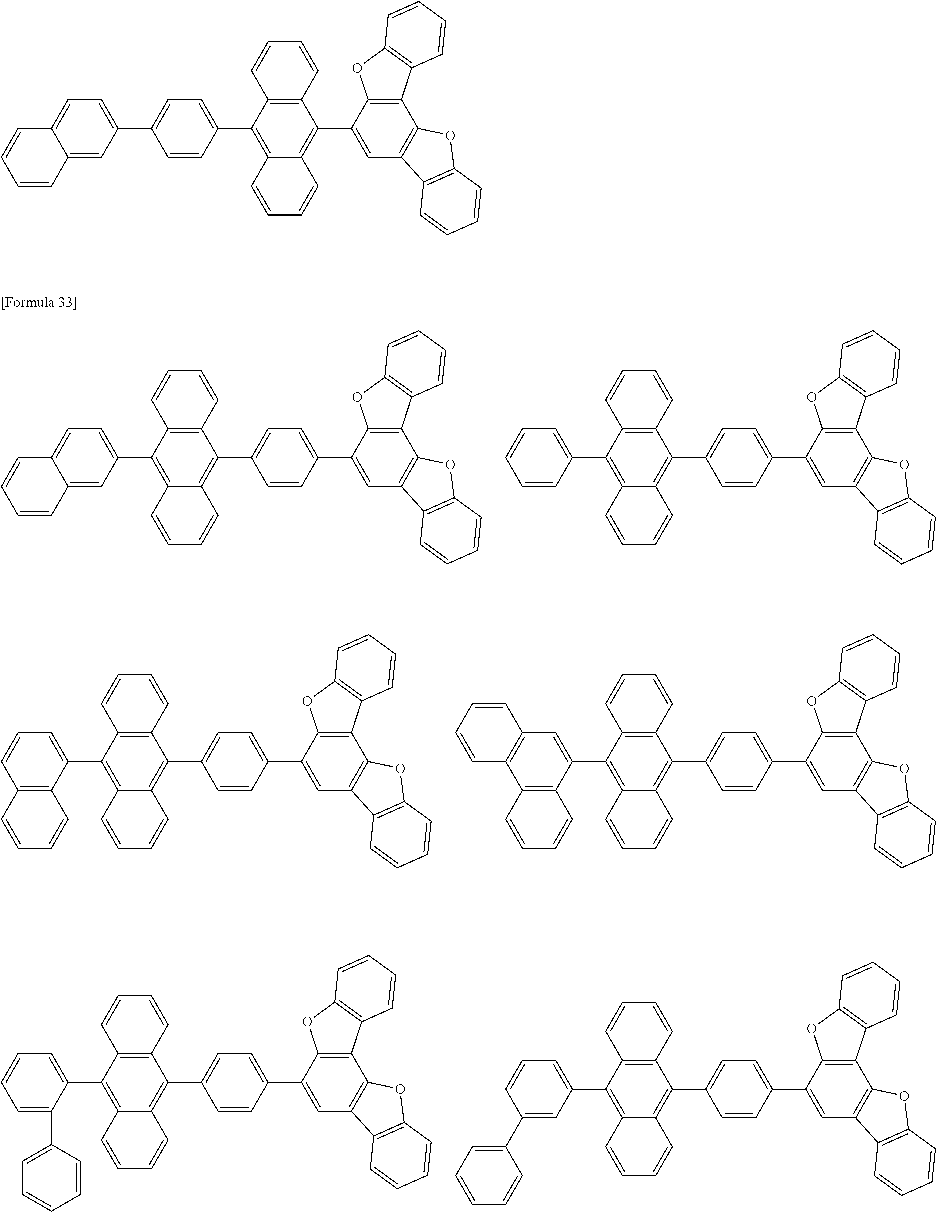

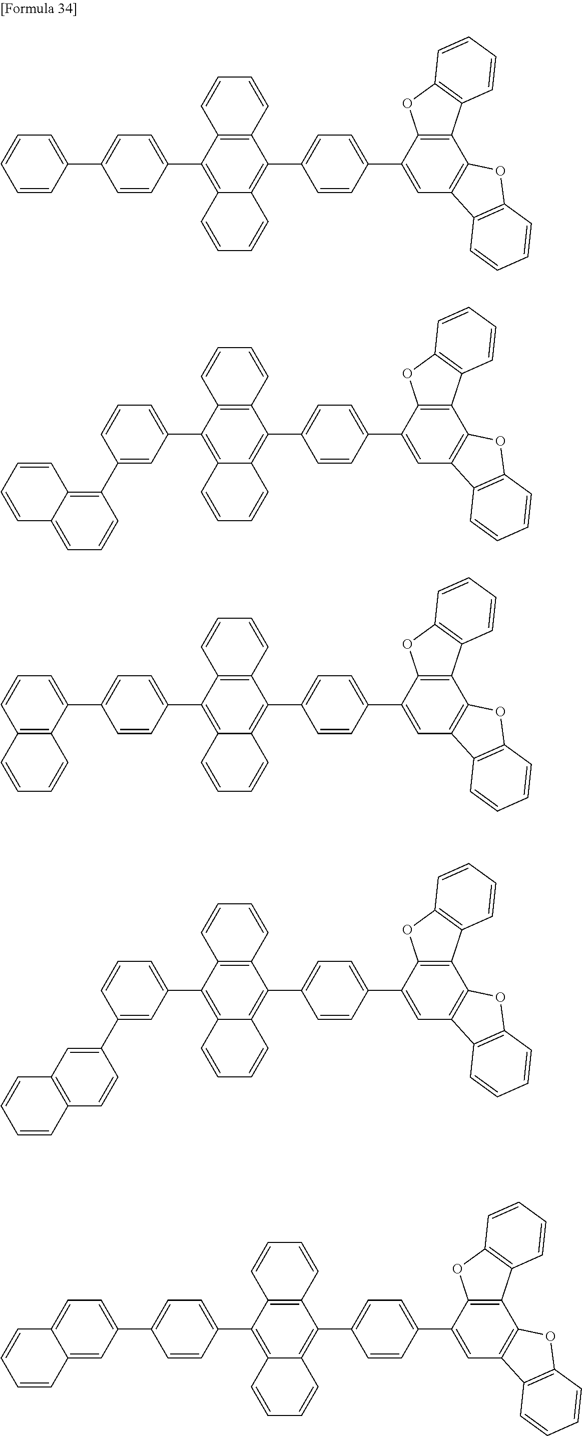 [SMILES: c1ccc(-c2ccc(-c3c4ccccc4c(-c4ccc(-c5cc6c7ccccc7oc6c6c5oc5ccccc56)cc4)c4ccccc34)cc2)cc1 ; c1cc(-c2cccc3ccccc23)cc(-c2c3ccccc3c(-c3ccc(-c4cc5c6ccccc6oc5c5c4oc4ccccc45)cc3)c3ccccc23)c1 ; c1ccc2c(-c3ccc(-c4c5ccccc5c(-c5ccc(-c6cc7c8ccccc8oc7c7c6oc6ccccc67)cc5)c5ccccc45)cc3)cccc2c1 ; c1cc(-c2ccc3ccccc3c2)cc(-c2c3ccccc3c(-c3ccc(-c4cc5c6ccccc6oc5c5c4oc4ccccc45)cc3)c3ccccc23)c1 ; c1ccc2cc(-c3ccc(-c4c5ccccc5c(-c5ccc(-c6cc7c8ccccc8oc7c7c6oc6ccccc67)cc5)c5ccccc45)cc3)ccc2c1]

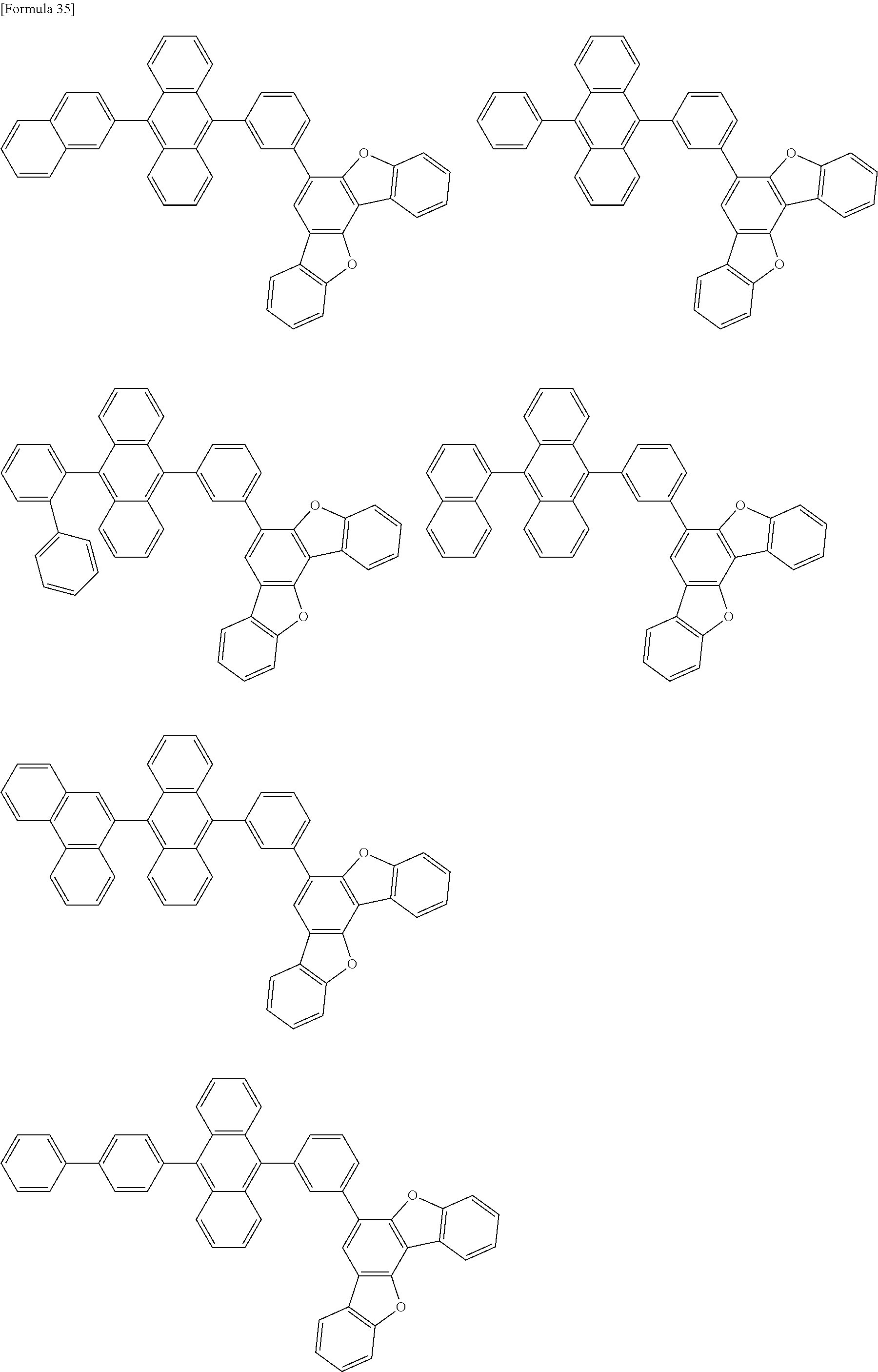

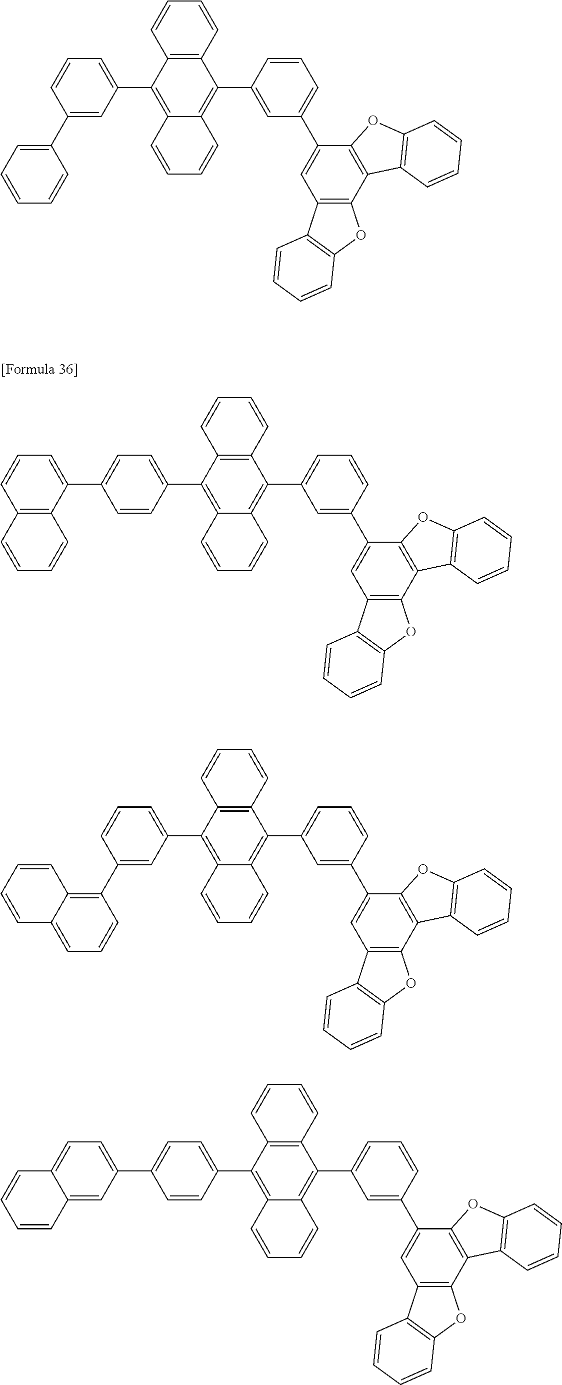 [SMILES: c1ccc(-c2cccc(-c3c4ccccc4c(-c4cccc(-c5cc6c7ccccc7oc6c6c5oc5ccccc56)c4)c4ccccc34)c2)cc1 ; c1cc(-c2c3ccccc3c(-c3ccc(-c4cccc5ccccc45)cc3)c3ccccc23)cc(-c2cc3c4ccccc4oc3c3c2oc2ccccc23)c1 ; c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2c3ccccc3c(-c3ccc(-c4ccc5ccccc5c4)cc3)c3ccccc23)cc(-c2cc3c4ccccc4oc3c3c2oc2ccccc23)c1]

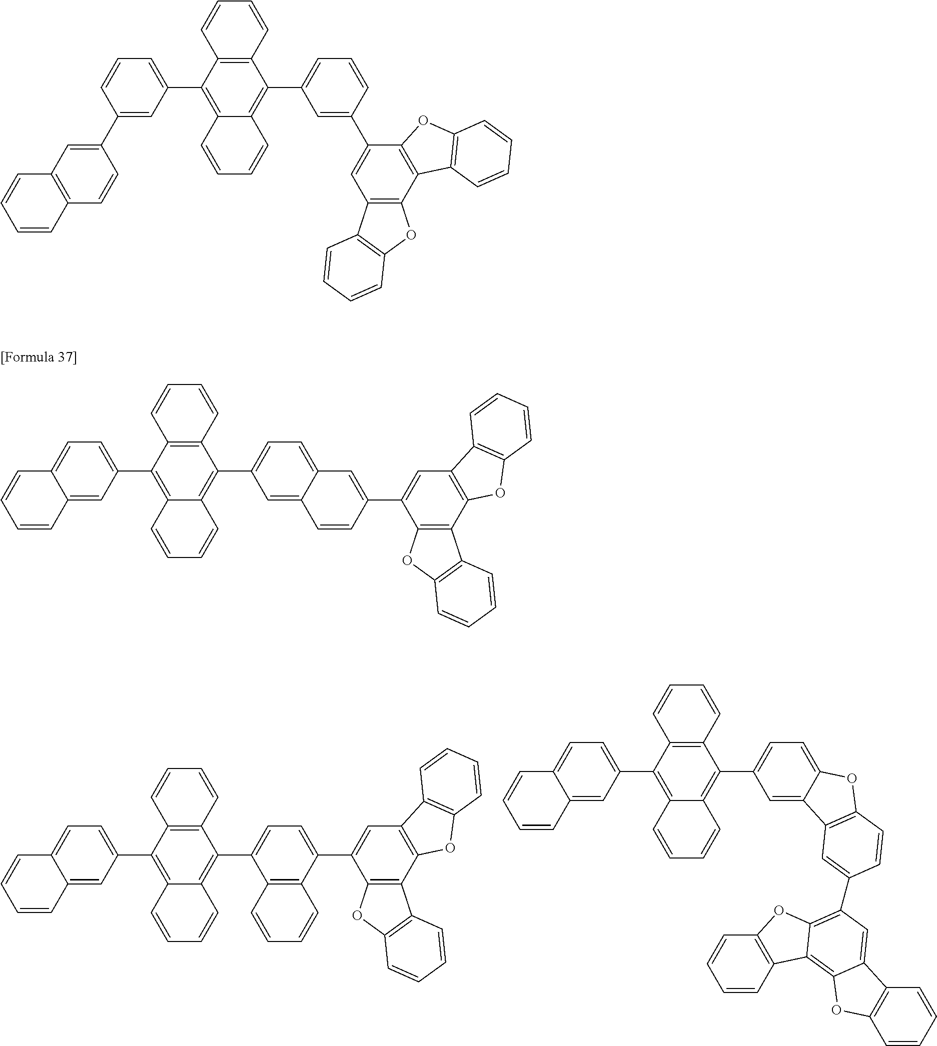

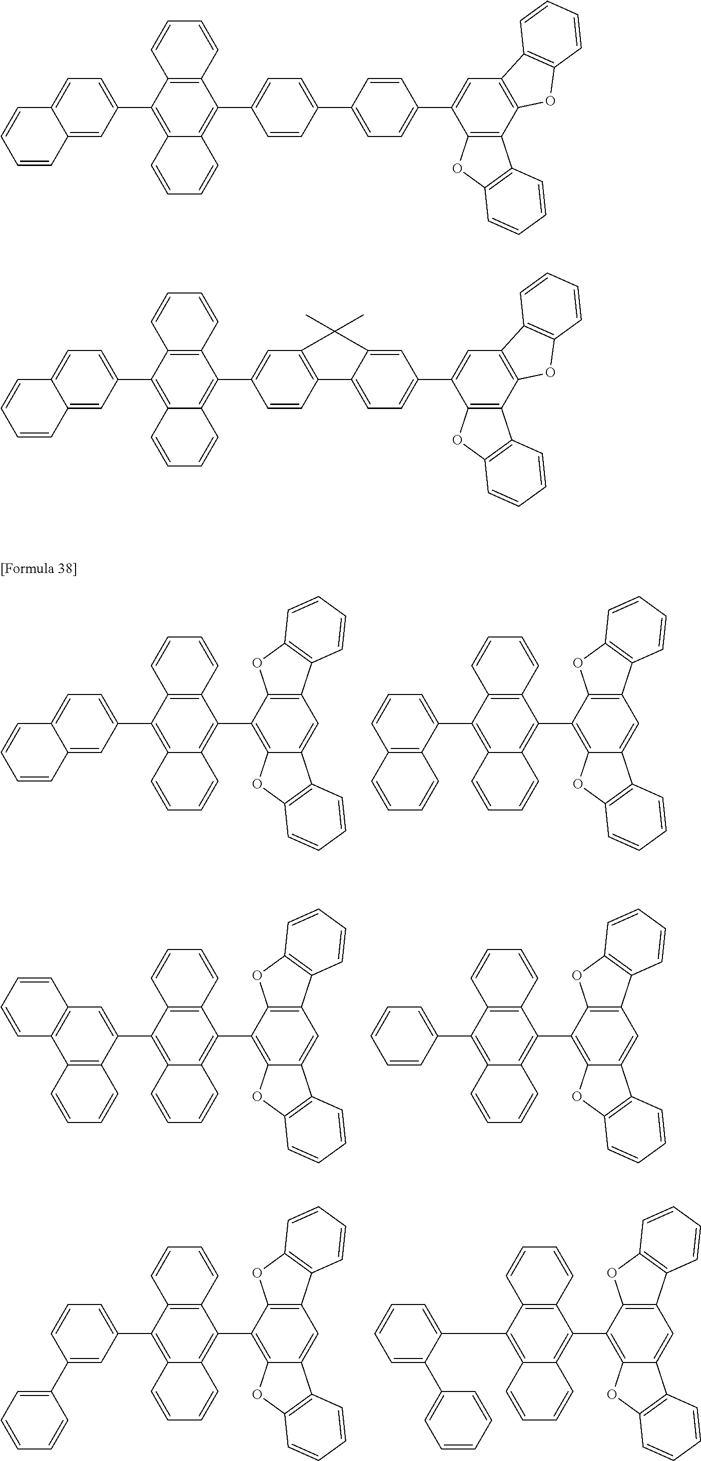

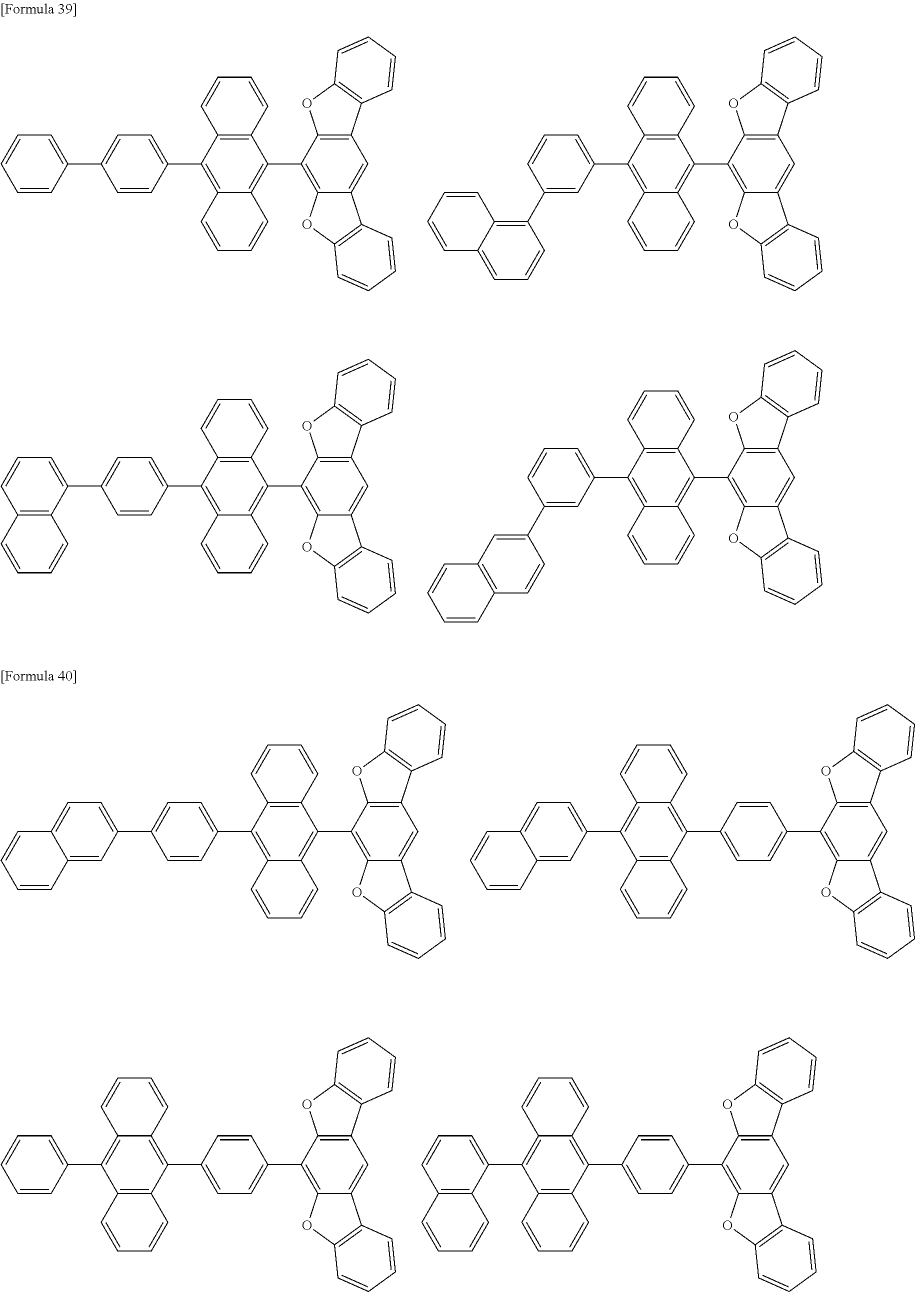

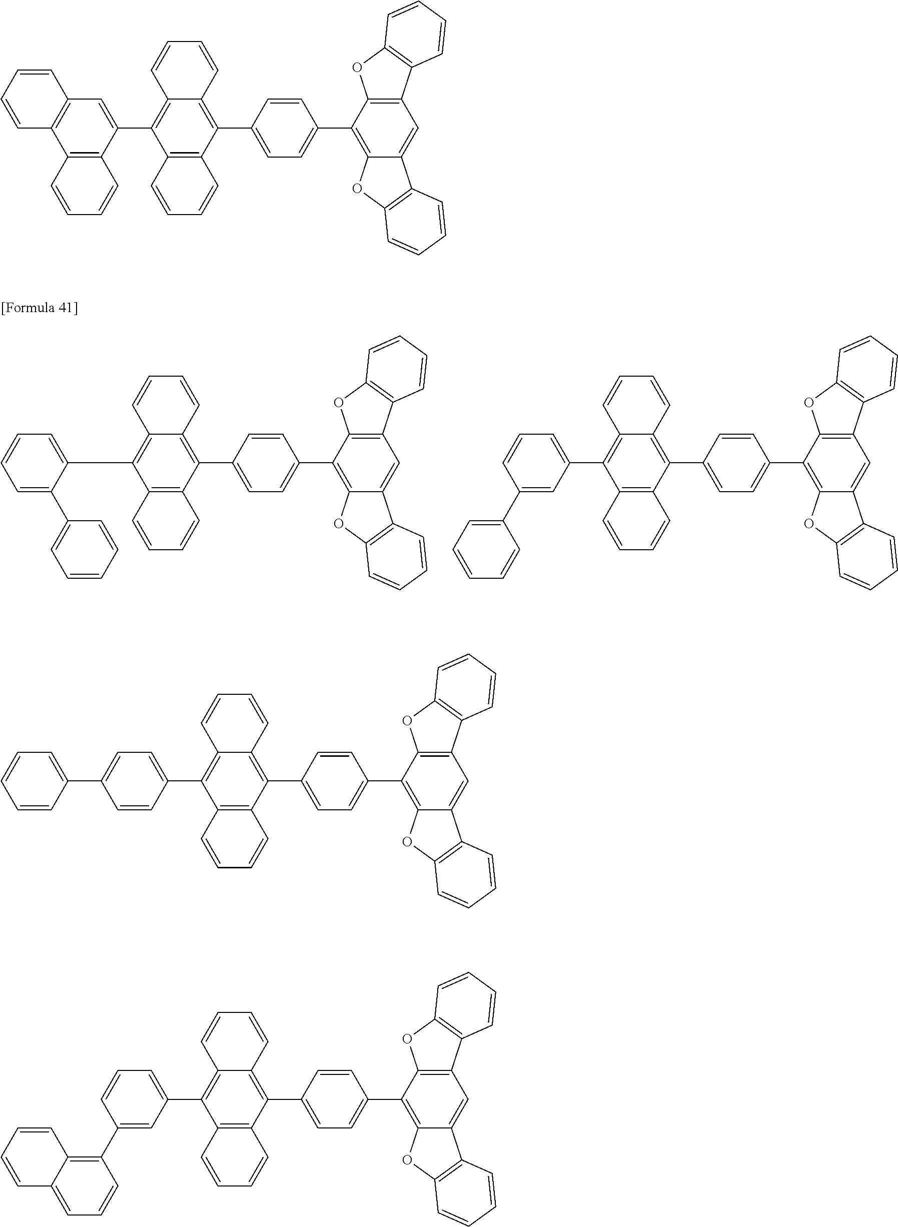

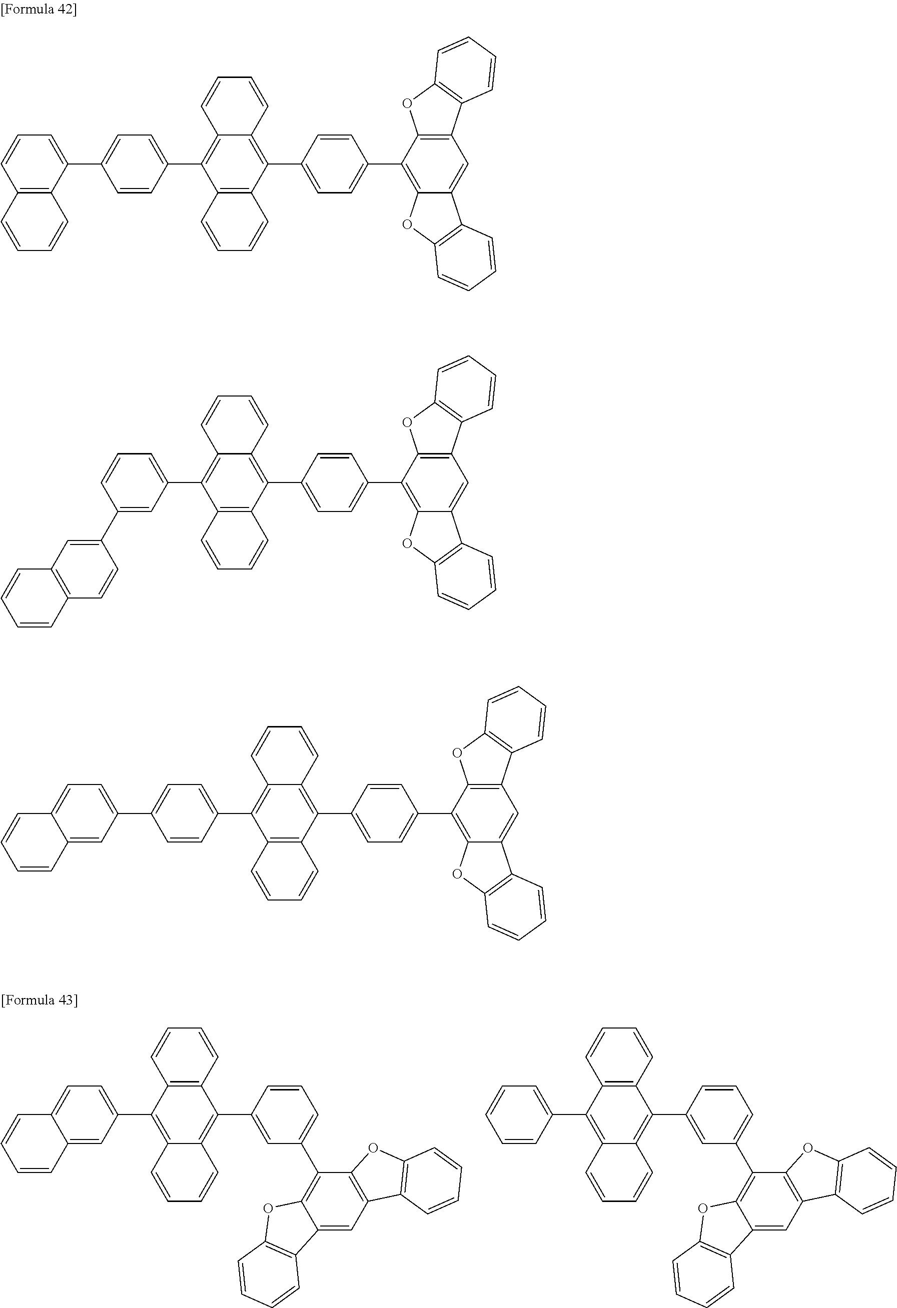 [SMILES: c1ccc2c(-c3ccc(-c4c5ccccc5c(-c5ccc(-c6c7oc8ccccc8c7cc7c6oc6ccccc67)cc5)c5ccccc45)cc3)cccc2c1 ; c1cc(-c2ccc3ccccc3c2)cc(-c2c3ccccc3c(-c3ccc(-c4c5oc6ccccc6c5cc5c4oc4ccccc45)cc3)c3ccccc23)c1 ; c1ccc2cc(-c3ccc(-c4c5ccccc5c(-c5ccc(-c6c7oc8ccccc8c7cc7c6oc6ccccc67)cc5)c5ccccc45)cc3)ccc2c1 ; c1cc(-c2c3ccccc3c(-c3ccc4ccccc4c3)c3ccccc23)cc(-c2c3oc4ccccc4c3cc3c2oc2ccccc23)c1 ; c1ccc(-c2c3ccccc3c(-c3cccc(-c4c5oc6ccccc6c5cc5c4oc4ccccc45)c3)c3ccccc23)cc1]

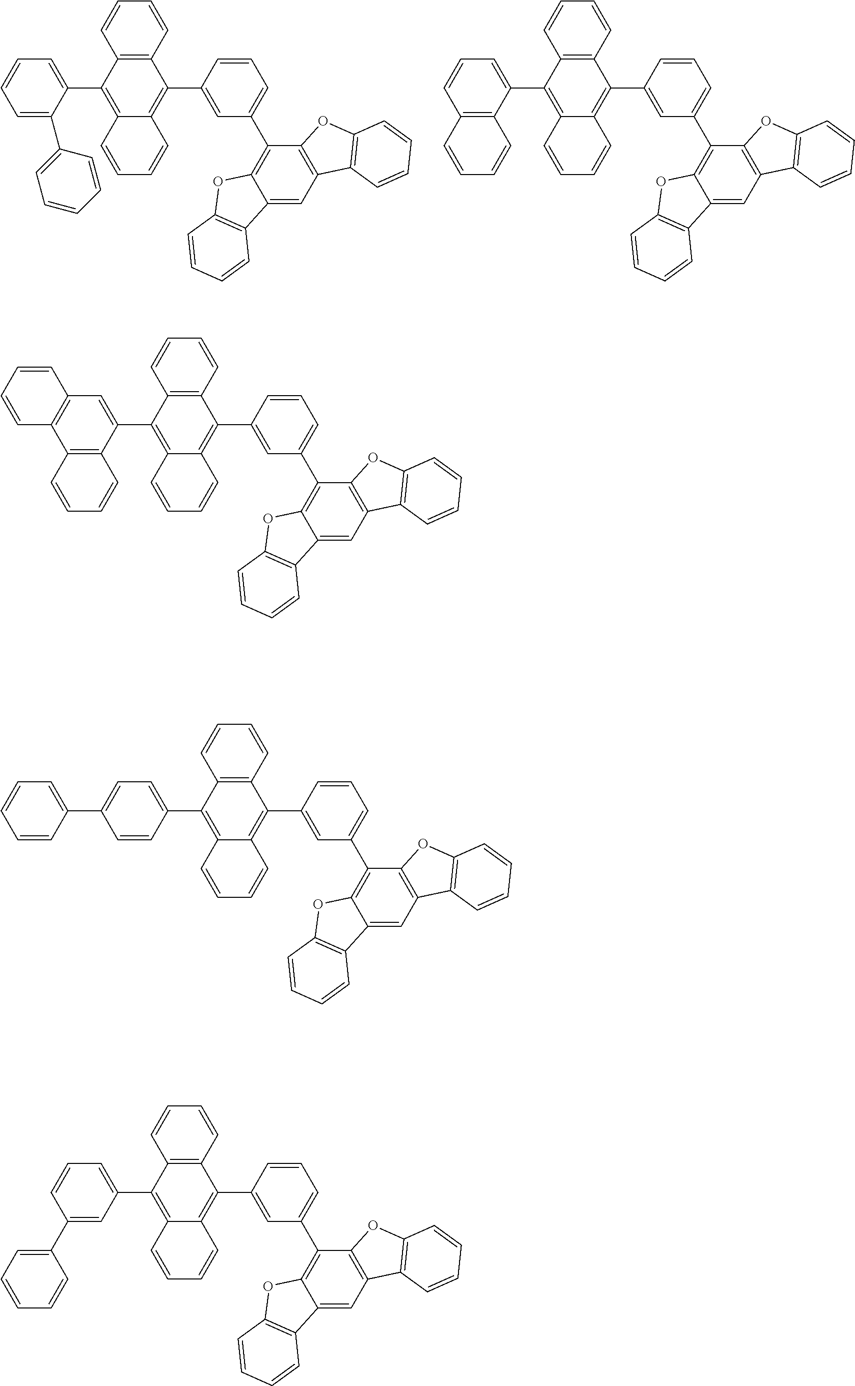

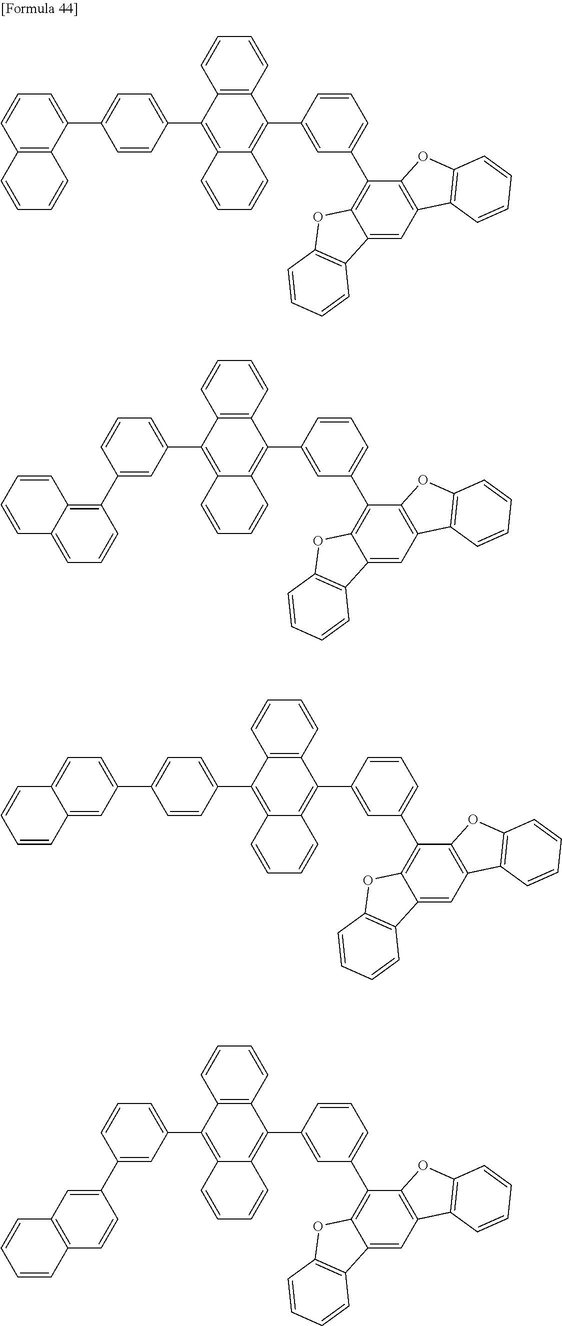 [SMILES: c1cc(-c2c3ccccc3c(-c3ccc(-c4cccc5ccccc45)cc3)c3ccccc23)cc(-c2c3oc4ccccc4c3cc3c2oc2ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2c3ccccc3c(-c3ccc(-c4ccc5ccccc5c4)cc3)c3ccccc23)cc(-c2c3oc4ccccc4c3cc3c2oc2ccccc23)c1 ; c1cc(-c2ccc3ccccc3c2)cc(-c2c3ccccc3c(-c3cccc(-c4c5oc6ccccc6c5cc5c4oc4ccccc45)c3)c3ccccc23)c1]

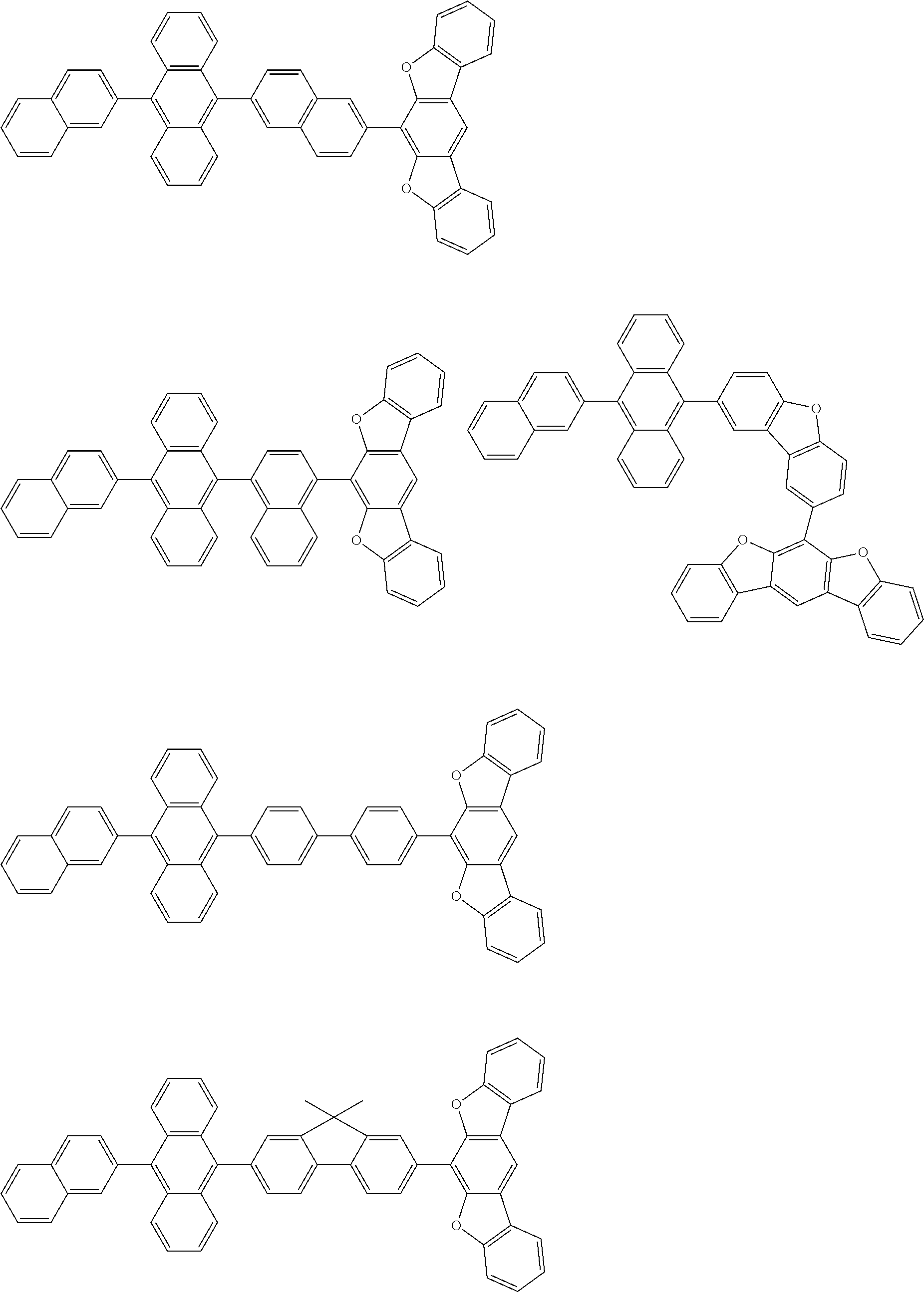

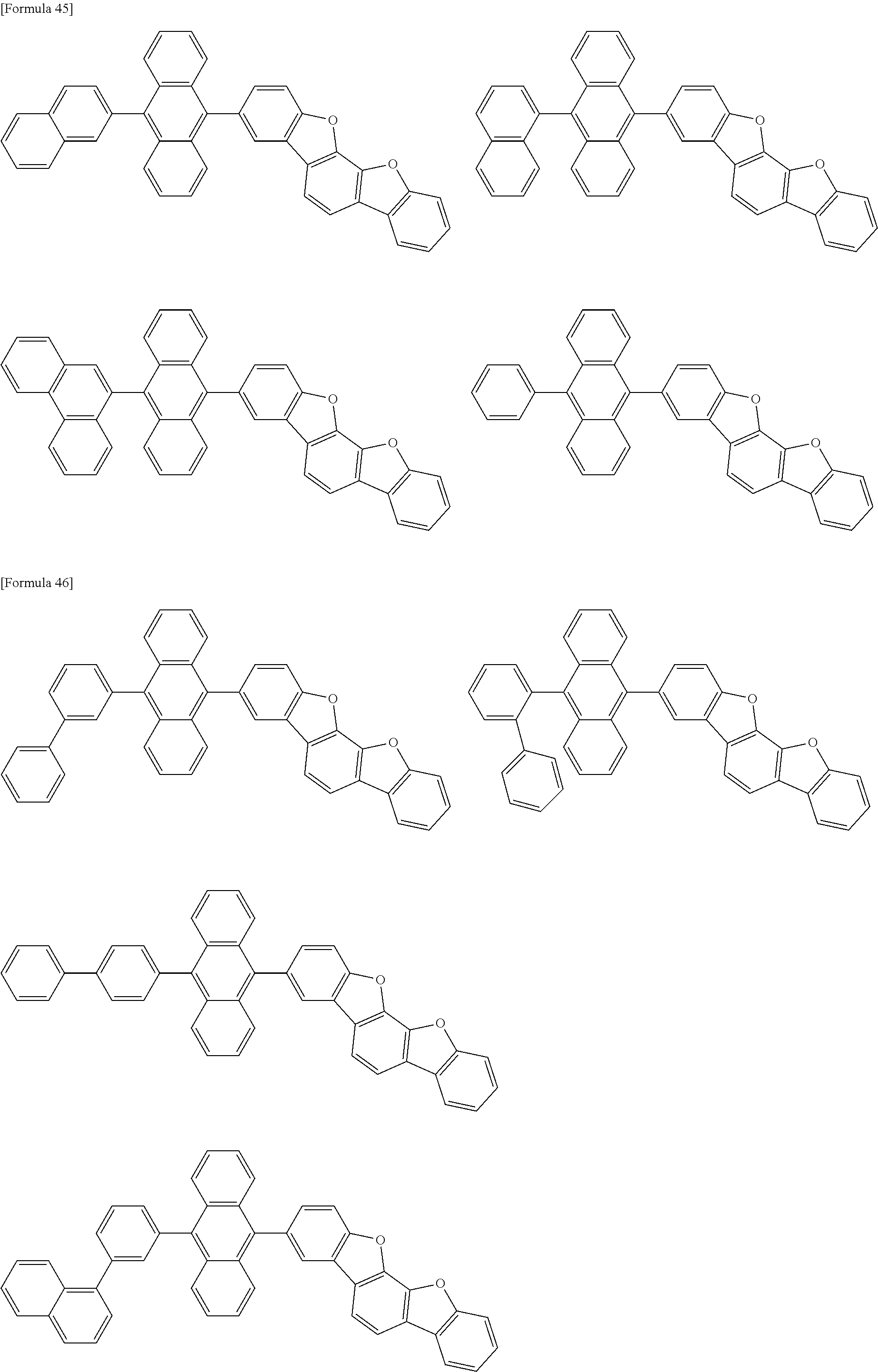

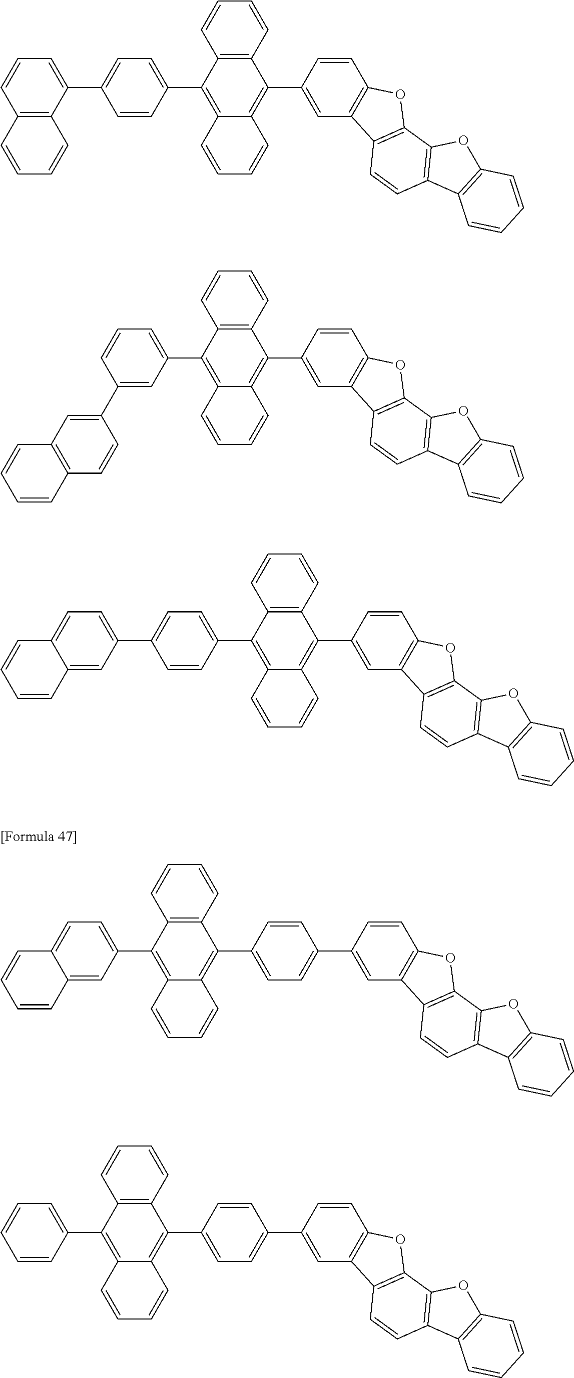 [SMILES: c1ccc2c(-c3ccc(-c4c5ccccc5c(-c5ccc6oc7c(ccc8c9ccccc9oc87)c6c5)c5ccccc45)cc3)cccc2c1 ; c1cc(-c2ccc3ccccc3c2)cc(-c2c3ccccc3c(-c3ccc4oc5c(ccc6c7ccccc7oc65)c4c3)c3ccccc23)c1 ; c1ccc2cc(-c3ccc(-c4c5ccccc5c(-c5ccc6oc7c(ccc8c9ccccc9oc87)c6c5)c5ccccc45)cc3)ccc2c1 ; c1ccc2cc(-c3c4ccccc4c(-c4ccc(-c5ccc6oc7c(ccc8c9ccccc9oc87)c6c5)cc4)c4ccccc34)ccc2c1 ; c1ccc(-c2c3ccccc3c(-c3ccc(-c4ccc5oc6c(ccc7c8ccccc8oc76)c5c4)cc3)c3ccccc23)cc1]

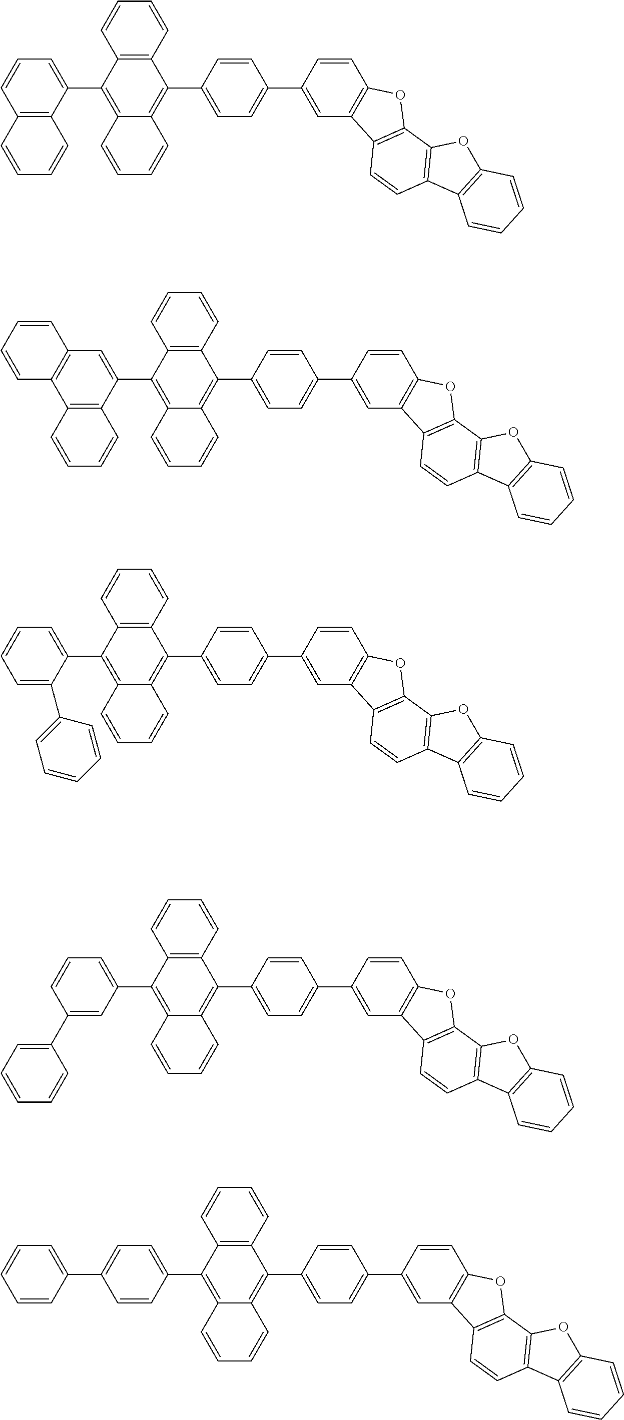 [SMILES: c1ccc2c(-c3c4ccccc4c(-c4ccc(-c5ccc6oc7c(ccc8c9ccccc9oc87)c6c5)cc4)c4ccccc34)cccc2c1 ; c1ccc2c(c1)cc(-c1c3ccccc3c(-c3ccc(-c4ccc5oc6c(ccc7c8ccccc8oc76)c5c4)cc3)c3ccccc13)c1ccccc12 ; c1ccc(-c2ccccc2-c2c3ccccc3c(-c3ccc(-c4ccc5oc6c(ccc7c8ccccc8oc76)c5c4)cc3)c3ccccc23)cc1 ; c1ccc(-c2cccc(-c3c4ccccc4c(-c4ccc(-c5ccc6oc7c(ccc8c9ccccc9oc87)c6c5)cc4)c4ccccc34)c2)cc1 ; c1ccc(-c2ccc(-c3c4ccccc4c(-c4ccc(-c5ccc6oc7c(ccc8c9ccccc9oc87)c6c5)cc4)c4ccccc34)cc2)cc1]

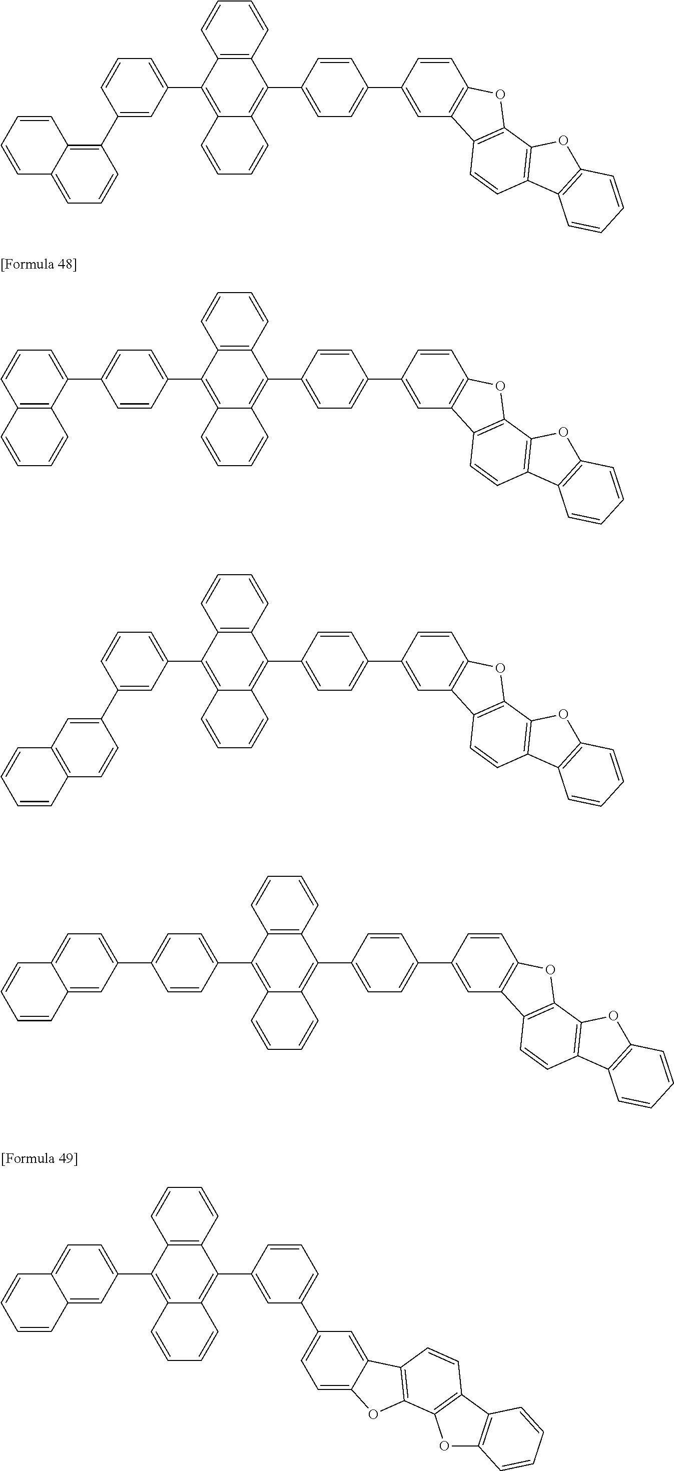 [SMILES: c1cc(-c2cccc3ccccc23)cc(-c2c3ccccc3c(-c3ccc(-c4ccc5oc6c(ccc7c8ccccc8oc76)c5c4)cc3)c3ccccc23)c1 ; c1ccc2c(-c3ccc(-c4c5ccccc5c(-c5ccc(-c6ccc7oc8c(ccc9c%10ccccc%10oc98)c7c6)cc5)c5ccccc45)cc3)cccc2c1 ; c1cc(-c2ccc3ccccc3c2)cc(-c2c3ccccc3c(-c3ccc(-c4ccc5oc6c(ccc7c8ccccc8oc76)c5c4)cc3)c3ccccc23)c1 ; c1ccc2cc(-c3ccc(-c4c5ccccc5c(-c5ccc(-c6ccc7oc8c(ccc9c%10ccccc%10oc98)c7c6)cc5)c5ccccc45)cc3)ccc2c1 ; c1cc(-c2ccc3oc4c(ccc5c6ccccc6oc54)c3c2)cc(-c2c3ccccc3c(-c3ccc4ccccc4c3)c3ccccc23)c1]

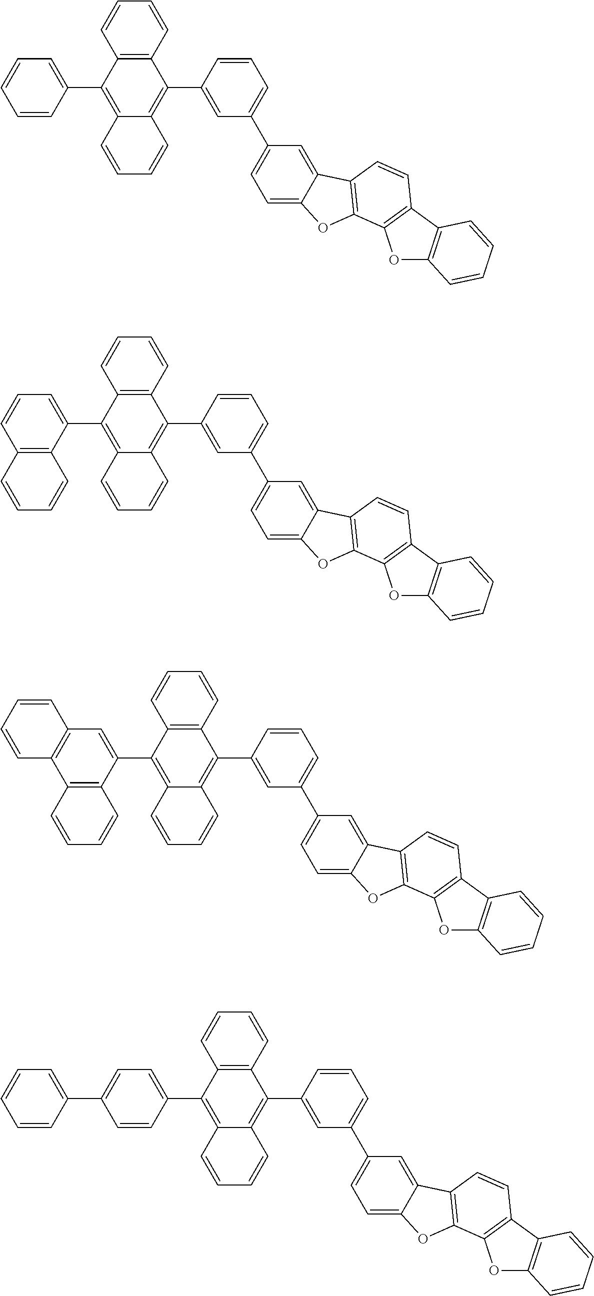 [SMILES: c1ccc(-c2c3ccccc3c(-c3cccc(-c4ccc5oc6c(ccc7c8ccccc8oc76)c5c4)c3)c3ccccc23)cc1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3oc4c(ccc5c6ccccc6oc54)c3c2)cc(-c2c3ccccc3c(-c3cc4ccccc4c4ccccc34)c3ccccc23)c1 ; c1ccc(-c2ccc(-c3c4ccccc4c(-c4cccc(-c5ccc6oc7c(ccc8c9ccccc9oc87)c6c5)c4)c4ccccc34)cc2)cc1]

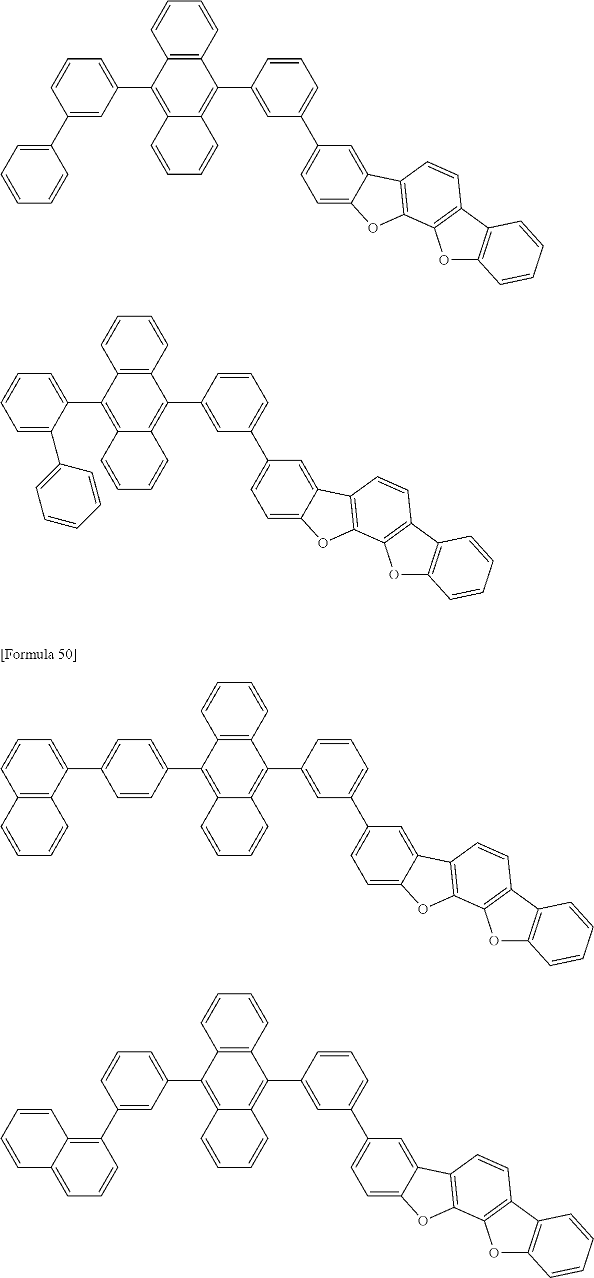 [SMILES: c1ccc(-c2cccc(-c3c4ccccc4c(-c4cccc(-c5ccc6oc7c(ccc8c9ccccc9oc87)c6c5)c4)c4ccccc34)c2)cc1 ; c1ccc(-c2ccccc2-c2c3ccccc3c(-c3cccc(-c4ccc5oc6c(ccc7c8ccccc8oc76)c5c4)c3)c3ccccc23)cc1 ; c1cc(-c2ccc3oc4c(ccc5c6ccccc6oc54)c3c2)cc(-c2c3ccccc3c(-c3ccc(-c4cccc5ccccc45)cc3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1]

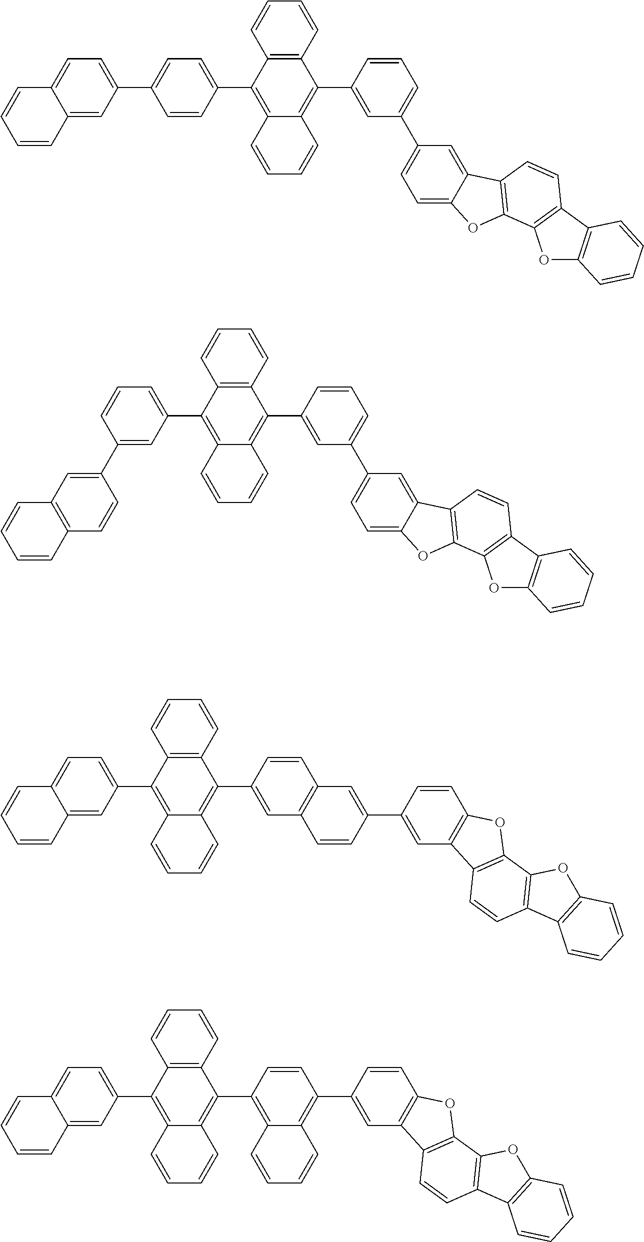 [SMILES: c1cc(-c2ccc3oc4c(ccc5c6ccccc6oc54)c3c2)cc(-c2c3ccccc3c(-c3ccc(-c4ccc5ccccc5c4)cc3)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1ccc2cc(-c3c4ccccc4c(-c4ccc5cc(-c6ccc7oc8c(ccc9c%10ccccc%10oc98)c7c6)ccc5c4)c4ccccc34)ccc2c1 ; c1ccc2cc(-c3c4ccccc4c(-c4ccc(-c5ccc6oc7c(ccc8c9ccccc9oc87)c6c5)c5ccccc45)c4ccccc34)ccc2c1]

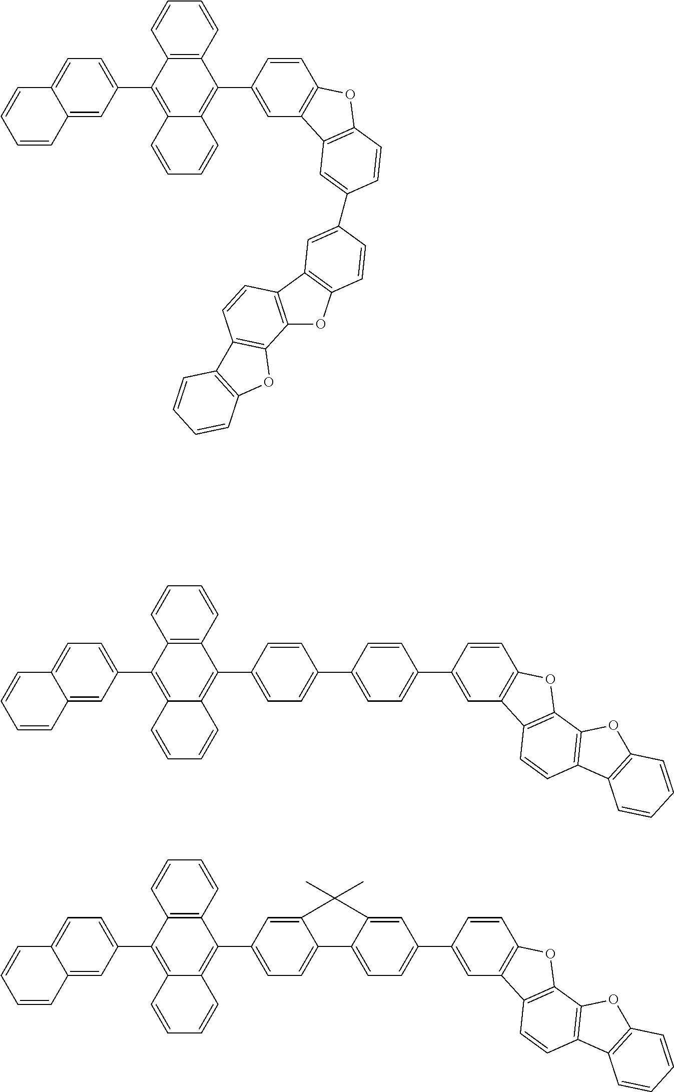 [SMILES: c1ccc2cc(-c3c4ccccc4c(-c4ccc5oc6ccc(-c7ccc8oc9c(ccc%10c%11ccccc%11oc%109)c8c7)cc6c5c4)c4ccccc34)ccc2c1 ; c1ccc2cc(-c3c4ccccc4c(-c4ccc(-c5ccc(-c6ccc7oc8c(ccc9c%10ccccc%10oc98)c7c6)cc5)cc4)c4ccccc34)ccc2c1 ; CC1(C)c2cc(-c3ccc4oc5c(ccc6c7ccccc7oc65)c4c3)ccc2-c2ccc(-c3c4ccccc4c(-c4ccc5ccccc5c4)c4ccccc34)cc21]

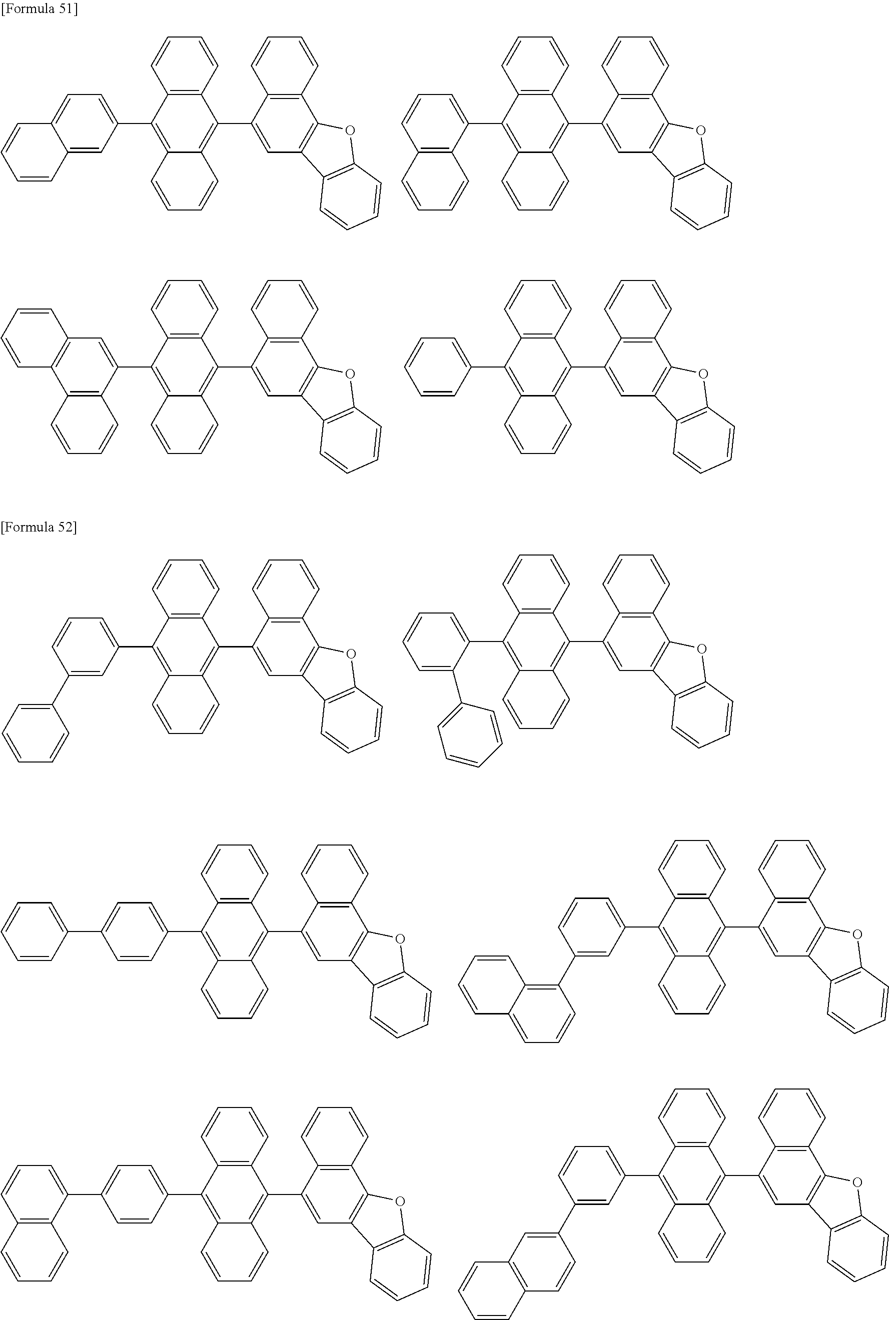

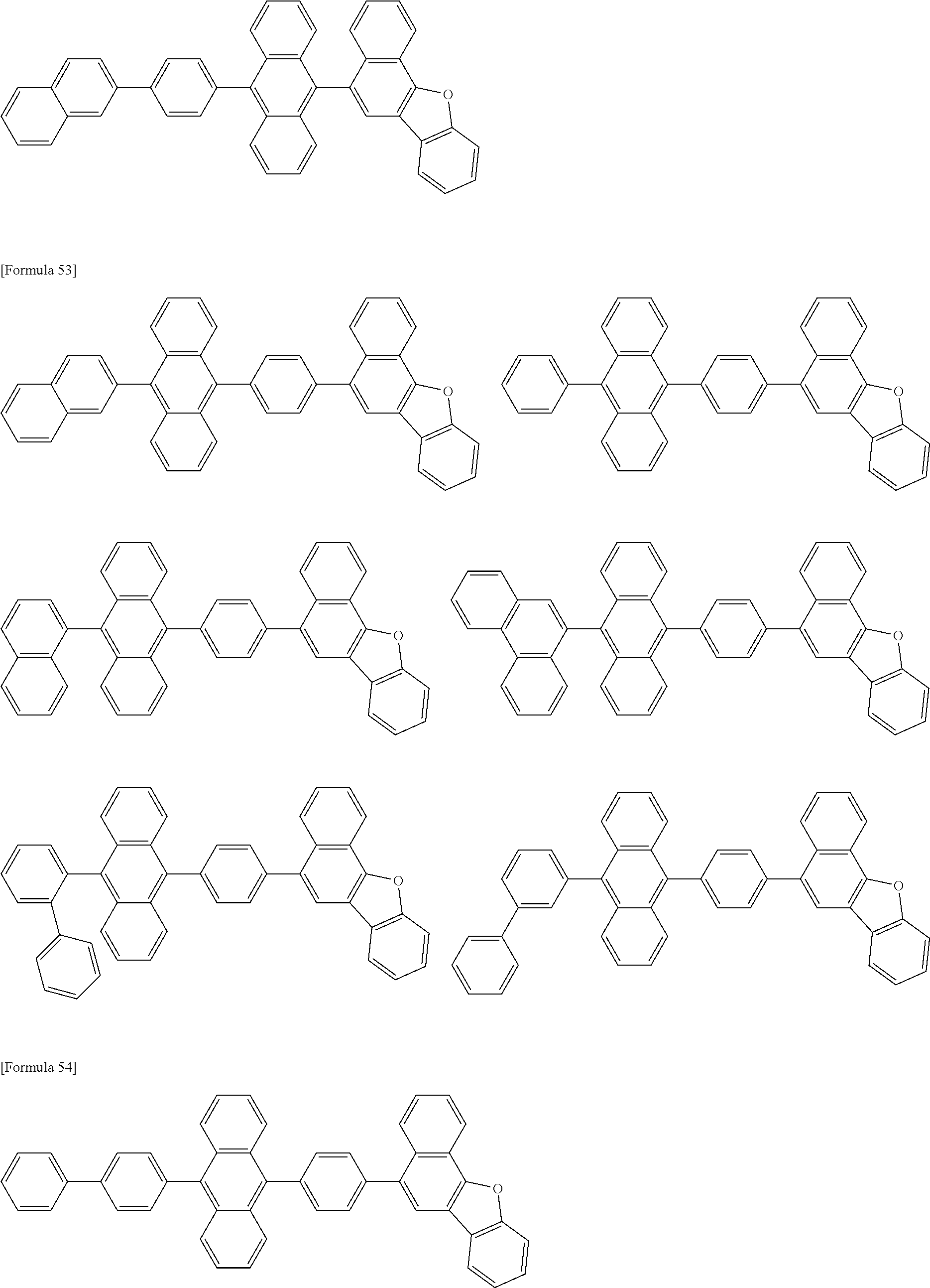

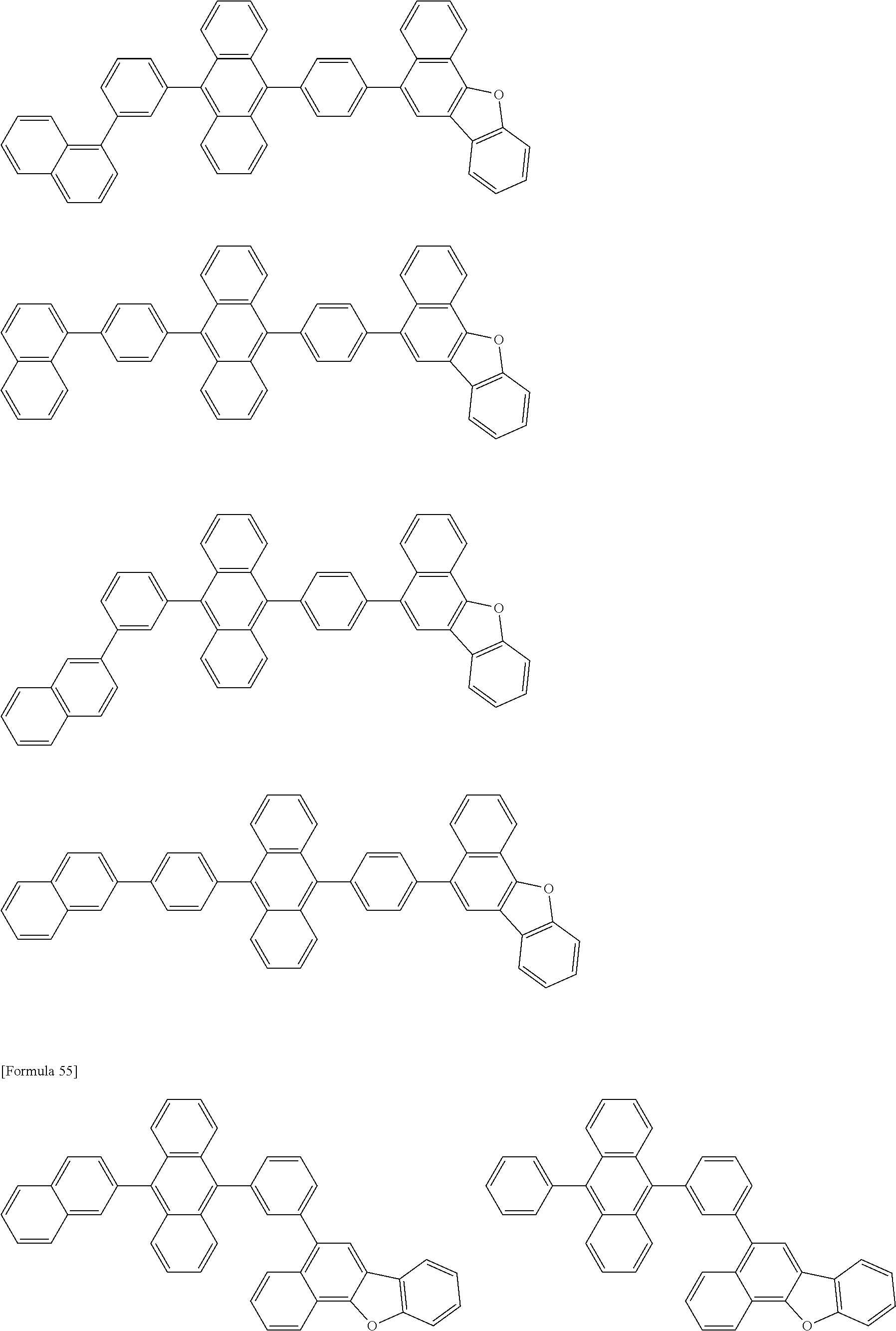

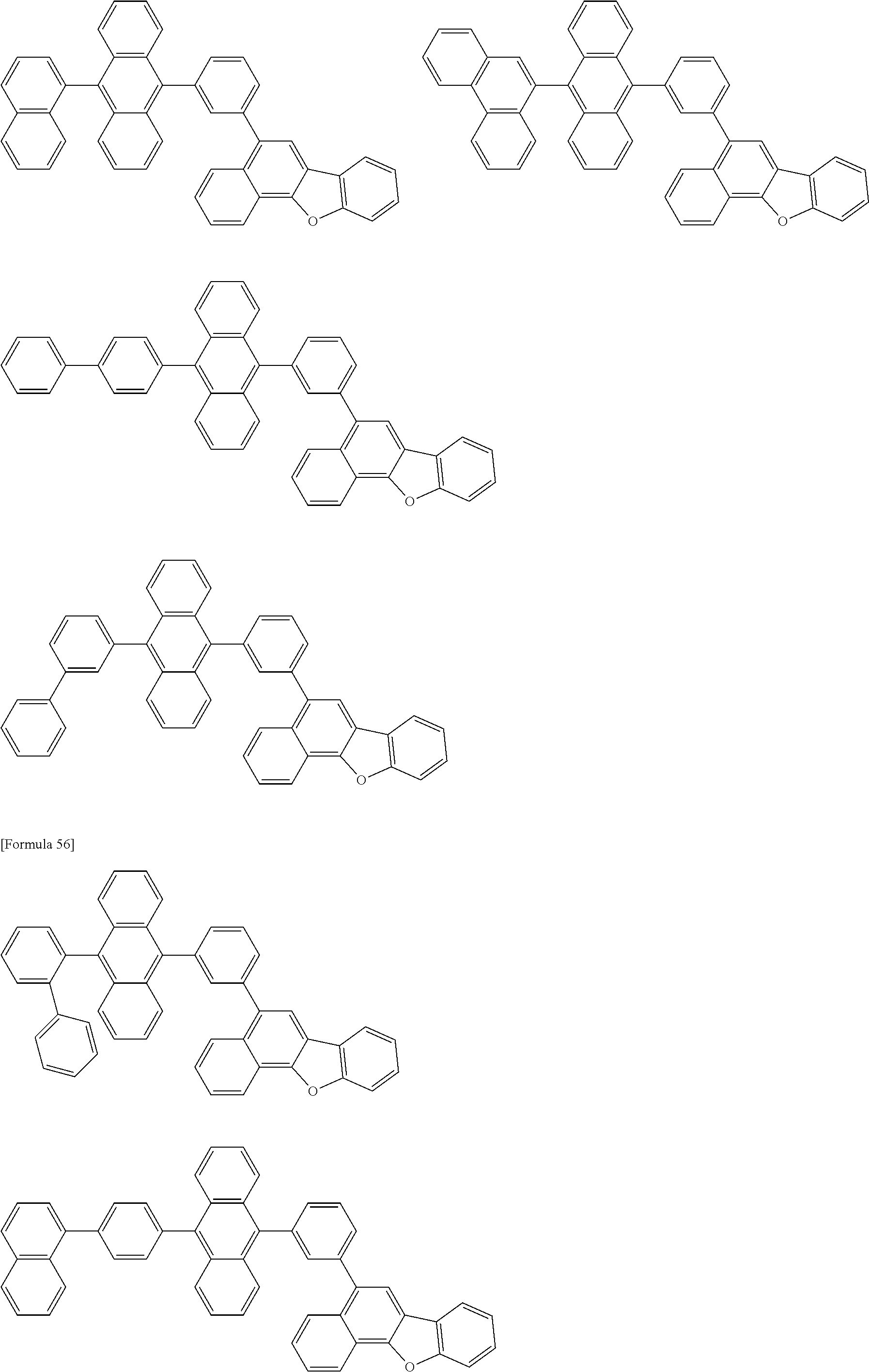

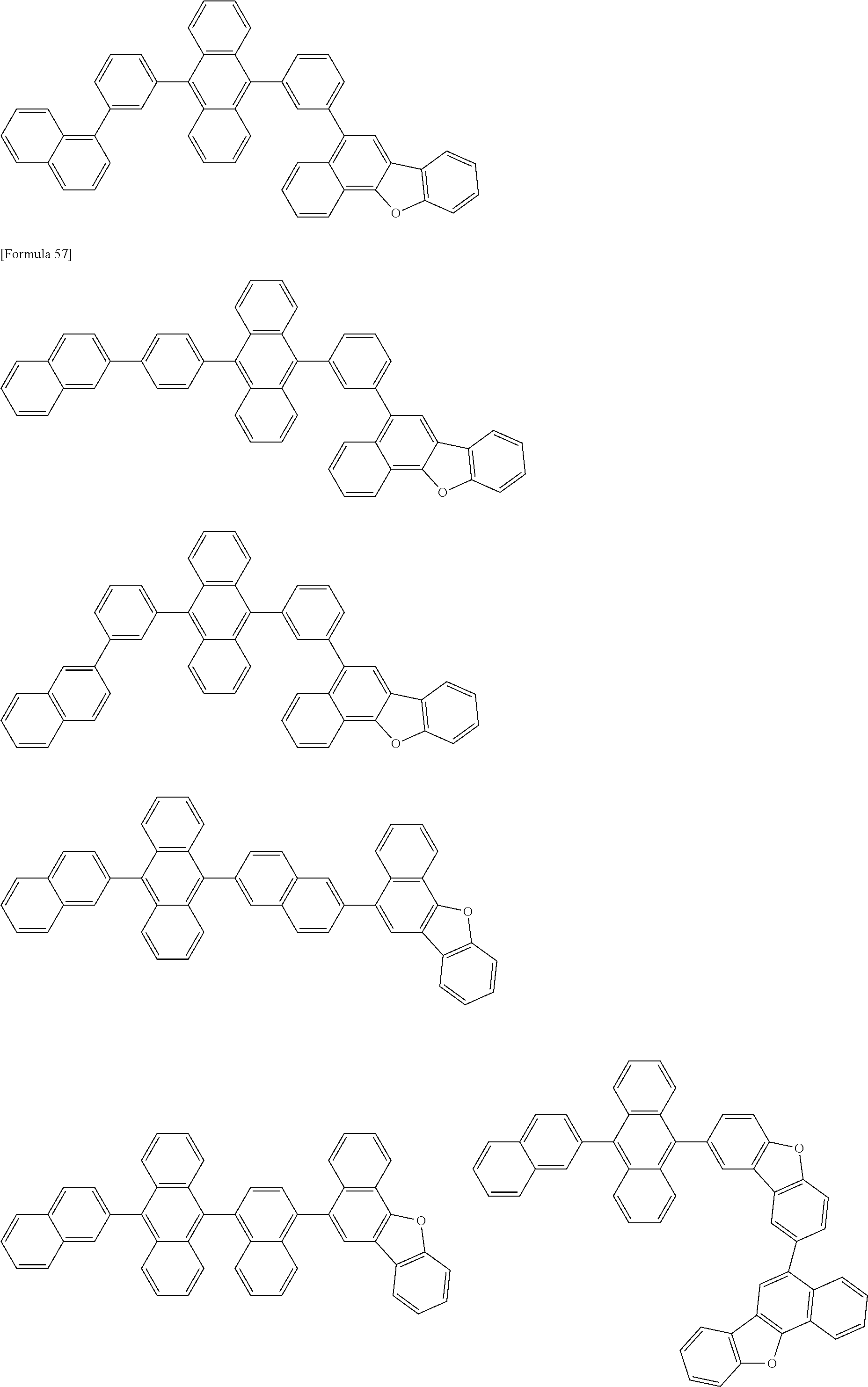

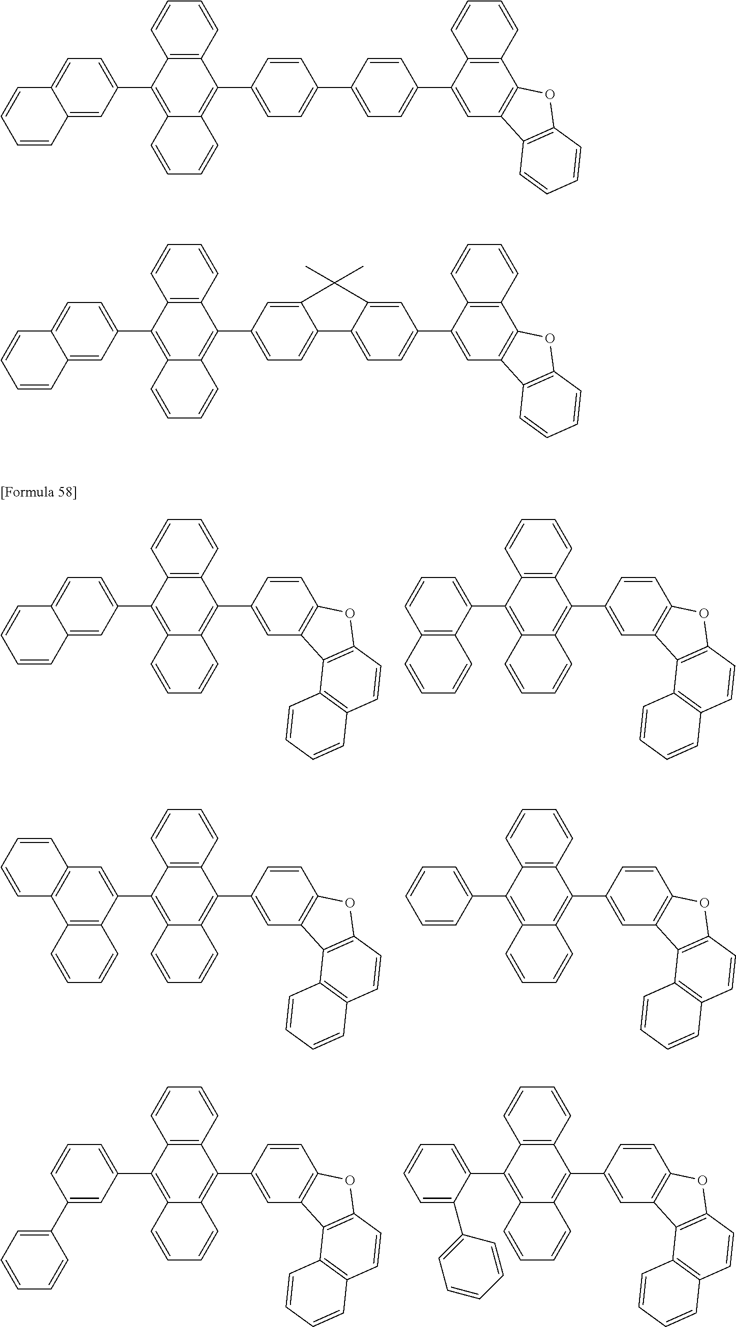

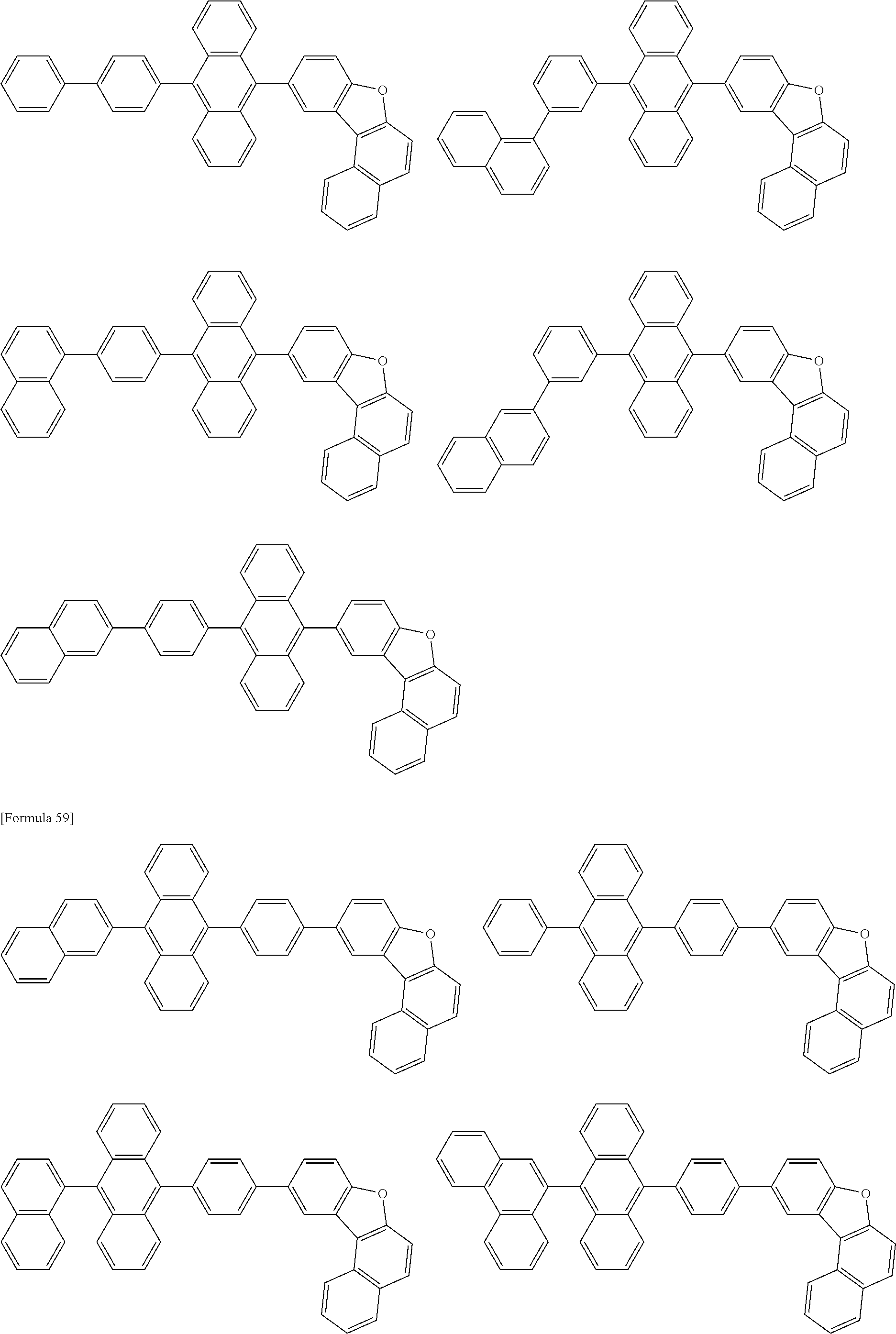

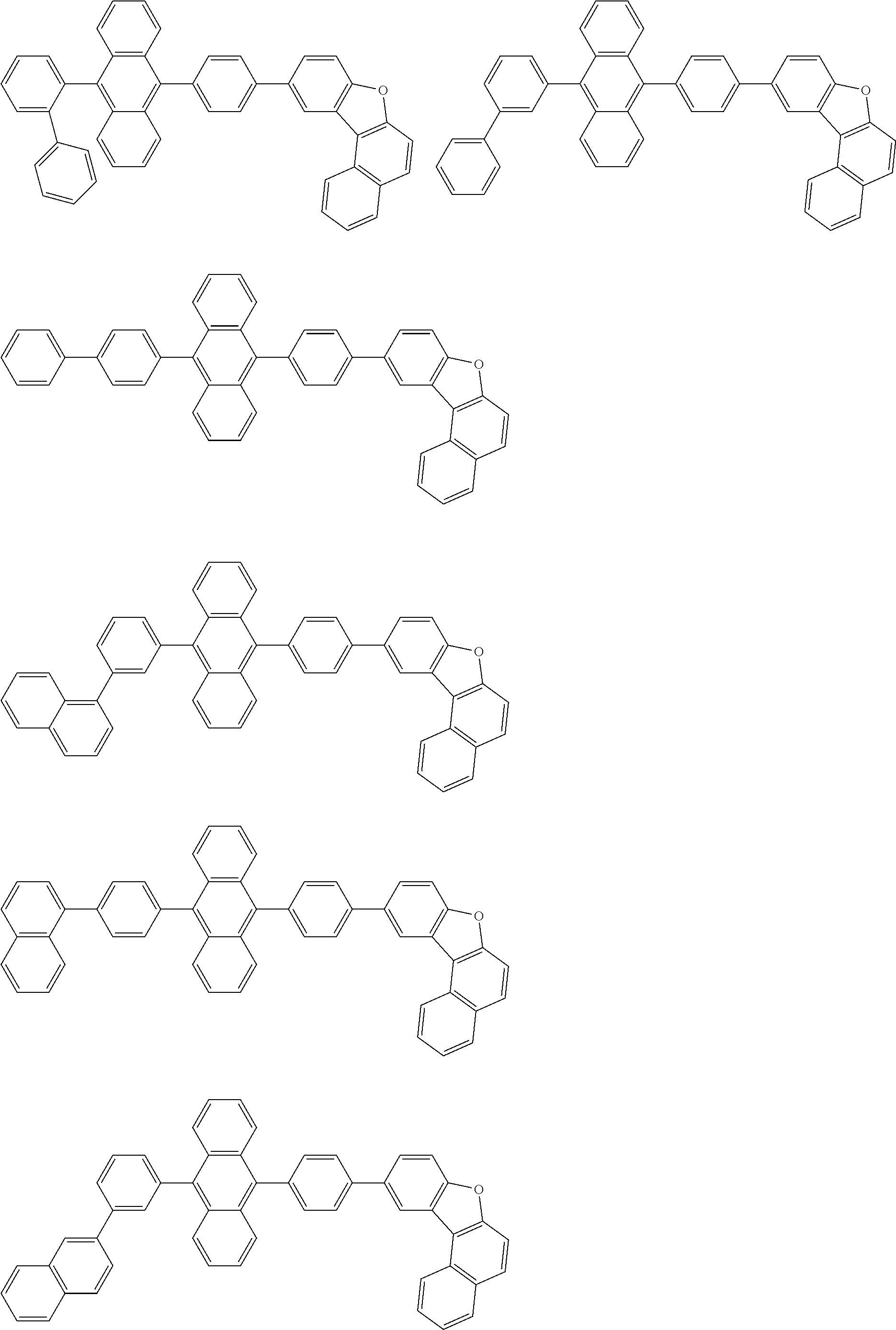

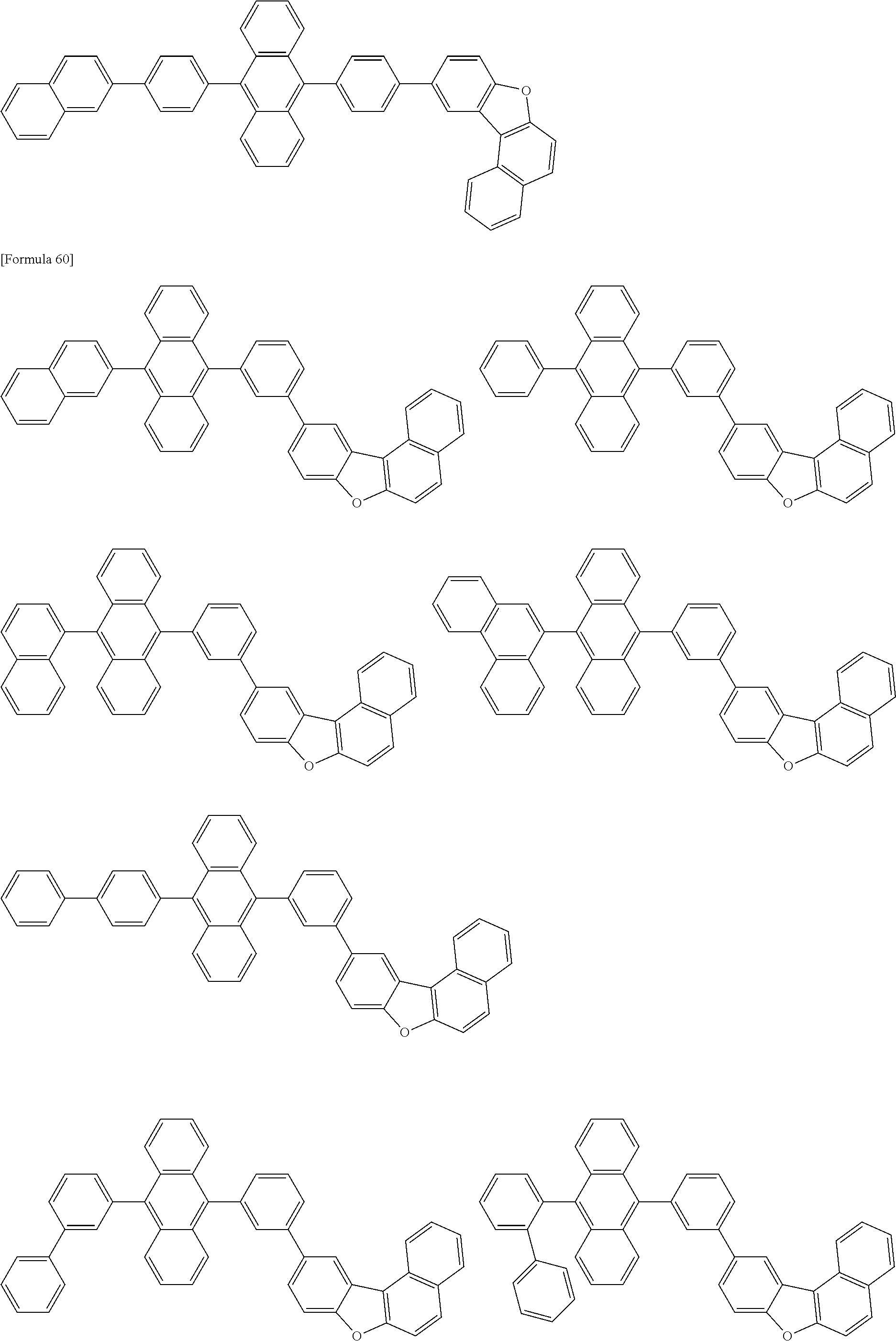

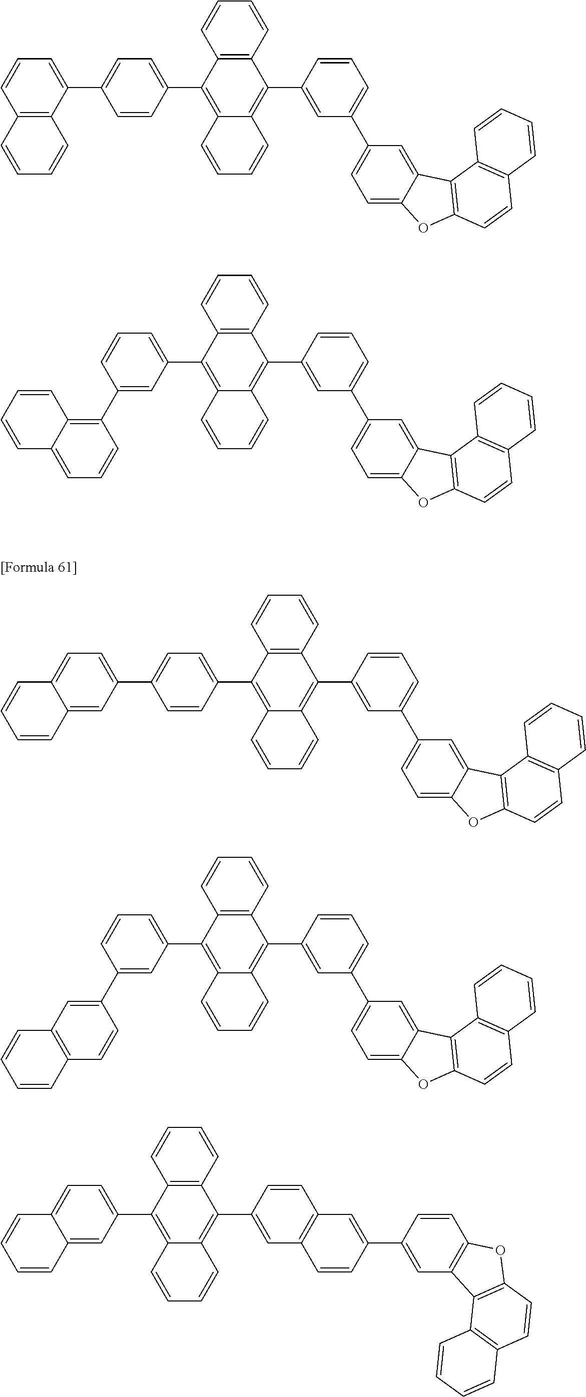 [SMILES: c1cc(-c2ccc3oc4ccc5ccccc5c4c3c2)cc(-c2c3ccccc3c(-c3ccc(-c4cccc5ccccc45)cc3)c3ccccc23)c1 ; c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2ccc3oc4ccc5ccccc5c4c3c2)cc(-c2c3ccccc3c(-c3ccc(-c4ccc5ccccc5c4)cc3)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1 ; c1ccc2cc(-c3c4ccccc4c(-c4ccc5cc(-c6ccc7oc8ccc9ccccc9c8c7c6)ccc5c4)c4ccccc34)ccc2c1]

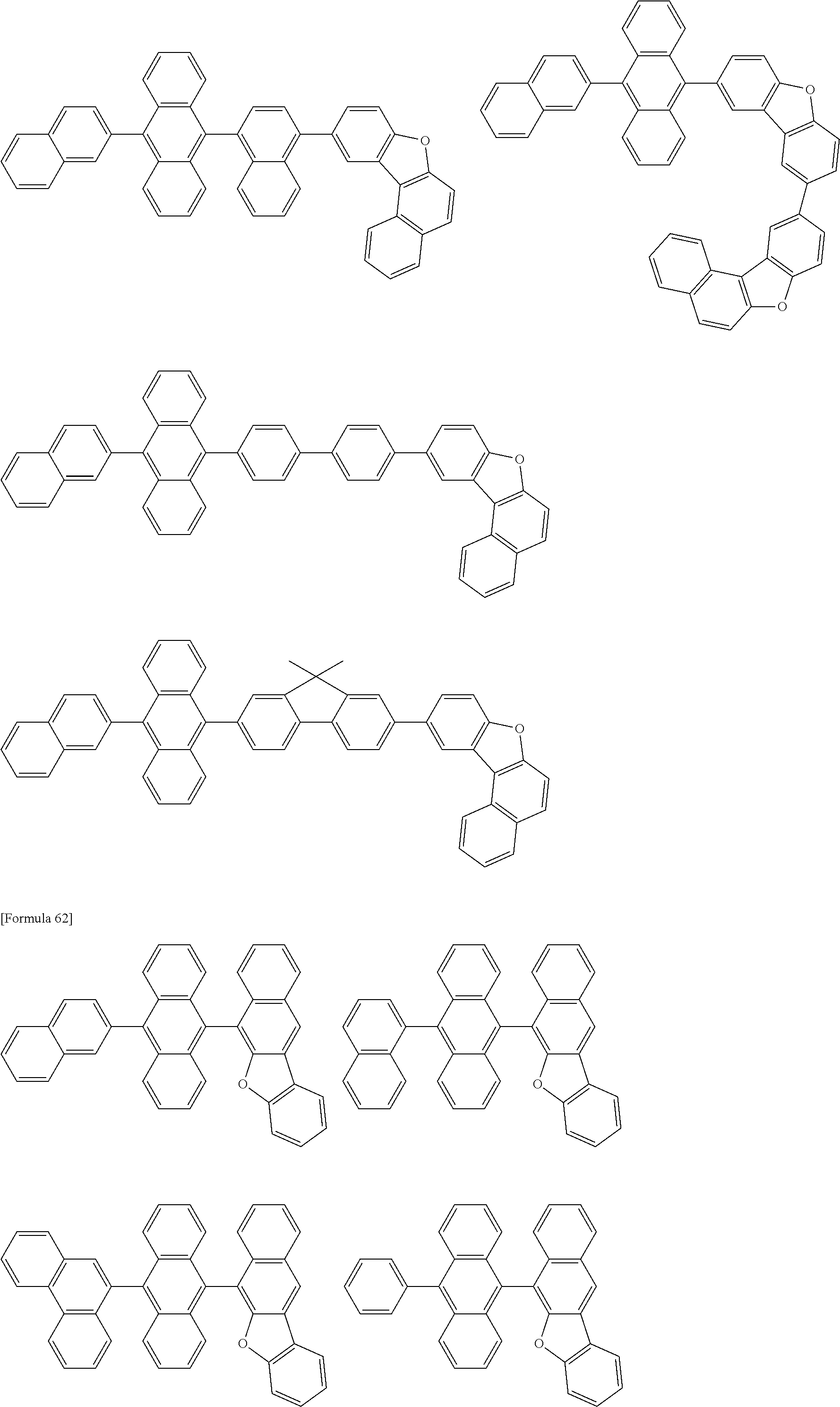

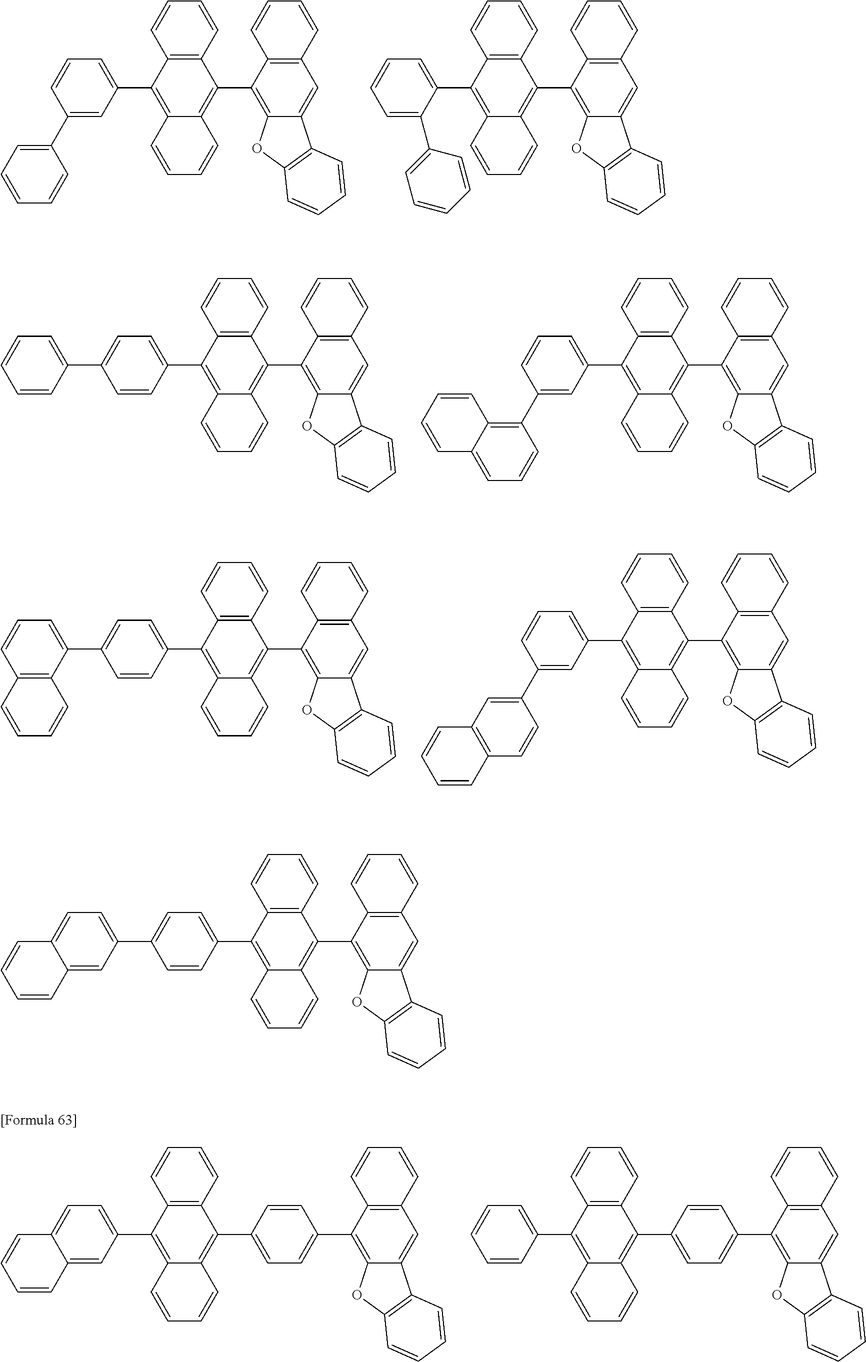

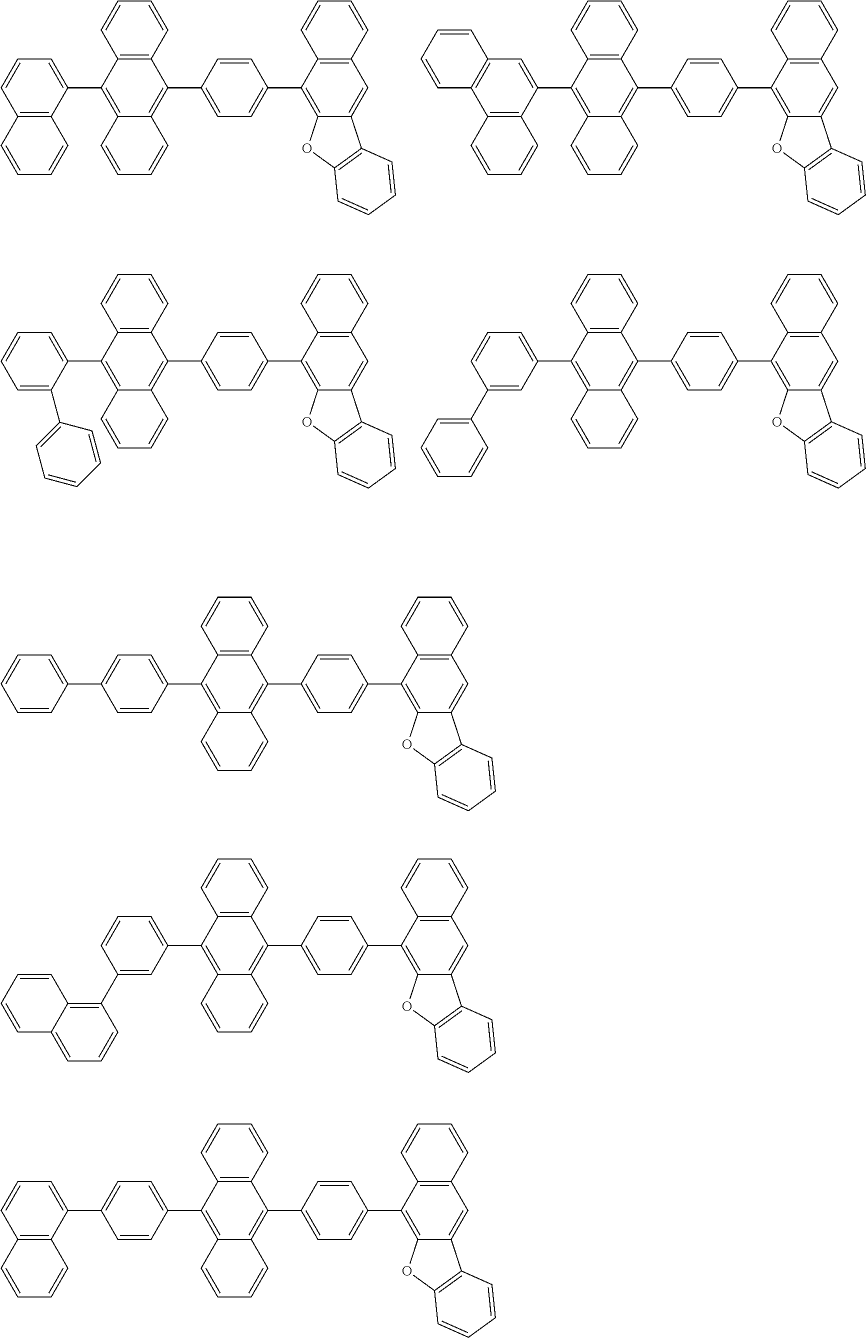

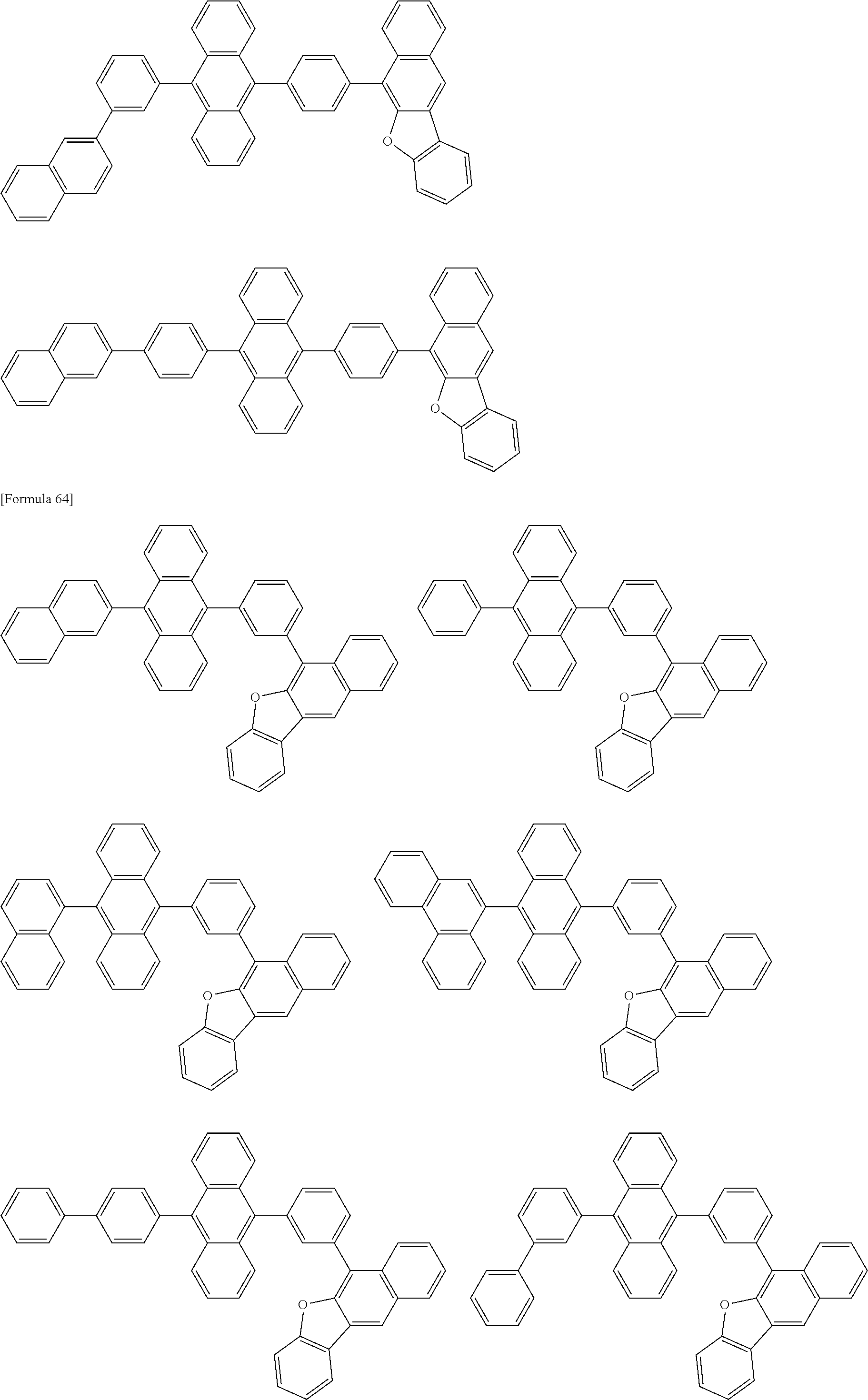

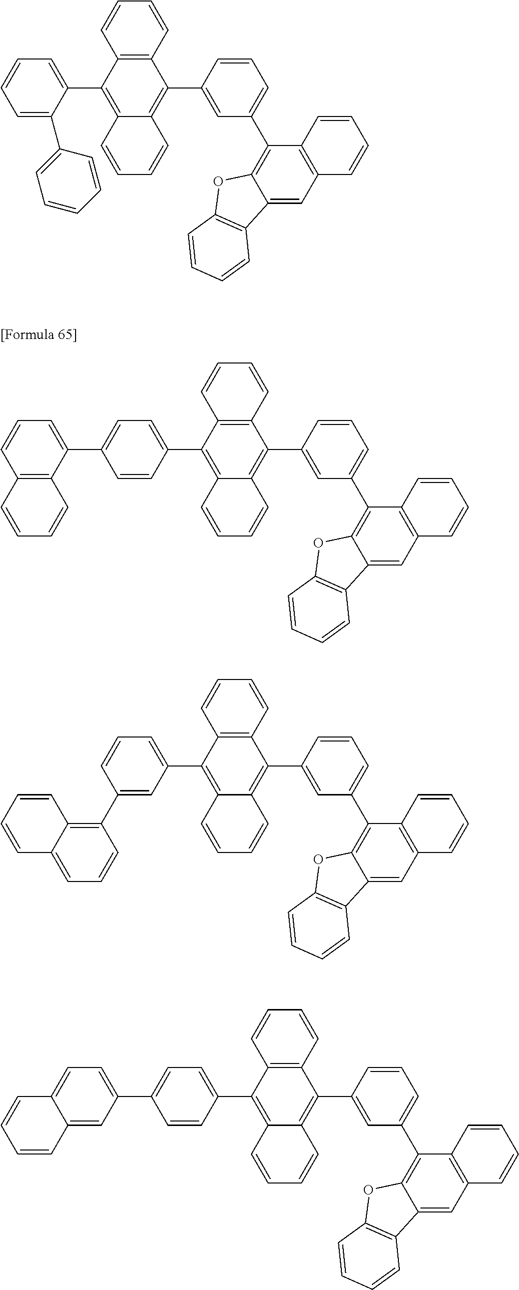 [SMILES: c1ccc(-c2ccccc2-c2c3ccccc3c(-c3cccc(-c4c5ccccc5cc5c4oc4ccccc45)c3)c3ccccc23)cc1 ; c1cc(-c2c3ccccc3c(-c3ccc(-c4cccc5ccccc45)cc3)c3ccccc23)cc(-c2c3ccccc3cc3c2oc2ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1cc(-c2c3ccccc3c(-c3ccc(-c4ccc5ccccc5c4)cc3)c3ccccc23)cc(-c2c3ccccc3cc3c2oc2ccccc23)c1]

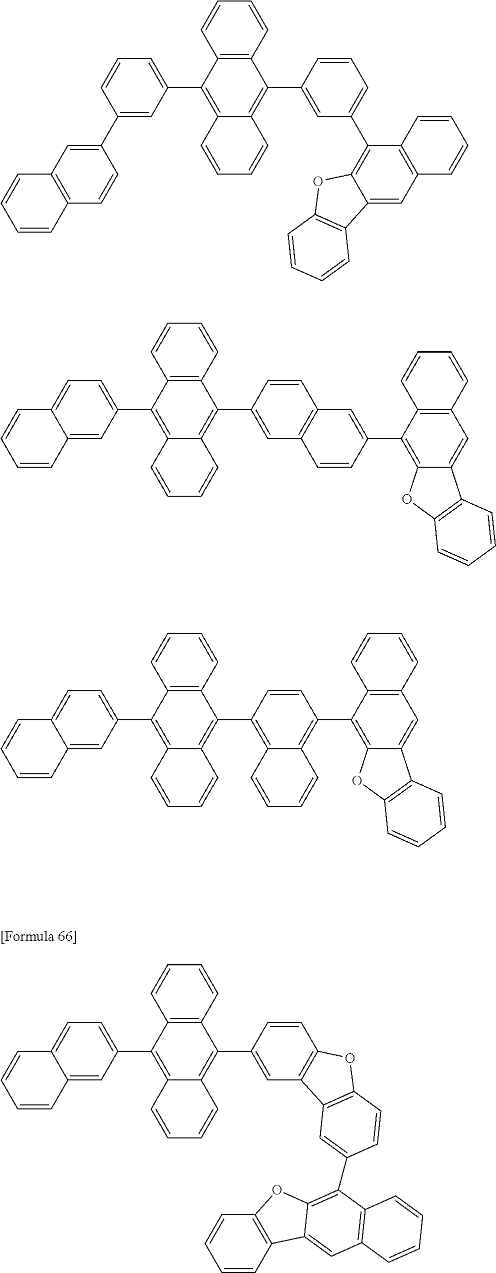 [SMILES: c1cc(-c2ccc3ccccc3c2)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5cc(-c6c7ccccc7cc7c6oc6ccccc67)ccc5c4)c4ccccc34)ccc2c1 ; c1ccc2cc(-c3c4ccccc4c(-c4ccc(-c5c6ccccc6cc6c5oc5ccccc56)c5ccccc45)c4ccccc34)ccc2c1 ; c1ccc2cc(-c3c4ccccc4c(-c4ccc5oc6ccc(-c7c8ccccc8cc8c7oc7ccccc78)cc6c5c4)c4ccccc34)ccc2c1]

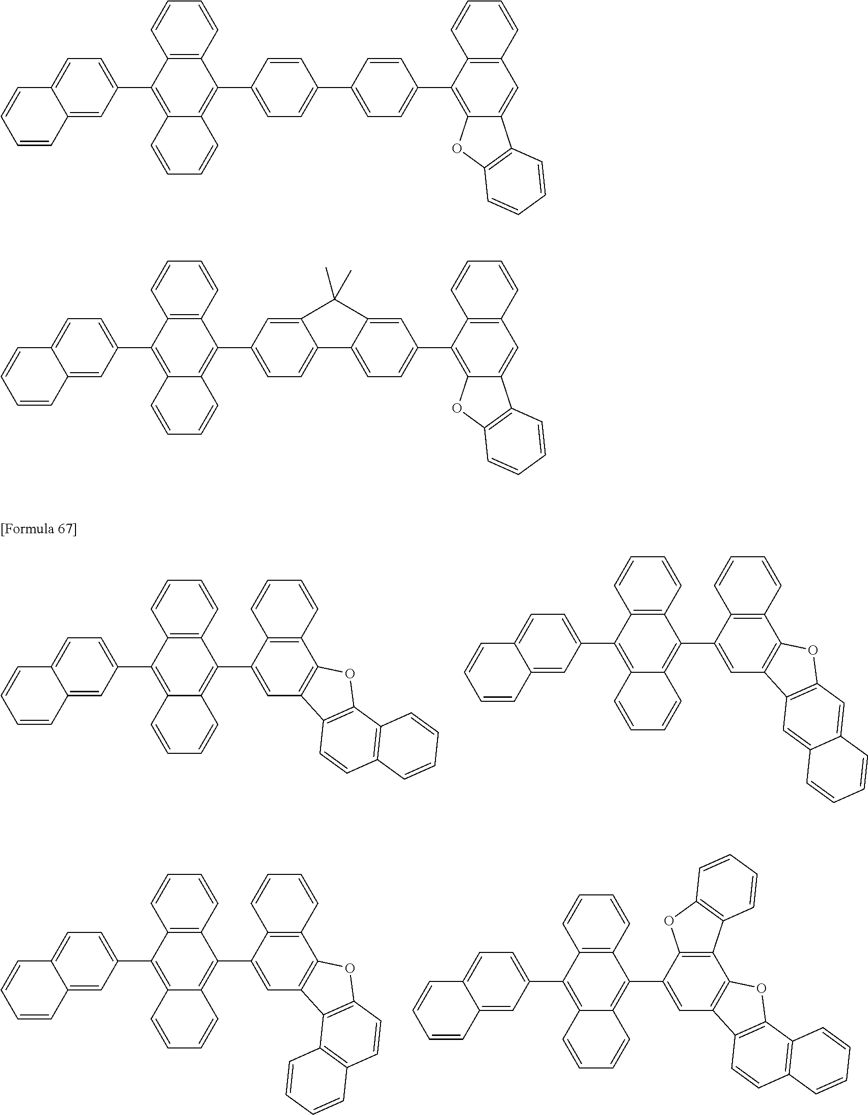

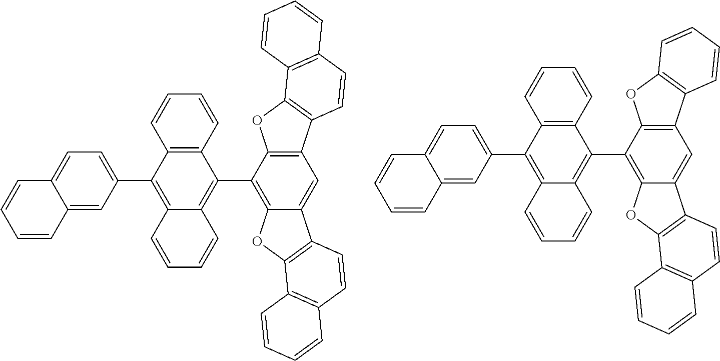 [SMILES: c1ccc2cc(-c3c4ccccc4c(-c4c5oc6c7ccccc7ccc6c5cc5c4oc4c6ccccc6ccc54)c4ccccc34)ccc2c1 ; c1ccc2cc(-c3c4ccccc4c(-c4c5oc6ccccc6c5cc5c4oc4c6ccccc6ccc54)c4ccccc34)ccc2c1]

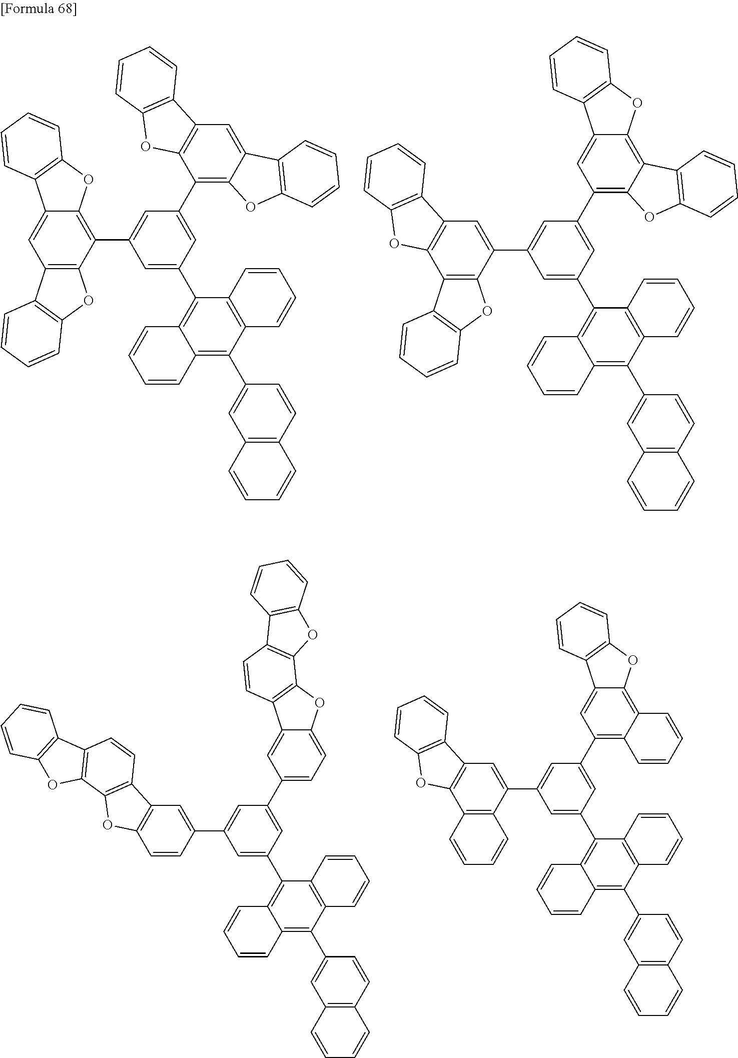

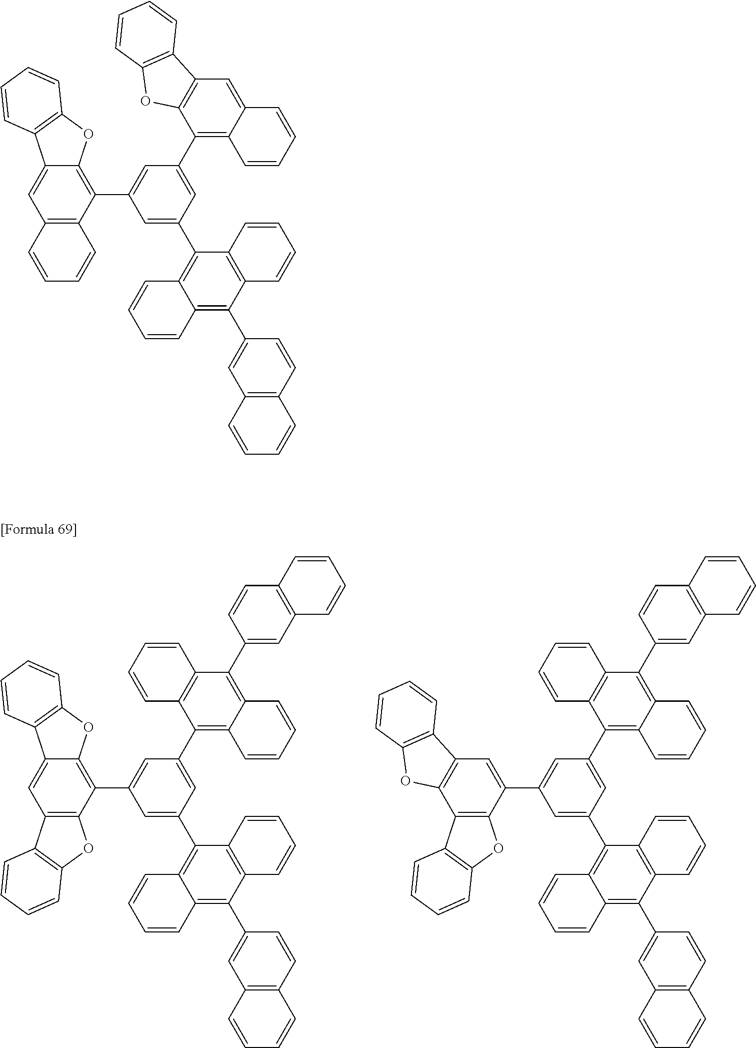 [SMILES: c1ccc2cc(-c3c4ccccc4c(-c4cc(-c5c6ccccc6cc6c5oc5ccccc56)cc(-c5c6ccccc6cc6c5oc5ccccc56)c4)c4ccccc34)ccc2c1 ; c1ccc2cc(-c3c4ccccc4c(-c4cc(-c5c6ccccc6c(-c6ccc7ccccc7c6)c6ccccc56)cc(-c5c6oc7ccccc7c6cc6c5oc5ccccc56)c4)c4ccccc34)ccc2c1 ; c1ccc2cc(-c3c4ccccc4c(-c4cc(-c5c6ccccc6c(-c6ccc7ccccc7c6)c6ccccc56)cc(-c5cc6c7ccccc7oc6c6c5oc5ccccc56)c4)c4ccccc34)ccc2c1]

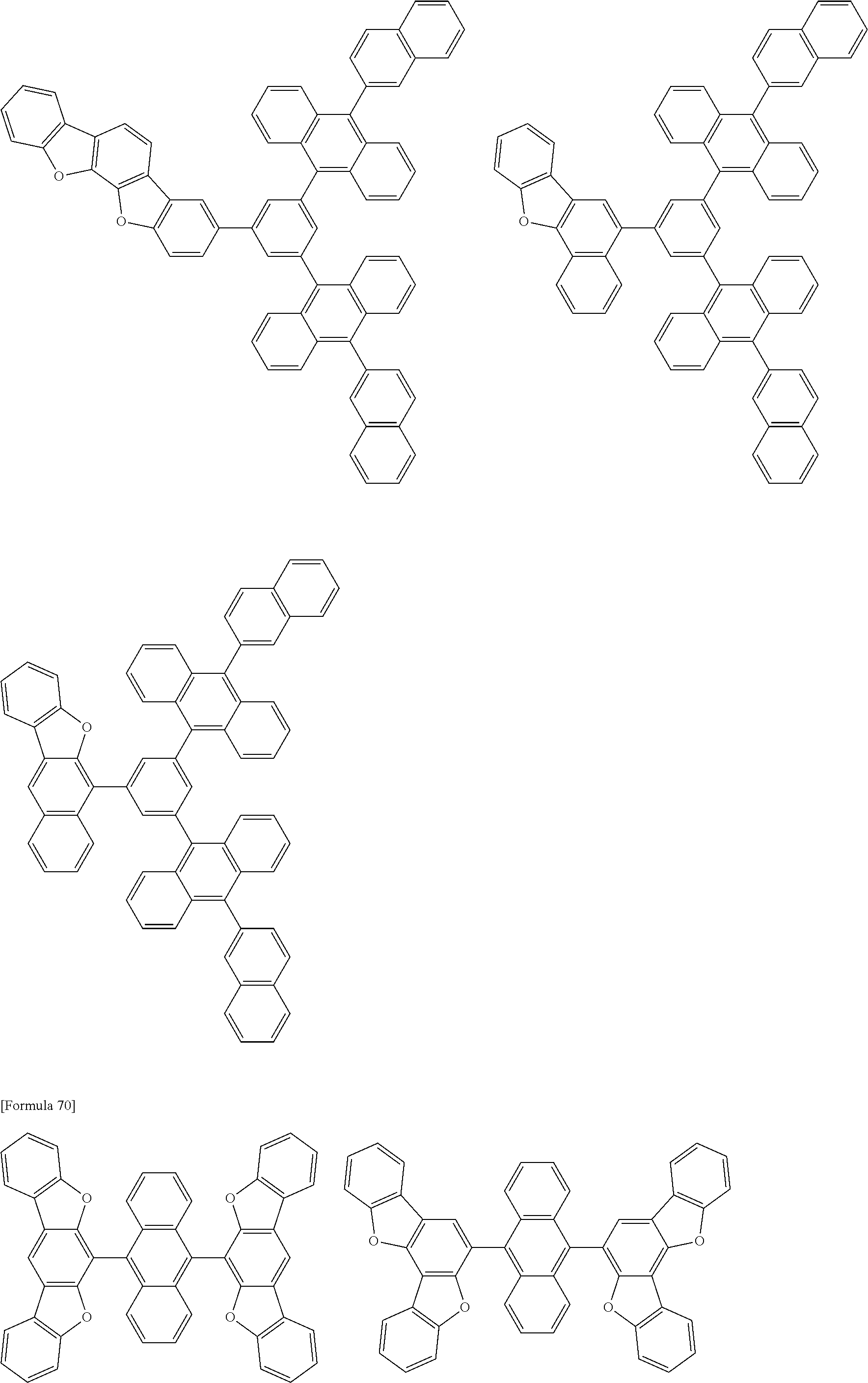

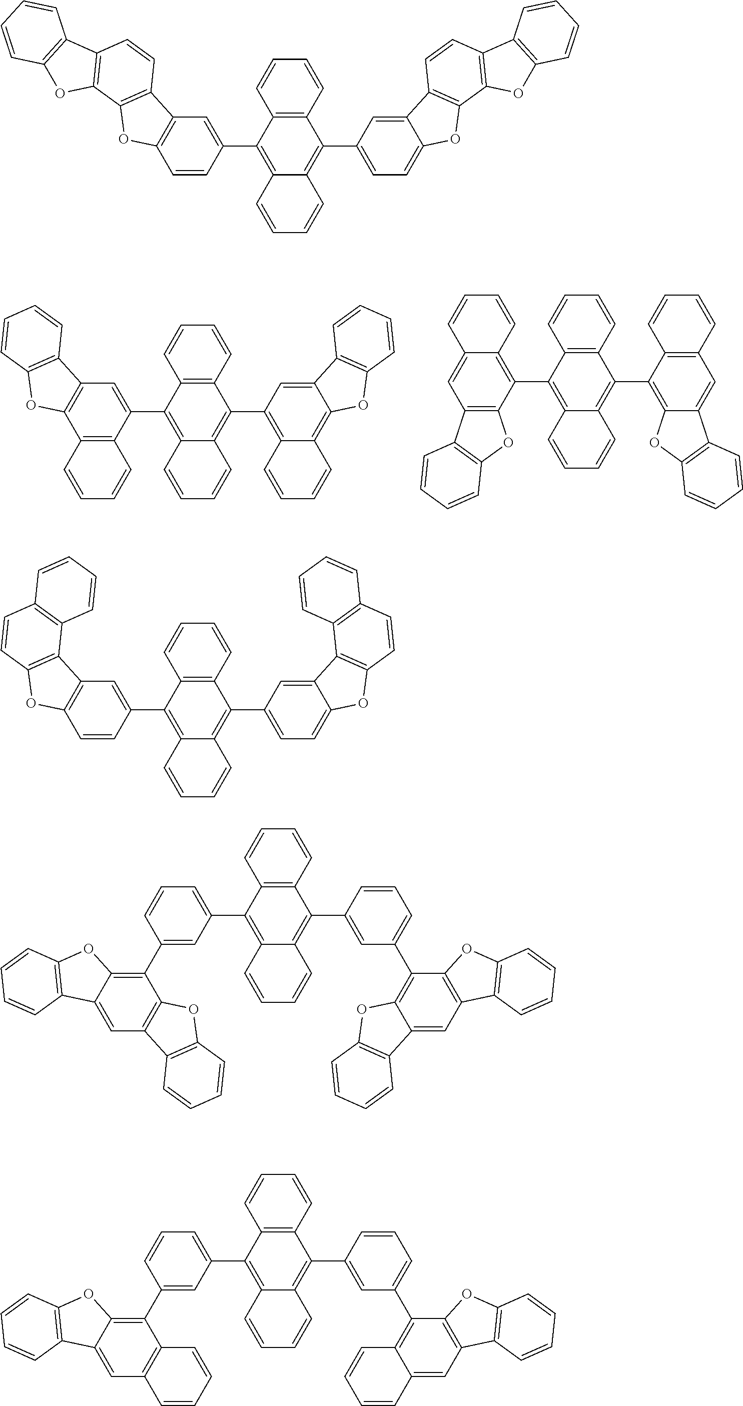

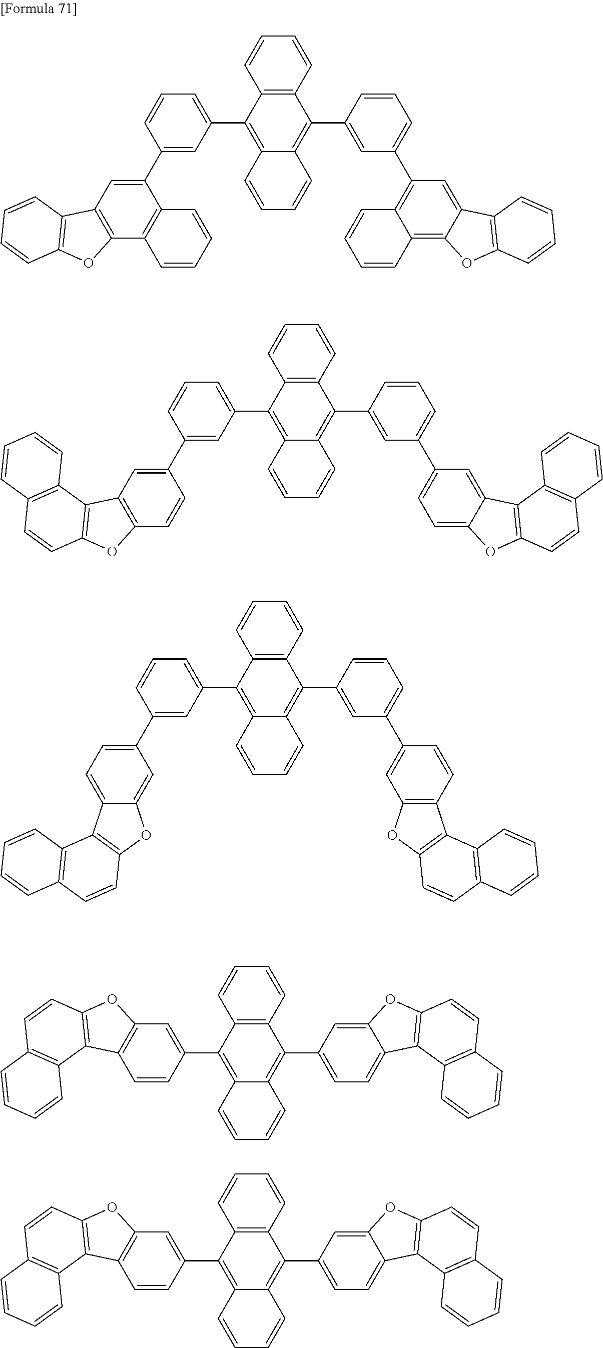

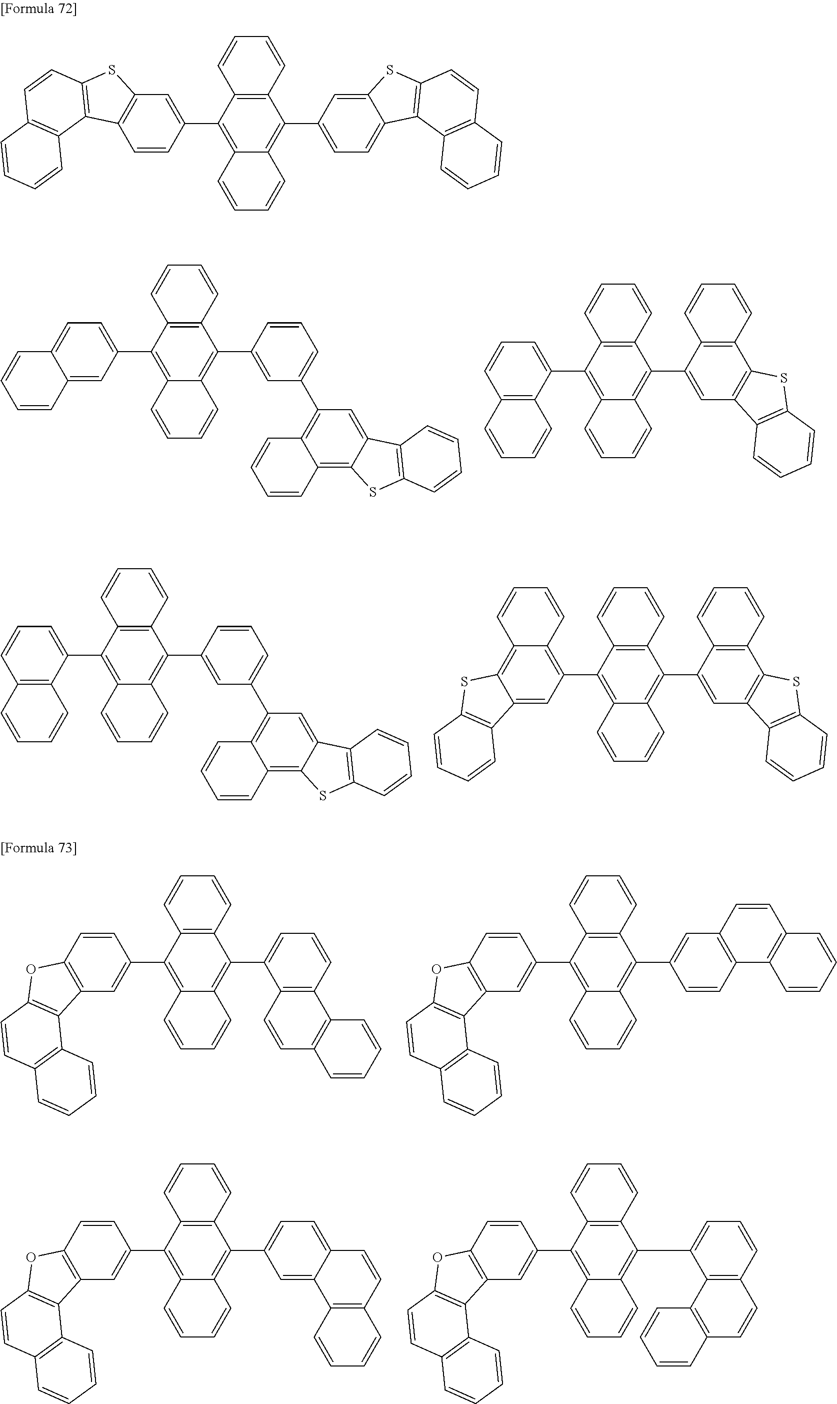

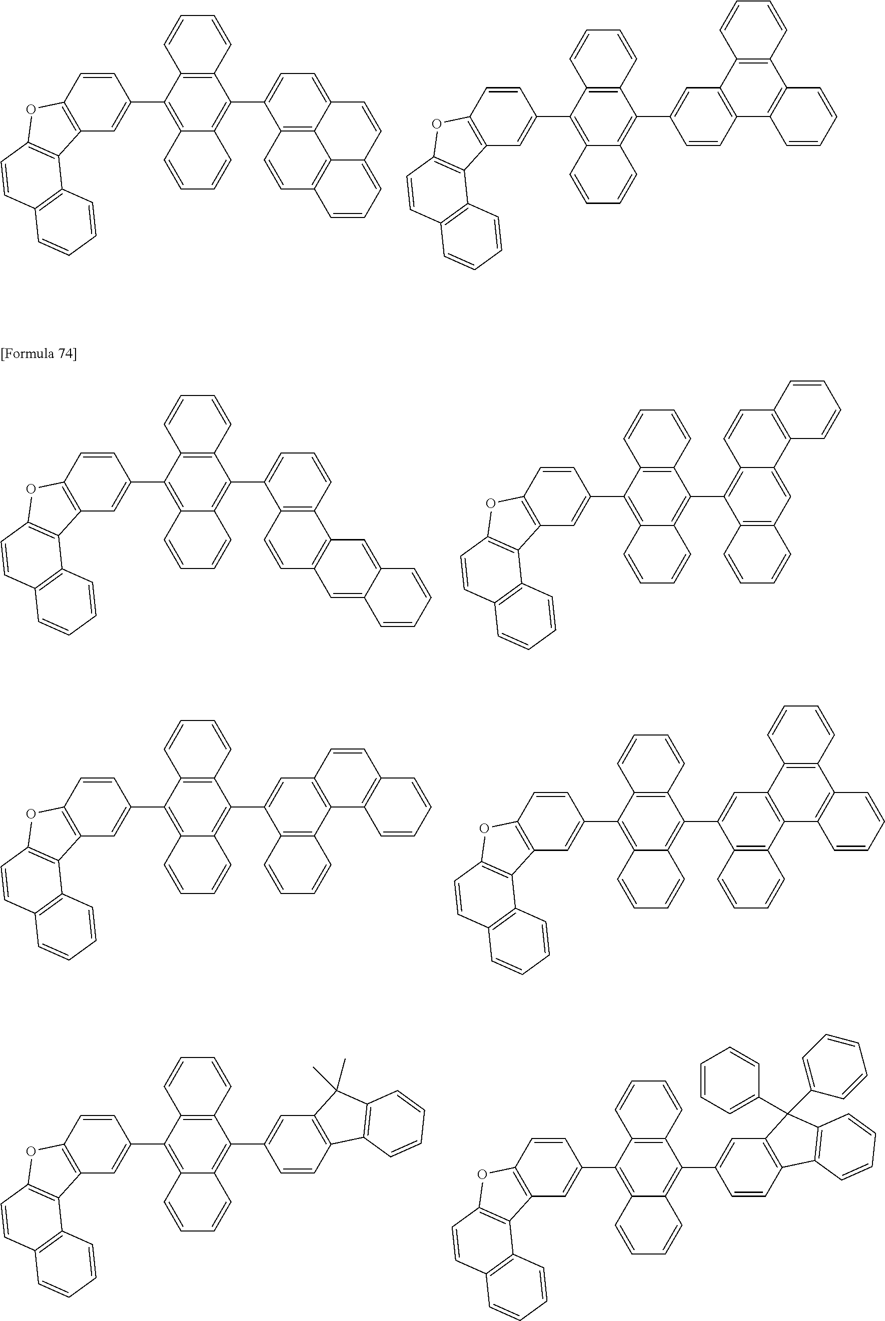

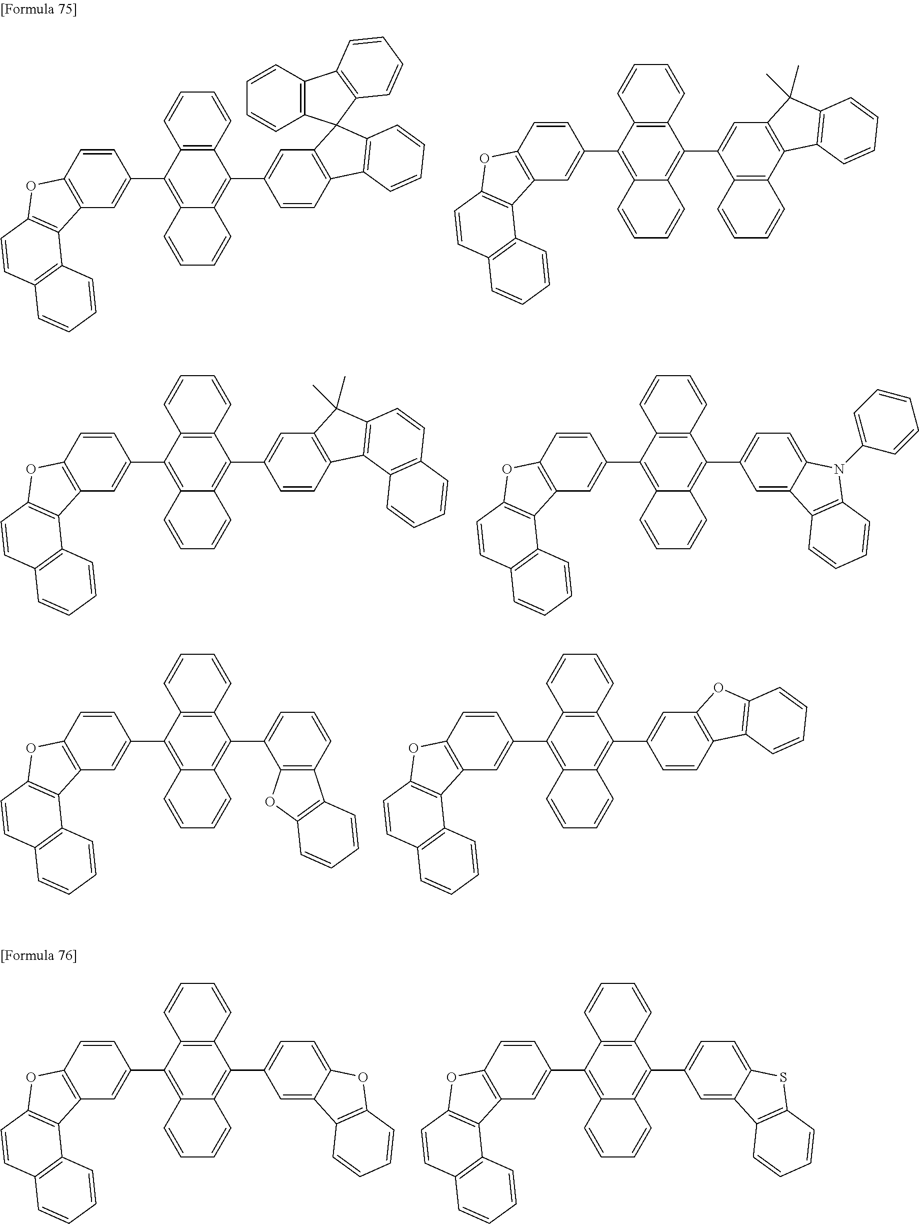

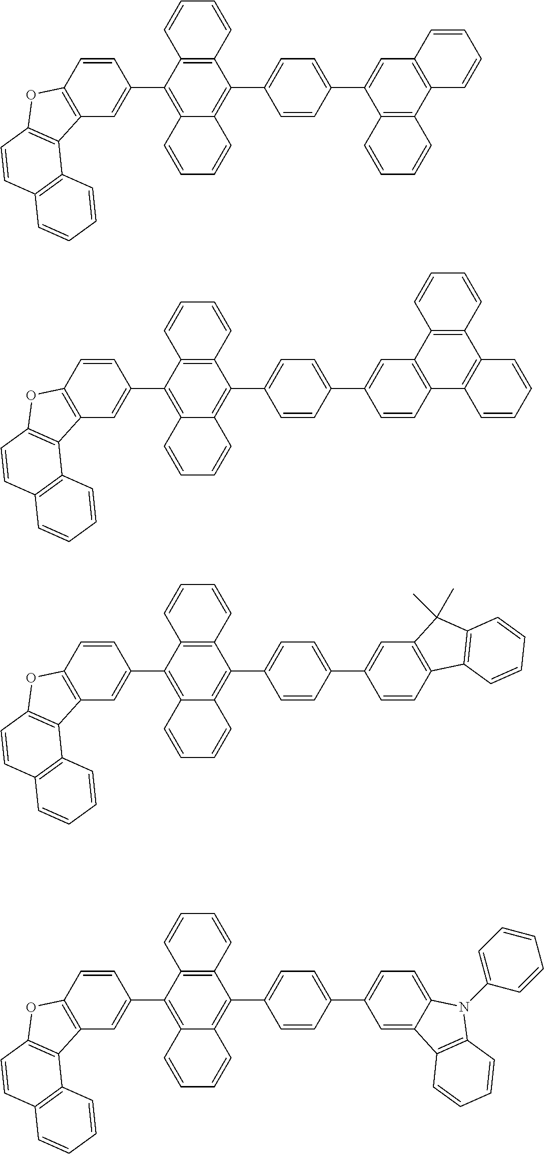 [SMILES: c1ccc2c(c1)cc(-c1ccc(-c3c4ccccc4c(-c4ccc5oc6ccc7ccccc7c6c5c4)c4ccccc34)cc1)c1ccccc12 ; c1ccc2c(c1)ccc1oc3ccc(-c4c5ccccc5c(-c5ccc(-c6ccc7c8ccccc8c8ccccc8c7c6)cc5)c5ccccc45)cc3c12 ; CC1(C)c2ccccc2-c2ccc(-c3ccc(-c4c5ccccc5c(-c5ccc6oc7ccc8ccccc8c7c6c5)c5ccccc45)cc3)cc21 ; c1ccc(-n2c3ccccc3c3cc(-c4ccc(-c5c6ccccc6c(-c6ccc7oc8ccc9ccccc9c8c7c6)c6ccccc56)cc4)ccc32)cc1]

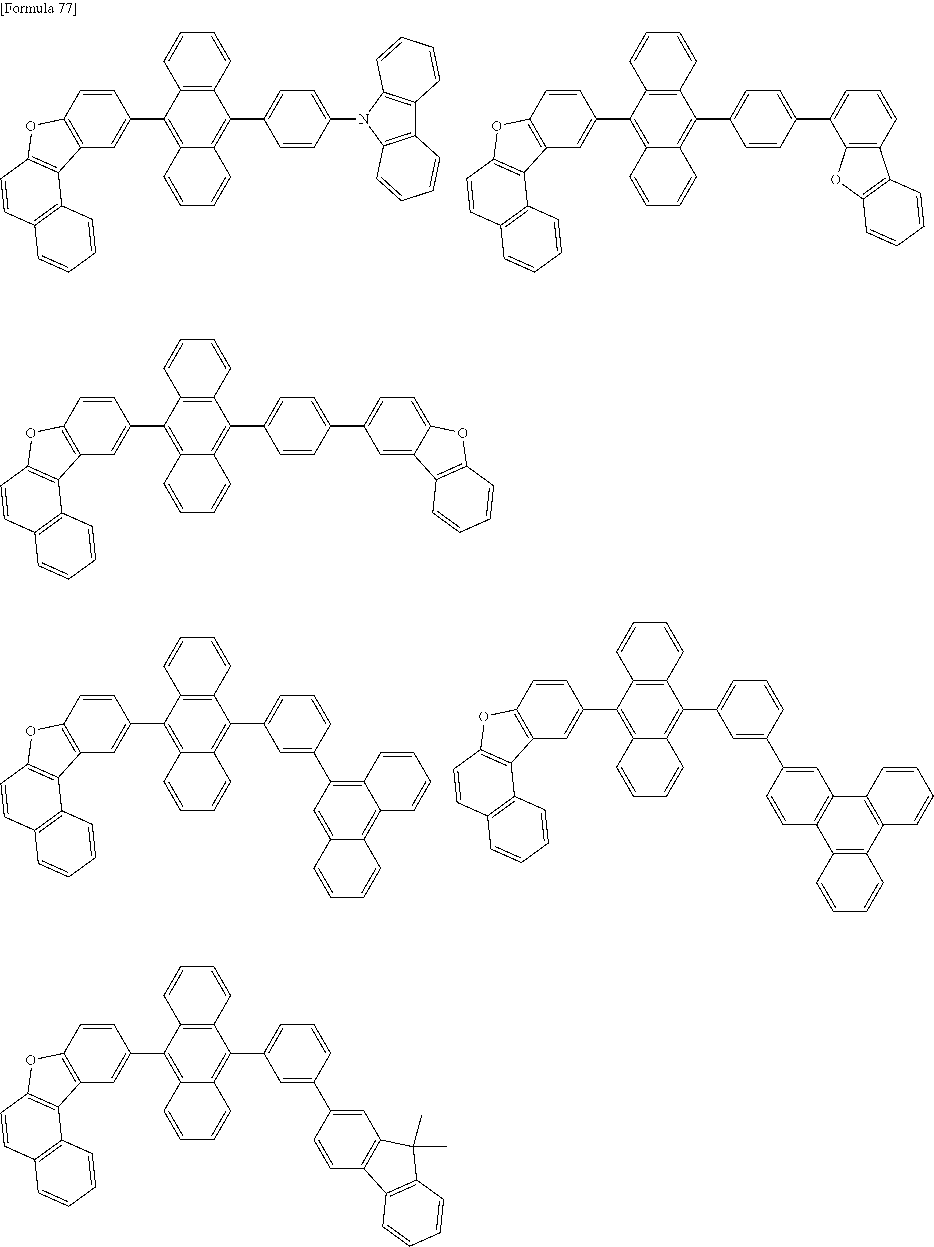

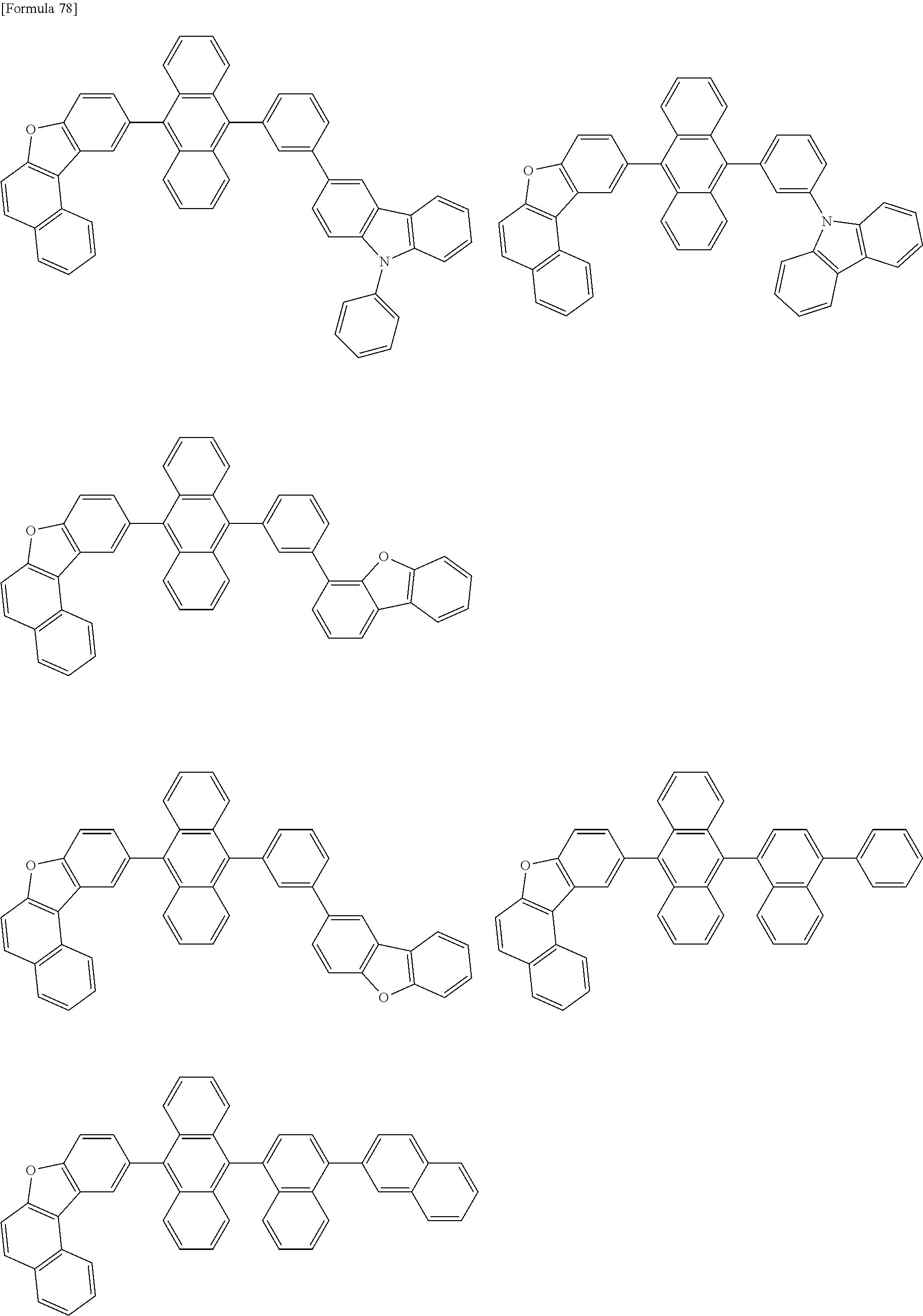

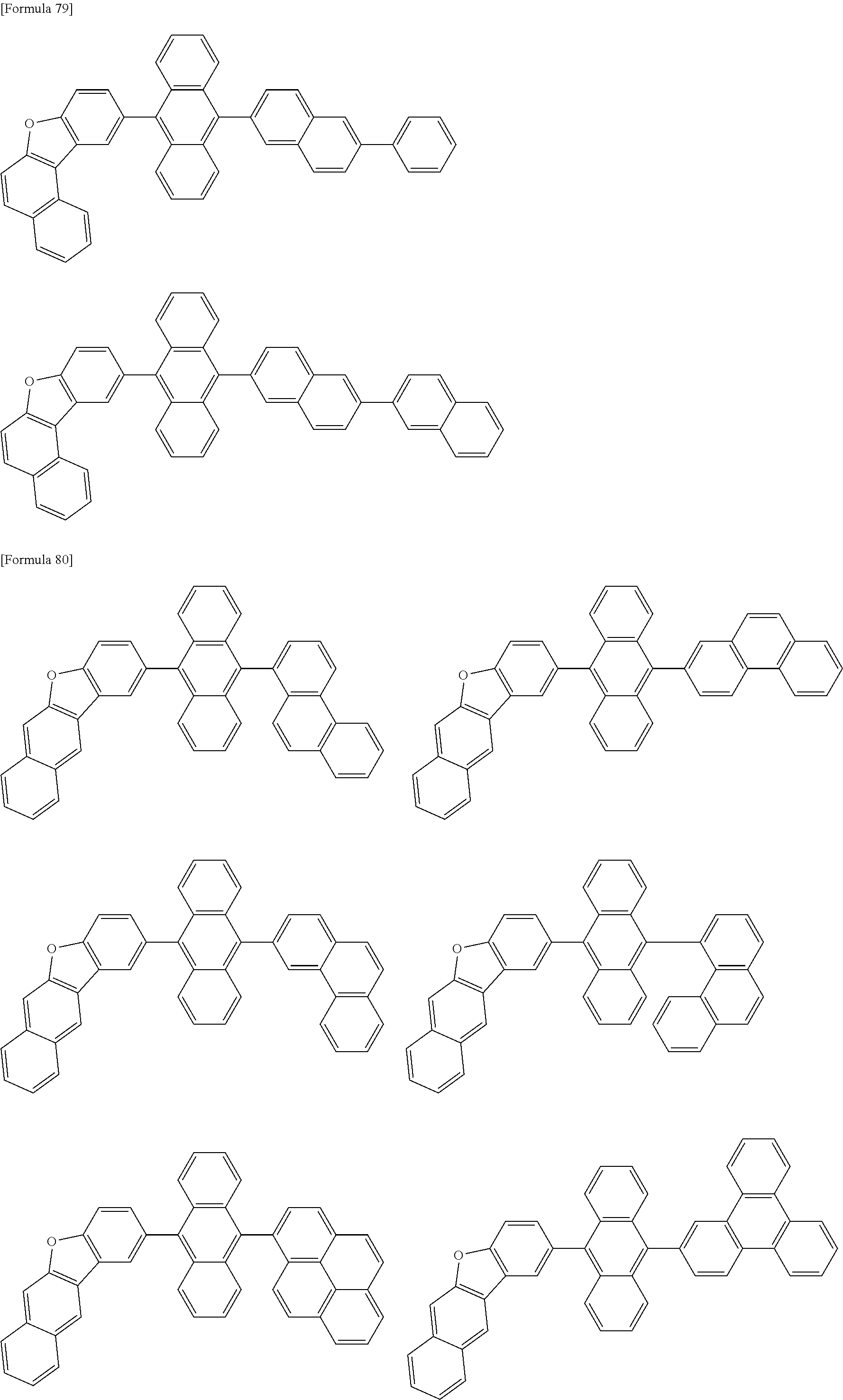

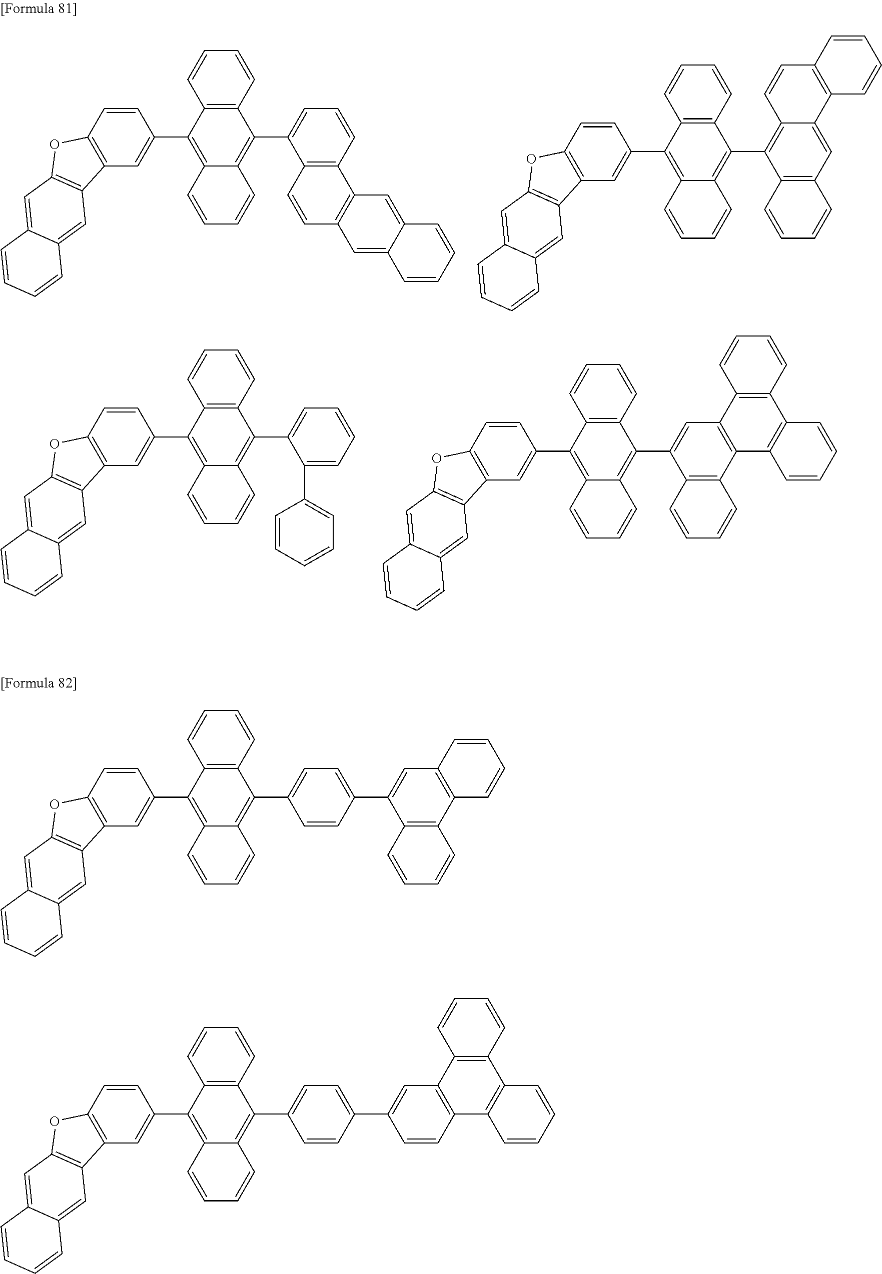

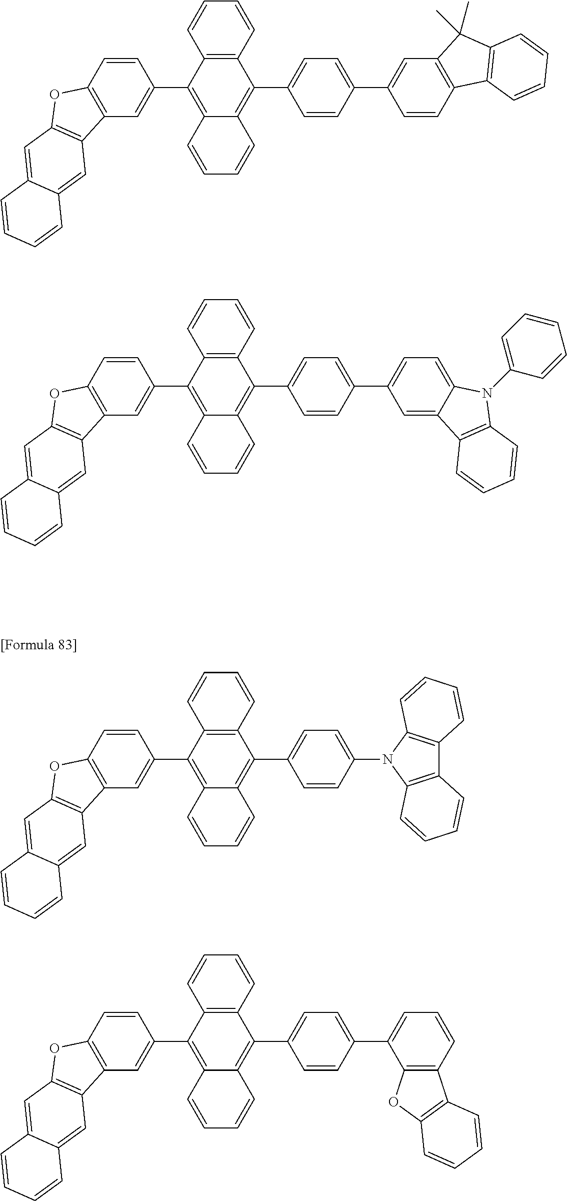 [SMILES: CC1(C)c2ccccc2-c2ccc(-c3ccc(-c4c5ccccc5c(-c5ccc6oc7cc8ccccc8cc7c6c5)c5ccccc45)cc3)cc21 ; c1ccc(-n2c3ccccc3c3cc(-c4ccc(-c5c6ccccc6c(-c6ccc7oc8cc9ccccc9cc8c7c6)c6ccccc56)cc4)ccc32)cc1 ; c1ccc2cc3c(cc2c1)oc1ccc(-c2c4ccccc4c(-c4ccc(-n5c6ccccc6c6ccccc65)cc4)c4ccccc24)cc13 ; c1ccc2cc3c(cc2c1)oc1ccc(-c2c4ccccc4c(-c4ccc(-c5cccc6c5oc5ccccc56)cc4)c4ccccc24)cc13]

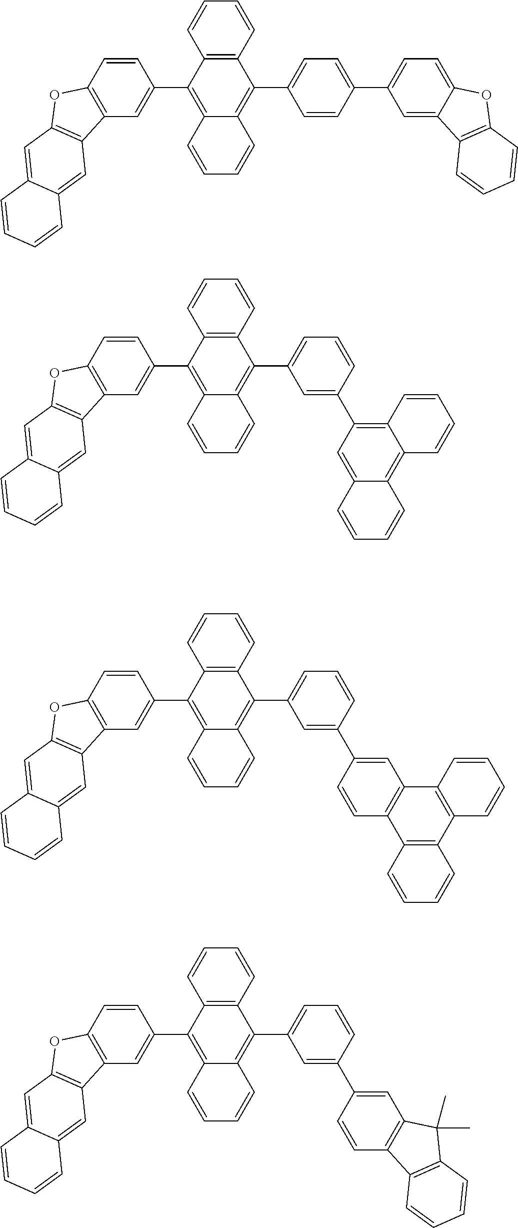 [SMILES: c1ccc2cc3c(cc2c1)oc1ccc(-c2c4ccccc4c(-c4ccc(-c5ccc6oc7ccccc7c6c5)cc4)c4ccccc24)cc13 ; c1cc(-c2c3ccccc3c(-c3ccc4oc5cc6ccccc6cc5c4c3)c3ccccc23)cc(-c2cc3ccccc3c3ccccc23)c1 ; c1cc(-c2ccc3c4ccccc4c4ccccc4c3c2)cc(-c2c3ccccc3c(-c3ccc4oc5cc6ccccc6cc5c4c3)c3ccccc23)c1 ; CC1(C)c2ccccc2-c2ccc(-c3cccc(-c4c5ccccc5c(-c5ccc6oc7cc8ccccc8cc7c6c5)c5ccccc45)c3)cc21]

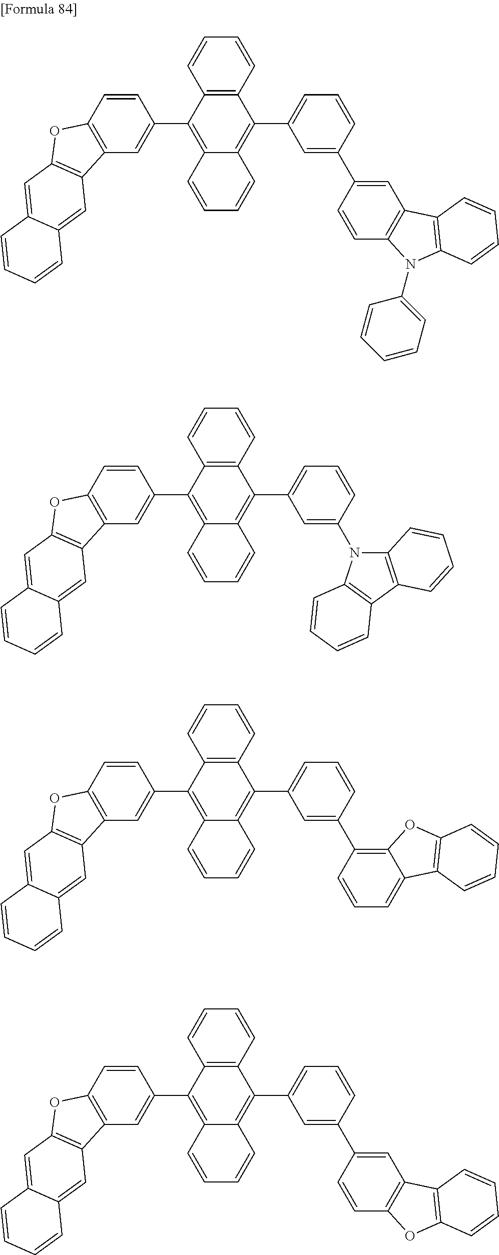 [SMILES: c1ccc(-n2c3ccccc3c3cc(-c4cccc(-c5c6ccccc6c(-c6ccc7oc8cc9ccccc9cc8c7c6)c6ccccc56)c4)ccc32)cc1 ; c1cc(-c2c3ccccc3c(-c3ccc4oc5cc6ccccc6cc5c4c3)c3ccccc23)cc(-n2c3ccccc3c3ccccc32)c1 ; c1cc(-c2c3ccccc3c(-c3ccc4oc5cc6ccccc6cc5c4c3)c3ccccc23)cc(-c2cccc3c2oc2ccccc23)c1 ; c1cc(-c2ccc3oc4ccccc4c3c2)cc(-c2c3ccccc3c(-c3ccc4oc5cc6ccccc6cc5c4c3)c3ccccc23)c1]

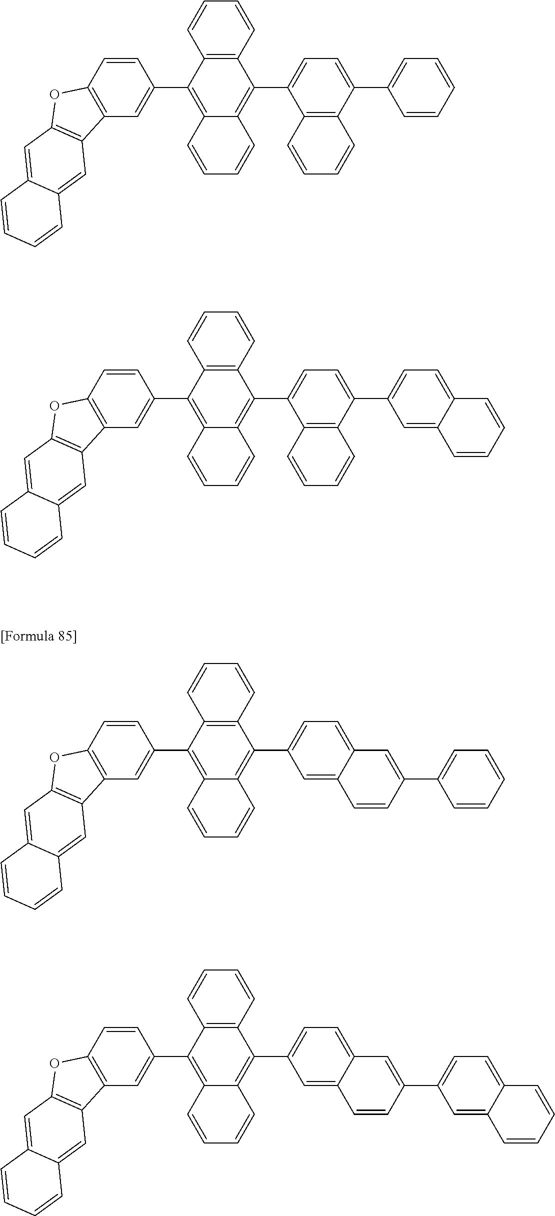 [SMILES: c1ccc(-c2ccc(-c3c4ccccc4c(-c4ccc5oc6cc7ccccc7cc6c5c4)c4ccccc34)c3ccccc23)cc1 ; c1ccc2cc(-c3ccc(-c4c5ccccc5c(-c5ccc6oc7cc8ccccc8cc7c6c5)c5ccccc45)c4ccccc34)ccc2c1 ; c1ccc(-c2ccc3cc(-c4c5ccccc5c(-c5ccc6oc7cc8ccccc8cc7c6c5)c5ccccc45)ccc3c2)cc1 ; c1ccc2cc(-c3ccc4cc(-c5c6ccccc6c(-c6ccc7oc8cc9ccccc9cc8c7c6)c6ccccc56)ccc4c3)ccc2c1]

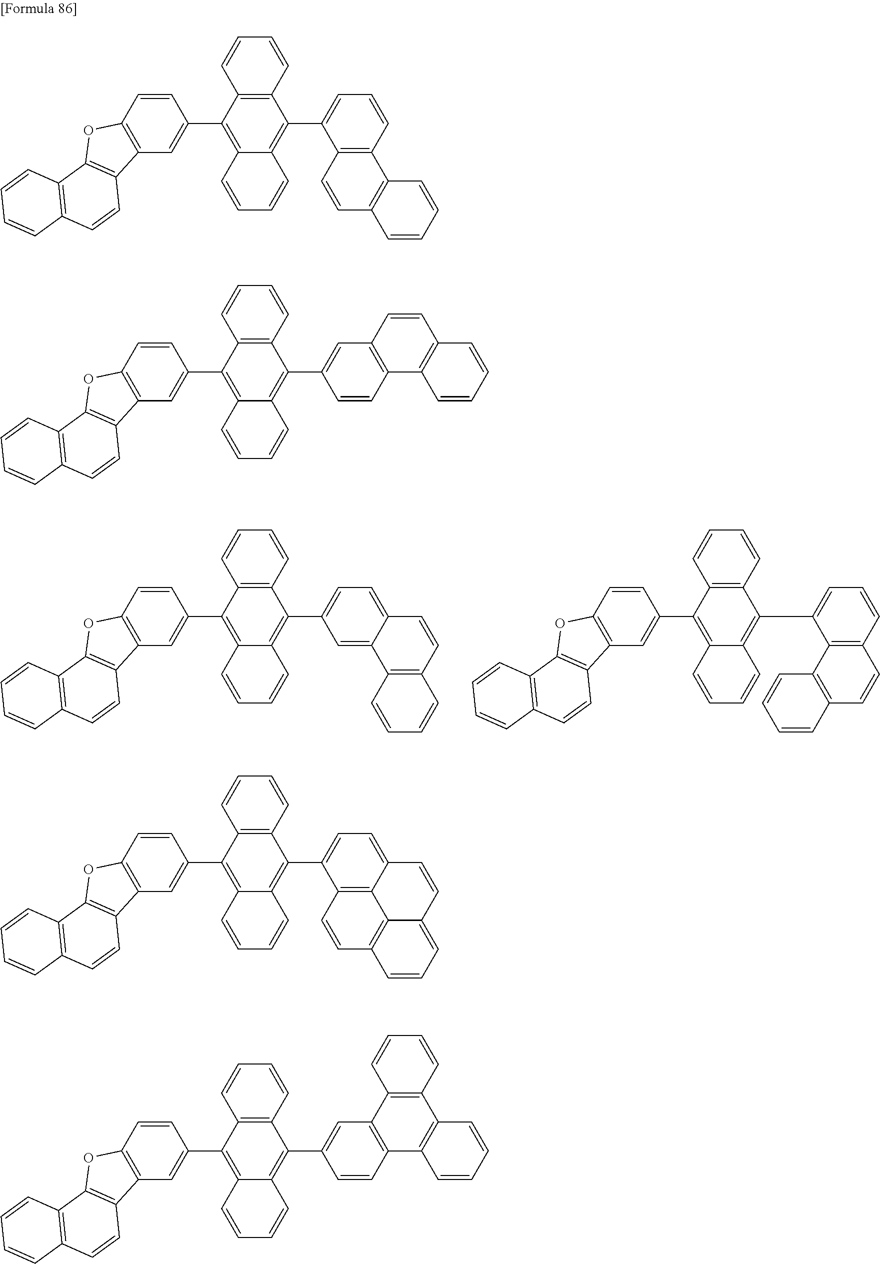

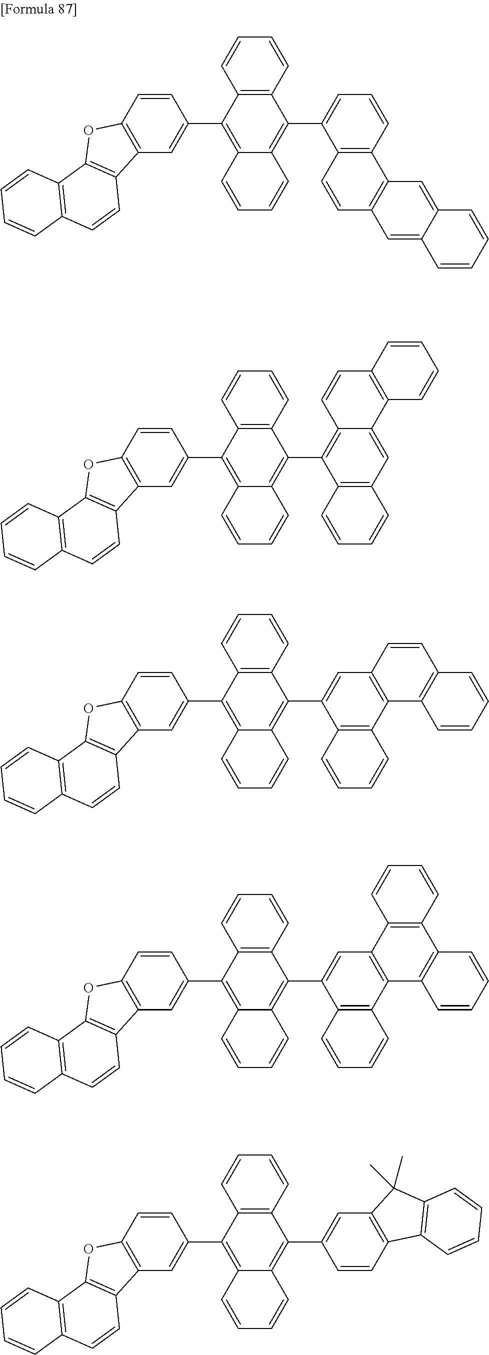 [SMILES: c1ccc2cc3c(ccc4c(-c5c6ccccc6c(-c6ccc7oc8c9ccccc9ccc8c7c6)c6ccccc56)cccc43)cc2c1 ; c1ccc2c(-c3c4ccccc4c(-c4ccc5oc6c7ccccc7ccc6c5c4)c4ccccc34)c3ccc4ccccc4c3cc2c1 ; c1ccc2c(c1)ccc1c3cc(-c4c5ccccc5c(-c5cc6ccc7ccccc7c6c6ccccc56)c5ccccc45)ccc3oc21 ; c1ccc2c(c1)ccc1c3cc(-c4c5ccccc5c(-c5cc6c7ccccc7c7ccccc7c6c6ccccc56)c5ccccc45)ccc3oc21 ; CC1(C)c2ccccc2-c2ccc(-c3c4ccccc4c(-c4ccc5oc6c7ccccc7ccc6c5c4)c4ccccc34)cc21]

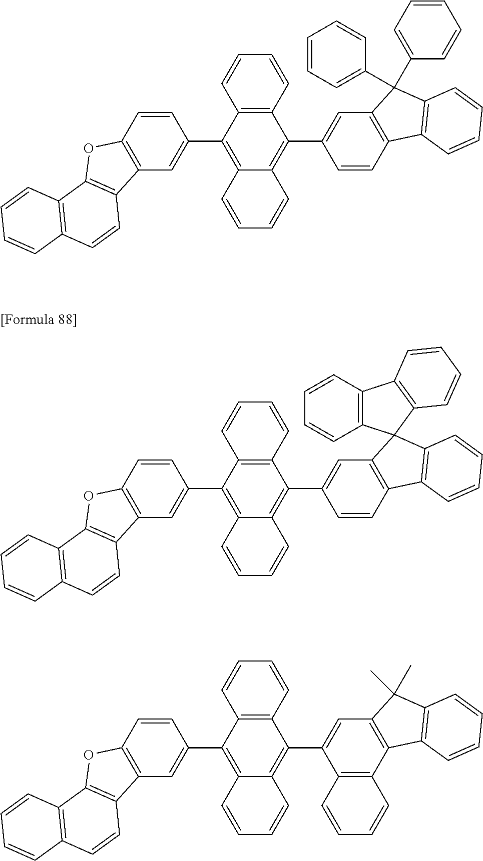 [SMILES: c1ccc(C2(c3ccccc3)c3ccccc3-c3ccc(-c4c5ccccc5c(-c5ccc6oc7c8ccccc8ccc7c6c5)c5ccccc45)cc32)cc1 ; c1ccc2c(c1)-c1ccccc1C21c2ccccc2-c2ccc(-c3c4ccccc4c(-c4ccc5oc6c7ccccc7ccc6c5c4)c4ccccc34)cc21 ; CC1(C)c2ccccc2-c2c1cc(-c1c3ccccc3c(-c3ccc4oc5c6ccccc6ccc5c4c3)c3ccccc13)c1ccccc21]

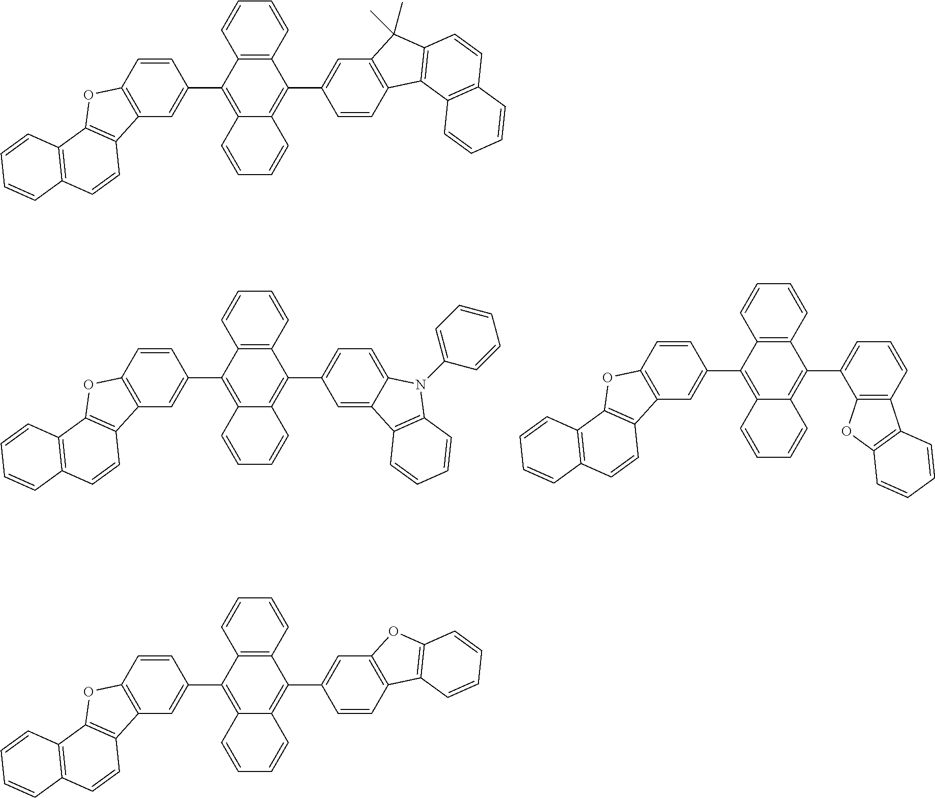 [SMILES: CC1(C)c2cc(-c3c4ccccc4c(-c4ccc5oc6c7ccccc7ccc6c5c4)c4ccccc34)ccc2-c2c1ccc1ccccc21 ; c1ccc(-n2c3ccccc3c3cc(-c4c5ccccc5c(-c5ccc6oc7c8ccccc8ccc7c6c5)c5ccccc45)ccc32)cc1 ; c1ccc2c(c1)ccc1c3cc(-c4c5ccccc5c(-c5cccc6c5oc5ccccc56)c5ccccc45)ccc3oc21 ; c1ccc2c(c1)ccc1c3cc(-c4c5ccccc5c(-c5ccc6c(c5)oc5ccccc56)c5ccccc45)ccc3oc21]

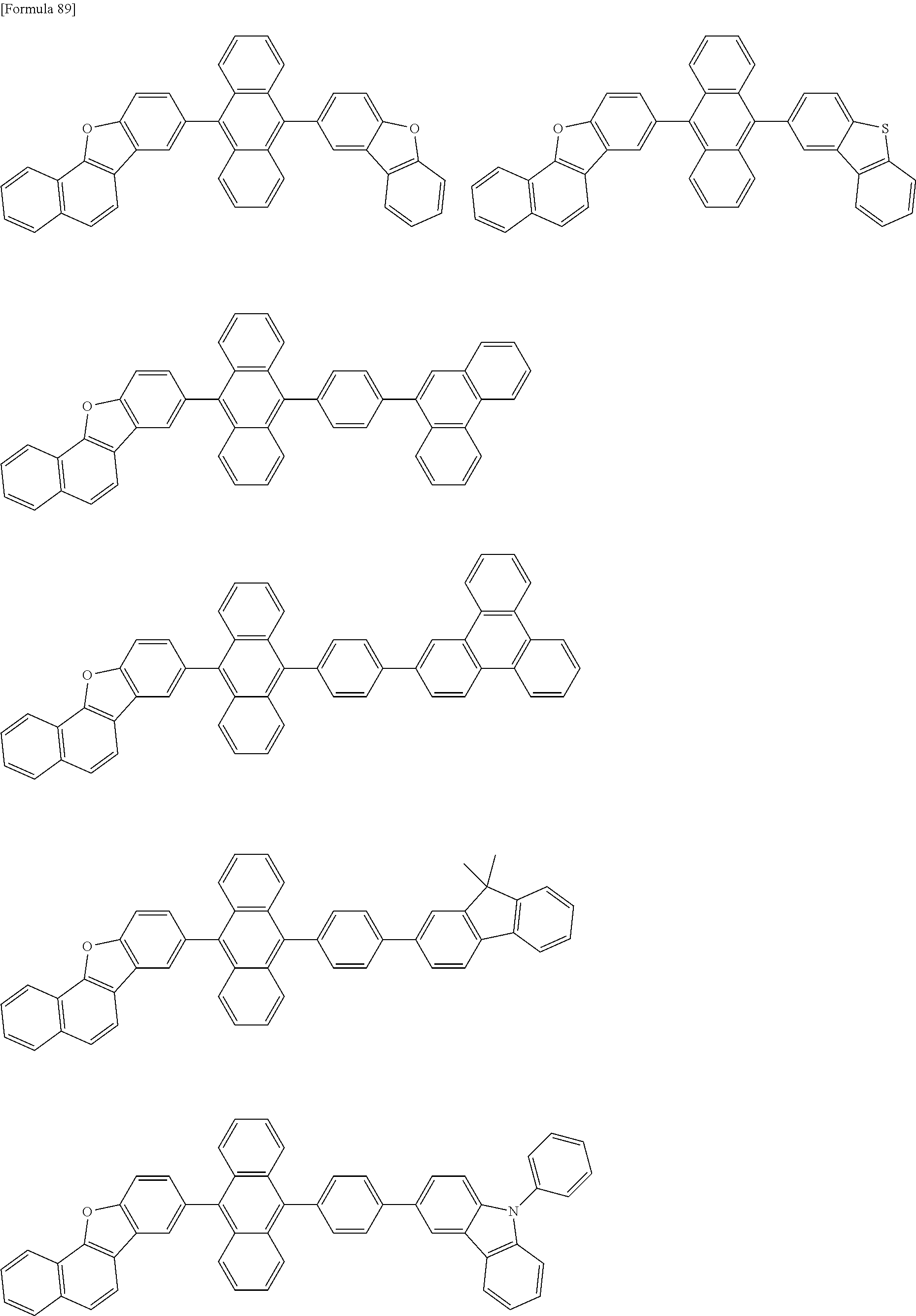

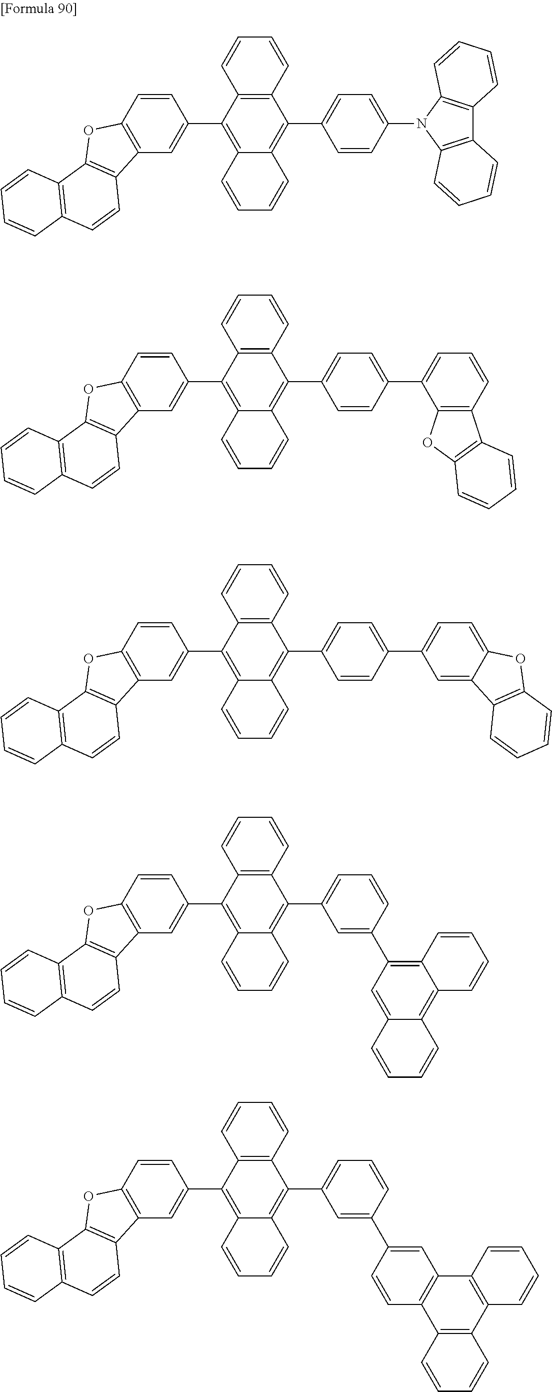 [SMILES: c1ccc2c(c1)ccc1c3cc(-c4c5ccccc5c(-c5ccc(-n6c7ccccc7c7ccccc76)cc5)c5ccccc45)ccc3oc21 ; c1ccc2c(c1)ccc1c3cc(-c4c5ccccc5c(-c5ccc(-c6cccc7c6oc6ccccc67)cc5)c5ccccc45)ccc3oc21 ; c1ccc2c(c1)ccc1c3cc(-c4c5ccccc5c(-c5ccc(-c6ccc7oc8ccccc8c7c6)cc5)c5ccccc45)ccc3oc21 ; c1cc(-c2c3ccccc3c(-c3ccc4oc5c6ccccc6ccc5c4c3)c3ccccc23)cc(-c2cc3ccccc3c3ccccc23)c1 ; c1cc(-c2ccc3c4ccccc4c4ccccc4c3c2)cc(-c2c3ccccc3c(-c3ccc4oc5c6ccccc6ccc5c4c3)c3ccccc23)c1]

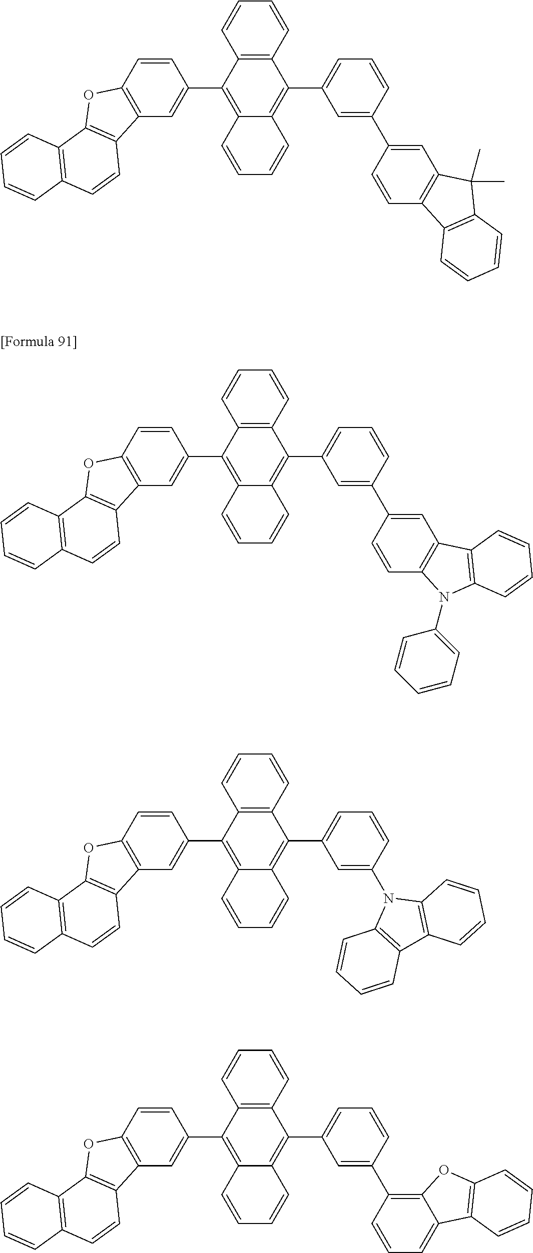 [SMILES: CC1(C)c2ccccc2-c2ccc(-c3cccc(-c4c5ccccc5c(-c5ccc6oc7c8ccccc8ccc7c6c5)c5ccccc45)c3)cc21 ; c1ccc(-n2c3ccccc3c3cc(-c4cccc(-c5c6ccccc6c(-c6ccc7oc8c9ccccc9ccc8c7c6)c6ccccc56)c4)ccc32)cc1 ; c1cc(-c2c3ccccc3c(-c3ccc4oc5c6ccccc6ccc5c4c3)c3ccccc23)cc(-n2c3ccccc3c3ccccc32)c1 ; c1cc(-c2c3ccccc3c(-c3ccc4oc5c6ccccc6ccc5c4c3)c3ccccc23)cc(-c2cccc3c2oc2ccccc23)c1]

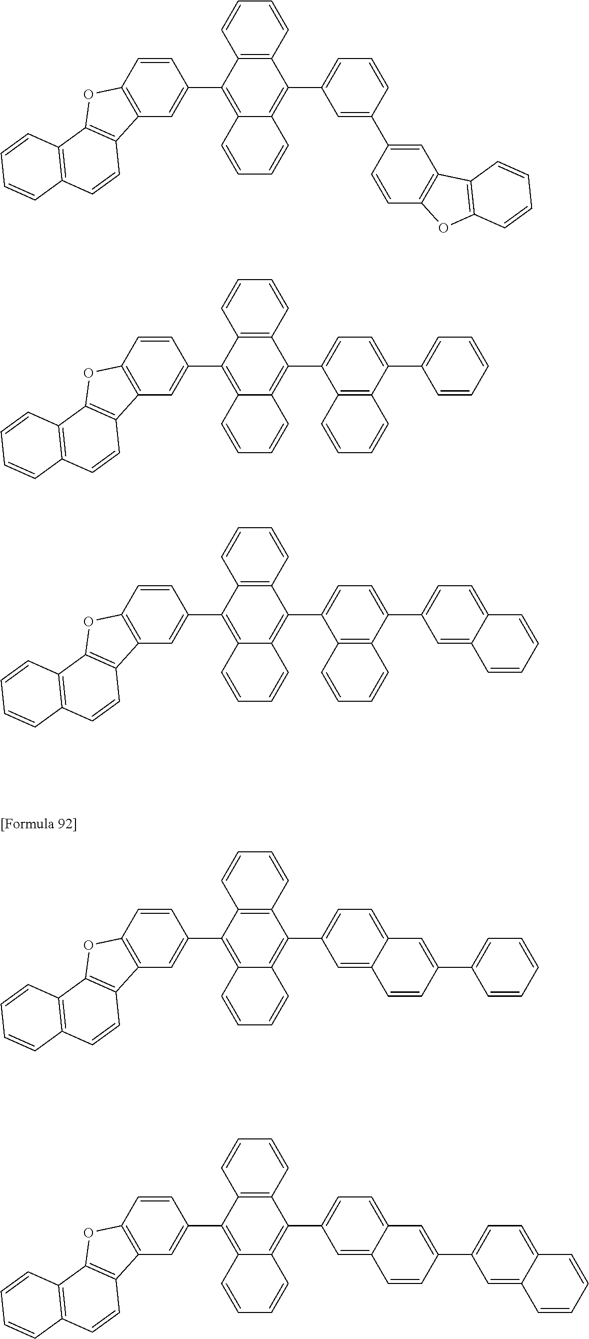 [SMILES: c1cc(-c2ccc3oc4ccccc4c3c2)cc(-c2c3ccccc3c(-c3ccc4oc5c6ccccc6ccc5c4c3)c3ccccc23)c1 ; c1ccc(-c2ccc(-c3c4ccccc4c(-c4ccc5oc6c7ccccc7ccc6c5c4)c4ccccc34)c3ccccc23)cc1 ; c1ccc2cc(-c3ccc(-c4c5ccccc5c(-c5ccc6oc7c8ccccc8ccc7c6c5)c5ccccc45)c4ccccc34)ccc2c1 ; c1ccc(-c2ccc3cc(-c4c5ccccc5c(-c5ccc6oc7c8ccccc8ccc7c6c5)c5ccccc45)ccc3c2)cc1 ; c1ccc2cc(-c3ccc4cc(-c5c6ccccc6c(-c6ccc7oc8c9ccccc9ccc8c7c6)c6ccccc56)ccc4c3)ccc2c1]

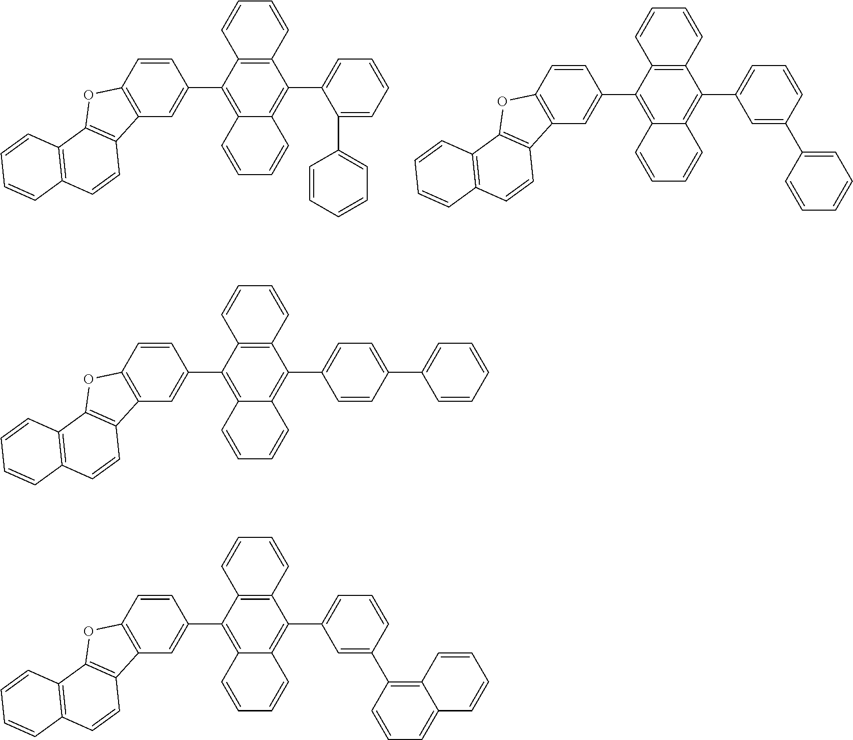 [SMILES: c1ccc(-c2ccccc2-c2c3ccccc3c(-c3ccc4oc5c6ccccc6ccc5c4c3)c3ccccc23)cc1 ; c1ccc(-c2cccc(-c3c4ccccc4c(-c4ccc5oc6c7ccccc7ccc6c5c4)c4ccccc34)c2)cc1 ; c1ccc(-c2ccc(-c3c4ccccc4c(-c4ccc5oc6c7ccccc7ccc6c5c4)c4ccccc34)cc2)cc1 ; c1cc(-c2cccc3ccccc23)cc(-c2c3ccccc3c(-c3ccc4oc5c6ccccc6ccc5c4c3)c3ccccc23)c1]

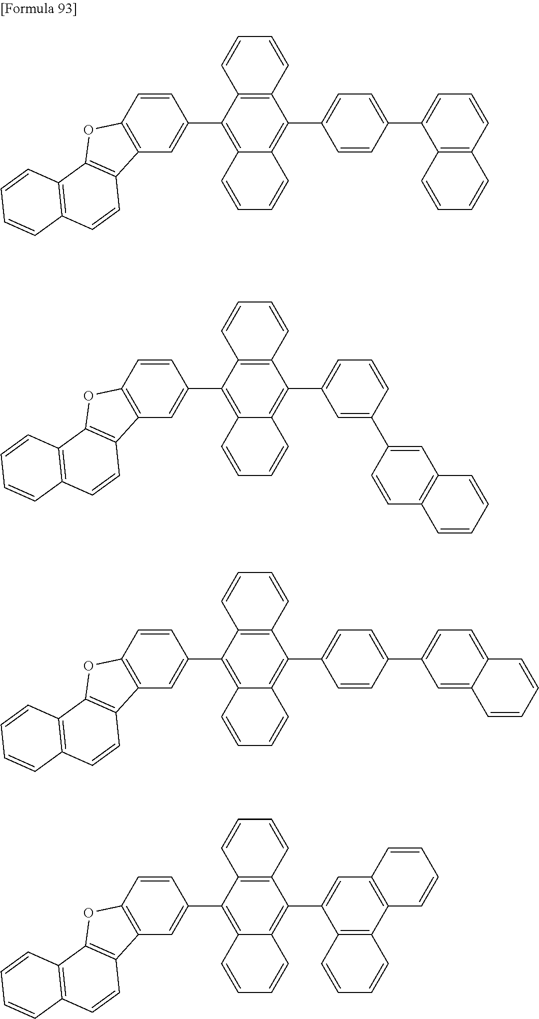 [SMILES: c1ccc2c(-c3ccc(-c4c5ccccc5c(-c5ccc6oc7c8ccccc8ccc7c6c5)c5ccccc45)cc3)cccc2c1 ; c1cc(-c2ccc3ccccc3c2)cc(-c2c3ccccc3c(-c3ccc4oc5c6ccccc6ccc5c4c3)c3ccccc23)c1 ; c1ccc2cc(-c3ccc(-c4c5ccccc5c(-c5ccc6oc7c8ccccc8ccc7c6c5)c5ccccc45)cc3)ccc2c1 ; c1ccc2c(c1)cc(-c1c3ccccc3c(-c3ccc4oc5c6ccccc6ccc5c4c3)c3ccccc13)c1ccccc12]

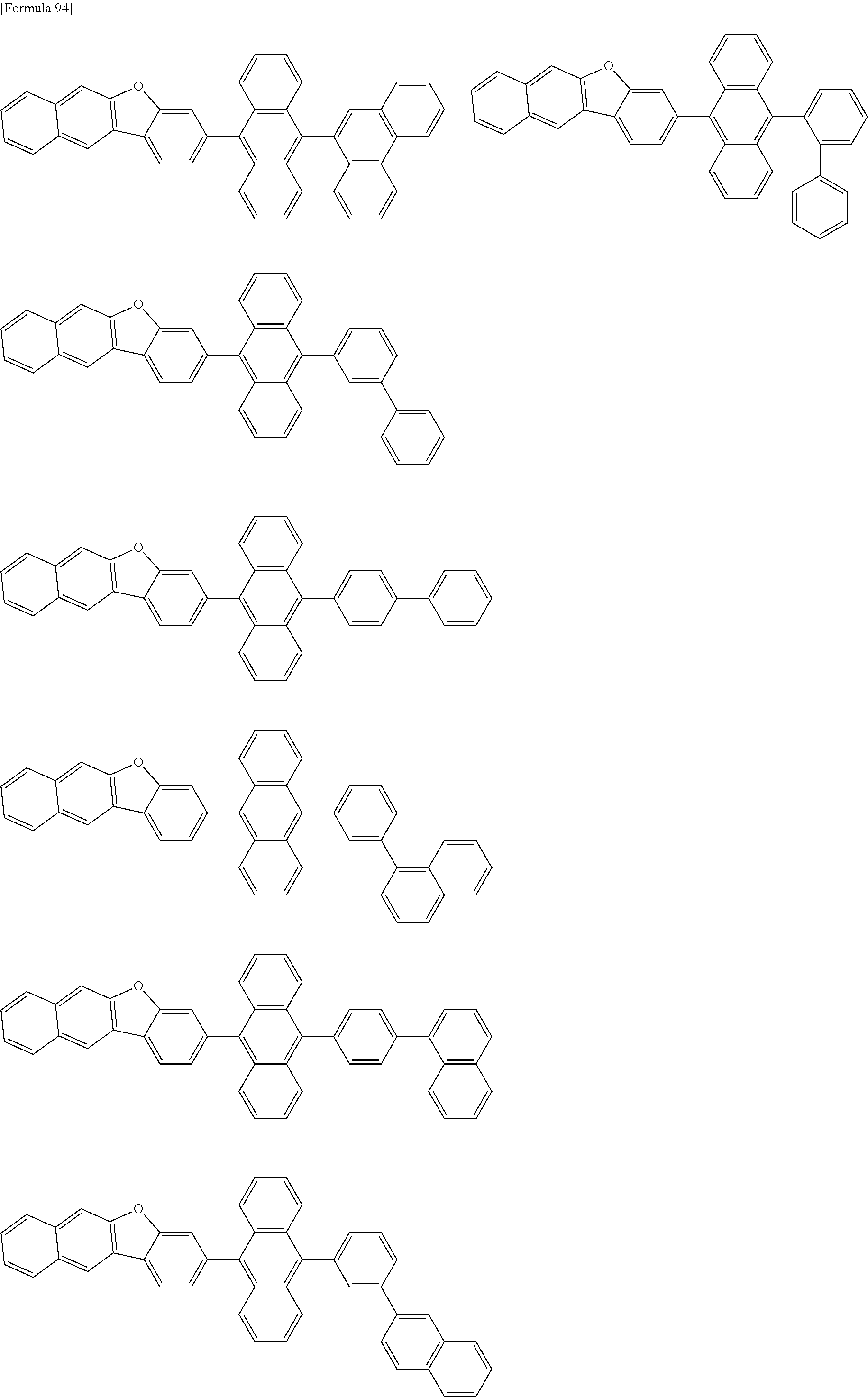

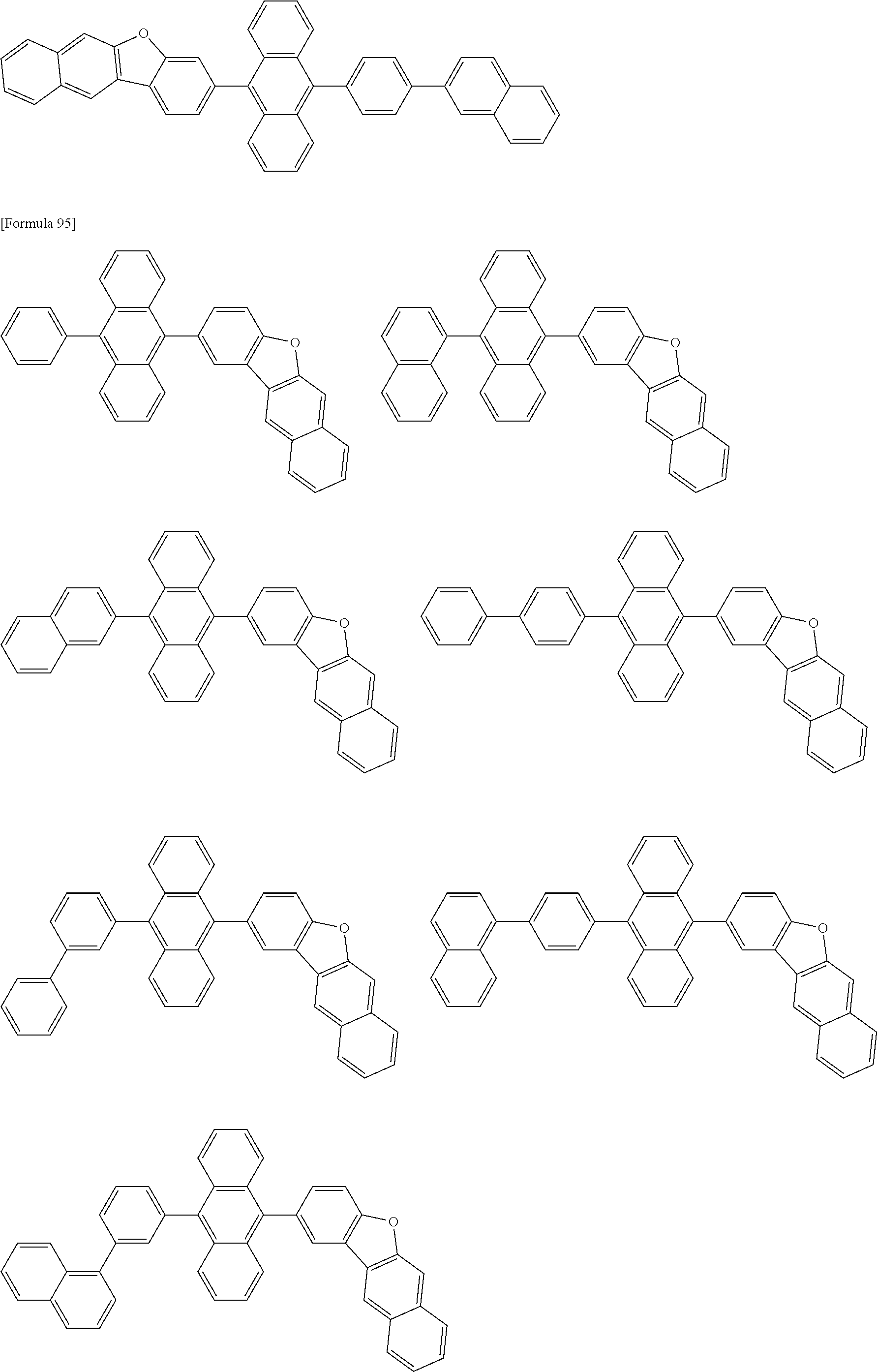

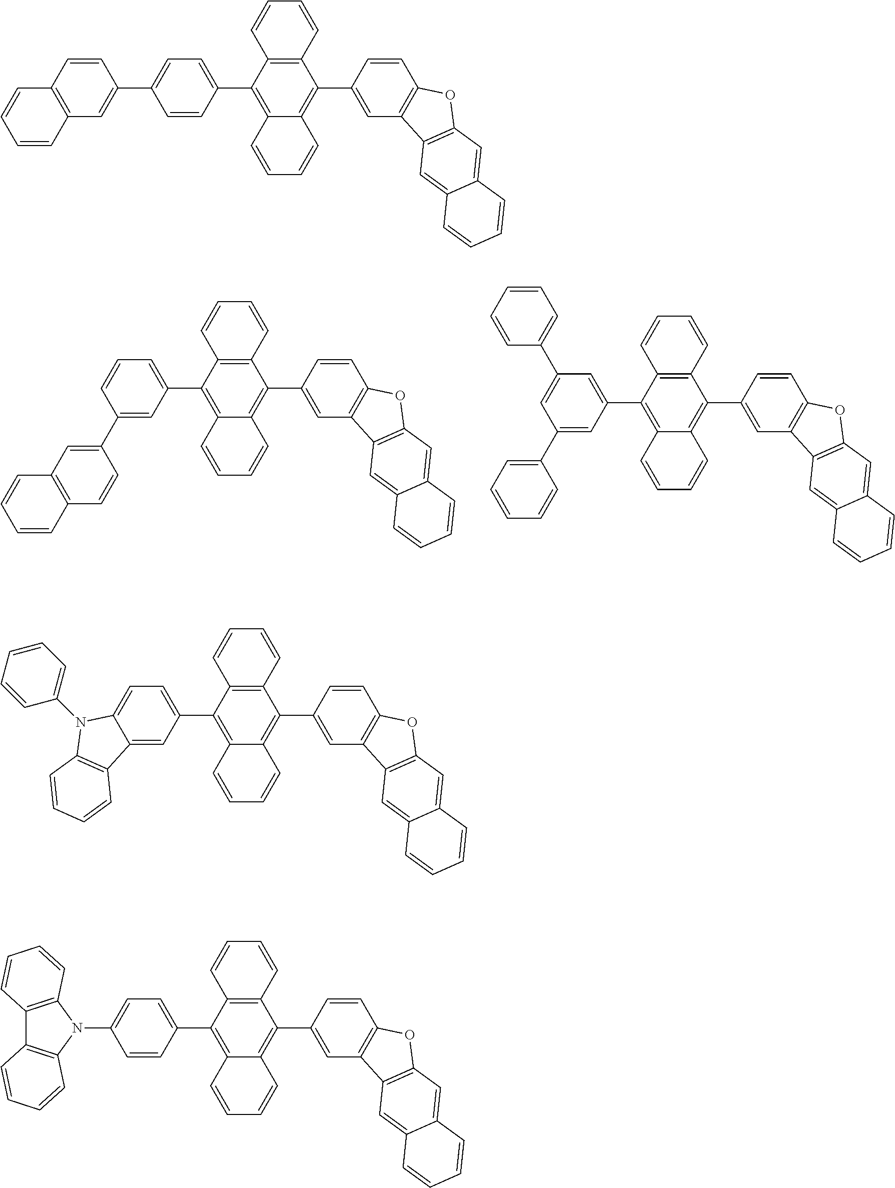

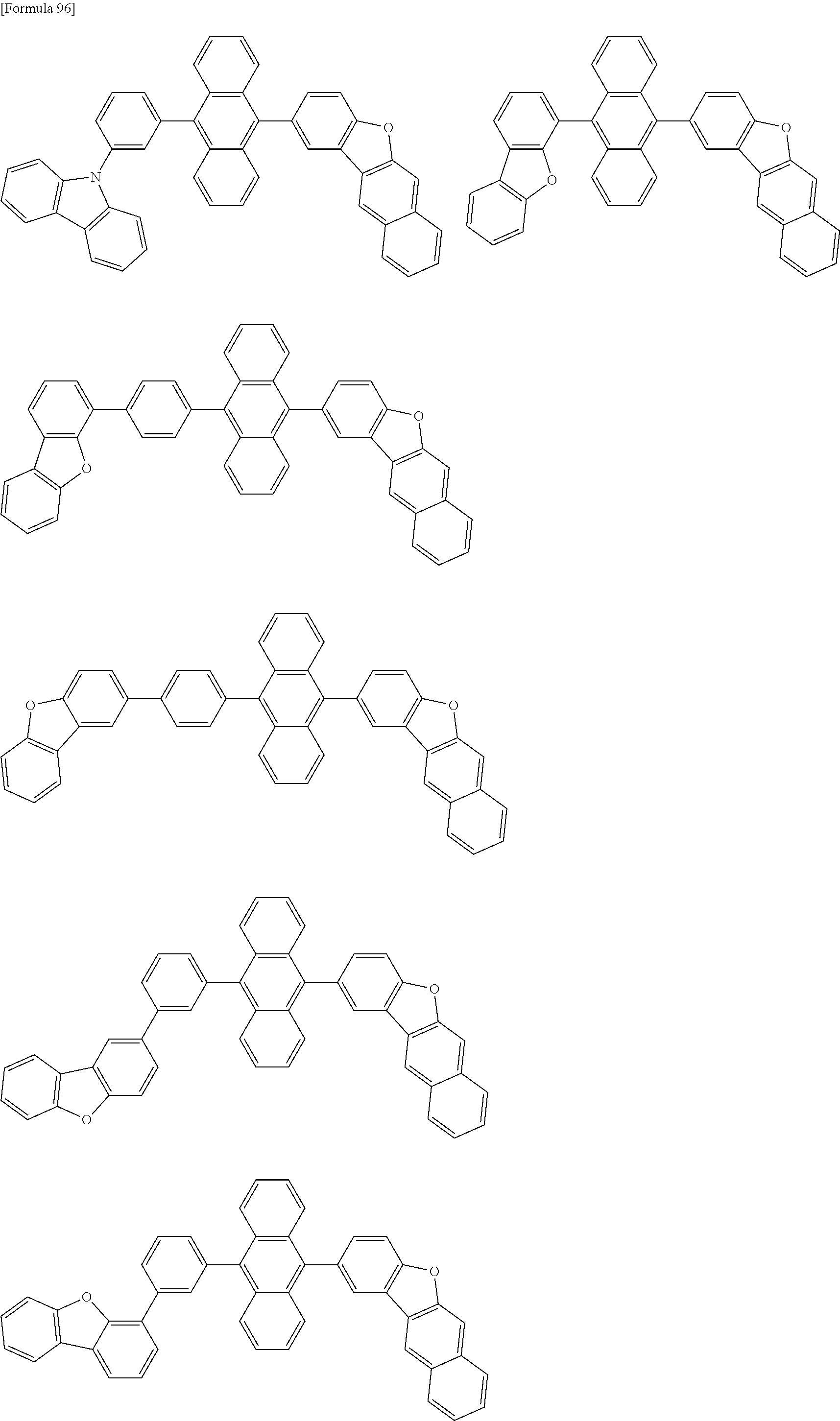

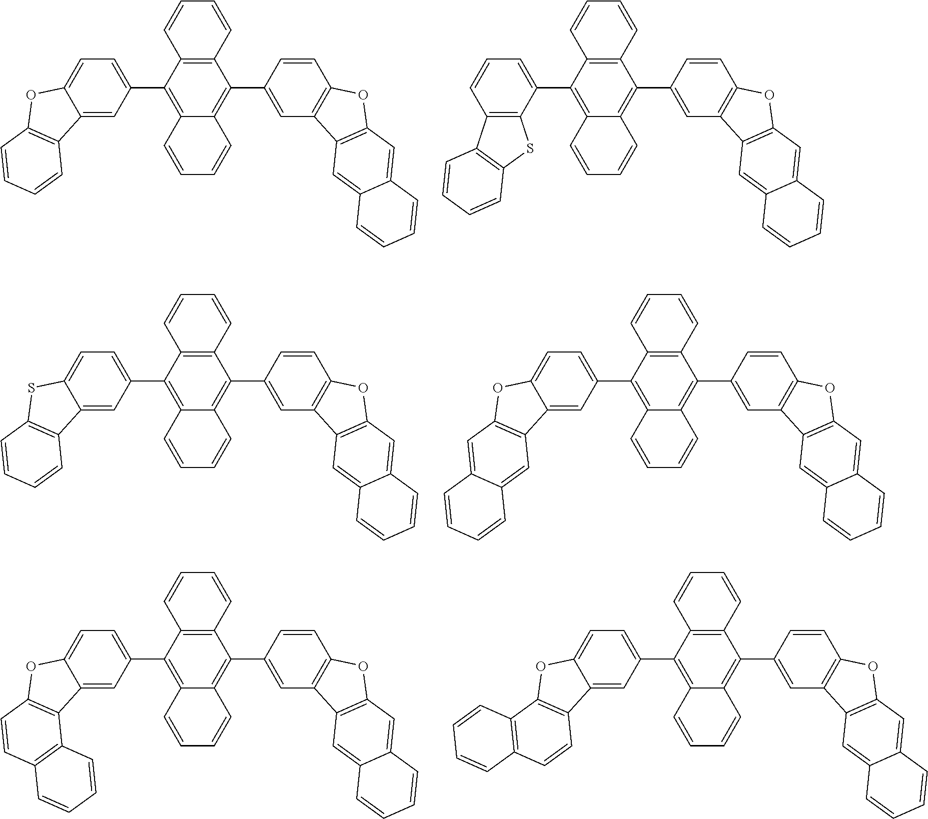

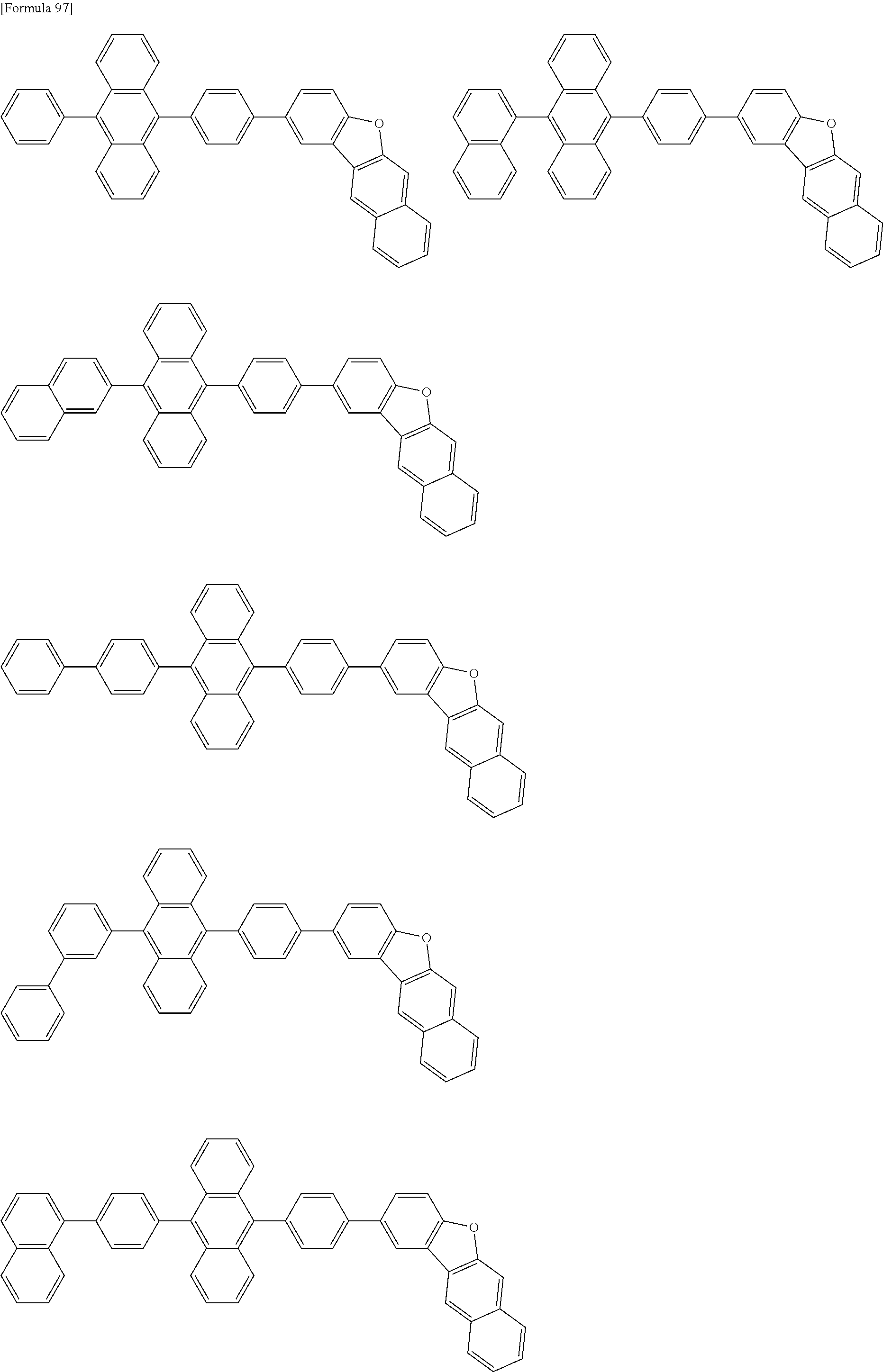 [SMILES: c1ccc(-c2c3ccccc3c(-c3ccc(-c4ccc5oc6cc7ccccc7cc6c5c4)cc3)c3ccccc23)cc1 ; c1ccc2cc3c(cc2c1)oc1ccc(-c2ccc(-c4c5ccccc5c(-c5cccc6ccccc56)c5ccccc45)cc2)cc13 ; c1ccc2cc(-c3c4ccccc4c(-c4ccc(-c5ccc6oc7cc8ccccc8cc7c6c5)cc4)c4ccccc34)ccc2c1 ; c1ccc(-c2ccc(-c3c4ccccc4c(-c4ccc(-c5ccc6oc7cc8ccccc8cc7c6c5)cc4)c4ccccc34)cc2)cc1 ; c1ccc(-c2cccc(-c3c4ccccc4c(-c4ccc(-c5ccc6oc7cc8ccccc8cc7c6c5)cc4)c4ccccc34)c2)cc1 ; c1ccc2cc3c(cc2c1)oc1ccc(-c2ccc(-c4c5ccccc5c(-c5ccc(-c6cccc7ccccc67)cc5)c5ccccc45)cc2)cc13]

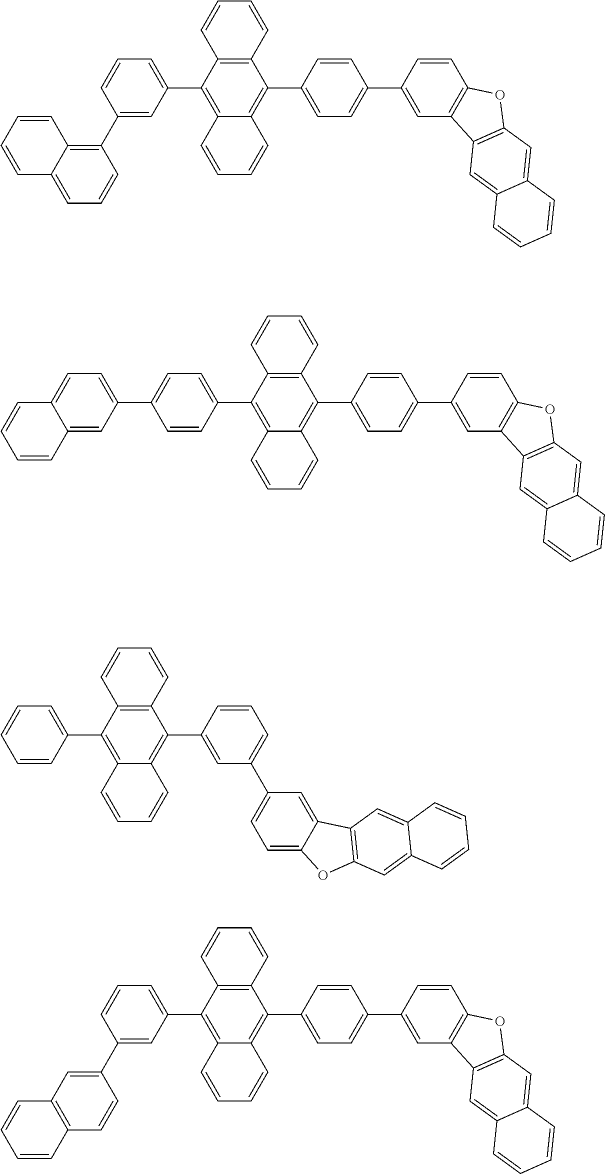 [SMILES: c1cc(-c2cccc3ccccc23)cc(-c2c3ccccc3c(-c3ccc(-c4ccc5oc6cc7ccccc7cc6c5c4)cc3)c3ccccc23)c1 ; c1ccc2cc(-c3ccc(-c4c5ccccc5c(-c5ccc(-c6ccc7oc8cc9ccccc9cc8c7c6)cc5)c5ccccc45)cc3)ccc2c1 ; c1ccc(-c2c3ccccc3c(-c3cccc(-c4ccc5oc6cc7ccccc7cc6c5c4)c3)c3ccccc23)cc1 ; c1cc(-c2ccc3ccccc3c2)cc(-c2c3ccccc3c(-c3ccc(-c4ccc5oc6cc7ccccc7cc6c5c4)cc3)c3ccccc23)c1]

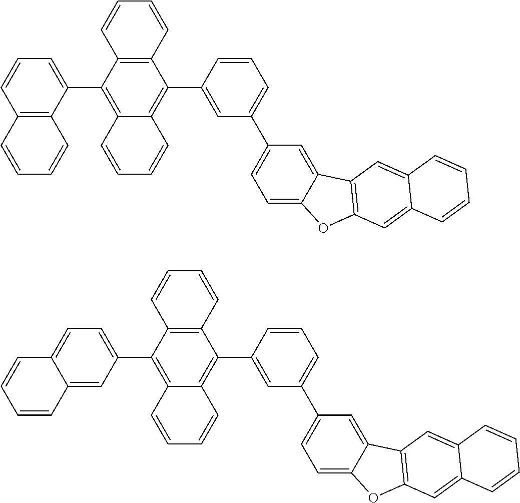 [SMILES: c1cc(-c2ccc3oc4cc5ccccc5cc4c3c2)cc(-c2c3ccccc3c(-c3cccc4ccccc34)c3ccccc23)c1 ; c1cc(-c2ccc3oc4cc5ccccc5cc4c3c2)cc(-c2c3ccccc3c(-c3ccc4ccccc4c3)c3ccccc23)c1]

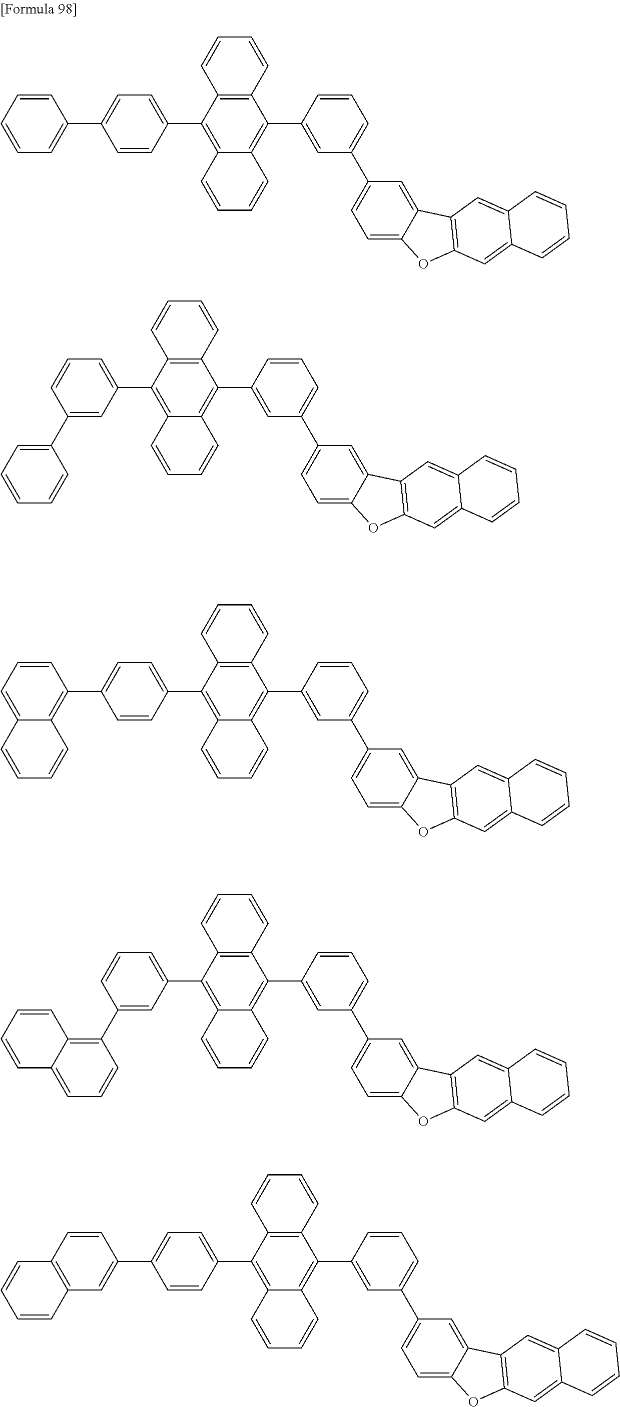 [SMILES: c1ccc(-c2ccc(-c3c4ccccc4c(-c4cccc(-c5ccc6oc7cc8ccccc8cc7c6c5)c4)c4ccccc34)cc2)cc1 ; c1ccc(-c2cccc(-c3c4ccccc4c(-c4cccc(-c5ccc6oc7cc8ccccc8cc7c6c5)c4)c4ccccc34)c2)cc1 ; c1cc(-c2ccc3oc4cc5ccccc5cc4c3c2)cc(-c2c3ccccc3c(-c3ccc(-c4cccc5ccccc45)cc3)c3ccccc23)c1 ; c1cc(-c2ccc3oc4cc5ccccc5cc4c3c2)cc(-c2c3ccccc3c(-c3cccc(-c4cccc5ccccc45)c3)c3ccccc23)c1 ; c1cc(-c2ccc3oc4cc5ccccc5cc4c3c2)cc(-c2c3ccccc3c(-c3ccc(-c4ccc5ccccc5c4)cc3)c3ccccc23)c1]

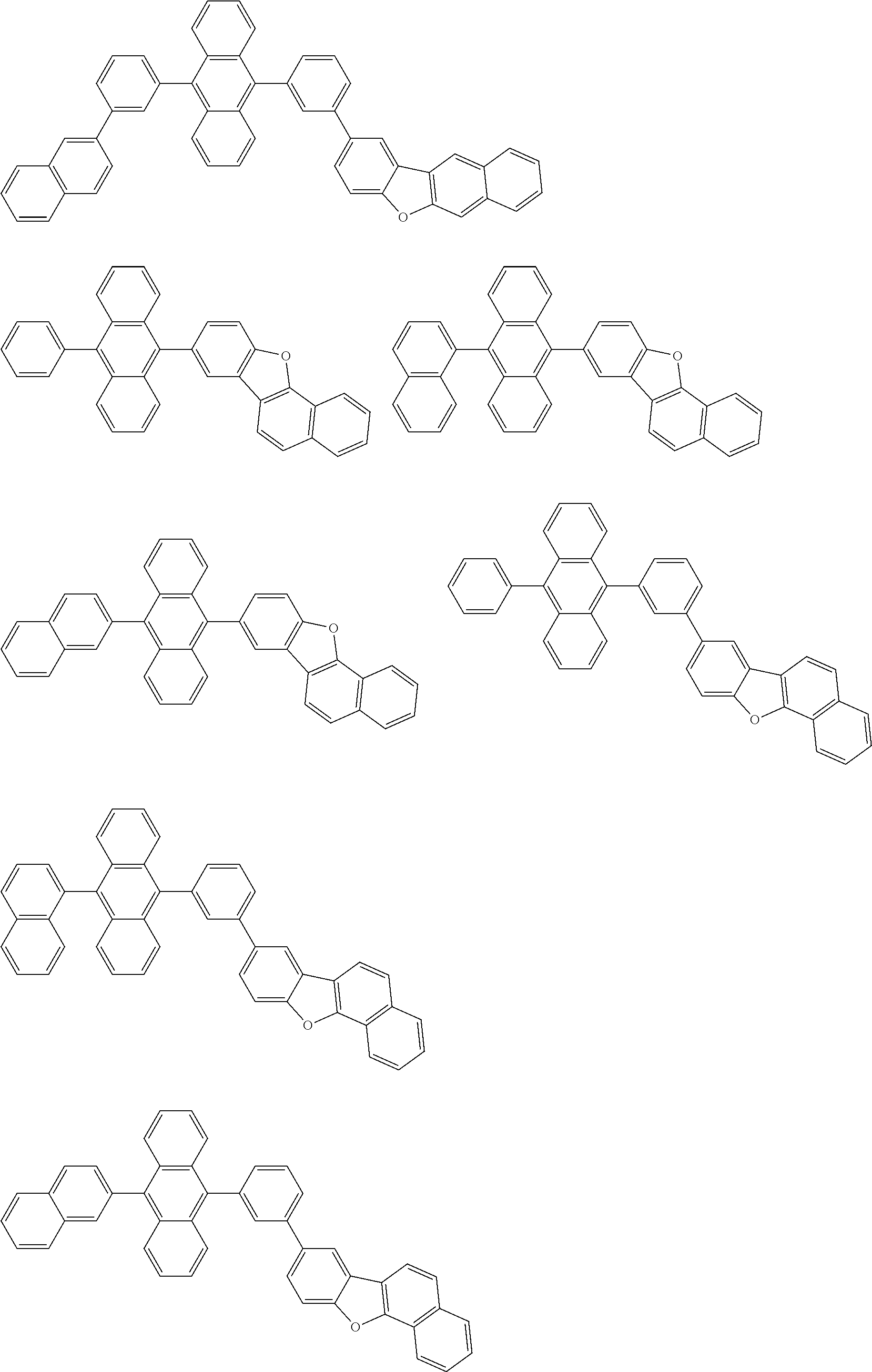

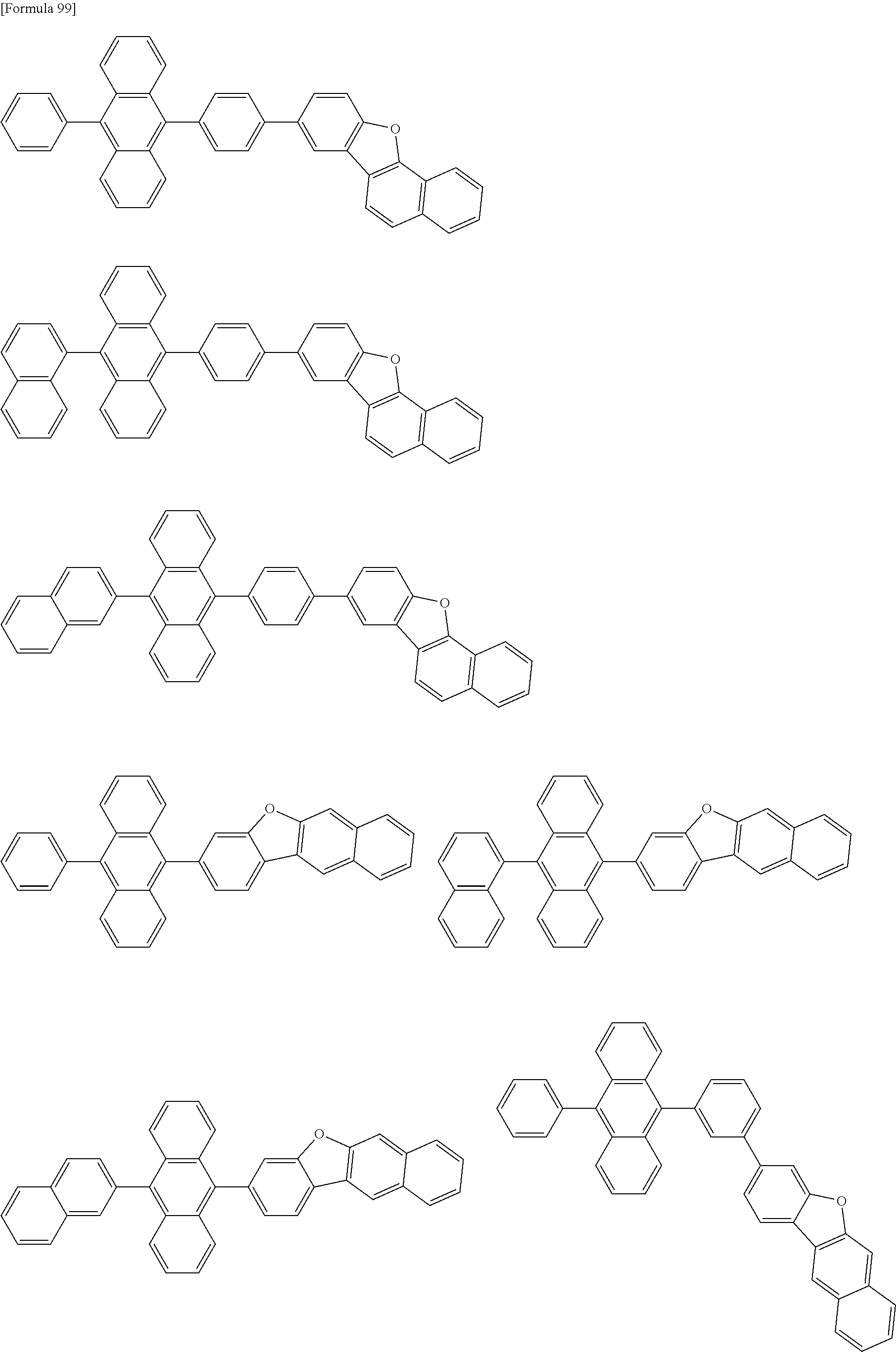

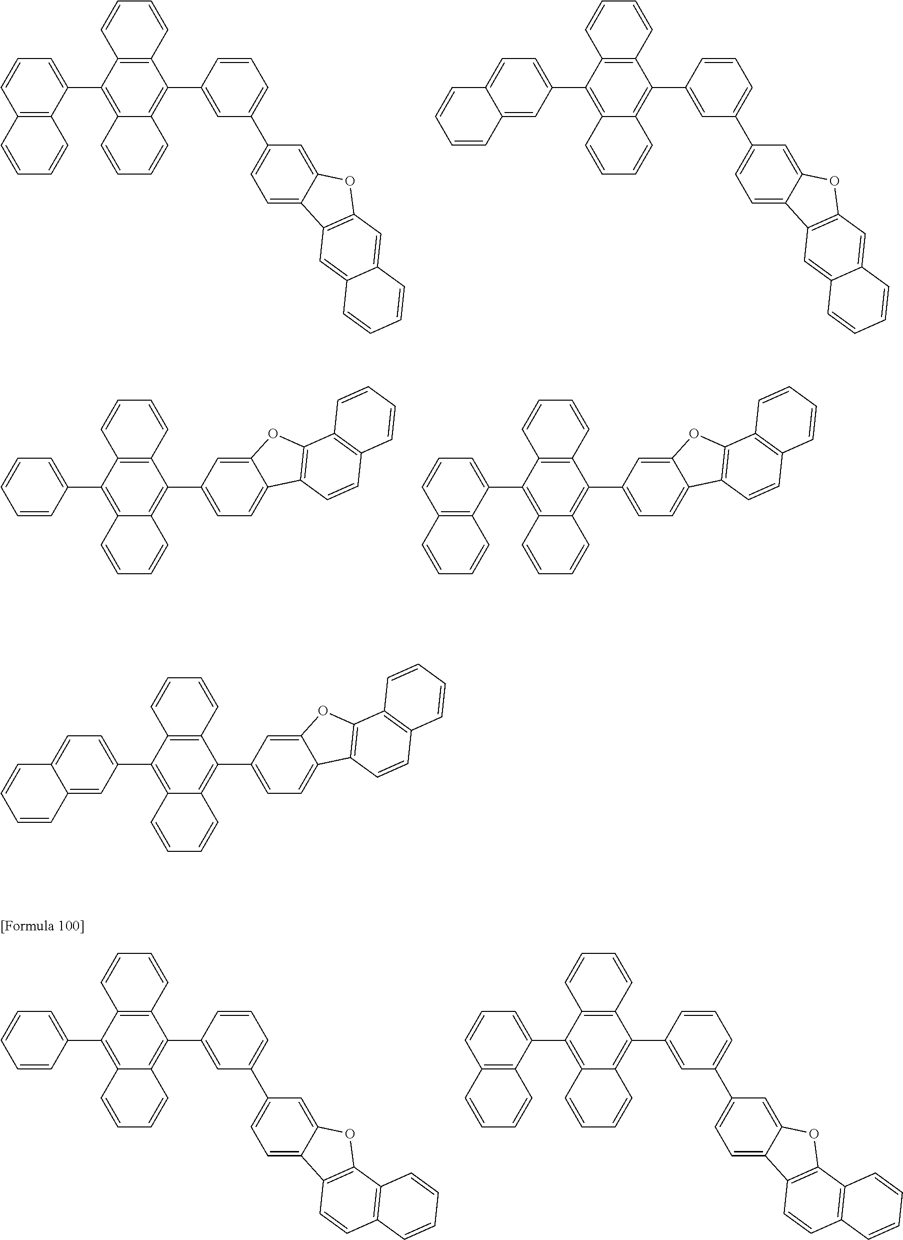

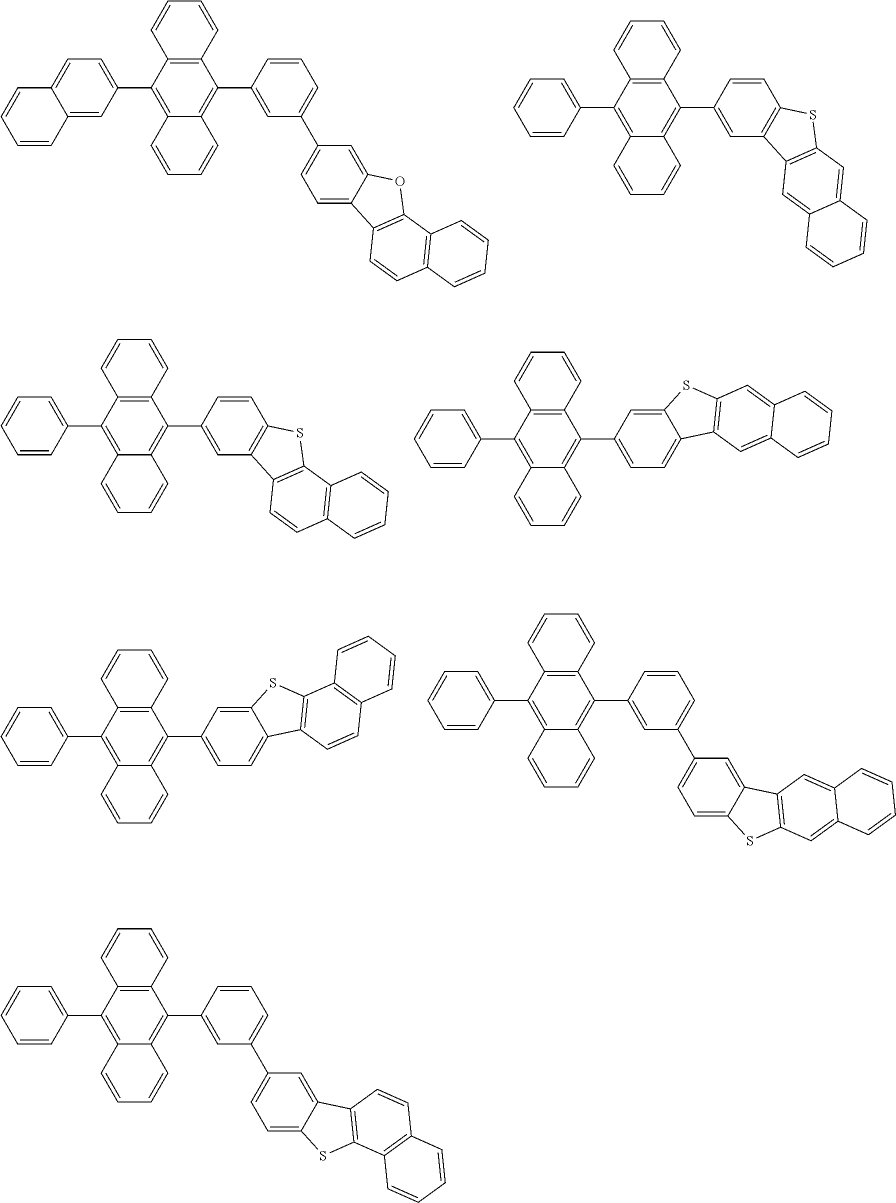

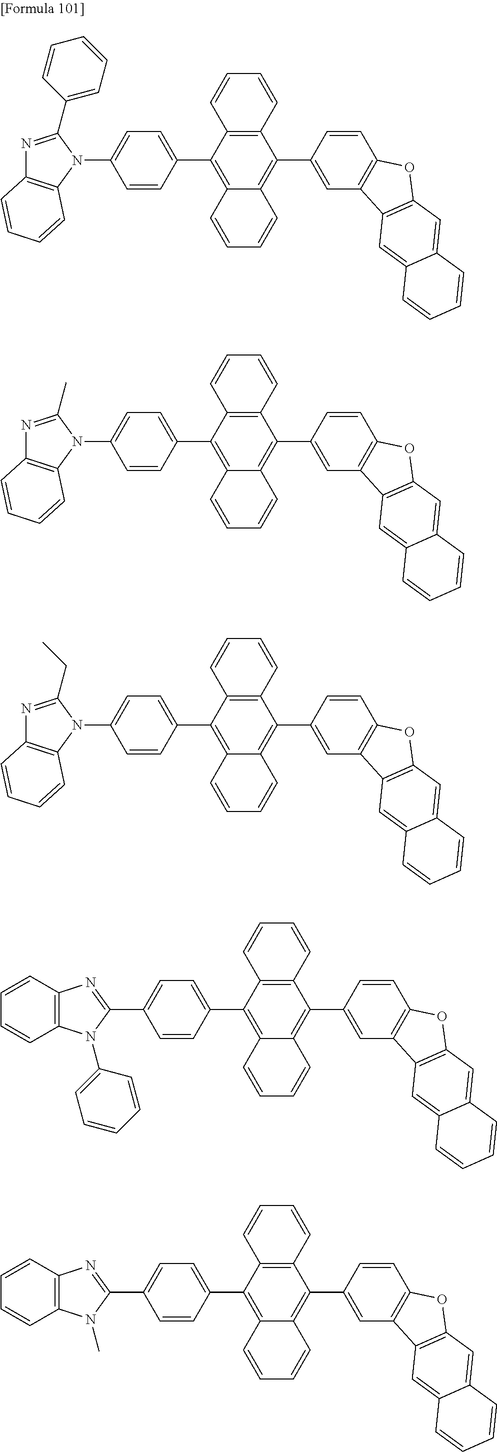 [SMILES: c1ccc(-c2nc3ccccc3n2-c2ccc(-c3c4ccccc4c(-c4ccc5oc6cc7ccccc7cc6c5c4)c4ccccc34)cc2)cc1 ; Cc1nc2ccccc2n1-c1ccc(-c2c3ccccc3c(-c3ccc4oc5cc6ccccc6cc5c4c3)c3ccccc23)cc1 ; CCc1nc2ccccc2n1-c1ccc(-c2c3ccccc3c(-c3ccc4oc5cc6ccccc6cc5c4c3)c3ccccc23)cc1 ; c1ccc(-n2c(-c3ccc(-c4c5ccccc5c(-c5ccc6oc7cc8ccccc8cc7c6c5)c5ccccc45)cc3)nc3ccccc32)cc1 ; Cn1c(-c2ccc(-c3c4ccccc4c(-c4ccc5oc6cc7ccccc7cc6c5c4)c4ccccc34)cc2)nc2ccccc21]

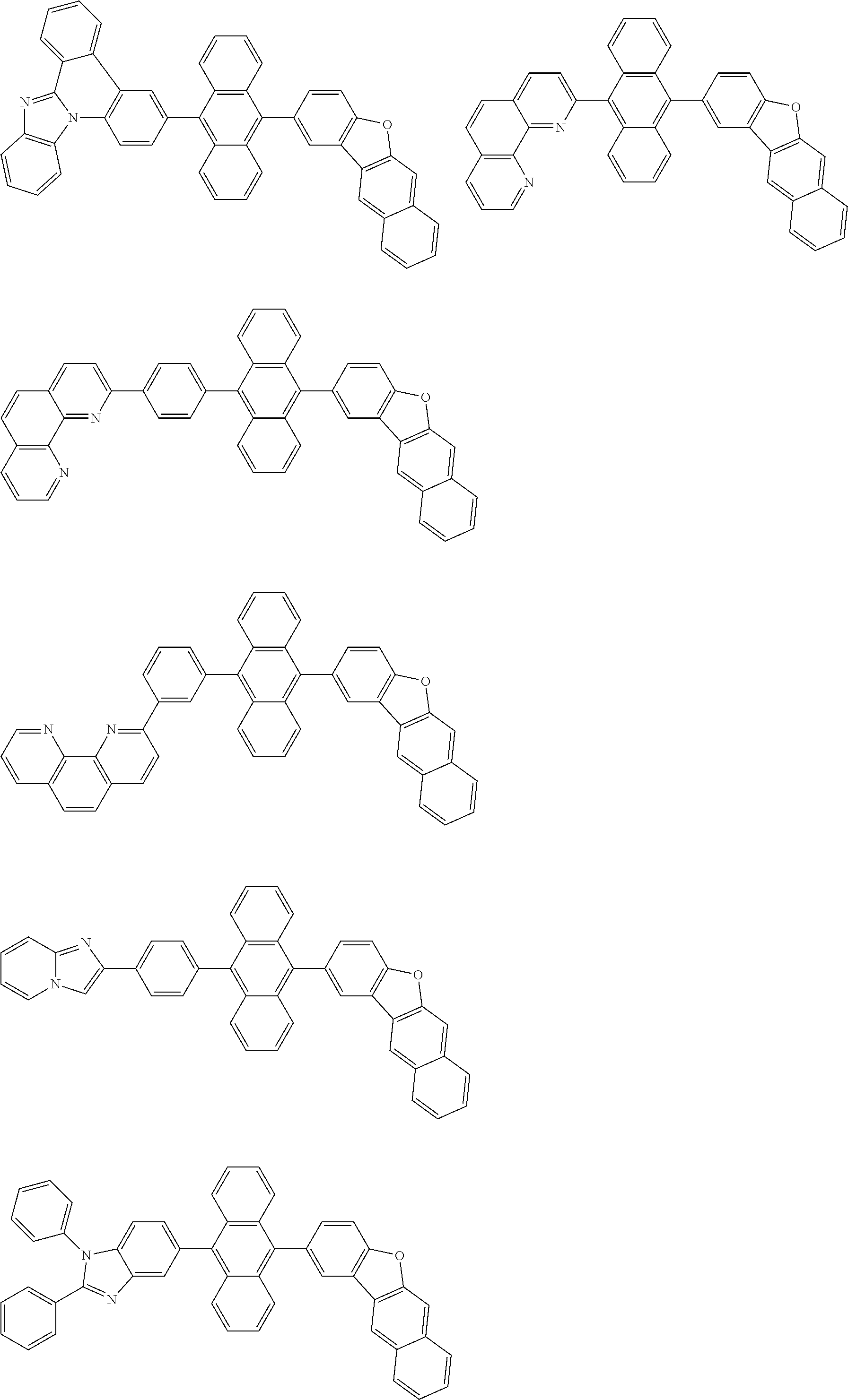

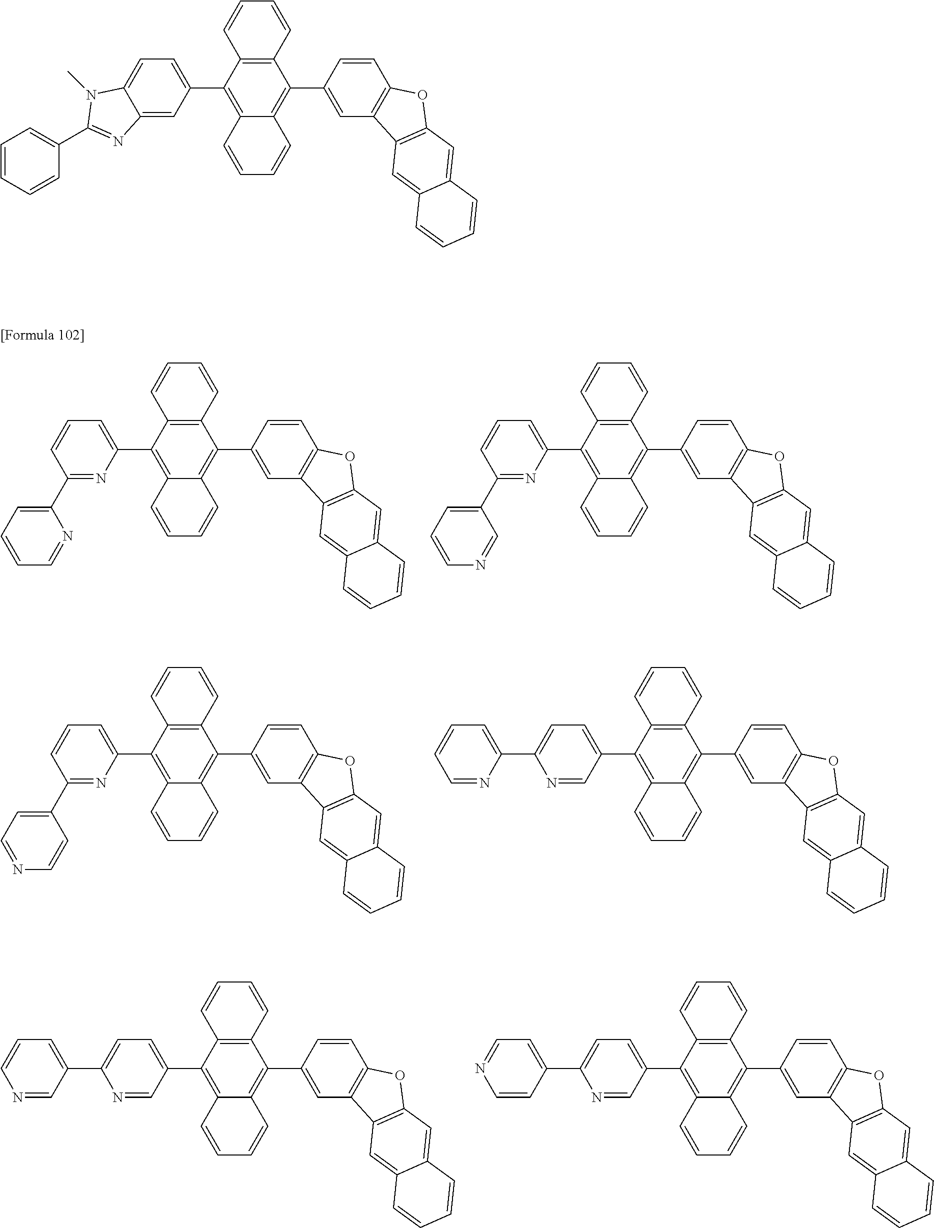

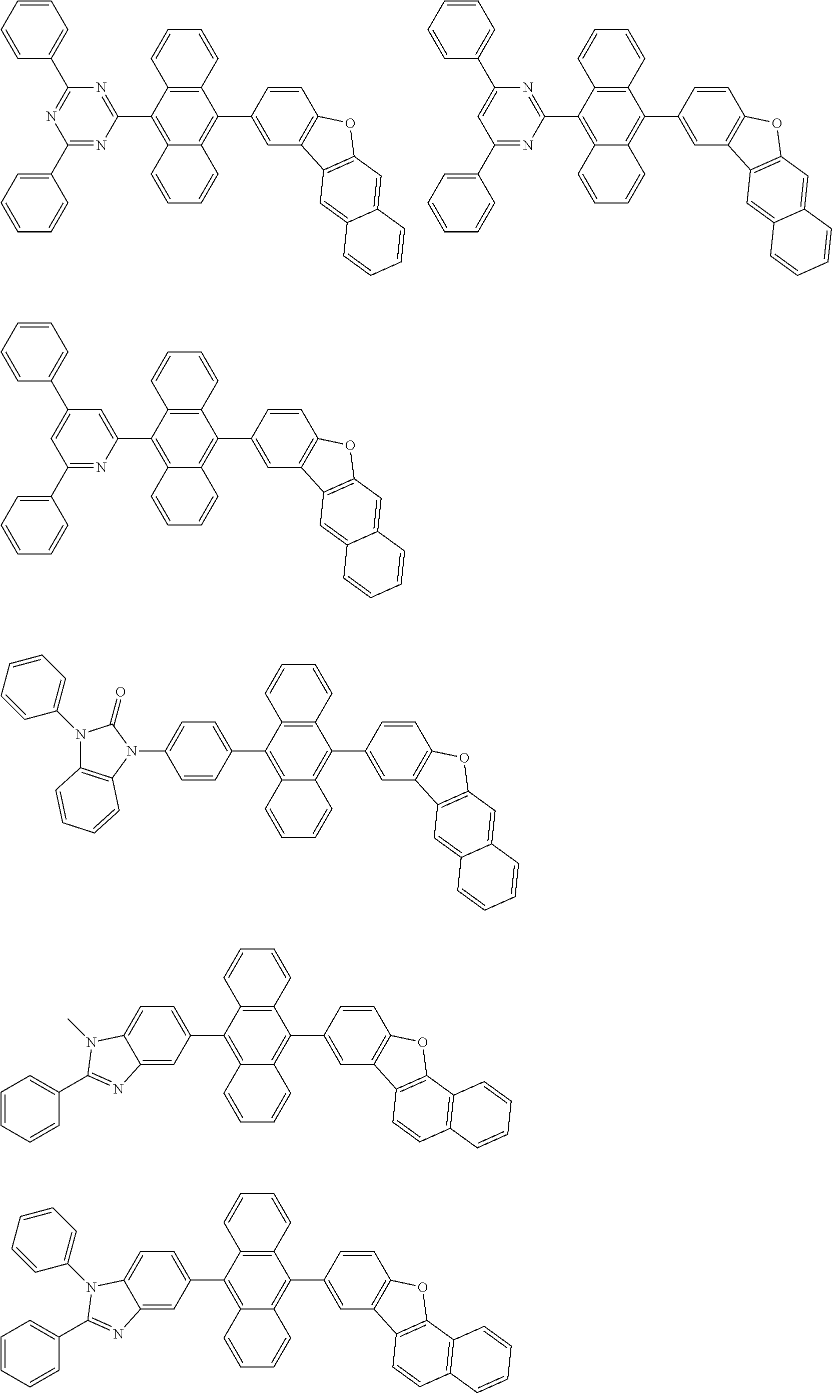

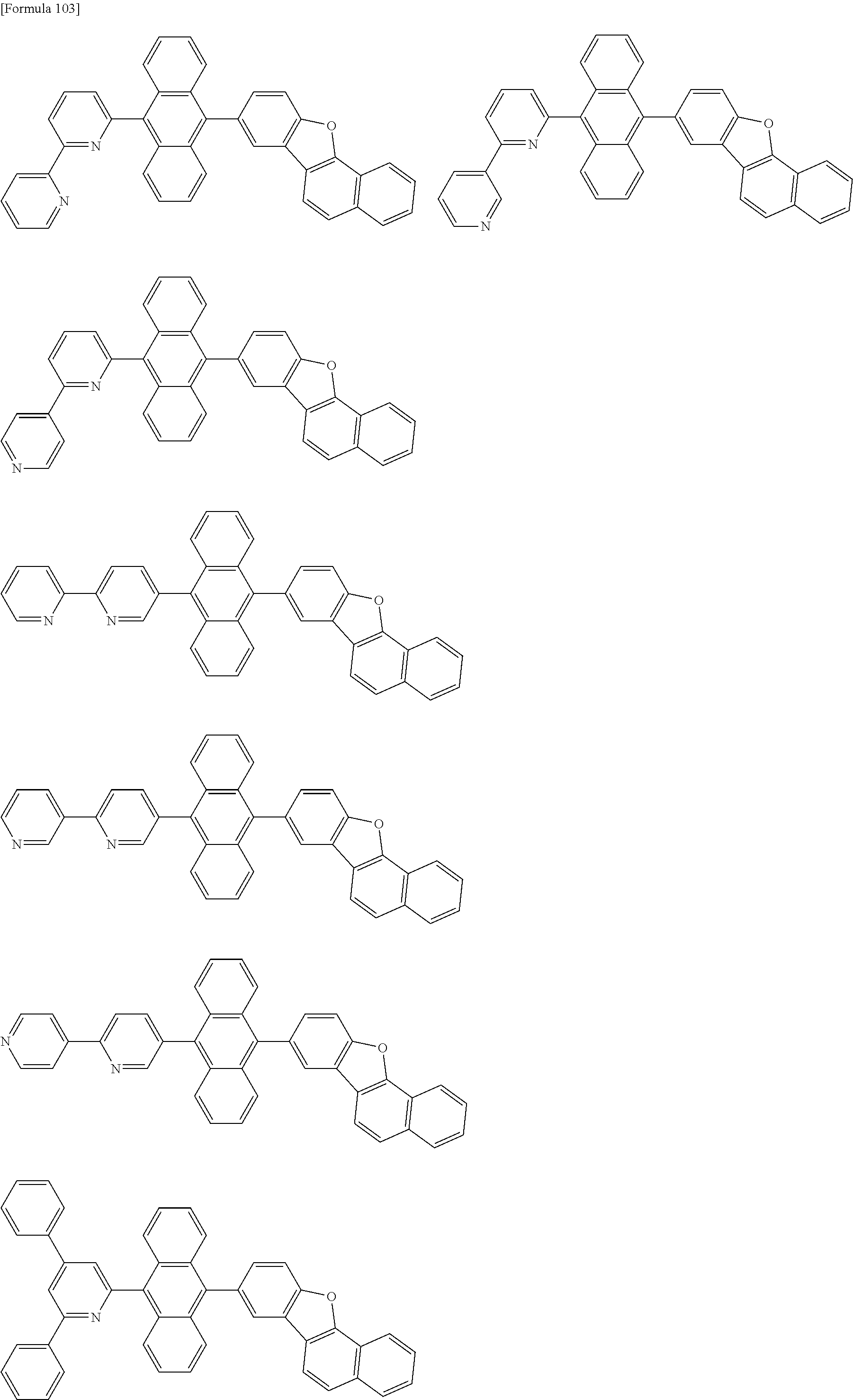

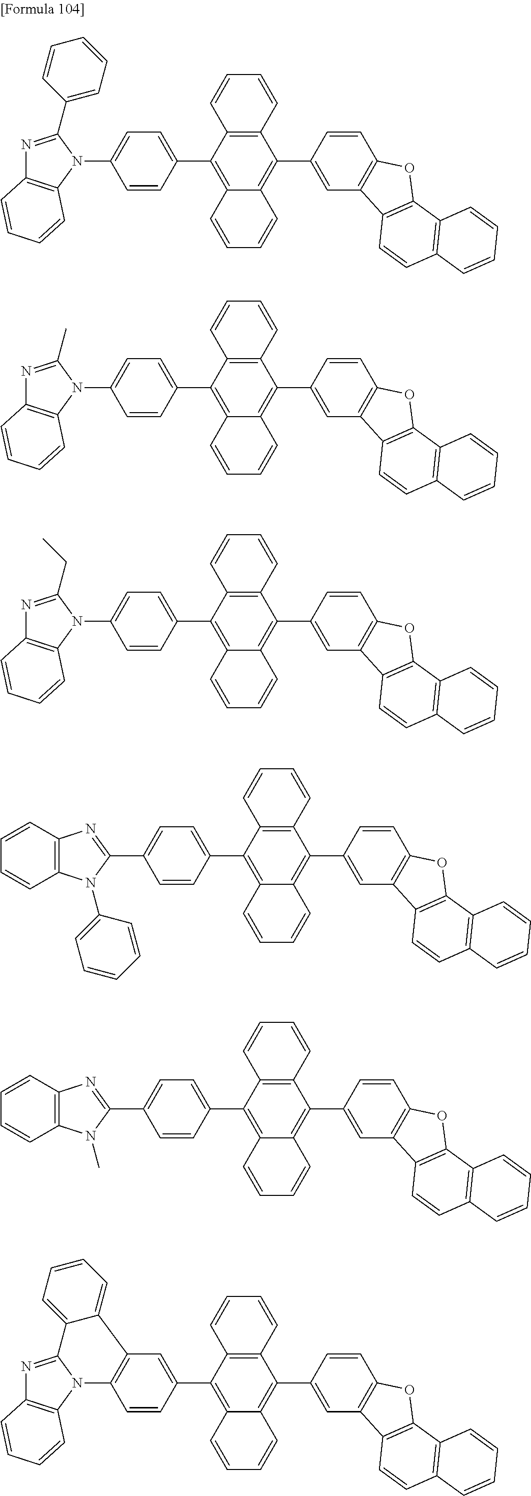 [SMILES: c1ccc(-c2nc3ccccc3n2-c2ccc(-c3c4ccccc4c(-c4ccc5oc6c7ccccc7ccc6c5c4)c4ccccc34)cc2)cc1 ; Cc1nc2ccccc2n1-c1ccc(-c2c3ccccc3c(-c3ccc4oc5c6ccccc6ccc5c4c3)c3ccccc23)cc1 ; CCc1nc2ccccc2n1-c1ccc(-c2c3ccccc3c(-c3ccc4oc5c6ccccc6ccc5c4c3)c3ccccc23)cc1 ; c1ccc(-n2c(-c3ccc(-c4c5ccccc5c(-c5ccc6oc7c8ccccc8ccc7c6c5)c5ccccc45)cc3)nc3ccccc32)cc1 ; Cn1c(-c2ccc(-c3c4ccccc4c(-c4ccc5oc6c7ccccc7ccc6c5c4)c4ccccc34)cc2)nc2ccccc21 ; c1ccc2c(c1)ccc1c3cc(-c4c5ccccc5c(-c5ccc6c(c5)c5ccccc5c5nc7ccccc7n65)c5ccccc45)ccc3oc21]

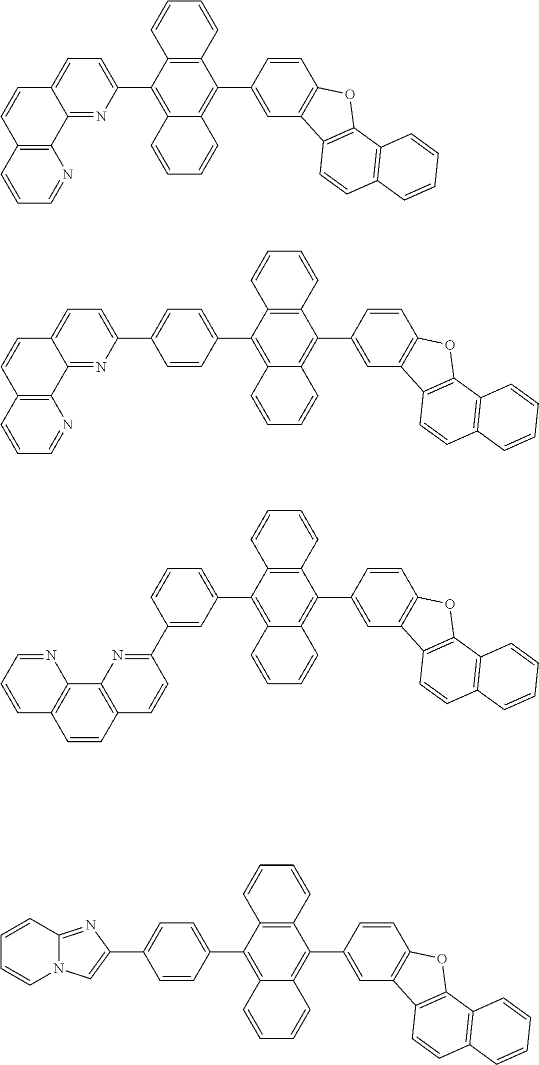 [SMILES: c1ccc2c(c1)ccc1c3cc(-c4c5ccccc5c(-c5ccc6ccc7cccnc7c6n5)c5ccccc45)ccc3oc21 ; c1ccc2c(c1)ccc1c3cc(-c4c5ccccc5c(-c5ccc(-c6ccc7ccc8cccnc8c7n6)cc5)c5ccccc45)ccc3oc21 ; c1cc(-c2ccc3ccc4cccnc4c3n2)cc(-c2c3ccccc3c(-c3ccc4oc5c6ccccc6ccc5c4c3)c3ccccc23)c1 ; c1ccc2c(c1)ccc1c3cc(-c4c5ccccc5c(-c5ccc(-c6cn7ccccc7n6)cc5)c5ccccc45)ccc3oc21]

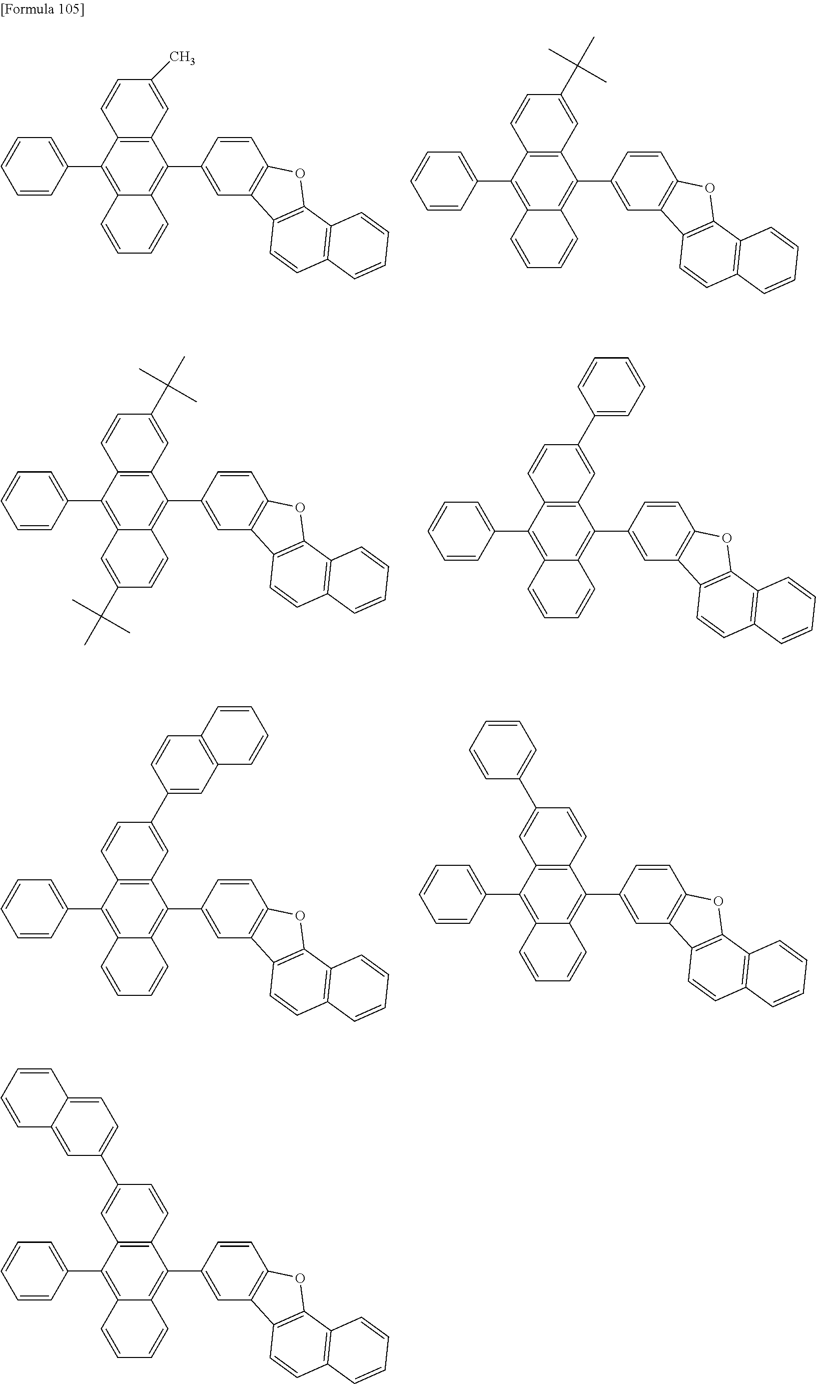

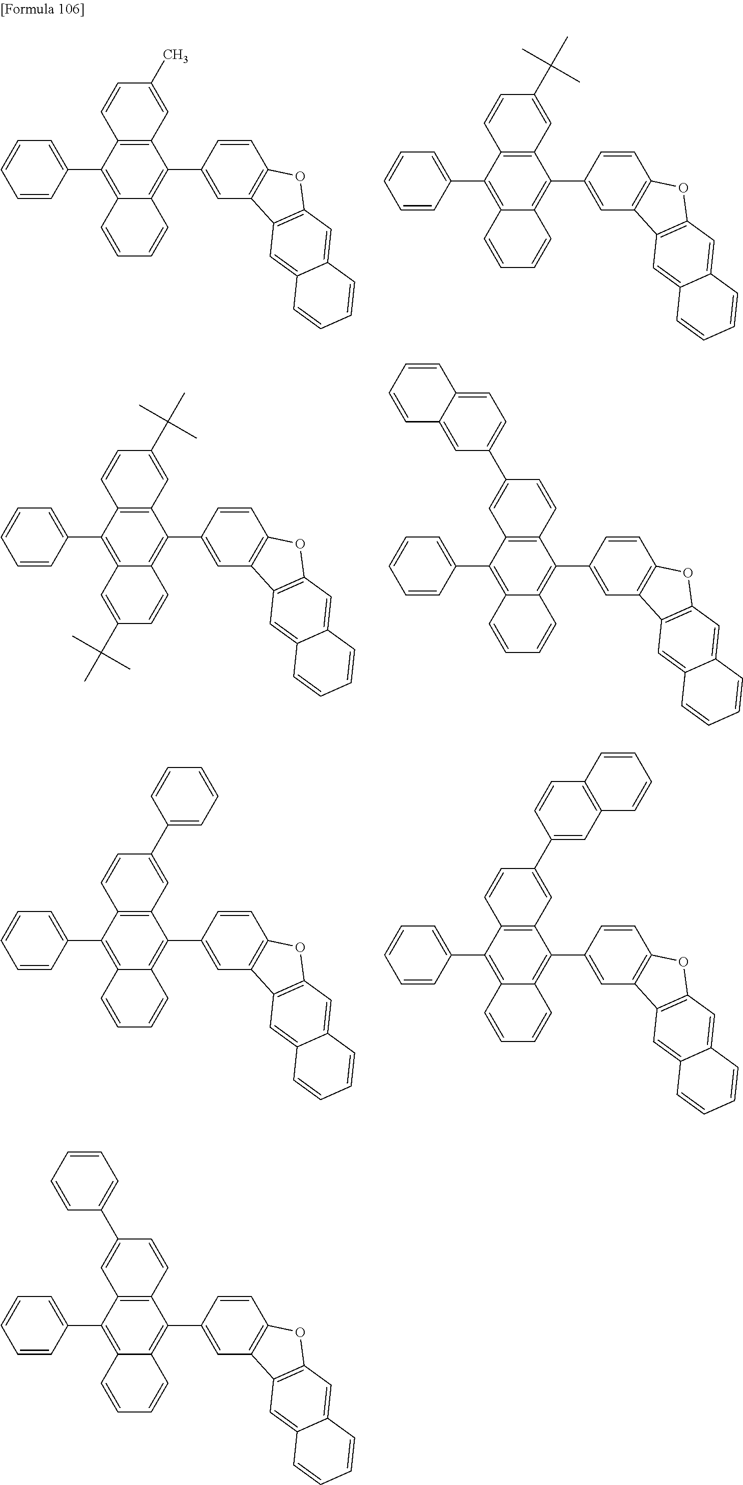

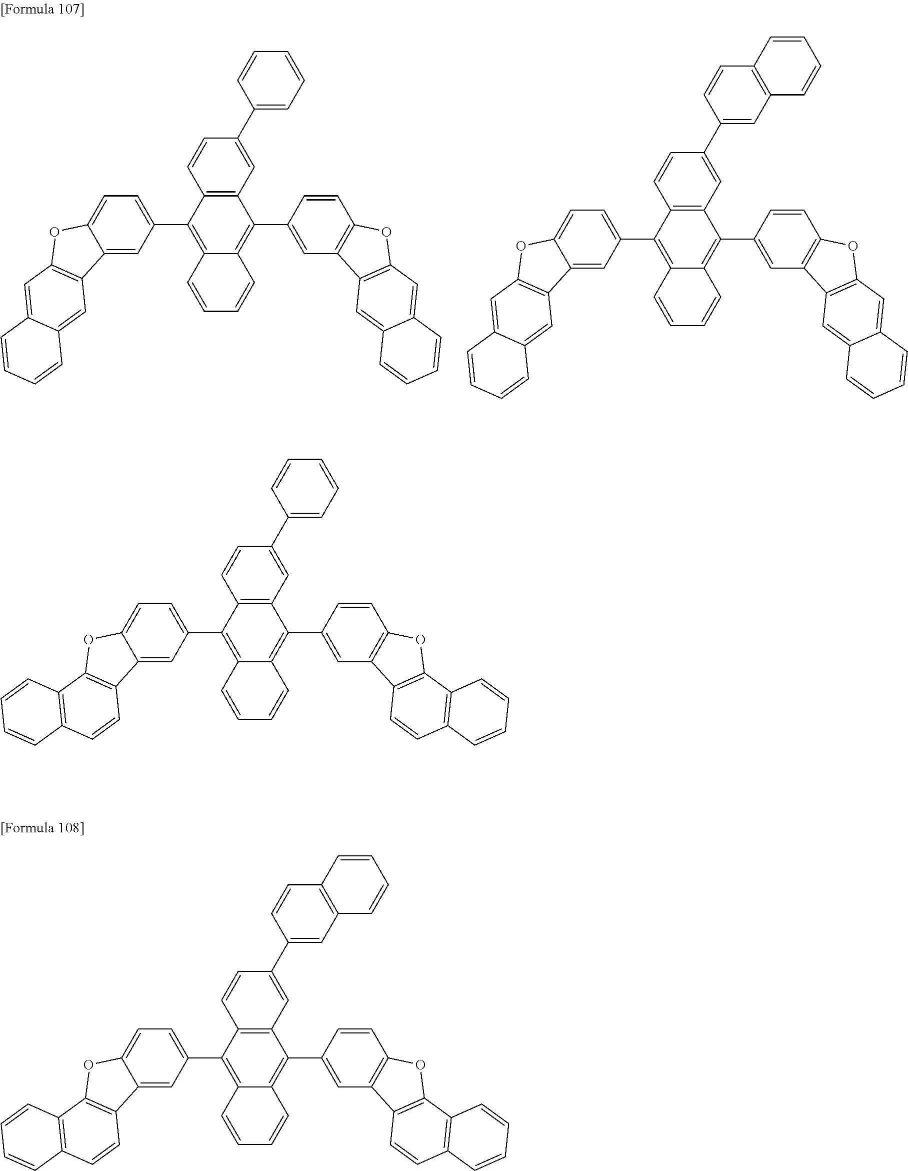

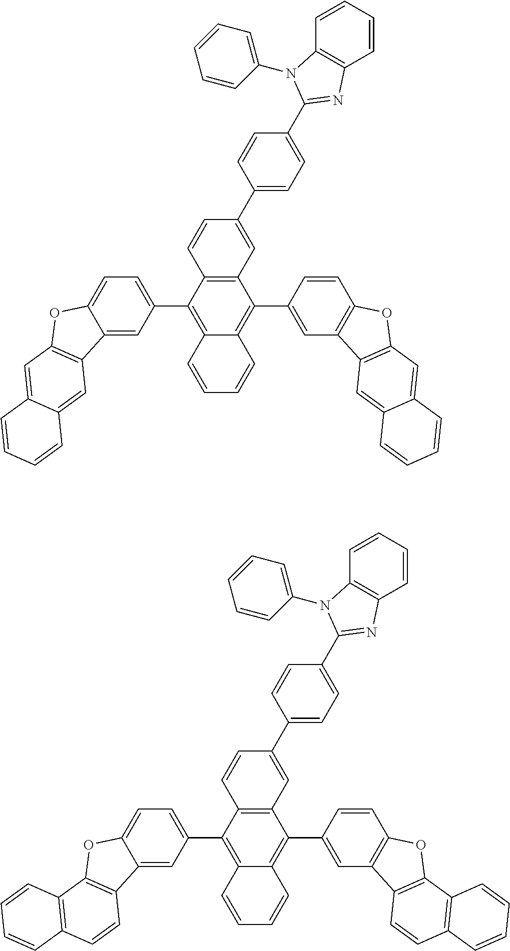 [SMILES: c1ccc(-n2c(-c3ccc(-c4ccc5c(-c6ccc7oc8cc9ccccc9cc8c7c6)c6ccccc6c(-c6ccc7oc8cc9ccccc9cc8c7c6)c5c4)cc3)nc3ccccc32)cc1 ; c1ccc(-n2c(-c3ccc(-c4ccc5c(-c6ccc7oc8c9ccccc9ccc8c7c6)c6ccccc6c(-c6ccc7oc8c9ccccc9ccc8c7c6)c5c4)cc3)nc3ccccc32)cc1]

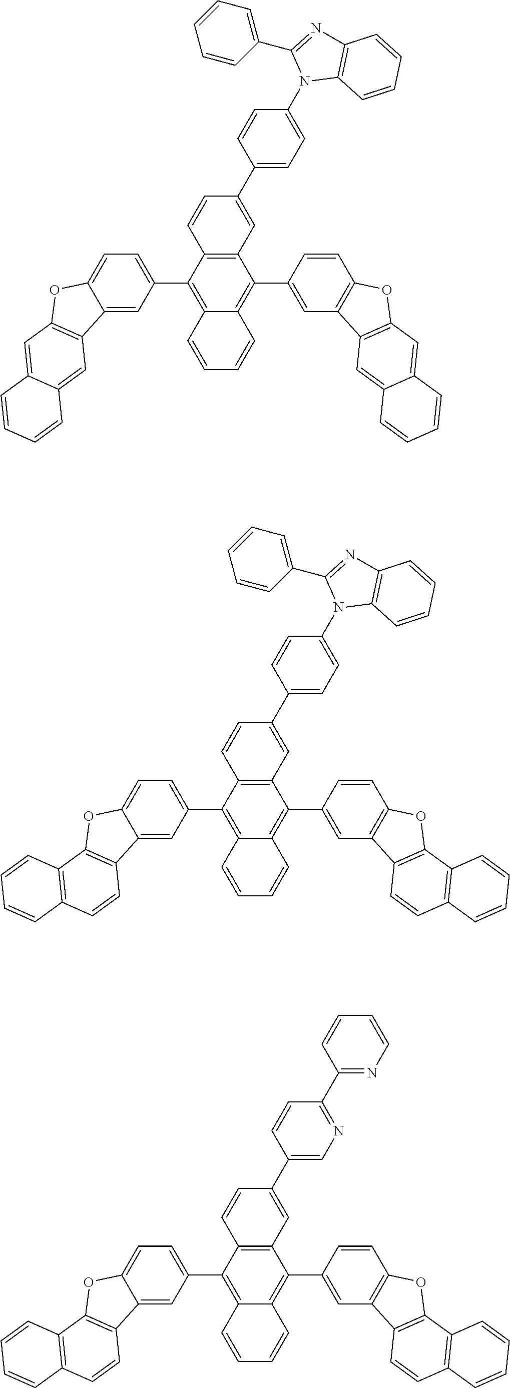 [SMILES: c1ccc(-c2nc3ccccc3n2-c2ccc(-c3ccc4c(-c5ccc6oc7cc8ccccc8cc7c6c5)c5ccccc5c(-c5ccc6oc7cc8ccccc8cc7c6c5)c4c3)cc2)cc1 ; c1ccc(-c2nc3ccccc3n2-c2ccc(-c3ccc4c(-c5ccc6oc7c8ccccc8ccc7c6c5)c5ccccc5c(-c5ccc6oc7c8ccccc8ccc7c6c5)c4c3)cc2)cc1 ; c1ccc(-c2ccc(-c3ccc4c(-c5ccc6oc7c8ccccc8ccc7c6c5)c5ccccc5c(-c5ccc6oc7c8ccccc8ccc7c6c5)c4c3)cn2)nc1]

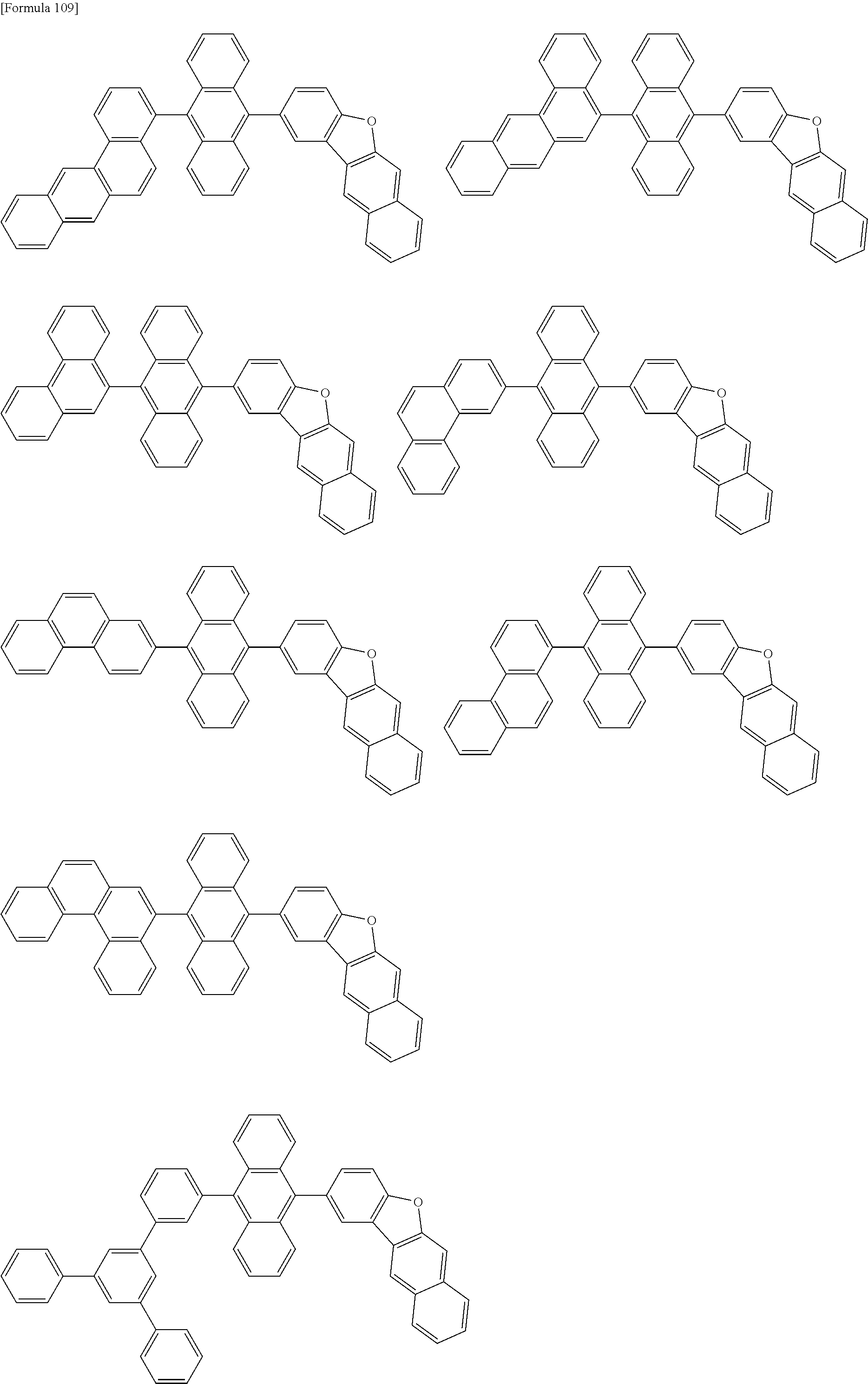

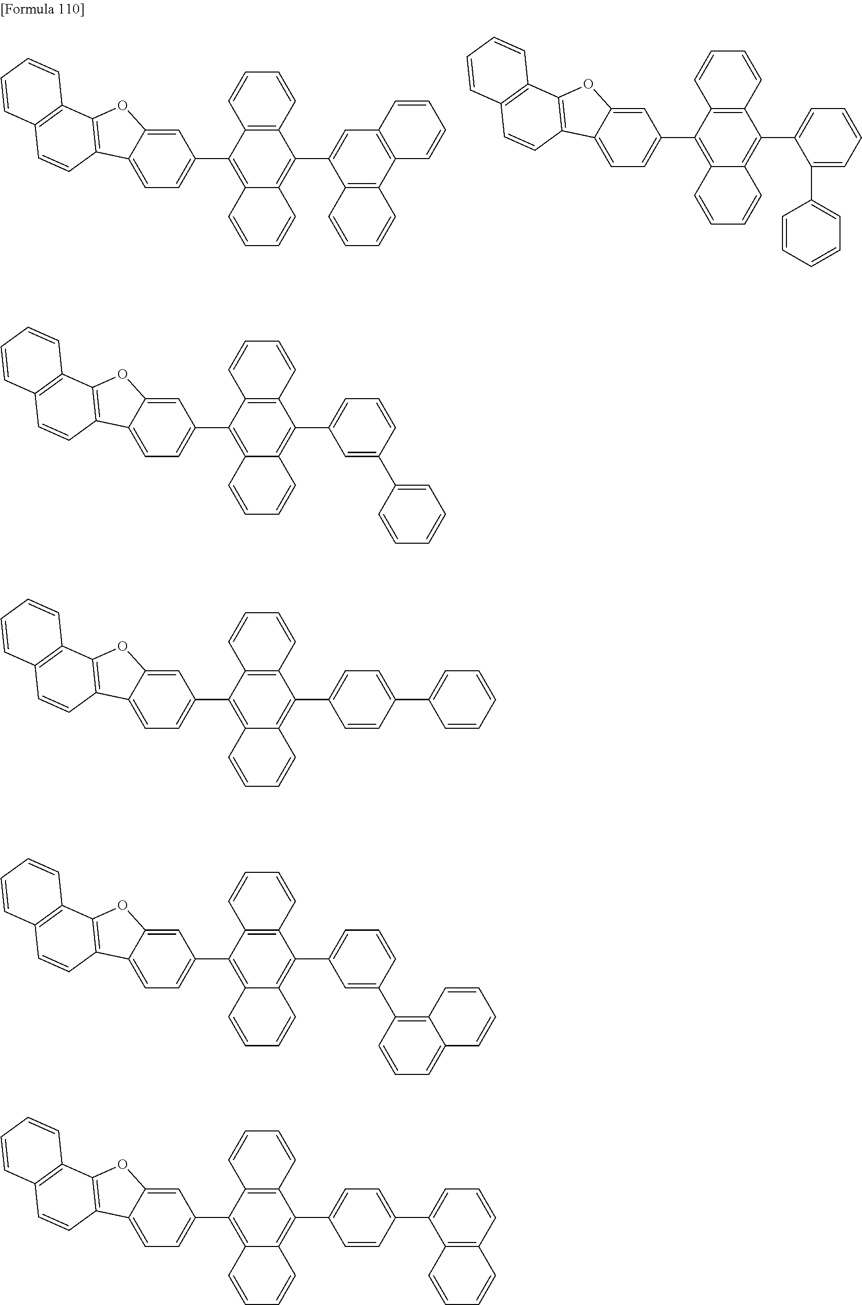

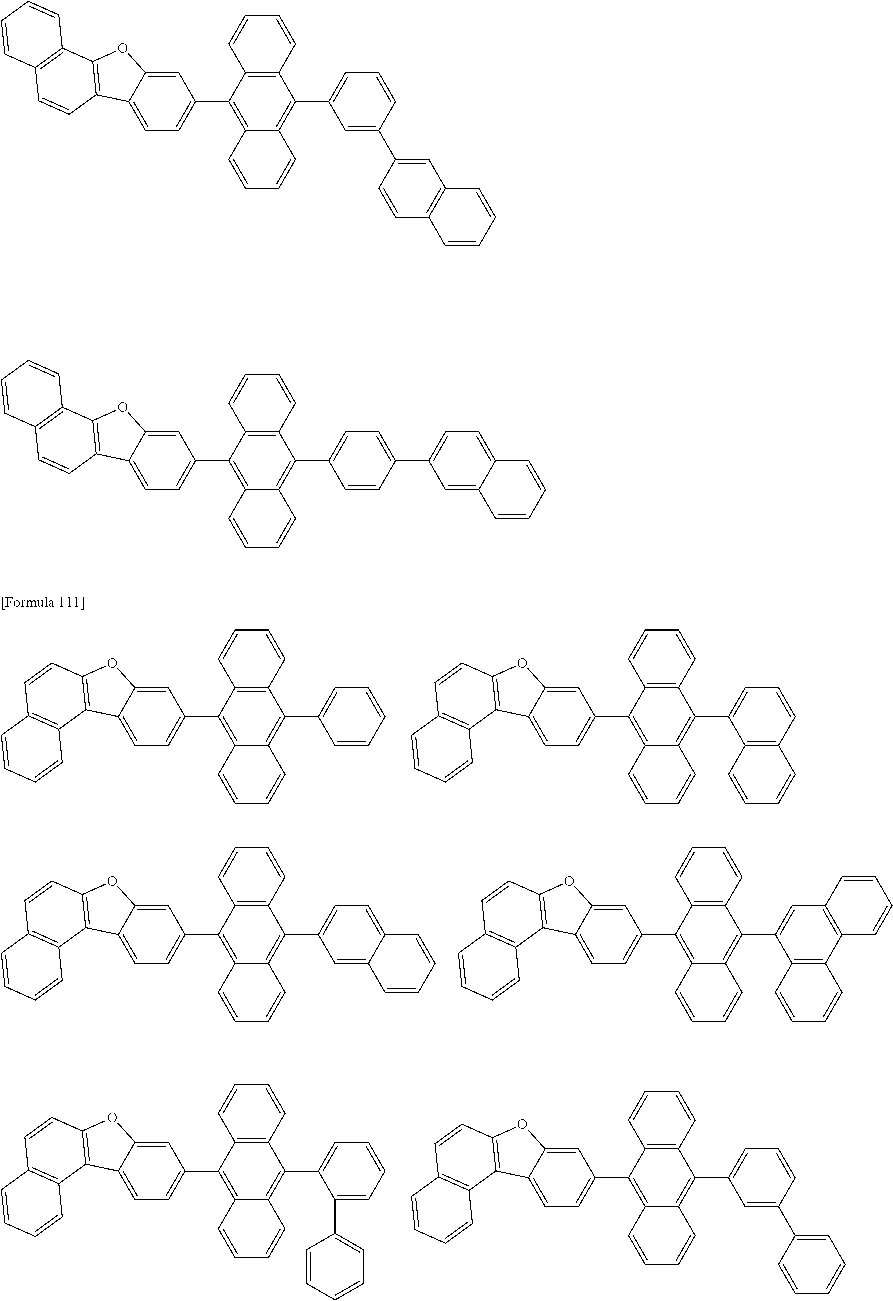

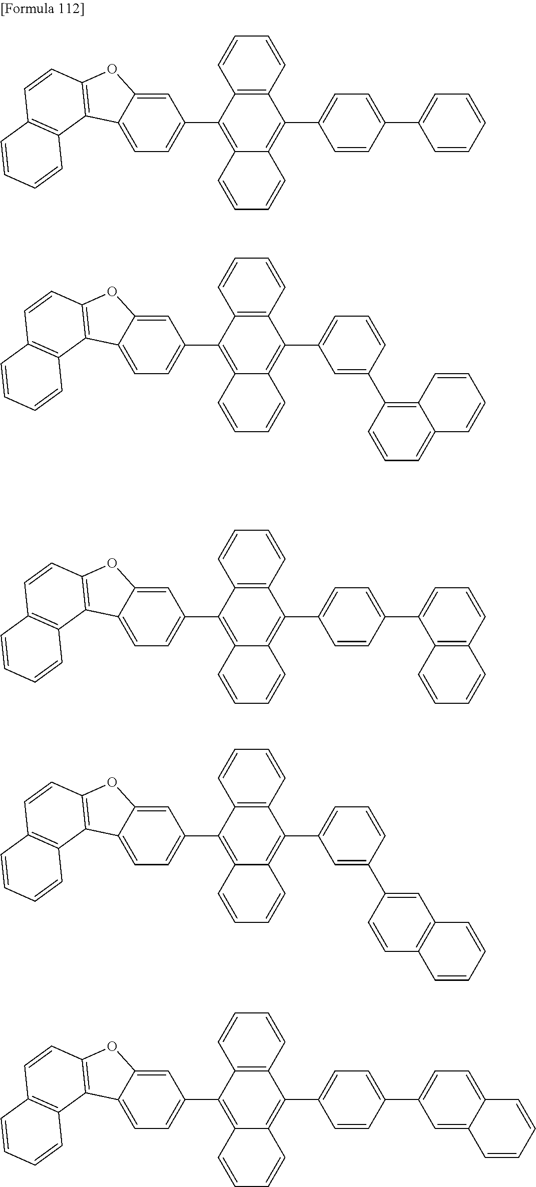

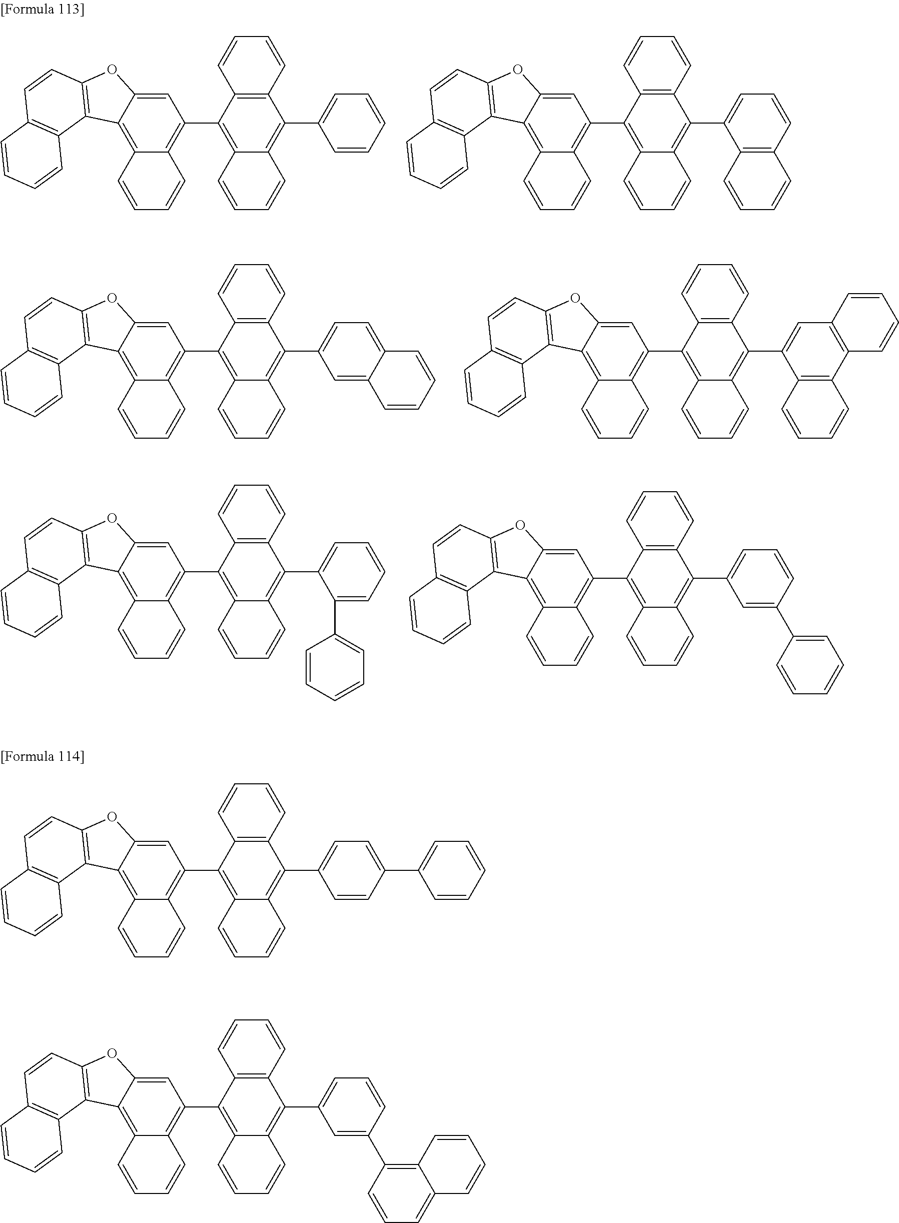

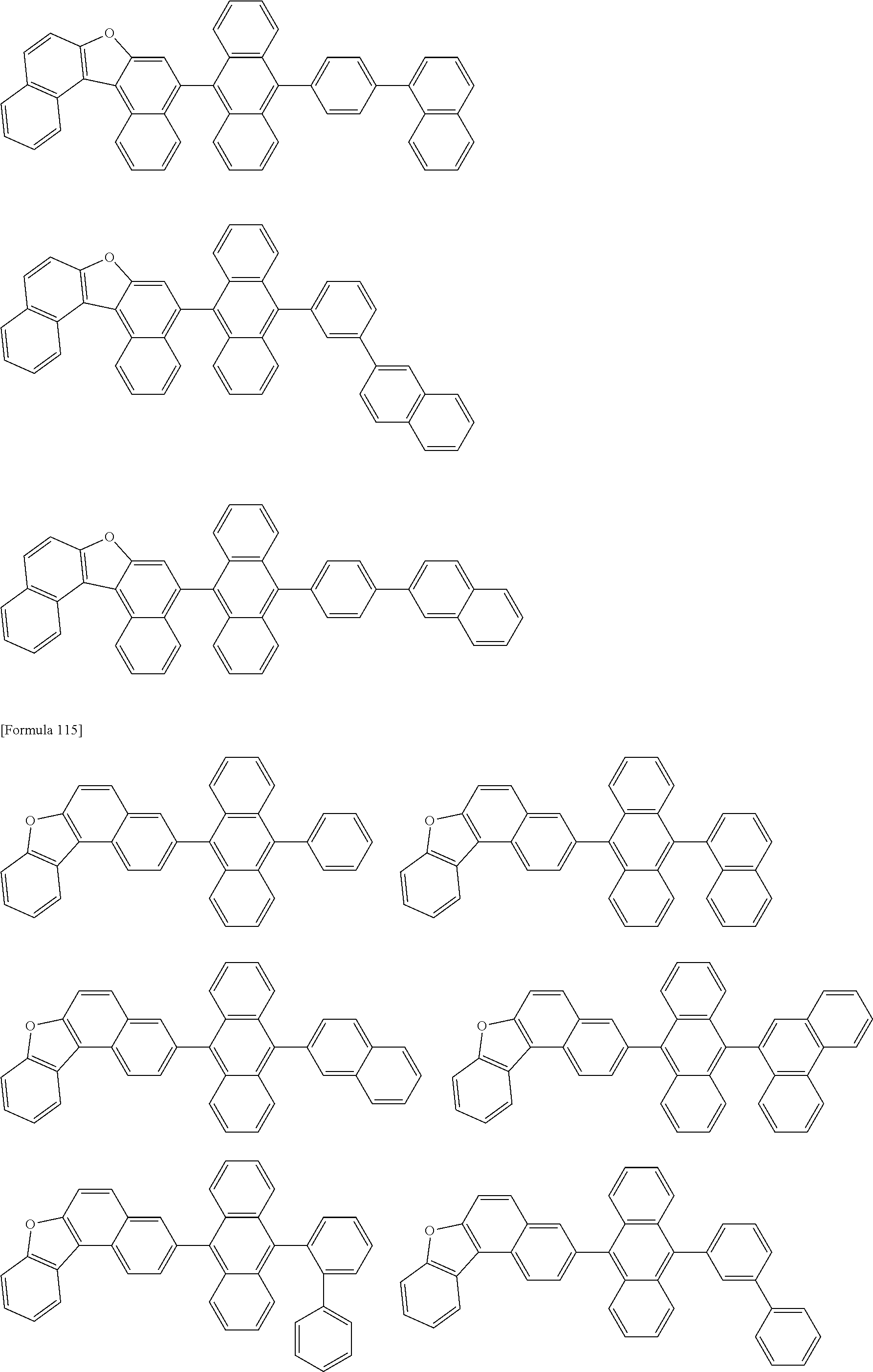

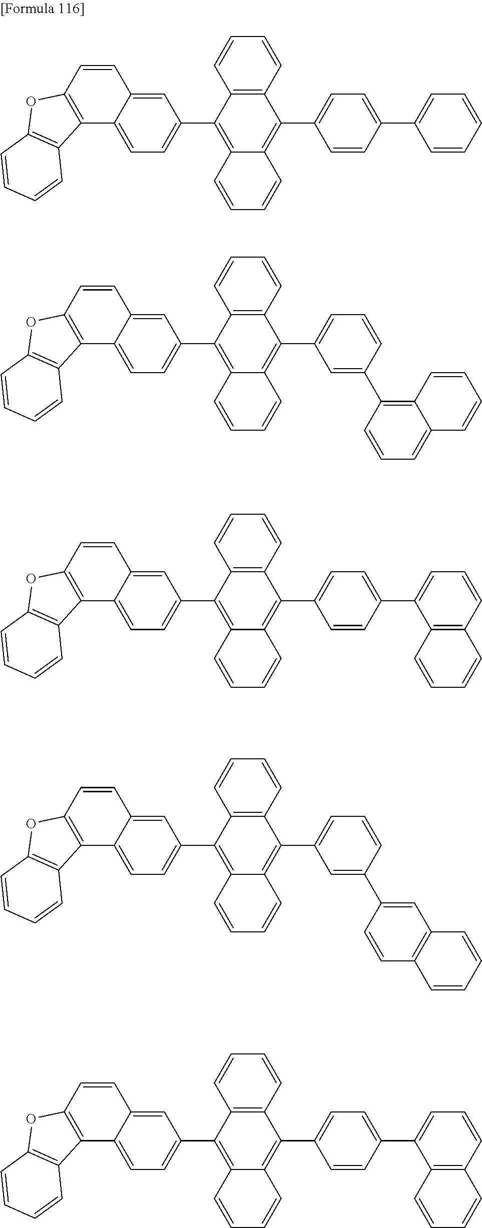 [SMILES: c1ccc(-c2ccc(-c3c4ccccc4c(-c4ccc5c(ccc6oc7ccccc7c65)c4)c4ccccc34)cc2)cc1 ; c1cc(-c2cccc3ccccc23)cc(-c2c3ccccc3c(-c3ccc4c(ccc5oc6ccccc6c54)c3)c3ccccc23)c1 ; c1ccc2c(-c3ccc(-c4c5ccccc5c(-c5ccc6c(ccc7oc8ccccc8c76)c5)c5ccccc45)cc3)cccc2c1 ; c1cc(-c2ccc3ccccc3c2)cc(-c2c3ccccc3c(-c3ccc4c(ccc5oc6ccccc6c54)c3)c3ccccc23)c1 ; c1ccc2c(-c3ccc(-c4c5ccccc5c(-c5ccc6c(ccc7oc8ccccc8c76)c5)c5ccccc45)cc3)cccc2c1]

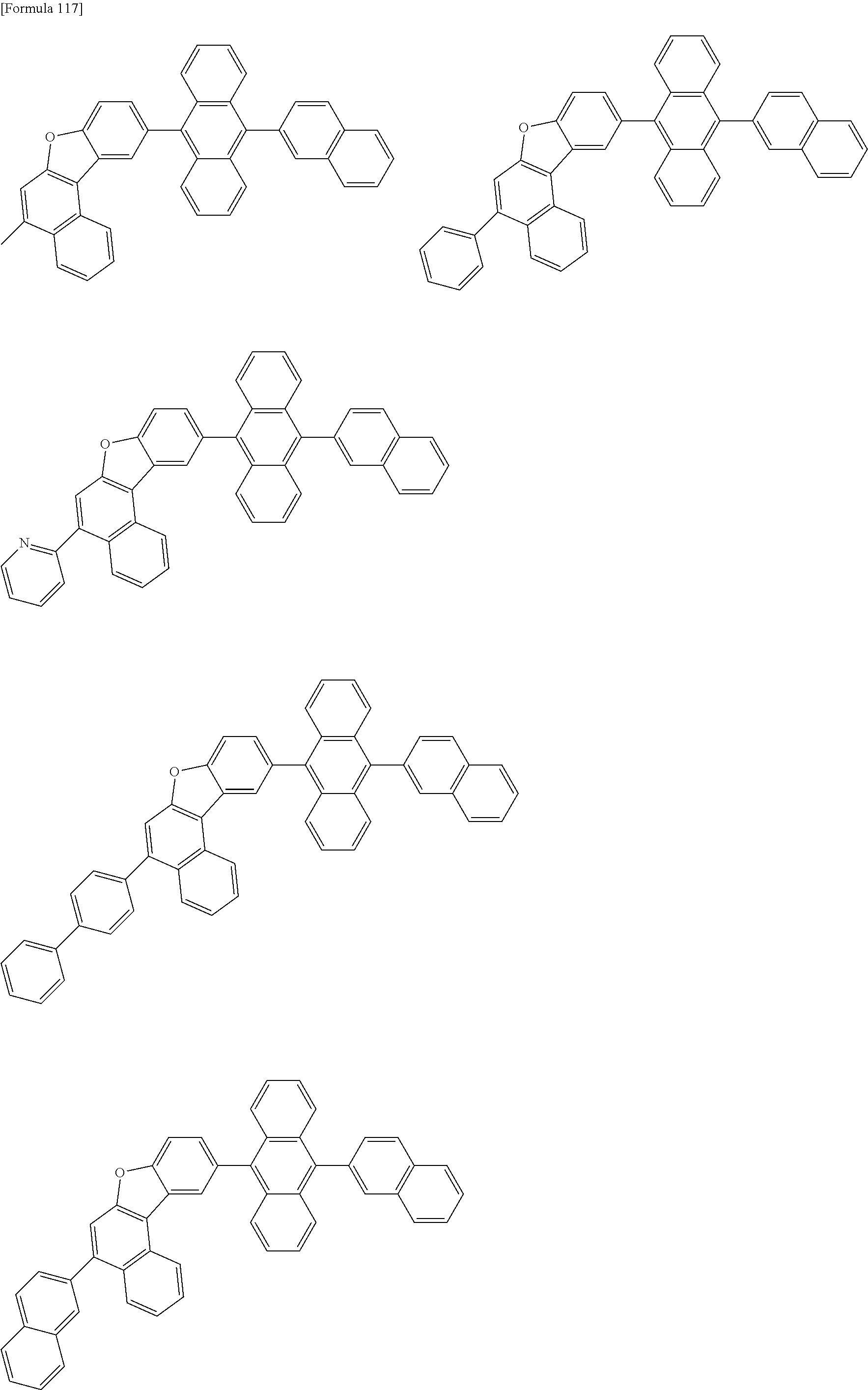 [SMILES: Cc1cc2oc3ccc(-c4c5ccccc5c(-c5ccc6ccccc6c5)c5ccccc45)cc3c2c2ccccc12 ; c1ccc(-c2cc3oc4ccc(-c5c6ccccc6c(-c6ccc7ccccc7c6)c6ccccc56)cc4c3c3ccccc23)cc1 ; c1ccc(-c2cc3oc4ccc(-c5c6ccccc6c(-c6ccc7ccccc7c6)c6ccccc56)cc4c3c3ccccc23)nc1 ; c1ccc(-c2ccc(-c3cc4oc5ccc(-c6c7ccccc7c(-c7ccc8ccccc8c7)c7ccccc67)cc5c4c4ccccc34)cc2)cc1 ; c1ccc2cc(-c3c4ccccc4c(-c4ccc5oc6cc(-c7ccc8ccccc8c7)c7ccccc7c6c5c4)c4ccccc34)ccc2c1]

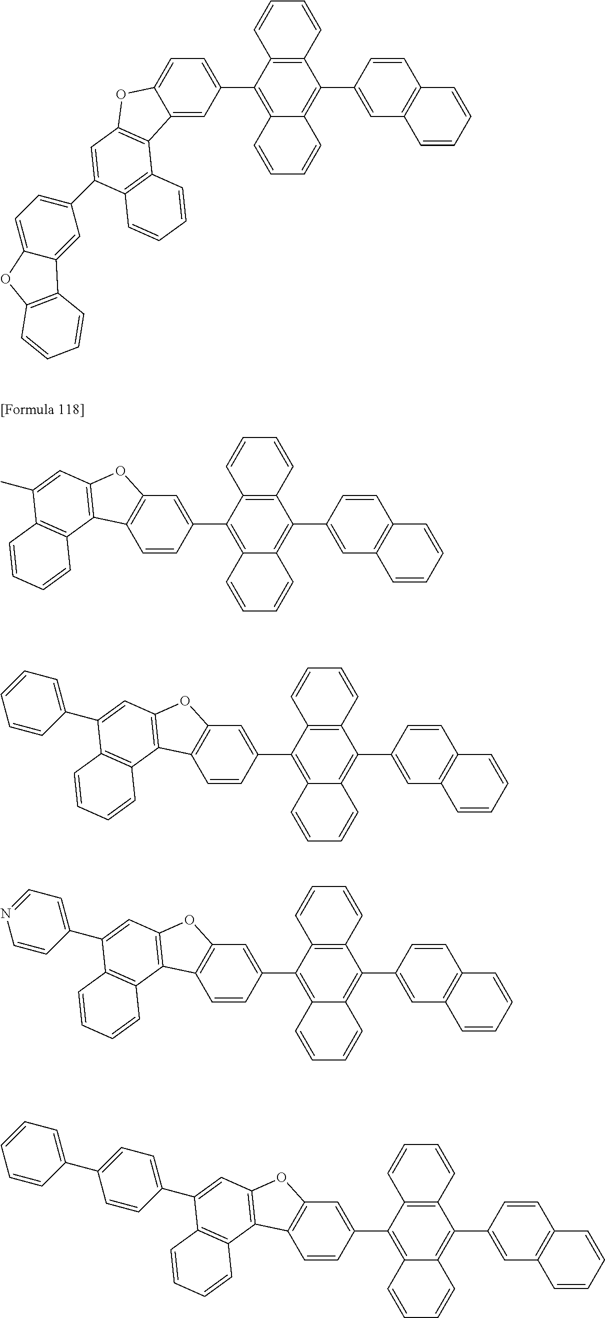

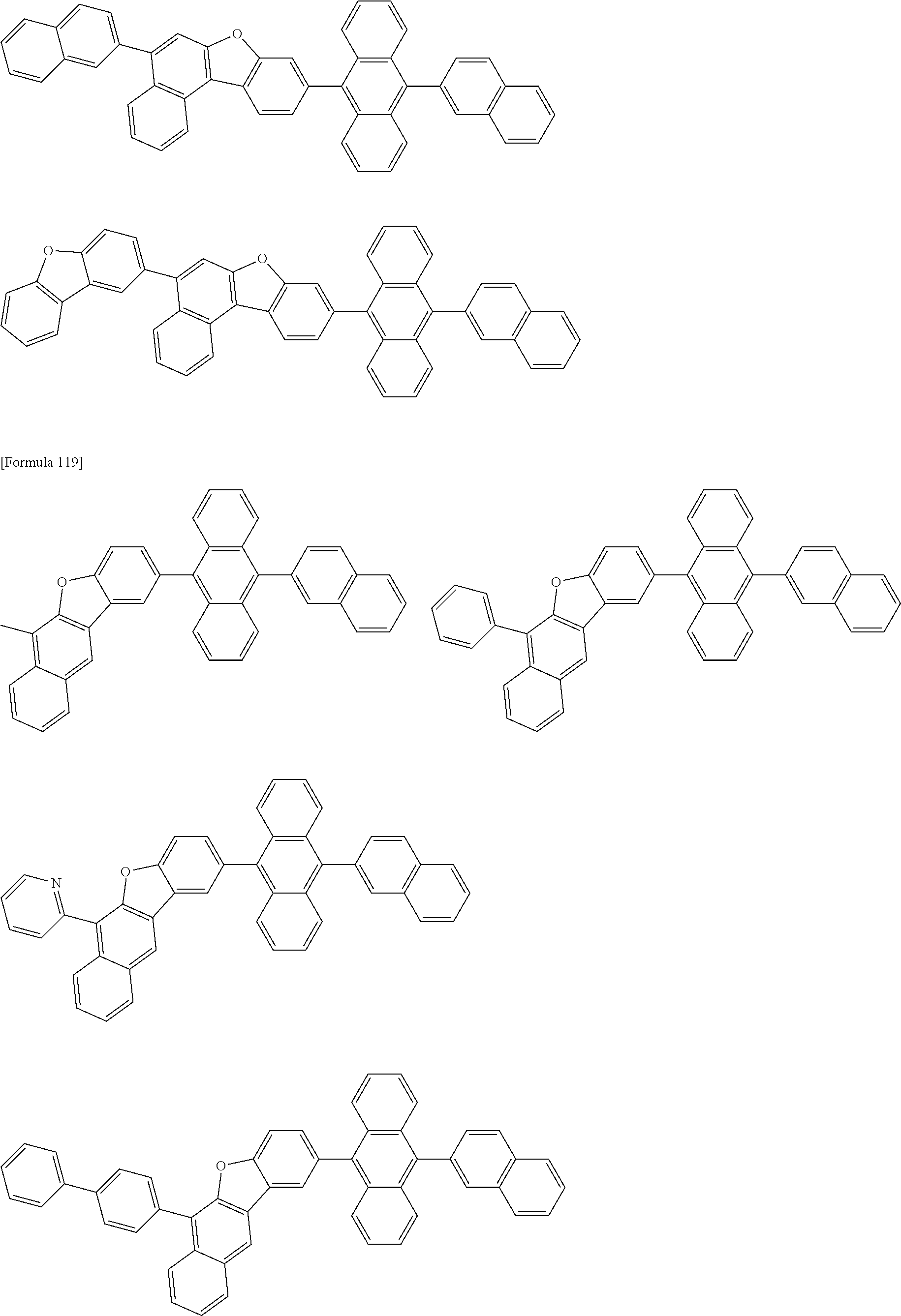

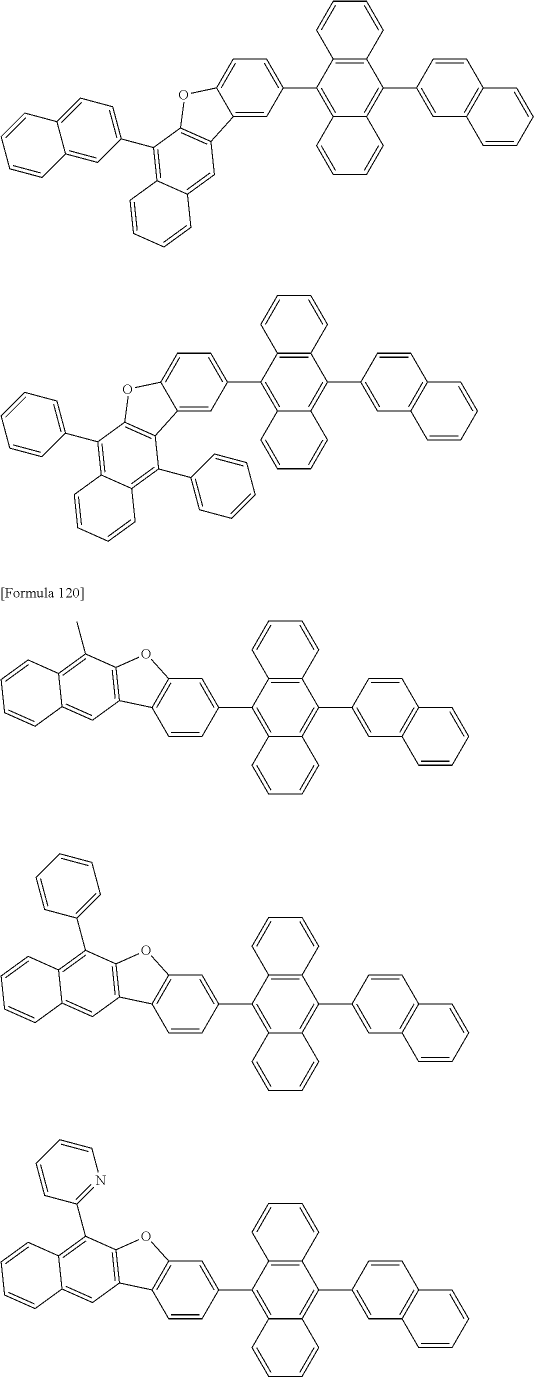 [SMILES: c1ccc2cc(-c3c4ccccc4c(-c4ccc5oc6c(-c7ccc8ccccc8c7)c7ccccc7cc6c5c4)c4ccccc34)ccc2c1 ; c1ccc(-c2c3ccccc3c(-c3ccccc3)c3c2oc2ccc(-c4c5ccccc5c(-c5ccc6ccccc6c5)c5ccccc45)cc23)cc1 ; Cc1c2ccccc2cc2c1oc1cc(-c3c4ccccc4c(-c4ccc5ccccc5c4)c4ccccc34)ccc12 ; c1ccc(-c2c3ccccc3cc3c2oc2cc(-c4c5ccccc5c(-c5ccc6ccccc6c5)c5ccccc45)ccc23)cc1 ; c1ccc(-c2c3ccccc3cc3c2oc2cc(-c4c5ccccc5c(-c5ccc6ccccc6c5)c5ccccc45)ccc23)nc1]

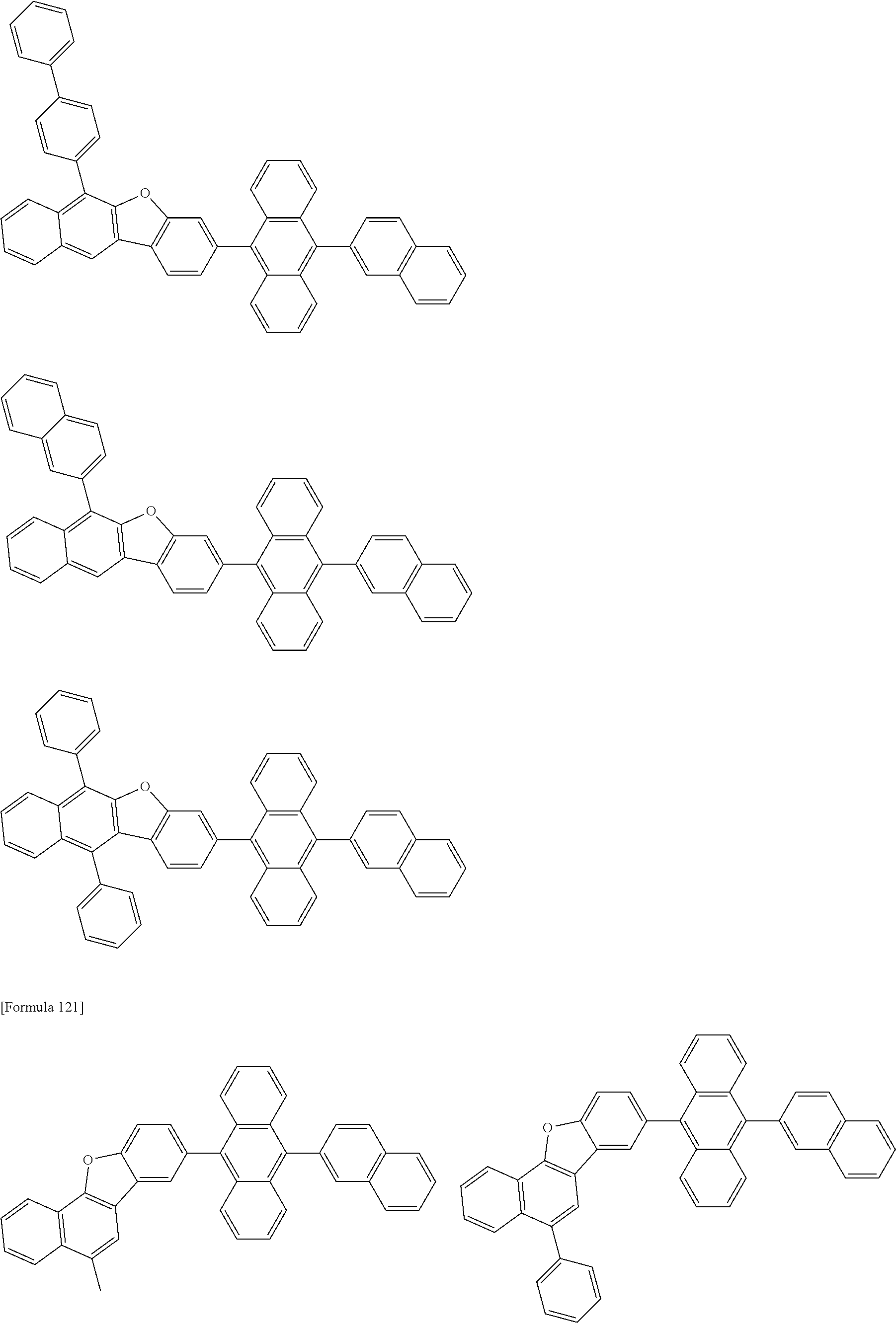

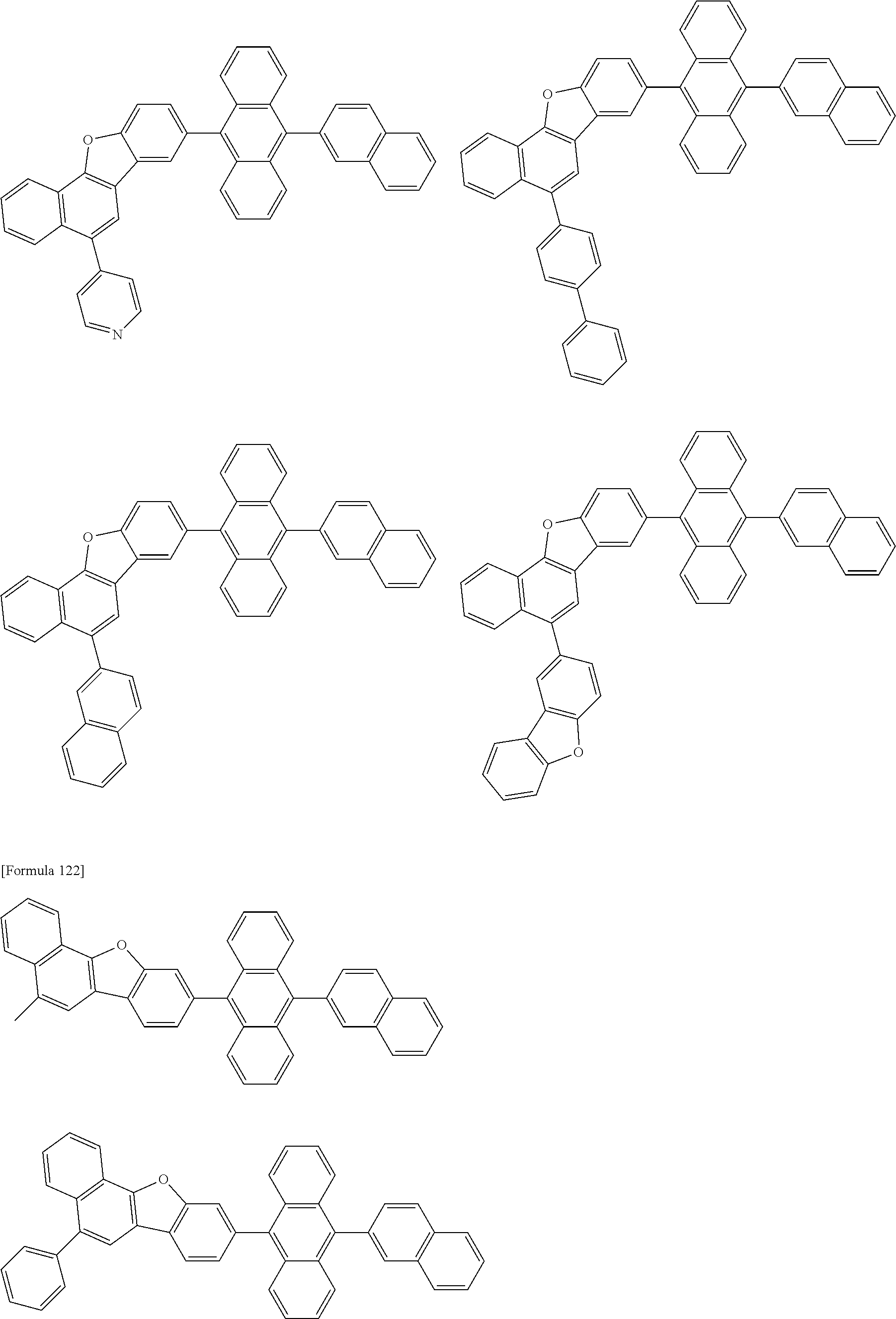

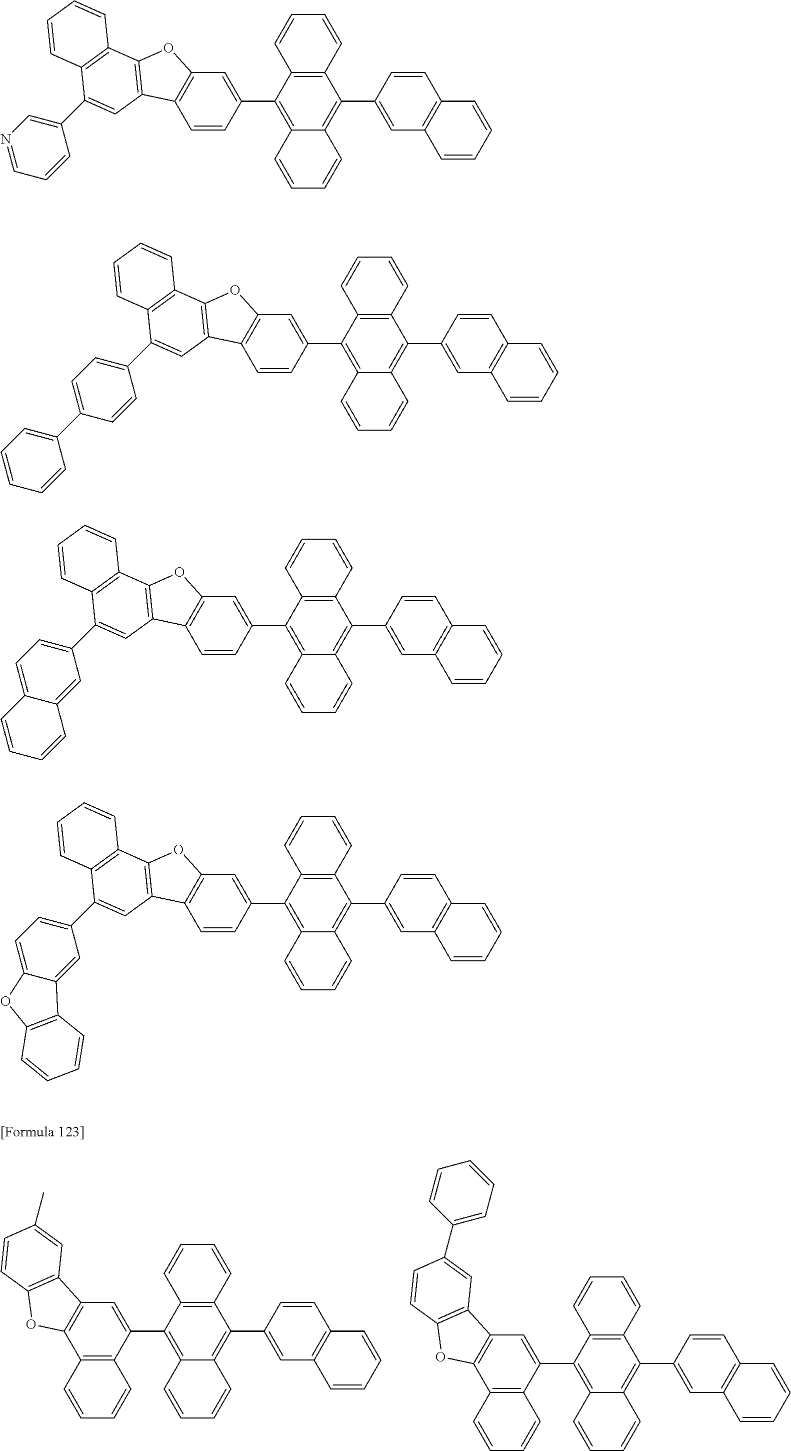 [SMILES: c1cncc(-c2cc3c4ccc(-c5c6ccccc6c(-c6ccc7ccccc7c6)c6ccccc56)cc4oc3c3ccccc23)c1 ; c1ccc(-c2ccc(-c3cc4c5ccc(-c6c7ccccc7c(-c7ccc8ccccc8c7)c7ccccc67)cc5oc4c4ccccc34)cc2)cc1 ; c1ccc2cc(-c3c4ccccc4c(-c4ccc5c(c4)oc4c6ccccc6c(-c6ccc7ccccc7c6)cc54)c4ccccc34)ccc2c1 ; c1ccc2cc(-c3c4ccccc4c(-c4ccc5c(c4)oc4c6ccccc6c(-c6ccc7oc8ccccc8c7c6)cc54)c4ccccc34)ccc2c1 ; Cc1ccc2oc3c4ccccc4c(-c4c5ccccc5c(-c5ccc6ccccc6c5)c5ccccc45)cc3c2c1 ; c1ccc(-c2ccc3oc4c5ccccc5c(-c5c6ccccc6c(-c6ccc7ccccc7c6)c6ccccc56)cc4c3c2)cc1]

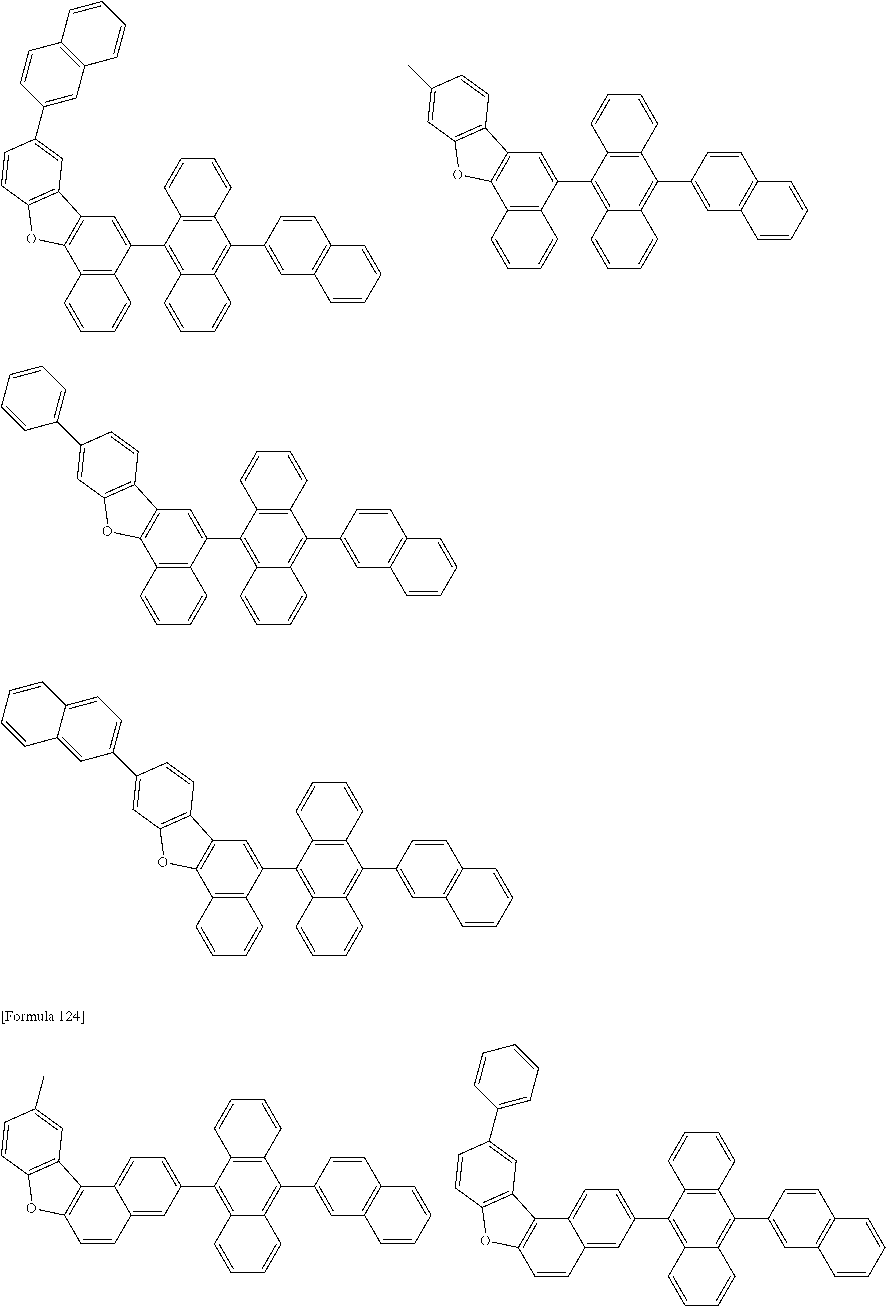

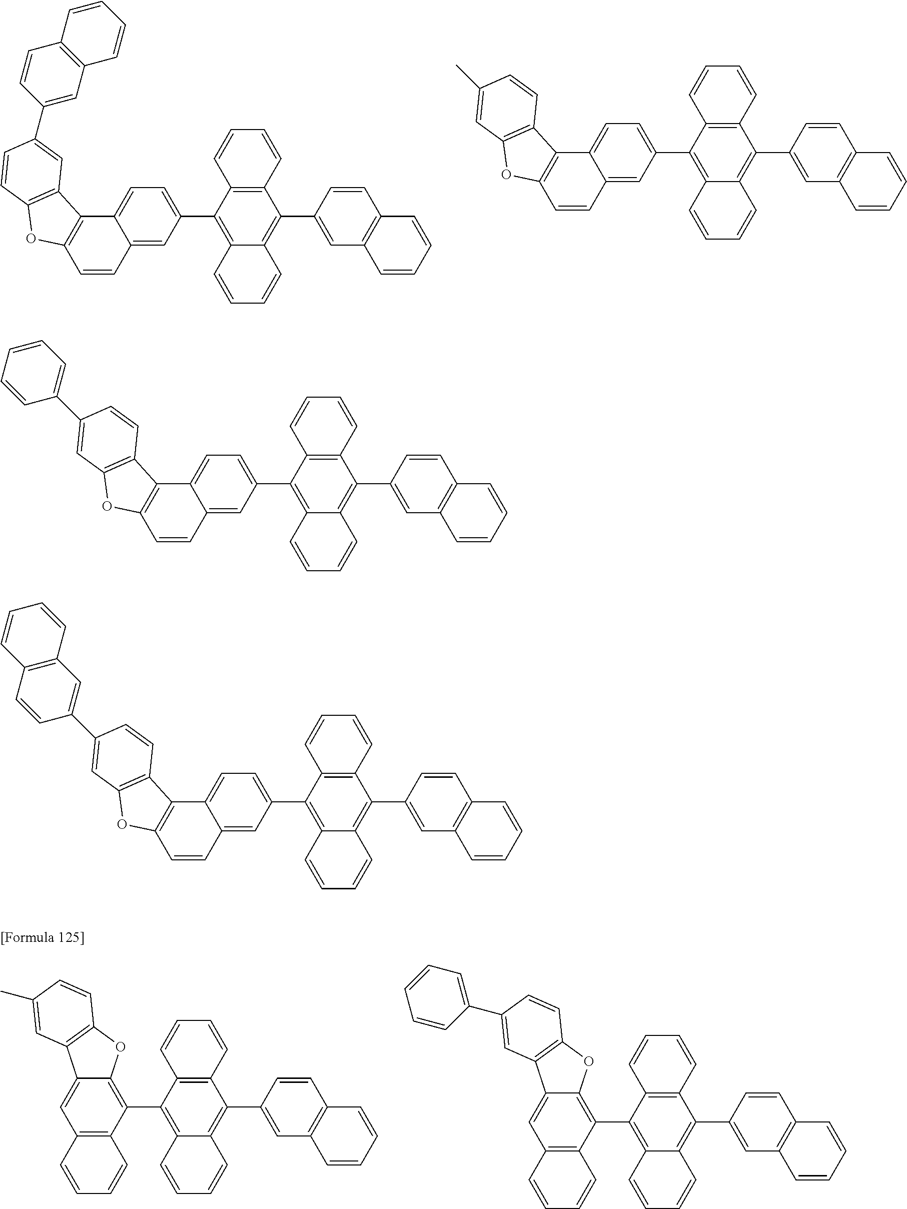 [SMILES: c1ccc2cc(-c3ccc4oc5ccc6cc(-c7c8ccccc8c(-c8ccc9ccccc9c8)c8ccccc78)ccc6c5c4c3)ccc2c1 ; Cc1ccc2c(c1)oc1ccc3cc(-c4c5ccccc5c(-c5ccc6ccccc6c5)c5ccccc45)ccc3c12 ; c1ccc(-c2ccc3c(c2)oc2ccc4cc(-c5c6ccccc6c(-c6ccc7ccccc7c6)c6ccccc56)ccc4c23)cc1 ; c1ccc2cc(-c3ccc4c(c3)oc3ccc5cc(-c6c7ccccc7c(-c7ccc8ccccc8c7)c7ccccc67)ccc5c34)ccc2c1 ; Cc1ccc2oc3c(-c4c5ccccc5c(-c5ccc6ccccc6c5)c5ccccc45)c4ccccc4cc3c2c1 ; c1ccc(-c2ccc3oc4c(-c5c6ccccc6c(-c6ccc7ccccc7c6)c6ccccc56)c5ccccc5cc4c3c2)cc1]

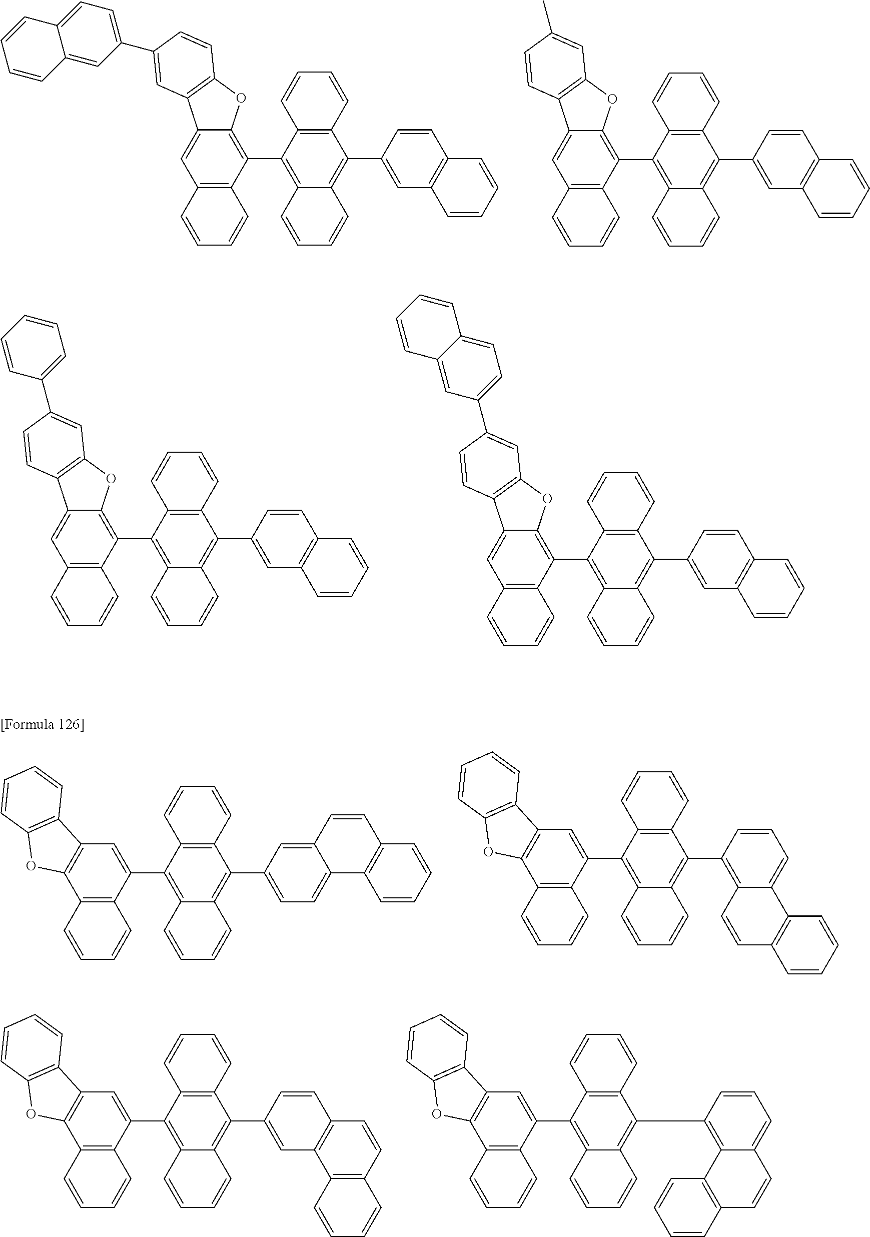

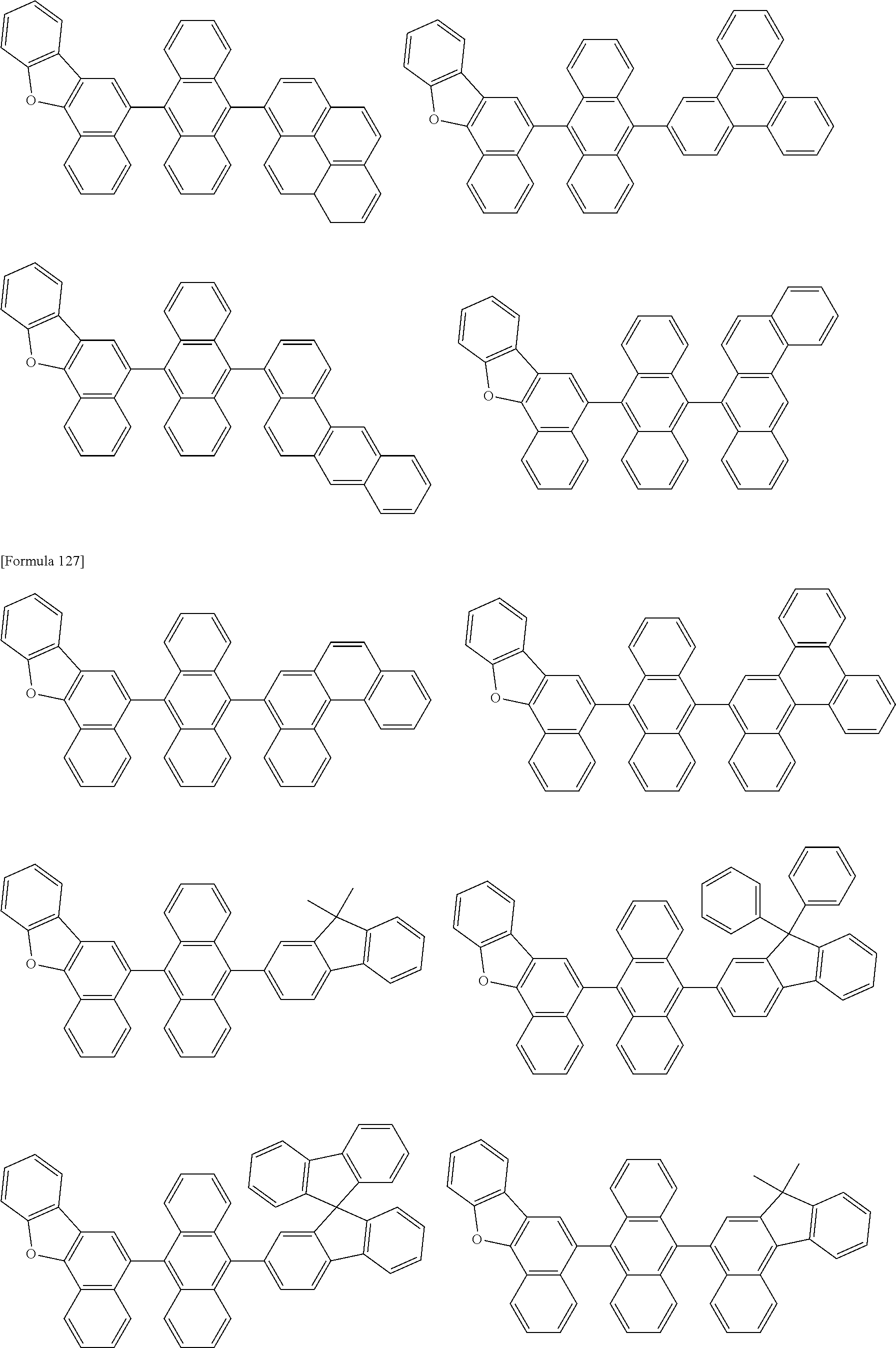

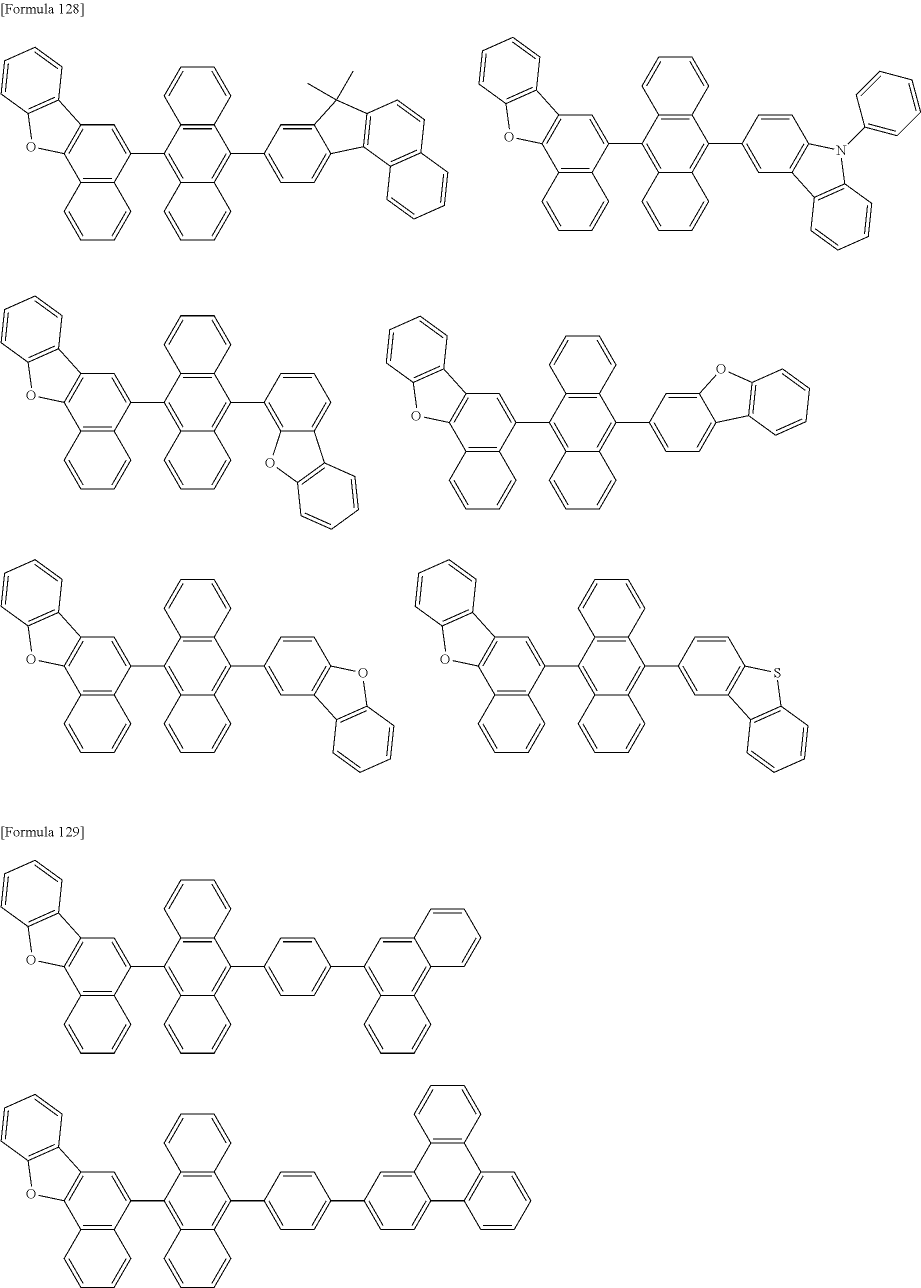

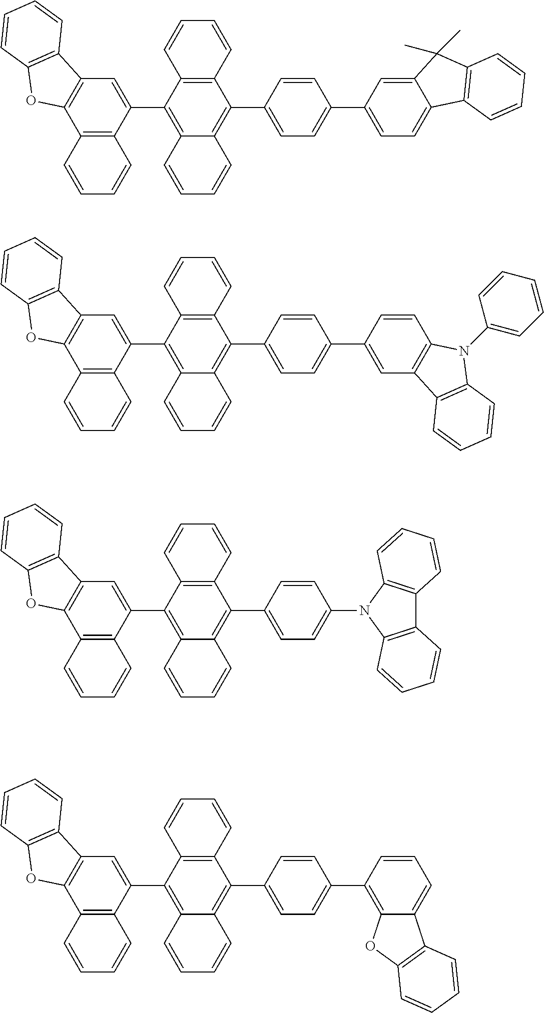 [SMILES: CC1(C)c2ccccc2-c2ccc(-c3ccc(-c4c5ccccc5c(-c5cc6c7ccccc7oc6c6ccccc56)c5ccccc45)cc3)cc21 ; c1ccc(-n2c3ccccc3c3cc(-c4ccc(-c5c6ccccc6c(-c6cc7c8ccccc8oc7c7ccccc67)c6ccccc56)cc4)ccc32)cc1 ; c1ccc2c(c1)oc1c3ccccc3c(-c3c4ccccc4c(-c4ccc(-n5c6ccccc6c6ccccc65)cc4)c4ccccc34)cc21 ; c1ccc2c(c1)oc1c(-c3ccc(-c4c5ccccc5c(-c5cc6c7ccccc7oc6c6ccccc56)c5ccccc45)cc3)cccc12]

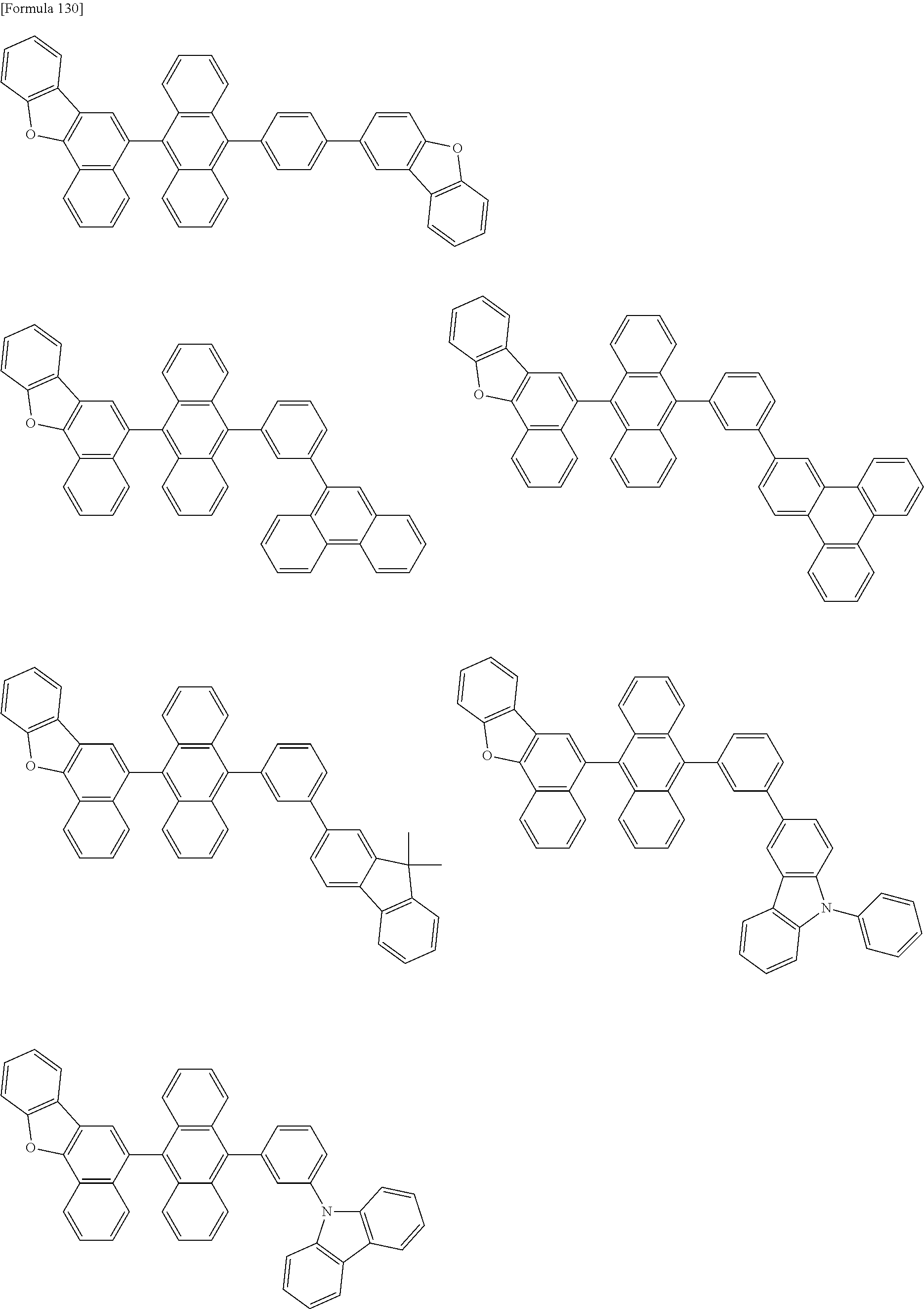

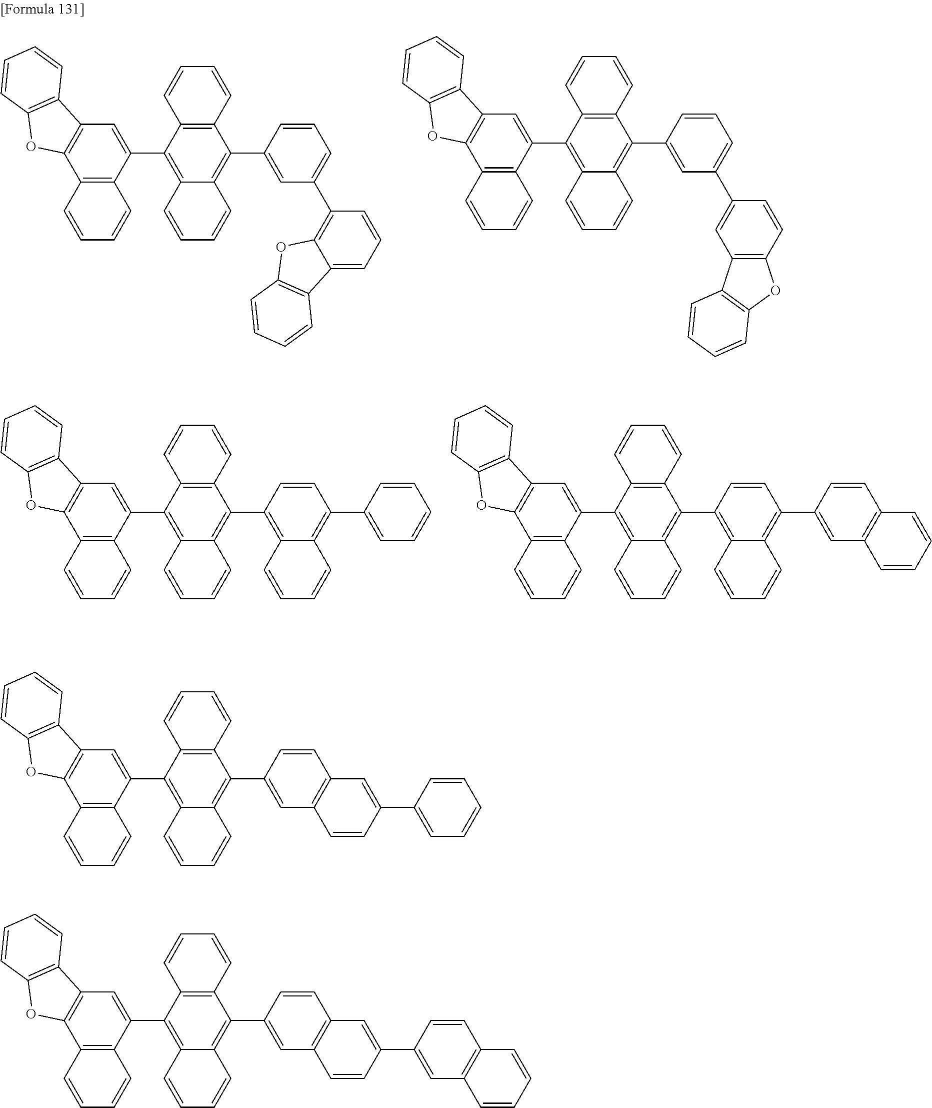 [SMILES: c1cc(-c2c3ccccc3c(-c3cc4c5ccccc5oc4c4ccccc34)c3ccccc23)cc(-c2cccc3c2oc2ccccc23)c1 ; c1cc(-c2ccc3oc4ccccc4c3c2)cc(-c2c3ccccc3c(-c3cc4c5ccccc5oc4c4ccccc34)c3ccccc23)c1 ; c1ccc(-c2ccc(-c3c4ccccc4c(-c4cc5c6ccccc6oc5c5ccccc45)c4ccccc34)c3ccccc23)cc1 ; c1ccc2cc(-c3ccc(-c4c5ccccc5c(-c5cc6c7ccccc7oc6c6ccccc56)c5ccccc45)c4ccccc34)ccc2c1 ; c1ccc(-c2ccc3cc(-c4c5ccccc5c(-c5cc6c7ccccc7oc6c6ccccc56)c5ccccc45)ccc3c2)cc1 ; c1ccc2cc(-c3ccc4cc(-c5c6ccccc6c(-c6cc7c8ccccc8oc7c7ccccc67)c6ccccc56)ccc4c3)ccc2c1]

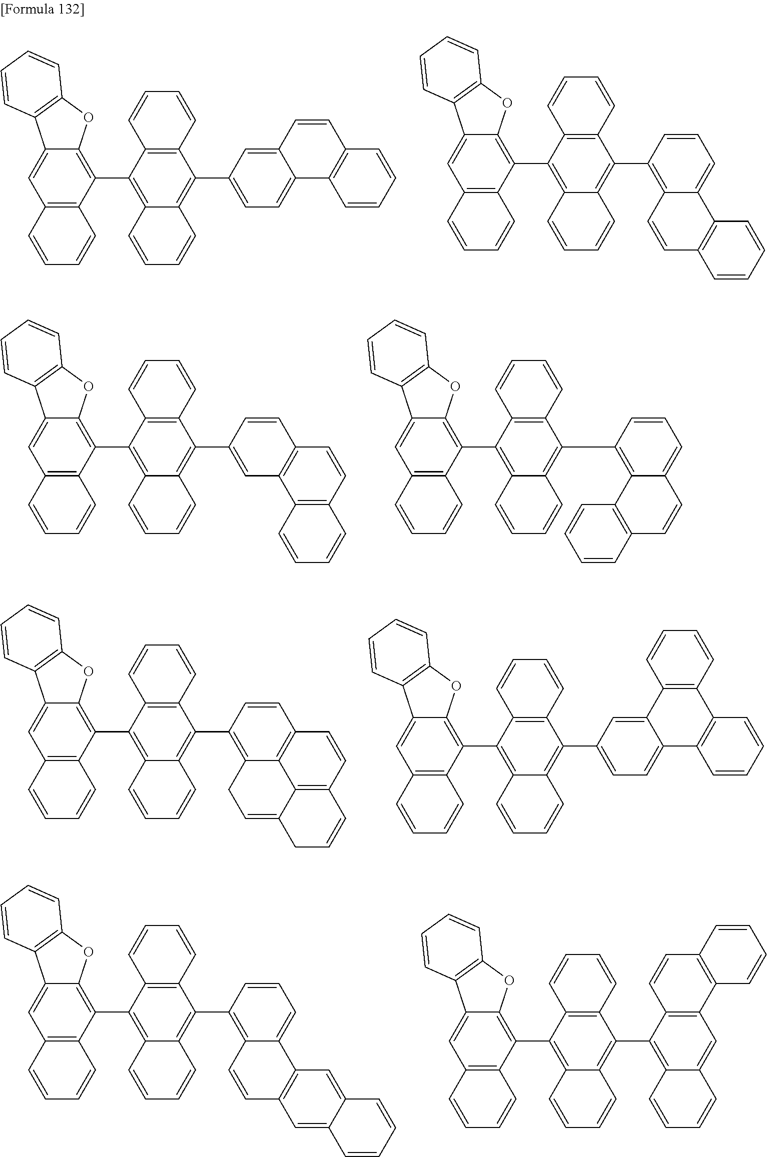

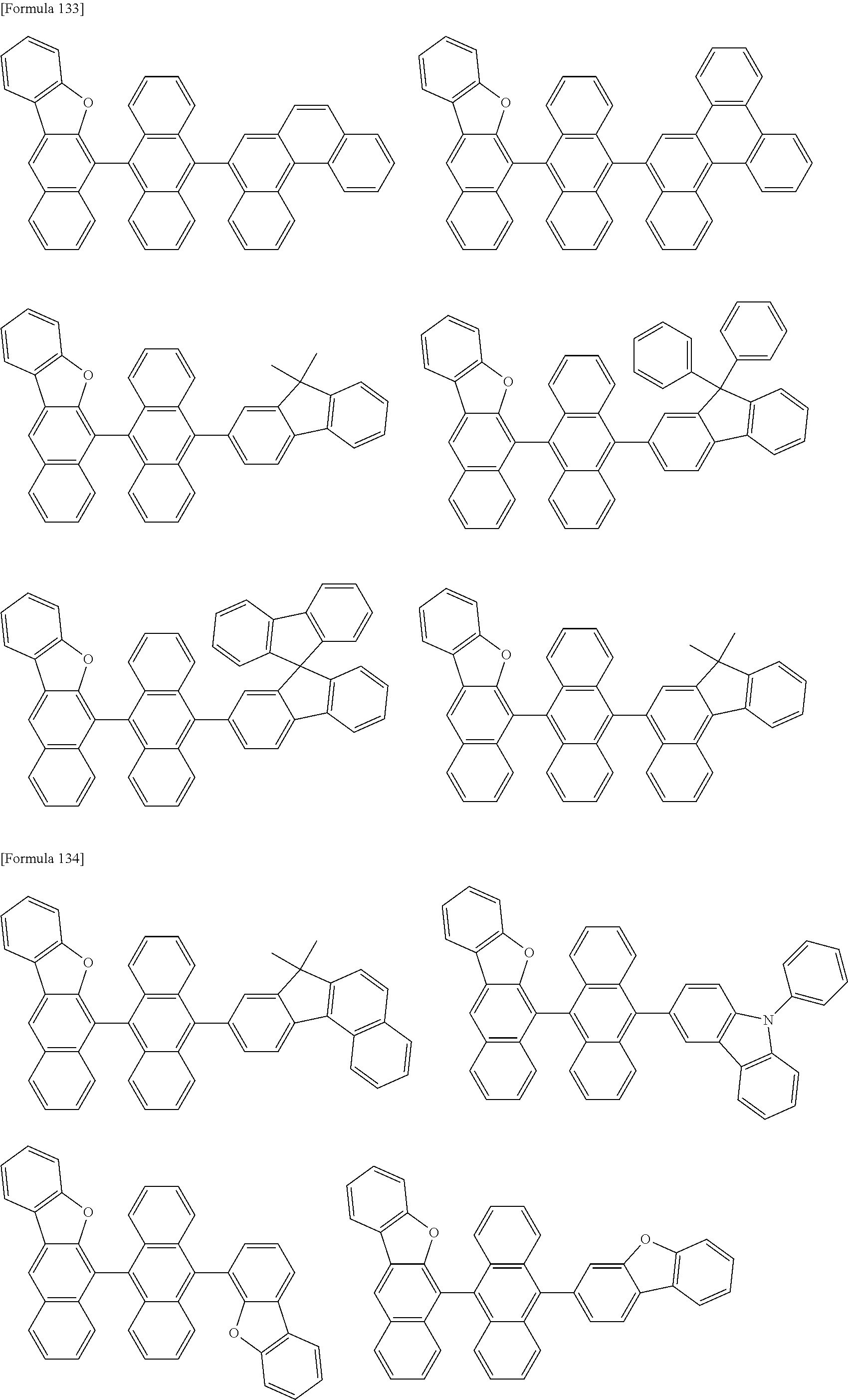

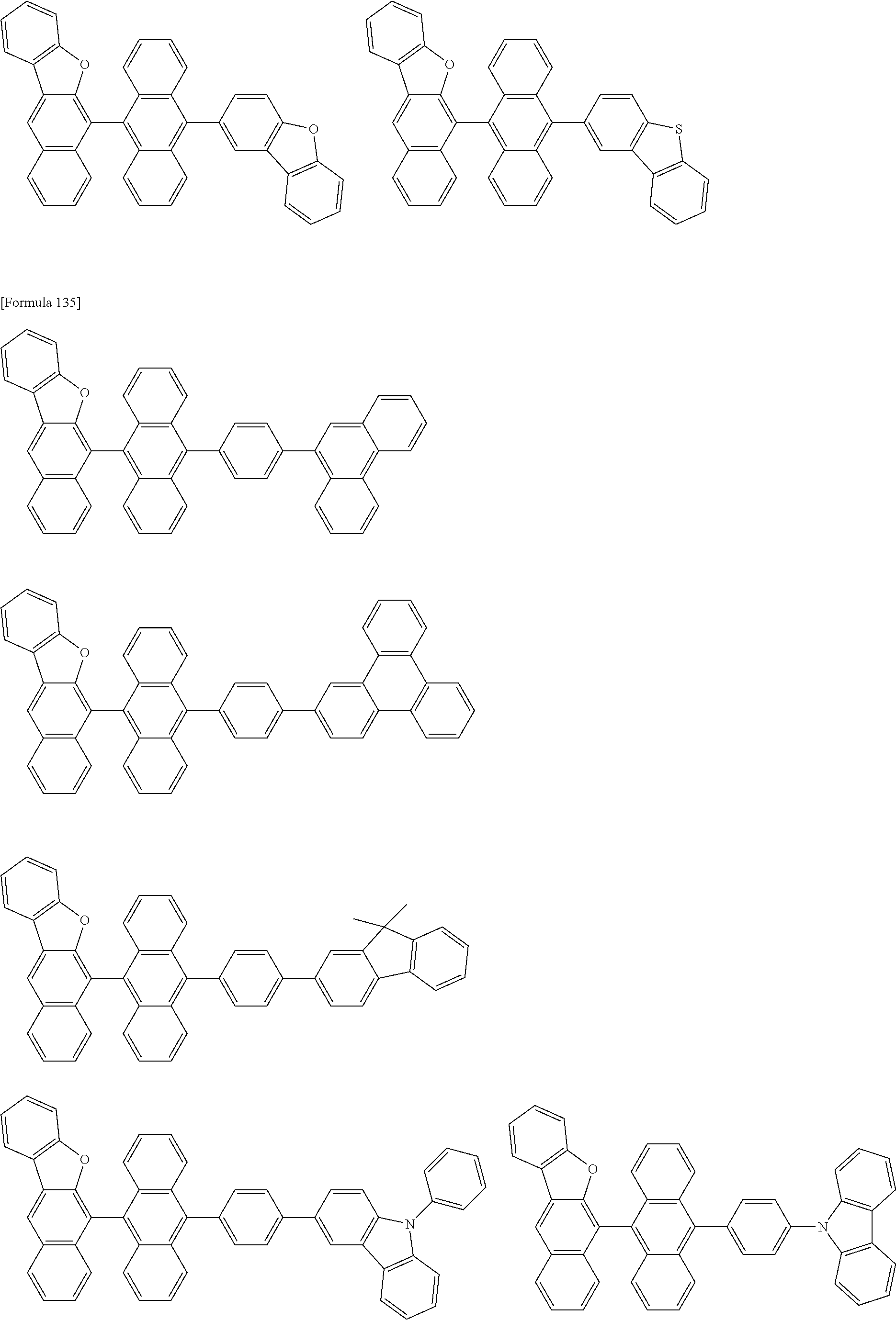

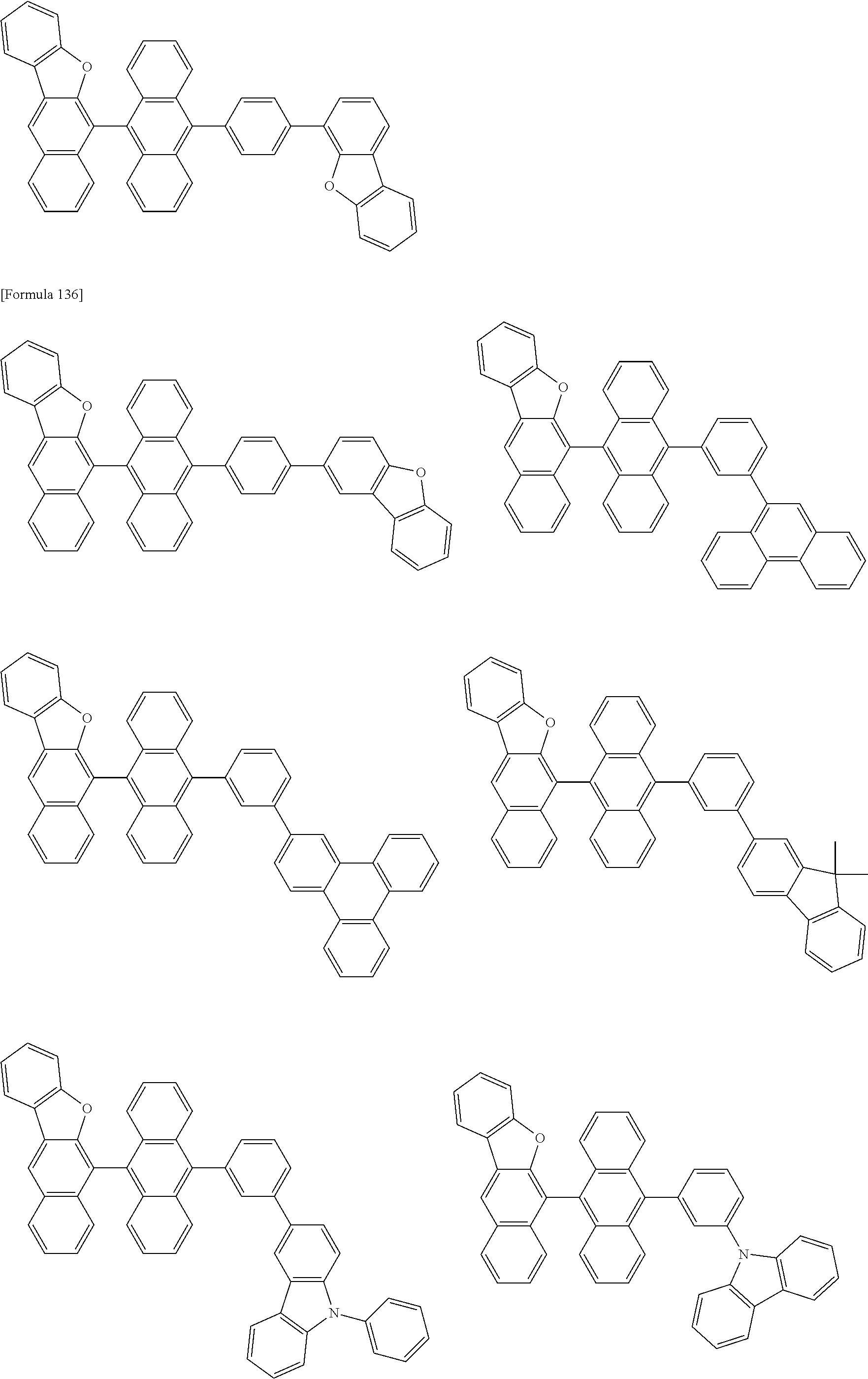

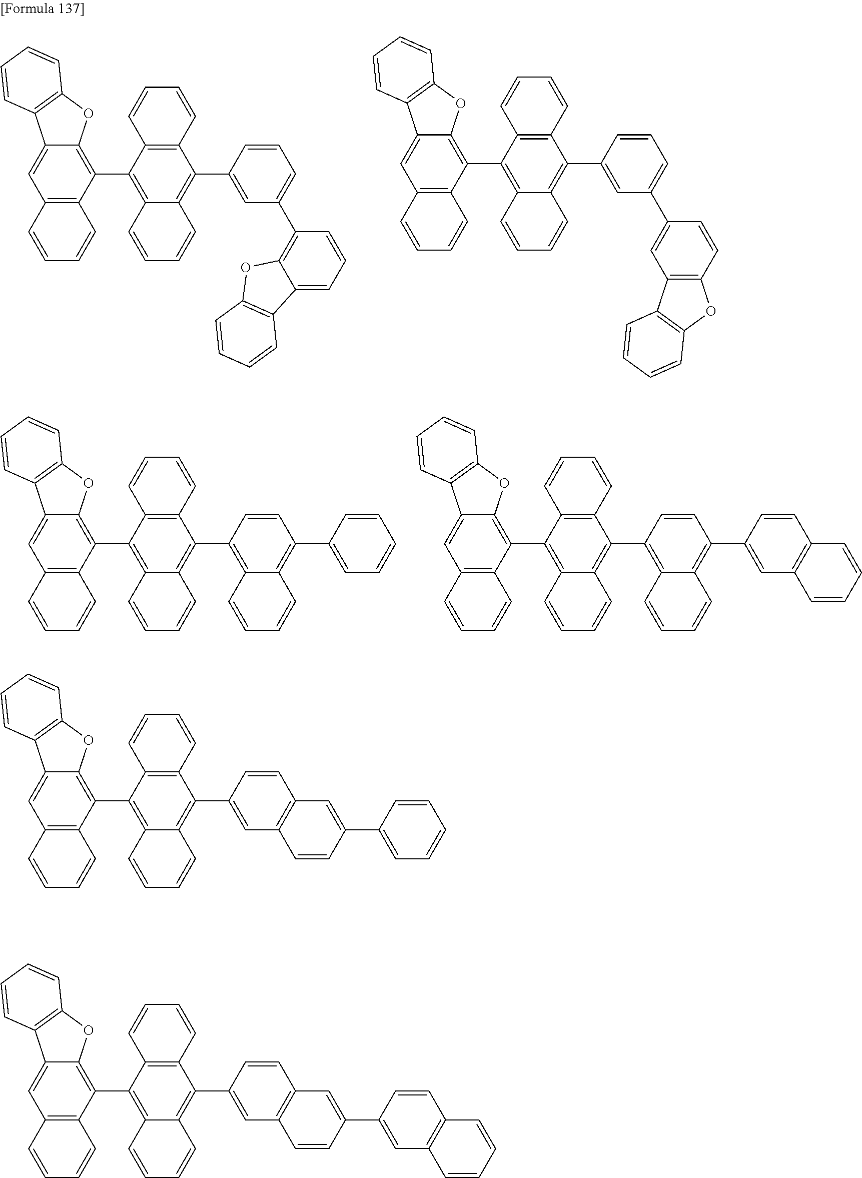 [SMILES: c1cc(-c2c3ccccc3c(-c3c4ccccc4cc4c3oc3ccccc34)c3ccccc23)cc(-c2cccc3c2oc2ccccc23)c1 ; c1cc(-c2ccc3oc4ccccc4c3c2)cc(-c2c3ccccc3c(-c3c4ccccc4cc4c3oc3ccccc34)c3ccccc23)c1 ; c1ccc(-c2ccc(-c3c4ccccc4c(-c4c5ccccc5cc5c4oc4ccccc45)c4ccccc34)c3ccccc23)cc1 ; c1ccc2cc(-c3ccc(-c4c5ccccc5c(-c5c6ccccc6cc6c5oc5ccccc56)c5ccccc45)c4ccccc34)ccc2c1 ; c1ccc(-c2ccc3cc(-c4c5ccccc5c(-c5c6ccccc6cc6c5oc5ccccc56)c5ccccc45)ccc3c2)cc1 ; c1ccc2cc(-c3ccc4cc(-c5c6ccccc6c(-c6c7ccccc7cc7c6oc6ccccc67)c6ccccc56)ccc4c3)ccc2c1]

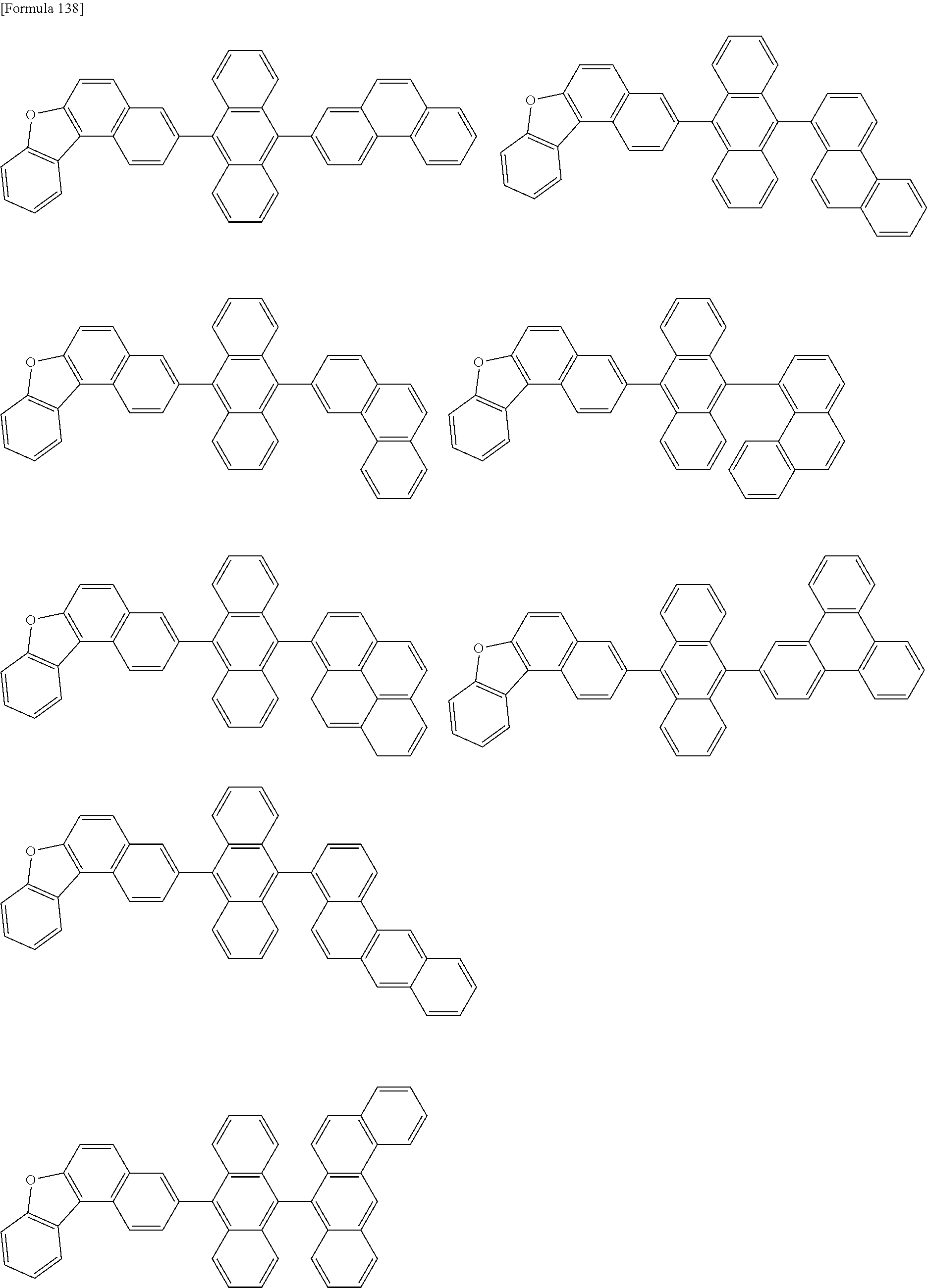

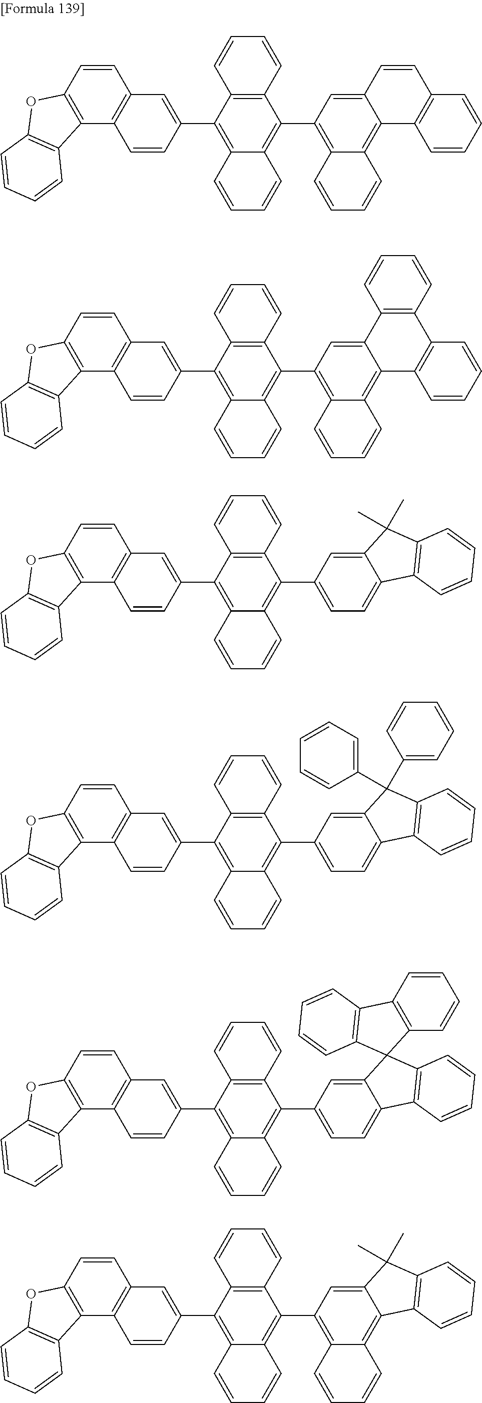

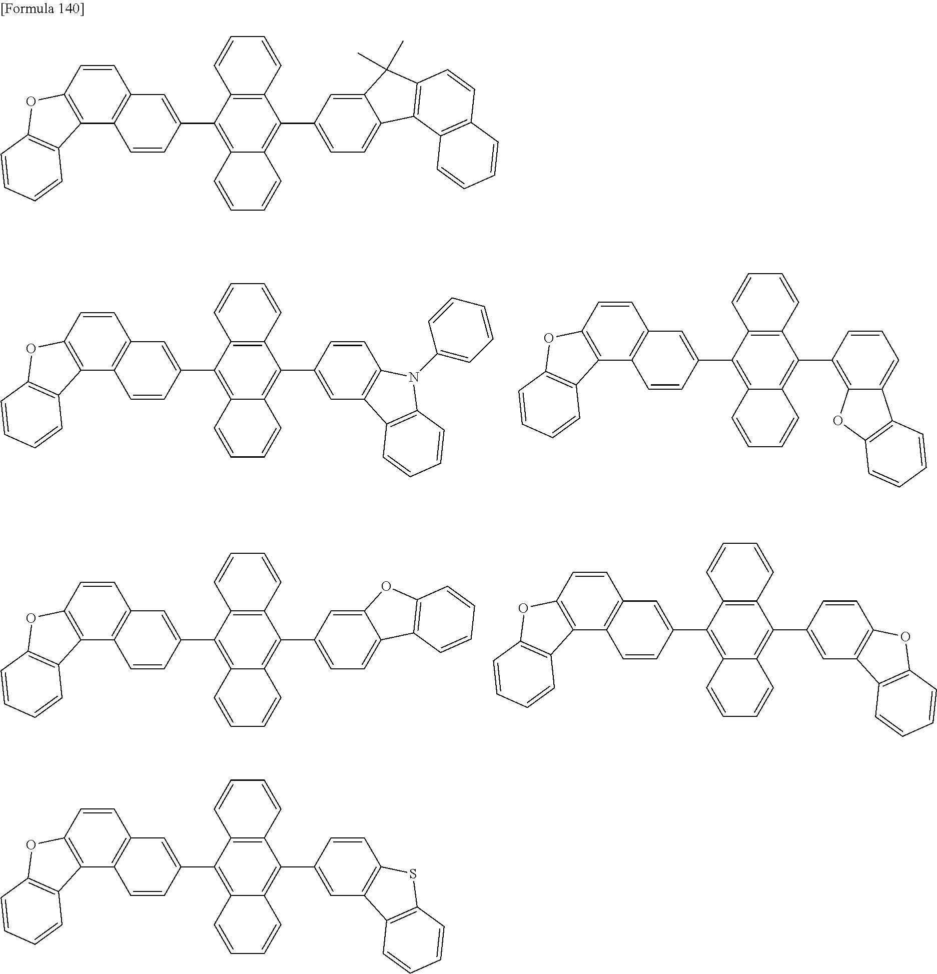

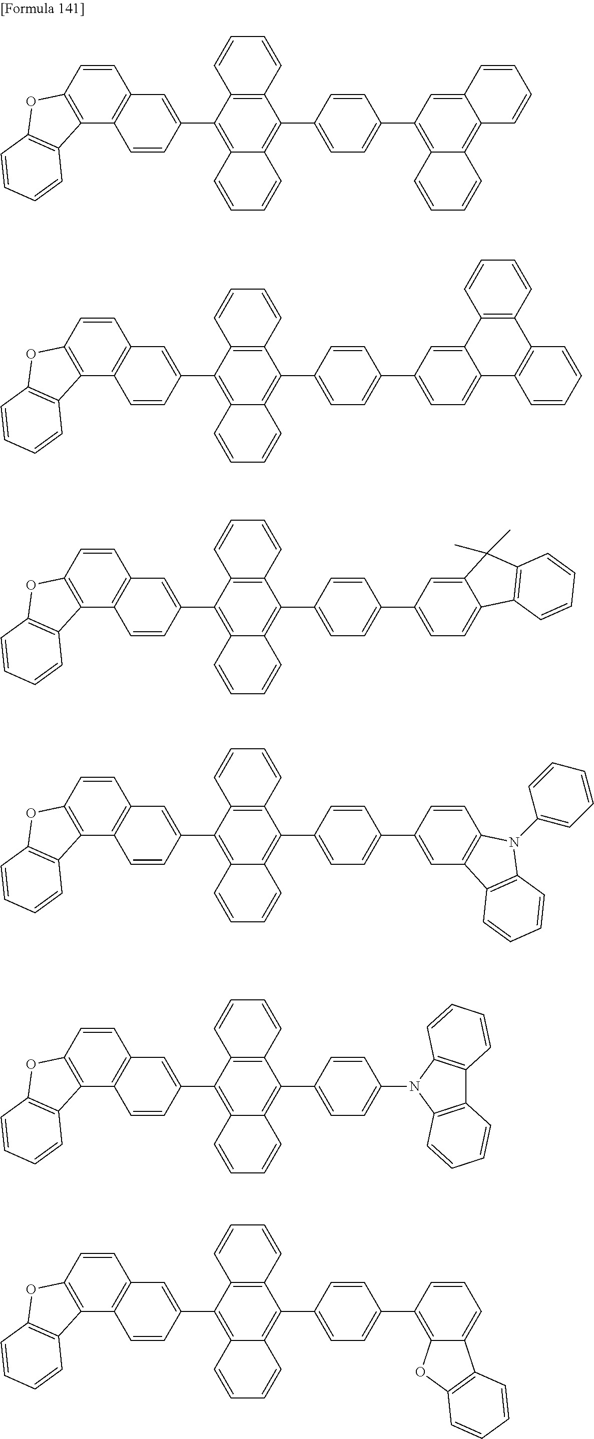

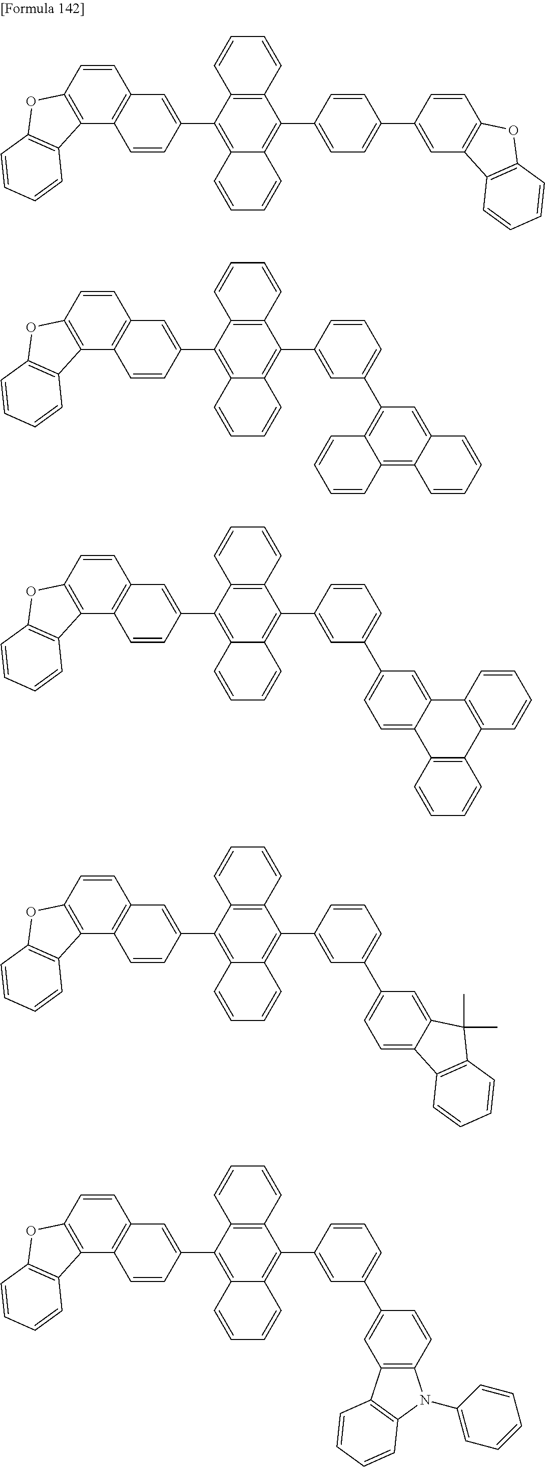 [SMILES: c1ccc2c(c1)oc1ccc(-c3ccc(-c4c5ccccc5c(-c5ccc6c(ccc7oc8ccccc8c76)c5)c5ccccc45)cc3)cc12 ; c1cc(-c2c3ccccc3c(-c3ccc4c(ccc5oc6ccccc6c54)c3)c3ccccc23)cc(-c2cc3ccccc3c3ccccc23)c1 ; c1cc(-c2ccc3c4ccccc4c4ccccc4c3c2)cc(-c2c3ccccc3c(-c3ccc4c(ccc5oc6ccccc6c54)c3)c3ccccc23)c1 ; CC1(C)c2ccccc2-c2ccc(-c3cccc(-c4c5ccccc5c(-c5ccc6c(ccc7oc8ccccc8c76)c5)c5ccccc45)c3)cc21 ; c1ccc(-n2c3ccccc3c3cc(-c4cccc(-c5c6ccccc6c(-c6ccc7c(ccc8oc9ccccc9c87)c6)c6ccccc56)c4)ccc32)cc1]

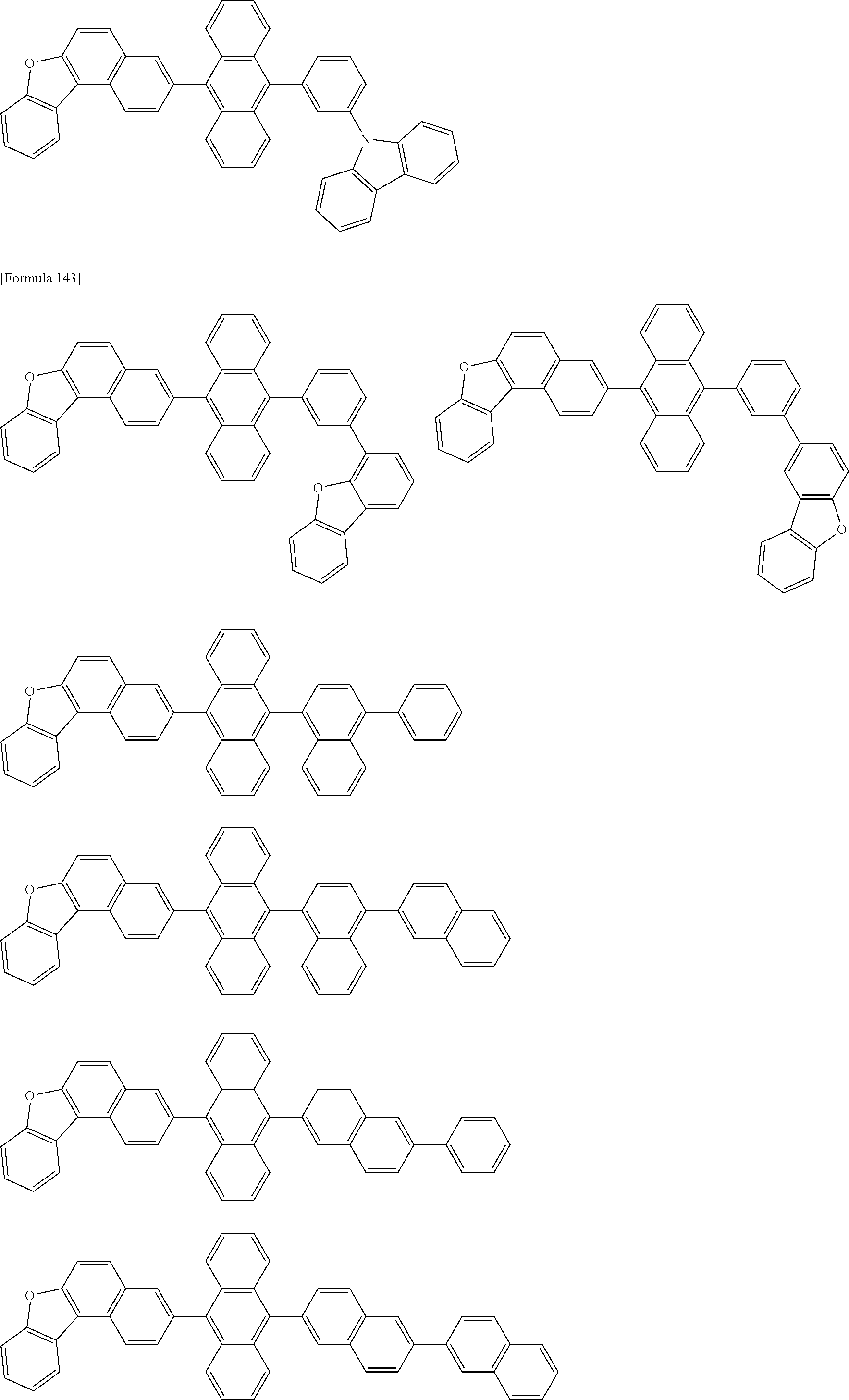

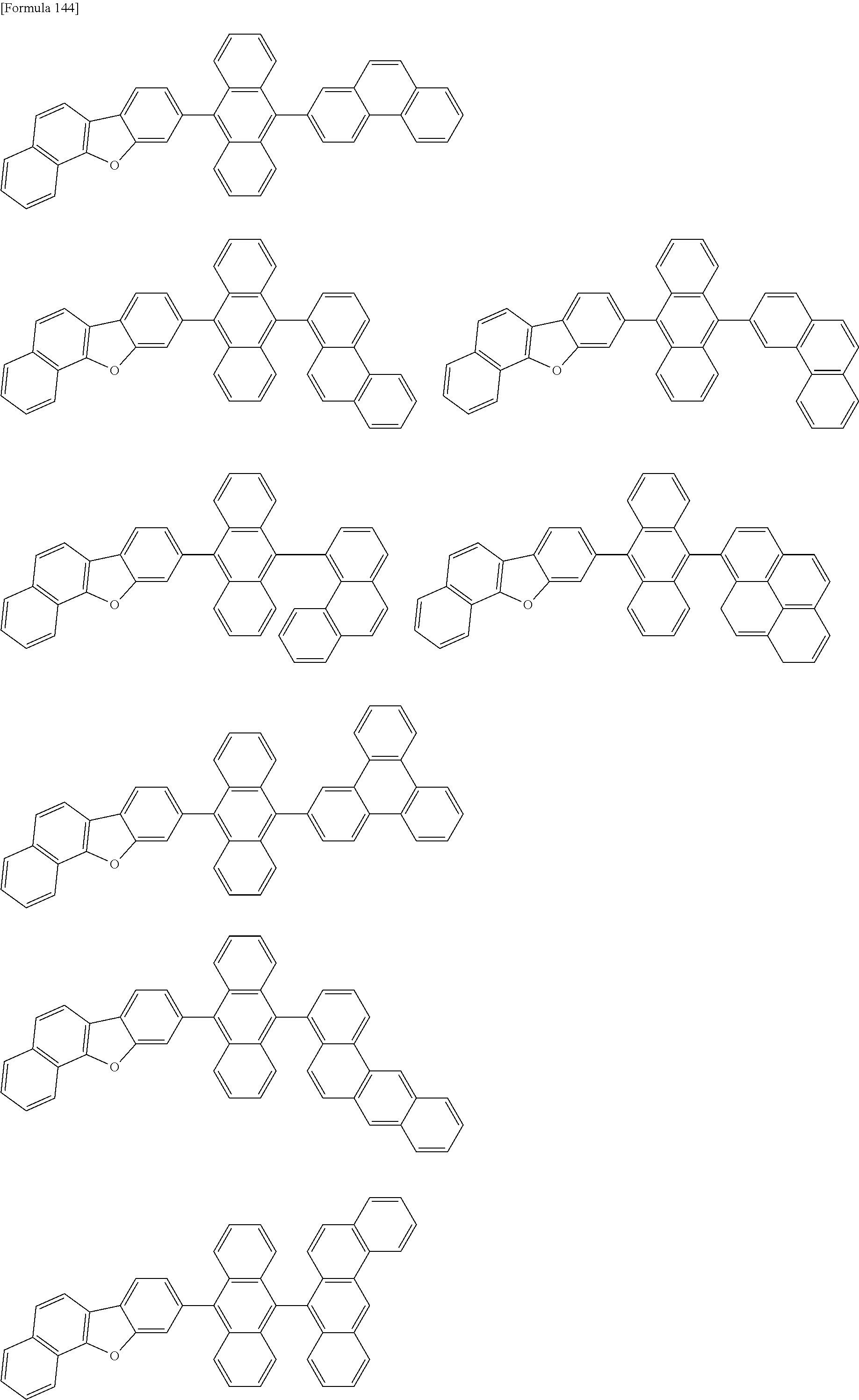

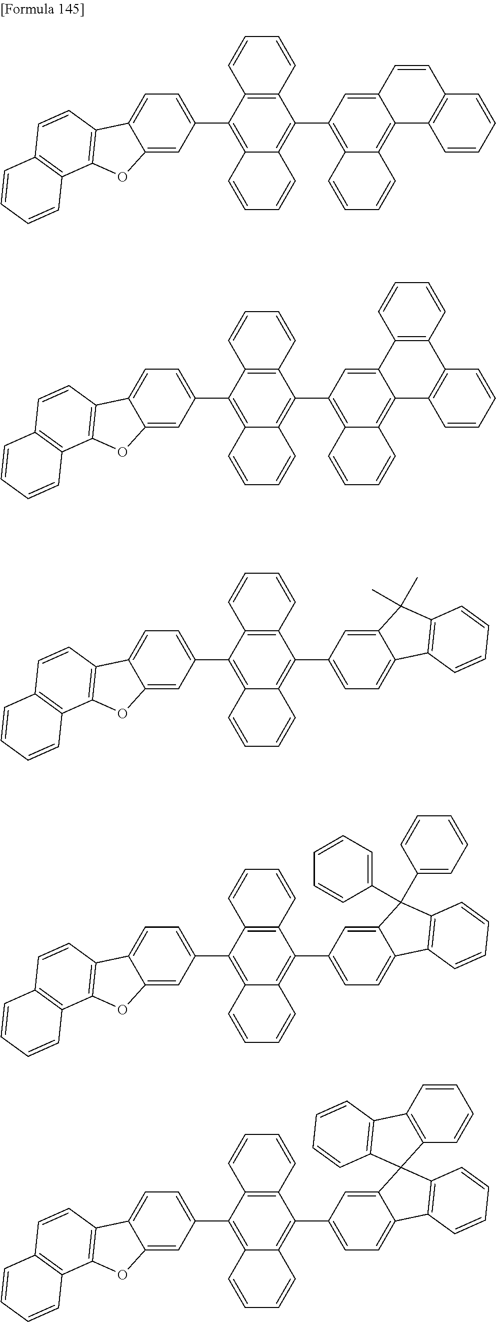 [SMILES: c1ccc2c(c1)ccc1c3ccc(-c4c5ccccc5c(-c5cc6ccc7ccccc7c6c6ccccc56)c5ccccc45)cc3oc21 ; c1ccc2c(c1)ccc1c3ccc(-c4c5ccccc5c(-c5cc6c7ccccc7c7ccccc7c6c6ccccc56)c5ccccc45)cc3oc21 ; CC1(C)c2ccccc2-c2ccc(-c3c4ccccc4c(-c4ccc5c(c4)oc4c6ccccc6ccc54)c4ccccc34)cc21 ; c1ccc(C2(c3ccccc3)c3ccccc3-c3ccc(-c4c5ccccc5c(-c5ccc6c(c5)oc5c7ccccc7ccc65)c5ccccc45)cc32)cc1 ; c1ccc2c(c1)-c1ccccc1C21c2ccccc2-c2ccc(-c3c4ccccc4c(-c4ccc5c(c4)oc4c6ccccc6ccc54)c4ccccc34)cc21]

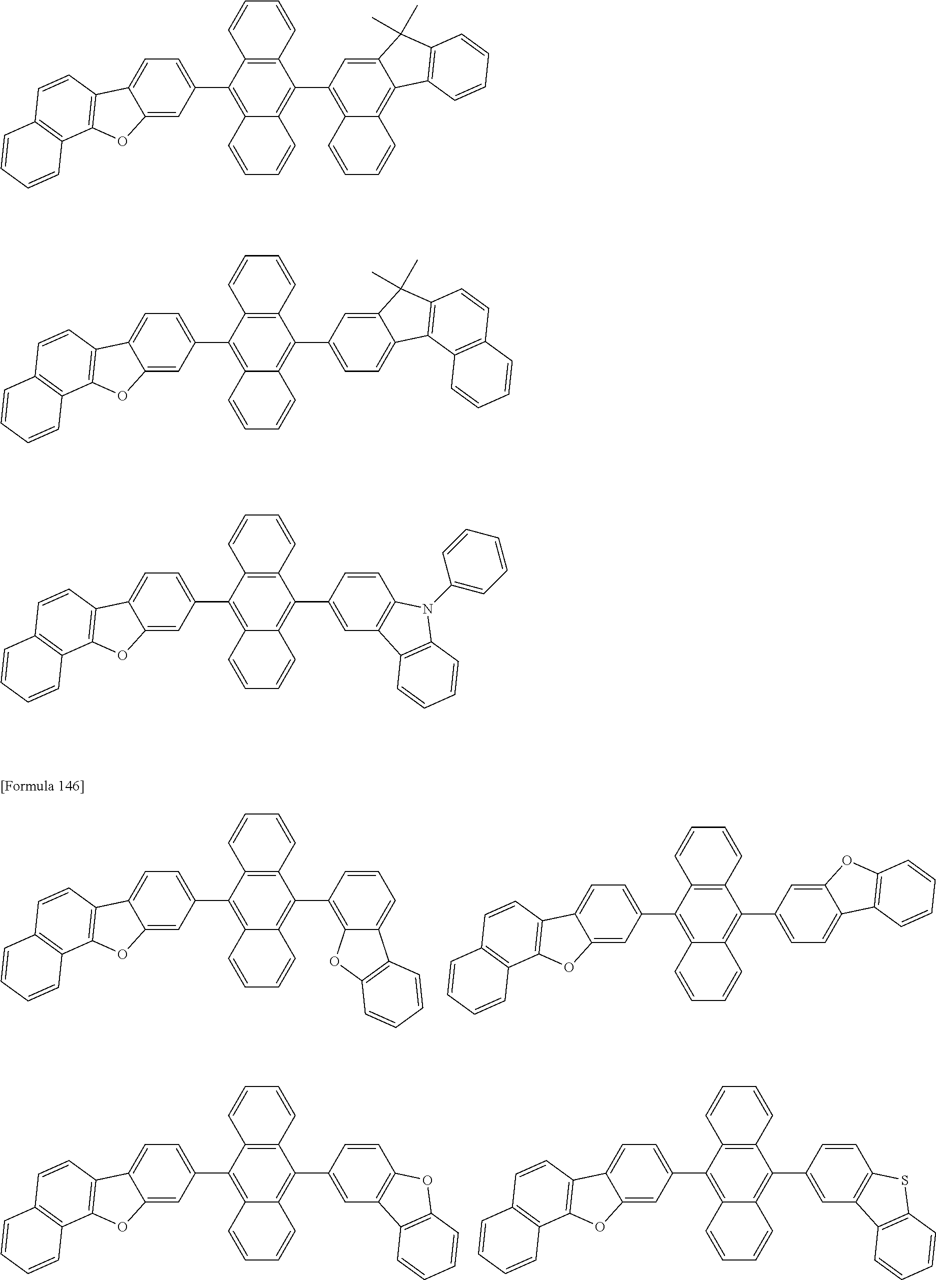

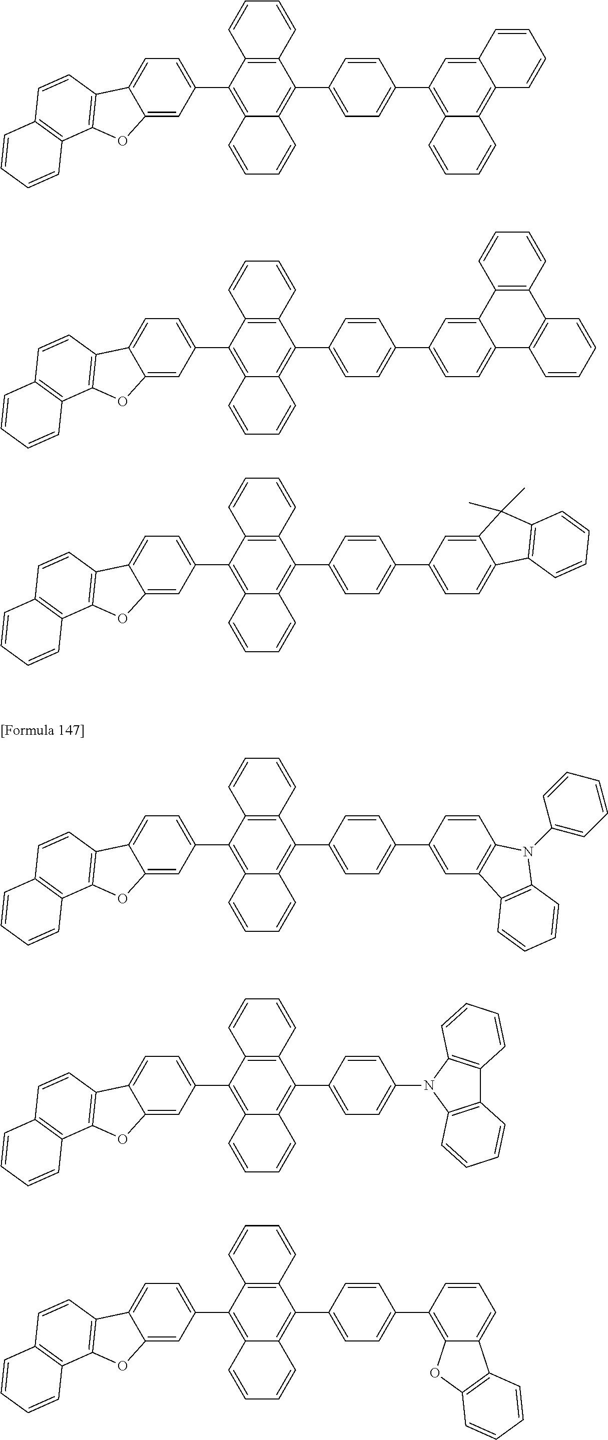

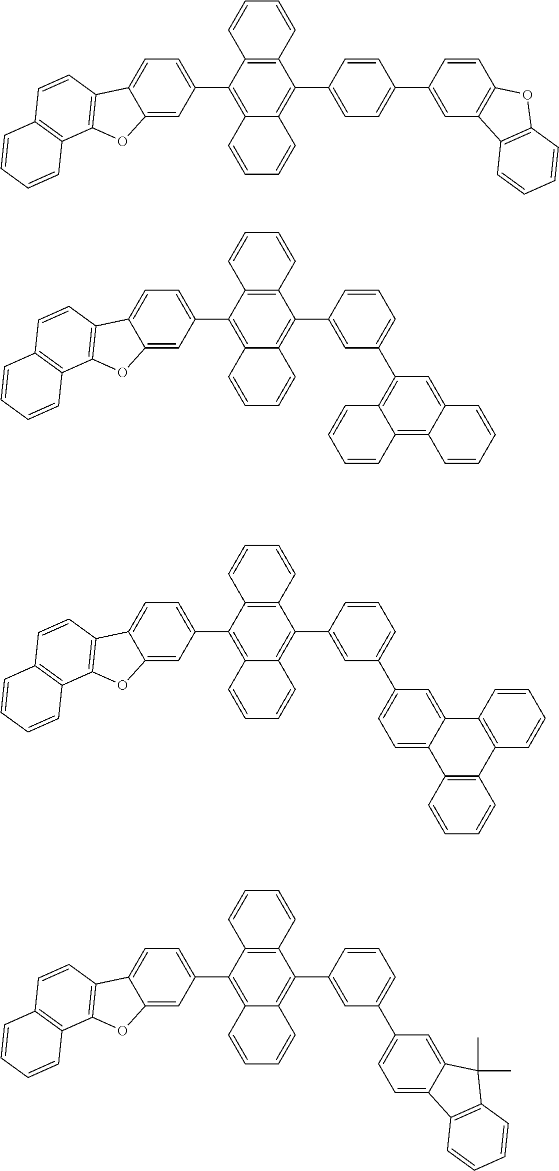 [SMILES: c1ccc2c(c1)ccc1c3ccc(-c4c5ccccc5c(-c5ccc(-c6ccc7oc8ccccc8c7c6)cc5)c5ccccc45)cc3oc21 ; c1cc(-c2c3ccccc3c(-c3ccc4c(c3)oc3c5ccccc5ccc43)c3ccccc23)cc(-c2cc3ccccc3c3ccccc23)c1 ; c1cc(-c2ccc3c4ccccc4c4ccccc4c3c2)cc(-c2c3ccccc3c(-c3ccc4c(c3)oc3c5ccccc5ccc43)c3ccccc23)c1 ; CC1(C)c2ccccc2-c2ccc(-c3cccc(-c4c5ccccc5c(-c5ccc6c(c5)oc5c7ccccc7ccc65)c5ccccc45)c3)cc21]

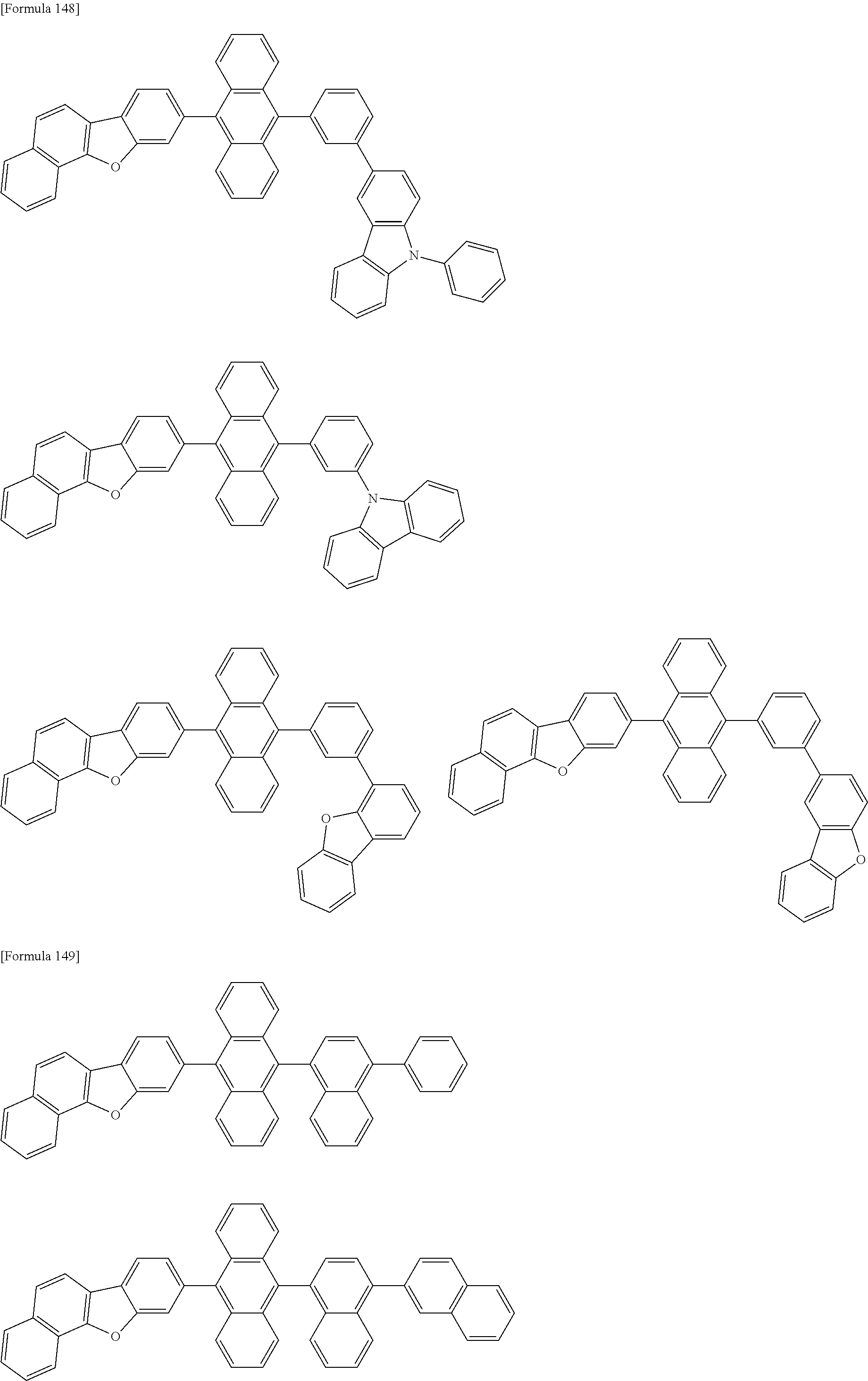

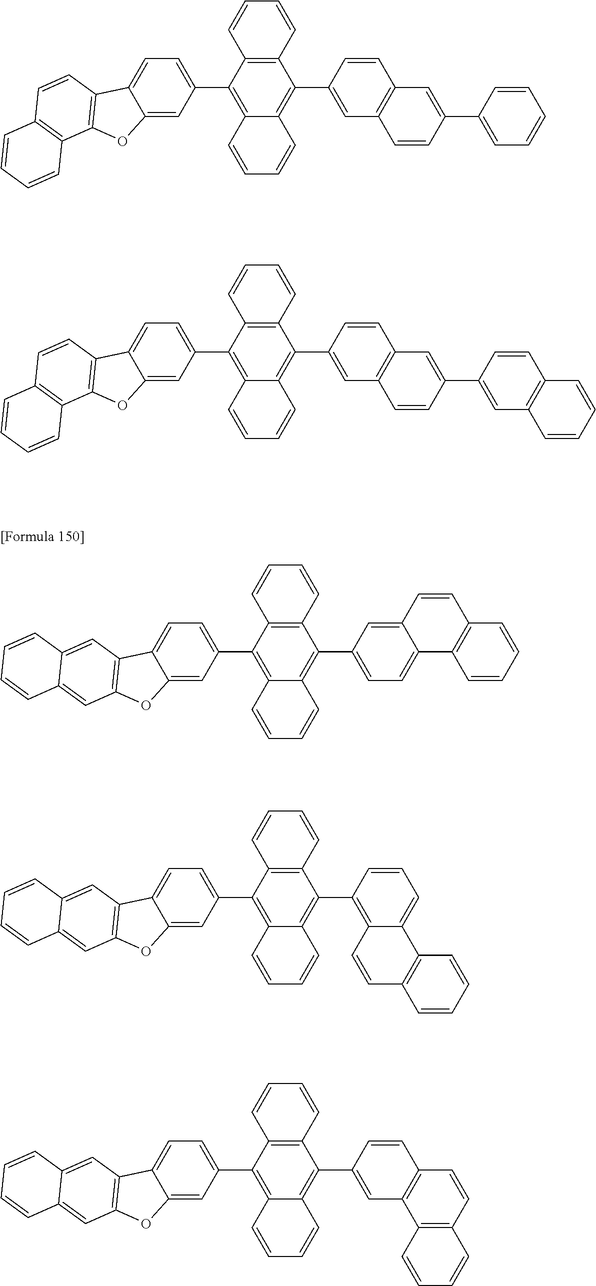 [SMILES: c1ccc(-c2ccc3cc(-c4c5ccccc5c(-c5ccc6c(c5)oc5c7ccccc7ccc65)c5ccccc45)ccc3c2)cc1 ; c1ccc2cc(-c3ccc4cc(-c5c6ccccc6c(-c6ccc7c(c6)oc6c8ccccc8ccc76)c6ccccc56)ccc4c3)ccc2c1 ; c1ccc2cc3c(cc2c1)oc1cc(-c2c4ccccc4c(-c4ccc5c(ccc6ccccc65)c4)c4ccccc24)ccc13 ; c1ccc2cc3c(cc2c1)oc1cc(-c2c4ccccc4c(-c4cccc5c4ccc4ccccc45)c4ccccc24)ccc13 ; c1ccc2cc3c(cc2c1)oc1cc(-c2c4ccccc4c(-c4ccc5ccc6ccccc6c5c4)c4ccccc24)ccc13]

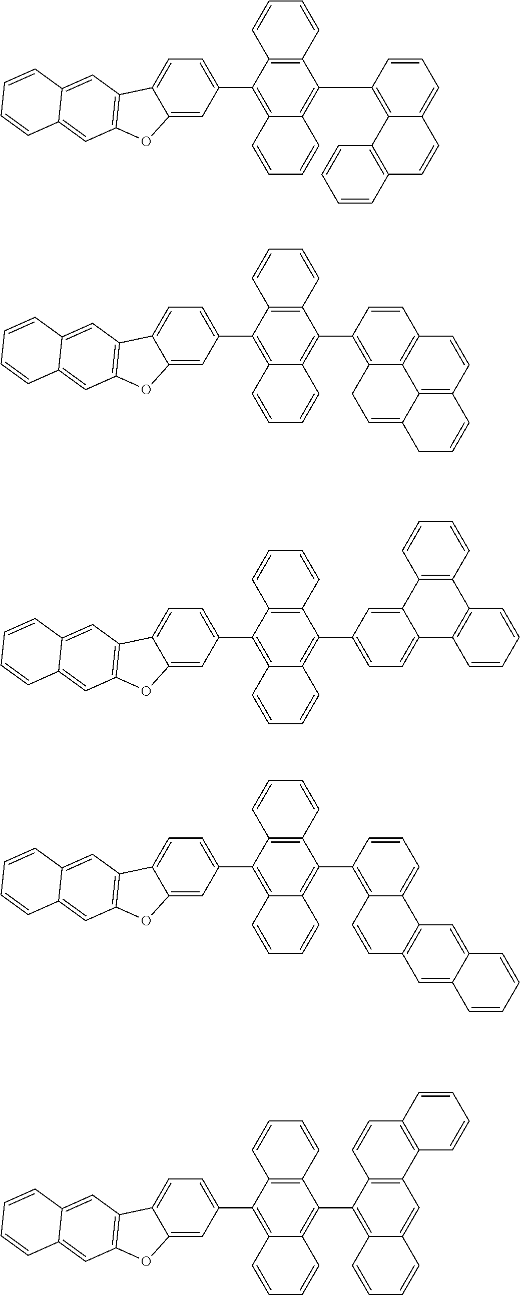 [SMILES: c1ccc2cc3c(cc2c1)oc1cc(-c2c4ccccc4c(-c4cccc5ccc6ccccc6c45)c4ccccc24)ccc13 ; C1=Cc2ccc3ccc(-c4c5ccccc5c(-c5ccc6c(c5)oc5cc7ccccc7cc56)c5ccccc45)c4c3c2C(=CC4)C1 ; c1ccc2cc3c(cc2c1)oc1cc(-c2c4ccccc4c(-c4ccc5c6ccccc6c6ccccc6c5c4)c4ccccc24)ccc13 ; c1ccc2cc3c(ccc4c(-c5c6ccccc6c(-c6ccc7c(c6)oc6cc8ccccc8cc67)c6ccccc56)cccc43)cc2c1 ; c1ccc2cc3c(cc2c1)oc1cc(-c2c4ccccc4c(-c4c5ccccc5cc5c4ccc4ccccc45)c4ccccc24)ccc13]

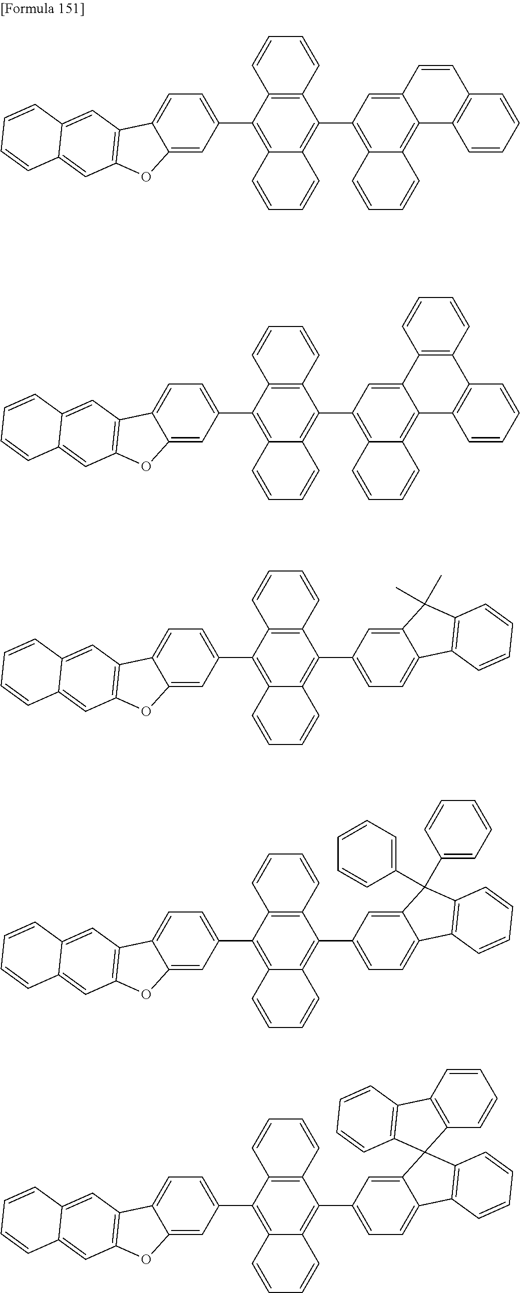 [SMILES: c1ccc2cc3c(cc2c1)oc1cc(-c2c4ccccc4c(-c4cc5ccc6ccccc6c5c5ccccc45)c4ccccc24)ccc13 ; c1ccc2cc3c(cc2c1)oc1cc(-c2c4ccccc4c(-c4cc5c6ccccc6c6ccccc6c5c5ccccc45)c4ccccc24)ccc13 ; CC1(C)c2ccccc2-c2ccc(-c3c4ccccc4c(-c4ccc5c(c4)oc4cc6ccccc6cc45)c4ccccc34)cc21 ; c1ccc(C2(c3ccccc3)c3ccccc3-c3ccc(-c4c5ccccc5c(-c5ccc6c(c5)oc5cc7ccccc7cc56)c5ccccc45)cc32)cc1 ; c1ccc2c(c1)-c1ccccc1C21c2ccccc2-c2ccc(-c3c4ccccc4c(-c4ccc5c(c4)oc4cc6ccccc6cc45)c4ccccc34)cc21]

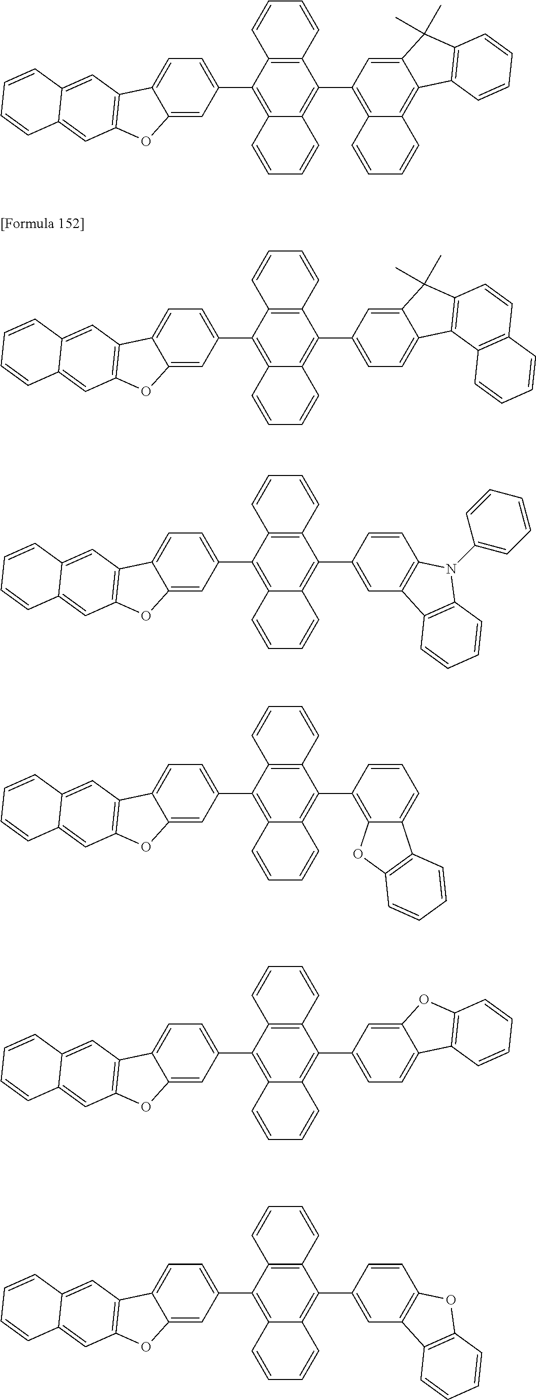 [SMILES: CC1(C)c2ccccc2-c2c1cc(-c1c3ccccc3c(-c3ccc4c(c3)oc3cc5ccccc5cc34)c3ccccc13)c1ccccc21 ; CC1(C)c2cc(-c3c4ccccc4c(-c4ccc5c(c4)oc4cc6ccccc6cc45)c4ccccc34)ccc2-c2c1ccc1ccccc21 ; c1ccc(-n2c3ccccc3c3cc(-c4c5ccccc5c(-c5ccc6c(c5)oc5cc7ccccc7cc56)c5ccccc45)ccc32)cc1 ; c1ccc2cc3c(cc2c1)oc1cc(-c2c4ccccc4c(-c4cccc5c4oc4ccccc45)c4ccccc24)ccc13 ; c1ccc2cc3c(cc2c1)oc1cc(-c2c4ccccc4c(-c4ccc5c(c4)oc4ccccc45)c4ccccc24)ccc13 ; c1ccc2cc3c(cc2c1)oc1cc(-c2c4ccccc4c(-c4ccc5oc6ccccc6c5c4)c4ccccc24)ccc13]

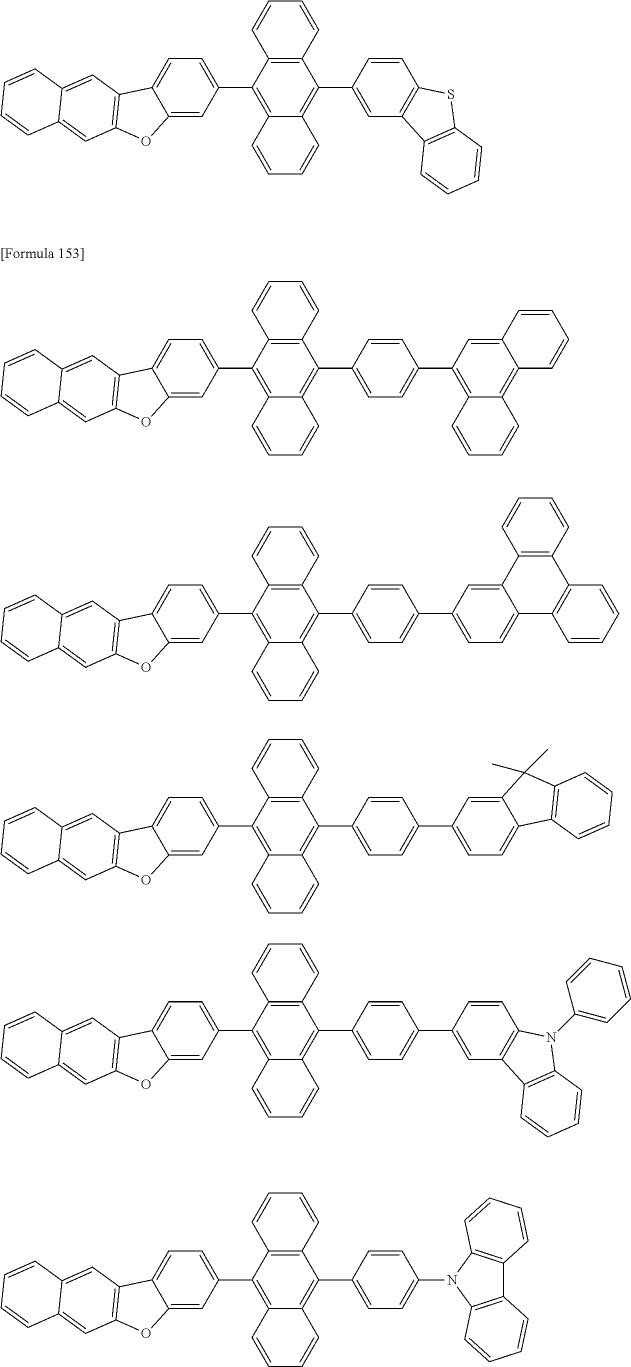

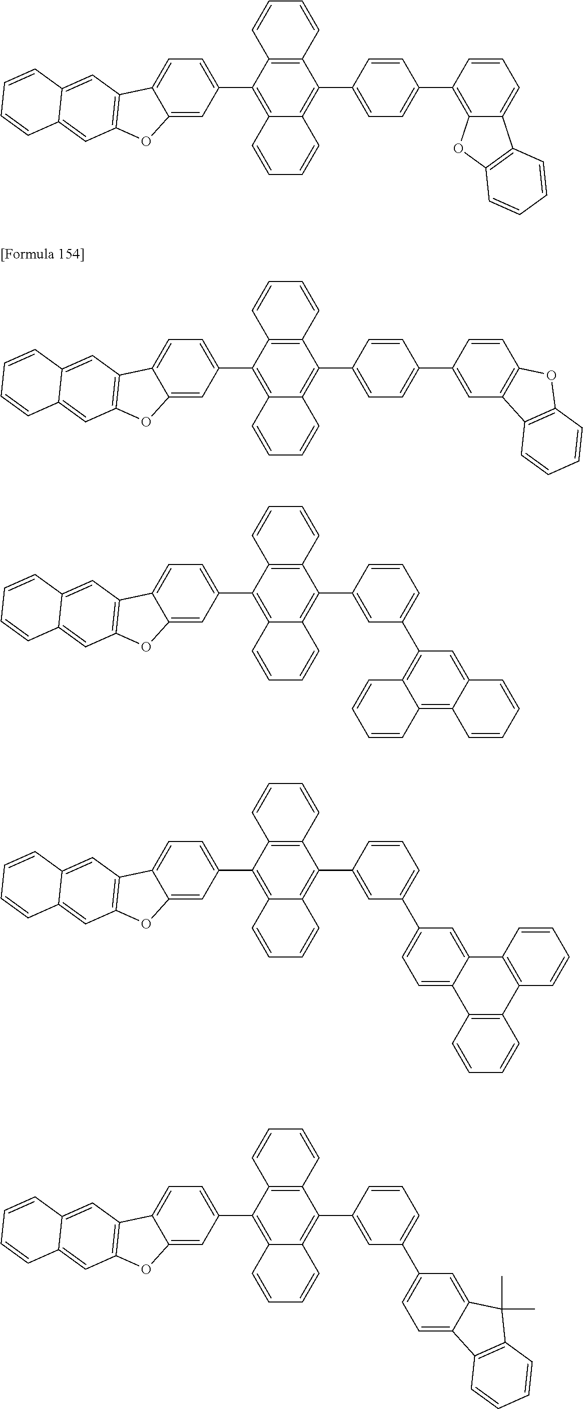 [SMILES: c1ccc2cc3c(cc2c1)oc1cc(-c2c4ccccc4c(-c4ccc(-c5cccc6c5oc5ccccc56)cc4)c4ccccc24)ccc13 ; c1ccc2cc3c(cc2c1)oc1cc(-c2c4ccccc4c(-c4ccc(-c5ccc6oc7ccccc7c6c5)cc4)c4ccccc24)ccc13 ; c1cc(-c2c3ccccc3c(-c3ccc4c(c3)oc3cc5ccccc5cc34)c3ccccc23)cc(-c2cc3ccccc3c3ccccc23)c1 ; c1cc(-c2ccc3c4ccccc4c4ccccc4c3c2)cc(-c2c3ccccc3c(-c3ccc4c(c3)oc3cc5ccccc5cc34)c3ccccc23)c1 ; CC1(C)c2ccccc2-c2ccc(-c3cccc(-c4c5ccccc5c(-c5ccc6c(c5)oc5cc7ccccc7cc56)c5ccccc45)c3)cc21]

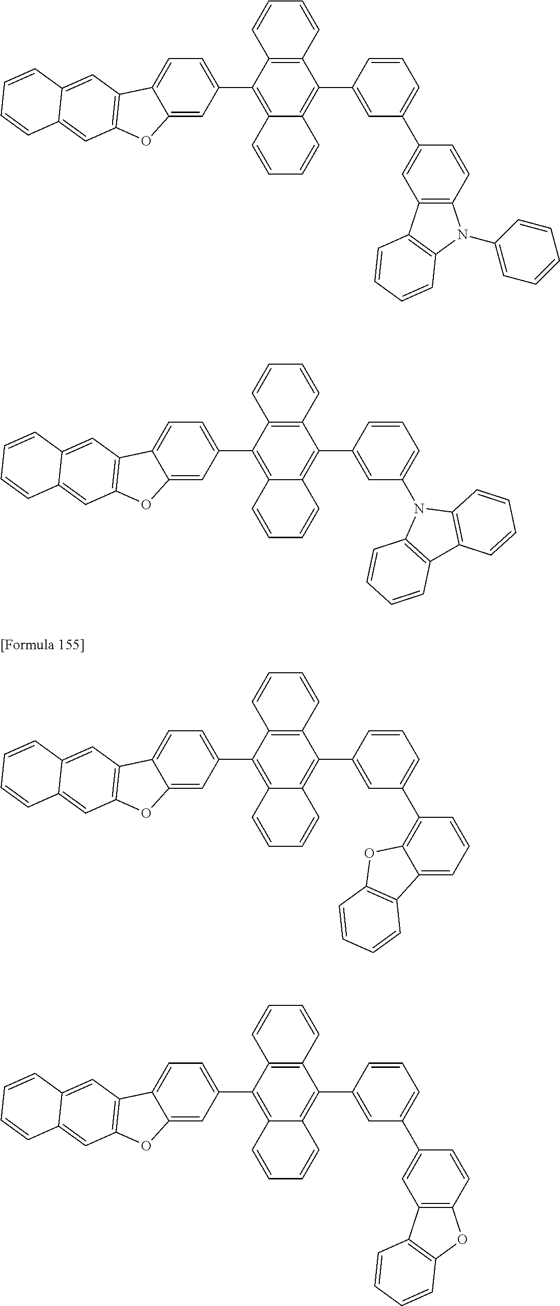 [SMILES: c1ccc(-n2c3ccccc3c3cc(-c4cccc(-c5c6ccccc6c(-c6ccc7c(c6)oc6cc8ccccc8cc67)c6ccccc56)c4)ccc32)cc1 ; c1cc(-c2c3ccccc3c(-c3ccc4c(c3)oc3cc5ccccc5cc34)c3ccccc23)cc(-n2c3ccccc3c3ccccc32)c1 ; c1cc(-c2c3ccccc3c(-c3ccc4c(c3)oc3cc5ccccc5cc34)c3ccccc23)cc(-c2cccc3c2oc2ccccc23)c1 ; c1cc(-c2ccc3oc4ccccc4c3c2)cc(-c2c3ccccc3c(-c3ccc4c(c3)oc3cc5ccccc5cc34)c3ccccc23)c1]

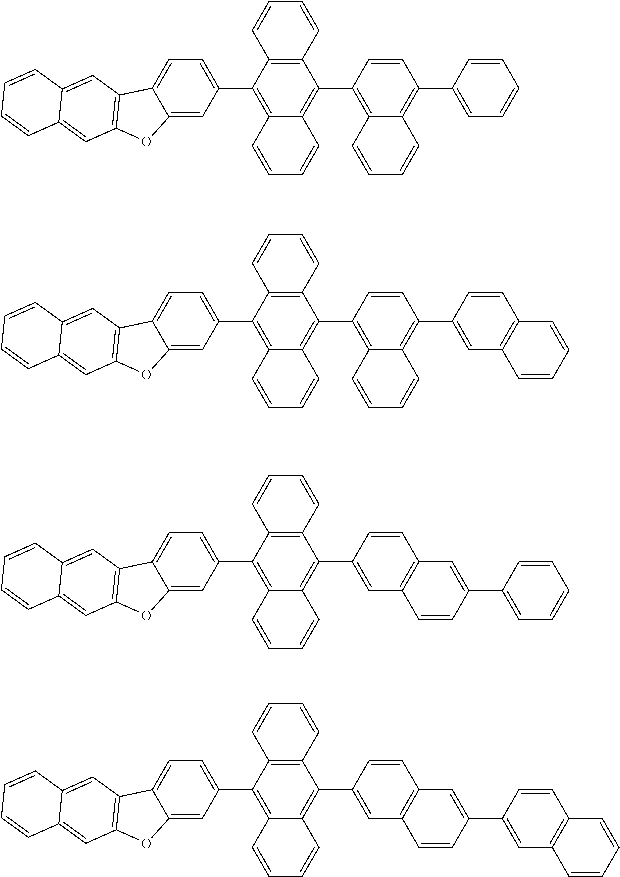 [SMILES: c1ccc(-c2ccc(-c3c4ccccc4c(-c4ccc5c(c4)oc4cc6ccccc6cc45)c4ccccc34)c3ccccc23)cc1 ; c1ccc2cc(-c3ccc(-c4c5ccccc5c(-c5ccc6c(c5)oc5cc7ccccc7cc56)c5ccccc45)c4ccccc34)ccc2c1 ; c1ccc(-c2ccc3cc(-c4c5ccccc5c(-c5ccc6c(c5)oc5cc7ccccc7cc56)c5ccccc45)ccc3c2)cc1 ; c1ccc2cc(-c3ccc4cc(-c5c6ccccc6c(-c6ccc7c(c6)oc6cc8ccccc8cc67)c6ccccc56)ccc4c3)ccc2c1]

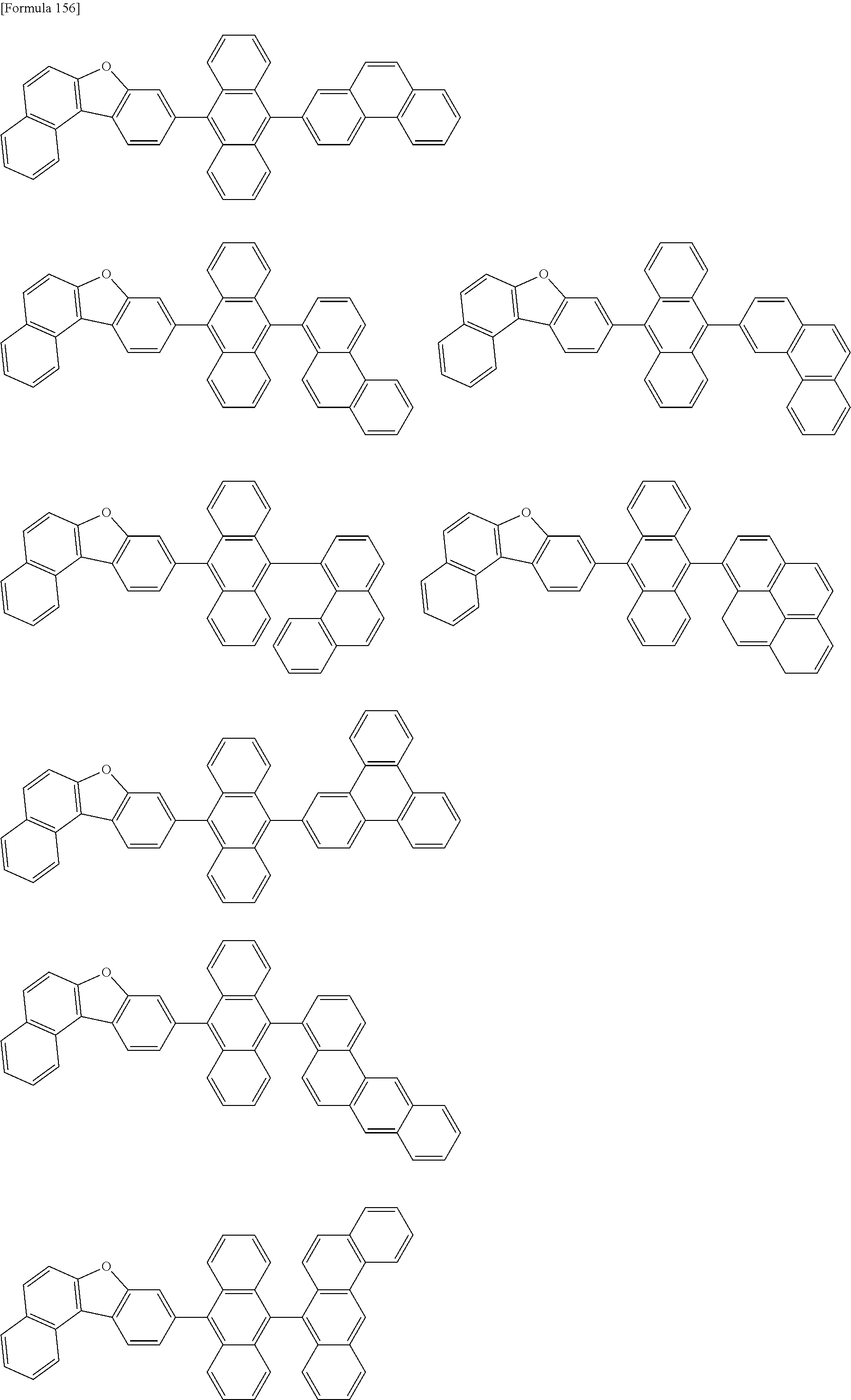

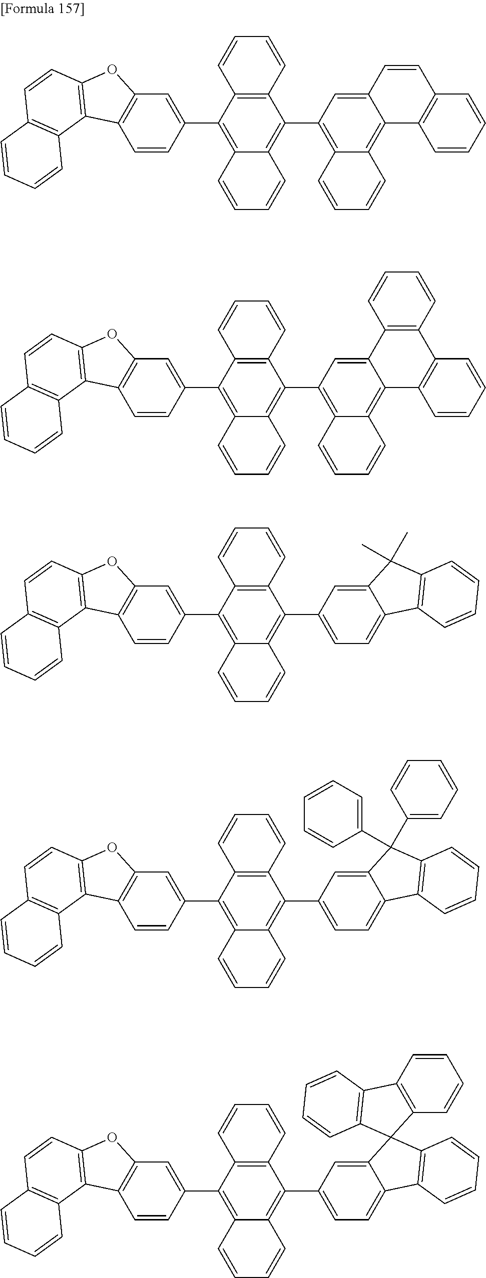 [SMILES: c1ccc2c(c1)ccc1cc(-c3c4ccccc4c(-c4ccc5c(c4)oc4ccc6ccccc6c45)c4ccccc34)c3ccccc3c12 ; c1ccc2c(c1)ccc1oc3cc(-c4c5ccccc5c(-c5cc6c7ccccc7c7ccccc7c6c6ccccc56)c5ccccc45)ccc3c12 ; CC1(C)c2ccccc2-c2ccc(-c3c4ccccc4c(-c4ccc5c(c4)oc4ccc6ccccc6c45)c4ccccc34)cc21 ; c1ccc(C2(c3ccccc3)c3ccccc3-c3ccc(-c4c5ccccc5c(-c5ccc6c(c5)oc5ccc7ccccc7c56)c5ccccc45)cc32)cc1 ; c1ccc2c(c1)-c1ccccc1C21c2ccccc2-c2ccc(-c3c4ccccc4c(-c4ccc5c(c4)oc4ccc6ccccc6c45)c4ccccc34)cc21]

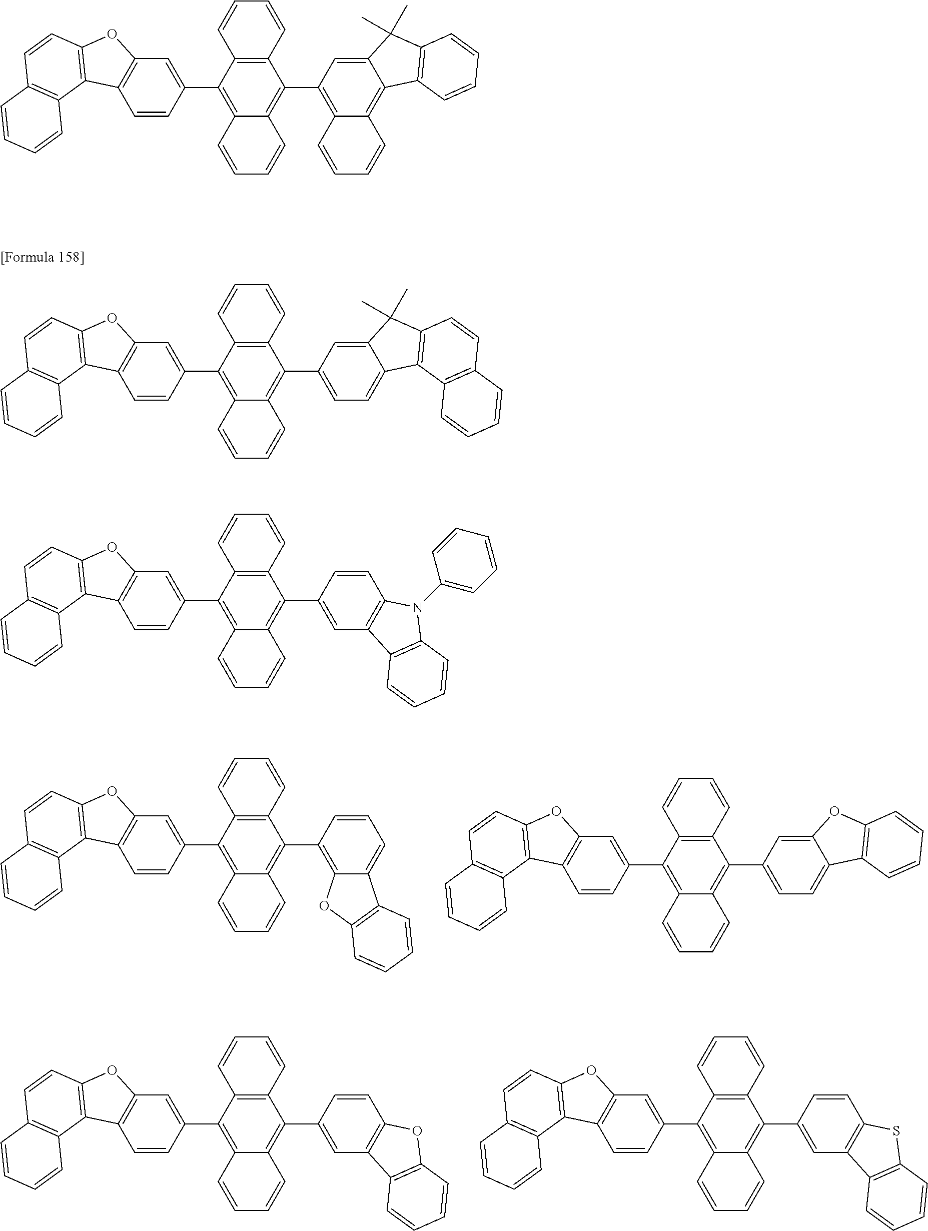

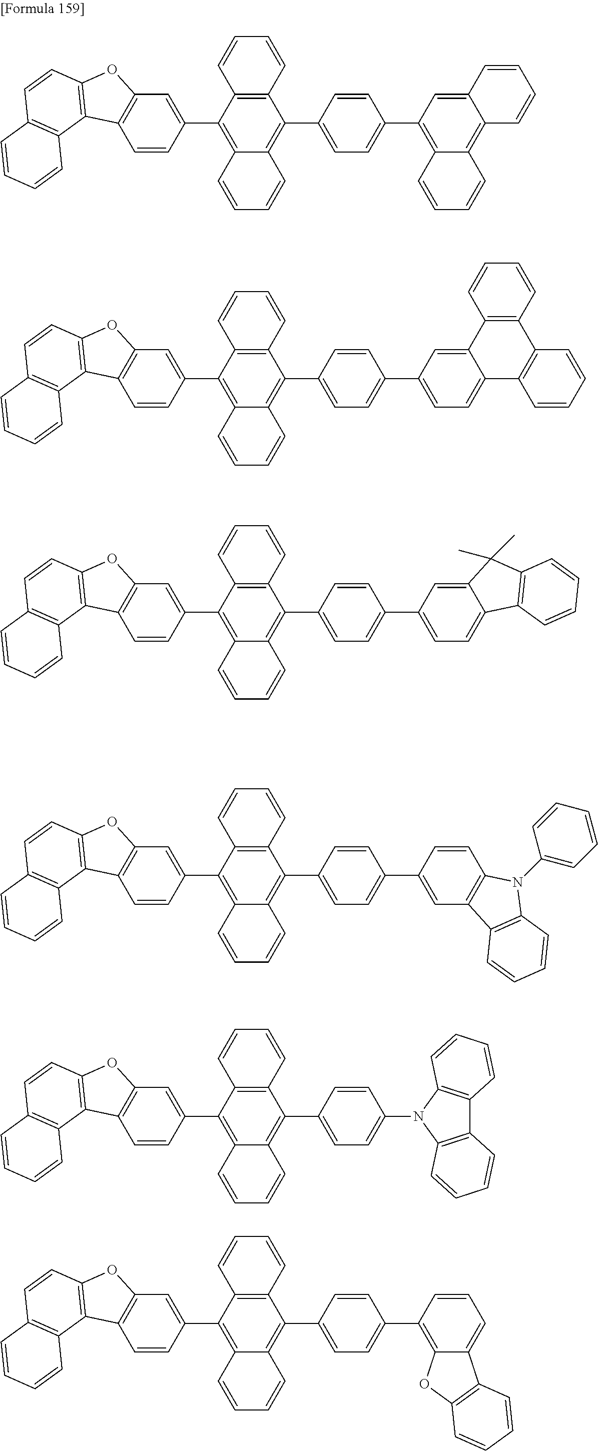

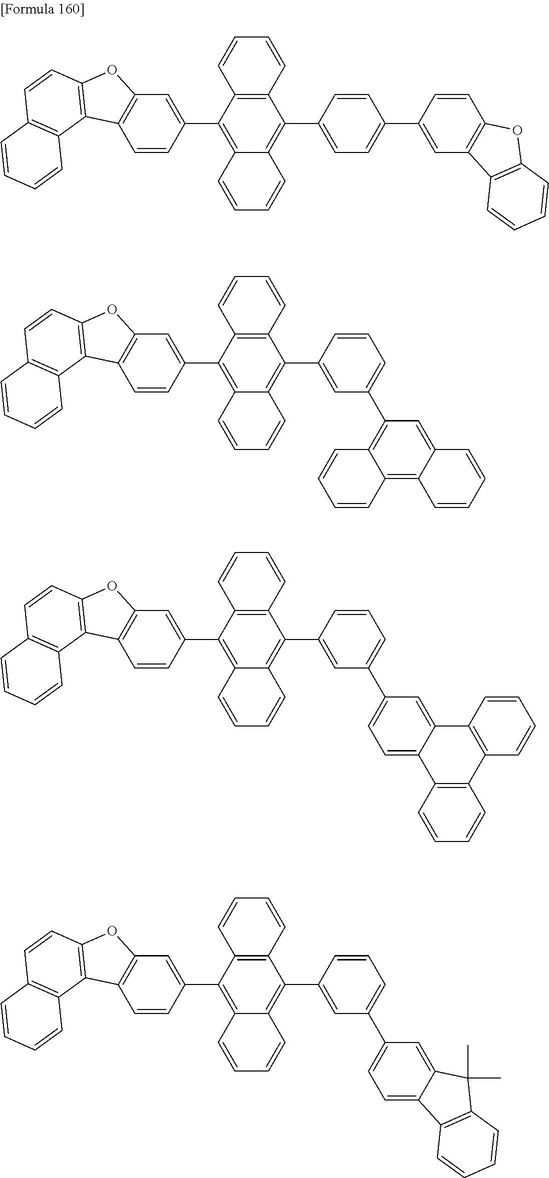 [SMILES: c1ccc2c(c1)ccc1oc3cc(-c4c5ccccc5c(-c5ccc(-c6ccc7oc8ccccc8c7c6)cc5)c5ccccc45)ccc3c12 ; c1cc(-c2c3ccccc3c(-c3ccc4c(c3)oc3ccc5ccccc5c34)c3ccccc23)cc(-c2cc3ccccc3c3ccccc23)c1 ; c1cc(-c2ccc3c4ccccc4c4ccccc4c3c2)cc(-c2c3ccccc3c(-c3ccc4c(c3)oc3ccc5ccccc5c34)c3ccccc23)c1 ; CC1(C)c2ccccc2-c2ccc(-c3cccc(-c4c5ccccc5c(-c5ccc6c(c5)oc5ccc7ccccc7c56)c5ccccc45)c3)cc21]

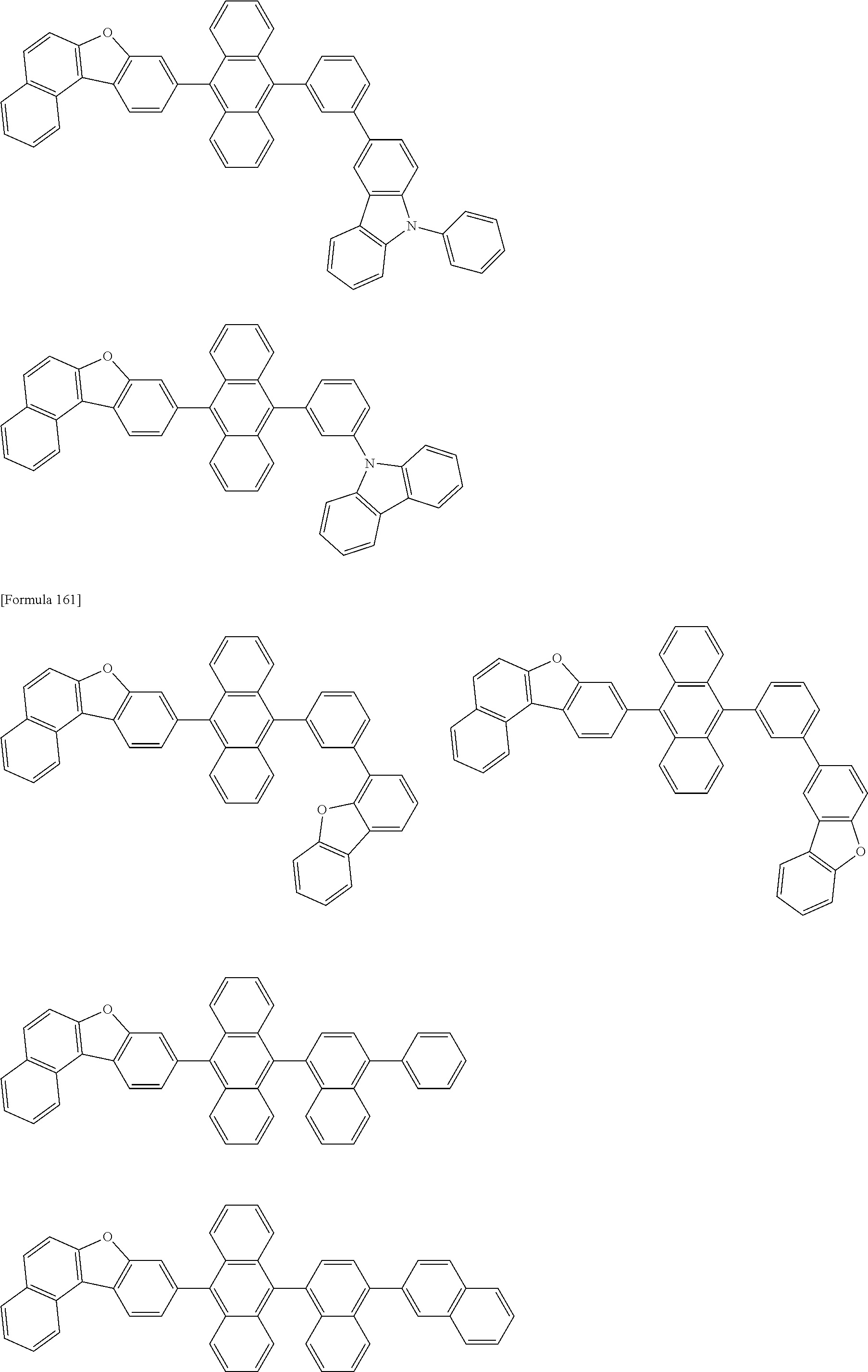

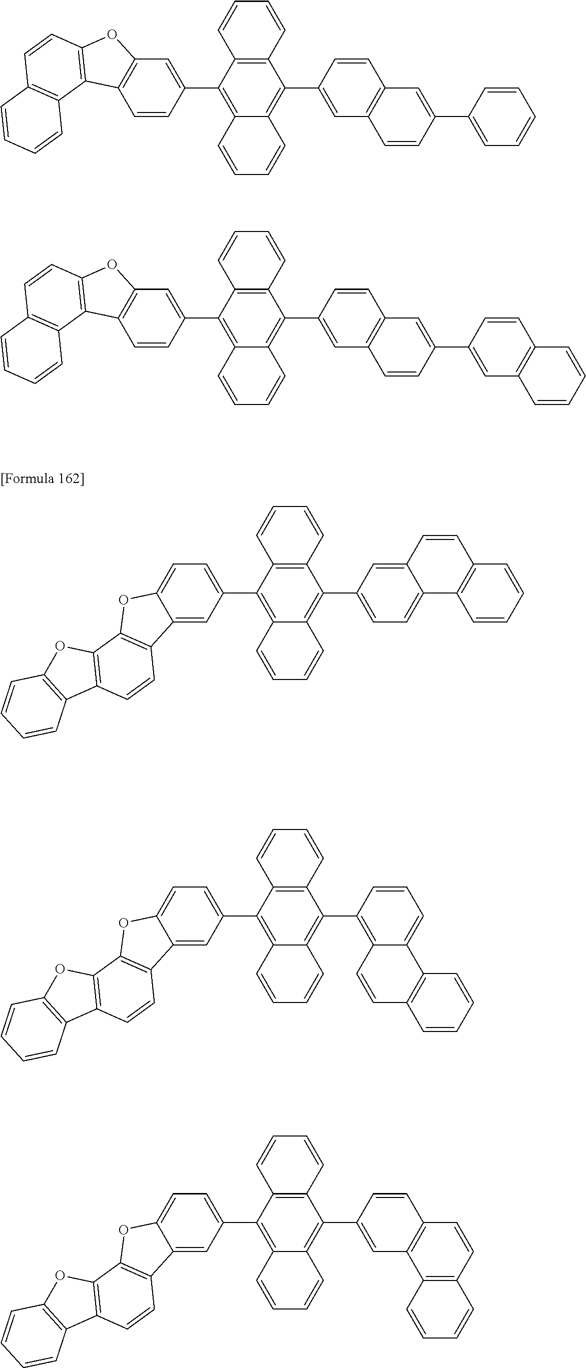 [SMILES: c1ccc(-c2ccc3cc(-c4c5ccccc5c(-c5ccc6c(c5)oc5ccc7ccccc7c56)c5ccccc45)ccc3c2)cc1 ; c1ccc2cc(-c3ccc4cc(-c5c6ccccc6c(-c6ccc7c(c6)oc6ccc8ccccc8c67)c6ccccc56)ccc4c3)ccc2c1 ; c1ccc2c(c1)ccc1cc(-c3c4ccccc4c(-c4ccc5oc6c(ccc7c8ccccc8oc76)c5c4)c4ccccc34)ccc12 ; c1ccc2c(c1)ccc1c(-c3c4ccccc4c(-c4ccc5oc6c(ccc7c8ccccc8oc76)c5c4)c4ccccc34)cccc12 ; c1ccc2c(c1)ccc1ccc(-c3c4ccccc4c(-c4ccc5oc6c(ccc7c8ccccc8oc76)c5c4)c4ccccc34)cc12]

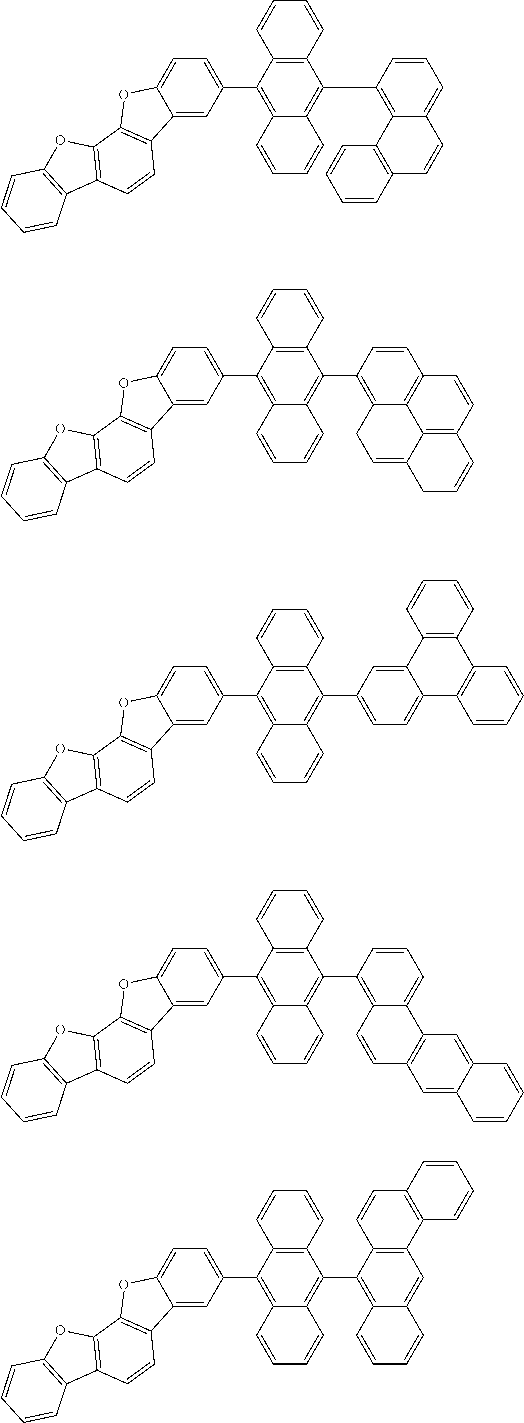

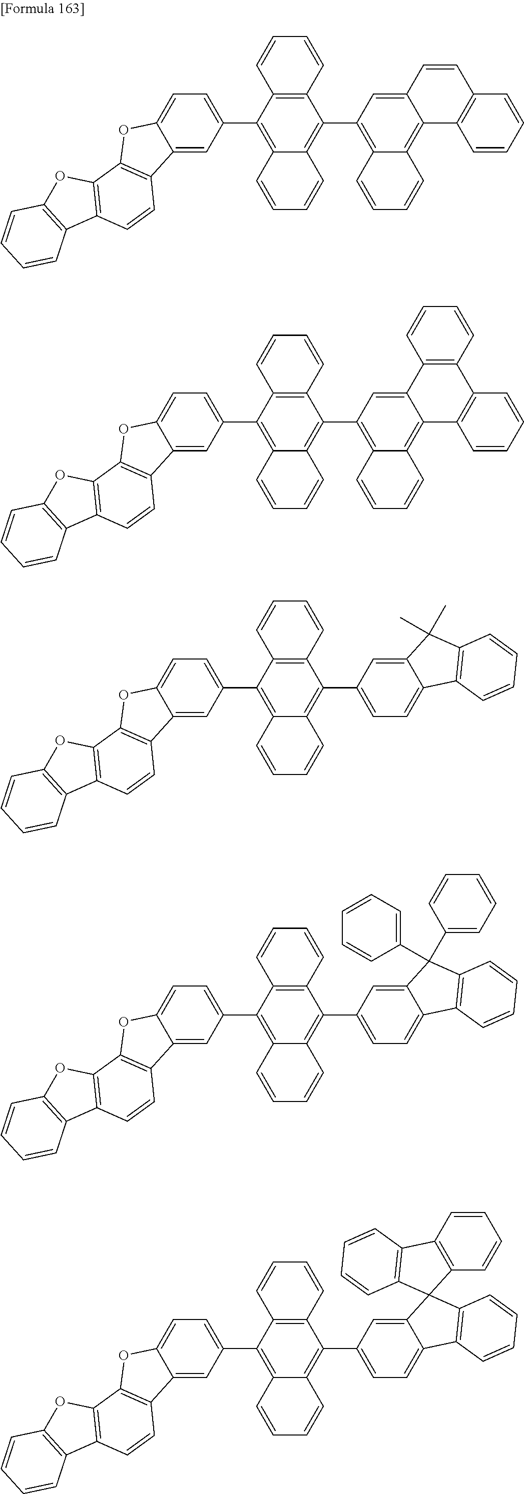 [SMILES: c1ccc2c(c1)ccc1cc(-c3c4ccccc4c(-c4ccc5oc6c(ccc7c8ccccc8oc76)c5c4)c4ccccc34)c3ccccc3c12 ; c1ccc2c(c1)oc1c2ccc2c3cc(-c4c5ccccc5c(-c5cc6c7ccccc7c7ccccc7c6c6ccccc56)c5ccccc45)ccc3oc21 ; CC1(C)c2ccccc2-c2ccc(-c3c4ccccc4c(-c4ccc5oc6c(ccc7c8ccccc8oc76)c5c4)c4ccccc34)cc21 ; c1ccc(C2(c3ccccc3)c3ccccc3-c3ccc(-c4c5ccccc5c(-c5ccc6oc7c(ccc8c9ccccc9oc87)c6c5)c5ccccc45)cc32)cc1 ; c1ccc2c(c1)-c1ccccc1C21c2ccccc2-c2ccc(-c3c4ccccc4c(-c4ccc5oc6c(ccc7c8ccccc8oc76)c5c4)c4ccccc34)cc21]

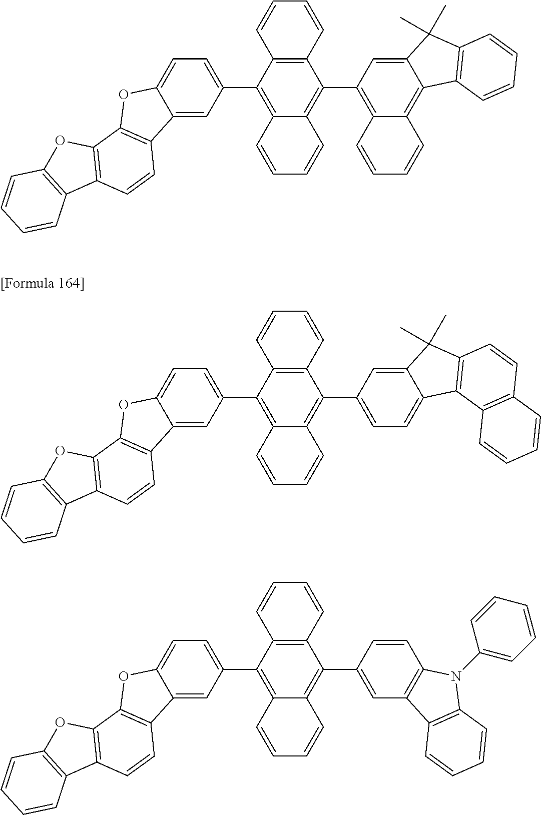 [SMILES: CC1(C)c2ccccc2-c2c1cc(-c1c3ccccc3c(-c3ccc4oc5c(ccc6c7ccccc7oc65)c4c3)c3ccccc13)c1ccccc21 ; CC1(C)c2cc(-c3c4ccccc4c(-c4ccc5oc6c(ccc7c8ccccc8oc76)c5c4)c4ccccc34)ccc2-c2c1ccc1ccccc21 ; c1ccc(-n2c3ccccc3c3cc(-c4c5ccccc5c(-c5ccc6oc7c(ccc8c9ccccc9oc87)c6c5)c5ccccc45)ccc32)cc1]

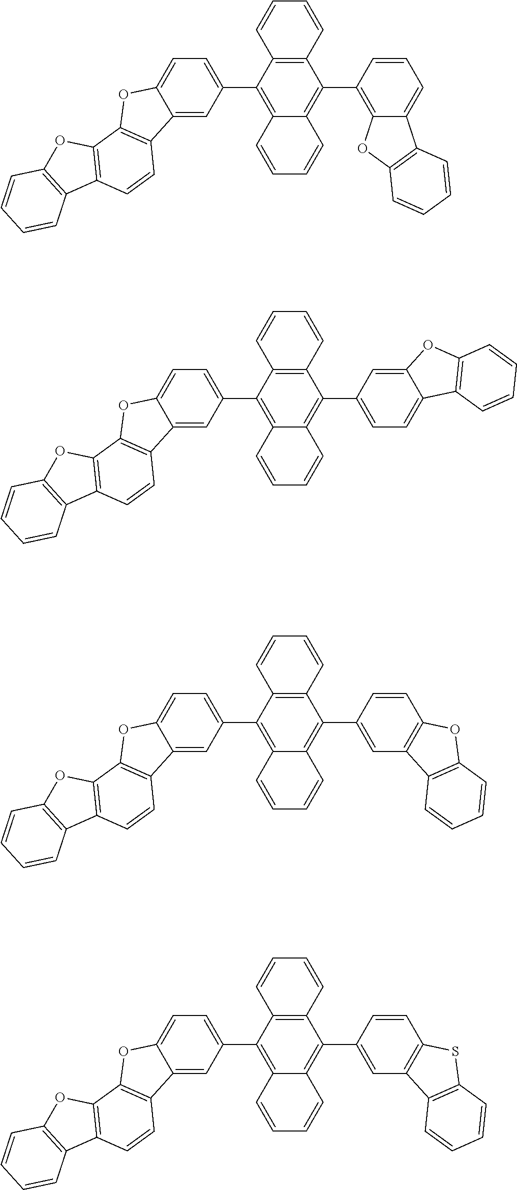 [SMILES: c1ccc2c(c1)oc1c(-c3c4ccccc4c(-c4ccc5oc6c(ccc7c8ccccc8oc76)c5c4)c4ccccc34)cccc12 ; c1ccc2c(c1)oc1cc(-c3c4ccccc4c(-c4ccc5oc6c(ccc7c8ccccc8oc76)c5c4)c4ccccc34)ccc12 ; c1ccc2c(c1)oc1ccc(-c3c4ccccc4c(-c4ccc5oc6c(ccc7c8ccccc8oc76)c5c4)c4ccccc34)cc12 ; c1ccc2c(c1)oc1c2ccc2c3cc(-c4c5ccccc5c(-c5ccc6sc7ccccc7c6c5)c5ccccc45)ccc3oc21]

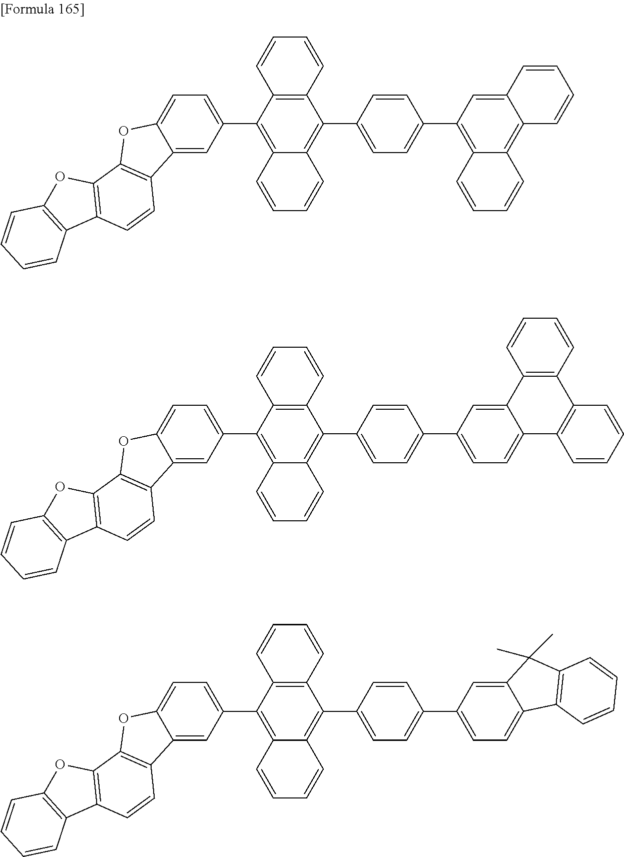 [SMILES: c1ccc2c(c1)cc(-c1ccc(-c3c4ccccc4c(-c4ccc5oc6c(ccc7c8ccccc8oc76)c5c4)c4ccccc34)cc1)c1ccccc12 ; c1ccc2c(c1)oc1c2ccc2c3cc(-c4c5ccccc5c(-c5ccc(-c6ccc7c8ccccc8c8ccccc8c7c6)cc5)c5ccccc45)ccc3oc21 ; CC1(C)c2ccccc2-c2ccc(-c3ccc(-c4c5ccccc5c(-c5ccc6oc7c(ccc8c9ccccc9oc87)c6c5)c5ccccc45)cc3)cc21]

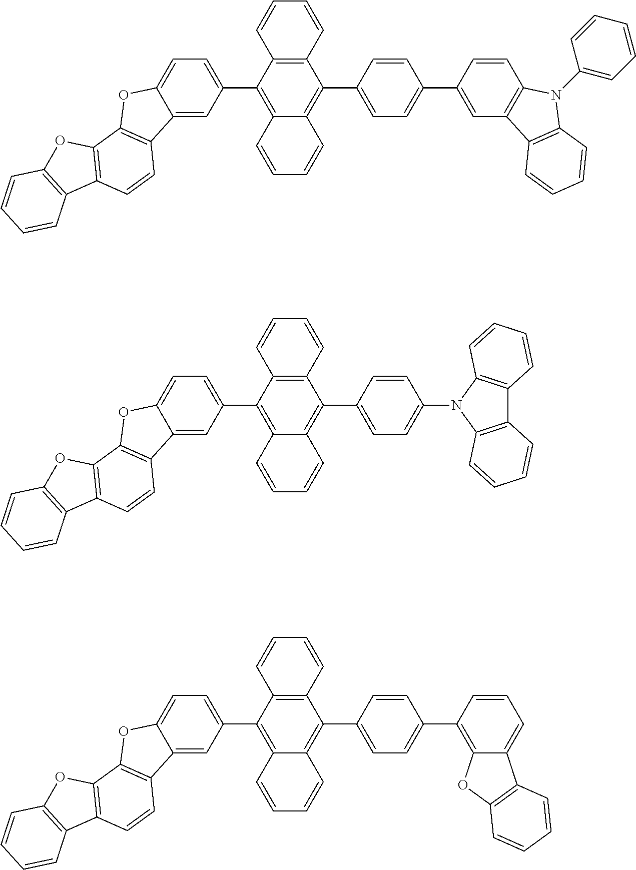 [SMILES: c1ccc(-n2c3ccccc3c3cc(-c4ccc(-c5c6ccccc6c(-c6ccc7oc8c(ccc9c%10ccccc%10oc98)c7c6)c6ccccc56)cc4)ccc32)cc1 ; c1ccc2c(c1)oc1c2ccc2c3cc(-c4c5ccccc5c(-c5ccc(-n6c7ccccc7c7ccccc76)cc5)c5ccccc45)ccc3oc21 ; c1ccc2c(c1)oc1c(-c3ccc(-c4c5ccccc5c(-c5ccc6oc7c(ccc8c9ccccc9oc87)c6c5)c5ccccc45)cc3)cccc12]

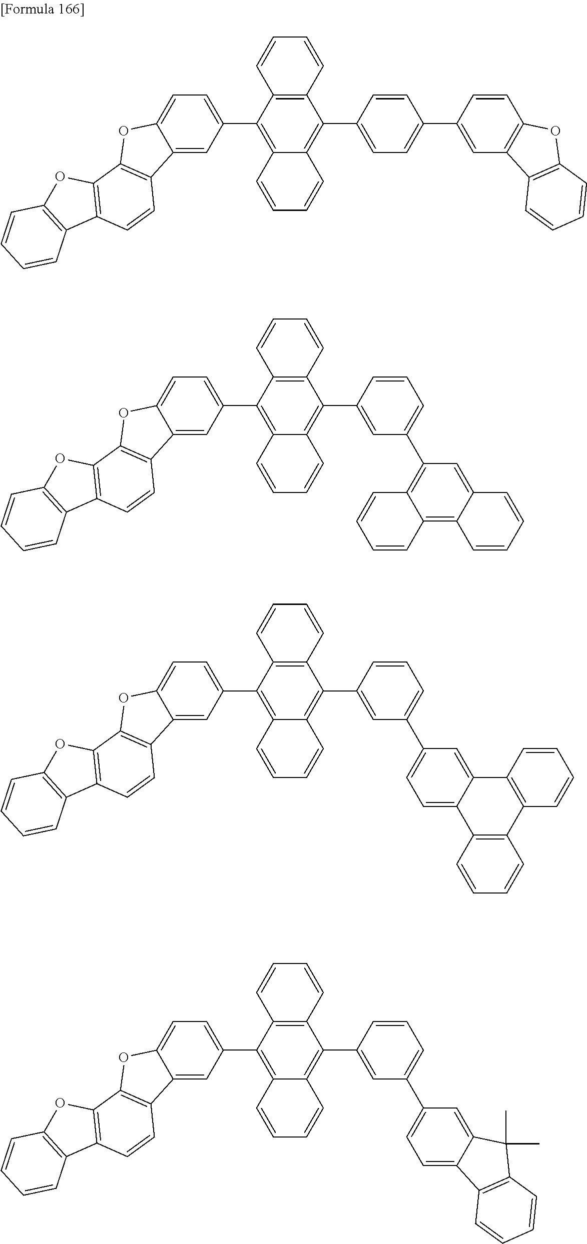 [SMILES: c1ccc2c(c1)oc1ccc(-c3ccc(-c4c5ccccc5c(-c5ccc6oc7c(ccc8c9ccccc9oc87)c6c5)c5ccccc45)cc3)cc12 ; c1cc(-c2c3ccccc3c(-c3ccc4oc5c(ccc6c7ccccc7oc65)c4c3)c3ccccc23)cc(-c2cc3ccccc3c3ccccc23)c1 ; c1cc(-c2ccc3c4ccccc4c4ccccc4c3c2)cc(-c2c3ccccc3c(-c3ccc4oc5c(ccc6c7ccccc7oc65)c4c3)c3ccccc23)c1 ; CC1(C)c2ccccc2-c2ccc(-c3cccc(-c4c5ccccc5c(-c5ccc6oc7c(ccc8c9ccccc9oc87)c6c5)c5ccccc45)c3)cc21]

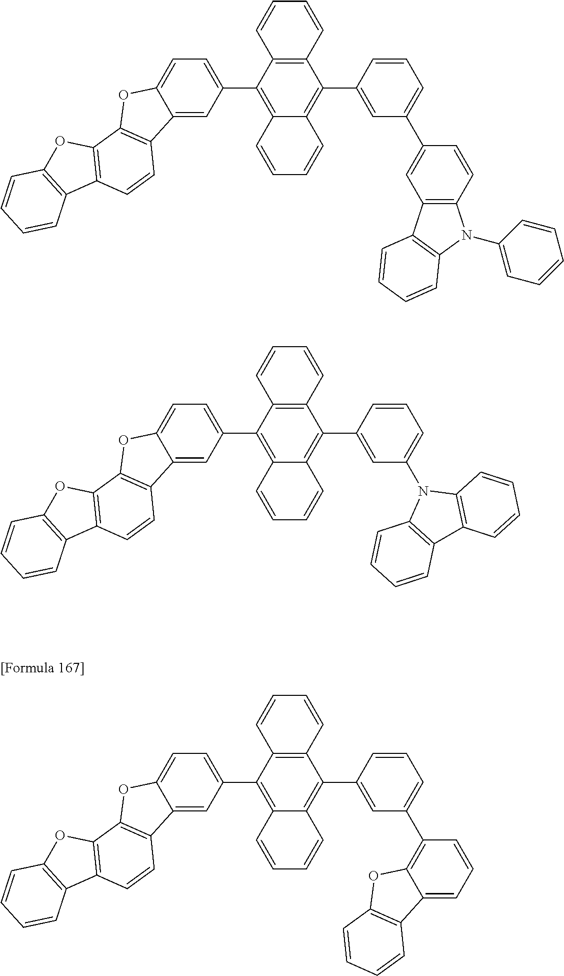 [SMILES: c1ccc(-n2c3ccccc3c3cc(-c4cccc(-c5c6ccccc6c(-c6ccc7oc8c(ccc9c%10ccccc%10oc98)c7c6)c6ccccc56)c4)ccc32)cc1 ; c1cc(-c2c3ccccc3c(-c3ccc4oc5c(ccc6c7ccccc7oc65)c4c3)c3ccccc23)cc(-n2c3ccccc3c3ccccc32)c1 ; c1cc(-c2c3ccccc3c(-c3ccc4oc5c(ccc6c7ccccc7oc65)c4c3)c3ccccc23)cc(-c2cccc3c2oc2ccccc23)c1]

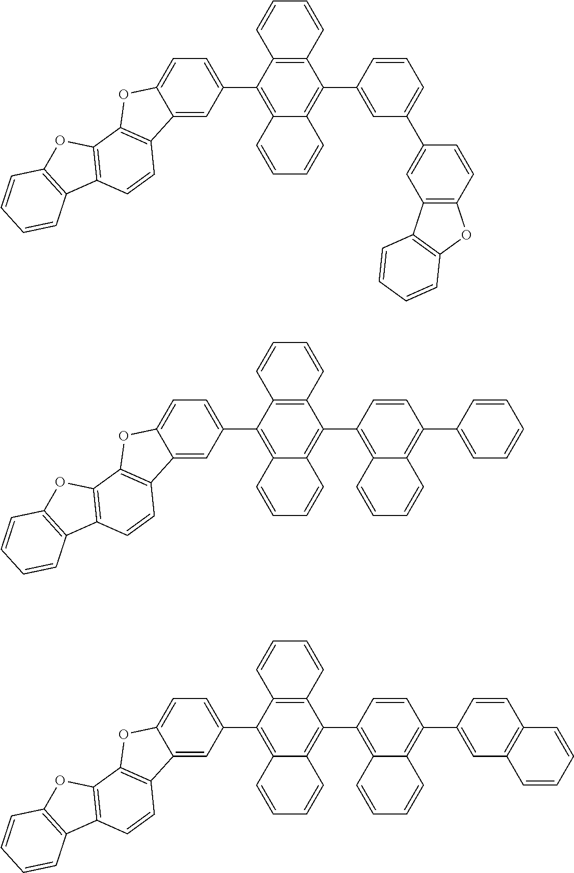 [SMILES: c1cc(-c2ccc3oc4ccccc4c3c2)cc(-c2c3ccccc3c(-c3ccc4oc5c(ccc6c7ccccc7oc65)c4c3)c3ccccc23)c1 ; c1ccc(-c2ccc(-c3c4ccccc4c(-c4ccc5oc6c(ccc7c8ccccc8oc76)c5c4)c4ccccc34)c3ccccc23)cc1 ; c1ccc2cc(-c3ccc(-c4c5ccccc5c(-c5ccc6oc7c(ccc8c9ccccc9oc87)c6c5)c5ccccc45)c4ccccc34)ccc2c1]

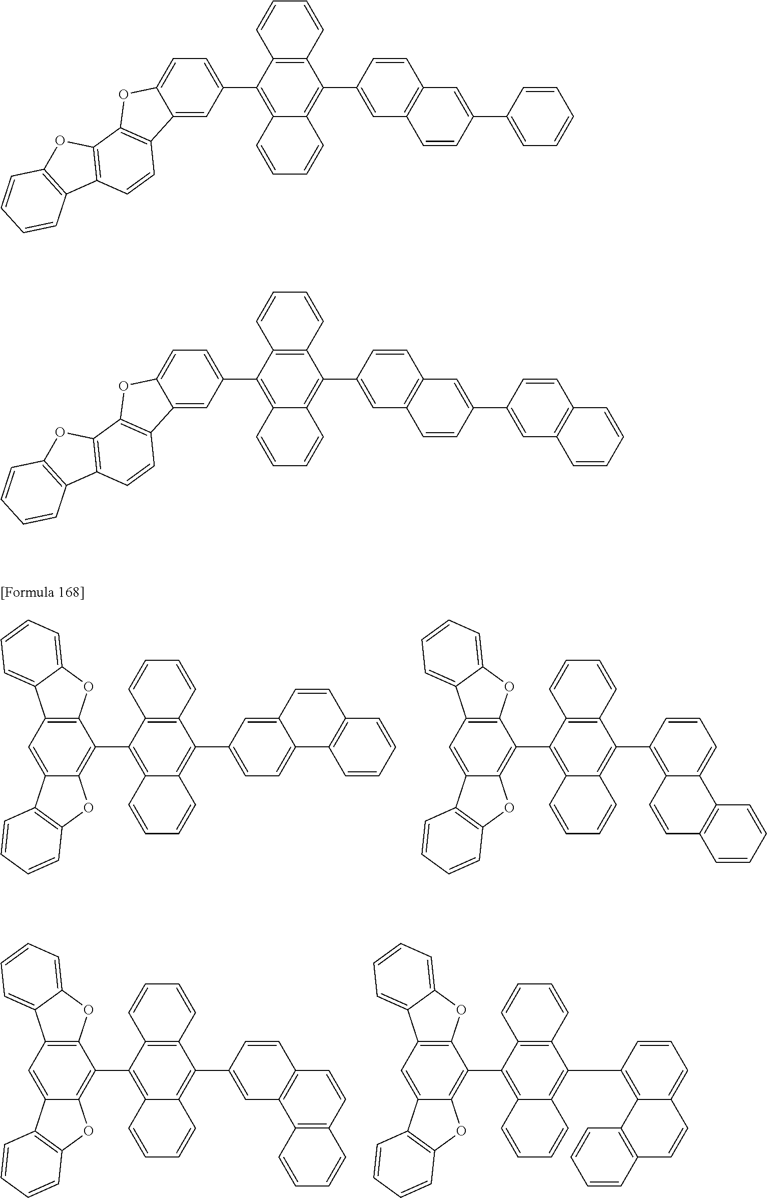

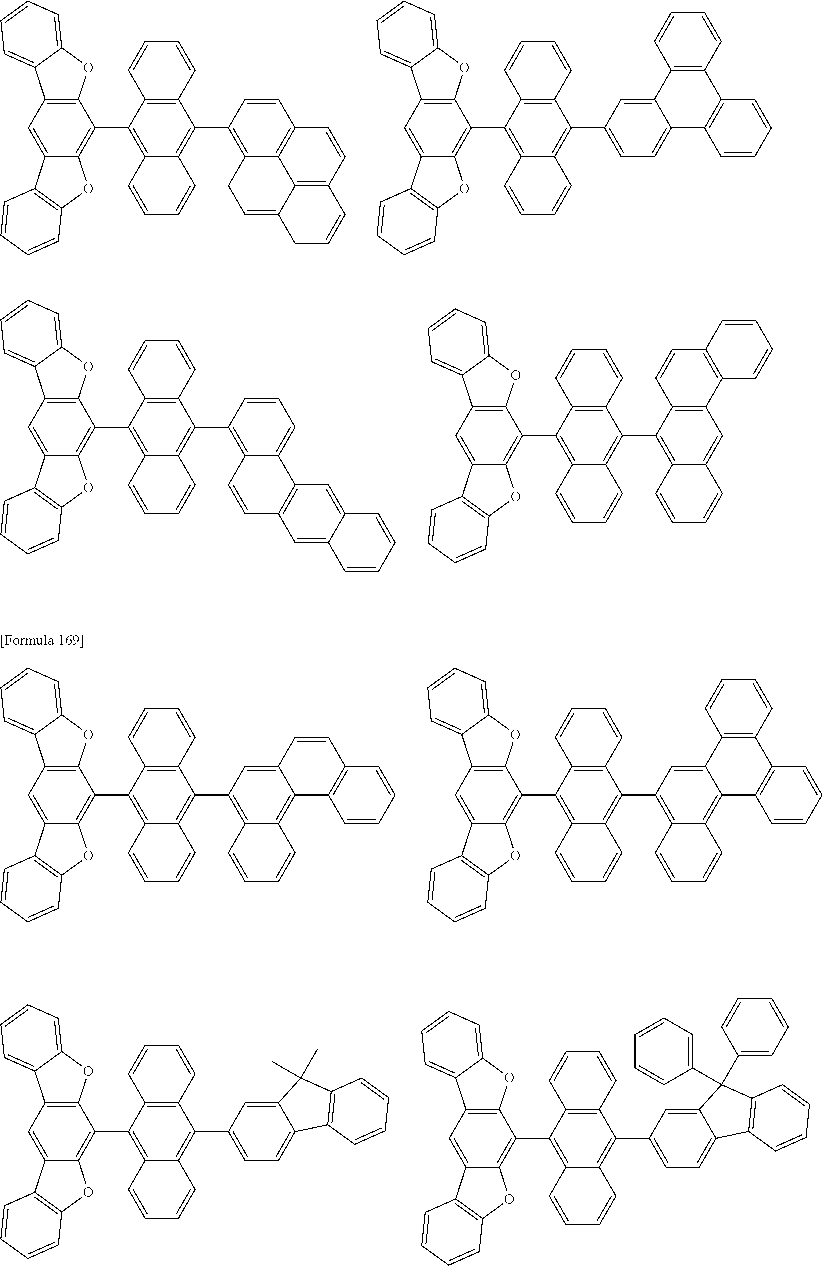

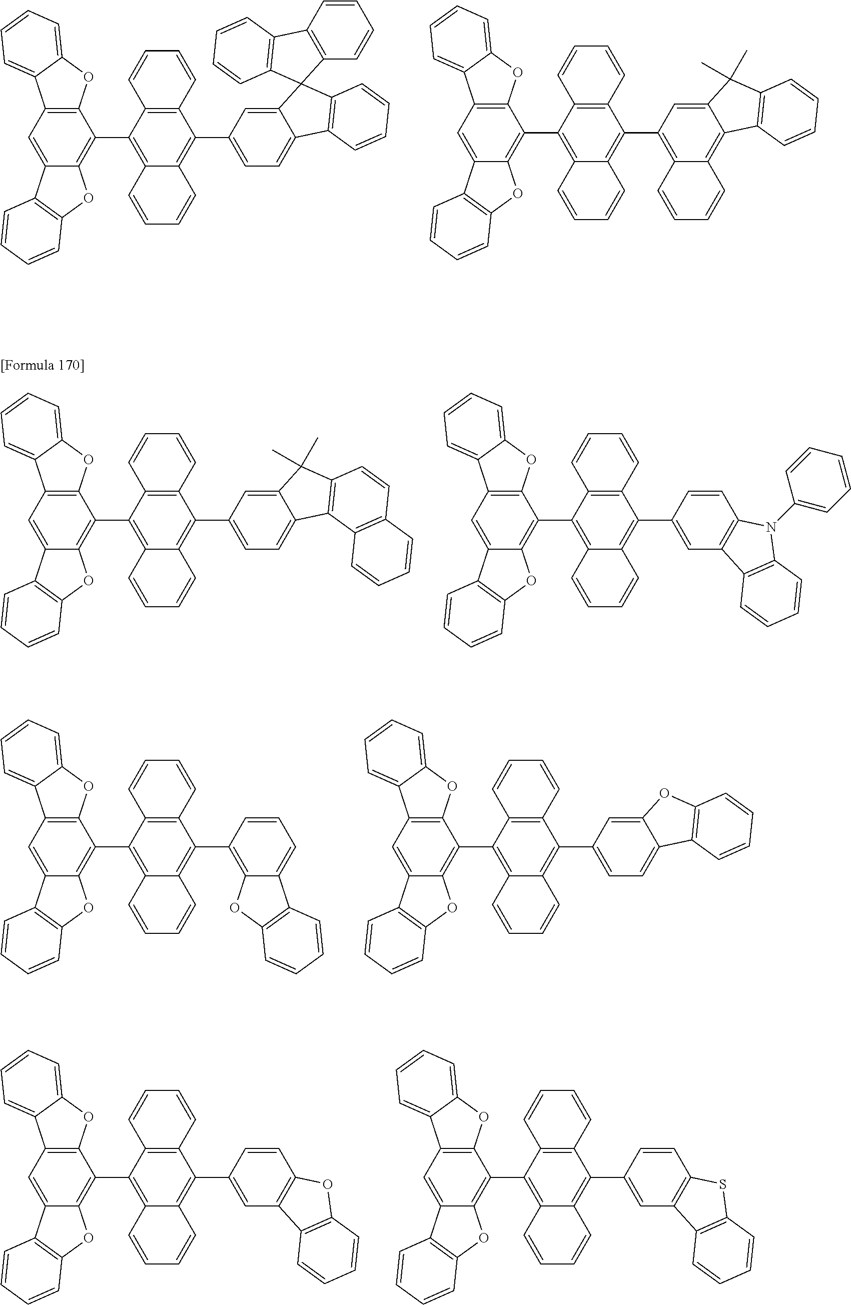

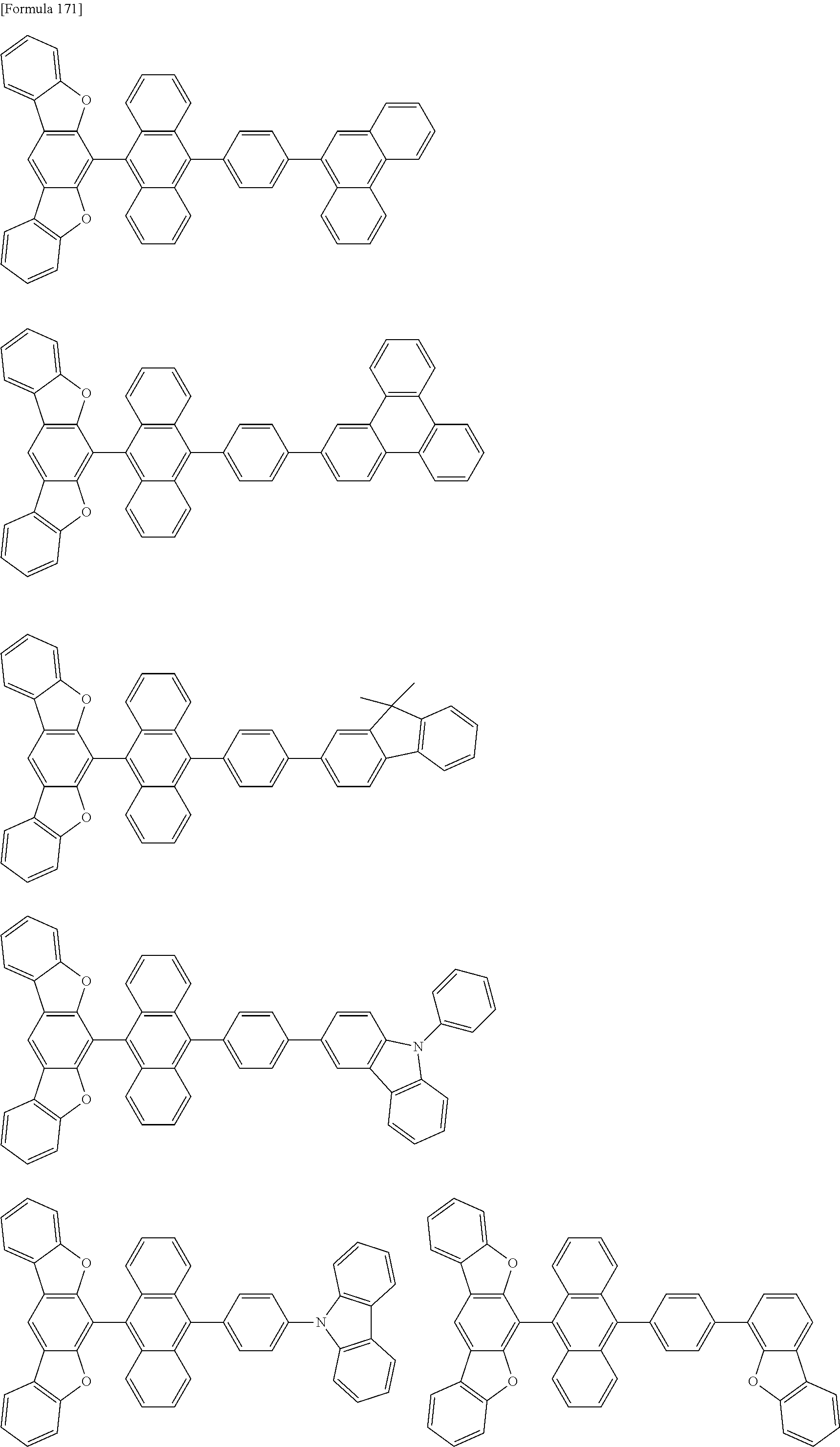

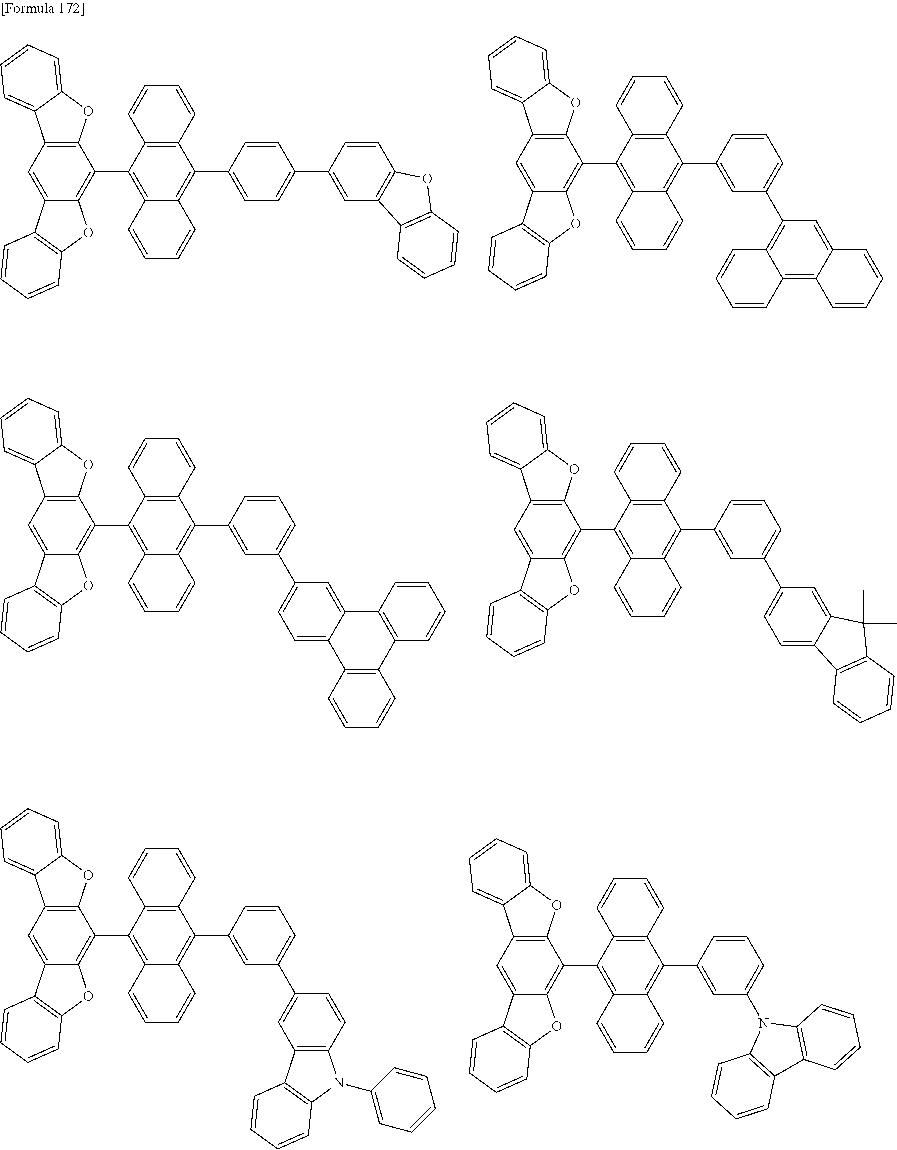

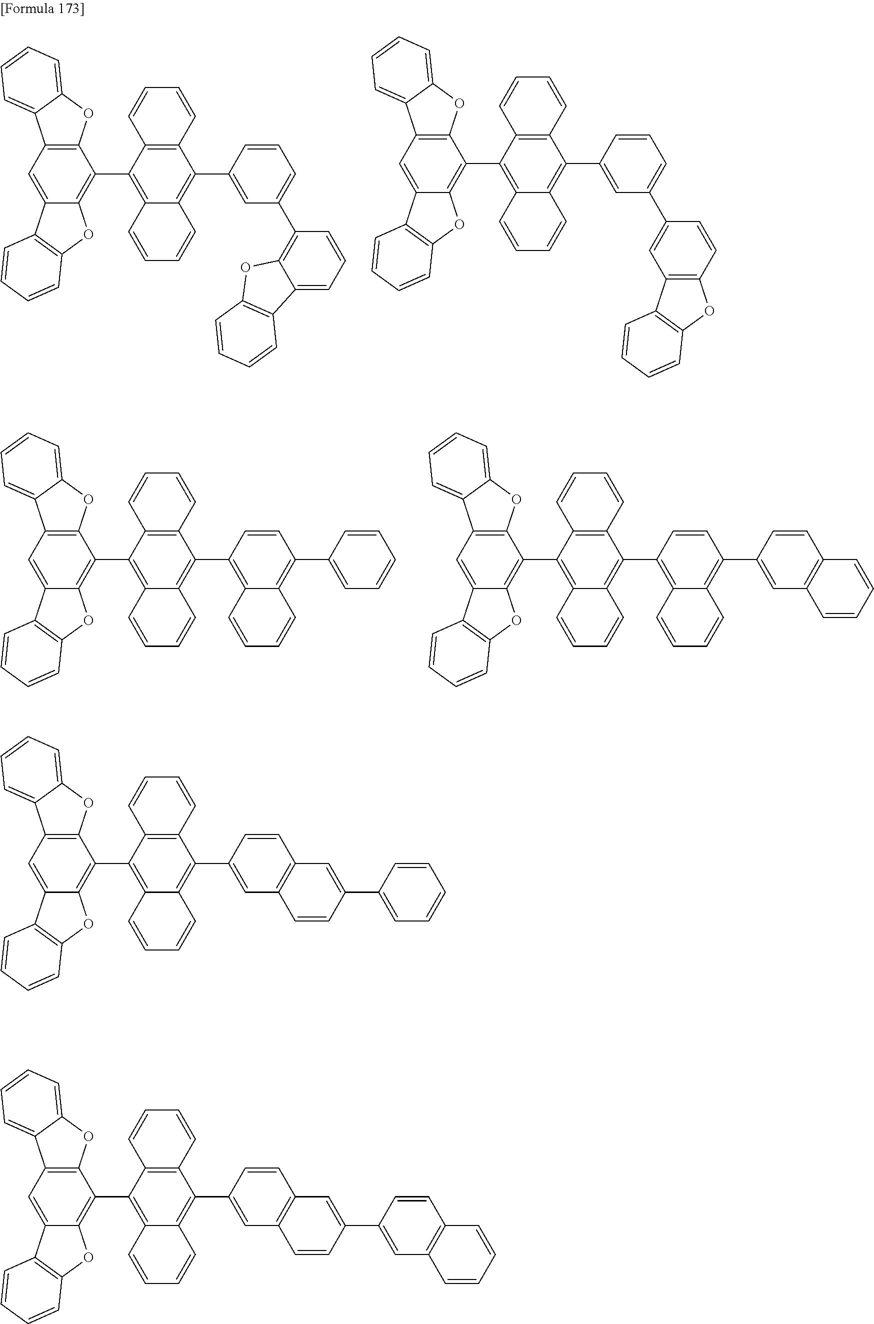

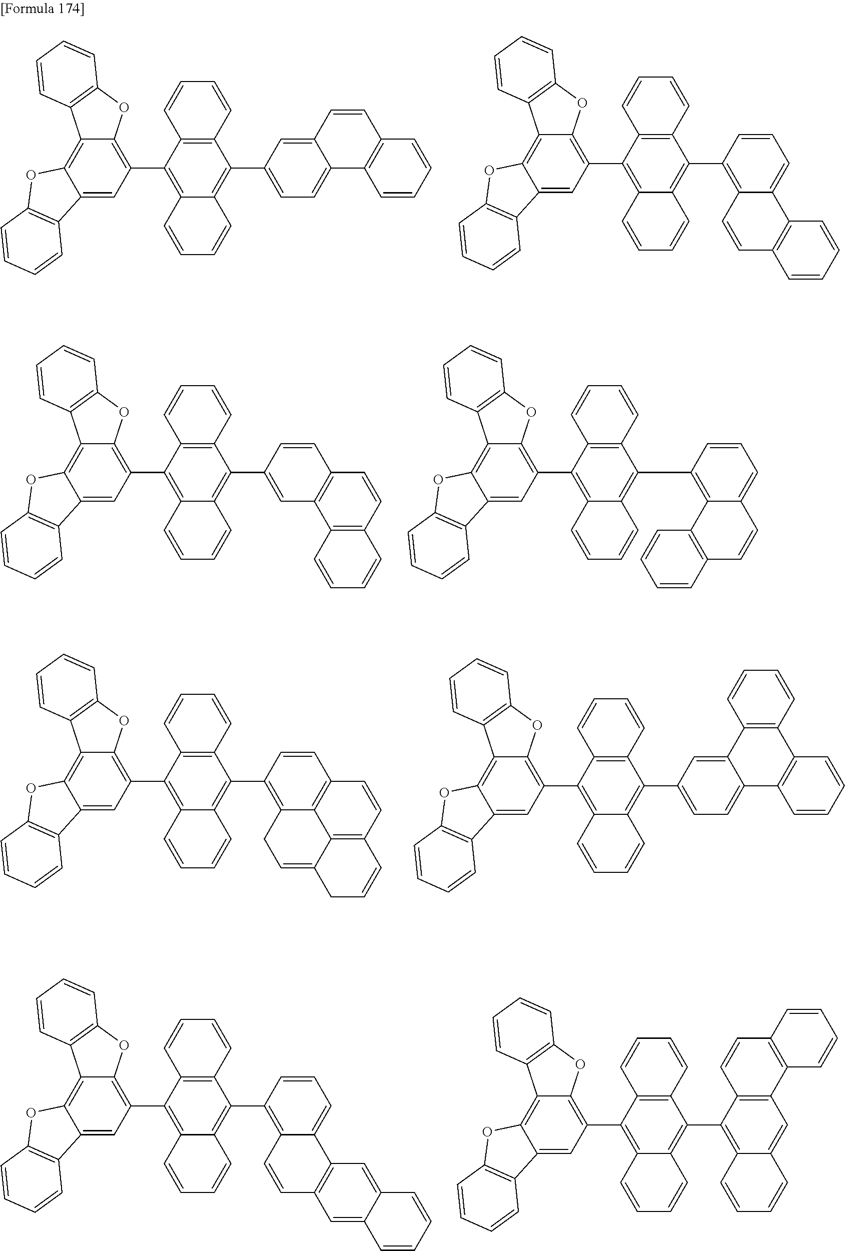

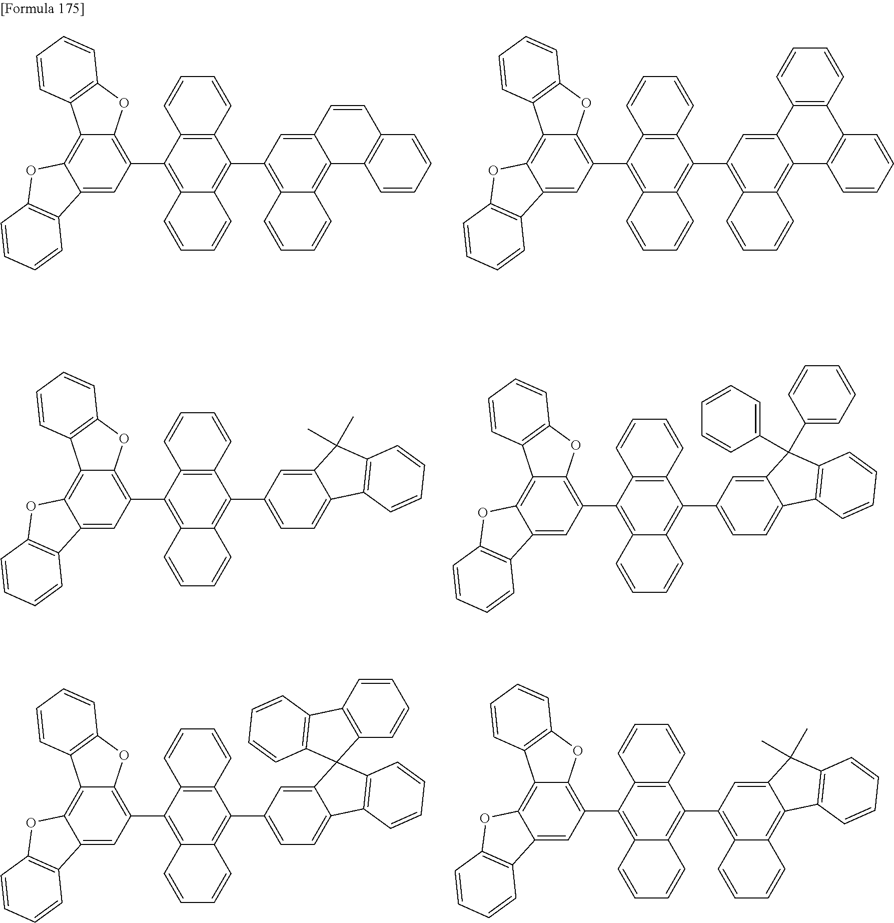

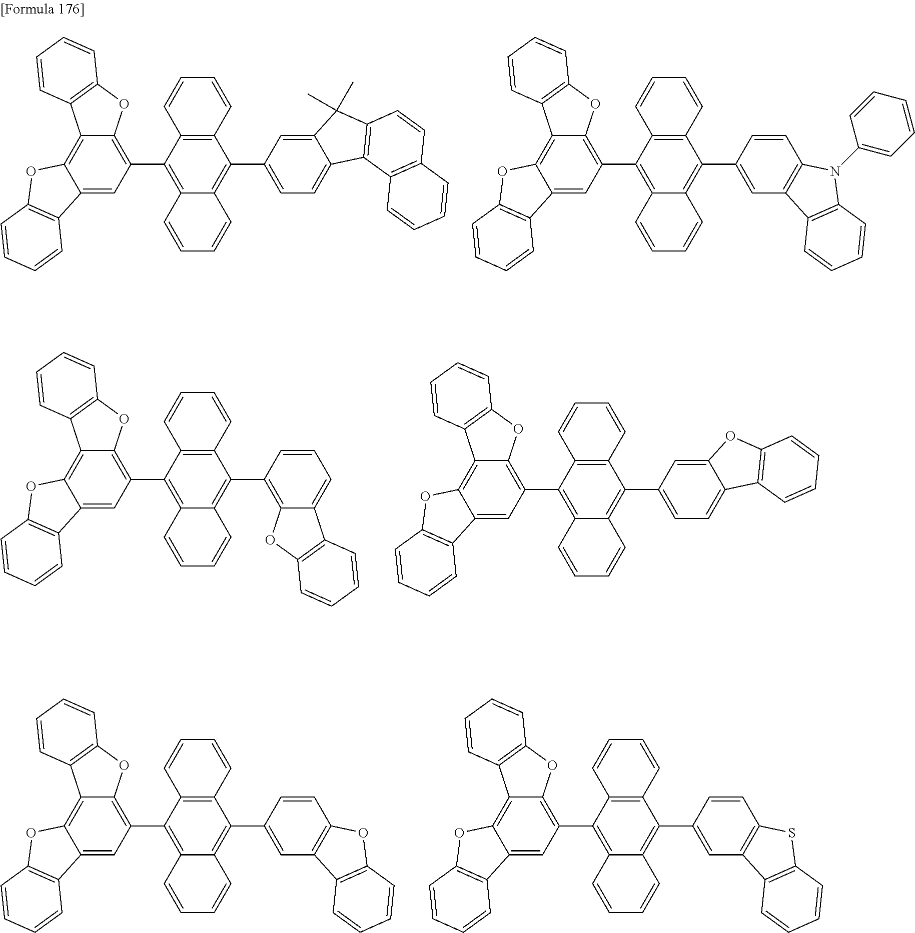

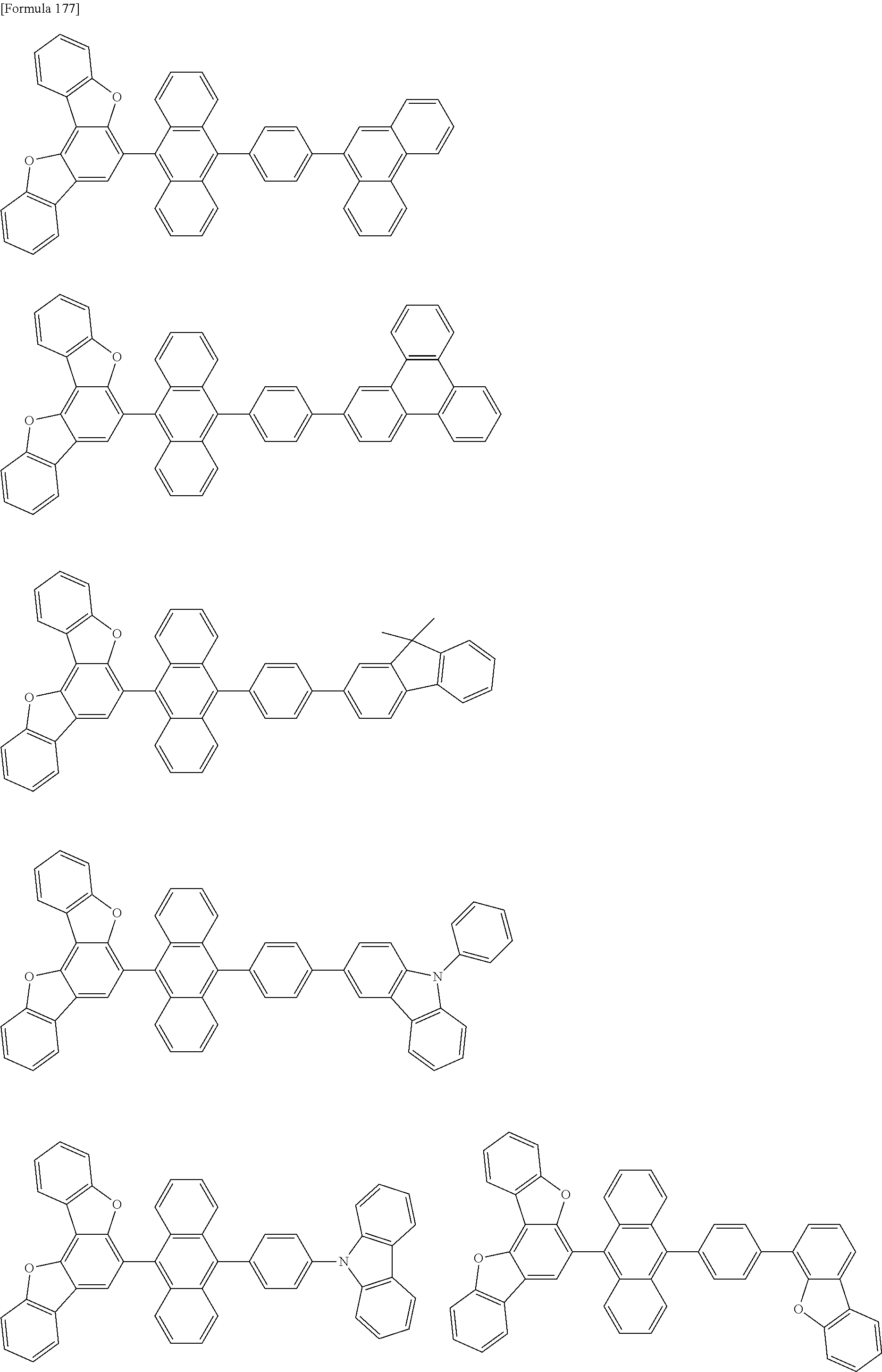

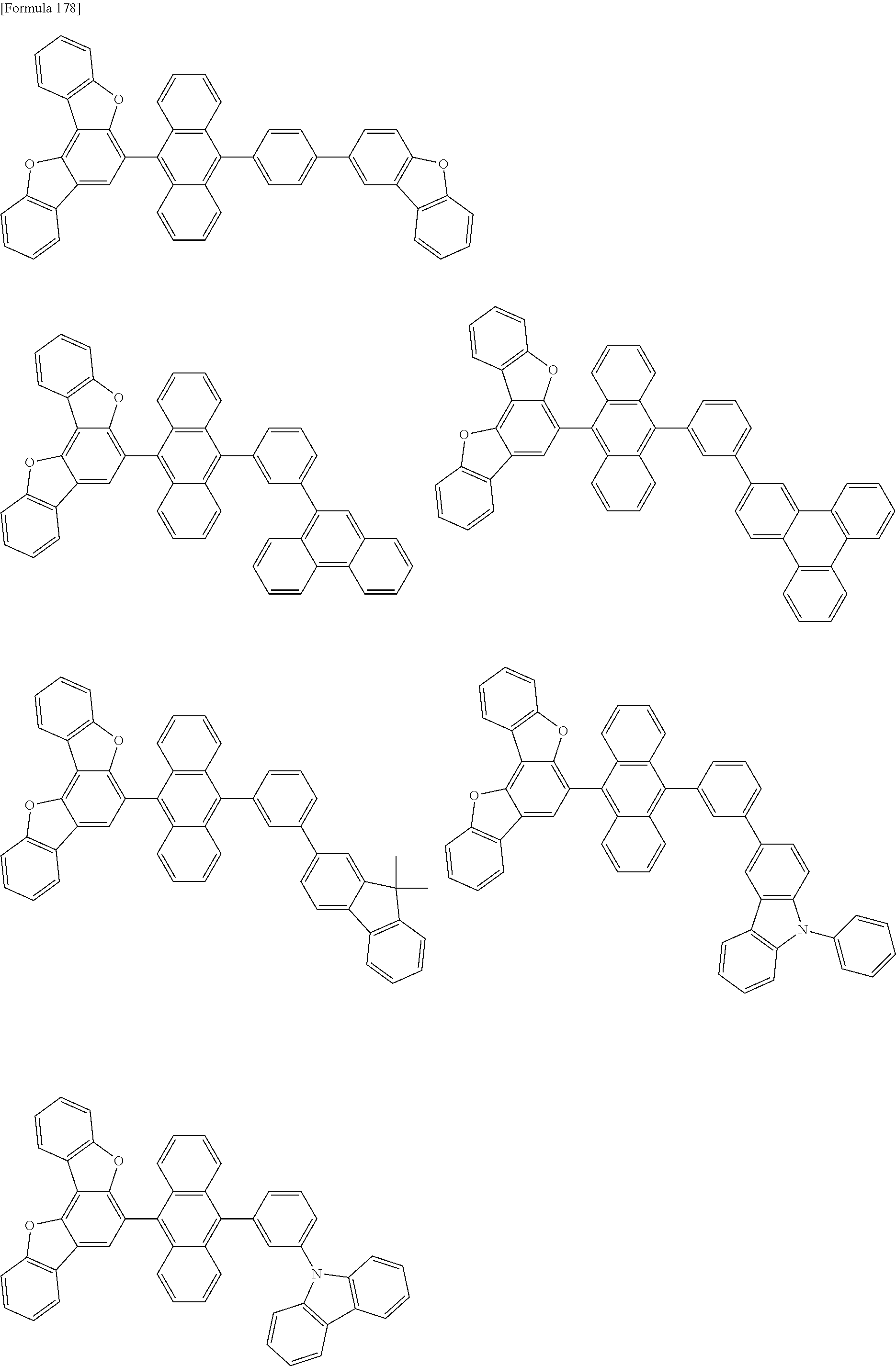

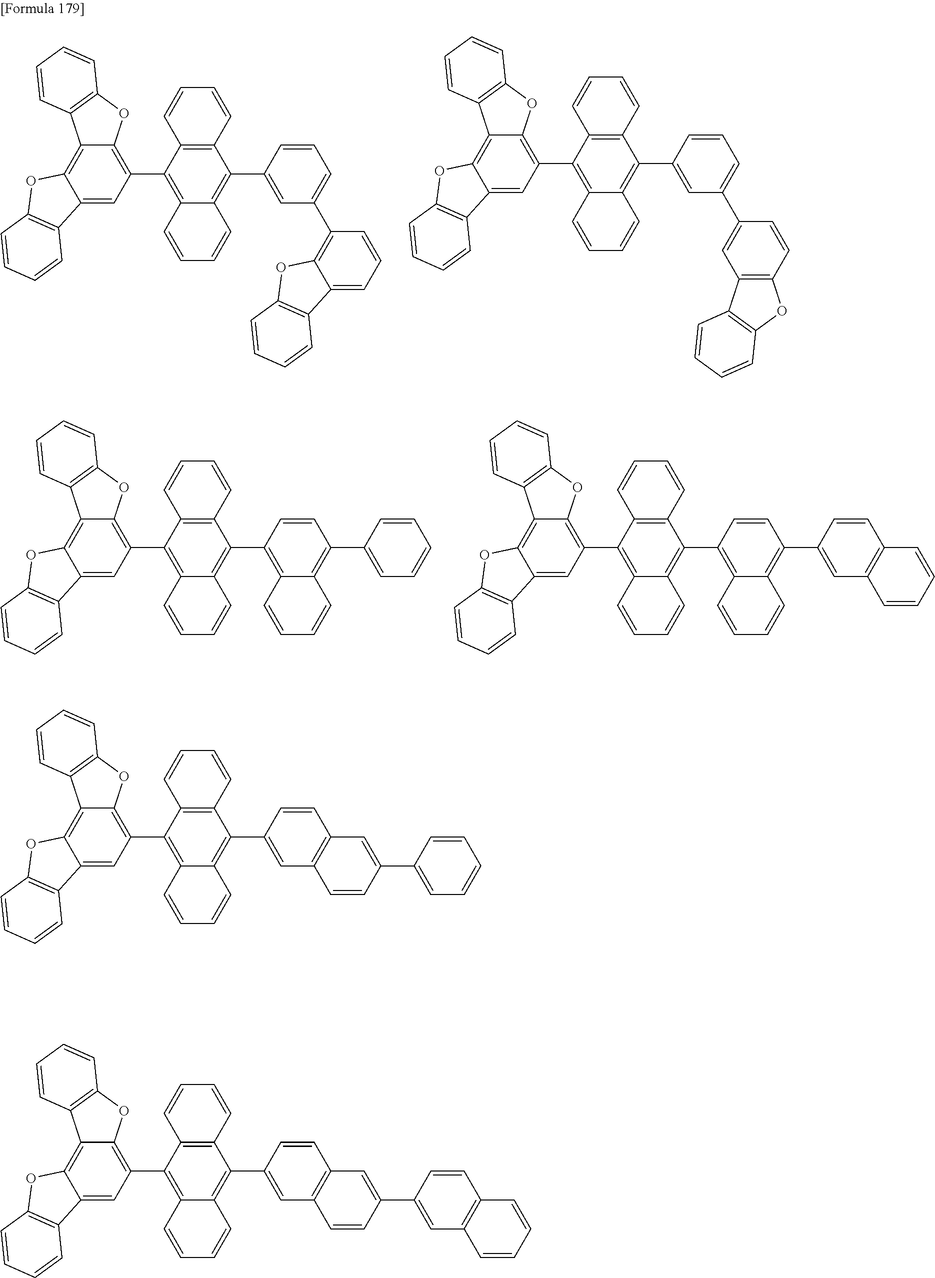

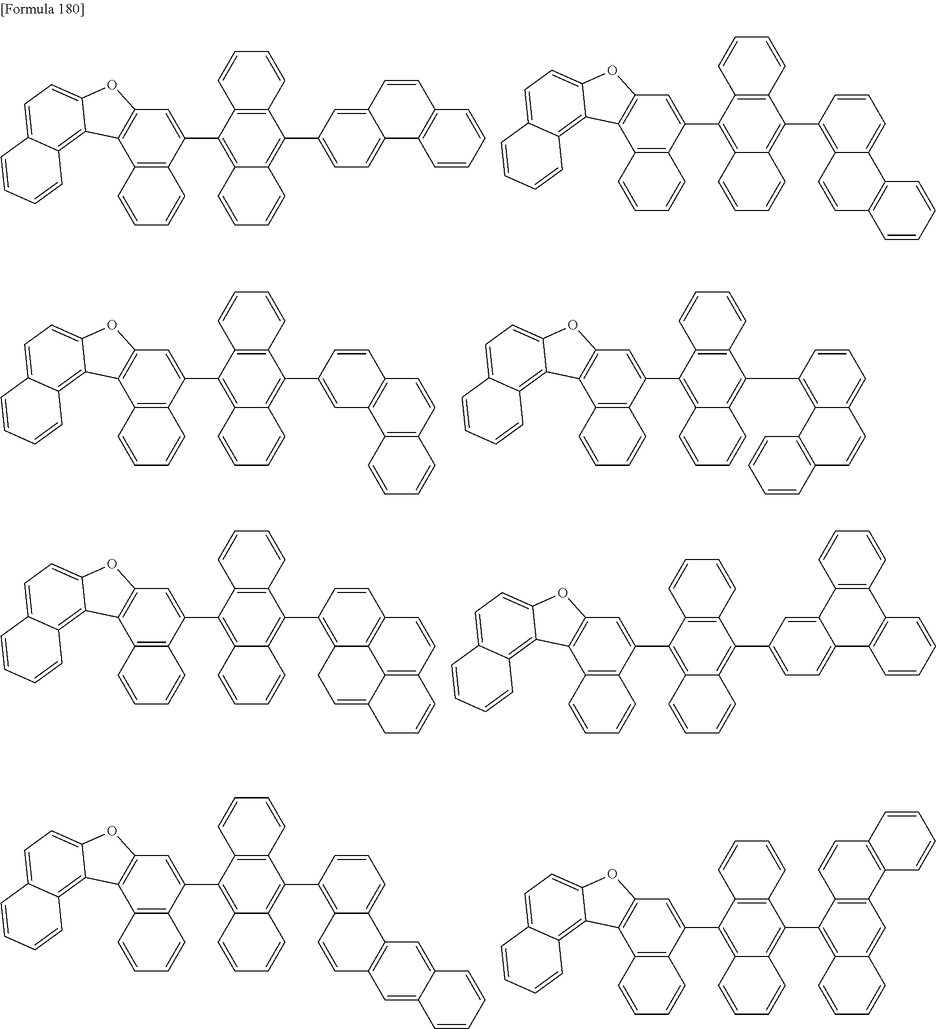

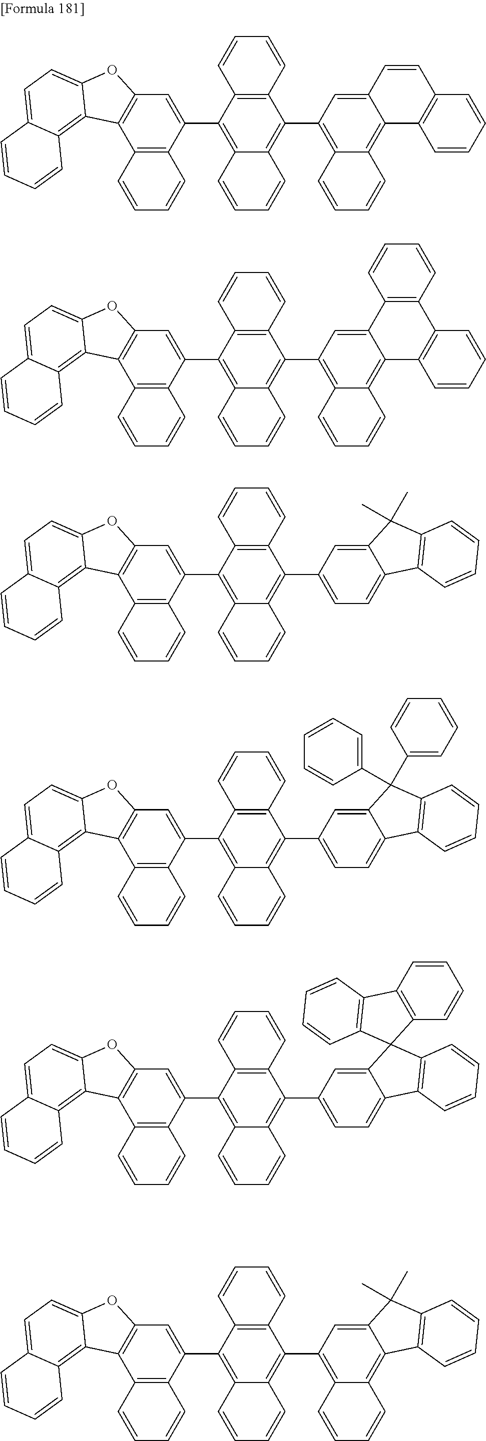

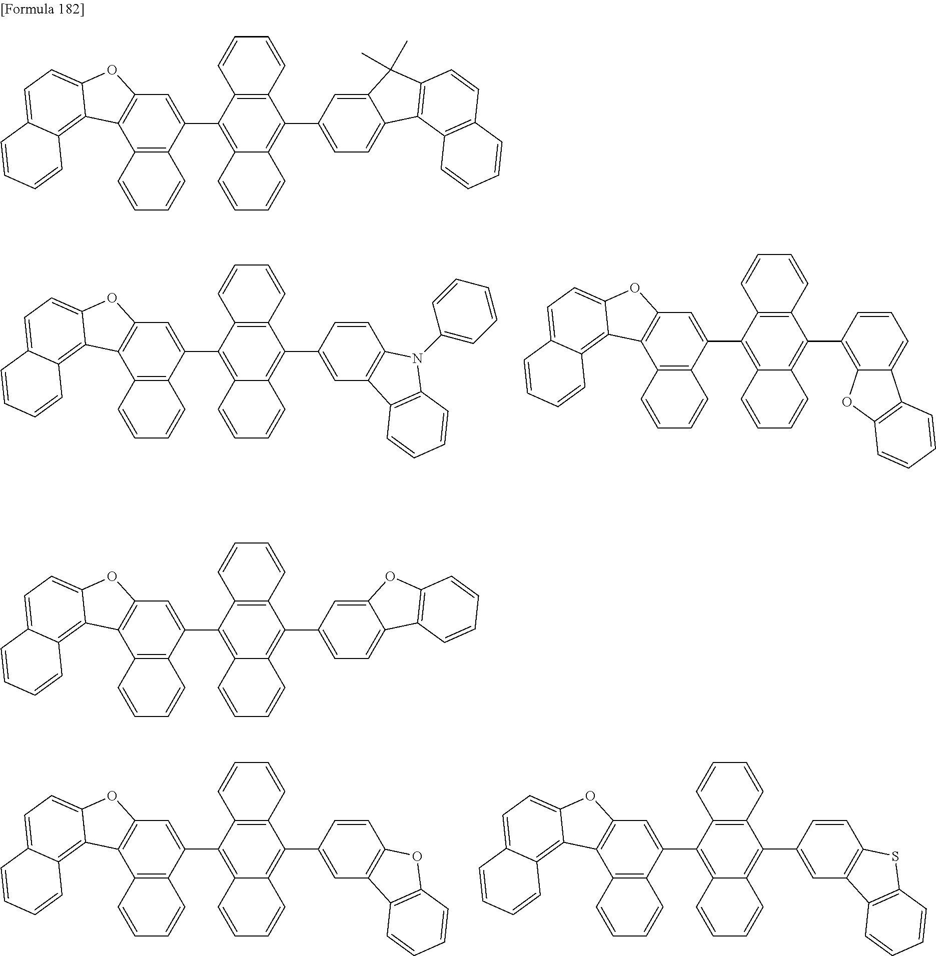

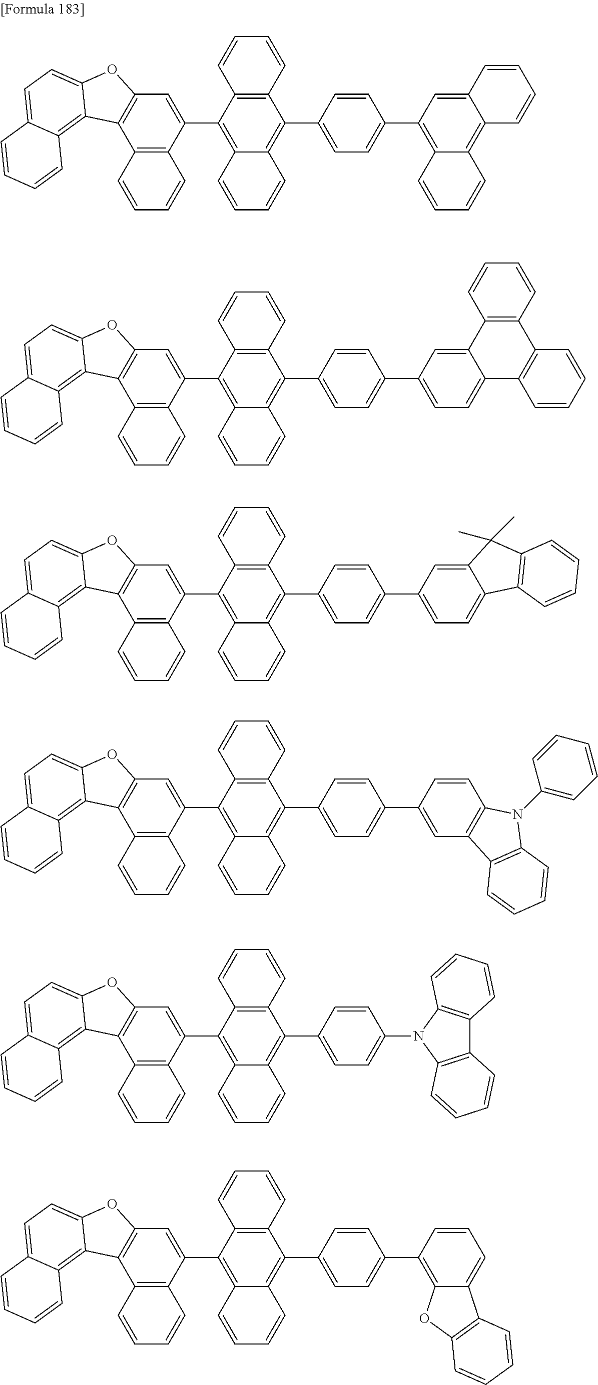

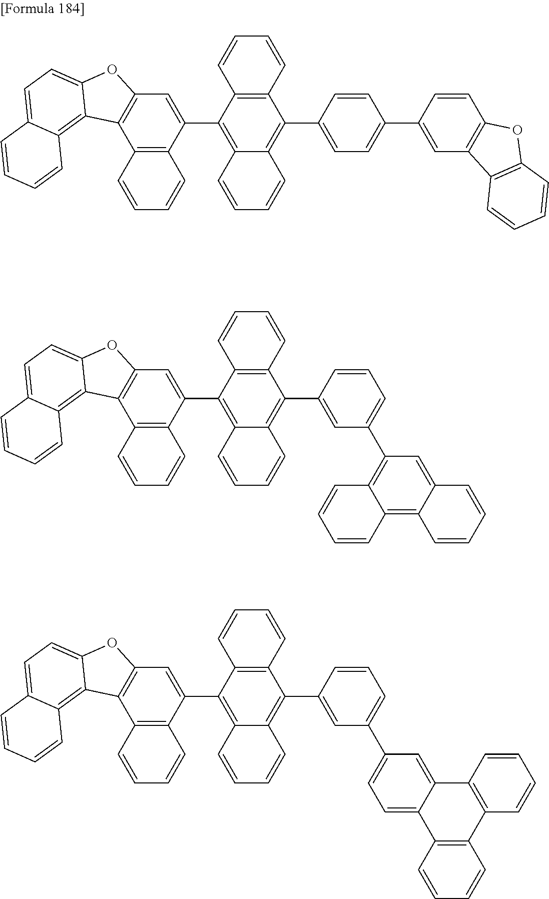 [SMILES: c1ccc2c(c1)ccc1oc3cc(-c4c5ccccc5c(-c5ccc(-c6ccc7oc8ccccc8c7c6)cc5)c5ccccc45)c4ccccc4c3c12 ; c1cc(-c2c3ccccc3c(-c3cc4oc5ccc6ccccc6c5c4c4ccccc34)c3ccccc23)cc(-c2cc3ccccc3c3ccccc23)c1 ; c1cc(-c2ccc3c4ccccc4c4ccccc4c3c2)cc(-c2c3ccccc3c(-c3cc4oc5ccc6ccccc6c5c4c4ccccc34)c3ccccc23)c1]

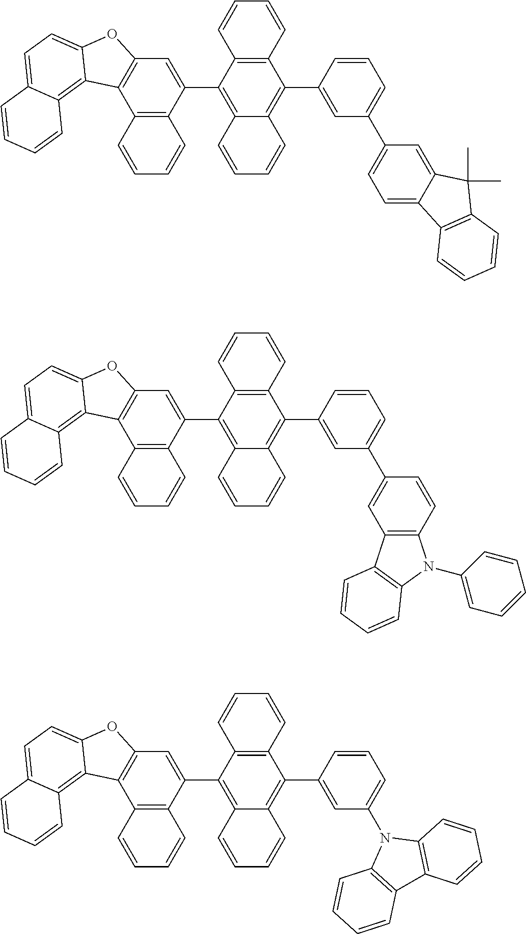 [SMILES: CC1(C)c2ccccc2-c2ccc(-c3cccc(-c4c5ccccc5c(-c5cc6oc7ccc8ccccc8c7c6c6ccccc56)c5ccccc45)c3)cc21 ; c1ccc(-n2c3ccccc3c3cc(-c4cccc(-c5c6ccccc6c(-c6cc7oc8ccc9ccccc9c8c7c7ccccc67)c6ccccc56)c4)ccc32)cc1 ; c1cc(-c2c3ccccc3c(-c3cc4oc5ccc6ccccc6c5c4c4ccccc34)c3ccccc23)cc(-n2c3ccccc3c3ccccc32)c1]

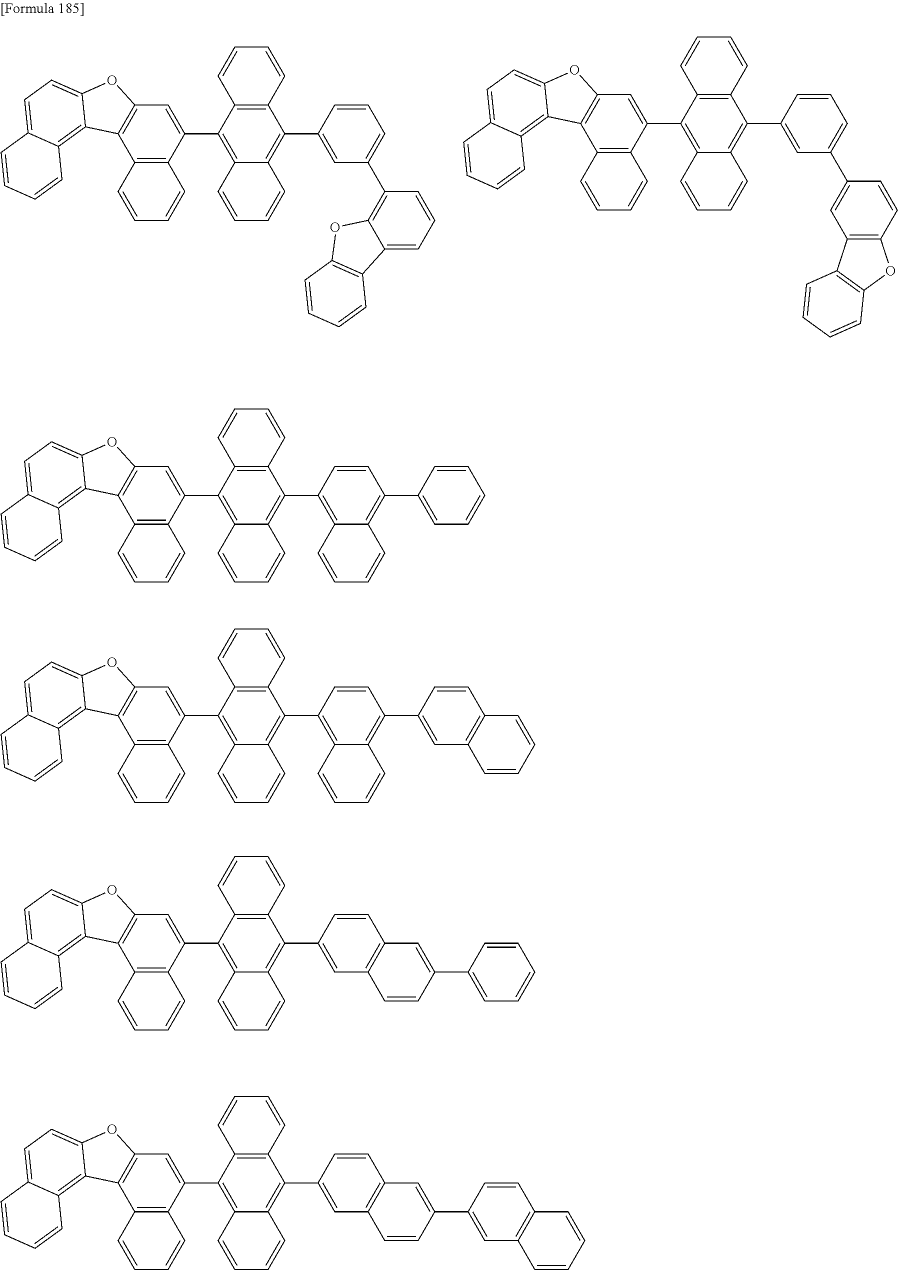

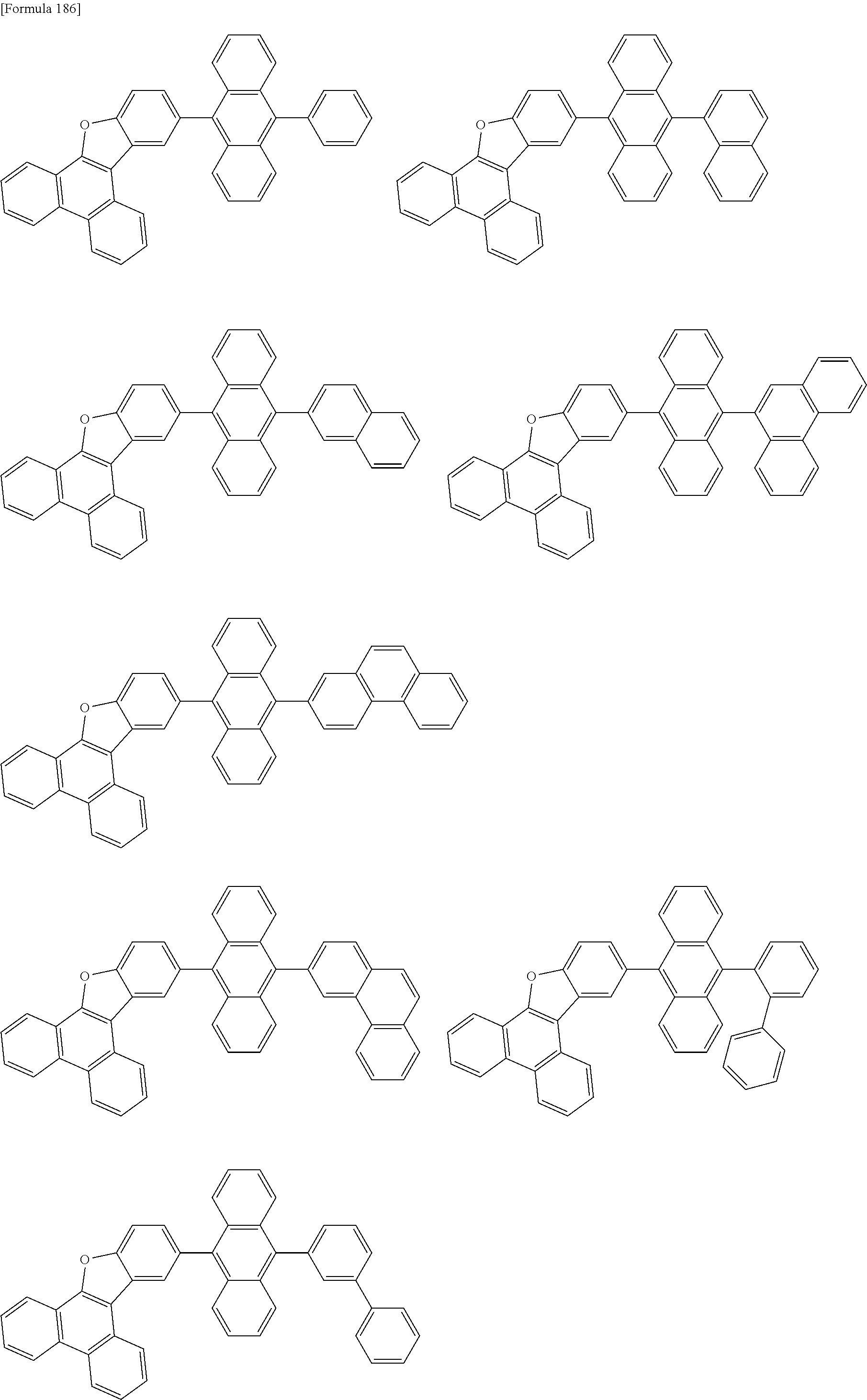

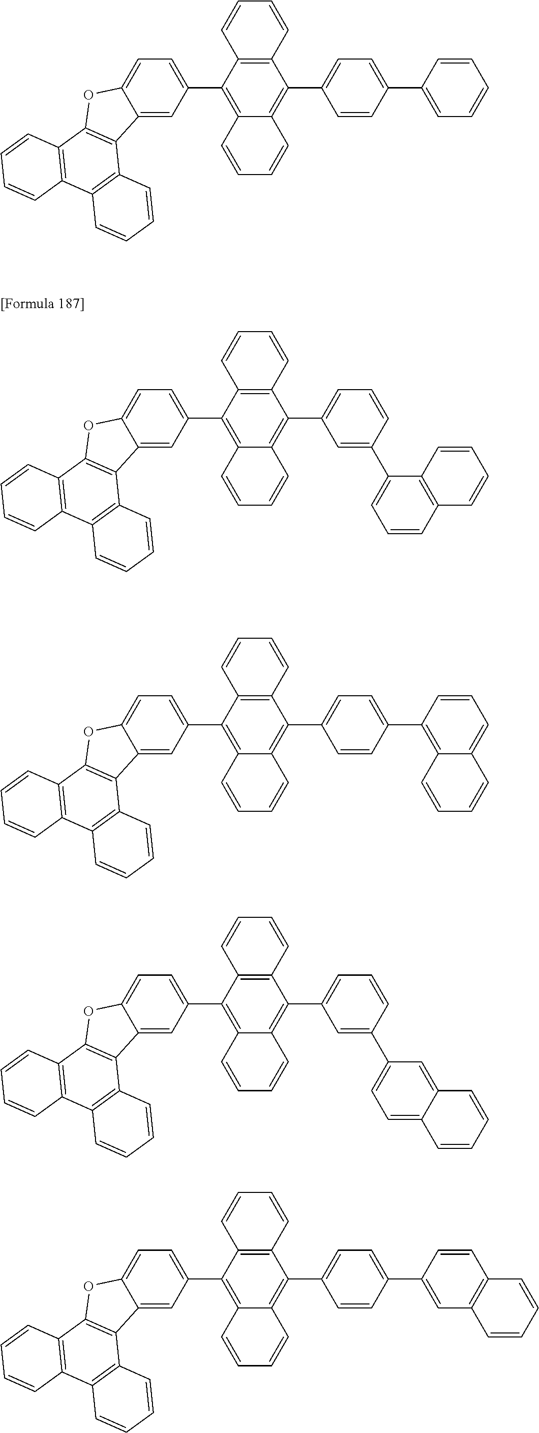 [SMILES: c1ccc(-c2ccc(-c3c4ccccc4c(-c4ccc5oc6c7ccccc7c7ccccc7c6c5c4)c4ccccc34)cc2)cc1 ; c1cc(-c2cccc3ccccc23)cc(-c2c3ccccc3c(-c3ccc4oc5c6ccccc6c6ccccc6c5c4c3)c3ccccc23)c1 ; c1ccc2c(-c3ccc(-c4c5ccccc5c(-c5ccc6oc7c8ccccc8c8ccccc8c7c6c5)c5ccccc45)cc3)cccc2c1 ; c1cc(-c2ccc3ccccc3c2)cc(-c2c3ccccc3c(-c3ccc4oc5c6ccccc6c6ccccc6c5c4c3)c3ccccc23)c1 ; c1ccc2cc(-c3ccc(-c4c5ccccc5c(-c5ccc6oc7c8ccccc8c8ccccc8c7c6c5)c5ccccc45)cc3)ccc2c1]

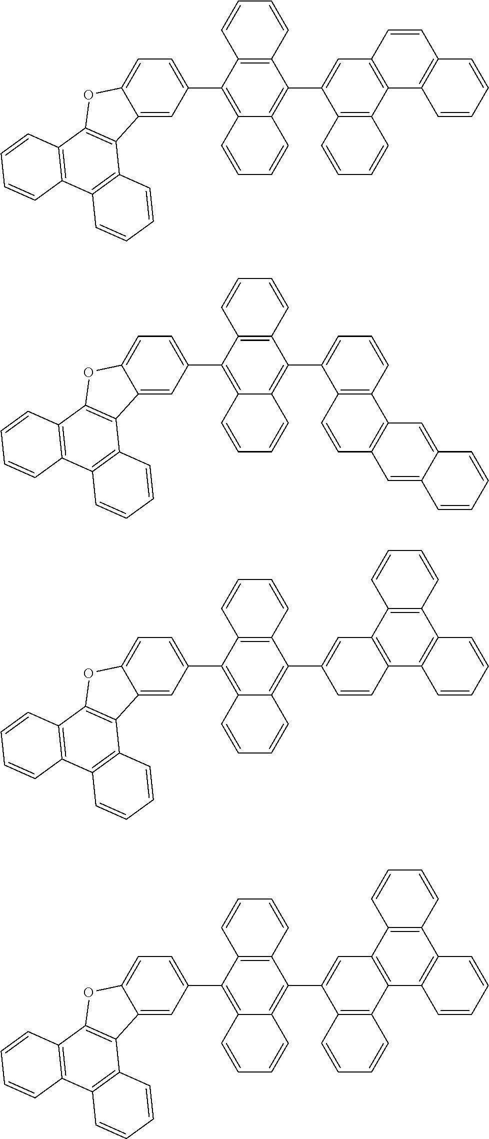

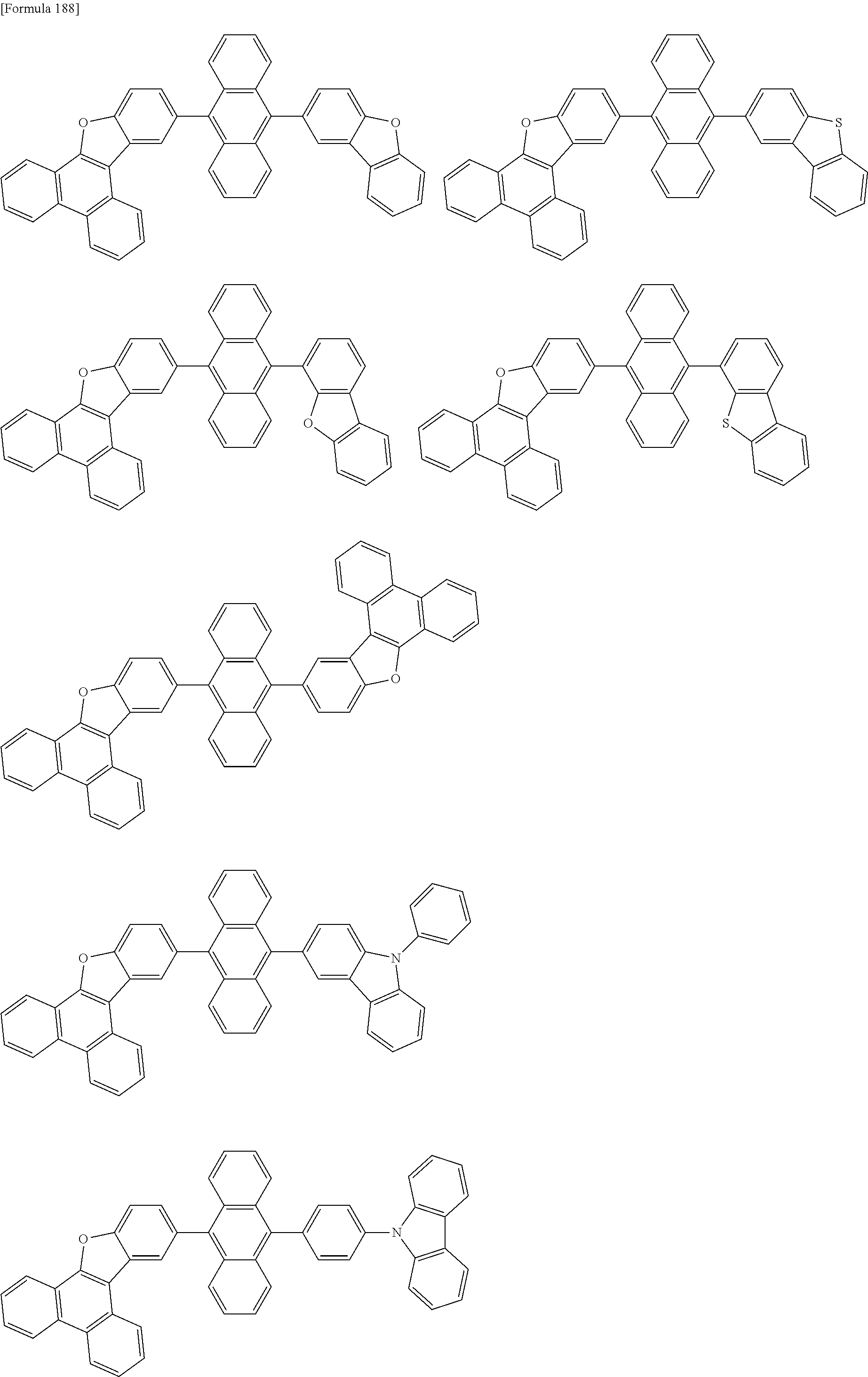

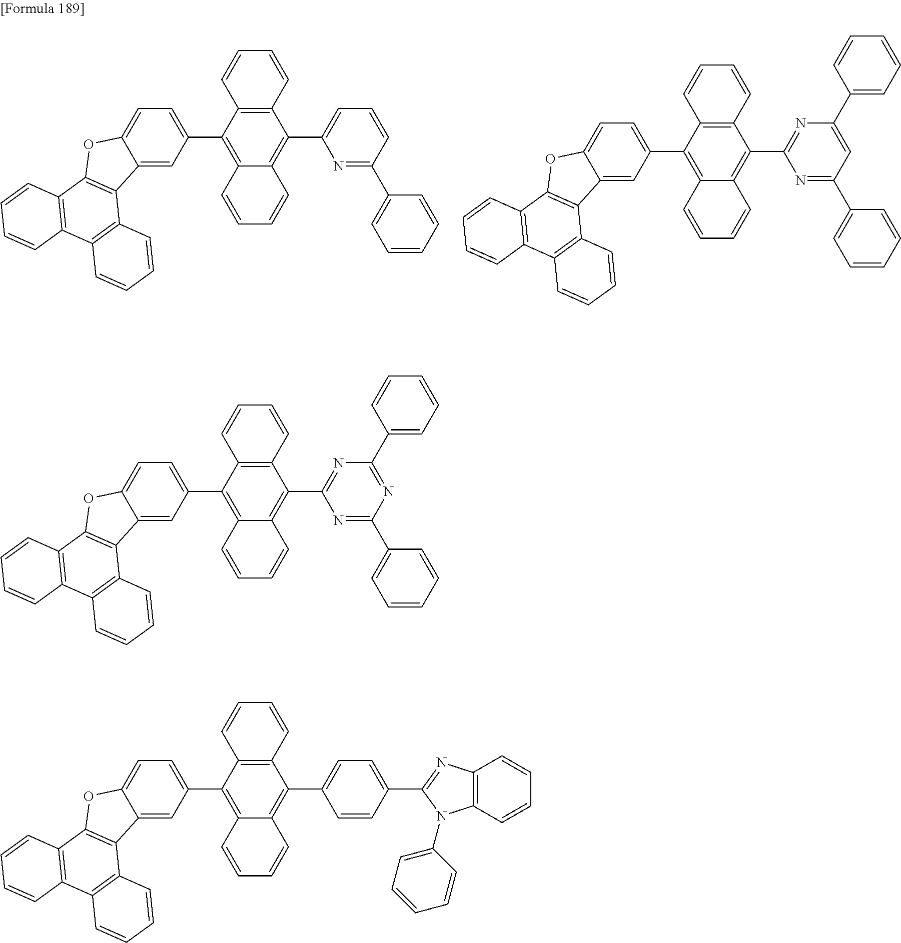

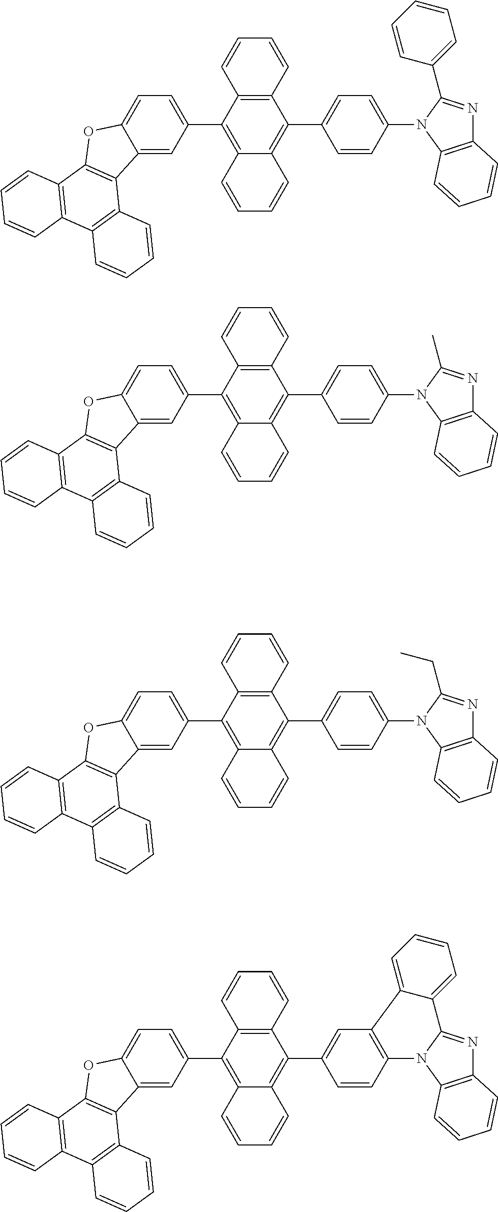 [SMILES: c1ccc(-c2nc3ccccc3n2-c2ccc(-c3c4ccccc4c(-c4ccc5oc6c7ccccc7c7ccccc7c6c5c4)c4ccccc34)cc2)cc1 ; Cc1nc2ccccc2n1-c1ccc(-c2c3ccccc3c(-c3ccc4oc5c6ccccc6c6ccccc6c5c4c3)c3ccccc23)cc1 ; CCc1nc2ccccc2n1-c1ccc(-c2c3ccccc3c(-c3ccc4oc5c6ccccc6c6ccccc6c5c4c3)c3ccccc23)cc1 ; c1ccc2c(c1)nc1c3ccccc3c3cc(-c4c5ccccc5c(-c5ccc6oc7c8ccccc8c8ccccc8c7c6c5)c5ccccc45)ccc3n21]

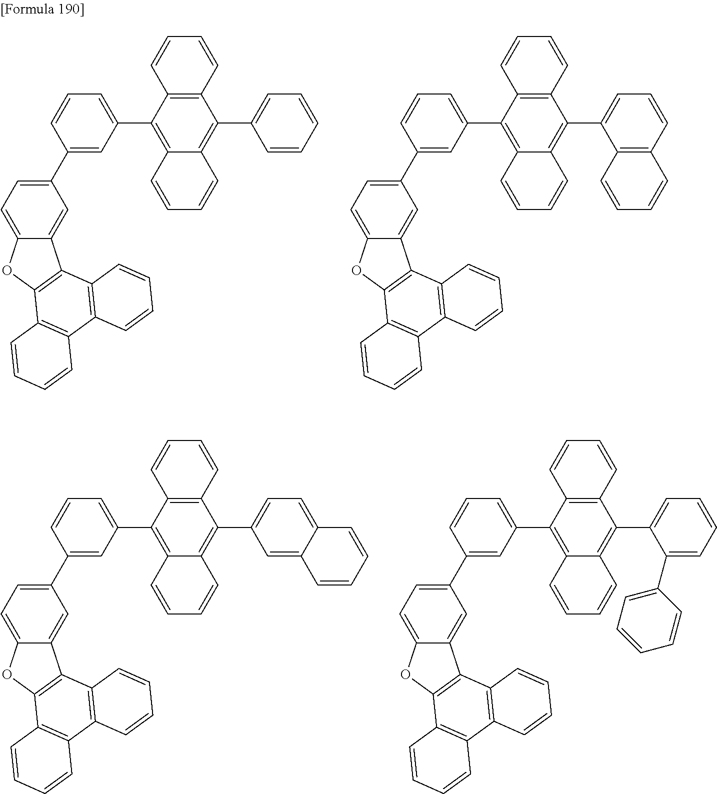 [SMILES: c1ccc(-c2c3ccccc3c(-c3cccc(-c4ccc5oc6c7ccccc7c7ccccc7c6c5c4)c3)c3ccccc23)cc1 ; c1cc(-c2ccc3oc4c5ccccc5c5ccccc5c4c3c2)cc(-c2c3ccccc3c(-c3cccc4ccccc34)c3ccccc23)c1 ; c1cc(-c2ccc3oc4c5ccccc5c5ccccc5c4c3c2)cc(-c2c3ccccc3c(-c3ccc4ccccc4c3)c3ccccc23)c1 ; c1ccc(-c2ccccc2-c2c3ccccc3c(-c3cccc(-c4ccc5oc6c7ccccc7c7ccccc7c6c5c4)c3)c3ccccc23)cc1]

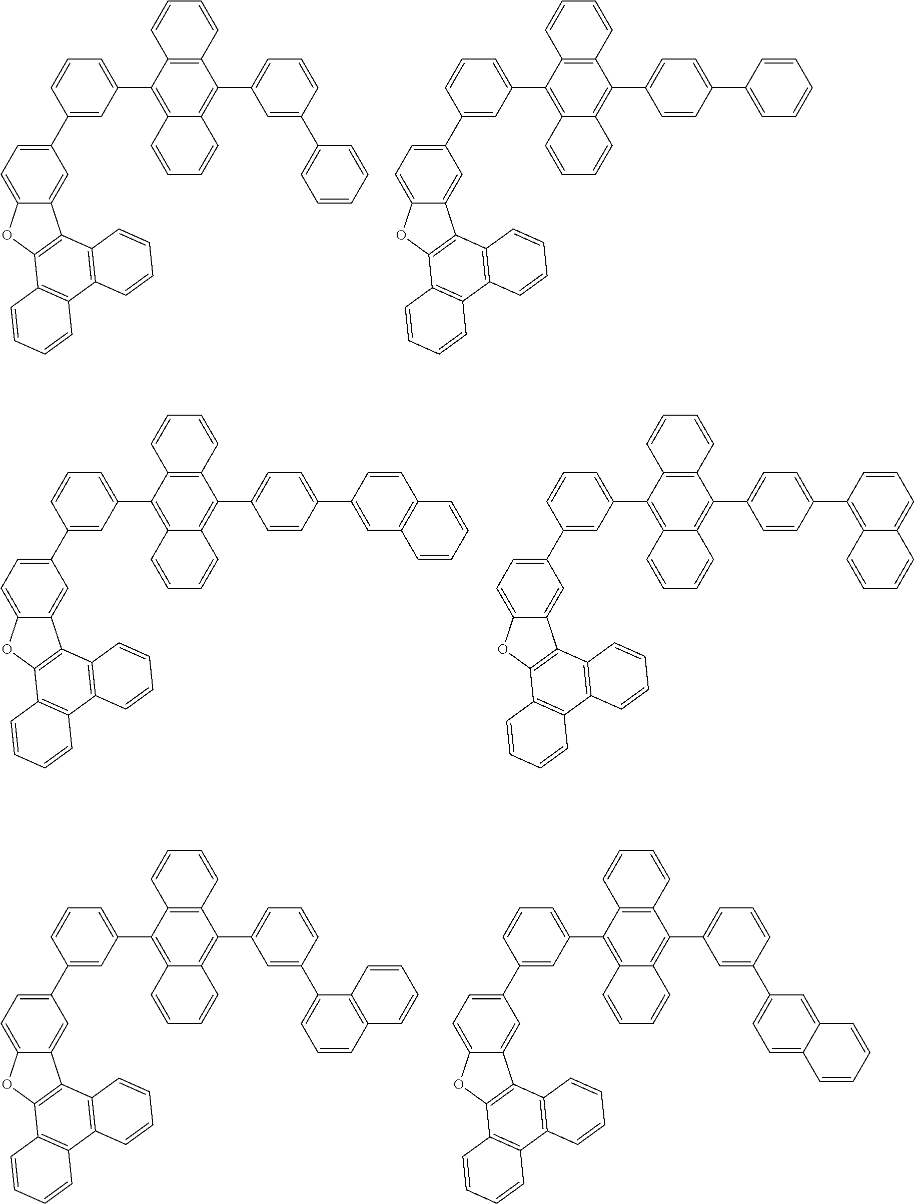

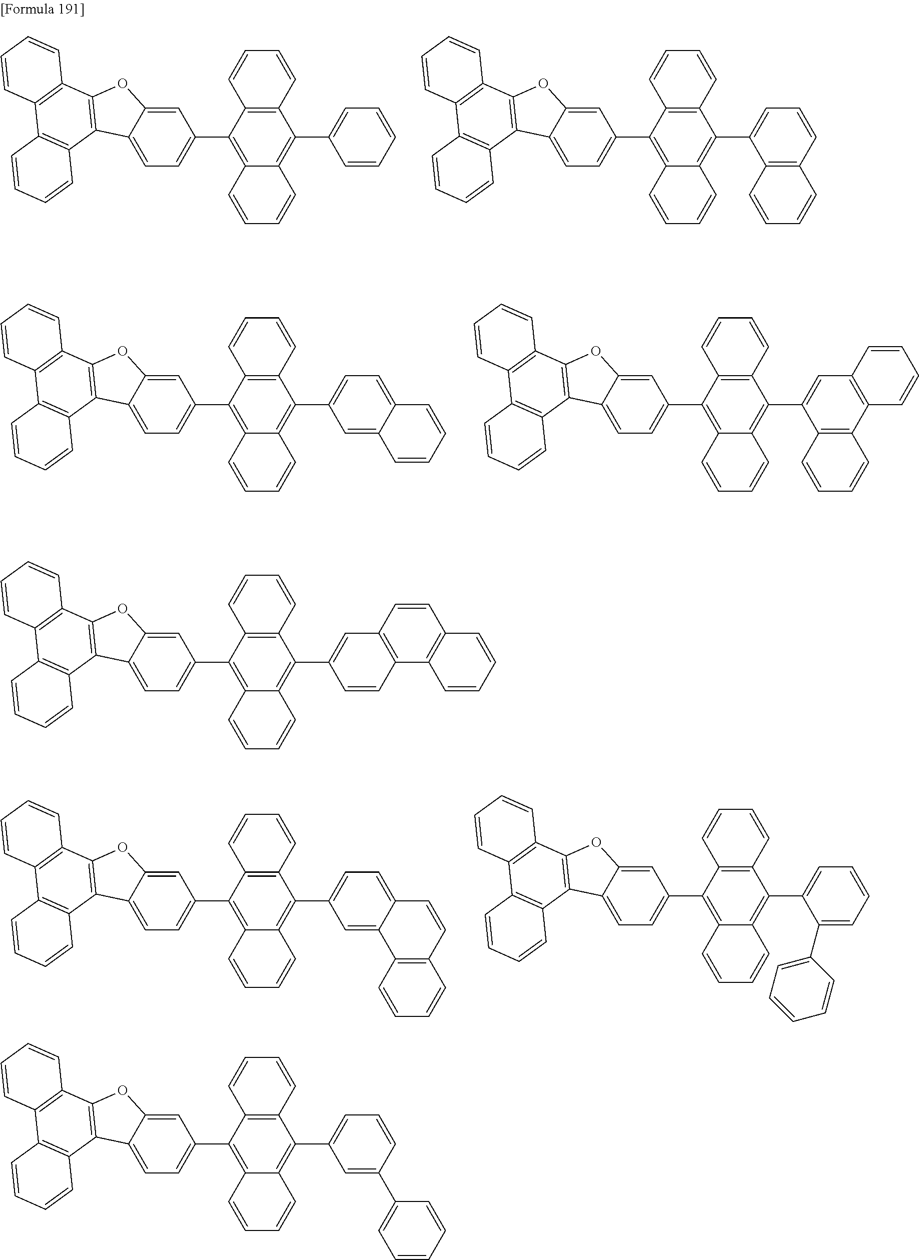

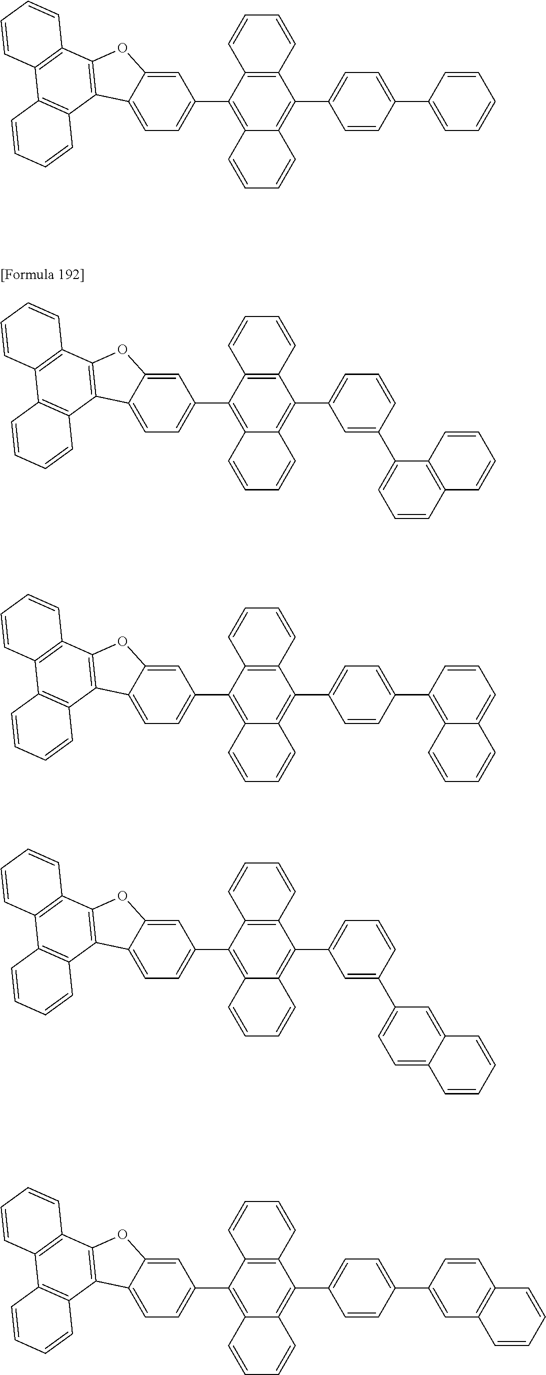 [SMILES: c1ccc(-c2ccc(-c3c4ccccc4c(-c4ccc5c(c4)oc4c6ccccc6c6ccccc6c54)c4ccccc34)cc2)cc1 ; c1cc(-c2cccc3ccccc23)cc(-c2c3ccccc3c(-c3ccc4c(c3)oc3c5ccccc5c5ccccc5c43)c3ccccc23)c1 ; c1ccc2c(-c3ccc(-c4c5ccccc5c(-c5ccc6c(c5)oc5c7ccccc7c7ccccc7c65)c5ccccc45)cc3)cccc2c1 ; c1cc(-c2ccc3ccccc3c2)cc(-c2c3ccccc3c(-c3ccc4c(c3)oc3c5ccccc5c5ccccc5c43)c3ccccc23)c1 ; c1ccc2cc(-c3ccc(-c4c5ccccc5c(-c5ccc6c(c5)oc5c7ccccc7c7ccccc7c65)c5ccccc45)cc3)ccc2c1]

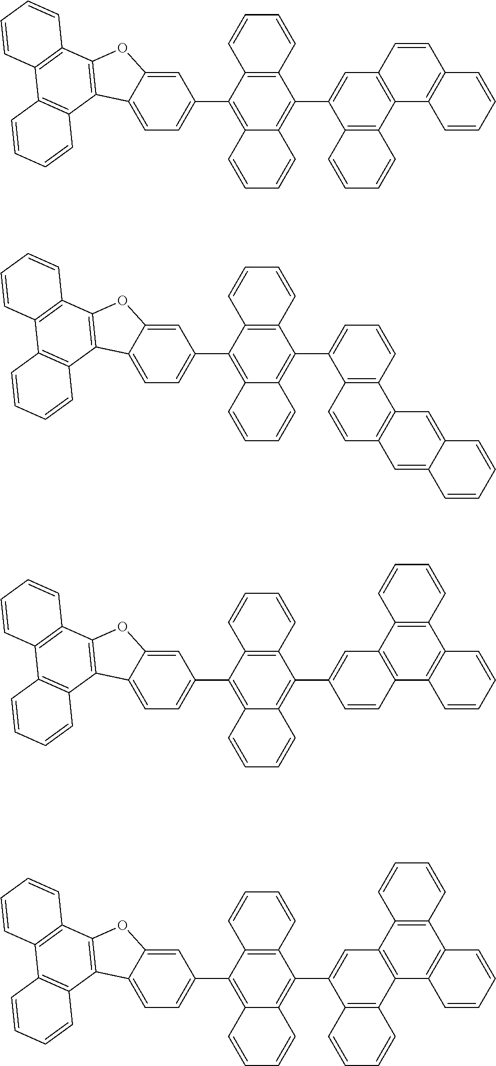 [SMILES: c1ccc2c(c1)ccc1cc(-c3c4ccccc4c(-c4ccc5c(c4)oc4c6ccccc6c6ccccc6c54)c4ccccc34)c3ccccc3c12 ; c1ccc2cc3c(ccc4c(-c5c6ccccc6c(-c6ccc7c(c6)oc6c8ccccc8c8ccccc8c76)c6ccccc56)cccc43)cc2c1 ; c1ccc2c(-c3ccc4c5ccccc5c5ccccc5c4c3)c3ccccc3c(-c3ccc4c(c3)oc3c5ccccc5c5ccccc5c43)c2c1 ; c1ccc2c(-c3cc4c5ccccc5c5ccccc5c4c4ccccc34)c3ccccc3c(-c3ccc4c(c3)oc3c5ccccc5c5ccccc5c43)c2c1]

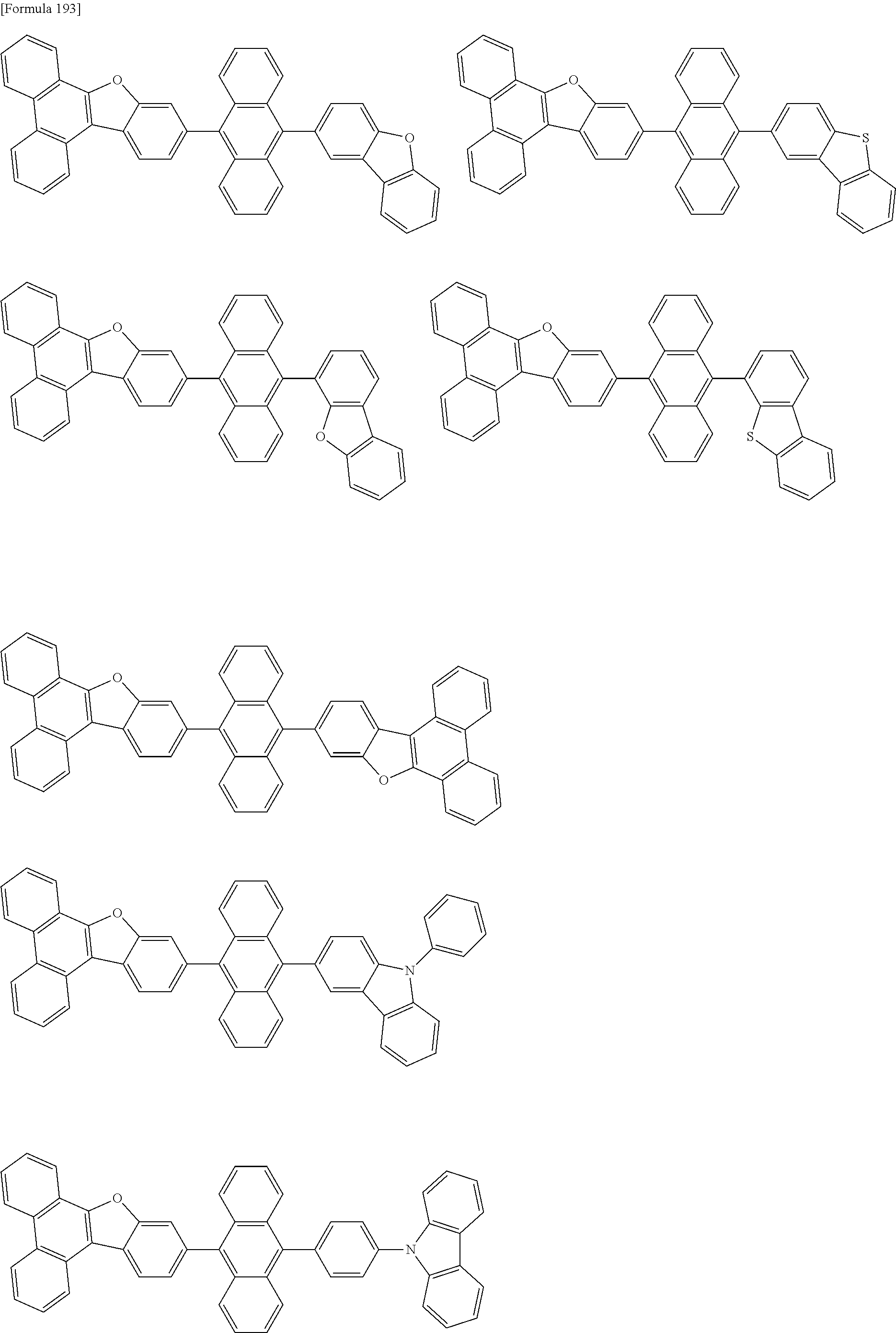

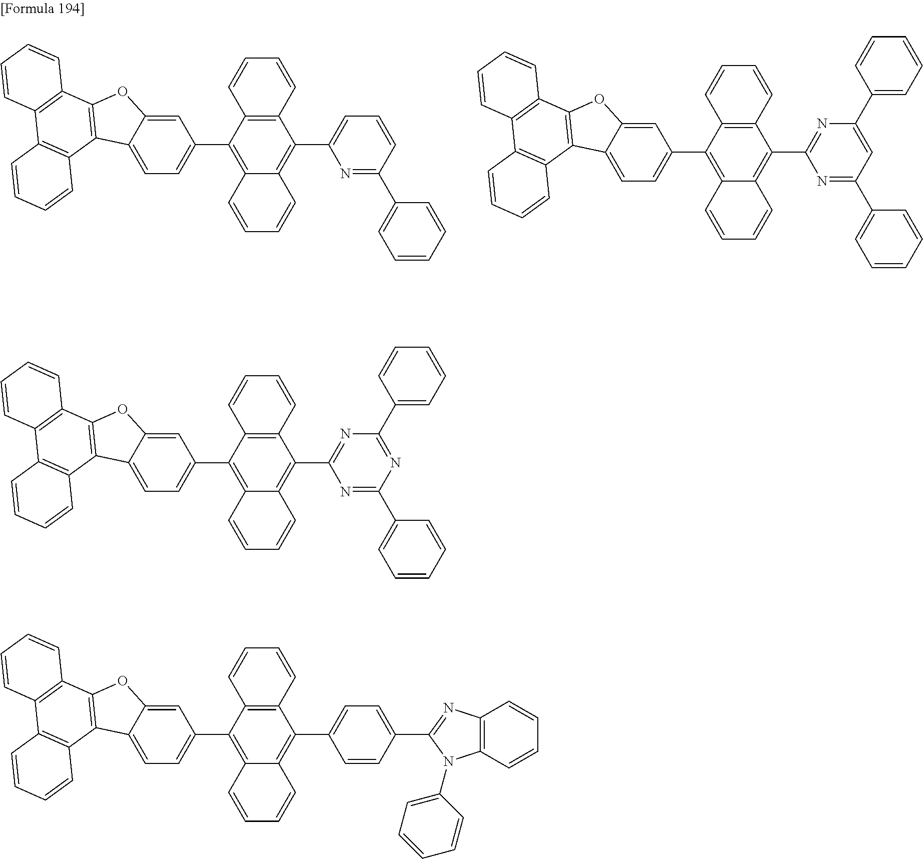 [SMILES: c1ccc(-c2cccc(-c3c4ccccc4c(-c4ccc5c(c4)oc4c6ccccc6c6ccccc6c54)c4ccccc34)n2)cc1 ; c1ccc(-c2cc(-c3ccccc3)nc(-c3c4ccccc4c(-c4ccc5c(c4)oc4c6ccccc6c6ccccc6c54)c4ccccc34)n2)cc1 ; c1ccc(-c2nc(-c3ccccc3)nc(-c3c4ccccc4c(-c4ccc5c(c4)oc4c6ccccc6c6ccccc6c54)c4ccccc34)n2)cc1 ; c1ccc(-n2c(-c3ccc(-c4c5ccccc5c(-c5ccc6c(c5)oc5c7ccccc7c7ccccc7c65)c5ccccc45)cc3)nc3ccccc32)cc1]

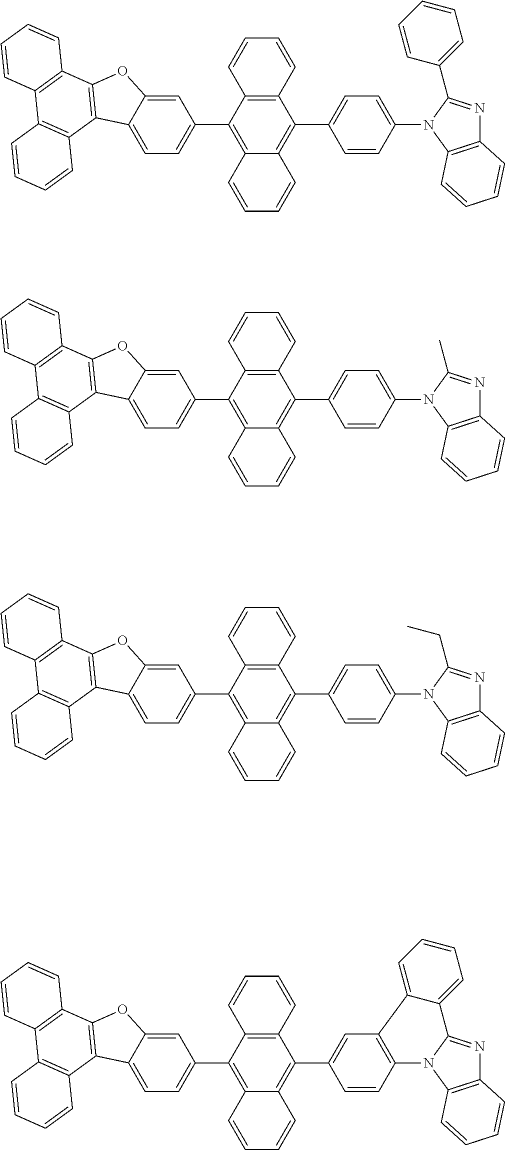 [SMILES: c1ccc(-c2nc3ccccc3n2-c2ccc(-c3c4ccccc4c(-c4ccc5c(c4)oc4c6ccccc6c6ccccc6c54)c4ccccc34)cc2)cc1 ; Cc1nc2ccccc2n1-c1ccc(-c2c3ccccc3c(-c3ccc4c(c3)oc3c5ccccc5c5ccccc5c43)c3ccccc23)cc1 ; CCc1nc2ccccc2n1-c1ccc(-c2c3ccccc3c(-c3ccc4c(c3)oc3c5ccccc5c5ccccc5c43)c3ccccc23)cc1 ; c1ccc2c(c1)nc1c3ccccc3c3cc(-c4c5ccccc5c(-c5ccc6c(c5)oc5c7ccccc7c7ccccc7c65)c5ccccc45)ccc3n21]

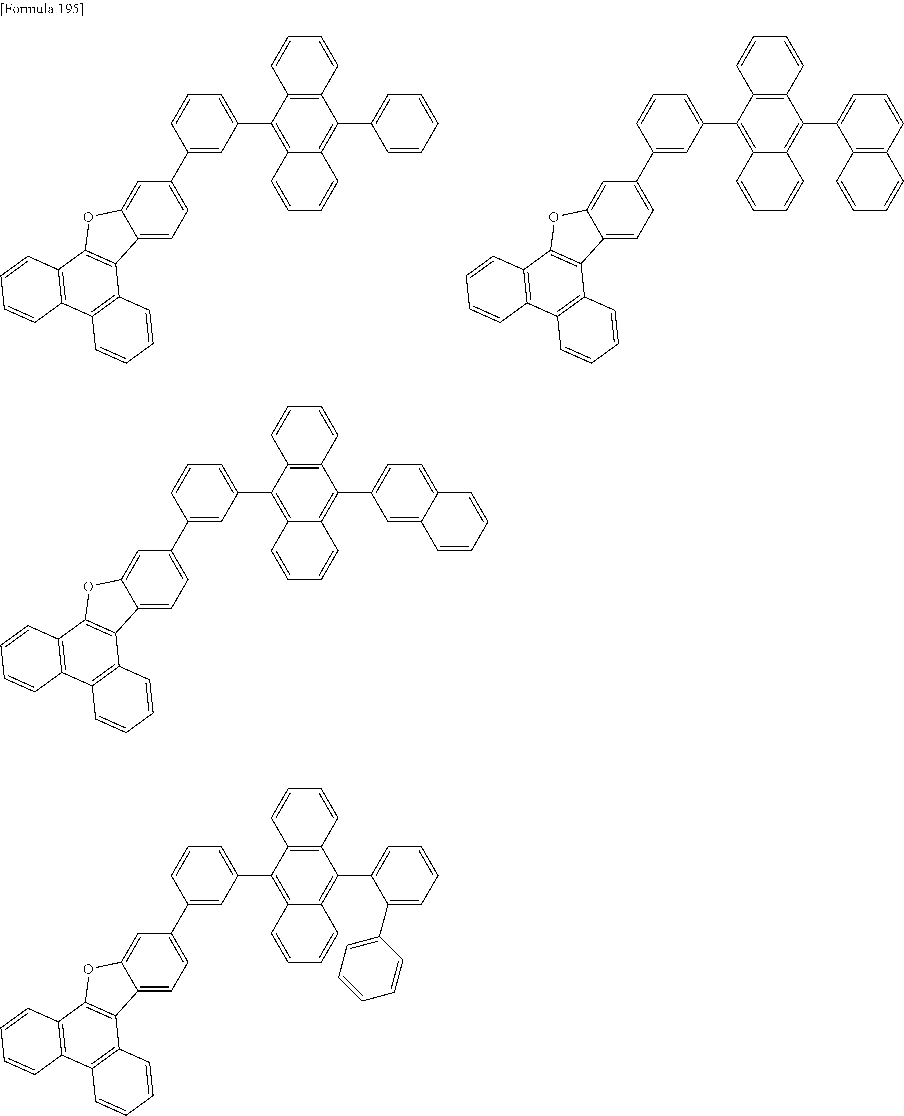 [SMILES: c1ccc(-c2c3ccccc3c(-c3cccc(-c4ccc5c(c4)oc4c6ccccc6c6ccccc6c54)c3)c3ccccc23)cc1 ; c1cc(-c2ccc3c(c2)oc2c4ccccc4c4ccccc4c32)cc(-c2c3ccccc3c(-c3cccc4ccccc34)c3ccccc23)c1 ; c1cc(-c2ccc3c(c2)oc2c4ccccc4c4ccccc4c32)cc(-c2c3ccccc3c(-c3ccc4ccccc4c3)c3ccccc23)c1 ; c1ccc(-c2ccccc2-c2c3ccccc3c(-c3cccc(-c4ccc5c(c4)oc4c6ccccc6c6ccccc6c54)c3)c3ccccc23)cc1]

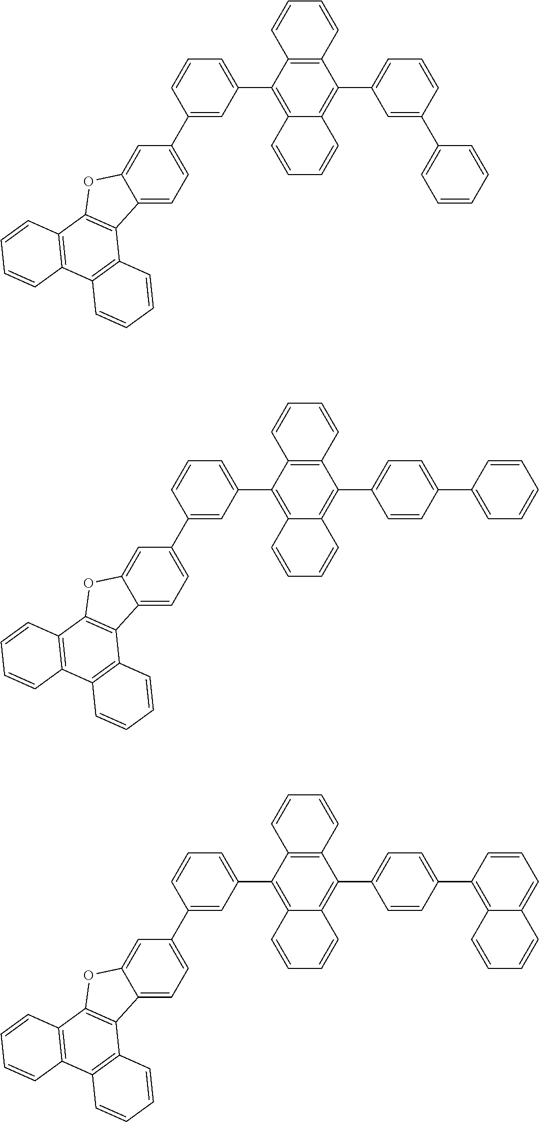 [SMILES: c1ccc(-c2cccc(-c3c4ccccc4c(-c4cccc(-c5ccc6c(c5)oc5c7ccccc7c7ccccc7c65)c4)c4ccccc34)c2)cc1 ; c1ccc(-c2ccc(-c3c4ccccc4c(-c4cccc(-c5ccc6c(c5)oc5c7ccccc7c7ccccc7c65)c4)c4ccccc34)cc2)cc1 ; c1cc(-c2ccc3c(c2)oc2c4ccccc4c4ccccc4c32)cc(-c2c3ccccc3c(-c3ccc(-c4cccc5ccccc45)cc3)c3ccccc23)c1]

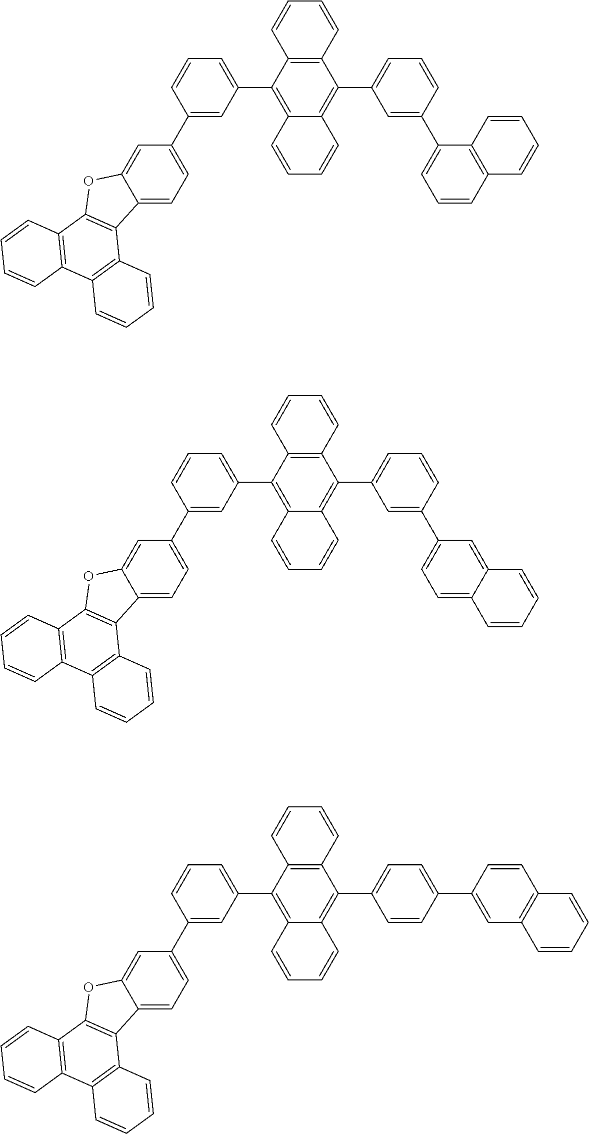 [SMILES: c1cc(-c2ccc3c(c2)oc2c4ccccc4c4ccccc4c32)cc(-c2c3ccccc3c(-c3cccc(-c4cccc5ccccc45)c3)c3ccccc23)c1 ; c1cc(-c2ccc3ccccc3c2)cc(-c2c3ccccc3c(-c3cccc(-c4ccc5c(c4)oc4c6ccccc6c6ccccc6c54)c3)c3ccccc23)c1 ; c1cc(-c2ccc3c(c2)oc2c4ccccc4c4ccccc4c32)cc(-c2c3ccccc3c(-c3ccc(-c4ccc5ccccc5c4)cc3)c3ccccc23)c1]

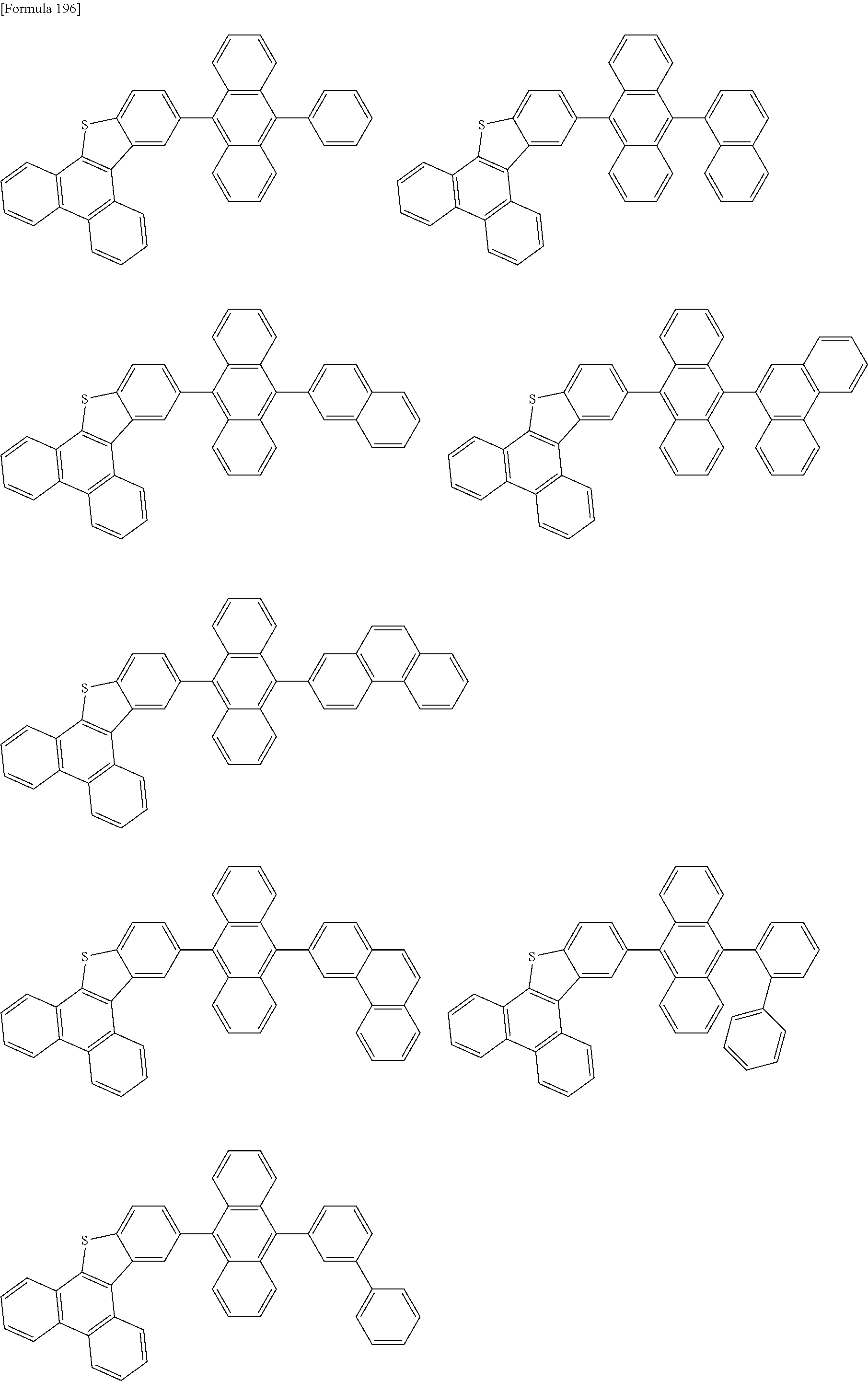

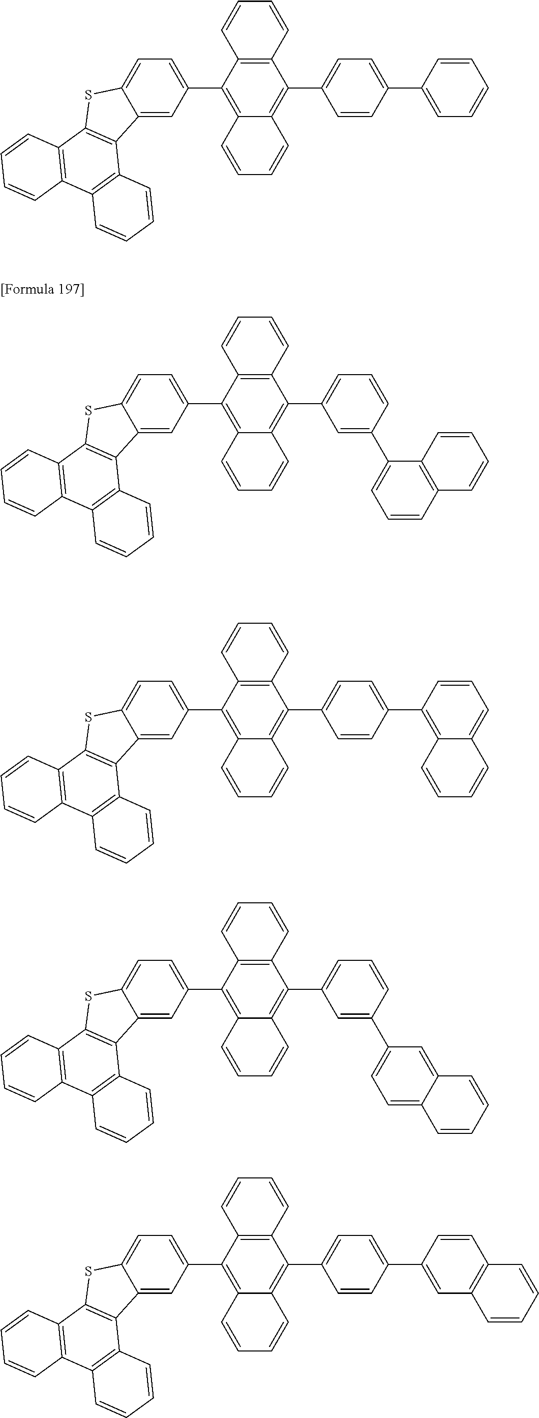 [SMILES: c1ccc(-c2ccc(-c3c4ccccc4c(-c4ccc5sc6c7ccccc7c7ccccc7c6c5c4)c4ccccc34)cc2)cc1 ; c1cc(-c2cccc3ccccc23)cc(-c2c3ccccc3c(-c3ccc4sc5c6ccccc6c6ccccc6c5c4c3)c3ccccc23)c1 ; c1ccc2c(-c3ccc(-c4c5ccccc5c(-c5ccc6sc7c8ccccc8c8ccccc8c7c6c5)c5ccccc45)cc3)cccc2c1 ; c1cc(-c2ccc3ccccc3c2)cc(-c2c3ccccc3c(-c3ccc4sc5c6ccccc6c6ccccc6c5c4c3)c3ccccc23)c1 ; c1ccc2cc(-c3ccc(-c4c5ccccc5c(-c5ccc6sc7c8ccccc8c8ccccc8c7c6c5)c5ccccc45)cc3)ccc2c1]

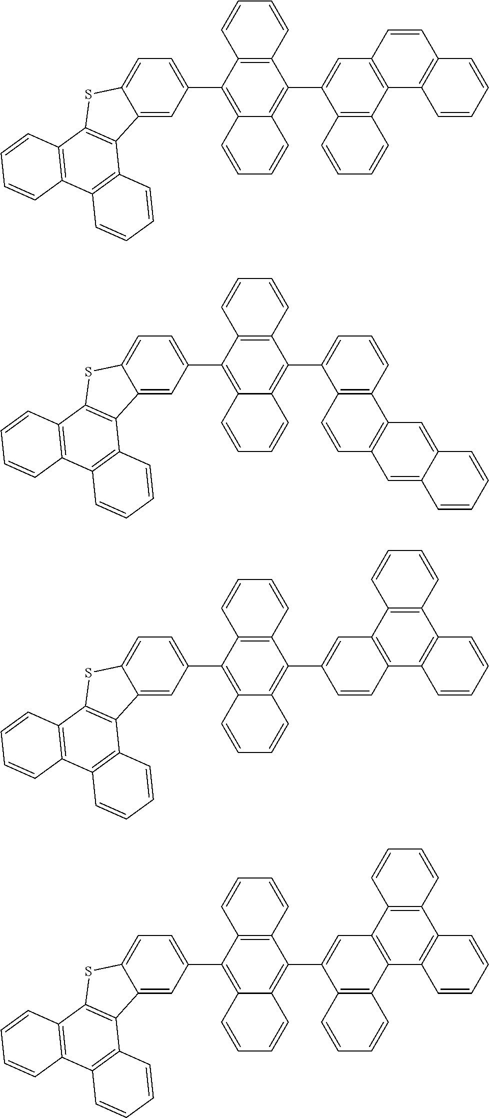

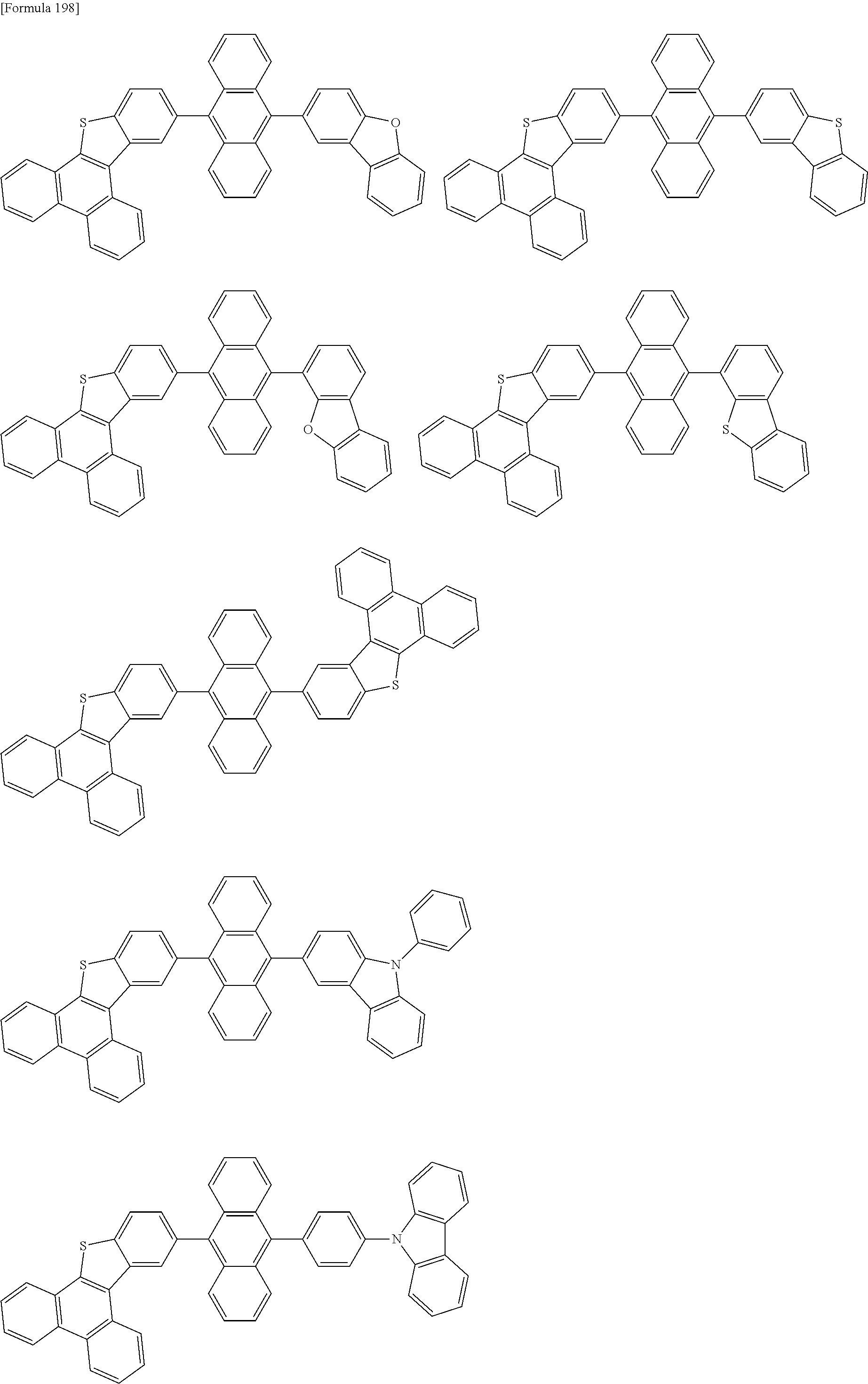

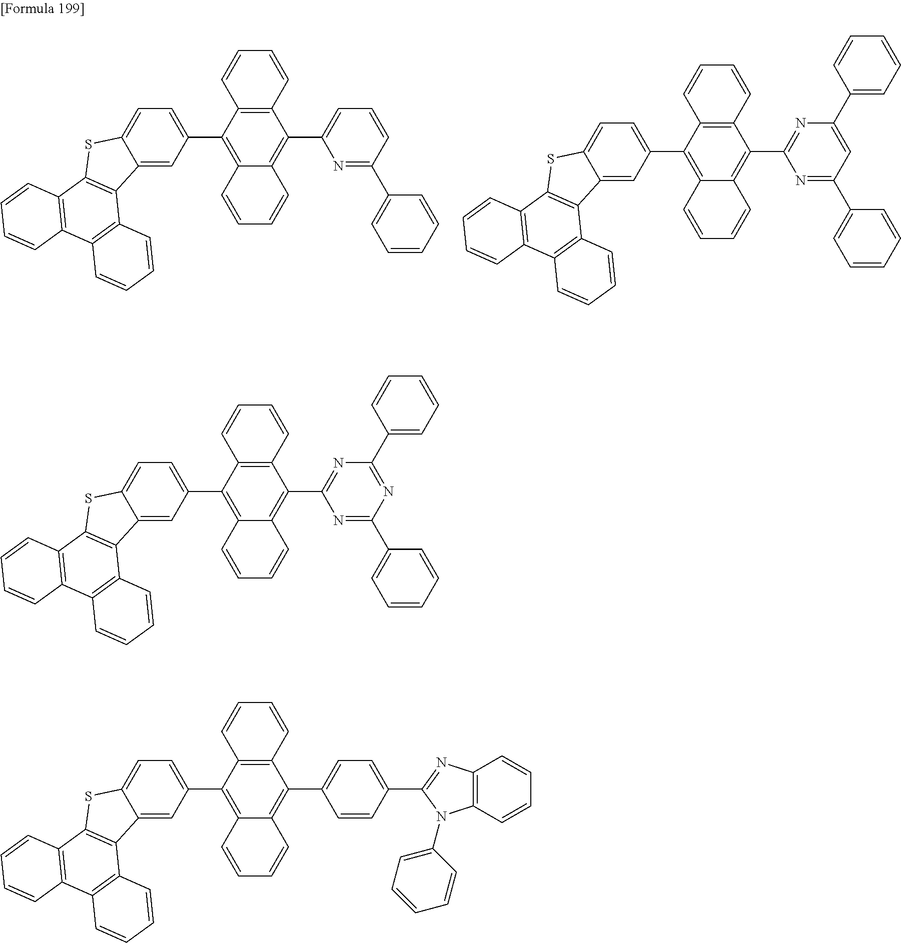

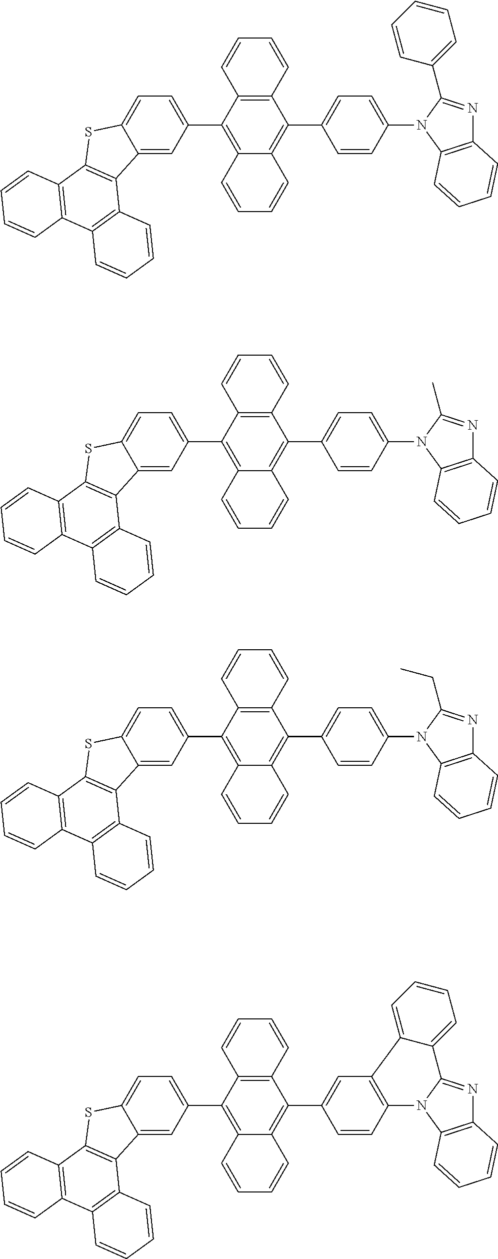 [SMILES: c1ccc(-c2nc3ccccc3n2-c2ccc(-c3c4ccccc4c(-c4ccc5sc6c7ccccc7c7ccccc7c6c5c4)c4ccccc34)cc2)cc1 ; Cc1nc2ccccc2n1-c1ccc(-c2c3ccccc3c(-c3ccc4sc5c6ccccc6c6ccccc6c5c4c3)c3ccccc23)cc1 ; CCc1nc2ccccc2n1-c1ccc(-c2c3ccccc3c(-c3ccc4sc5c6ccccc6c6ccccc6c5c4c3)c3ccccc23)cc1 ; c1ccc2c(c1)nc1c3ccccc3c3cc(-c4c5ccccc5c(-c5ccc6sc7c8ccccc8c8ccccc8c7c6c5)c5ccccc45)ccc3n21]

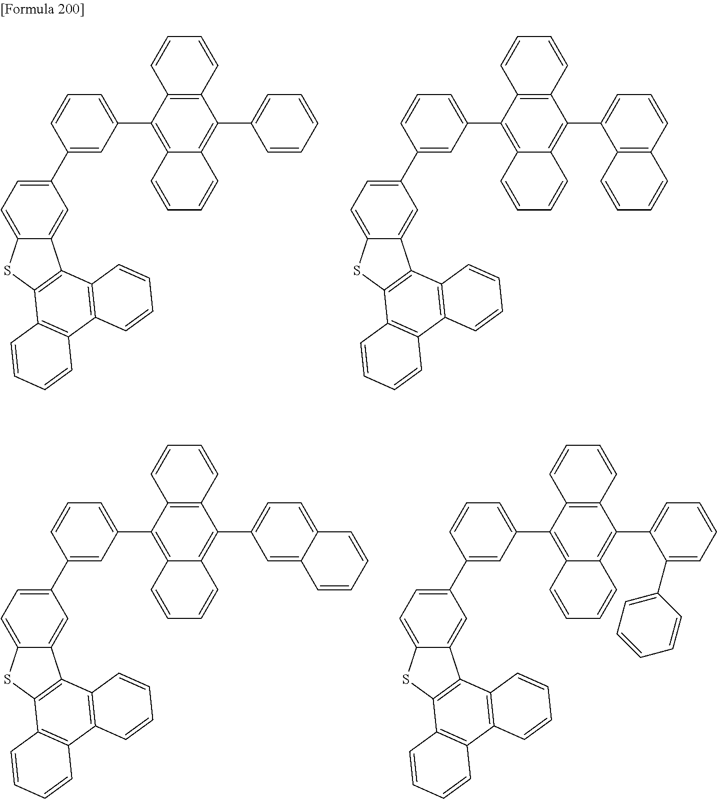 [SMILES: c1ccc(-c2c3ccccc3c(-c3cccc(-c4ccc5sc6c7ccccc7c7ccccc7c6c5c4)c3)c3ccccc23)cc1 ; c1cc(-c2ccc3sc4c5ccccc5c5ccccc5c4c3c2)cc(-c2c3ccccc3c(-c3cccc4ccccc34)c3ccccc23)c1 ; c1cc(-c2ccc3sc4c5ccccc5c5ccccc5c4c3c2)cc(-c2c3ccccc3c(-c3ccc4ccccc4c3)c3ccccc23)c1 ; c1ccc(-c2ccccc2-c2c3ccccc3c(-c3cccc(-c4ccc5sc6c7ccccc7c7ccccc7c6c5c4)c3)c3ccccc23)cc1]

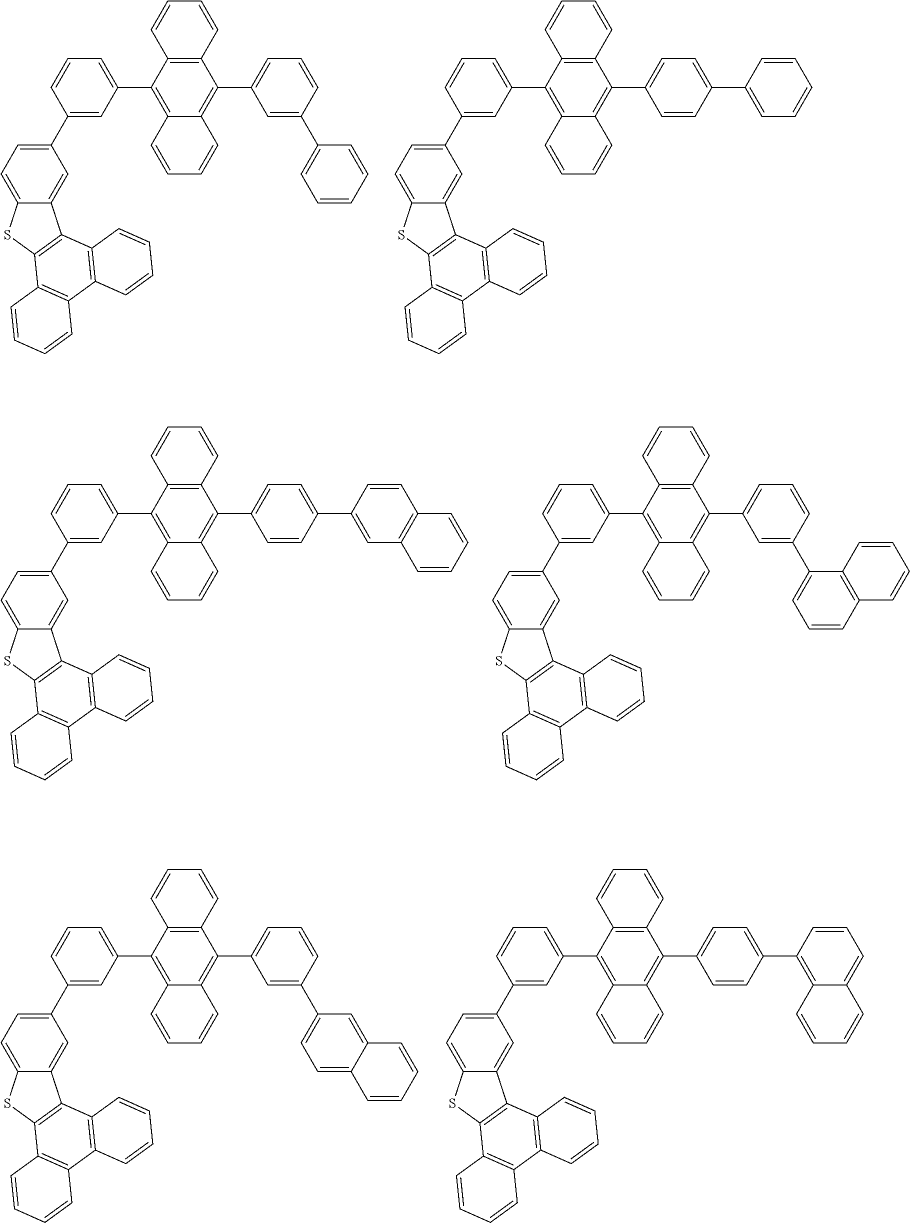

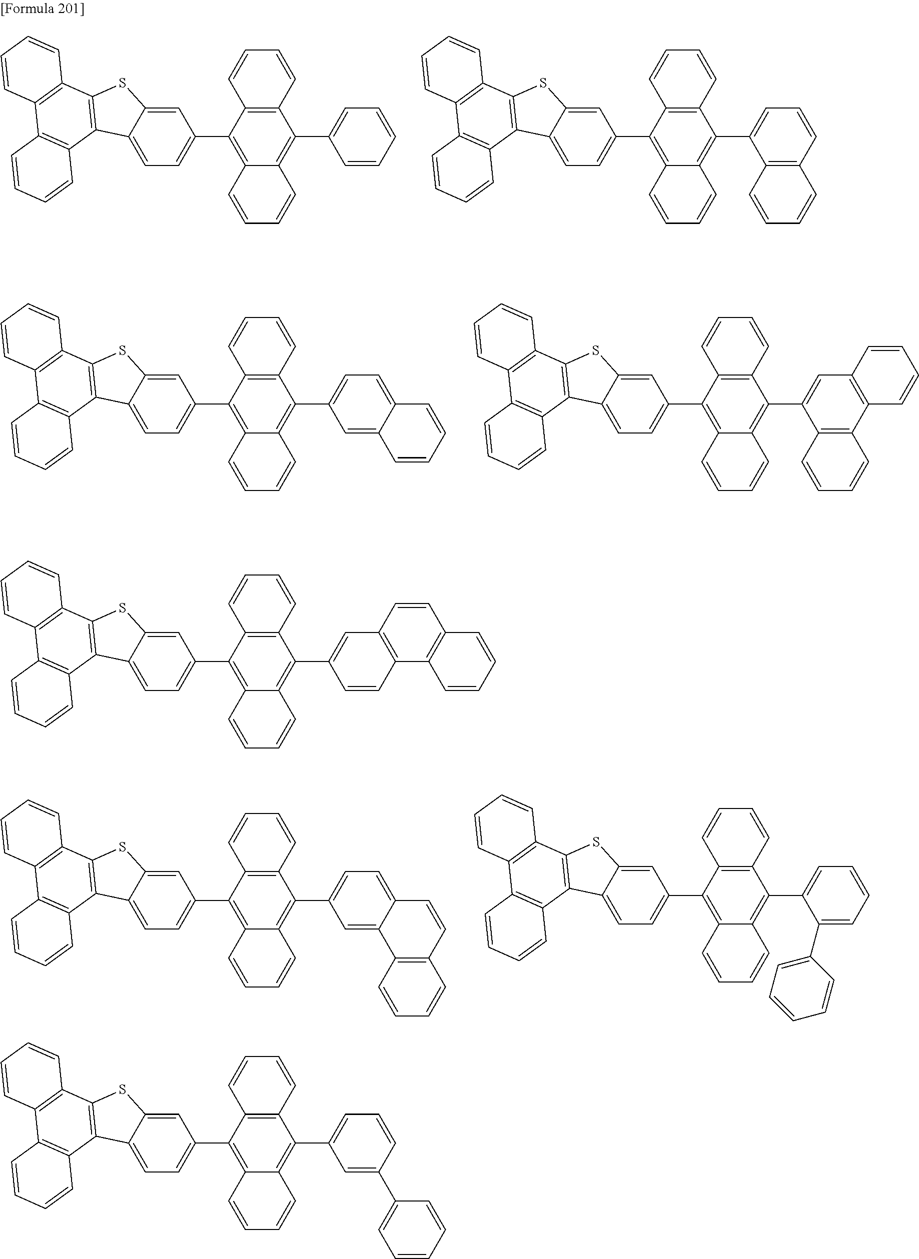

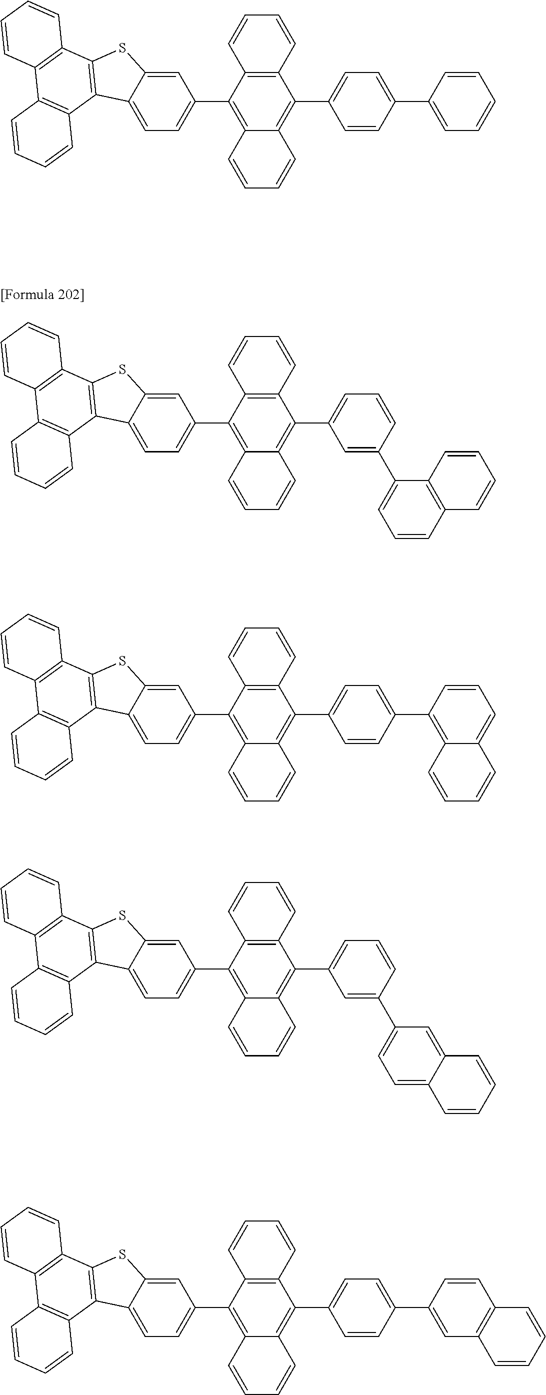 [SMILES: c1ccc(-c2ccc(-c3c4ccccc4c(-c4ccc5c(c4)sc4c6ccccc6c6ccccc6c54)c4ccccc34)cc2)cc1 ; c1cc(-c2cccc3ccccc23)cc(-c2c3ccccc3c(-c3ccc4c(c3)sc3c5ccccc5c5ccccc5c43)c3ccccc23)c1 ; c1ccc2c(-c3ccc(-c4c5ccccc5c(-c5ccc6c(c5)sc5c7ccccc7c7ccccc7c65)c5ccccc45)cc3)cccc2c1 ; c1cc(-c2ccc3ccccc3c2)cc(-c2c3ccccc3c(-c3ccc4c(c3)sc3c5ccccc5c5ccccc5c43)c3ccccc23)c1 ; c1ccc2cc(-c3ccc(-c4c5ccccc5c(-c5ccc6c(c5)sc5c7ccccc7c7ccccc7c65)c5ccccc45)cc3)ccc2c1]

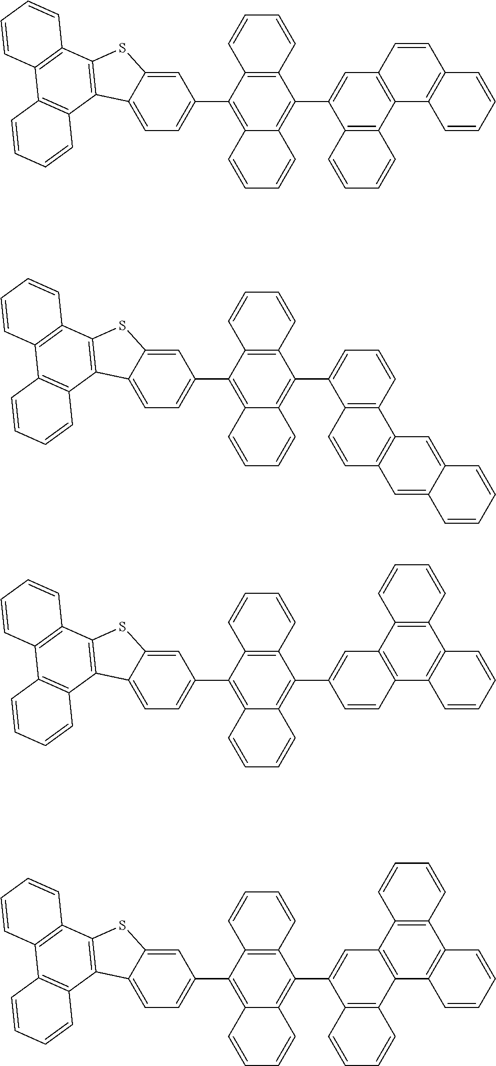

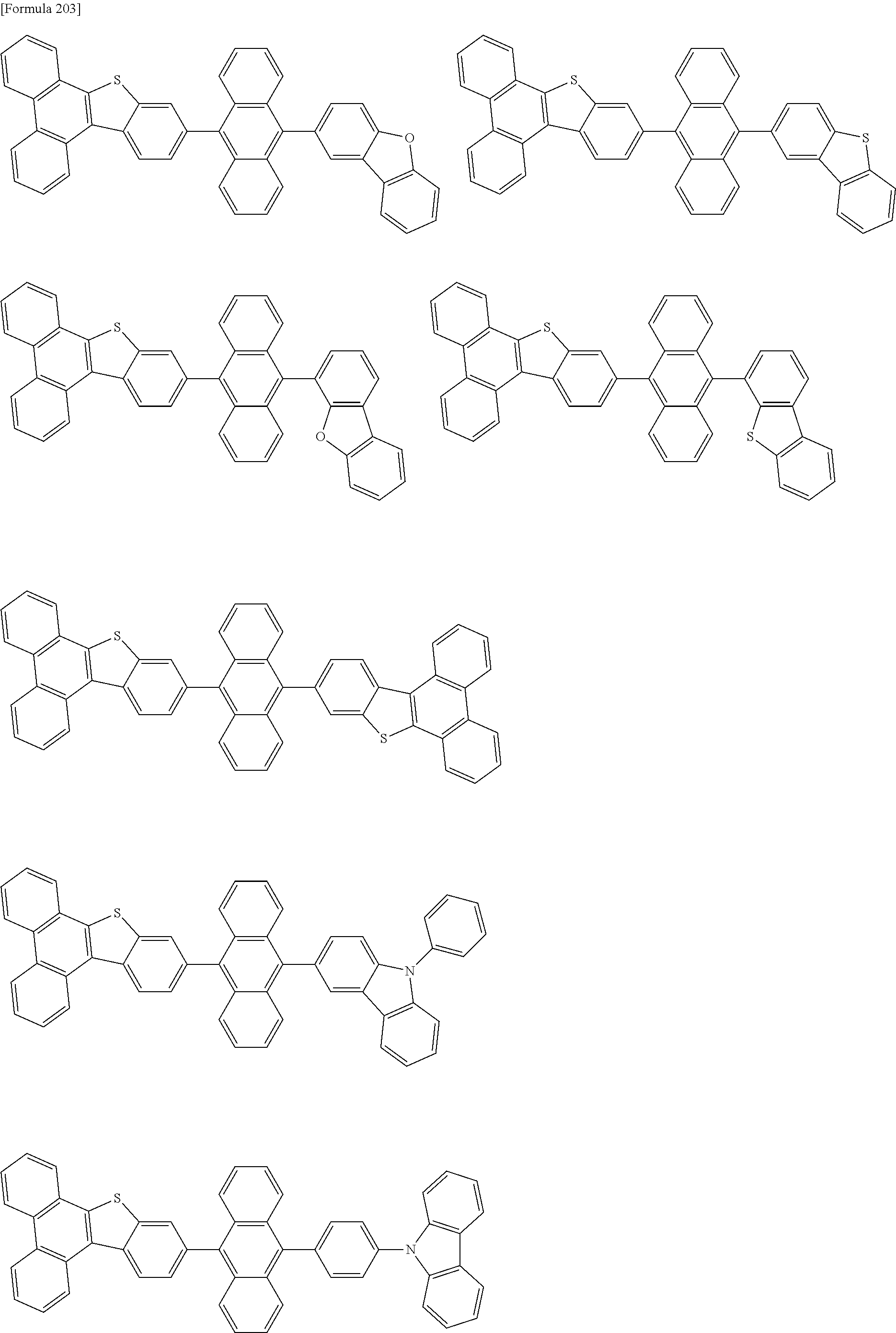

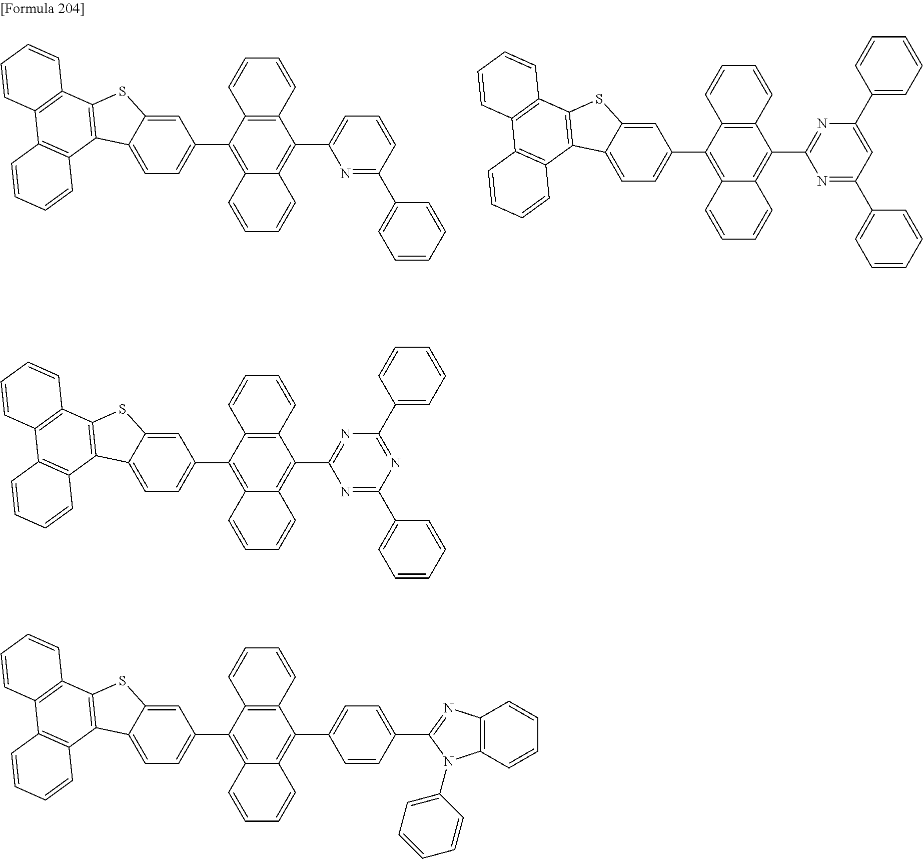 [SMILES: c1ccc(-c2cccc(-c3c4ccccc4c(-c4ccc5c(c4)sc4c6ccccc6c6ccccc6c54)c4ccccc34)n2)cc1 ; c1ccc(-c2cc(-c3ccccc3)nc(-c3c4ccccc4c(-c4ccc5c(c4)sc4c6ccccc6c6ccccc6c54)c4ccccc34)n2)cc1 ; c1ccc(-c2nc(-c3ccccc3)nc(-c3c4ccccc4c(-c4ccc5c(c4)sc4c6ccccc6c6ccccc6c54)c4ccccc34)n2)cc1 ; c1ccc(-n2c(-c3ccc(-c4c5ccccc5c(-c5ccc6c(c5)sc5c7ccccc7c7ccccc7c65)c5ccccc45)cc3)nc3ccccc32)cc1]

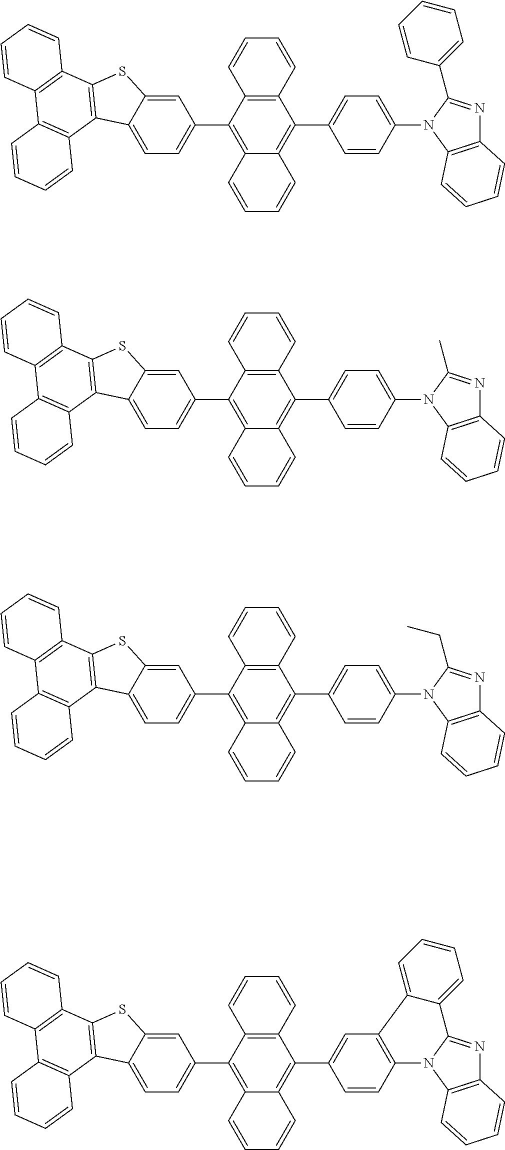 [SMILES: c1ccc(-c2nc3ccccc3n2-c2ccc(-c3c4ccccc4c(-c4ccc5c(c4)sc4c6ccccc6c6ccccc6c54)c4ccccc34)cc2)cc1 ; Cc1nc2ccccc2n1-c1ccc(-c2c3ccccc3c(-c3ccc4c(c3)sc3c5ccccc5c5ccccc5c43)c3ccccc23)cc1 ; CCc1nc2ccccc2n1-c1ccc(-c2c3ccccc3c(-c3ccc4c(c3)sc3c5ccccc5c5ccccc5c43)c3ccccc23)cc1 ; c1ccc2c(c1)nc1c3ccccc3c3cc(-c4c5ccccc5c(-c5ccc6c(c5)sc5c7ccccc7c7ccccc7c65)c5ccccc45)ccc3n21]

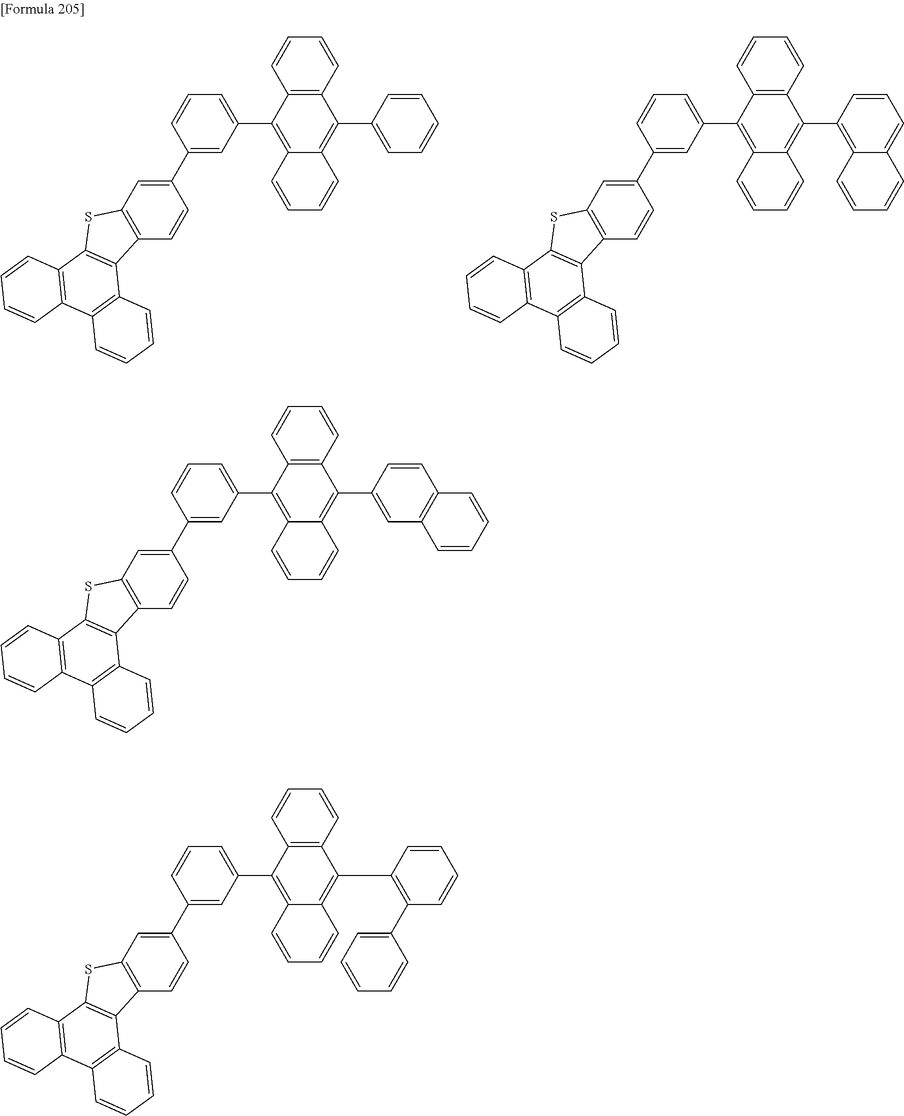 [SMILES: c1ccc(-c2c3ccccc3c(-c3cccc(-c4ccc5c(c4)sc4c6ccccc6c6ccccc6c54)c3)c3ccccc23)cc1 ; c1cc(-c2ccc3c(c2)sc2c4ccccc4c4ccccc4c32)cc(-c2c3ccccc3c(-c3cccc4ccccc34)c3ccccc23)c1 ; c1cc(-c2ccc3c(c2)sc2c4ccccc4c4ccccc4c32)cc(-c2c3ccccc3c(-c3ccc4ccccc4c3)c3ccccc23)c1 ; c1ccc(-c2ccccc2-c2c3ccccc3c(-c3cccc(-c4ccc5c(c4)sc4c6ccccc6c6ccccc6c54)c3)c3ccccc23)cc1]

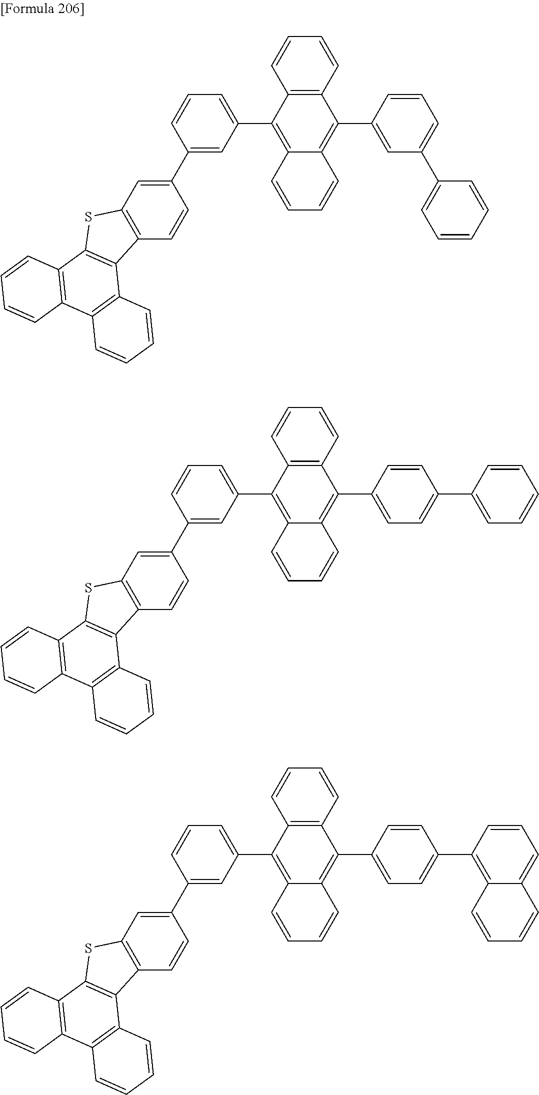 [SMILES: c1ccc(-c2cccc(-c3c4ccccc4c(-c4cccc(-c5ccc6c(c5)sc5c7ccccc7c7ccccc7c65)c4)c4ccccc34)c2)cc1 ; c1ccc(-c2ccc(-c3c4ccccc4c(-c4cccc(-c5ccc6c(c5)sc5c7ccccc7c7ccccc7c65)c4)c4ccccc34)cc2)cc1 ; c1cc(-c2ccc3c(c2)sc2c4ccccc4c4ccccc4c32)cc(-c2c3ccccc3c(-c3ccc(-c4cccc5ccccc45)cc3)c3ccccc23)c1]

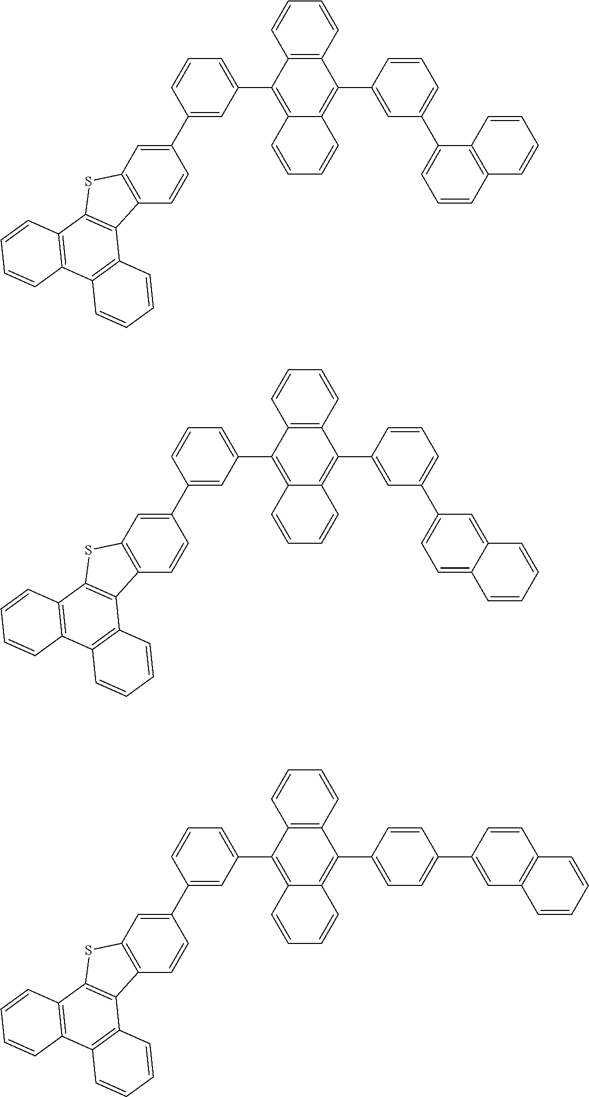 [SMILES: c1cc(-c2ccc3c(c2)sc2c4ccccc4c4ccccc4c32)cc(-c2c3ccccc3c(-c3cccc(-c4cccc5ccccc45)c3)c3ccccc23)c1 ; c1cc(-c2ccc3ccccc3c2)cc(-c2c3ccccc3c(-c3cccc(-c4ccc5c(c4)sc4c6ccccc6c6ccccc6c54)c3)c3ccccc23)c1 ; c1cc(-c2ccc3c(c2)sc2c4ccccc4c4ccccc4c32)cc(-c2c3ccccc3c(-c3ccc(-c4ccc5ccccc5c4)cc3)c3ccccc23)c1]

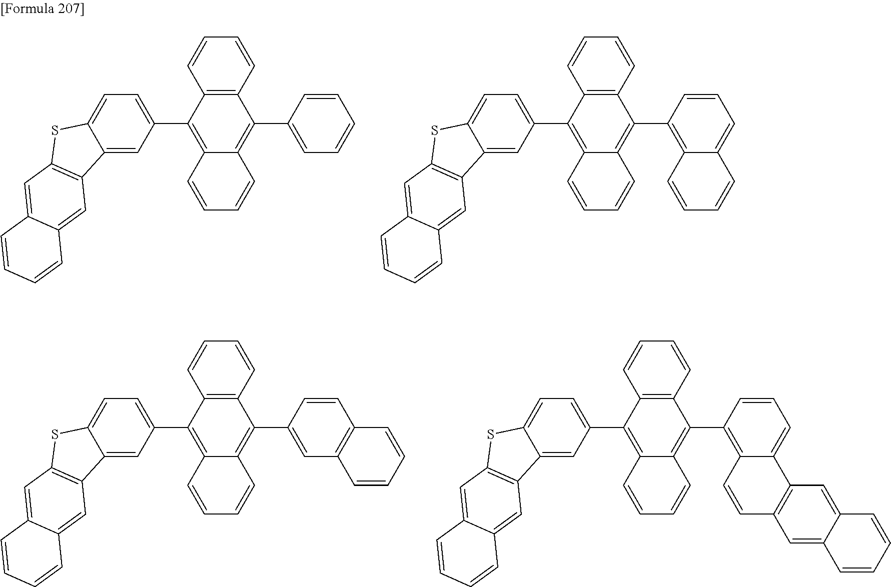 [SMILES: c1ccc(-c2c3ccccc3c(-c3ccc4sc5cc6ccccc6cc5c4c3)c3ccccc23)cc1 ; c1ccc2cc3c(cc2c1)sc1ccc(-c2c4ccccc4c(-c4cccc5ccccc45)c4ccccc24)cc13 ; c1ccc2cc(-c3c4ccccc4c(-c4ccc5sc6cc7ccccc7cc6c5c4)c4ccccc34)ccc2c1 ; c1ccc2cc3c(ccc4c(-c5c6ccccc6c(-c6ccc7sc8cc9ccccc9cc8c7c6)c6ccccc56)cccc43)cc2c1]

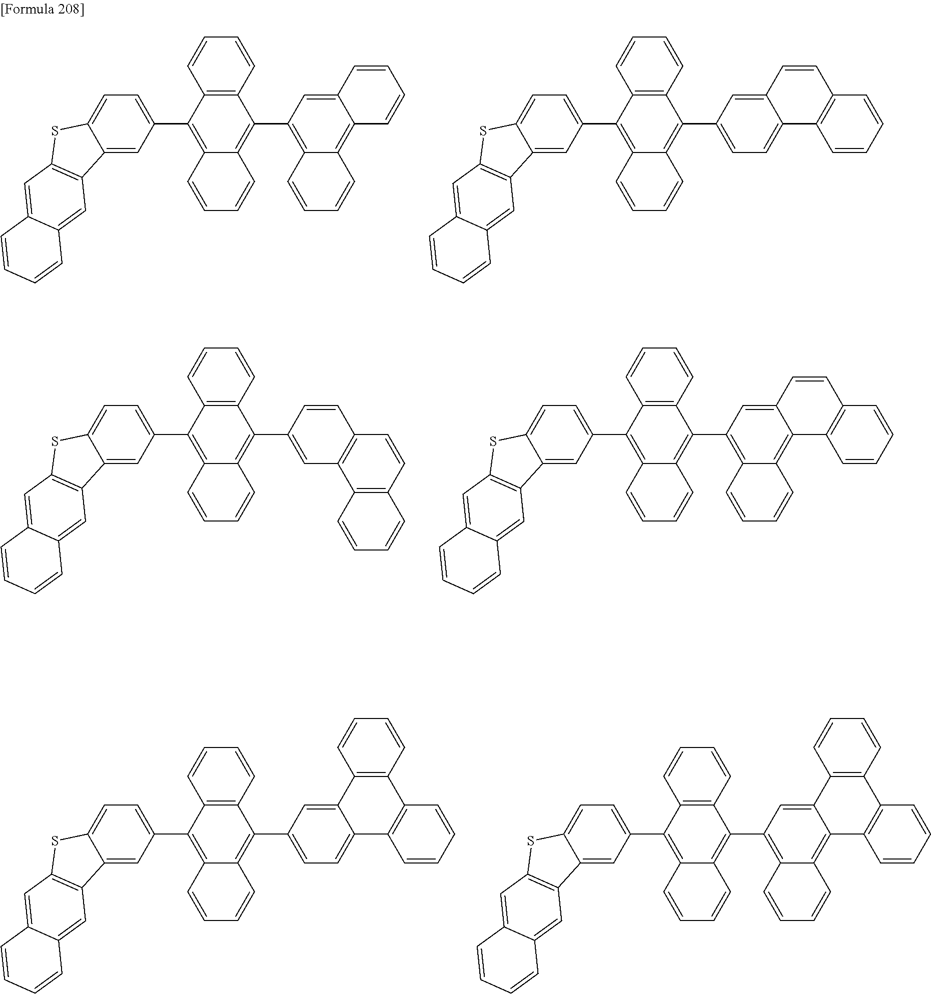

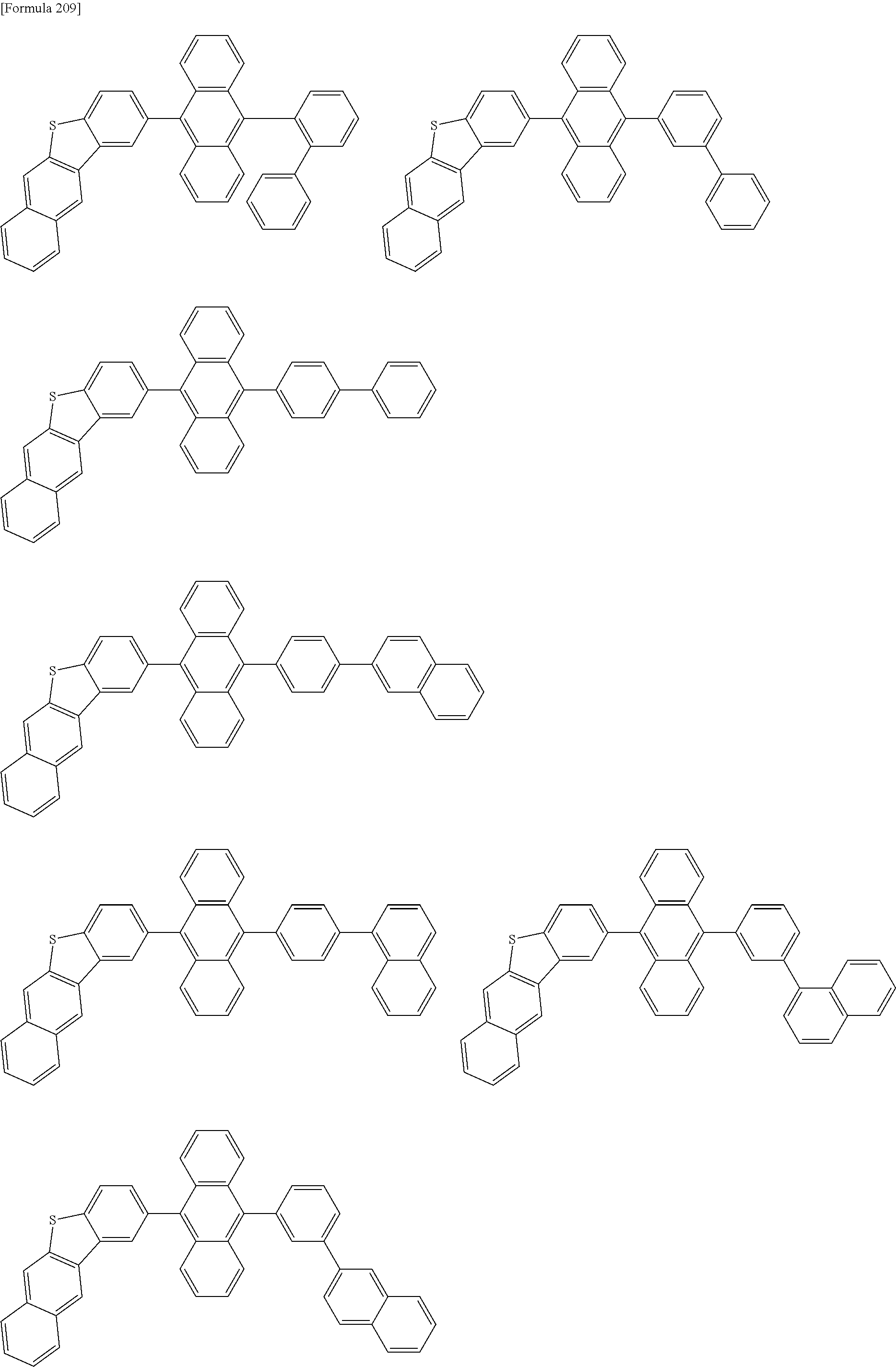

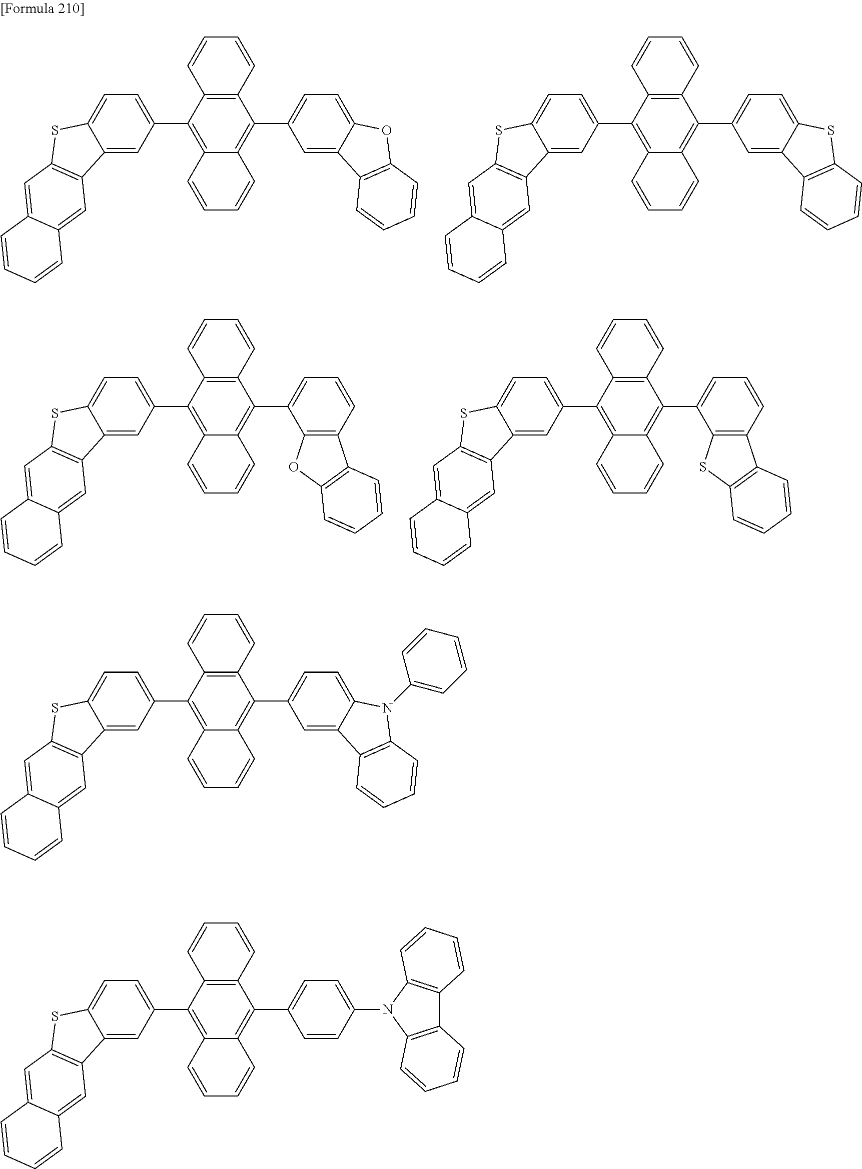

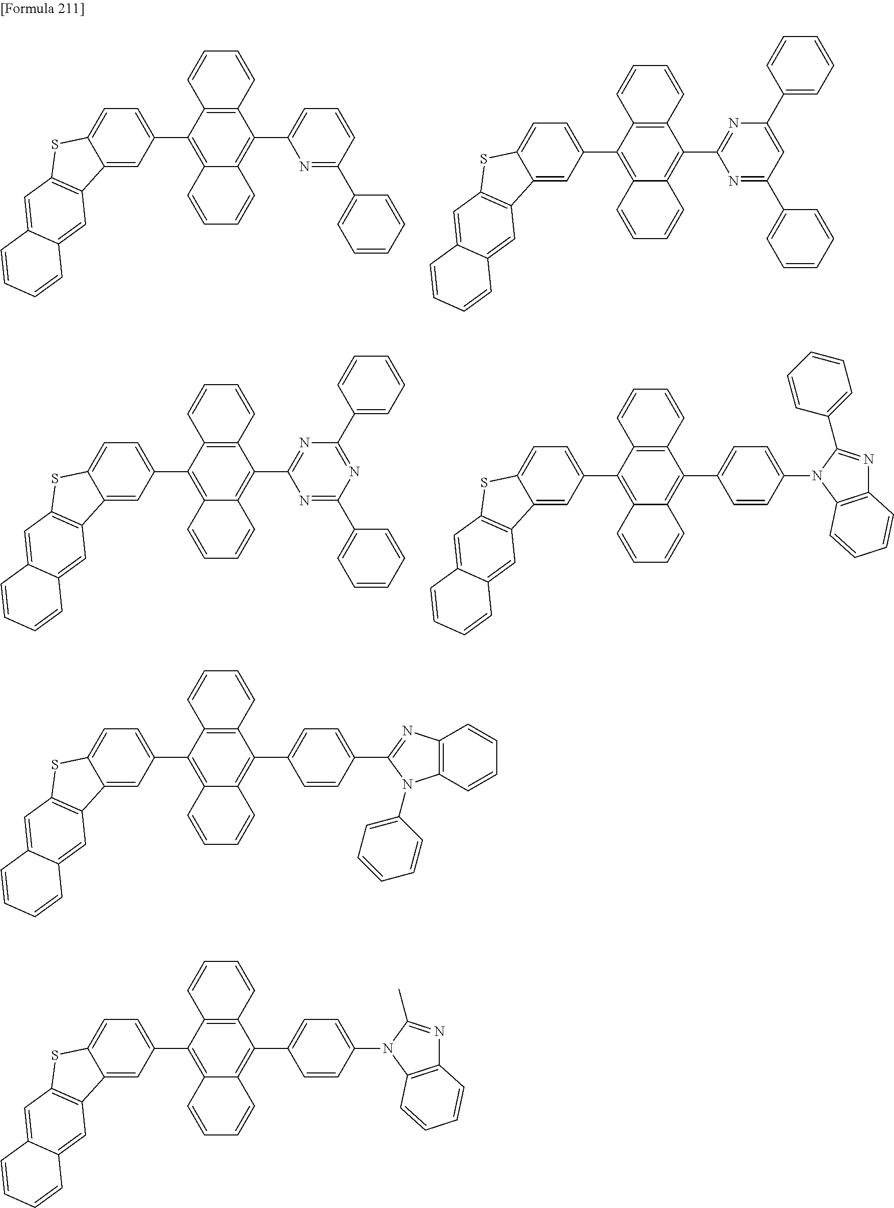

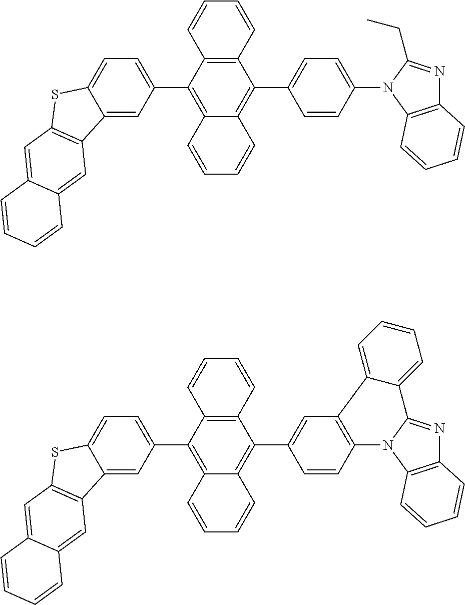 [SMILES: CCc1nc2ccccc2n1-c1ccc(-c2c3ccccc3c(-c3ccc4sc5cc6ccccc6cc5c4c3)c3ccccc23)cc1 ; c1ccc2cc3c(cc2c1)sc1ccc(-c2c4ccccc4c(-c4ccc5c(c4)c4ccccc4c4nc6ccccc6n54)c4ccccc24)cc13]

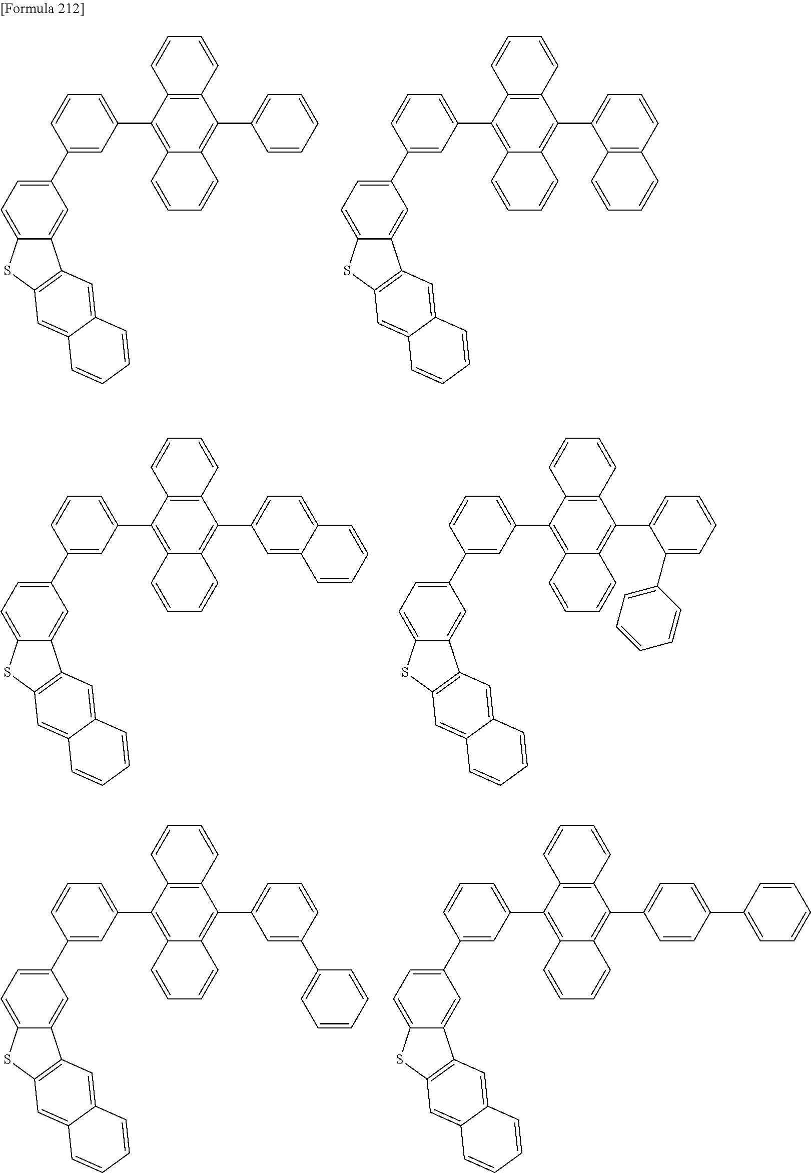

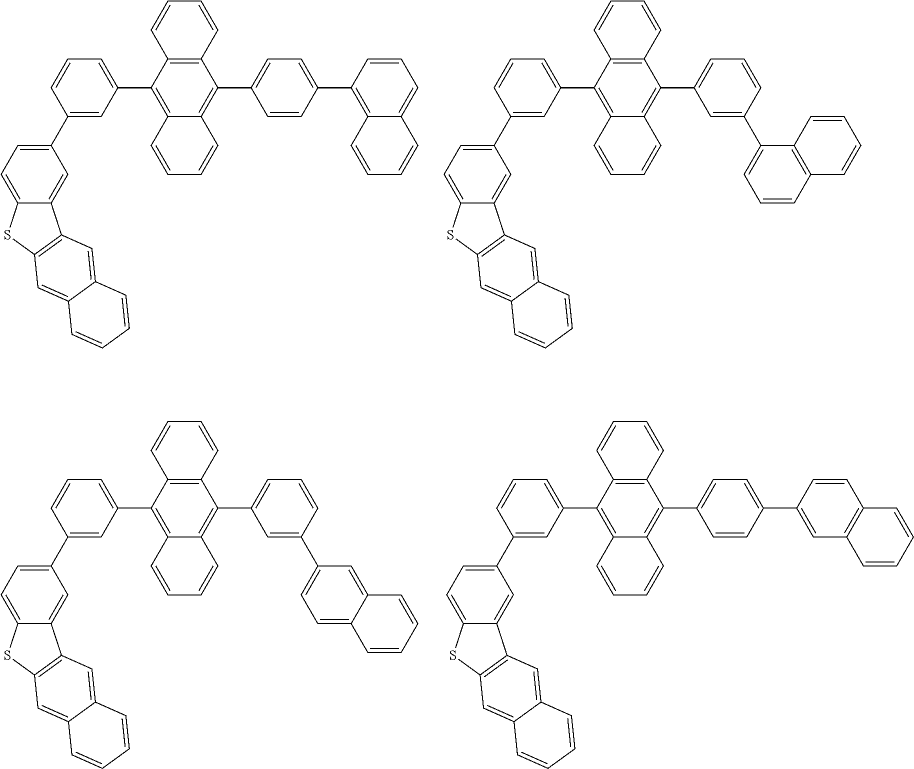

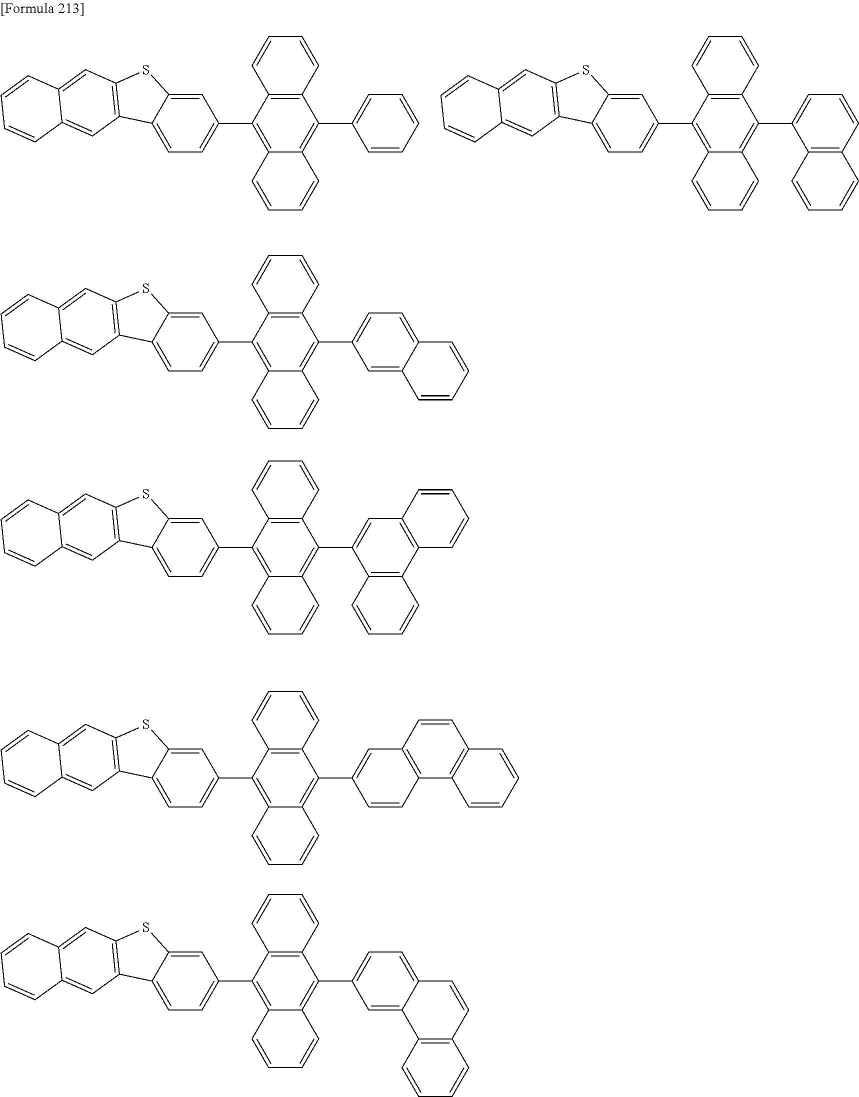

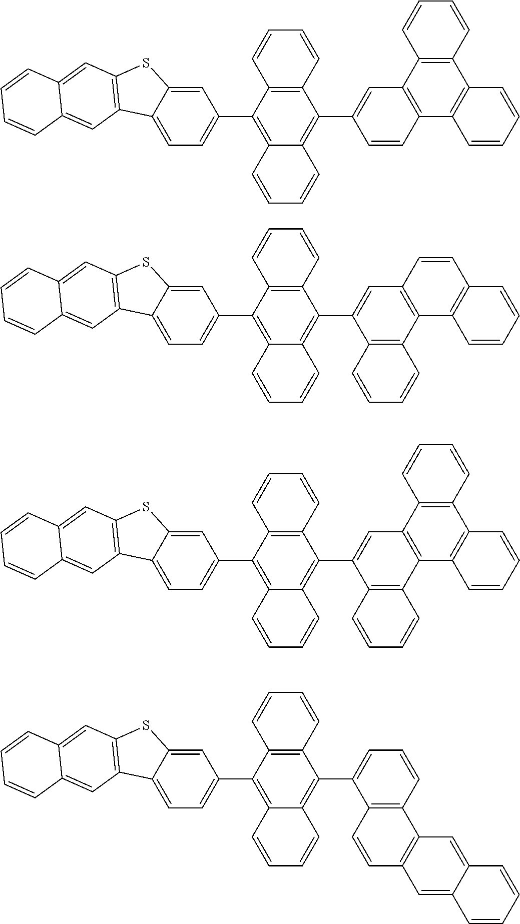

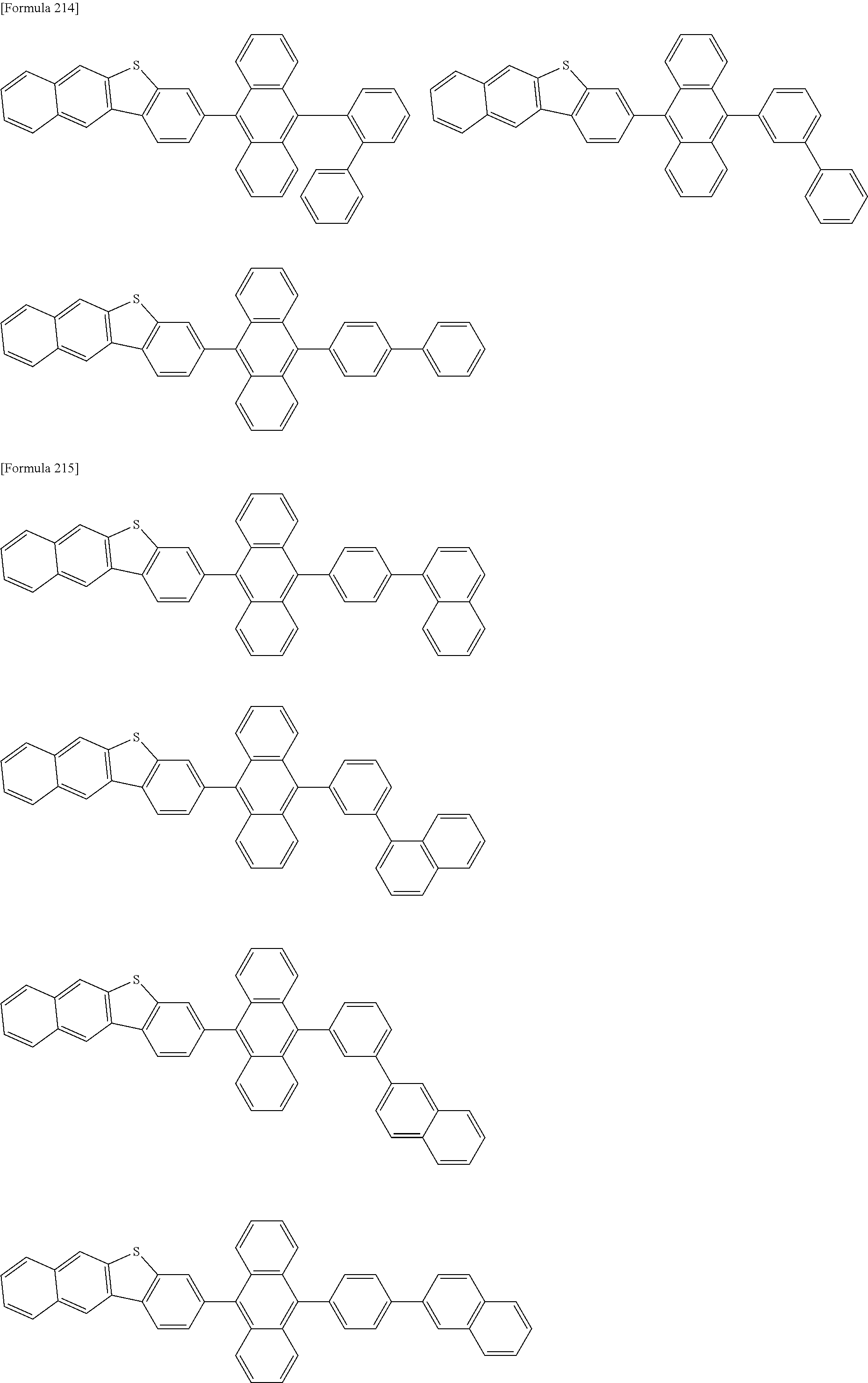

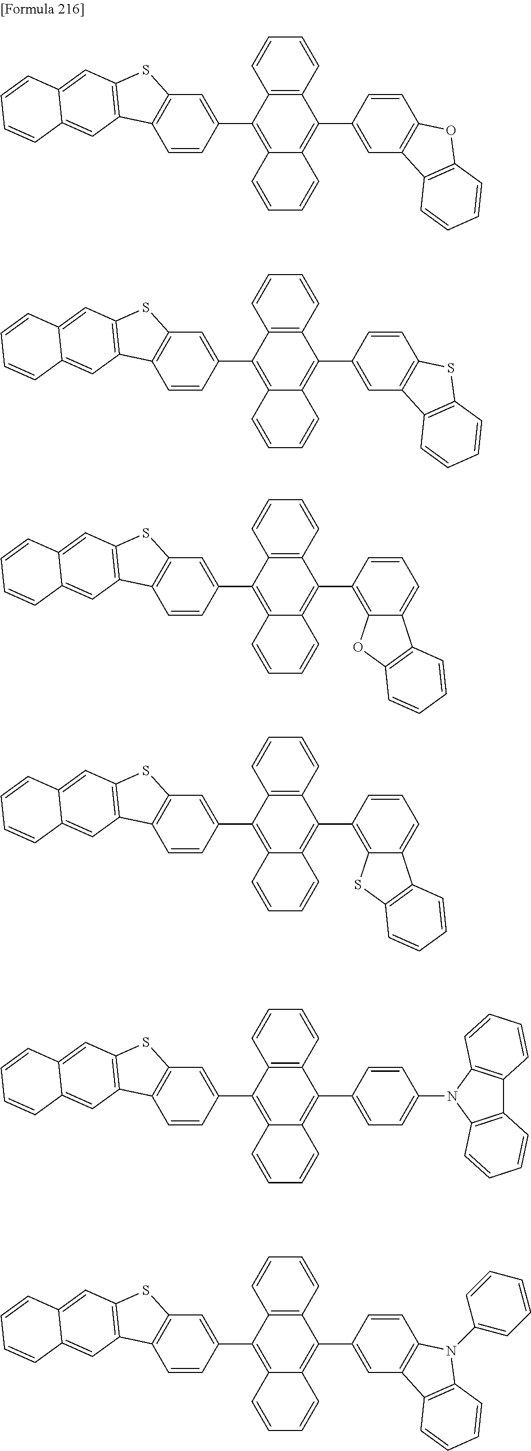 [SMILES: c1ccc2cc3c(cc2c1)sc1cc(-c2c4ccccc4c(-c4ccc5oc6ccccc6c5c4)c4ccccc24)ccc13 ; c1ccc2cc3c(cc2c1)sc1cc(-c2c4ccccc4c(-c4ccc5sc6ccccc6c5c4)c4ccccc24)ccc13 ; c1ccc2cc3c(cc2c1)sc1cc(-c2c4ccccc4c(-c4cccc5c4oc4ccccc45)c4ccccc24)ccc13 ; c1ccc2cc3c(cc2c1)sc1cc(-c2c4ccccc4c(-c4cccc5c4sc4ccccc45)c4ccccc24)ccc13 ; c1ccc2cc3c(cc2c1)sc1cc(-c2c4ccccc4c(-c4ccc(-n5c6ccccc6c6ccccc65)cc4)c4ccccc24)ccc13 ; c1ccc(-n2c3ccccc3c3cc(-c4c5ccccc5c(-c5ccc6c(c5)sc5cc7ccccc7cc56)c5ccccc45)ccc32)cc1]

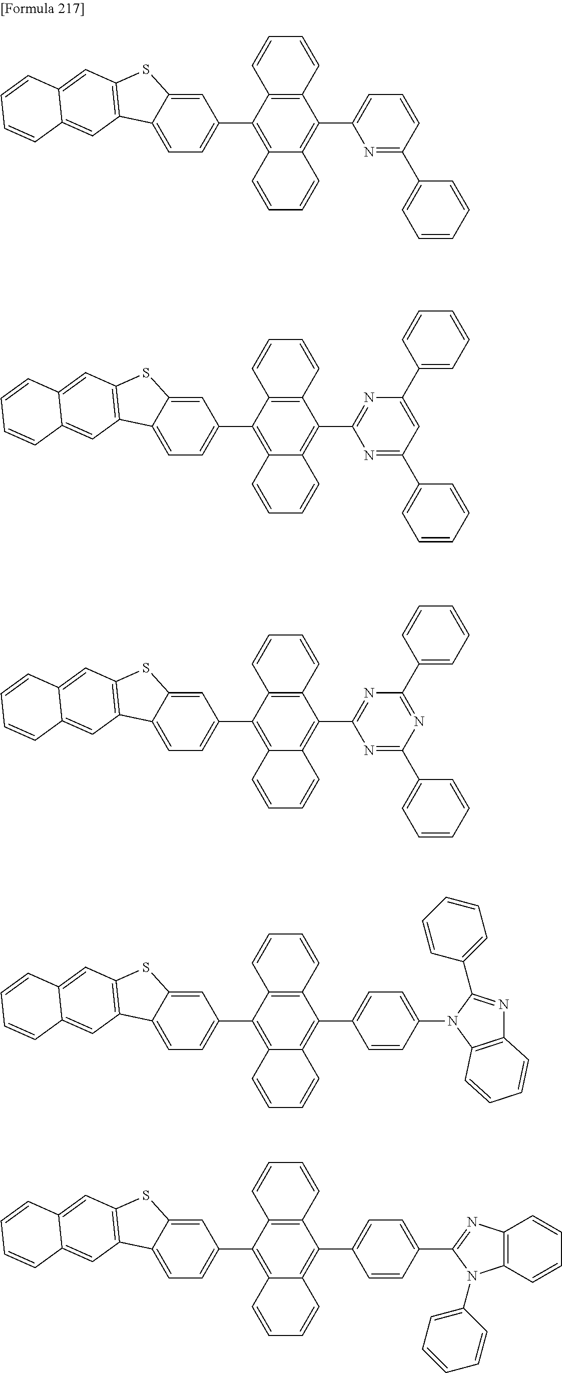 [SMILES: c1ccc(-c2cccc(-c3c4ccccc4c(-c4ccc5c(c4)sc4cc6ccccc6cc45)c4ccccc34)n2)cc1 ; c1ccc(-c2cc(-c3ccccc3)nc(-c3c4ccccc4c(-c4ccc5c(c4)sc4cc6ccccc6cc45)c4ccccc34)n2)cc1 ; c1ccc(-c2nc(-c3ccccc3)nc(-c3c4ccccc4c(-c4ccc5c(c4)sc4cc6ccccc6cc45)c4ccccc34)n2)cc1 ; c1ccc(-c2nc3ccccc3n2-c2ccc(-c3c4ccccc4c(-c4ccc5c(c4)sc4cc6ccccc6cc45)c4ccccc34)cc2)cc1 ; c1ccc(-n2c(-c3ccc(-c4c5ccccc5c(-c5ccc6c(c5)sc5cc7ccccc7cc56)c5ccccc45)cc3)nc3ccccc32)cc1]

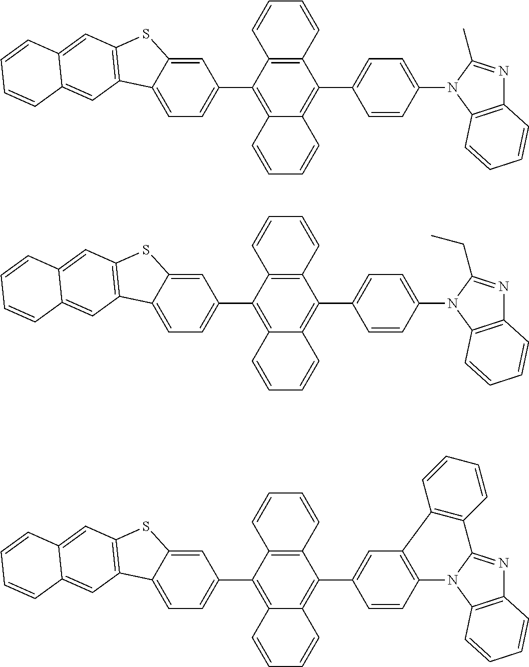

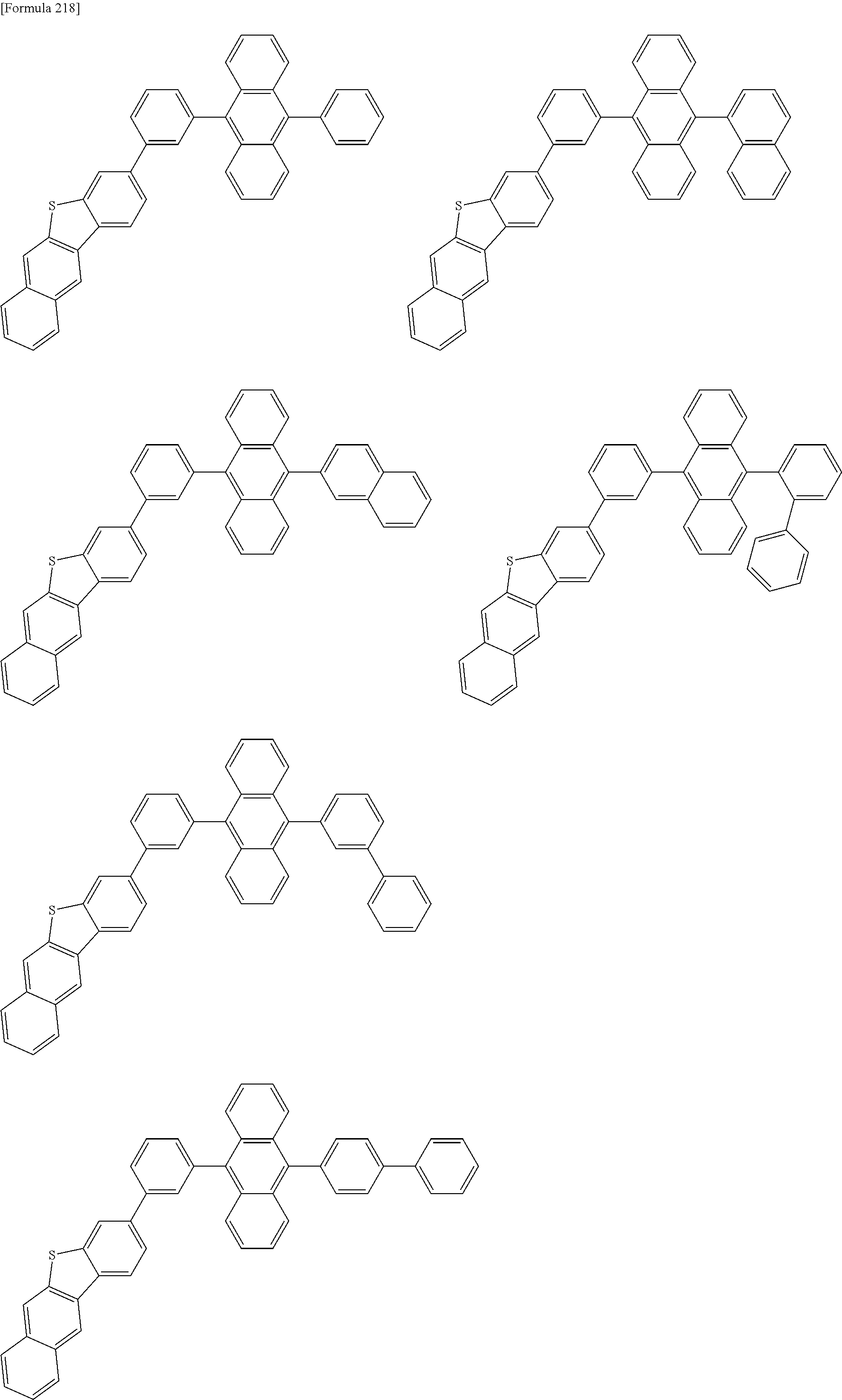 [SMILES: c1ccc(-c2c3ccccc3c(-c3cccc(-c4ccc5c(c4)sc4cc6ccccc6cc45)c3)c3ccccc23)cc1 ; c1cc(-c2ccc3c(c2)sc2cc4ccccc4cc23)cc(-c2c3ccccc3c(-c3cccc4ccccc34)c3ccccc23)c1 ; c1cc(-c2ccc3c(c2)sc2cc4ccccc4cc23)cc(-c2c3ccccc3c(-c3ccc4ccccc4c3)c3ccccc23)c1 ; c1ccc(-c2ccccc2-c2c3ccccc3c(-c3cccc(-c4ccc5c(c4)sc4cc6ccccc6cc45)c3)c3ccccc23)cc1 ; c1ccc(-c2cccc(-c3c4ccccc4c(-c4cccc(-c5ccc6c(c5)sc5cc7ccccc7cc56)c4)c4ccccc34)c2)cc1 ; c1ccc(-c2ccc(-c3c4ccccc4c(-c4cccc(-c5ccc6c(c5)sc5cc7ccccc7cc56)c4)c4ccccc34)cc2)cc1]

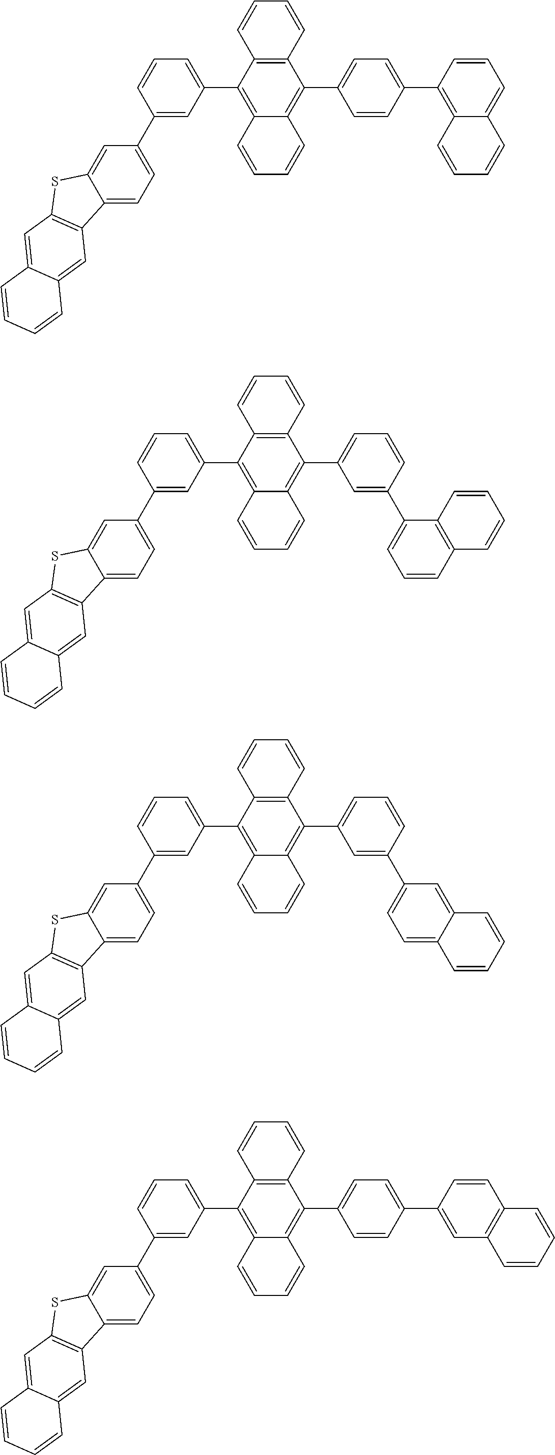 [SMILES: c1cc(-c2ccc3c(c2)sc2cc4ccccc4cc23)cc(-c2c3ccccc3c(-c3ccc(-c4cccc5ccccc45)cc3)c3ccccc23)c1 ; c1cc(-c2ccc3c(c2)sc2cc4ccccc4cc23)cc(-c2c3ccccc3c(-c3cccc(-c4cccc5ccccc45)c3)c3ccccc23)c1 ; c1cc(-c2ccc3ccccc3c2)cc(-c2c3ccccc3c(-c3cccc(-c4ccc5c(c4)sc4cc6ccccc6cc45)c3)c3ccccc23)c1 ; c1cc(-c2ccc3c(c2)sc2cc4ccccc4cc23)cc(-c2c3ccccc3c(-c3ccc(-c4ccc5ccccc5c4)cc3)c3ccccc23)c1]

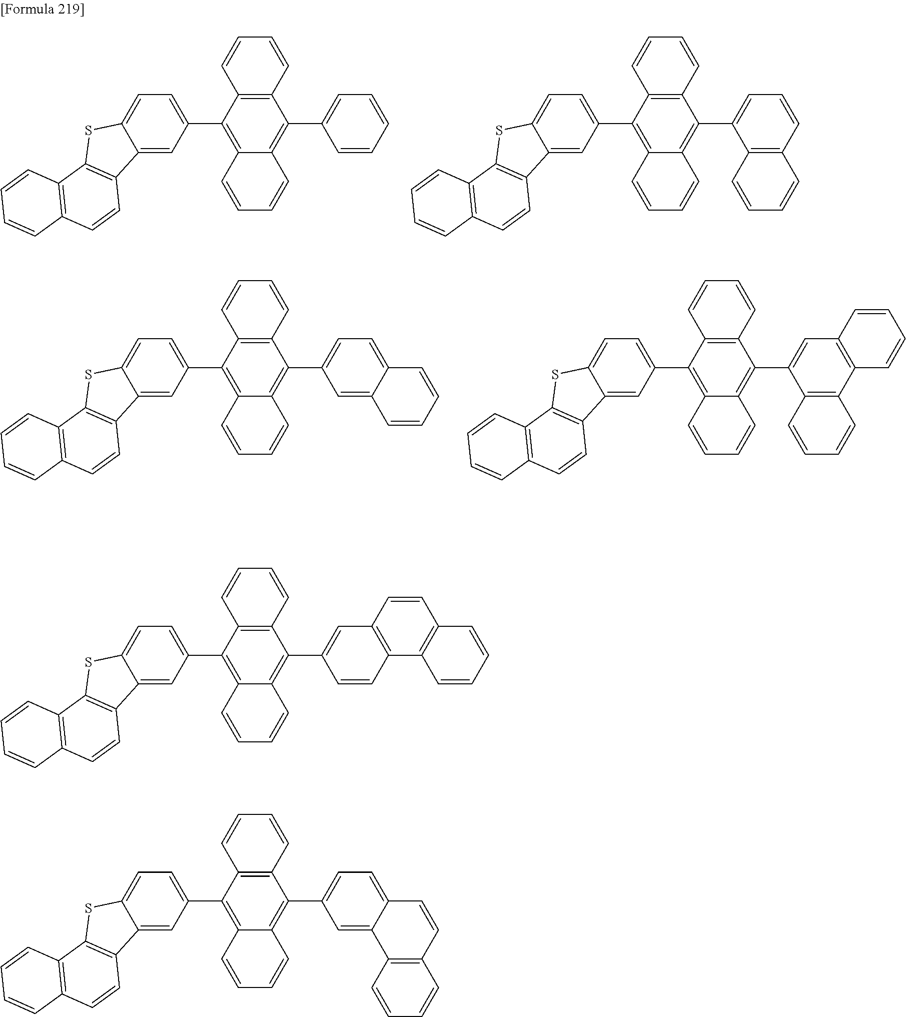

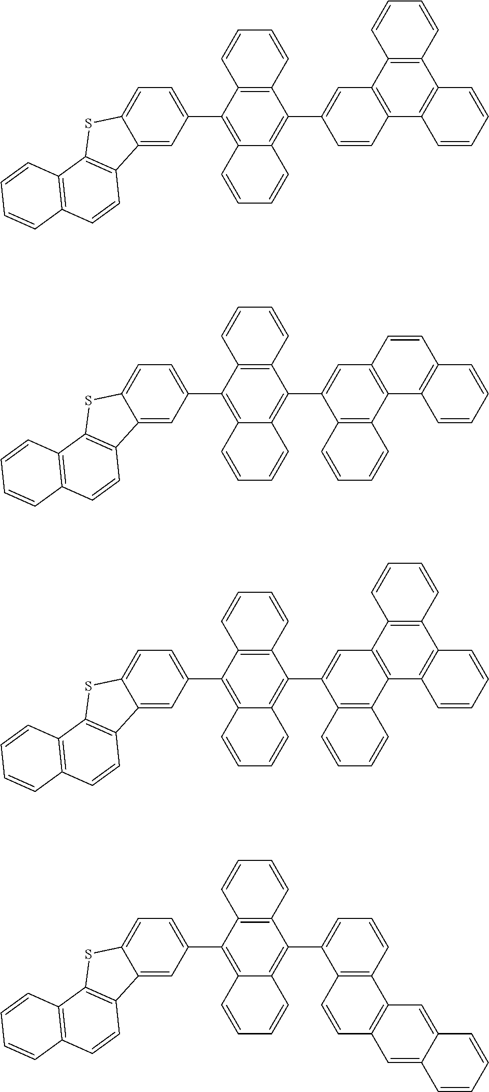 [SMILES: c1ccc2c(c1)ccc1c3cc(-c4c5ccccc5c(-c5ccc6c7ccccc7c7ccccc7c6c5)c5ccccc45)ccc3sc21 ; c1ccc2c(c1)ccc1c3cc(-c4c5ccccc5c(-c5cc6ccc7ccccc7c6c6ccccc56)c5ccccc45)ccc3sc21 ; c1ccc2c(c1)ccc1c3cc(-c4c5ccccc5c(-c5cc6c7ccccc7c7ccccc7c6c6ccccc56)c5ccccc45)ccc3sc21 ; c1ccc2cc3c(ccc4c(-c5c6ccccc6c(-c6ccc7sc8c9ccccc9ccc8c7c6)c6ccccc56)cccc43)cc2c1]

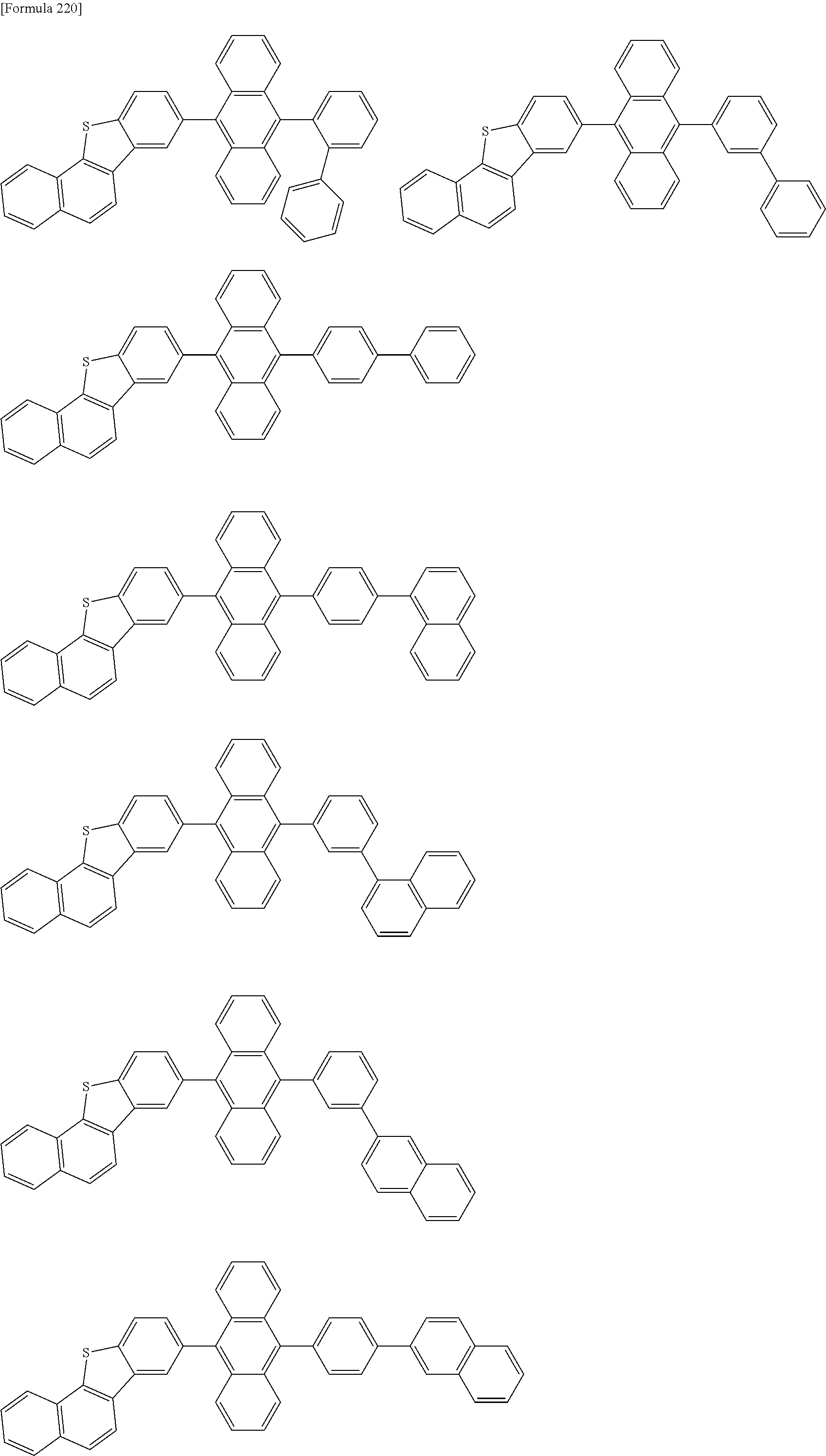

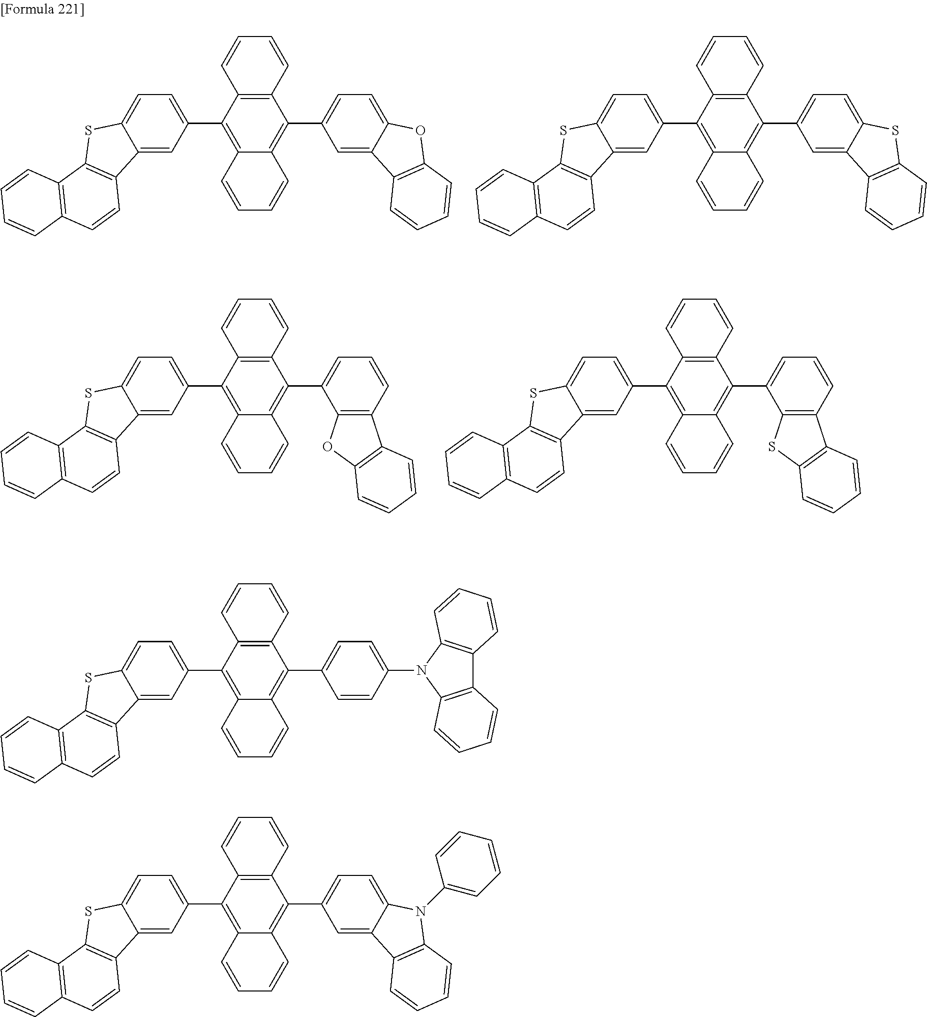

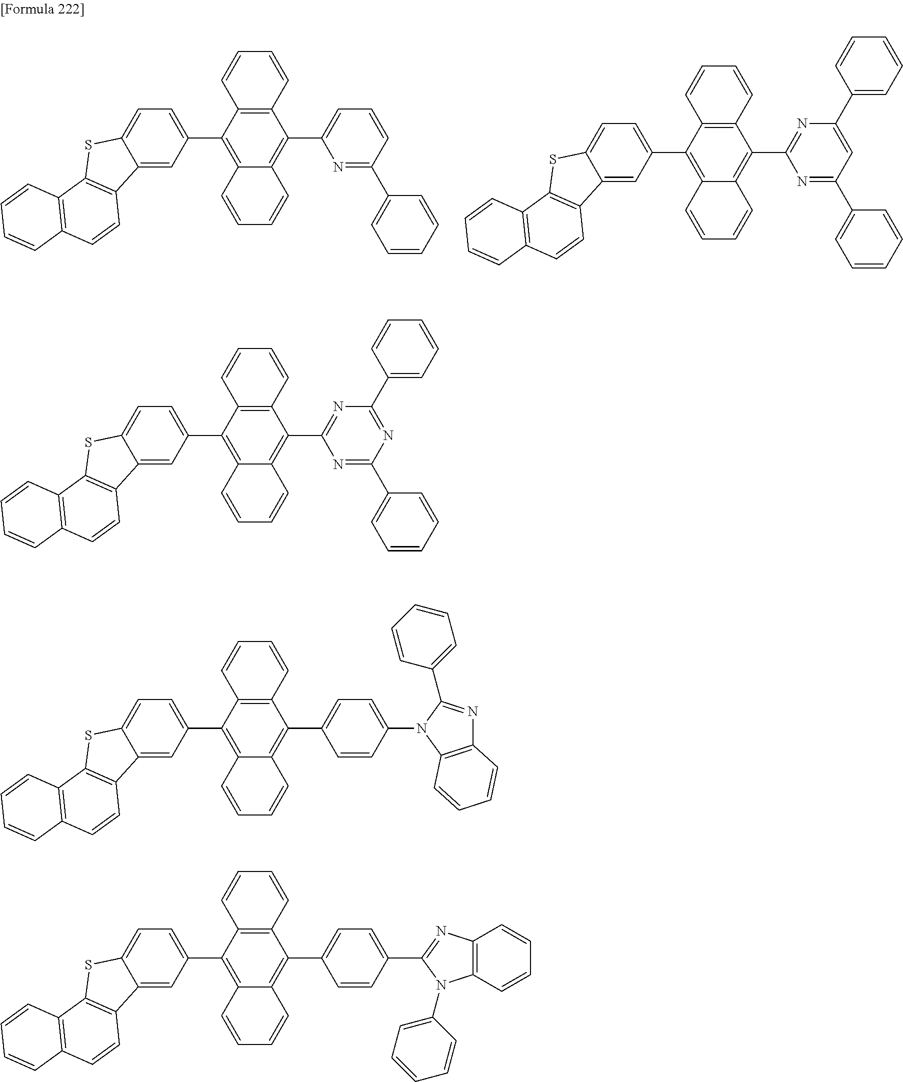

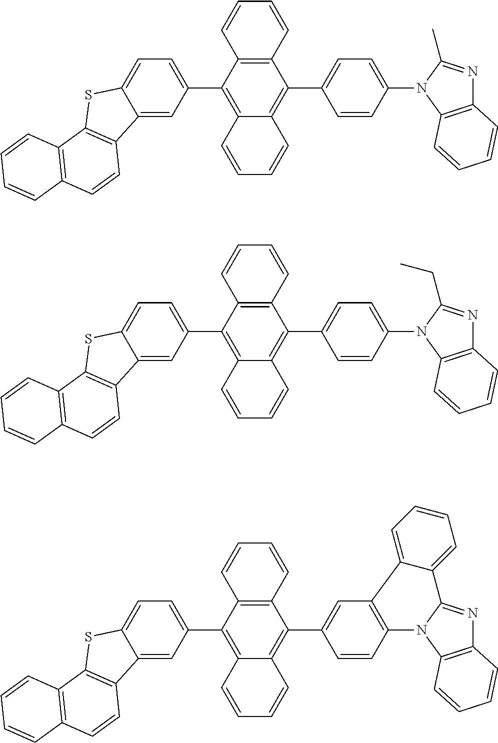 [SMILES: Cc1nc2ccccc2n1-c1ccc(-c2c3ccccc3c(-c3ccc4sc5c6ccccc6ccc5c4c3)c3ccccc23)cc1 ; CCc1nc2ccccc2n1-c1ccc(-c2c3ccccc3c(-c3ccc4sc5c6ccccc6ccc5c4c3)c3ccccc23)cc1 ; c1ccc2c(c1)ccc1c3cc(-c4c5ccccc5c(-c5ccc6c(c5)c5ccccc5c5nc7ccccc7n65)c5ccccc45)ccc3sc21]

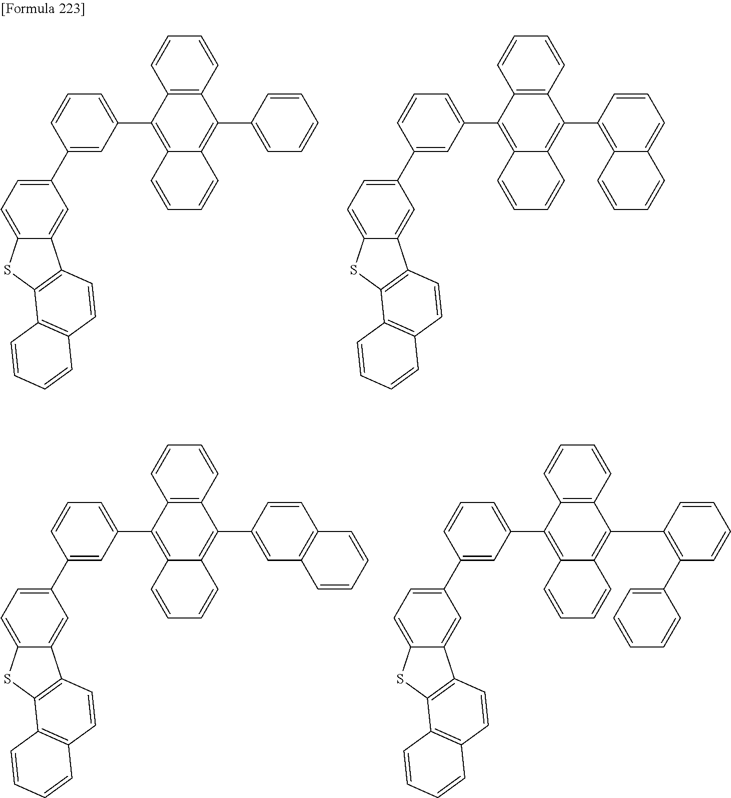 [SMILES: c1ccc(-c2c3ccccc3c(-c3cccc(-c4ccc5sc6c7ccccc7ccc6c5c4)c3)c3ccccc23)cc1 ; c1cc(-c2ccc3sc4c5ccccc5ccc4c3c2)cc(-c2c3ccccc3c(-c3cccc4ccccc34)c3ccccc23)c1 ; c1cc(-c2ccc3sc4c5ccccc5ccc4c3c2)cc(-c2c3ccccc3c(-c3ccc4ccccc4c3)c3ccccc23)c1 ; c1ccc(-c2ccccc2-c2c3ccccc3c(-c3cccc(-c4ccc5sc6c7ccccc7ccc6c5c4)c3)c3ccccc23)cc1]

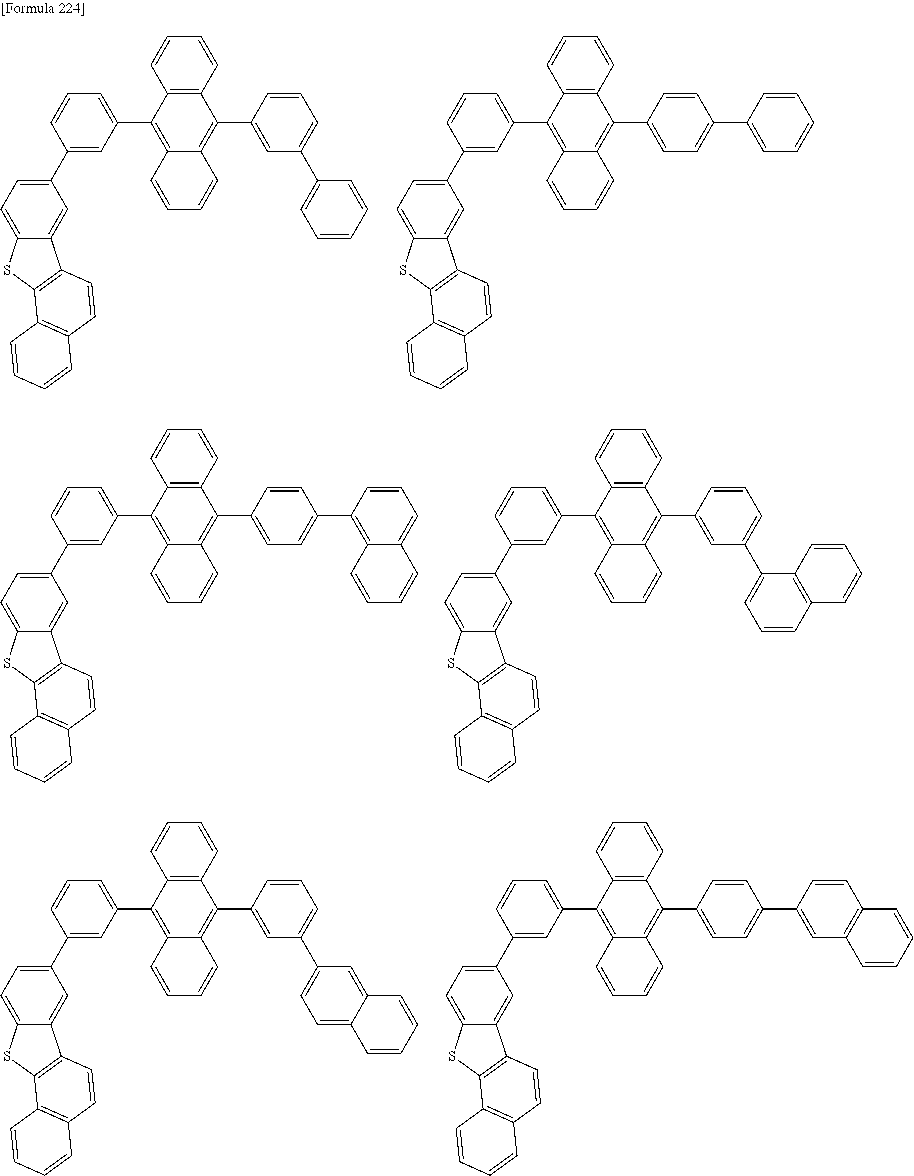

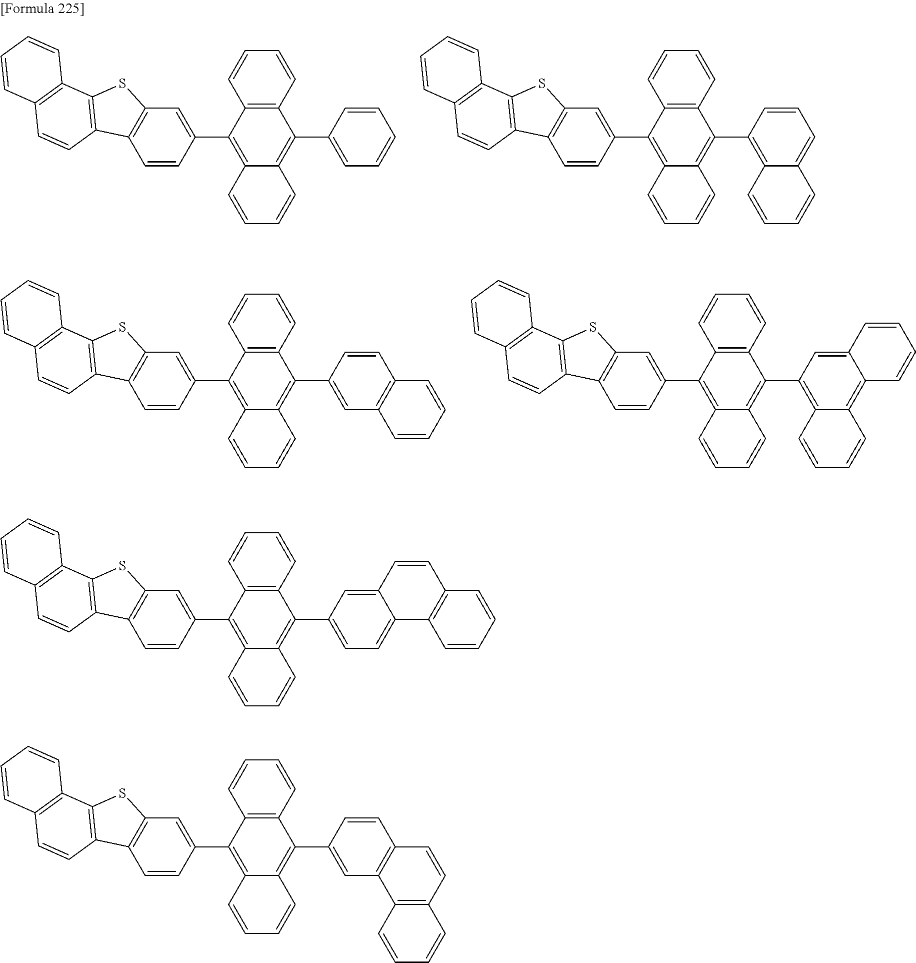 [SMILES: c1ccc(-c2c3ccccc3c(-c3ccc4c(c3)sc3c5ccccc5ccc43)c3ccccc23)cc1 ; c1ccc2c(-c3c4ccccc4c(-c4ccc5c(c4)sc4c6ccccc6ccc54)c4ccccc34)cccc2c1 ; c1ccc2cc(-c3c4ccccc4c(-c4ccc5c(c4)sc4c6ccccc6ccc54)c4ccccc34)ccc2c1 ; c1ccc2c(c1)cc(-c1c3ccccc3c(-c3ccc4c(c3)sc3c5ccccc5ccc43)c3ccccc13)c1ccccc12 ; c1ccc2c(c1)ccc1cc(-c3c4ccccc4c(-c4ccc5c(c4)sc4c6ccccc6ccc54)c4ccccc34)ccc12 ; c1ccc2c(c1)ccc1ccc(-c3c4ccccc4c(-c4ccc5c(c4)sc4c6ccccc6ccc54)c4ccccc34)cc12]

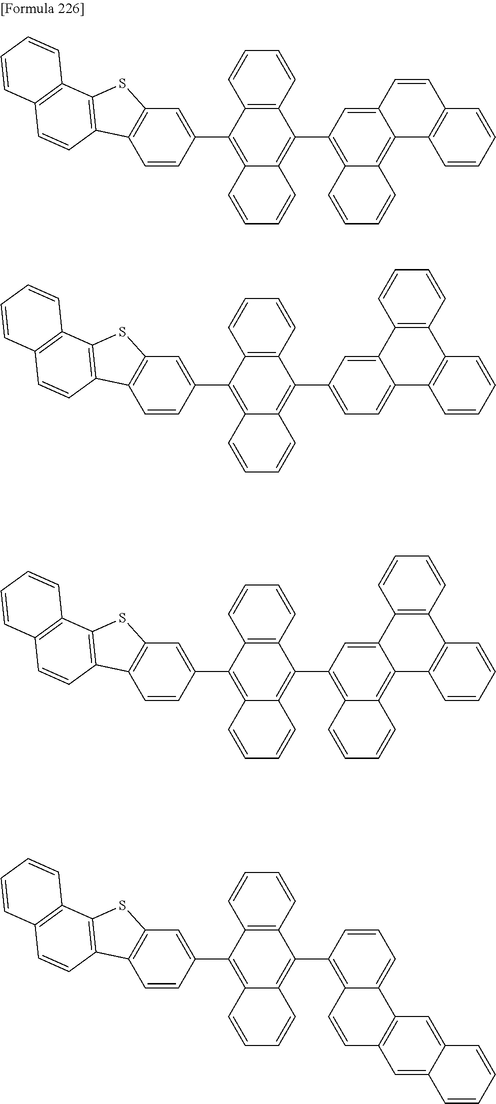 [SMILES: c1ccc2c(c1)ccc1c3ccc(-c4c5ccccc5c(-c5cc6ccc7ccccc7c6c6ccccc56)c5ccccc45)cc3sc21 ; c1ccc2c(c1)ccc1c3ccc(-c4c5ccccc5c(-c5ccc6c7ccccc7c7ccccc7c6c5)c5ccccc45)cc3sc21 ; c1ccc2c(c1)ccc1c3ccc(-c4c5ccccc5c(-c5cc6c7ccccc7c7ccccc7c6c6ccccc56)c5ccccc45)cc3sc21 ; c1ccc2cc3c(ccc4c(-c5c6ccccc6c(-c6ccc7c(c6)sc6c8ccccc8ccc76)c6ccccc56)cccc43)cc2c1]

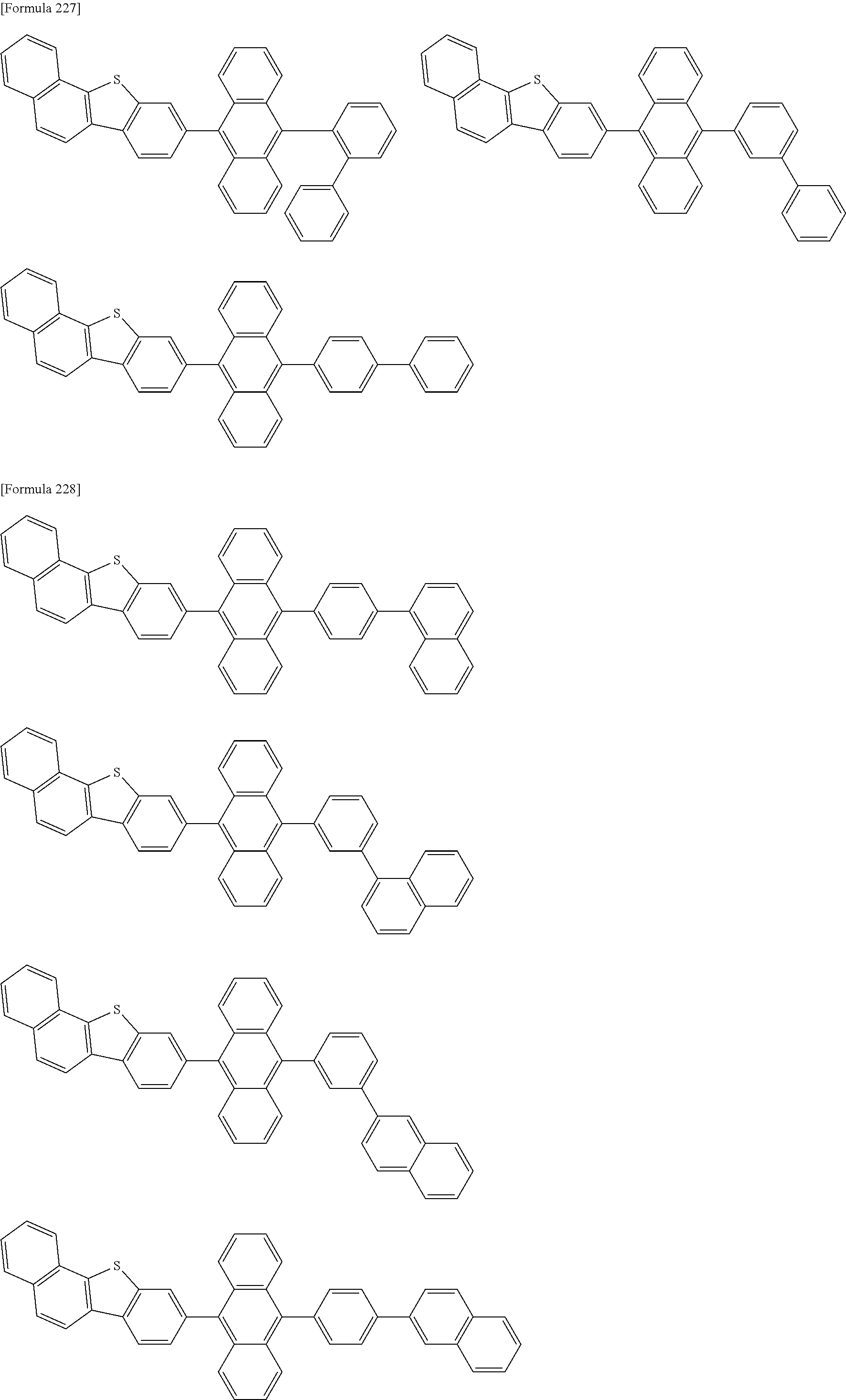

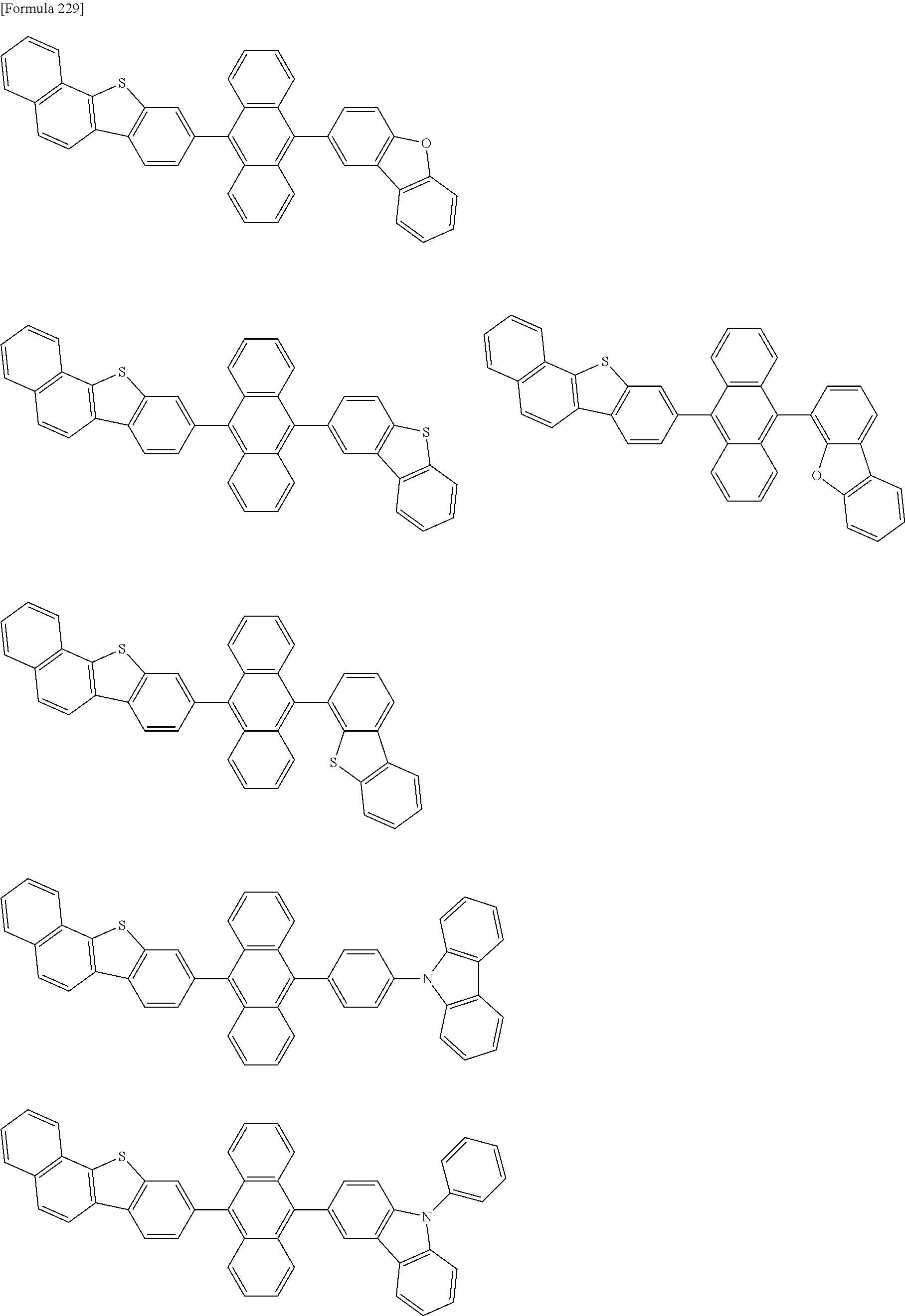 [SMILES: c1ccc2c(c1)ccc1c3ccc(-c4c5ccccc5c(-c5ccc6oc7ccccc7c6c5)c5ccccc45)cc3sc21 ; c1ccc2c(c1)ccc1c3ccc(-c4c5ccccc5c(-c5ccc6sc7ccccc7c6c5)c5ccccc45)cc3sc21 ; c1ccc2c(c1)ccc1c3ccc(-c4c5ccccc5c(-c5cccc6c5oc5ccccc56)c5ccccc45)cc3sc21 ; c1ccc2c(c1)ccc1c3ccc(-c4c5ccccc5c(-c5cccc6c5sc5ccccc56)c5ccccc45)cc3sc21 ; c1ccc2c(c1)ccc1c3ccc(-c4c5ccccc5c(-c5ccc(-n6c7ccccc7c7ccccc76)cc5)c5ccccc45)cc3sc21 ; c1ccc(-n2c3ccccc3c3cc(-c4c5ccccc5c(-c5ccc6c(c5)sc5c7ccccc7ccc65)c5ccccc45)ccc32)cc1]

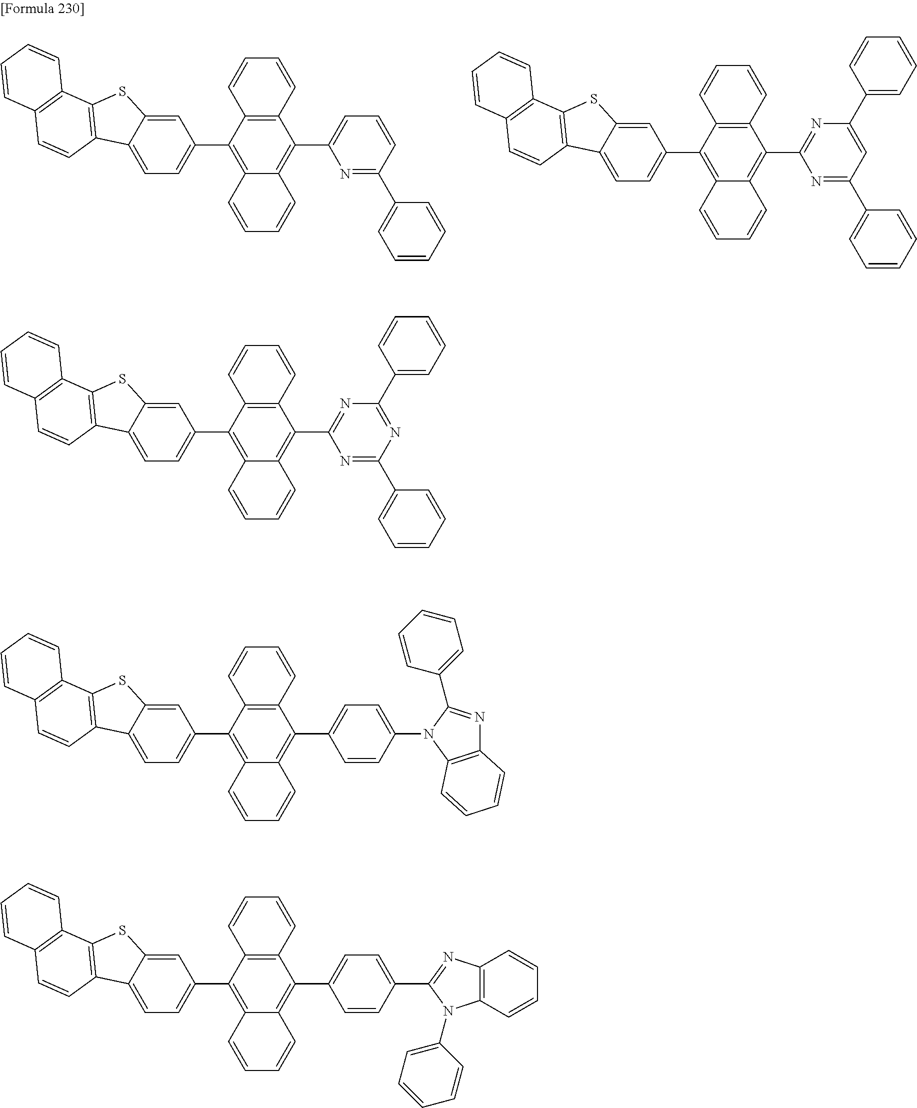 [SMILES: c1ccc(-c2cccc(-c3c4ccccc4c(-c4ccc5c(c4)sc4c6ccccc6ccc54)c4ccccc34)n2)cc1 ; c1ccc(-c2cc(-c3ccccc3)nc(-c3c4ccccc4c(-c4ccc5c(c4)sc4c6ccccc6ccc54)c4ccccc34)n2)cc1 ; c1ccc(-c2nc(-c3ccccc3)nc(-c3c4ccccc4c(-c4ccc5c(c4)sc4c6ccccc6ccc54)c4ccccc34)n2)cc1 ; c1ccc(-c2nc3ccccc3n2-c2ccc(-c3c4ccccc4c(-c4ccc5c(c4)sc4c6ccccc6ccc54)c4ccccc34)cc2)cc1 ; c1ccc(-n2c(-c3ccc(-c4c5ccccc5c(-c5ccc6c(c5)sc5c7ccccc7ccc65)c5ccccc45)cc3)nc3ccccc32)cc1]

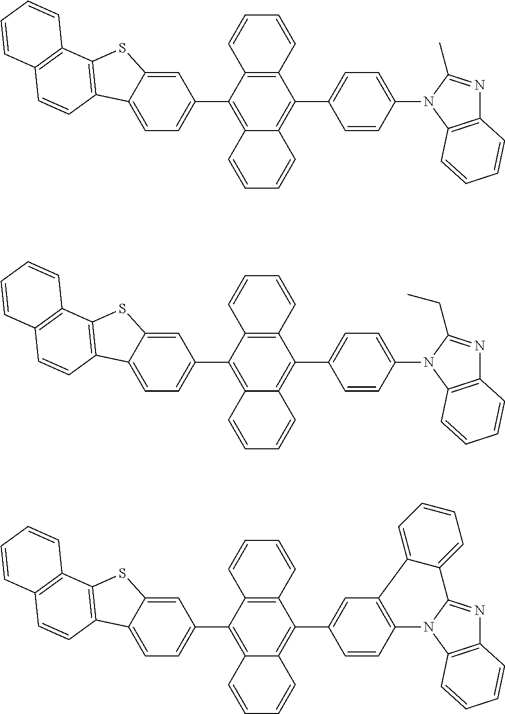 [SMILES: Cc1nc2ccccc2n1-c1ccc(-c2c3ccccc3c(-c3ccc4c(c3)sc3c5ccccc5ccc43)c3ccccc23)cc1 ; CCc1nc2ccccc2n1-c1ccc(-c2c3ccccc3c(-c3ccc4c(c3)sc3c5ccccc5ccc43)c3ccccc23)cc1 ; c1ccc2c(c1)ccc1c3ccc(-c4c5ccccc5c(-c5ccc6c(c5)c5ccccc5c5nc7ccccc7n65)c5ccccc45)cc3sc21]

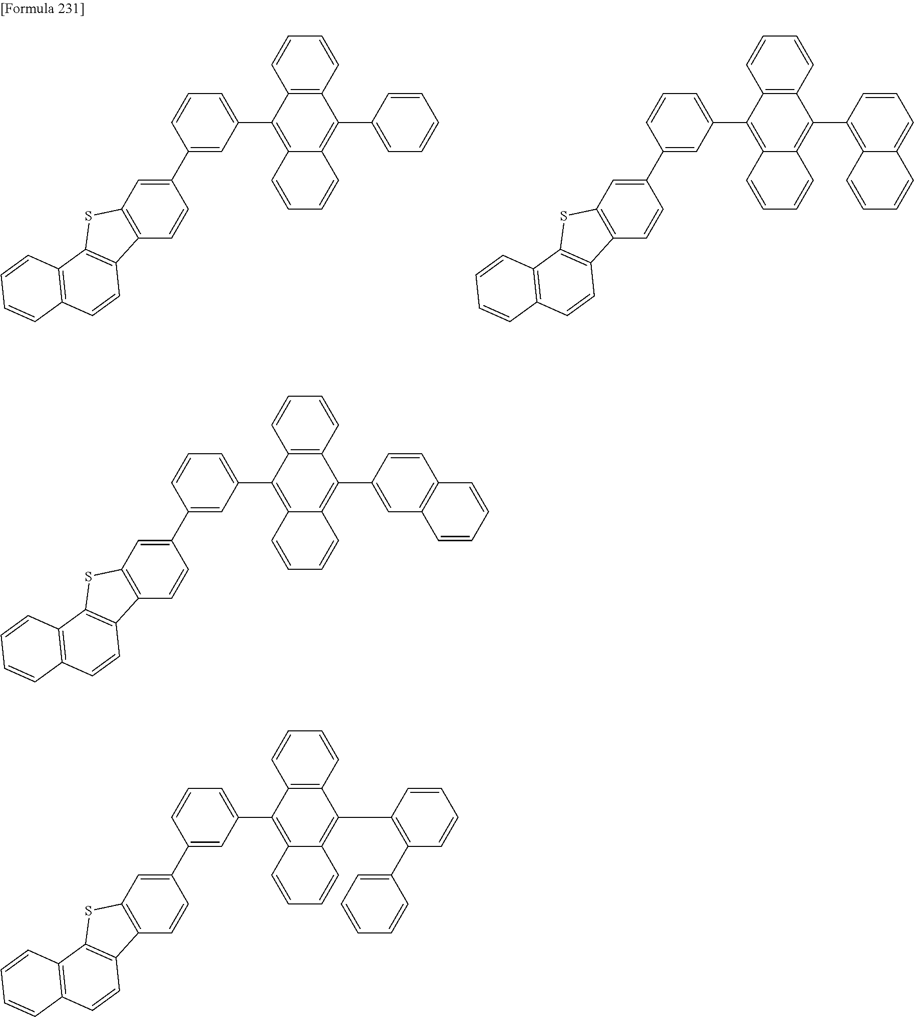 [SMILES: c1ccc(-c2c3ccccc3c(-c3cccc(-c4ccc5c(c4)sc4c6ccccc6ccc54)c3)c3ccccc23)cc1 ; c1cc(-c2ccc3c(c2)sc2c4ccccc4ccc32)cc(-c2c3ccccc3c(-c3cccc4ccccc34)c3ccccc23)c1 ; c1cc(-c2ccc3c(c2)sc2c4ccccc4ccc32)cc(-c2c3ccccc3c(-c3ccc4ccccc4c3)c3ccccc23)c1 ; c1ccc(-c2ccccc2-c2c3ccccc3c(-c3cccc(-c4ccc5c(c4)sc4c6ccccc6ccc54)c3)c3ccccc23)cc1]

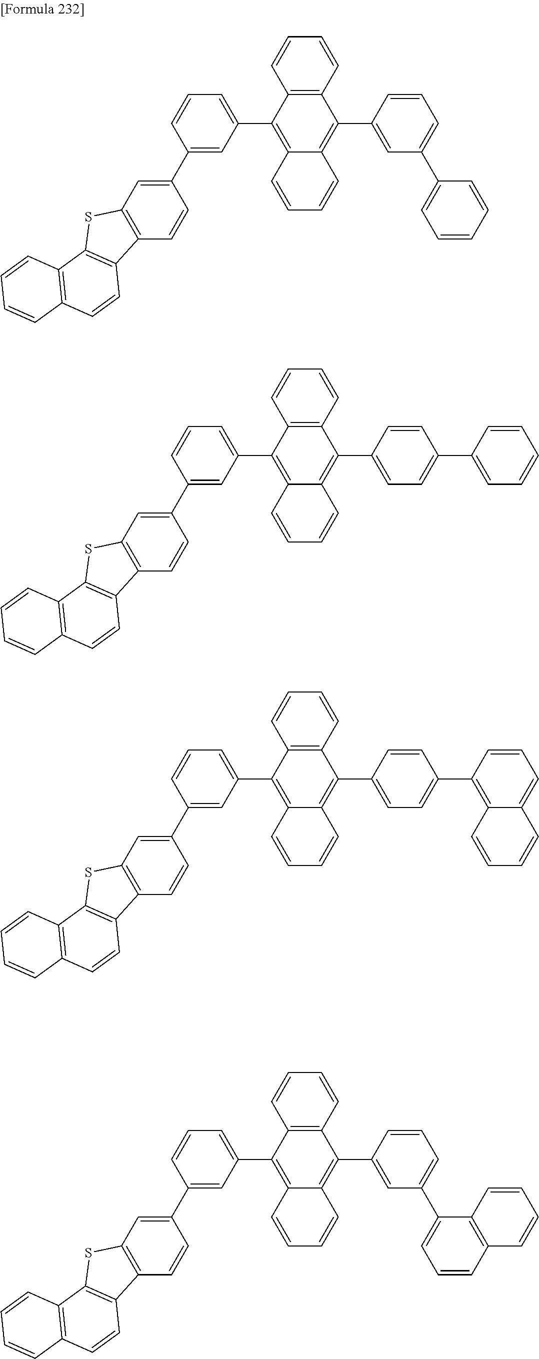 [SMILES: c1ccc(-c2cccc(-c3c4ccccc4c(-c4cccc(-c5ccc6c(c5)sc5c7ccccc7ccc65)c4)c4ccccc34)c2)cc1 ; c1ccc(-c2ccc(-c3c4ccccc4c(-c4cccc(-c5ccc6c(c5)sc5c7ccccc7ccc65)c4)c4ccccc34)cc2)cc1 ; c1cc(-c2ccc3c(c2)sc2c4ccccc4ccc32)cc(-c2c3ccccc3c(-c3ccc(-c4cccc5ccccc45)cc3)c3ccccc23)c1 ; c1cc(-c2ccc3c(c2)sc2c4ccccc4ccc32)cc(-c2c3ccccc3c(-c3cccc(-c4cccc5ccccc45)c3)c3ccccc23)c1]

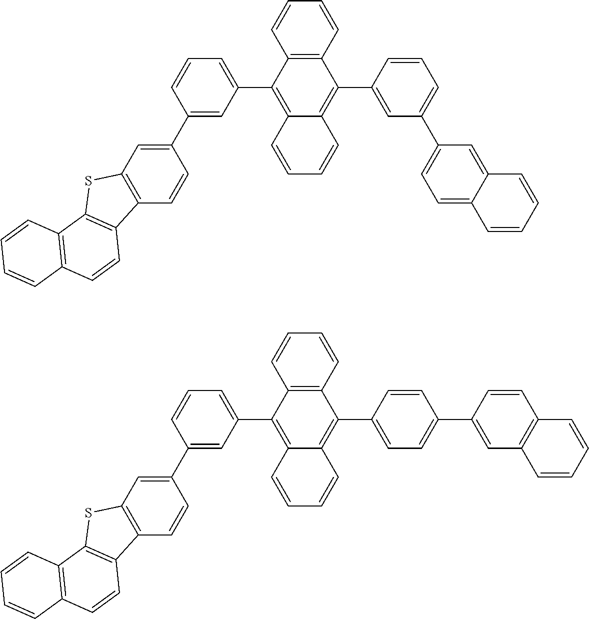 [SMILES: c1cc(-c2ccc3ccccc3c2)cc(-c2c3ccccc3c(-c3cccc(-c4ccc5c(c4)sc4c6ccccc6ccc54)c3)c3ccccc23)c1 ; c1cc(-c2ccc3c(c2)sc2c4ccccc4ccc32)cc(-c2c3ccccc3c(-c3ccc(-c4ccc5ccccc5c4)cc3)c3ccccc23)c1]

### Second Compound

Any compound is usable as the blue-emitting second compound usable in the blue emitting layer 12. A blue fluorescent or phosphorescent material is usable as the second compound, among which a blue-emitting fluorescent material is preferable.

An emission peak wavelength of the second compound is preferably in a range from 400 nm to 500 nm, more preferably in a range from 430 nm to 480 nm. The emission peak wavelength means a peak wavelength of an emission spectrum exhibiting a maximum luminous intensity among emission spectra measured using a toluene solution where a measurement target compound is dissolved at a concentration from 10⁻⁶ mol/l to 10⁻⁵ mol/l.

Examples of the blue fluorescent material include a pyrene derivative, styrylamine derivative, chrysene derivative, fluoranthene derivative, fluorene derivative, diamine derivative, and triarylamine derivative. Specific examples of the blue fluorescent material include
N,N′-bis[4-(9H-carbazole-9-yl)phenyl]-N,N′-diphenylstilbene-4,4′-diamine (abbreviation: YGA2S),
4-(9H-carbazole-9-yl)-4′-(10-phenyl-9-anthryl)triphenylamine (abbreviation: YGAPA), and
4-(10-phenyl-9-anthryl)-4′-(9-phenyl-9H-carbazole-3-yl)triphenylamine (abbreviation: PCBAPA).

The blue phosphorescent material is exemplified by a metal complex such as an iridium complex, osmium complex, and platinum complex. Specific examples of the blue phosphorescent material include
bis[2-(4′,6′-difluorophenyl)pyridinato-N,C2′]iridium(III)tetrakis(1-pyrazolyl)borate (abbreviation: FIr6),
bis[2-(4′,6′-difluorophenyl)pyridinato-N,C2′]iridium(III)picolinate (abbreviation: FIrpic),
bis[2-(3′,5′bistrifluoromethylphenyl)pyridinato-N,C2]iridium(III) picolinate(abbreviation: Ir(CF3ppy)₂(pic)), and
bis[2-(4′,6′-difluorophenyl)pyridinato-N,C2′]iridium(III)acetylacetonato (abbreviation: FIracac).

### Content Ratio of Compounds in Emitting Layer

A content ratio of the first compound in the blue emitting layer 12 is preferably in a range from 90 mass % to 99 mass %. A content ratio of the second compound in the blue emitting layer 12 is preferably in a range from 1 mass % to 10 mass %. It should be noted that the blue emitting layer 12 may further contain another material in addition to the first and second compounds.

### Hole Transporting Layer

The hole transporting layer 11 is a layer containing a highly hole-transporting substance.

An aromatic amine compound, carbazole derivative, anthracene derivative and the like are usable for the hole transporting layer 11. Specific examples of the substance usable for the hole transporting layer 7 include an aromatic amine compound such as
4,4′-bis[N-(1-naphthyl)-N-phenylamino]biphenyl (abbreviation: NPB),
N,N′-bis(3-methylphenyl)-N,N′-diphenyl-[1,1′-biphenyl]-4,4′-diamine (abbreviation: TPD),
4-phenyl-4′-(9-phenylfluorene-9-yl)triphenylamine (abbreviation: BAFLP),
4,4′-bis[N-(9,9-dimethylfluorene-2-yl)-N-phenylamino]biphenyl (abbreviation: DFLDPBi),
4,4′,4″-tris(N,N-diphenylamino)triphenylamine (abbreviation: TDATA),
4,4′,4″-tris[N-(3-methylphenyl)-N-phenylamino]triphenylamine (abbreviation: MTDATA), and
4,4′-bis[N-(spiro-9,9′-bifluorene-2-yl)-N-phenylamino]biphenyl (abbreviation: BSPB). The above-described substances mostly have a hole mobility of 10⁻⁶ cm²/(V·s) or more.

For the hole transporting layer 11, a carbazole derivative such as CBP, 9-[4-(N-carbazolyl)]phenyl-10-phenylanthracene (CzPA) and 9-phenyl-3-[4-(10-phenyl-9-anthryl)phenyl]-9H-carbazole (PCzPA) and an anthracene derivative such as t-BuDNA, DNA, and DPAnth may be used. Moreover, a polymer compound such as poly(N-vinylcarbazole) (abbreviation: PVK) and poly(4-vinyltriphenylamine) (abbreviation: PVTPA) is also usable for the hole transporting layer 6.

However, any substance having a hole transporting performance higher than an electron transporting performance may be used in addition to the above substances.

When the hole transporting layer includes two or more layers, one of the layers with a larger energy gap is preferably provided closer to the emitting layer.

### Electron Transporting Layer

The electron transporting layer 13 is a layer containing a highly electron-transporting substance. For the electron transporting layer 13, 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound are usable. Specifically, as a low molecular organic compound, the metal complex such as Alq, tris(4-methyl-8-quinolinolato)aluminum (abbreviation: Almq3), bis(10-hydroxybenzo[h]quinolinato)beryllium (abbreviation: BeBq2), BAlq, Znq, ZnPBO, and ZnBTZ are usable. In addition to the metal complex, the hetero aromatic compound such as
2-(4-biphenylyl)-5-(4-tert-butylphenyl)-1,3,4-oxadiazole (abbreviation: PBD),
1,3-bis[5-(ptert-butylphenyl)-1,3,4-oxadiazole-2-yl]benzene (abbreviation: OXD-7),
3-(4-tert-butylphenyl)-4-phenyl-5-(4-biphenylyl)-1,2,4-triazole (abbreviation: TAZ),
3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and
4,4′-bis(5-methylbenzooxazole-2-yl)stilbene (abbreviation: BzOs) are usable.

The above-described substances mostly have an electron mobility of 10⁻⁶ cm²/(V·s) or more. However, any substance having an electron transporting performance higher than a hole transporting performance may be used for the electron transporting layer 13 in addition to the above substances. The electron transporting layer 13 may be provided in the form of a single layer or a laminated layer of two or more layers of the above substance(s).

Moreover, a polymer compound is also usable for the electron transporting layer 13. For instance,
poly[(9,9-dihexylfluorene-2,7-diyl)-co-(pyridine-3,5-diyl)] (abbreviation: PF-Py),
poly[(9,9-dioctylfluorene-2,7-diyl)-co-(2,2′-bipyridine-6,6′-diyl)] (abbreviation: PF-BPy) and the like are usable.

In the exemplary embodiments, a hetero aromatic compound is suitably usable for the electron transporting layer 13.

### Electron Injecting Layer

The electron injecting layer 14 is a layer containing a highly electron-injectable substance. Examples of a material for the electron injecting layer 14 include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, a substance containing an alkali metal, alkaline earth metal and a compound thereof in the electron-transporting substance, specifically, a substance containing magnesium (Mg) in Alq may be used. In this case, electrons can be more efficiently injected from the cathode 4.

Alternatively, a composite material provided by mixing an organic compound with an electron donor may be used for the electron injecting layer 14. The composite material exhibits excellent electron injecting performance and electron transporting performance since the electron donor generates electron in the organic compound. In this arrangement, the organic compound is preferably a material exhibiting an excellent transforming performance of the generated electrons. Specifically, for instance, the above-described substance for the electron transporting layer 13 (e.g., the metal complex and heteroaromatic compound) is usable. The electron donor may be any substance exhibiting an electron donating performance to the organic compound. Specifically, an alkali metal, an alkaline earth metal or a rare earth metal is preferable, examples of which include lithium, cesium, magnesium, calcium, erbium and ytterbium. Moreover, an alkali metal oxide and alkaline earth metal oxide are preferably used, examples of which include lithium oxide, calcium oxide, and barium oxide. Further, Lewis base such as magnesium oxide is also usable. Furthermore, tetrathiafulvalene (abbreviation: TTF) is also usable.

### Charge Generating Layer

The charge generating layer 5 is a supply source of holes to be injected into the first emitting unit 10 while being a supply source of electrons to be injected into the second emitting unit 20.

In the organic EL device 1, in addition to charges to be injected from a pair of electrodes (i.e., the anode 3 and the cathode 4), charges supplied from the charge generating layer 5 are injected into the first emitting unit 10 and the second emitting unit 20. Provision of the charge generating layer 5 improves the luminous efficiency (current efficiency) for the injected current.

The charge generating layer 5 is a layer including at least one of an intermediate conductive layer or the charge generating layer, or at least one layer of the intermediate conductive layer or the charge generating layer.

The charge generating layer 5 may be structured such that a p-type charge generating layer including an electron-accepting material is laminated on an n-type charge generating layer including an electron transporting material and doped with a donor (electron donor) such as metal Li. In the exemplary embodiment, at an interface between the p-type charge generating layer and the hole transporting layer 11, the p-type charge generating layer draws electrons from the hole transporting layer 11, thereby generating electrons and holes. When an external charge is applied on the organic EL device 1, the generated electrons are transported to the green emitting layer 24 and the red emitting layer 23 through the n-type charge generating layer and the electron transporting layer 25 while the generated holes are transported to the blue emitting layer 12 through the hole transporting layer 11.

Examples of the charge generating layer 5 include a metal, metal oxide, mixture of metal oxides, composite oxide, and electron-accepting organic compound.

Examples of the metal include Mg and Al. The charge generating layer 5 is also preferably a co-deposition film of Mg and Al.

Examples of the metal oxide include ZnO, WO₃, MoO₃ and MoO₂.

Examples of the mixture of the metal oxides include ITO, IZO (registered trade mark), and ZnO:Al (ZnO added with Al).

Examples of the electron-accepting organic compound include an organic compound having a CN group as a substituent. The organic compound having a CN group is preferably a triphenylene derivative, tetracyanoquinodimethane derivative and indenofluorene derivative. The triphenylene derivative is preferably hexacyanohexaazatriphenylene. The tetracyanoquinodimethane derivative is preferably tetrafluoroquinodimethane and dicyanoquinodimethane. The indenofluorene derivative is preferably a compound disclosed in WO2009/011327, WO2009/069717, or WO2010/064655.The electron accepting substance may be a single substance, or a mixture with other organic compound(s).

In order to easily accept the electrons from the charge generating layer 5, the electron transporting layer 25 of the second emitting unit 20 is preferably doped with a donor (electron donor) in the vicinity of an interface between the electron transporting layer 25 and the charge generating layer 5. The donor is at least one selected from the group consisting of a donor metal (electron-donating metal), donor metal compound (electron-donating metal compound) and donor metal complex (electron-donating metal complex). An alkali metal is a representative example of the donor. Specific examples of the donor metal, the donor metal compound and the donor metal complex include compounds disclosed in International Publication No. WO2010/134352.

### Second Emitting Unit

The second emitting unit 20 includes the hole injecting layer 21, the hole transporting layer 22, the red emitting layer 23, the green emitting layer 24, and the electron transporting layer 25 which are sequentially laminated on the anode 3.

### Red Emitting Layer and Green Emitting Layer

The emitting layer is a layer containing a highly emittable substance and can be formed of various materials. For instance, a fluorescent compound emitting fluorescence and a phosphorescent compound emitting phosphorescence are usable as the highly emittable substance. The fluorescent compound is a compound capable of emitting in a singlet state. The phosphorescent compound is a compound capable of emitting in a triplet state.

The green emitting layer 24 includes a green emitting compound (a third compound), and preferably includes a green fluorescent or phosphorescent material. A green fluorescent material is exemplified by an aromatic amine derivative. Specific examples of the green fluorescent material include
N-(9,10-diphenyl-2-anthryl)-N,9-diphenyl-9H-carbazole-3-amine (abbreviation: 2PCAPA),
N-[9,10-bis(1,1′-biphenyl-2-yl)-2-anthryl]-N,9-diphenyl-9H-carbazole-3-amine (abbreviation: 2PCABPhA),
N-(9,10-diphenyl-2-anthryl)-N,N′,N′-triphenyl-1,4-phenylenediamine (abbreviation: 2DPAPA),
N-[9,10-bis(1,1′-biphenyl-2-yl)-2-anthryl]-N,N′,N′-triphenyl-1,4-phenylene diamine (abbreviation: 2DPABPhA),
N-[9,10-bis(1,1′-biphenyl-2-yl)]-N-[4-(9H-carbazole-9-yl)phenyl]-N-phenylanthracene-2-amine (abbreviation: 2YGABPhA), and
N,N,9-triphenylanthracene-9-amine (abbreviation: DPhAPhA).

A green phosphorescent material is exemplified by an iridium complex. Examples of the green phosphorescent material further include tris(2-phenylpyridinatoN,C2′)iridium(III) (abbreviation: Ir(ppy)₃), bis(2-phenylpyridinatoN,C2′)iridium(III)acetylacetonato (abbreviation: Ir(ppy)₂(acac)),
bis(1,2-diphenyl-1H-benzimidazolato)iridium(III)acetylacetonato (abbreviation: Ir(pbi)₂(acac)), and
bis(benzo[h]quinolinato)iridium(III)acetylacetonato (abbreviation: Ir(bzq)₂(acac)).

The red emitting layer 23 preferably includes a red emitting compound (a fourth compound), in other words, a red fluorescent or phosphorescent material.

A red fluorescent material is exemplified by a tetracene derivative and a diamine derivative. Examples of the red fluorescent material include
N,N,N′,N′-tetrakis(4-methylphenyl)tetracene-5,11-diamine (abbreviation: p-mPhTD), and
7,14-diphenyl-N,N,N′,N′-tetrakis(4-methylphenyl)acenaphtho[1,2-a]fluoranthene-3,10-diamine (abbreviation: p-mPhAFD).

A red phosphorescent material is exemplified by a metal complex such as an iridium complex, platinum complex, terbium complex and europium complex. Specifically, the red phosphorescent material is exemplified by an organic metal complex such as
bis[2-(2′-benzo[4,5-α]thienyl)pyridinato-N,C3′]iridium(III)acetylacetonato (abbreviation: Ir(btp)₂(acac)),
bis(1-phenylisoquinolinato-N,C2′)iridium(III)acetylacetonato (abbreviation: Ir(piq)₂(acac)),
(acetylacetonato)bis[2,3-bis(4-fluorophenyl)quinoxalinato]iridium(III) (abbreviation: Ir(Fdpq)₂(acac)), and
2,3,7,8,12,13,17,18-octaethyl-21H,23H-porphyrinplatinum(II) (abbreviation: PtOEP).

Since a rare earth metal complex such as tris(acetylacetonato)(monophenanthroline)terbium(III)(abbreviation: Tb(acac)₃(Phen)), tris (1,3-diphenyl-1,3-propanedionato)(monophenanthroline)europium (III)(abbreviation: Eu(DBM)₃(Phen)), and tris [1-(2-thenoyl)-3,3,3-trifluoroacetonato](monophenanthroline)europium (III)(abbreviation: Eu(TTA)₃(Phen)) produces emission from a rare earth metal ion (electron transition between different multiplicities), the rare earth metal complex is usable as the phosphorescent compound.

The emitting layer may be structured such that the aforementioned highly emittable substance (a guest material) is dispersed in another substance (a host material). As the substance for dispersing the highly emittable substance, various substances are usable, among which a substance having a Lowest Unoccupied Molecular Orbital level (LUMO level) higher than that of the highly emittable substance and a Highest Occupied Molecular Orbital (HOMO level) lower than that of the highly emittable substance is preferable.

Examples of the substance (the host material) for dispersing the highly emittable substance include: 1) a metal complex such as an aluminum complex, beryllium complex or zinc complex; 2) a heterocyclic compound such as an oxadiazole derivative, benzimidazole derivative or phenanthroline derivative; 3) a fused aromatic compound such as a carbazole derivative, anthracene derivative, phenanthrene derivative, pyrene derivative or chrysene derivative; and 4) an aromatic amine compound such as a triarylamine derivative or a fused polycyclic amine derivative.

The hole injecting layer 21, the hole transporting layer 22 and the electron transporting layer 25 are formable of the same compounds as those for the hole injecting layer, hole transporting layer and electron transporting layer described in relation to the first emitting unit 10.

### Substrate

The substrate 2 is used as a support for the organic EL device 1. For instance, glass, quartz, plastics and the like are usable as the substrate 2. A flexible substrate is also usable. The flexible substrate is a bendable substrate. The flexible substrate is exemplified by a plastic substrate formed of polycarbonate, polyarylate, polyethersulfone, polypropylene, polyester, polyvinyl fluoride, polyvinyl chloride, polyimide, polyethylene naphthalate or the like. Moreover, an inorganic vapor deposition film is also usable as the substrate 2.

### Anode

Metal having a large work function (specifically, 4.0 eV or more), alloy, an electrically conductive compound and a mixture thereof are preferably usable as the anode 3 formed on the substrate 2. Specific examples of the material for the anode include indium tin oxide (ITO), indium tin oxide containing silicon or silicon oxide, indium zinc oxide, tungsten oxide, indium oxide containing zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), nitrides of a metal material (e.g., titanium nitride) and the like are usable.

The above materials are typically formed into a film by sputtering. For instance, a target of the indium zinc oxide which is prepared by adding zinc oxide in a range from 1 mass % to 10 mass % relative to indium oxide is used for forming a film by sputtering. Moreover, for instance, as for the indium oxide containing tungsten oxide and zinc oxide, a target thereof prepared by adding tungsten oxide in a range from 0.5 mass % to 5 mass % and zinc oxide in a range from 0.1 mass % to 1 mass % relative to indium oxide is usable for forming a film by sputtering. In addition, vapor deposition, coating, ink jet printing, spin coating and the like may be used for forming the anode 3.

Among the organic layers formed on the anode 3, since the hole injecting layer 21 formed adjacent to the anode 3 is formed of a composite material in which holes are easily injectable irrespective of the work function of the anode 3, other materials usable as an electrode material (e.g., a metal, alloy, electrically conductive compound, mixture thereof, and elements belonging to Group 1 or 2 in the periodic table of the elements) are also usable for the anode 3.

A material having a small work function such as elements belonging to Groups 1 and 2 in the periodic table of the elements are also usable for the anode 3. Examples of the material for the anode 3 include an alkali metal such as lithium (Li) and cesium (Cs), an alkaline earth metal such as magnesium (Mg), calcium (Ca) and strontium (Sr), alloys (e.g., MgAg and AlLi) including at least one of the alkali metal or the alkaline earth metal, a rare earth metal such as europium (Eu) and ytterbium (Yb), and alloys including the rare earth metal. When the cathode 3 is formed of the alkali metal, alkaline earth metal and alloys thereof, vapor deposition and sputtering are usable. Further, when the anode 3 is formed of silver paste and the like, coating, ink jet printing and the like are usable.

### Cathode

Metal, alloy, an electrically conductive compound, a mixture thereof and the like, which have a small work function (specifically, 3.8 eV or less), are preferably usable as a material for the cathode 4. Examples of the material for the cathode include elements belonging to Groups 1 and 2 in the periodic table of the elements, specifically, the alkali metal such as lithium (Li) and cesium (Cs), the alkaline earth metal such as magnesium (Mg), calcium (Ca) and strontium (Sr), alloys (e.g., MgAg and AlLi) including the alkali metal or the alkaline earth metal, the rare earth metal such as europium (Eu) and ytterbium (Yb), and alloys including the rare earth metal.

When the cathode 4 is formed of the alkali metal, alkaline earth metal and alloy thereof, vapor deposition and sputtering are usable. Further, when the cathode 4 is formed of silver paste and the like, coating, ink jet printing and the like are usable.

By providing the electron injecting layer 14, various conductive materials such as Al, Ag, ITO, graphene, and indium tin oxide containing silicon or silicon oxide are usable for forming the cathode 4 irrespective of the magnitude of the work function. The conductive materials can be formed into a film by sputtering, ink jet printing, spin coating and the like.

The organic EL device 1 of the exemplary embodiment includes the light-transmissive substrate 2, the cathode 4 that is a light-reflective electrode, and the anode 3 that is a light-transmissive electrode. In other words, the organic EL device 1 is a bottom-emission organic EL device configured to emit light irradiated from the first emitting unit 10 and the second emitting unit 20 through the substrate 2. The light-transmissive electrode is exemplified by an electrode formed of ITO. The light-reflective electrode is exemplified by an electrode formed of metal Al and metal Ag.

### Layer Formation Method(s)

There is no restriction except for the above particular description for a method for forming each layer of the organic EL device 1 in the exemplary embodiment. Known methods such as dry film-forming and wet film-forming are applicable. Examples of the dry film-forming include vacuum deposition, sputtering, plasma deposition method and ion plating. Examples of the wet film-forming include spin coating, dipping, flow coating and ink-jet.

### Film Thickness

There is no restriction except for the above particular description for a film thickness of each of the organic layers of the organic EL device 1 in the exemplary embodiment. The film thickness is generally preferably in the range from several nanometers to 1 μm, since too small thickness possibly causes defects such as a pin hole while too large thickness requires high voltage to be applied and lowers efficiency.

### Manufacturing Method of Compound according to Exemplary Embodiment

The compound according to the exemplary embodiment can be manufactured by, for instance, a typically known method. The compound according to the exemplary embodiment can be synthesized by application of known substitution reactions and/or materials depending on a target compound in accordance with a typically known method.

Herein, a “hydrogen atom” means isotopes having different neutron numbers and specifically encompasses protium, deuterium and tritium.

Herein, “carbon atoms forming a ring (ring carbon atoms)” mean carbon atoms forming a saturated ring, unsaturated ring, or aromatic ring.

Herein, the number of carbon atoms forming a ring (also referred to as ring carbon atoms) means the number of carbon atoms included in atoms forming the ring itself of a compound in which the atoms are bonded to form the ring (e.g., a monocyclic compound, a fused ring compound, a cross-linked compound, a carbocyclic compound, and a heterocyclic compound).When the ring is substituted by a substituent, the “ring carbon atoms” do not include carbon(s) contained in the substituent. Unless specifically described, the same applies to the “ring carbon atoms” described later. For instance, a benzene ring has 6 ring carbon atoms, a naphthalene ring has 10 ring carbon atoms, a pyridinyl group has 5 ring carbon atoms, and a furanyl group has 4 ring carbon atoms. For instance, a benzene ring has 6 ring carbon atoms, a naphthalene ring has 10 ring carbon atoms, a pyridinyl group has 5 ring carbon atoms, and a furanyl group has 4 ring carbon atoms. When a fluorene ring is substituted by, for instance, a fluorene ring (e.g., a spirofluorene ring), the number of carbon atoms of the fluorene ring as a substituent is not counted in the number of the ring carbon atoms for the fluorene ring.

Herein, “atoms forming a ring (ring atoms)” mean carbon atoms and hetero atoms forming a hetero ring including a saturated ring, unsaturated ring, or aromatic ring.

Herein, the number of atoms forming a ring (also referred to as ring atoms) means the number of atoms forming the ring itself of a compound in which the atoms are bonded to form the ring (e.g., a monocyclic compound, a fused ring compound, a cross-linked compound, a carbocyclic compound, and a heterocyclic compound). Atom(s) not forming the ring (e.g., a hydrogen atom for terminating the atoms forming the ring) and atoms included in a substituent substituting the ring are not counted in the number of the ring atoms. Unless specifically described, the same applies to the “ring atoms” described later. For instance, a pyridine ring has 6 ring atoms, a quinazoline ring has 10 ring atoms, and a furan ring has 5 ring atoms. Hydrogen atoms respectively bonded to the pyridine ring and the quinazoline ring and atoms forming the substituents are not counted in the number of the ring atoms. When a fluorene ring is substituted by a substituent (e.g., a fluorene ring) (i.e., a spirofluorene ring is included), the number of atoms of the fluorene ring as the substituent is not counted in the number of the ring atoms of the fluorene ring.

Next, each of substituents described in the above formulae will be described.

Examples of the aromatic hydrocarbon group (occasionally referred to as an aryl group) having 6 to 30 ring carbon atoms in the exemplary embodiment include a phenyl group, biphenyl group, terphenyl group, naphthyl group, anthryl group, phenanthryl group, fluorenyl group, pyrenyl group, chrysenyl group, fluoranthenyl group, benzo[a]anthryl group, benzo[c]phenanthryl group, triphenylenyl group, benzo[k]fluoranthenyl group, benzo[g]chrysenyl group, benzo[b]triphenylenyl group, picenyl group, and perylenyl group.

The aryl group in the exemplary embodiment preferably has 6 to 20 ring carbon atoms, more preferably 6 to 14 ring carbon atoms, further preferably 6 to 12 ring carbon atoms. Among the aryl group, a phenyl group, biphenyl group, naphthyl group, phenanthryl group, terphenyl group and fluorenyl group are particularly preferable. In a 1-fluorenyl group, 2-fluorenyl group, 3-fluorenyl group and 4-fluorenyl group, a carbon atom at a position 9 is preferably substituted by the substituted or unsubstituted alkyl group having 1 to 30 carbon atoms or an unsubstituted aryl group having 6 to 18 ring carbon atoms in a later-described exemplary embodiment.

The heterocyclic group (occasionally, referred to as a heteroaryl group, heteroaromatic ring group or aromatic heterocyclic group) having 5 to 30 ring atoms in the exemplary embodiment preferably contains as a hetero atom at least one atom selected from the group consisting of nitrogen, sulfur, oxygen, silicon, selenium atom and germanium atom, and more preferably contains at least one atom selected from the group consisting of nitrogen, sulfur and oxygen.

Examples of the heteroaryl group having 5 to 30 ring atoms in the exemplary embodiment include a pyridyl group, pyrimidinyl group, pyrazinyl group, pyridazynyl group, triazinyl group, quinolyl group, isoquinolinyl group, naphthyridinyl group, phthalazinyl group, quinoxalinyl group, quinazolinyl group, phenanthridinyl group, acridinyl group, phenanthrolinyl group, pyrrolyl group, imidazolyl group, pyrazolyl group, triazolyl group, tetrazolyl group, indolyl group, benzimidazolyl group, indazolyl group, imidazopyridinyl group, benzotriazolyl group, carbazolyl group, furyl group, thienyl group, oxazolyl group, thiazolyl group, isoxazolyl group, isothiazolyl group, oxadiazolyl group, thiadiazolyl group, benzofuranyl group, benzothiophenyl group, benzoxazolyl group, benzothiazolyl group, benzisoxazolyl group, benzisothiazolyl group, benzoxadiazolyl group, benzothiadiazolyl group, dibenzofuranyl group, dibenzothiophenyl group, piperidinyl group, pyrrolidinyl group, piperazinyl group, morpholyl group, phenazinyl group, phenothiazinyl group, and phenoxazinyl group.

The heteroaryl group in the exemplary embodiment preferably has 5 to 20 ring atoms, more preferably 5 to 14 ring atoms. Among the above heterocyclic groups, a 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-carbazolyl group, 2-carbazolyl group, 3-carbazolyl group, 4-carbazolyl group, and 9-carbazolyl group are particularly preferable. In 1-carbazolyl group, 2-carbazolyl group, 3-carbazolyl group and 4-carbazolyl group, a nitrogen atom at the ninth position is preferably substituted by a substituted or unsubstituted aryl group having 6 to 30 ring carbon atoms or a substituted or unsubstituted heterocyclic group having 5 to 30 ring atoms according to the exemplary embodiment.

In the exemplary embodiment, the heteroaryl group may be a group derived from partial structures represented by formulae (XY-1) to (XY-18) below.

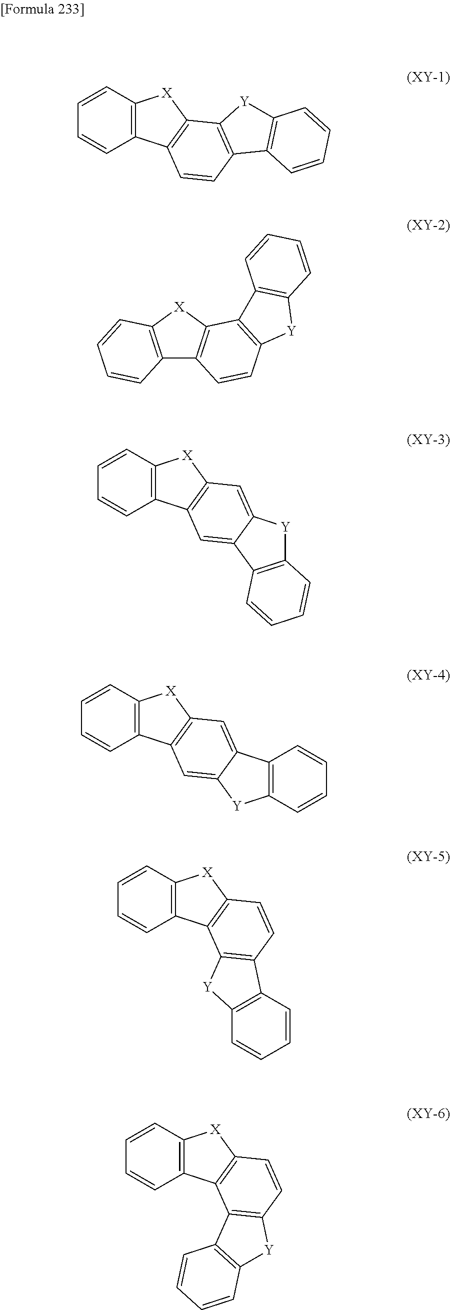

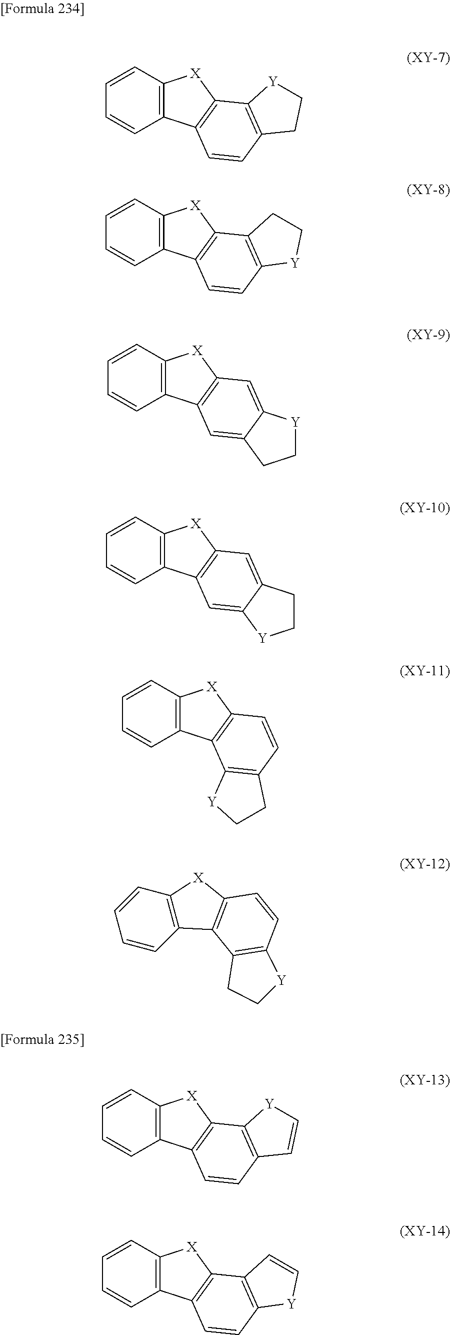

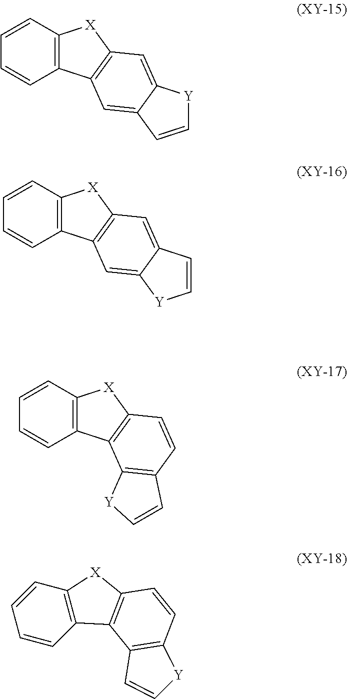

In the formulae (XY-1) to (XY-18), X and Y each independently represent a hetero atom, and preferably represent an oxygen atom, sulfur atom, selenium atom, silicon atom or germanium atom. The partial structures represented by the formulae (XY-1) to (XY-18) may each be bonded in any position to be a heteroaryl group, which may be substituted.

In the exemplary embodiment, for instance, a substituted or unsubstituted carbazolyl group may include a group in which a ring is further fused to a carbazole ring represented by a formula below. Such a group may be substituted. The group may be bonded in any position as desired.

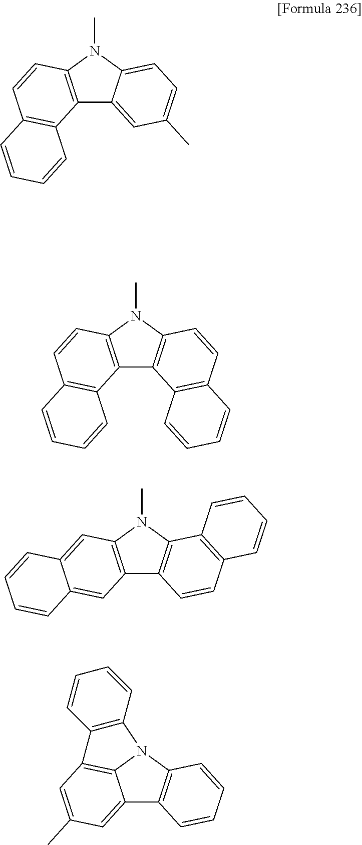

The alkyl group having 1 to 30 carbon atoms in the exemplary embodiment may be linear, branched or cyclic. Also, the alkyl group may be a halogenated alkyl group.

Examples of the linear or branched alkyl group include a methyl group, ethyl group, propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neo-pentyl group, amyl group, isoamyl group, 1-methylpentyl group, 2-methylpentyl group, 1-pentylhexyl group, 1-butylpentyl group, 1-heptyloctyl group and 3-methylpentyl group.

The linear or branched alkyl group in the exemplary embodiment preferably has 1 to 10 carbon atoms, more preferably 1 to 6 carbon atoms. Among the linear or branched alkyl group, a methyl group, ethyl group, propyl group, isopropyl group, n-butyl group, s-butyl group, isobutyl group, t-butyl group, n-pentyl group, n-hexyl group, amyl group, isoamyl group and neopentyl group are particularly preferable.

The cyclic alkyl group is exemplified by a cycloalkyl group having 3 to 30 carbon atoms. Examples of the cycloalkyl group having 3 to 30 carbon atoms in the exemplary embodiment are a cyclopropyl group, cyclobutyl group, cyclopentyl group, cyclohexyl group, 4-metylcyclohexyl group, adamantyl group and norbornyl group. The cycloalkyl group preferably has 3 to 10 ring carbon atoms, more preferably 5 to 8 ring carbon atoms. Among the cycloalkyl group, a cyclopentyl group and a cyclohexyl group are particularly preferable.

The halogenated alkyl group is exemplified by a halogenated alkyl group having 1 to 30 carbon atoms. The halogenated alkyl group having 1 to 30 carbon atoms in the exemplary embodiment is exemplified by a group provided by substituting the alkyl group having 1 to 30 carbon atoms with one or more halogen atoms. Specific examples of the halogenated alkyl group includes a fluoromethyl group, difluoromethyl group, trifluoromethyl group, fluoroethyl group, trifluoromethylmethyl group, trifluoroethyl group, and pentafluoroethyl group.

Examples of the halogen atom are a fluorine atom, a chlorine atom, a bromine atom and an iodine atom, among which a fluorine atom is preferable.

Examples of the substituted amino group include an alkylamino group having 2 to 30 carbon atoms and an arylamino group having 6 to 60 ring carbon atoms.

The alkylamino group having 2 to 30 carbon atoms is represented by —NHR_{V} or —N(R_{V})₂. R_{V} is exemplified by the alkyl group having 1 to 30 carbon atoms.

The arylamino group having 6 to 60 ring carbon atoms is represented by —NHR_{W} or —N(R_{W})₂. R_{W} is exemplified by the above aryl group having 6 to 30 ring carbon atoms.

The alkoxy group having 1 to 30 carbon atoms is represented by —OZ₁. Z₁ is exemplified by the above alkyl group having 1 to 30 carbon atoms. Examples of the alkoxy group are a methoxy group, ethoxy group, propoxy group, butoxy group, pentyloxy group and hexyloxy group. The alkoxy group preferably has 1 to 20 carbon atoms.

A halogenated alkoxy group provided by substituting the alkoxy group with a halogen atom is exemplified by a halogenated alkoxy group provided by substituting the alkoxy group having 1 to 30 carbon atoms with one or more fluorine groups.

The aryloxy group having 6 to 30 ring carbon atoms is represented by —OZ₂. Z₂ is exemplified by the above aryl group having 6 to 30 ring carbon atoms. The aryloxy group preferably has 6 to 20 ring carbon atoms. The aryloxy group is exemplified by a phenoxy group.

The arylthio group having 6 to 30 ring carbon atoms is represented by —SR_{W}. R_{W} is exemplified by the above aryl group having 6 to 30 ring carbon atoms. The arylthio group preferably has 6 to 20 ring carbon atoms.

“Unsubstituted” in “substituted or unsubstituted” herein means that a group is not substituted by the above-described substituents but bonded with a hydrogen atom.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX.” “XX” and “YY” each mean an integer of 1 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX.” “XX” and “YY” each mean an integer of 1 or more.

Herein, examples of the substituent meant by “substituted or unsubstituted” include an aromatic hydrocarbon group, heterocyclic group, alkyl group (linear or branched alkyl group, cycloalkyl group and halogenated alkyl group), cyano group, amino group, substituted amino group, halogen atom, alkoxy group, aryloxy group, arylthio group, aralkyl group, substituted phosphoryl group, substituted silyl group, nitro group, carboxy group, alkenyl group, alkynyl group, alkylthio group, alkylsilyl group, arylsilyl group and hydroxyl group.

Among the above substituents meant by “substituted or unsubstituted”, the aromatic hydrocarbon group, heterocyclic group, alkyl group, halogen atom, alkylsilyl group, arylsilyl group and cyano group are preferable and the specific preferable substituents described in each of the substituents are more preferable.

The substituent meant by “substituted or unsubstituted” may be further substituted by at least one group selected from the group consisting of an aromatic hydrocarbon group, heterocyclic group, alkyl group (linear or branched alkyl group, cycloalkyl group and halogenated alkyl group), substituted phosphoryl group, alkylsilyl group, arylsilyl group, alkoxy group, aryloxy group, alkylamino group, arylamino group, alkylthio group, arylthio group, alkenyl group, alkynyl group, aralkyl group, halogen atom, cyano group, hydroxyl group, nitro group, and carboxy group. In addition, plural ones of these substituents may be mutually bonded to form a ring.

The alkenyl group preferably has 2 to 30 carbon atoms and may be linear, branched or cyclic. Examples of the alkenyl group include a vinyl group, propenyl group, butenyl group, oleyl group, eicosapentaenyl group, docosahexaenyl group, styryl group, 2,2-diphenylvinyl group, 1,2,2-triphenylvinyl group, 2-phenyl-2-propenyl group, cyclopentadienyl group, cyclopentenyl group, cyclohexenyl group and cyclohexadienyl group.

The alkynyl group preferably has 2 to 30 carbon atoms and may be linear, branched or cyclic. Examples of the alkynyl group are ethynyl, propynyl and 2-phenylethynyl.

The alkylthio group having 1 to 30 carbon atoms is represented by —SR_{V}. R_{V} is exemplified by the alkyl group having 1 to 30 carbon atoms. The alkylthio group preferably has 1 to 20 carbon atoms.

A substituted or unsubstituted aralkyl group having 7 to 30 carbon atoms is represented by —Z₃—Z₄. Z₃ is exemplified by an alkylene group derived from the above alkyl group having 1 to 30 carbon atoms. Z₄ is exemplified by the above aryl group having 6 to 30 ring carbon atoms. In the aralkyl group having 7 to 30 carbon atoms, an aryl moiety as Z₄ preferably has 6 to 20 ring carbon atoms, more preferably 6 to 12 ring carbon atoms and an alkyl moiety as Z₃ preferably has 1 to 20 carbon atoms, more preferably 1 to 10 carbon atoms, further preferably 1 to 6 carbon atoms. Examples of the aralkyl group are a benzyl group, 2-phenylpropane-2-yl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

The substituted phosphoryl group is represented by a formula (P) below.

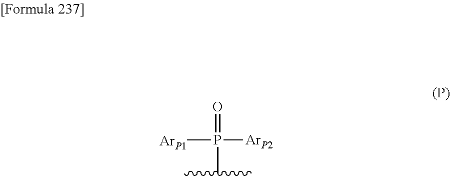

In the formula (P), Ar_{P1} and Ar_{P2}, which are each independently a substituent, are preferably a substituent selected from the group consisting of an alkyl having 1 to 30 carbon atoms and aryl group having 6 to 30 ring carbon atoms, more preferably a substituent selected from the group consisting of an alkyl group having 1 to 10 carbon atoms and an aryl group having 6 to 20 ring carbon atoms, further preferably a substituent selected from the group consisting of an alkyl group having 1 to 6 carbon atoms and an aryl group having 6 to 14 ring carbon atoms.

Examples of the substituted silyl group include an alkylsilyl group having 3 to 30 carbon atoms and an arylsilyl group having 6 to 30 ring carbon atoms.

The alkylsilyl group having 3 to 30 carbon atoms in the exemplary embodiment is exemplified by a trialkylsilyl group having the above examples of the alkyl group having 1 to 30 carbon atoms. Specific examples of the alkylsilyl group are a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyl dimethylsilyl group, propyldimethylsilyl group, and triisopropylsilyl group. Three alkyl groups in the trialkylsilyl group may be mutually the same or different.

Examples of the arylsilyl group having 6 to 30 ring carbon atoms in the exemplary embodiment are a dialkylarylsilyl group, alkyldiarylsilyl group and triarylsilyl group.

The dialkylarylsilyl group is exemplified by a dialkylarylsilyl group including two of the alkyl group listed as the examples of the alkyl group having 1 to 30 carbon atoms and one of the aryl group listed as the examples of the aryl group having 6 to 30 ring carbon atoms. The dialkylarylsilyl group preferably has 8 to 30 carbon atoms.

The alkyldiarylsilyl group is exemplified by an alkyldiarylsilyl group including one of the alkyl group listed as the examples of the alkyl group having 1 to 30 carbon atoms and two of the aryl group listed as the examples of the aryl group having 6 to 30 ring carbon atoms. The alkyldiarylsilyl group preferably has 13 to 30 carbon atoms.

The triarylsilyl group is exemplified by a triarylsilyl group including three of the aryl group listed as the examples of the aryl group having 6 to 30 ring carbon atoms. The triarylsilyl group preferably has 18 to 30 carbon atoms.

Herein, examples of the aromatic hydrocarbon group and the heterocyclic group as the linking group include divalent groups obtained by removing at least one hydrogen atom from the above monovalent aromatic hydrocarbon group and heterocyclic group.

Herein, when the substituents are mutually bonded to form a cyclic structure, the cyclic structure is a saturated ring, unsaturated ring, aromatic hydrocarbon ring, or a heterocycle. In addition, the cyclic structure formed by bonding the substituents may have a substituent.

Herein, examples of the aromatic hydrocarbon ring and the hetero ring include a cyclic structure from which the above monovalent group is derived.

### Electronic Device

The organic EL device 1 according to the exemplary embodiment is usable in an electronic device such as a display unit and a light-emitting unit. Examples of the display unit include display components such as an organic EL panel module, TV, mobile phone, tablet, and personal computer. Examples of the light-emitting unit include an illuminator and a vehicle light.

According to the exemplary embodiment, an organic EL device 1 drivable at a low voltage with a long lifetime while keeping a high luminous efficiency can be provided.

Typically, holes are restrictively injected into the emitting unit located closer to the cathode than the charge generating layer is close to the cathode. In the tandem organic EL device disclosed in Patent Literature 1, an anthracene derivative having a molecular structure consisting of a hydrocarbon skeleton is used as the host material in the blue emitting layer (hereinafter, such an anthracene derivative is occasionally referred to as a hydrocarbon anthracene derivative). The tandem organic EL device has a short lifetime when the hydrocarbon anthracene derivative is used as the host material in the blue emitting layer located closer to the cathode than the charge generating layer is close to the cathode, This is considered to be because a strong electron transporting performance of the hydrocarbon anthracene derivative causes electrons to concentrate on the interface between the emitting layer and the hole transporting layer without remaining within the emitting layer, resulting in deterioration of the hole transporting layer.

On the other hand, since the organic EL device 1 of the exemplary embodiment employs the first compound represented by the formula (1) in the blue emitting layer 12 of the first emitting unit 10 located closer to the cathode 4 than the charge generating layer 5 is close to the cathode 4, the organic EL device 1 of the exemplary embodiment is drivable at a low voltage with a long lifetime while keeping a high luminous efficiency as compared with a typical organic EL device employing the hydrocarbon anthracene derivative. The first compound has such a structure that an anthracene skeleton is bonded by a single bond or a linking group to the Z¹ structure represented by the formula (2) and containing an oxygen atom or a sulfur atom. Accordingly, it is expected that the first compound exhibits the electron-donating performance stronger than that of the hydrocarbon anthracene derivative, thereby improving the injecting performance and transporting performance of the holes generated in the charge generating layer 5 to the blue emitting layer 12, resulting in a low drive voltage.

A lack of the holes injected from the hole transporting layer to the emitting layer may cause collision between excitons generated in the emitting layer and electrons. It is expected that the collision between the excitons and the electrons deactivates the excitons to decrease the luminous efficiency. Moreover, an increase in electrons in the interface between the hole transporting layer and the emitting layer may deteriorate the hole transporting layer to shorten a lifetime.

According to the organic EL device 1 of the exemplary embodiment, it is expected that the injecting performance and the transporting performance of the holes from the charge generating layer 5 are improved to inhibit the excitons from being deactivated in the blue emitting layer 12, thereby providing a recombination region of the electrons and the holes at an inner region of the blue emitting layer 12 relative to the interface between the hole transporting layer 11 and the blue emitting layer 12 to inhibit deterioration of the hole transporting layer 11.

As a result, it is expected that the organic EL device 1 is drivable at a low voltage with a long lifetime while keeping a high luminous efficiency.

### Second Exemplary Embodiment

An arrangement of an organic EL device according to a second exemplary embodiment will be described. In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable for a material and a compound which are not particularly described.

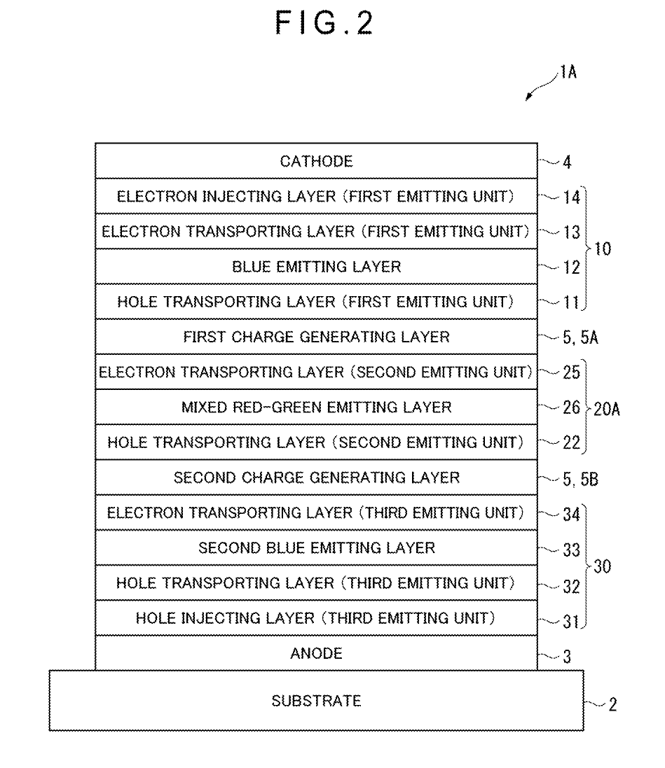

FIG. 2 schematically shows an arrangement of an organic EL device 1A according to the second exemplary embodiment.

The organic EL device 1A of the second exemplary embodiment is different from the organic EL device 1 of the first exemplary embodiment in the structure and the number of the emitting unit.

Specifically, the organic EL device 1A is different from the organic EL device 1 in that the organic EL device 1A has three emitting units (i.e., the first emitting unit 10, a second emitting unit 20A and a third emitting unit 30), whereas the organic EL device 1 has two emitting units (i.e., the first emitting unit 10 and the second emitting unit 20).

The organic EL device 1A includes the cathode 4, the anode 3, a first charge generating layer 5A provided between the cathode 4 and the anode 3, a second charge generating layer 5B provided between the first charge generating layer 5A and the anode 3, the first emitting unit 10 provided between the first charge generating layer 5A and the cathode 4, the second emitting unit 20A provided between the first charge generating layer 5A and the second charge generating layer 5B, and the third emitting unit 30 provided between the second charge generating layer 5B and the anode 3.

The first emitting unit 10, which is the same as in the first exemplary embodiment, includes the hole transporting layer 11, the blue emitting layer 12, the electron transporting layer 13, and the electron injecting layer 14. The blue emitting layer 12 includes the first compound represented by the formula (1) and the second compound emitting a blue light.

The second emitting unit 20A includes the hole transporting layer 22, a mixed red-green emitting layer 26 and the electron transporting layer 25.

The second emitting unit 30 includes a hole injecting layer 31, a hole transporting layer 32, a second blue emitting layer 33, and an electron transporting layer 34. It should be noted that the blue emitting layer 12 of the first emitting unit 10 is sometimes referred to as a first blue emitting layer 12 in order to be differentiated from the second blue emitting layer 33.

Since the organic EL device 1A includes the mixed red-green emitting layer and the blue emitting layer, the organic EL device 1A can emit a white light.

The hole transporting layer 22 and the electron transporting layer 25 of the second emitting unit 20A are the same as the hole transporting layer 22 and the electron transporting layer 25 described in the first exemplary embodiment.

The mixed red-green emitting layer 26 is different from the laminate structure of the red emitting layer 23 and the green emitting layer 24 of the first exemplary embodiment since the mixed red-green emitting layer 26 is an emitting layer including the red-emitting fourth compound and the green-emitting third compound in a single layer. The same compounds as the above are usable as the red-emitting compound, the green-emitting compound and the host material.

The hole injecting layer 31, the hole transporting layer 32, and the electron transporting layer 34 of the third emitting unit 30 are the same as the hole injecting layer, the hole transporting layer, and the electron transporting layer described in the first exemplary embodiment.

It should be noted that the second blue emitting layer 33 may have the same structure as that of the first blue emitting layer 12 of the first emitting unit 10 or may be formed of a sixth compound emitting a blue light. The blue-emitting compound and the host material described above are usable as the blue-emitting sixth compound.

The first charge generating layer 5A and the second charge generating layer 5B have the same structure as that of the charge generating layer 5. The first charge generating layer 5A and the second charge generating layer 5B may be formed of the same compound or different compounds.

According to the second exemplary embodiment, the organic EL device 1A drivable at a low voltage with a long lifetime while keeping a high luminous efficiency can be provided in the same manner as in the first exemplary embodiment.

### Modification of Embodiments

It should be noted that the scope of the invention is not limited to the above exemplary embodiments but may include any modification and improvement as long as such modification and improvement are compatible with the scope of the invention.

In the above exemplary embodiments, the bottom-emission organic EL device is described as an example. However, the invention is not limited thereto. The invention also encompasses a so-called top-emission organic EL device in which the cathode 4 is a light-transmissive electrode and the anode 3 is a light-reflective electrode. The top-emission organic EL device allows the blue emitting layer provided between the charge generating layer and the cathode to efficiently emit light.

When the emitting unit including the blue emitting layer between the light-reflective metal electrode (anode) and the charge generating layer is provided in the top-emission organic EL device, surface plasmon induced on a surface of the light-reflective metal electrode and a dipole of the blue emitting material strongly interact with each other, thereby reducing the luminous efficiency of the blue emitting layer.

On the other hand, when the organic EL device according to the above exemplary embodiments is in a form of a top-emission organic EL device, since the blue emitting layer containing the first compound having a predetermined structure is provided in the first emitting unit between the charge generating layer and the light-transmissive electrode (cathode), a distance between the light-transmissive electrode and the blue emitting layer is extended to prevent a reduction in the luminous efficiency caused by the surface plasmon effect.

In the above exemplary embodiments, the structure of the emitting layer of the second emitting unit is exemplified by the laminate structure of the red emitting layer and the green emitting layer and by the mixed red-green emitting layer. However, the invention is not limited to such structures. The invention also encompasses a tandem organic EL device, for instance, including a yellow emitting layer containing a yellow-emitting compound (a fifth compound) as the second emitting unit. Since such an organic EL device includes the yellow emitting layer and the blue emitting layer, the organic EL device can emit a white light.

Further, specific arrangements and configurations for practicing the invention may be altered to other arrangements and configurations compatible with the invention.

### EXAMPLES

Examples of the invention will be described below. However, the invention is not limited to Examples.

Compounds used for manufacturing the organic EL device will be shown below.

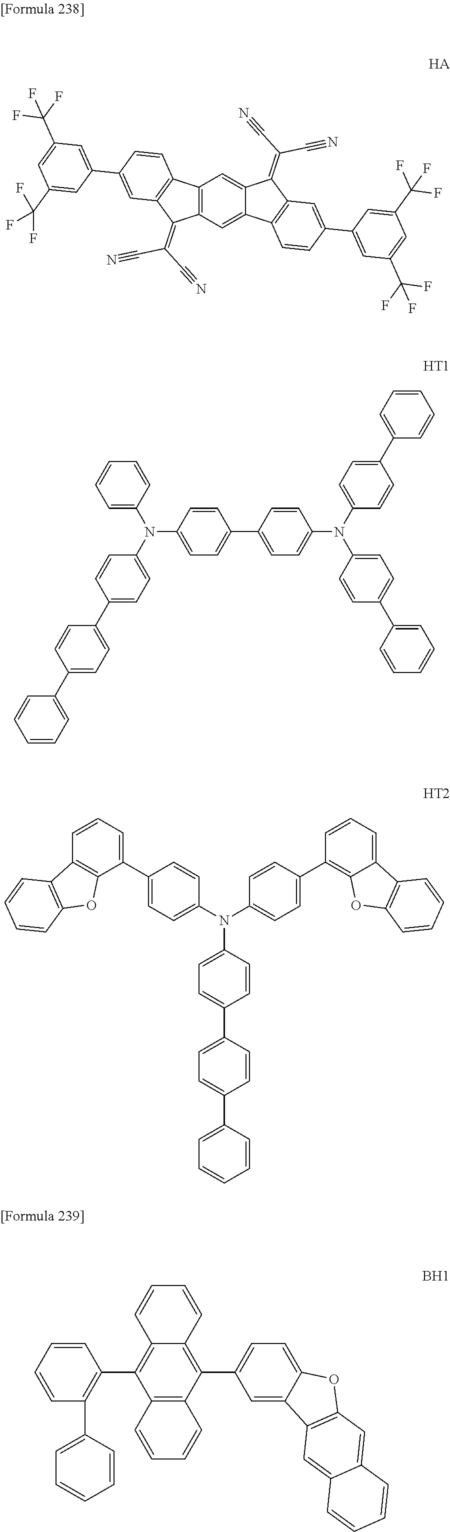 [SMILES: N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccccc2-c2c3ccccc3c(-c3ccc4oc5cc6ccccc6cc5c4c3)c3ccccc23)cc1]

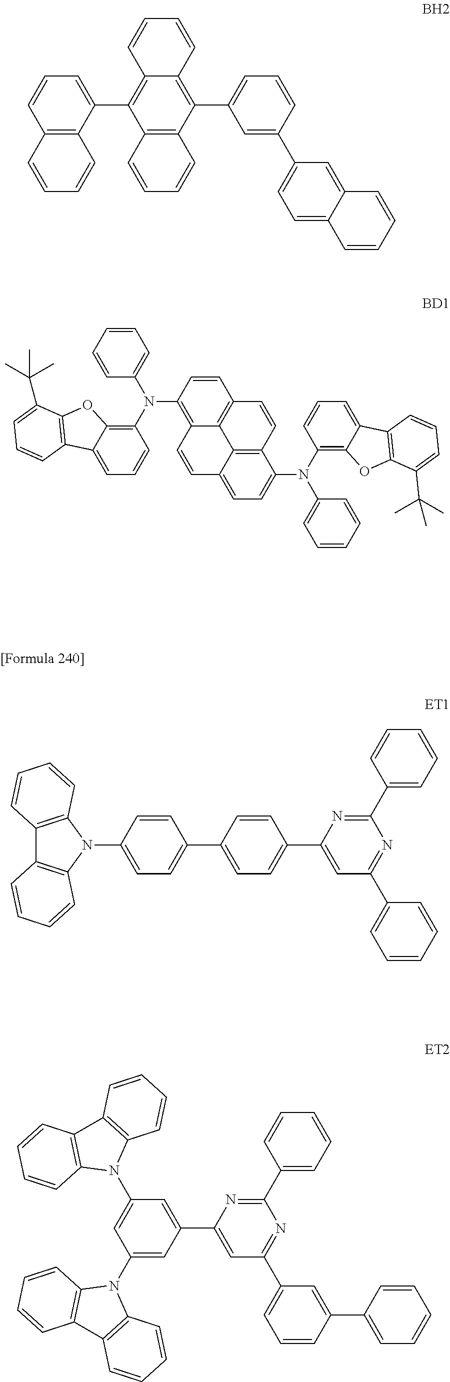

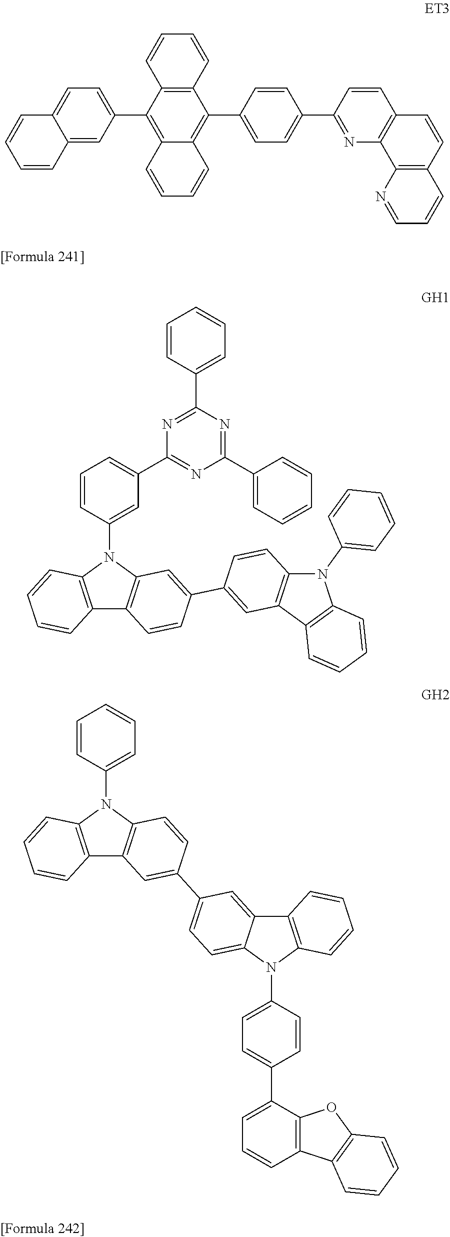 [SMILES: c1ccc2cc(-c3c4ccccc4c(-c4ccc(-c5ccc6ccc7cccnc7c6n5)cc4)c4ccccc34)ccc2c1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-n2c3ccccc3c3cc(-c4ccc5c(c4)c4ccccc4n5-c4ccc(-c5cccc6c5oc5ccccc56)cc4)ccc32)cc1]

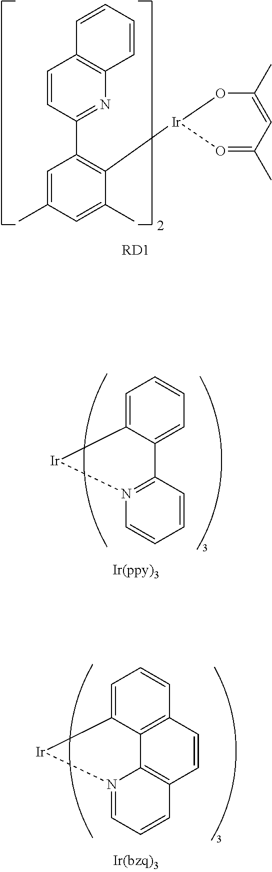

### Reference Examples

Reference Examples relate to an organic EL device including a single emitting unit (a mono-unit organic EL device).

### Manufacturing 1 of Organic EL Device

### Reference Example 1

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. A film of ITO was set to be 130-nm thick.

After the glass substrate having the transparent electrode line was cleaned, the glass substrate was mounted on a substrate holder of a vacuum evaporation apparatus. Firstly, the compound HA was deposited on a surface of the glass substrate where the transparent electrode line was provided in a manner to cover the transparent electrode, thereby forming a 5-nm thick HA film of the compound HA to form a hole injecting layer.

Next, the compound HT1 was deposited on the hole injecting layer to form an 80-nm thick HT1 film, thereby providing a first hole transporting layer.

Next, the compound HT2 was deposited on the first hole transporting layer to form a 15-nm thick HT2 film, thereby providing a second hole transporting layer.

Next, the compound BH2 and a blue fluorescent compound BD1 were co-deposited on the second hole transporting layer to form a 25-nm thick emitting layer. A concentration of the compound BD1 in the emitting layer was set at 3 mass %.

Following the film formation of the emitting layer, the compound ET2 was deposited on the emitting layer to form a 20-nm thick ET2 film as the first electron transporting layer.

Next, the compound ET3 and a metal Li were co-deposited on the first electron transporting layer to form a 5-nm thick second electron transporting layer. A Li concentration contained in the second electron transporting layer was set at 4 mass %.

A metal Al was deposited on the second electron transporting layer to form an 80-nm thick metal cathode.

Thus, the organic EL device of Reference Example 1 was manufactured.

A device arrangement of the organic EL device of Reference Example 1 is roughly shown as follows.

ITO(130)/HA(5)/HT1(80)/HT2(15)/BH2:BD1(25:3%)/ET2(20)/ET3:Li(5:4%)/Al(80)

Numerals in parentheses represent a film thickness (unit: nm). The numerals represented by percentage in the same parentheses indicate a concentration (mass %) of the compound BD1 in the emitting layer or the concentration (mass %) of Li in the second electron transporting layer. The same arrangement is also applicable to Reference Examples 2 to 4.

### Reference Example 2

An organic EL device of Reference Example 2 was manufactured in the same manner as the organic EL device of Reference Example 1 except for using the compound ET1 in place of the compound ET2 in the first electron transporting layer in Reference Example 1.

A device arrangement of the organic EL device of Reference Example 2 is roughly shown as follows.

ITO(130)/HA(5)/HT1(80)/HT2(15)/BH2:BD1(25:3%)/ET1(20)/ET3:Li(5:4%)/Al(80)

### Reference Example 3

An organic EL device of Reference Example 3 was manufactured in the same manner as the organic EL device of Reference Example 1 except for using the compound ET1 in place of the compound ET2 in the first electron transporting layer in Reference Example 1.

A device arrangement of the organic EL device of Reference Example 3 is roughly shown as follows.

ITO(130)/HA(5)/HT1(80)/HT2(15)/BH1:BD1(25:3%)/ET2(20)/ET3:Li(5:4%)/Al(80)

### Reference Example 4

An organic EL device of Reference Example 4 was manufactured in the same manner as the organic EL device of Reference Example 1 except for using the compound BH1 in place of the compound BH2 in the emitting layer and using the compound ET1 in place of the compound ET2 in the first electron transporting layer in Reference Example 1.

A device arrangement of the organic EL device of Reference Example 4 is roughly shown as follows.

ITO(130)/HA(5)/HT1(80)/HT2(15)/BH1:BD1(25:3%)/ET1(20)/ET3:Li(5:4%)/Al(80)

### Evaluation 1 of Organic EL Devices

The manufactured organic EL devices of Reference Examples 1 to 4 were evaluated as follows. The evaluation results are shown in Table 1.

### Drive Voltage

Voltage was applied between ITO transparent electrode and Al metal cathode such that a current density was 10 mA/cm², where the voltage (unit: V) was measured.

### CIE1931 Chromaticity

Voltage was applied on each of the organic EL devices manufactured such that a current density was 10 mA/cm², where coordinates (x, y) of CIE1931 chromaticity were measured by a spectroradiometer CS-1000 (manufactured by Konica Minolta, Inc.). In Table, CIEx and CIEy respectively correspond to the coordinates (x, y) of CIE1931 chromaticity.

### Luminance-Current Efficiency (L/J)

Voltage was applied on each of the organic EL devices manufactured such that the current density was 10 mA/cm², where luminance L (unit: cd/m²) was measured using a spectroradiometer (manufactured by Konica Minolta, Inc., product name: CS-1000). A luminance-current efficiency (unit: cd/A) was calculated based on the obtained luminance.

### External Quantum Efficiency EQE

Voltage was applied on each of the organic EL devices such that a current density was 10 mA/cm², where spectral radiance spectra were measured by a spectroradiometer CS-1000 (manufactured by Konica Minolta, Inc.). The external quantum efficiency EQE (unit: %) was calculated based on the obtained spectral-radiance spectra, assuming that the spectra was provided under a Lamb ertian radiation.

### Lifetime LT90

An initial current density was set at 50 mA/cm² and a continuous direct current test was performed. When a luminance at the start (t=0) of the test was defined as an initial luminance L(0) and a luminance at a time after elapse oft hours was defined as L(t), the time (unit: h) satisfying L(t)/L(0)=0.9 was defined as a lifetime (LT90). It should be noted that the luminance L represents a deterioration degree of a green luminance according to a green stimulus value Y in CIE1931 color system.

### Lifetime ZT90

Z(t) is an index representing a deterioration degree of a blue stimulus value and is calculated according to the following equation.

Z(t)=[(1−CIEx−CIEy)/CIEy]×(L(t))

When a value at the start (t=0) of the test was defined as an initial value Z(0) and a value at a time after elapse of t hours was defined as Z(t), the time (unit: h) satisfying Z(t)/Z(0)=0.9 was defined as a lifetime (ZT90).

TABLE 1

| | | 1st Electron | | | | | | | |
|---|---|---|---|---|---|---|---|---|---|
| | Emitting | Transporting | Voltage | | | L/J | EQE | LT90 | ZT90 |
| | Layer | Layer | [V] | CIEx | CIEy | [cd/A] | [%} | [h] | [h] |
| Reference | BH2:BD1 | ET2 | 4.43 | 0.137 | 0.095 | 7.1 | 8.3 | 124 | 122 |
| Example 1 | | | | | | | | | |
| Reference | BH2:BD1 | ET1 | 4.01 | 0.138 | 0.093 | 6.4 | 7.6 | 91 | 83 |
| Example 2 | | | | | | | | | |
| Reference | BH1:BD1 | ET2 | 3.95 | 0.137 | 0.091 | 6.3 | 7.6 | 86 | 89 |
| Example 3 | | | | | | | | | |
| Reference | BH1: BD1 | ET1 | 3.68 | 0.138 | 0.092 | 7.0 | 8.3 | 43 | 41 |
| Example 4 | | | | | | | | | |

In comparison between Reference Examples 1 and 2 in which the compound BH2 was used in each of the emitting layers, a use of the compound ET1 in the electron transporting layer decreases the drive voltage while decreasing the luminous efficiency (L/J and EQE).

In comparison between Reference Examples 3 and 4 in which the compound BH1 was used in each of the emitting layers, a use of the compound ET1 in the electron transporting layer decreases the drive voltage while improving the luminous efficiency (L/J and EQE).

In comparison between Reference Examples 1 and 4, in an organic EL device of Reference Example 4, in which the compound BH1 was used in the emitting layers and the compound ET1 is used in the electron transporting layer, the drive voltage is decreased and the luminous efficiency (L/J and EQE) is the same level as in Reference Example 1.

### Manufacturing 2 of Organic EL Device (Reference Example 5)

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. A film of ITO was set to be 77-nm thick.

After the glass substrate having the transparent electrode line was cleaned, the glass substrate was mounted on a substrate holder of a vacuum evaporation apparatus. Firstly, the compound HA was deposited on a surface of the glass substrate where the transparent electrode line was provided in a manner to cover the transparent electrode, thereby forming a 5-nm thick HA film of the compound HA to form a hole injecting layer.

Next, the compound HT1 was deposited on the hole injecting layer to form a 45-nm thick HT1 film, thereby providing a first hole transporting layer.

Next, the compound HT2 and the compound RD1 were co-deposited on the first hole transporting layer to form a 10-nm thick red emitting layer. A concentration of the compound RD1 in the red emitting layer was set at 6 mass %.

Next, the compound GH1, compound GH2 and compound Ir(ppy)₃ were co-deposited on the red emitting layer to form a 30-nm-thick green emitting layer. In the green emitting layer, a concentration of the compound GH2 was set at 47.5% and a concentration of the compound Ir(ppy)₃ was set at 5 mass %.

Subsequently, the compound ET2 was deposited on the green emitting layer to form a 20-nm-thick first electron transporting layer.

Next, the compound ET3 and metal Li were co-deposited on the first electron transporting layer to form a 15-nm thick second electron transporting layer. A Li concentration contained in the second electron transporting layer was set at 4 mass %.

The metal Al was deposited on the second electron transporting layer to form an 80-nm thick metal cathode.

Thus, the organic EL device of Reference Example 5 was manufactured.

A device arrangement of the organic EL device of Reference Example 5 is roughly shown as follows.

ITO(77)/HA(5)/HT1(45)/HT2:RD1(10:6%)/GH1:GH2:Ir(ppy)₃(30:47.5%, 5%)/ET2(20)/ET3:Li(15:4%)/Al(80)

Numerals in parentheses represent a film thickness (unit: nm). The numerals represented by percentage in the same parentheses indicate a concentration (mass %) of the compound RD1 in the red emitting layer, a concentration (mass %) of each of the compounds GH2 and Ir(ppy)₃ in the green emitting layer, or a concentration (mass %) of Li in the second electron transporting layer.

### Reference Example 6

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. A film of ITO was set to be 77-nm thick.

After the glass substrate having the transparent electrode line was cleaned, the glass substrate was mounted on a substrate holder of a vacuum evaporation apparatus. Firstly, the compound HA was deposited on a surface of the glass substrate where the transparent electrode line was provided in a manner to cover the transparent electrode, thereby forming a 5-nm thick HA film of the compound HA to form a hole injecting layer.

Next, the compound HT1 was deposited on the hole injecting layer to form a 40-nm thick HT1 film, thereby providing the first hole transporting layer.

Next, the compound HT2 was deposited on the first hole transporting layer to form a 10-nm thick HT2 film, thereby providing the second hole transporting layer.

Next, the compound GH1, the compound GH2 and the compound Ir(bzq)₃ were co-deposited on the second hole transporting layer to form a 30-nm-thick yellow emitting layer. In the yellow emitting layer, a concentration of the compound GH2 was set at 47.5 mass % and a concentration of the compound Ir(bzq)₃ was set at 5 mass %.

Subsequently, the compound ET2 was deposited on the yellow emitting layer to form a 20-nm-thick first electron transporting layer.

Next, the compound ET3 and metal Li were co-deposited on the first electron transporting layer to form a 15-nm thick second electron transporting layer. A Li concentration contained in the second electron transporting layer was set at 4 mass %.

The metal Al was deposited on the second electron transporting layer to form an 80-nm thick metal cathode.

Thus, the organic EL device of Reference Example 6 was manufactured.

A device arrangement of the organic EL device of Reference Example 6 is roughly shown as follows.

ITO(77)/HA(5)/HT1(40)/HT2(10)/GH1:GH2:Ir(bzq)₃(30:47.5%, 5%)/ET2(20)/ET3:Li(15:4%)/Al(80)

Numerals in parentheses represent a film thickness (unit: nm). The numerals represented by percentage in the same parentheses indicate a concentration (mass %) of each of the compound GH2 and the compound Ir(bzq)₃ in the yellow emitting layer or the concentration (mass %) of Li in the second electron transporting layer.

### Evaluation 2 of Organic EL Devices

The manufactured organic EL devices of Reference Examples 5 and 6 were evaluated in the same manner as described above. It should be noted that a lifetime (XT90) was measured in place of the lifetime (ZT90) in Reference Examples 5 and 6. The evaluation results are shown in Tables 2 and 3.

### Lifetime XT90

X(t) is an index representing a deterioration degree of a red stimulus value and is calculated according to the following equation.

X(t)=[CIEx/CIEy]×(L(t))

When a value at the start (t=0) of the test was defined as an initial value X(0) and a value at a time after elapse of t hours was defined as X(t), the time (unit: h) satisfying X(t)/X(0)=0.9 was defined as a lifetime (XT90).

TABLE 2

| | Red Emitting | Green Emitting | Voltage | | | L/J | EQE | LT90 | XT90 |
|---|---|---|---|---|---|---|---|---|---|
| | Layer | Layer | [V] | CIEx | CIEy | [cd/A] | [%} | [h] | [h] |
| Reference | HT2:RD1 | GH1:GH2:Ir(ppy)₃ | 4.23 | 0.399 | 0.554 | 43.6 | 17.0 | 140 | 99 |
| Example 5 | | | | | | | | | |

TABLE 3

| | Yellow Emitting | Voltage | | | L/J | EQE | LT90 | XT90 |
|---|---|---|---|---|---|---|---|---|
| | Layer | [V] | CIEx | CIEy | [cd/A] | [%} | [h] | [h] |
| Reference | GH1:GH2:Ir(bzq)₃ | 3.98 | 0.430 | 0.560 | 56.2 | 15.9 | 164 | 160 |
| Example 6 | | | | | | | | |

### Example and Comparatives

Examples and Comparatives relate tore a tandem organic EL device.

### Manufacturing 3 of Organic EL Device

### Example 1

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. A film of ITO was set to be 77-nm thick.

After the glass substrate having the transparent electrode line was cleaned, the glass substrate was mounted on a substrate holder of a vacuum evaporation apparatus. Initially, the second emitting unit including the mixed red-green emitting layer was formed on a surface of the glass substrate where the transparent electrode line was provided. The charge generating layer was formed on the second emitting unit. The first emitting unit including the blue emitting layer was formed on the charge generating layer. The cathode was formed on the first emitting unit.

The second emitting unit will be described below. Firstly, the compound HA was deposited on the glass substrate in a manner to cover the transparent electrode to form a 5-nm thick HA film, thereby providing the hole injecting layer.

Next, the compound HT1 was deposited on the hole injecting layer to form a 45-nm thick HT1 film, thereby providing the first hole transporting layer.

Next, the compound HT2 and the compound RD1 were co-deposited on the first hole transporting layer to form a 10-nm thick red emitting layer. A concentration of the compound RD1 in the red emitting layer was set at 6 mass %.

Next, the compound GH1, the compound GH2 and the compound Ir(ppy)₃ were co-deposited on the red emitting layer to form a 30-nm-thick green emitting layer. In the green emitting layer, the concentration of the compound GH2 was set at 47.5% and the concentration of the compound Ir(ppy)₃ was set at 5 mass %.

Subsequently, the compound ET2 was deposited on the green emitting layer to form a 20-nm-thick film, thereby providing the electron transporting layer.

The charge generating layer will be described. Firstly, the compound ET3 and metal Li were co-deposited on the electron transporting layer of the second emitting layer to form a 10-nm thick n-type charge generating layer. A Li concentration contained in the n-type charge generating layer was set at 4 mass %.

Subsequently, the compound HA was deposited on the n-type charge generating layer to form a 10-nm-thick HA film, thereby providing a p-type charge generating layer.

The first emitting unit will be described below. Firstly, the compound HT1 was deposited on the p-type charge generating layer of the charge generating layer charge generating layer to form a 105-nm thick HT1 film, thereby providing the first hole transporting layer.

Next, the compound HT2 was deposited on the first hole transporting layer to form a 15-nm thick HT2 film, thereby providing the second hole transporting layer.

Next, the compound BH1 and the blue fluorescent compound BD1 were co-deposited on the second hole transporting layer to form a 25-nm thick blue emitting layer. A concentration of the compound BD1 in the emitting layer was 3 mass %.

Following the film formation of the blue emitting layer, the compound ET1 was deposited on the emitting layer to form a 20-nm thick ET1 film as the first electron transporting layer.

Next, the compound ET3 and metal Li were co-deposited on the first electron transporting layer to form a 5-nm thick second electron transporting layer. A Li concentration contained in the second electron transporting layer was set at 4 mass %.

The metal Al was deposited on the second electron transporting layer of the first emitting unit to form an 80-nm thick metal cathode.

Thus, the organic EL device of Example 1 was manufactured.

A device arrangement of the organic EL device of Example 1 is roughly shown as follows.

ITO(77)/HA(5)/HT1(45)/HT2:RD1(10:6%)/GH1:GH2:Ir(ppy)₃(30:47.5%, 5%)/ET2(20)/ET3:Li(10:4%)/HA(10)/HT1(105)/HT2(15)/BH1:BD1(25:3%)/ET1(20)/ET3:Li(5:4%)/Al(80)

Numerals in parentheses represent a film thickness (unit: nm). The numerals represented by percentage in the same parentheses indicate a concentration (mass %) of the compound RD1 in the red emitting layer, a concentration (mass %) of each of the compounds GH2 and Ir(ppy)₃ in the green emitting layer, a concentration of the compound BD1 in the blue emitting layer, or a concentration (mass %) of Li in the second electron transporting layer. The same description applies to Comparative 1 below.

### Comparative 1

An organic EL device of Comparative 1 was manufactured in the same manner as the organic EL device of Example 1 except for using the compound BH2 in place of the compound BH1 in the blue emitting layer and using the compound ET2 in place of the compound ET1 in the first electron transporting layer in the first emitting unit including the blue emitting layer of Example 1.

A device arrangement of the organic EL device of Comparative Example 1 is roughly shown as follows.

ITO(77)/HA(5)/HT1(45)/HT2:RD1(10:6%)/GH1:GH2:Ir(ppy)₃(30:47.5%, 5%)/ET2(20)/ET3:Li(10:4%)/HA(10)/HT1(105)/HT2(15)/BH2:BD1(25:3%)/ET2(20)/ET3:Li(5:4%)/Al(80)

### Comparative 2

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes, and then UV/ozone-cleaned for 30 minutes. A film of ITO was set to be 130-nm thick.

After the glass substrate having the transparent electrode line was cleaned, the glass substrate was mounted on a substrate holder of a vacuum evaporation apparatus. Initially, the second emitting unit including the blue emitting layer was formed on a surface of the glass substrate where the transparent electrode line was provided. The charge generating layer was formed on the second emitting unit. The first emitting unit including the red emitting layer and the green emitting layer was formed on the charge generating layer. The cathode was formed on the first emitting unit.

The second emitting unit will be described below. Firstly, the compound HA was deposited on the glass substrate in a manner to cover the transparent electrode to form a 5-nm thick HA film, thereby providing the hole injecting layer.

Next, the compound HT1 was deposited on the hole injecting layer to form a 80-nm thick HT1 film, thereby providing the first hole transporting layer.

Next, the compound HT2 was deposited on the first hole transporting layer to form a 15-nm thick HT2 film, thereby providing the second hole transporting layer.

Next, the compound BH1 and the blue fluorescent compound BD1 were co-deposited on the second hole transporting layer to form a 25-nm thick blue emitting layer. A concentration of the compound BD1 in the emitting layer was set at 3 mass %.

Following the film formation of the blue emitting layer, the compound ET1 was deposited on the emitting layer to form a 20-nm thick ET1 film as the electron transporting layer.

The charge generating layer will be described. Firstly, the compound ET3 and metal Li were co-deposited on the electron transporting layer of the second emitting layer to form a 10-nm thick n-type charge generating layer. A Li concentration contained in the n-type charge generating layer was set at 4 mass %.

Subsequently, the compound HA was deposited on the n-type charge generating layer to form a 10-nm-thick film HA, thereby providing the p-type charge generating layer.

The first emitting unit will be described below. Firstly, the compound HT1 was deposited on the p-type charge generating layer of the charge generating layer charge generating layer to form a 40-nm thick HT1 film, thereby providing the hole transporting layer.

Next, the compound HT2 and the compound RD1 were co-deposited on the hole transporting layer to form a 10-nm thick red emitting layer. A concentration of the compound RD1 in the red emitting layer was set at 6 mass %.

Next, the compound GH1, the compound GH2 and the compound Ir(ppy)₃ were co-deposited on the red emitting layer to form a 30-nm-thick green emitting layer. In the green emitting layer, the concentration of the compound GH2 was set at 47.5% and the concentration of the compound Ir(ppy)₃ was set at 5 mass %.

Subsequently, the compound ET2 was deposited on the green emitting layer to form a 20-nm-thick film, thereby providing the first electron transporting layer.

Next, the compound ET3 and metal Li were co-deposited on the first electron transporting layer to form a 15-nm thick second electron transporting layer. A Li concentration contained in the second electron transporting layer was set at 4 mass %.

The metal Al was deposited on the second electron transporting layer of the first emitting unit to form an 80-nm thick metal cathode.

Thus, the organic EL device of Comparative 2 was manufactured.

A device arrangement of the organic EL device of Comparative 2 is roughly shown as follows.

ITO(130)/HA(5)/HT1(80)/HT2(15)/BH1:BD1(25:3%)/ET1(20)/ET3:Li(10, 4%)/HA(10)/HT1(40)/HT2:RD1(10:6%)/GH1:GH2:Ir(ppy)₃(30:47.5%, 5%)/ET2(20)/ET3:Li(15:4%)/Al(80)

Numerals in parentheses represent a film thickness (unit: nm). The numerals represented by percentage in the same parentheses indicate a concentration (mass %) of the compound RD1 in the red emitting layer, a concentration (mass %) of each of the compounds GH2 and Ir(ppy)₃ in the green emitting layer, a concentration of the compound BD1 in the blue emitting layer, or a concentration (mass %) of Li in the second electron transporting layer. The same description applies to Comparative 3 below.

### Comparative 3

An organic EL device of Comparative 3 was manufactured in the same manner as the organic EL device of Comparative 2 except for using the compound BH2 in place of the compound BH1 in the blue emitting layer and using the compound ET2 in place of the compound ET1 in the electron transporting layer in the second emitting unit of Comparative 2.

A device arrangement of the organic EL device of Comparative Example 3 is roughly shown as follows.

ITO(130)/HA(5)/HT1(80)/HT2(15)/BH2:BD1(25:3%)/ET2(20)/ET3:Li(10, 4%)/HA(10)/HT1(40)/HT2:RD1(10:6%)/GH1:GH2:Ir(ppy)₃(30:47.5%, 5%)/ET2(20)/ET3:Li(15:4%)/Al(80)

### Evaluation 3 of Organic EL Devices

The manufactured organic EL devices of Example 1 and Comparatives 1 to 3 were evaluated in the same manner as described above. The evaluation results are shown in Tables 4 and 5.

TABLE 4

| | | | First Emitting Unit | | | | | | | | | |
|---|---|---|---|---|---|---|---|---|---|---|---|---|
| | Second Emitting Unit | | | 1st Electron | Evaluation Result | | | | | | | |
| | Red Emitting | Green Emitting | Blue Emitting | Transporting | Voltage | | | L/J | EQE | LT90 | ZT90 | XT90 |
| | Layer | Layer | Layer | Layer | [V] | CIEx | CIEy | [cd/A] | [%} | [h] | [h] | [h] |
| Ex. 1 | HT2:RD1 | GH1:GH2:Ir(ppy)₃ | BH1:BD1 | ET1 | 7.77 | 0.320 | 0.311 | 47.4 | 24.2 | 118 | 67 | 88 |
| Comp. 1 | HT2:RD1 | GH1:GH2:Ir(ppy)₃ | BH2:BD1 | ET2 | 8.60 | 0.338 | 0.340 | 46.9 | 22.7 | 66 | 4 | 34 |

TABLE 5

| | Second Emitting Unit | | | | | | | | | | | |
|---|---|---|---|---|---|---|---|---|---|---|---|---|
| | | Electron | First Emitting Unit | | Evaluation Result | | | | | | | |
| | Blue Emitting | Transporting | Red Emitting | Green Emitting | Voltage | | | L/J | EQE | LT90 | ZT90 | XT90 |
| | Layer | Layer | Layer | Layer | [V] | CIEx | CIEy | [cd/A] | [%} | [h] | [h] | [h] |
| Comp. 2 | BH1:BD1 | ET1 | HT2:RD1 | GH1:GH2:Ir(ppy)₃ | 7.62 | 0.283 | 0.312 | 46.5 | 25.1 | 94 | 31 | 70 |
| Comp. 3 | BH2:BD1 | ET2 | HT2:RD1 | GH1:GH2:Ir(ppy)₃ | 8.39 | 0.284 | 0.298 | 43.9 | 24.8 | 100 | 64 | 76 |

Compared with the organic EL device of Comparative 1 in which the compound BH2 was used in the blue emitting layer, the organic EL device of Example 1 in which the compound BH1 was used in the blue emitting layer exhibited a low drive voltage, a high luminous efficiency and a long lifetime (LT90, ZT90 and XT90).

Compared with the organic EL devices of Comparatives 2 and 3 including the blue emitting layer between the anode and the charge generating layer, the organic EL device of Example 1 including the blue emitting layer between the charge generating layer and the cathode exhibited a low drive voltage and a long lifetime while keeping the luminous efficiency at the same level as in Comparatives 2 and 3.

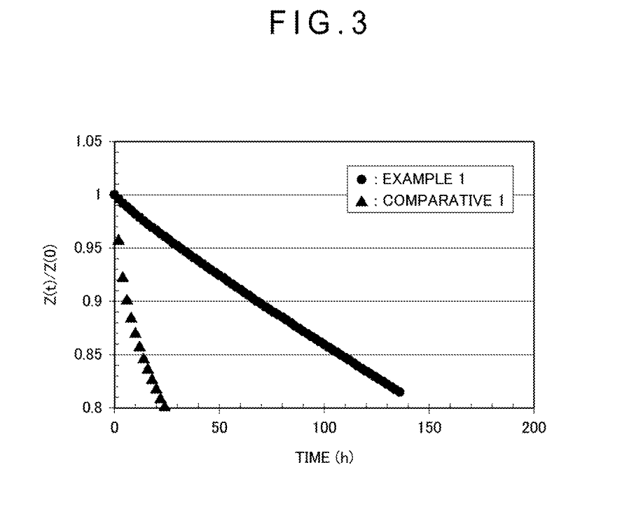

FIG. 3 is a graph showing a time-dependent change in stimulus value of a blue component in organic EL devices according to Example 1 and Comparative 1. The ordinate axis represents Z(t)/Z(0). The abscissa axis represents a time (unit: h). As shown in FIG. 3, the lifetime until reduced to Z(t)/Z(0)=0.95 was remarkably prolonged by providing the blue emitting layer containing a predetermined compound of the invention between the charge generating layer and the cathode.

### Manufacturing 4 of Organic EL Device

### Example 2

An organic EL device of Example 2 was manufactured in the same manner as the organic EL device of Example 1 except for using the second emitting unit including the yellow emitting layer in place of the second emitting unit including the red emitting layer and the green emitting layer in the organic EL device of Example 1.

Specifically, the second emitting unit of Example 2 was manufactured in the same manner as in Example 1 except that the compound HT2 was deposited to form a 10-nm thick HT2 film to provide the second hole transporting layer and the second hole transporting layer was used in place of the red emitting layer of Example 1 and that the compounds GH1, GH2 and Ir(bzq)₃ were co-deposited to form a 30-nm thick yellow emitting layer and the yellow emitting layer was used in place of the green emitting layer of Example 1. In the yellow emitting layer of Example 2, the concentration of the compound GH2 was set at 47.5% and the concentration of the compound Ir(bzq)₃ was set at 5 mass % .

A device arrangement of the organic EL device of Example 2 is roughly shown as follows.

ITO(77)/HA(5)/HT1(45)/HT2(10)/GH1:GH2:Ir(bzq)₃(30:47.5%, 5%)/ET2(20)/ET3:Li(10:4%)/HA(10)/HT1(105)/HT2(15)/BH1:BD1(25:3%)/ET1(20)/ET3:Li(5:4%)/Al(80)

Numerals in parentheses represent a film thickness (unit: nm). The numerals represented by percentage in the same parentheses indicate a concentration (mass %) of each of the compounds GH2 and Ir(bzq)₃ in the yellow emitting layer, a concentration (mass %) of the compound BD1 in the blue emitting layer, or a concentration (mass %) of Li in the electron transporting layer.

### Comparative 4

An organic EL device of Comparative 4 was manufactured in the same manner as the organic EL device of Example 2 except for using the compound BH2 in place of the compound BH1 in the blue emitting layer and using the compound ET2 in place of the compound ET1 in the first electron transporting layer in the first emitting unit including the blue emitting layer of Example 2.

A device arrangement of the organic EL device of Comparative 4 is roughly shown as follows.

ITO(77)/HA(5)/HT1(45)/HT2(10)/GH1:GH2:Ir(bzq)₃(30:47.5%, 5%)/ET2(20)/ET3:Li(10:4%)/HA(10)/HT1(105)/HT2(15)/BH2:BD1(25:3%)/ET2(20)/ET3:Li(5:4%)/Al(80)

### Comparative 5

An organic EL device of Comparative 5 was manufactured in the same manner as the organic EL device of Comparative 2 except for using the first emitting unit including the yellow emitting layer in place of the first emitting unit including the red emitting layer and the green emitting layer in Comparative 2.

Specifically, the first emitting unit of Comparative 5 was manufactured in the same manner as in Comparative 2 except that the compound HT2 was deposited to form a 10-nm thick HT2 film to provide the second hole transporting layer and the second hole transporting layer replaced the red emitting layer of Comparative 2 and that the compounds GH1, GH2 and Ir(bzq)₃ were co-deposited to form a 30-nm thick yellow emitting layer and the yellow emitting layer replaced the green emitting layer of Comparative 2. In the yellow emitting layer of Comparative 5, the concentration of the compound GH2 was set at 47.5% and the concentration of the compound Ir(bzq)₃ was set at 5 mass %.

A device arrangement of the organic EL device of Comparative 5 is roughly shown as follows.

ITO(130)/HA(5)/HT1(80)/HT2(15)/BH1:BD1(25:3%)/ET1(20)/ET3:Li(10, 4%)/HA(10)/HT1(40)/HT2(10)/GH1:GH2:Ir(bzq)₃(30:47.5%, 5%)/ET2(20)/ET3:Li(15:4%)/Al(80)

### Comparative 6

An organic EL device of Comparative 6 was manufactured in the same manner as the organic EL device of Comparative 5 except for using the compound BH2 in place of the compound BH1 in the blue emitting layer and using the compound ET2 in place of the compound ET1 in the electron transporting layer in the second emitting unit including the blue emitting layer of Comparative 5.

A device arrangement of the organic EL device of Comparative 6 is roughly shown as follows.

ITO(130)/HA(5)/HT1(80)/HT2(15)/BH2:BD1(25:3%)/ET2(20)/ET3:Li(10, 4%)/HA(10)/HT1(40)/HT2(10)/GH1:GH2:Ir(bzq)₃(30:47.5%, 5%)/ET2(20)/ET3:Li(15:4%)/Al(80)

### Evaluation 4 of Organic EL Devices

The manufactured organic EL devices of Example 2 and Comparatives 4 to 6 were evaluated in the same manner as described above. The evaluation results are shown in Tables 6 and 7.

TABLE 6

| | | First Emitting Unit | | | | | | | | | |
|---|---|---|---|---|---|---|---|---|---|---|---|
| | Second Emitting Unit | | 1st Electron | Evaluation Result | | | | | | | |
| | Yellow Emitting | Blue Emitting | Transporting | Voltage | | | L/J | EQE | LT90 | ZT90 | XT90 |
| | Layer | Layer | Layer | [V] | CIEx | CIEy | [cd/A] | [%} | [h] | [h] | [h] |
| Ex. 2 | GH1:GH2:Ir(bzq)₃ | BH1:BD1 | ET1 | 7.55 | 0.342 | 0.351 | 63.3 | 24.4 | 161 | 70 | 136 |
| Comp. 4 | GH1:GH2:Ir(bzq)₃ | BH2:BD1 | ET2 | 8.43 | 0.357 | 0.372 | 62.4 | 23.2 | 97 | 7 | 67 |

TABLE 7

| | Second Emitting Unit | | First Emitting | | | | | | | | |
|---|---|---|---|---|---|---|---|---|---|---|---|
| | | Electron | Unit | Evaluation Result | | | | | | | |
| | Blue Emitting | Transporting | Yellow Emitting | Voltage | | | L/J | EQE | LT90 | ZT90 | XT90 |
| | Layer | Layer | Layer | [V] | CIEx | CIEy | [cd/A] | [%} | [h] | [h] | [h] |
| Comp. 5 | BH1:BD1 | ET1 | GH1:GH2:Ir(bzq)₃ | 7.43 | 0.305 | 0.329 | 52.0 | 22.3 | 121 | 31 | 103 |
| Comp. 6 | BH2:BD1 | ET2 | GH1:GH2:Ir(bzq)₃ | 8.29 | 0.302 | 0.328 | 51.8 | 22.4 | 122 | 67 | 115 |

Compared with the organic EL device of Comparative 4 in which the compound BH2 was used in the blue emitting layer, the organic EL device of Example 2 in which the compound BH1 was used in the blue emitting layer exhibited a low drive voltage, a high luminous efficiency and a long lifetime (LT90, ZT90 and XT90).

Compared with the organic EL devices of Comparatives 2 and 6 including the blue emitting layer between the anode and the charge generating layer, the organic EL device of Example 2 including the blue emitting layer between the charge generating layer and the cathode exhibited a low drive voltage and a long lifetime while keeping the luminous efficiency at the same level as in Comparatives 5 and 3.

### EXPLANATION OF CODES

1 . . . organic EL device, 1A . . . organic EL device, 3 . . . anode, 4 . . . cathode, 5 . . . charge generating layer, 5A . . . first charge generating layer, 5B . . . second charge generating layer, 10 . . . first emitting unit, 11 . . . hole transporting layer, 12 . . . blue emitting layer (first blue emitting layer), 13 . . . electron transporting layer, 20 . . . second emitting unit, 20A . . . second emitting unit, 22 . . . hole transporting layer, 23 . . . red emitting layer, 24 . . . green emitting layer, 25 . . . electron transporting layer, 26 . . . mixed red-green emitting layer, 30 . . . third emitting unit, 32 . . . hole transporting layer, 33 . . . second blue emitting layer, 34 . . . electron transporting layer.

1. An organic electroluminescence device comprising:
a cathode;
an anode;
a charge generating layer provided between the anode and the cathode;
a first emitting unit provided between the charge generating layer and the cathode; and
a second emitting unit provided between the charge generating layer and the anode, wherein
the first emitting unit comprises a first blue emitting layer comprising a first compound represented by a formula (1) below and a second compound emitting a blue light, 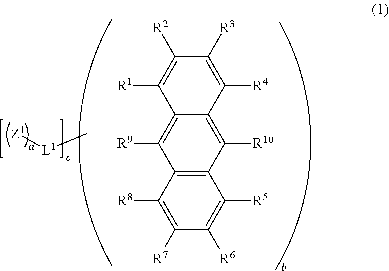
where: any one of R¹ to R¹⁰ is a single bond to be bonded to L¹ and the rest of R¹ to R¹⁰, which are not bonded to L¹, are each independently a hydrogen atom or a substituent,
R¹ to R¹⁰ each in a form of the substituent are each independently selected from the group consisting of a halogen atom, a hydroxyl group, a cyano group, a substituted or unsubstituted amino group, a substituted or unsubstituted alkyl group having 1 to 30 carbon atoms, a substituted or unsubstituted alkoxy group having 1 to 30 carbon atoms, a substituted or unsubstituted aryloxy group having 6 to 30 ring carbon atoms, a substituted or unsubstituted arylthio group having 6 to 30 ring carbon atoms, a substituted or unsubstituted aromatic hydrocarbon group having 6 to 30 ring carbon atoms, and a substituted or unsubstituted heterocyclic group having 5 to 30 ring atoms;
L¹ is a single bond or a linking group, and L¹ in a form of the linking group is a substituted or unsubstituted aromatic hydrocarbon group having 6 to 30 ring carbon atoms, or a substituted or unsubstituted heterocyclic group having 5 to 30 ring atoms;
Z¹ is represented by a formula (2) below;
a, b and c are each independently an integer of 1 to 4;
a plurality of Z¹ are optionally the same or different;
a plurality of structures each represented by [(Z¹)ₐ-L¹-] are optionally the same or different; and
a plurality of cyclic structures in parentheses with a suffix b are optionally the same or different, 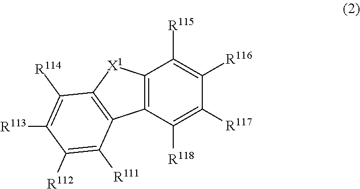
where: X¹ is an oxygen atom or a sulfur atom;
R¹¹¹ to R¹¹⁸ are each independently a hydrogen atom, a substituent, or a single bond bonded to L¹, and R¹¹¹ to R¹¹⁸ each in a form of the substituent are each independently selected from the examples of the substituent usable as R¹ to R¹⁰; and
at least one combination of a combination of R¹¹¹ and R¹¹², a combination of R¹¹² and R¹¹³, a combination of R¹¹³ and R¹¹⁴, a combination of R¹¹⁵ and R¹¹⁶, a combination of R¹¹⁶ and R¹¹⁷, or a combination of R¹¹⁷ and R¹¹⁸ is the substituents that are bonded to each other to form a ring represented by a formula (3) or (4) below, 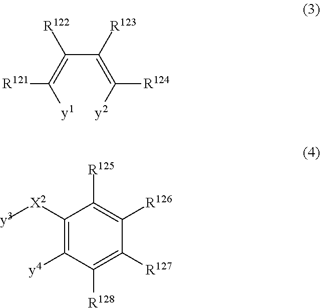
in the formula (3), y¹ and y² represent bonding positions with Z¹ that is the cyclic structure represented by the formula (2),
in the formula (4), y³ and y⁴ represent bonding positions with Z¹ that is the cyclic structure represented by the formula (2), and X² is an oxygen atom or a sulfur atom,
in the formulae (3) and (4), R¹²¹ to R¹²⁴ and R¹²⁵ to R¹²⁸ are each independently a hydrogen atom, a substituent, or a single bond bonded to L¹, and R¹²¹ to R¹²⁸ each in a form of the substituent are each independently selected from the examples of the substituent usable as R¹ to R¹⁰,
when the ring represented by the formula (3) is formed, any one of R¹¹¹ to R¹¹⁸ and R¹²¹ to R¹²⁴ not bonded to form a ring is a single bond bonded to L¹, and
when the ring represented by the formula (4) is formed, any one of R¹¹¹ to R¹¹⁸ and R¹²⁵ to R¹²⁸ not bonded to form a ring is a single bond bonded to L¹.

2. The organic electroluminescence device according to claim 1, wherein
the first emitting unit is connected in series with the second emitting unit via the charge generating layer.

3. The organic electroluminescence device according to claim 1, wherein
the second emitting unit comprises a mixed red-green emitting layer comprising a third compound emitting a green light and a fourth compound emitting a red light.

4. The organic electroluminescence device according to claim 1, wherein
the second emitting unit comprises a green emitting layer comprising a third compound emitting a green light and a red emitting layer comprising a fourth compound emitting a red light.

5. The organic electroluminescence device according to claim 1, wherein
the second emitting unit comprises a yellow emitting layer comprising a fifth compound emitting a yellow light.

6. The organic electroluminescence device according to claim 1, further comprising:
a second charge generating layer provided between the anode and the second emitting unit; and
a third emitting unit provided between the anode and the second charge generating layer, wherein
the second emitting unit comprises a mixed red-green emitting layer comprising a third compound emitting a green light and a fourth compound emitting a red light, and
the third emitting unit comprises a second blue emitting layer comprising a sixth compound emitting a blue light.

7. The organic electroluminescence device according to claim 1, wherein
the anode is a light-reflective electrode, and
the cathode is a light-transmissive electrode.

8. The organic electroluminescence device according to claim 1, wherein
the cathode is a light-reflective electrode, and
the anode is a light-transmissive electrode.

9. The organic electroluminescence device according to claim 1, wherein
Z¹ is a group selected from the group consisting of groups represented by formulae (8) to (10), 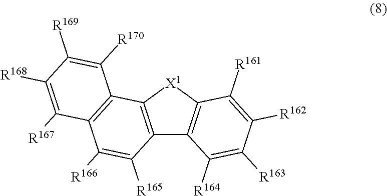 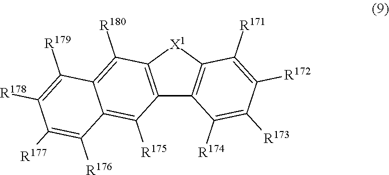 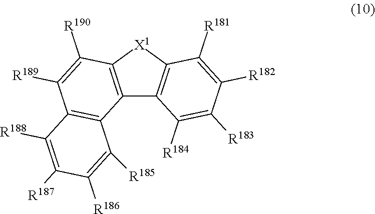
in the formula (8), R¹⁶¹ to R¹⁷⁰ each independently represent the same as R¹ to R¹⁰ not bonded to L¹ in the formula (1), and one of R¹⁶¹ to R¹⁷⁰ is a single bond bonded to L¹,
in the formula (9), R¹⁷¹ to R¹⁸⁰ each independently represent the same as R¹ to R¹⁰ not bonded to L¹ in the formula (1), and one of R¹⁷¹ to R¹⁸⁰ is a single bond bonded to L¹,
in the formula (10), R¹⁸¹ to R¹⁹⁰ each independently represent the same as R¹ to R¹⁰ not bonded to L¹ in the formula (1), and one of R¹⁸¹ to R¹⁹⁰ is a single bond bonded to L¹, and
in the formulae (8) to (10), X¹ represents the same as X¹ in the formula (2).

10. The organic electroluminescence device according to claim 1, wherein
the first compound is represented by a formula (12), 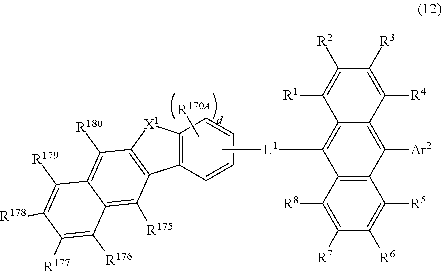
where: R¹ to R⁸ are each independently a hydrogen atom or a substituent; and R¹ to R⁸ each in a form of the substituent are each independently selected from the examples of the substituent usable as R¹ to R⁸ in the formula (1);
L¹ is a single bond or a linking group, and L¹ in a form of the linking group is a substituted or unsubstituted aromatic hydrocarbon group having 6 to 30 ring carbon atoms or a substituted or unsubstituted heterocyclic group having 5 to 30 ring atoms;
Ar² is a substituted or unsubstituted aromatic hydrocarbon group having 6 to 30 ring carbon atoms or a substituted or unsubstituted heterocyclic group having 5 to 30 ring atoms;
R^{170A} is a hydrogen atom, a substituent, or a single bond bonded to L¹, and R^{170A} in a form of the substituent is selected from the examples of the substituent usable as R¹ to R⁸;
d is 4, and a plurality of R^{170A} are optionally mutually the same or different;
X¹ is an oxygen atom or a sulfur atom; and
R¹⁷⁵ to R¹⁸⁰ are each independently a hydrogen atom or a substituent, and R¹⁷⁵ to R¹⁸⁰ each in a form of the substituent are each independently selected from the examples of the substituent usable as R¹ to R⁸.

11. The organic electroluminescence device according to claim 1, wherein
the first compound is represented by a formula (13) or (14), 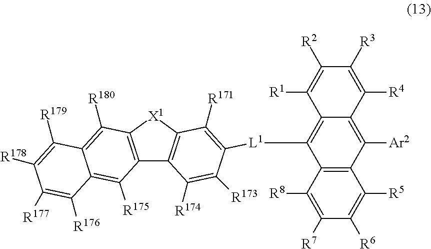 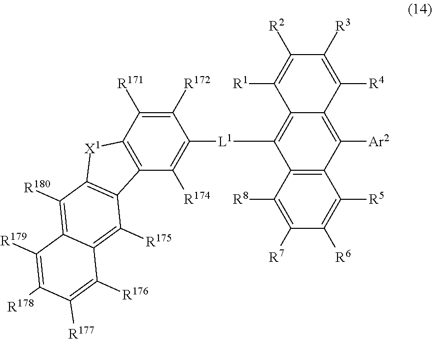
in the formulae (13) and (14): R¹ to R⁸, L¹ and X¹ respectively represent the same as R¹ to R⁸, L¹ and X¹ in the formula (1) or (2); and Ar² is a substituted or unsubstituted aromatic hydrocarbon group having 6 to 30 ring carbon atoms or a substituted or unsubstituted heterocyclic group having 5 to 30 ring atoms,
in the formula (13): R¹⁷¹ and R¹⁷³ to R¹⁸⁰ are each independently a hydrogen atom or a substituent; and R¹⁷¹ and R¹⁷³ to R¹⁸⁰ each in a form of the substituent are each independently selected from the examples of the substituent usable as R¹ to R⁸, and
in the formula (14): R¹⁷¹, R¹⁷², and R¹⁷⁴ to R¹⁸⁰ are each independently a hydrogen atom or a substituent; and R¹⁷¹, R¹⁷², and R¹⁷⁴ to R¹⁸⁰ each in a form of the substituent are each independently selected from the examples of the substituent usable as R¹ to R⁸.

12. The organic electroluminescence device according to claim 1, wherein
the first compound is represented by a formula (15) or (16), 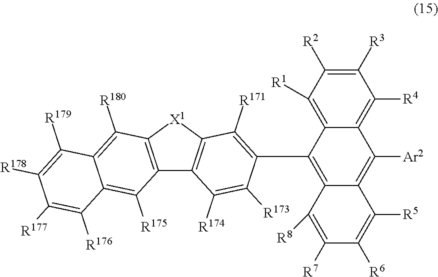 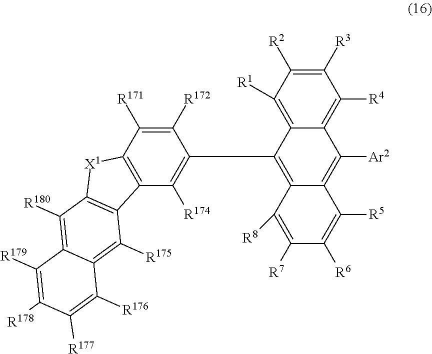
in the formulae (15) and (16): R¹ to R⁸ and X¹ respectively represent the same as R¹ to R⁸ and X¹ in the formula (1) or (2); and Ar² is a substituted or unsubstituted aromatic hydrocarbon group having 6 to 30 ring carbon atoms or a substituted or unsubstituted heterocyclic group having 5 to 30 ring atoms,
in the formula (15): R¹⁷¹ and R¹⁷³ to R¹⁸⁰ are each independently a hydrogen atom or a substituent; and R¹⁷¹ and R¹⁷³ to R¹⁸⁰ each in a form of the substituent are each independently selected from the examples of the substituent usable as R¹ to R⁸, and
in the formula (16): R¹⁷¹, R¹⁷², and R¹⁷⁴ to R¹⁸⁰ are each independently a hydrogen atom or a substituent; and R¹⁷¹, R¹⁷², and R¹⁷⁴ to R¹⁸⁰ each in a form of the substituent are each independently selected from the examples of the substituent usable as R¹ to R⁸.

13. The organic electroluminescence device according to claim 1, wherein
the first compound is represented by a formula (17), 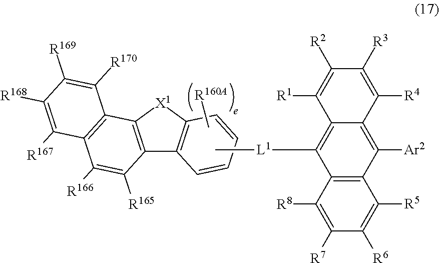
where: R¹ to R⁸ are each independently a hydrogen atom or a substituent;
R¹ to R⁸ each in a form of the substituent are each independently selected from the examples of the substituent usable as R¹ to R⁸ in the formula (1);
L¹ is a single bond or a linking group, and L¹ in a form of the linking group is a substituted or unsubstituted aromatic hydrocarbon group having 6 to 30 ring carbon atoms or a substituted or unsubstituted heterocyclic group having 5 to 30 ring atoms;
Ar² is a substituted or unsubstituted aromatic hydrocarbon group having 6 to 30 ring carbon atoms or a substituted or unsubstituted heterocyclic group having 5 to 30 ring atoms;
R^{160A} is a hydrogen atom, a substituent, or a single bond bonded to L¹, and R^{160A} in a form of the substituent is selected from the examples of the substituent usable as R¹ to R⁸;
e is 4, and a plurality of R^{160A} are optionally mutually the same or different;
X¹ is an oxygen atom or a sulfur atom; and
R¹⁶⁵ to R¹⁷⁰ are each independently a hydrogen atom or a substituent, and R¹⁶⁵ to R¹⁷⁰ each in a form of the substituent are each independently selected from the examples of the substituent usable as R¹ to R⁸.

14. The organic electroluminescence device according to claim 1, wherein
the first compound is represented by a formula (18) or (19), 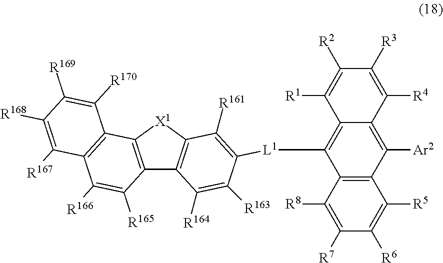 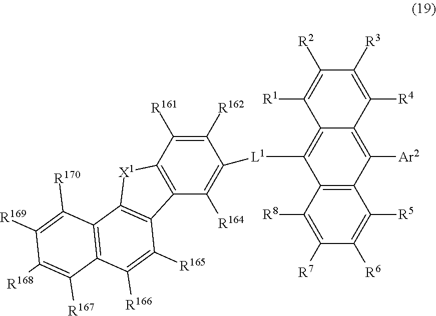
in the formulae (18) and (19): R¹ to R⁸, L¹ and X¹ respectively represent the same as R¹ to R⁸, L¹ and X¹ in the formula (1) or (2); Ar² is a substituted or unsubstituted aromatic hydrocarbon group having 6 to 30 ring carbon atoms or a substituted or unsubstituted heterocyclic group having 5 to 30 ring atoms,
in the formula (18): R¹⁶¹ and R¹⁶³ to R¹⁷⁰ are each independently a hydrogen atom or a substituent; and R¹⁶¹ and R¹⁶³ to R¹⁷⁰ each in a form of the substituent are each independently selected from the examples of the substituent usable as R¹ to R⁸, and
in the formula (19): R¹⁶¹, R¹⁶², and R¹⁶⁴ to R¹⁷⁰ are each independently a hydrogen atom or a substituent; and R¹⁶¹, R¹⁶², and R¹⁶⁴ to R¹⁷⁰ each in a form of the substituent are each independently selected from the examples of the substituent usable as R¹ to R⁸.

15. The organic electroluminescence device according to claim 1, wherein
the first compound is represented by a formula (20) or (21), 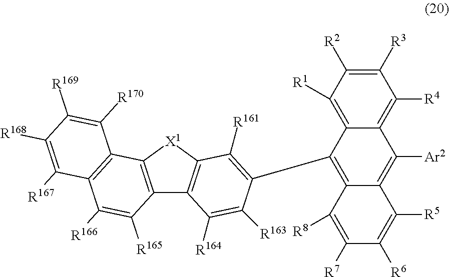 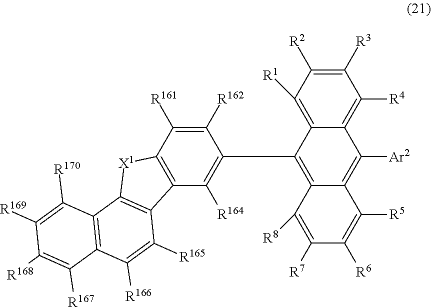
in the formulae (20) and (21): R¹ to R⁸ and X¹ respectively represent the same as R¹ to R⁸ and X¹ in the formula (1) or (2); and Ar² is a substituted or unsubstituted aromatic hydrocarbon group having 6 to 30 ring carbon atoms or a substituted or unsubstituted heterocyclic group having 5 to 30 ring atoms,
in the formula (20): R¹⁶¹ and R¹⁶³ to R¹⁷⁰ are each independently a hydrogen atom or a substituent; and R¹⁶¹ and R¹⁶³ to R¹⁷⁰ each in a form of the substituent are each independently selected from the examples of the substituent usable as R¹ to R⁸, and
in the formula (21): R¹⁶¹, R¹⁶², and R¹⁶⁴ to R¹⁷⁰ are each independently a hydrogen atom or a substituent; and R¹⁶¹, R¹⁶², and R¹⁶⁴ to R¹⁷⁰ each in a form of the substituent are each independently selected from the examples of the substituent usable as R¹ to R⁸.

16. The organic electroluminescence device according to claim 1, wherein
the first compound is represented by a formula (22), 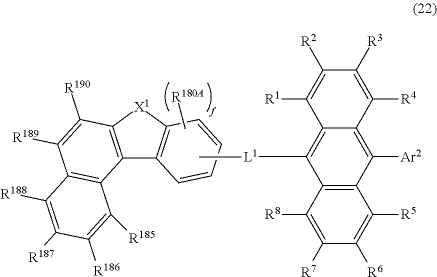
where: R¹ to R⁸ are each independently a hydrogen atom or a substituent;
R¹ to R⁸ each in a form of the substituent are each independently selected from the examples of the substituent usable as R¹ to R⁸ in the formula (1);
L¹ is a single bond or a linking group, and L¹ as the linking group is a substituted or unsubstituted aromatic hydrocarbon group having 6 to 30 ring carbon atoms or a substituted or unsubstituted heterocyclic group having 5 to 30 ring atoms;
Ar² is a substituted or unsubstituted aromatic hydrocarbon group having 6 to 30 ring carbon atoms or a substituted or unsubstituted heterocyclic group having 5 to 30 ring atoms;
R^{180A} is a hydrogen atom, a substituent, or a single bond bonded to L¹, and R^{180A} in a form of the substituent is selected from the examples of the substituent usable as R¹ to R⁸;
f is 4, and a plurality of R^{180A} are optionally mutually the same or different;
X¹ is an oxygen atom or a sulfur atom; and
R¹⁸⁵ to R¹⁹⁰ are each independently a hydrogen atom or a substituent, and R¹⁸⁵ to R¹⁹⁰ each in a form of the substituent are each independently selected from the examples of the substituent usable as R¹ to R⁸.

17. The organic electroluminescence device according to claim 1, wherein
the first compound is represented by a formula (23) or (24), 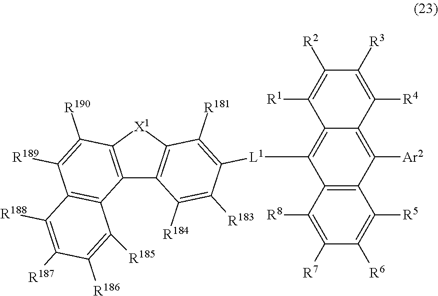 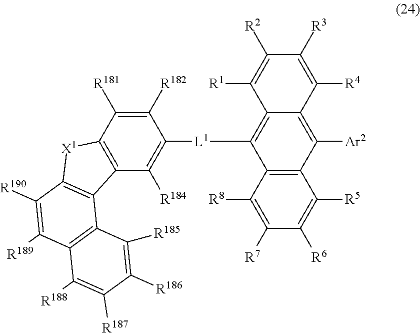
in the formulae (23) and (24): R¹ to R⁸, L¹ and X¹ respectively represent the same as R¹ to R⁸, L¹ and X¹ in the formula (1) or (2); and Ar² is a substituted or unsubstituted aromatic hydrocarbon group having 6 to 30 ring carbon atoms or a substituted or unsubstituted heterocyclic group having 5 to 30 ring atoms,
in the formula (23): R¹⁸¹ and R¹⁸³ to R¹⁹⁰ are each independently a hydrogen atom or a substituent; and R¹⁸¹ and R¹⁸³ to R¹⁹⁰ each in a form of the substituent are each independently selected from the examples of the substituent usable as R¹ to R⁸, and
in the formula (24): R¹⁸¹, R¹⁸², and R¹⁸⁴ to R¹⁹⁰ are each independently a hydrogen atom or a substituent; and R¹⁸¹, R¹⁸², and R¹⁸⁴ to R¹⁹⁰ each in a form of the substituent are each independently selected from the examples of the substituent usable as R¹ to R⁸.

18. The organic electroluminescence device according to claim 1, wherein
the first compound is represented by a formula (25) or (26), 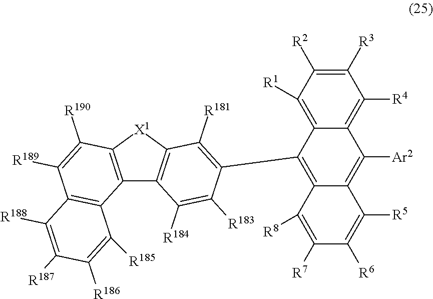 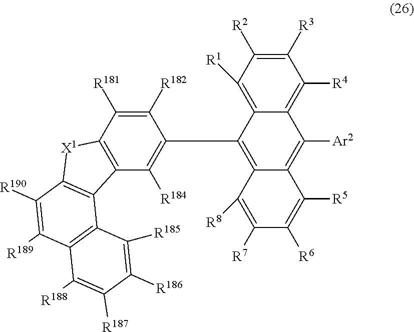
in the formulae (25) and (26): R¹ to R⁸ and X¹ respectively represent the same as R¹ to R⁸ and X¹ in the formula (1) or (2); and Ar² is a substituted or unsubstituted aromatic hydrocarbon group having 6 to 30 ring carbon atoms or a substituted or unsubstituted heterocyclic group having 5 to 30 ring atoms,
in the formula (25): R¹⁸¹ and R¹⁸³ to R¹⁹⁰ are each independently a hydrogen atom or a substituent; and R¹⁸¹ and R¹⁸³ to R¹⁹⁰ each in a form of the substituent are each independently selected from the examples of the substituent usable as R¹ to R⁸, and
in the formula (26): R¹⁸¹, R¹⁸², and R¹⁸⁴ to R¹⁹⁰ are each independently a hydrogen atom or a substituent; and R¹⁸¹, R¹⁸², and R¹⁸⁴ to R¹⁹⁰ each in a form of the substituent are each independently selected from the examples of the substituent usable as R¹ to R⁸.

19. The organic electroluminescence device according to claim 10, wherein
Ar² is a substituent selected from the group consisting of a substituted or unsubstituted phenyl group, substituted or unsubstituted naphthyl group, substituted or unsubstituted phenanthryl group, substituted or unsubstituted benzanthryl group, substituted or unsubstituted 9,9-dimethylfluorenyl group, and substituted or unsubstituted dibenzofuranyl group.

20. The organic electroluminescence device according to claim 10, wherein Ar² is a group selected from the group consisting of groups represented by formulae (11a) to (11k), (11m), (11n) and (11p),

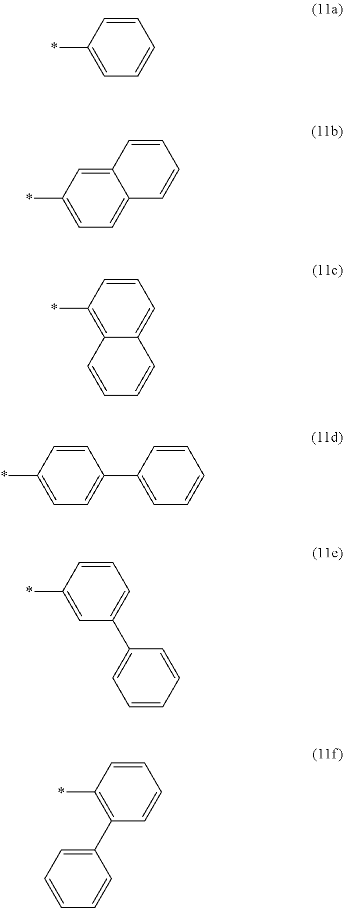 [SMILES: *c1ccccc1 ; *c1ccc2ccccc2c1 ; *c1cccc2ccccc12 ; *c1ccc(-c2ccccc2)cc1 ; *c1cccc(-c2ccccc2)c1 ; *c1ccccc1-c1ccccc1]

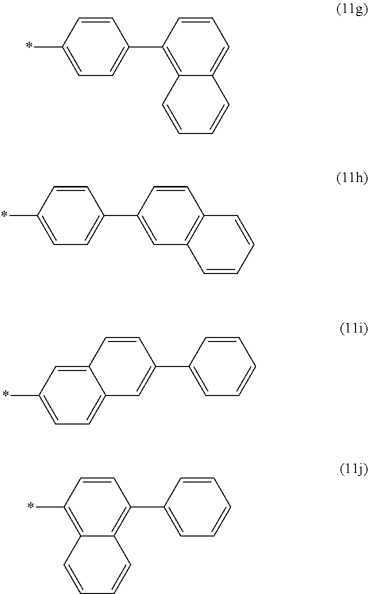 [SMILES: *c1ccc(-c2cccc3ccccc23)cc1 ; *c1ccc(-c2ccc3ccccc3c2)cc1 ; *c1ccc2cc(-c3ccccc3)ccc2c1 ; *c1ccc(-c2ccccc2)c2ccccc12]

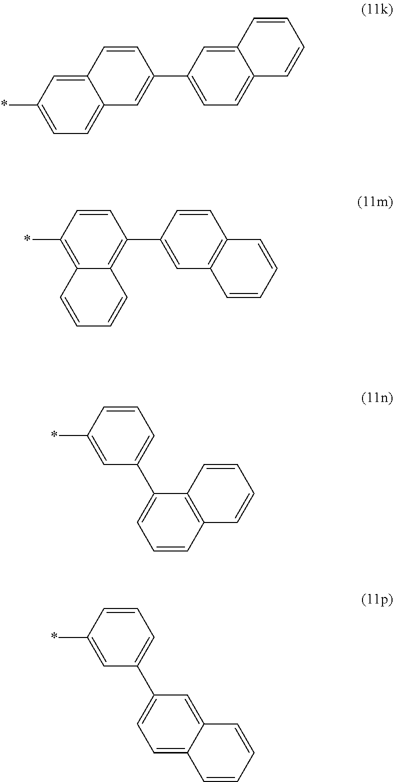 [SMILES: *c1ccc2cc(-c3ccc4ccccc4c3)ccc2c1 ; *c1ccc(-c2ccc3ccccc3c2)c2ccccc12 ; *c1cccc(-c2cccc3ccccc23)c1 ; *c1cccc(-c2ccc3ccccc3c2)c1]

21. The organic electroluminescence device according to claim 1, wherein X¹ is an oxygen atom.

22. The organic electroluminescence device according to claim 1, wherein R¹ to R⁸ are hydrogen atoms.

23. The organic electroluminescence device according to claim 1, further comprising an electron transporting layer interposed between the blue emitting layer and the cathode.

24. The organic electroluminescence device according to claim 1, further comprising a hole transporting layer interposed between the blue emitting layer and the charge generating layer.

25. An electronic device comprising the organic electroluminescence device according to claim 1.
